(19) United States
(12) Patent Application Publication
(10) Pub. No.: US 2022/0134421 A1
(43) Pub. Date: May 5, 2022

(54) METHOD FOR THE ECONOMIC MANUFACTURING OF METALLIC PARTS

(71) Applicant: INNOMAQ 21, S.L., Madrid (ES)

(72) Inventor: Isaac VALLS ANGLÉS, Rubí (ES)

(73) Assignee: INNOMAQ 21, S.L., Madrid (ES)

(21) Appl. No.: 17/517,421

(22) Filed: Nov. 2, 2021

Related U.S. Application Data
(63) Continuation of application No. 15/773,523, filed on May 3, 2018, now abandoned.

(30) Foreign Application Priority Data
Nov. 6, 2015 (EP) 15382549.2
Jan. 29, 2016 (ES) 201630110
Feb. 15, 2016 (ES) 201630174
Aug. 4, 2016 (EP) 16382386.7

(51) Int. Cl. B22F 1/00; C22C 1/04; B22F 3/22; C22C 14/00; B22F 3/10; C22C 33/02; C22C 21/00; C22C 19/03; C22C 38/12; B22F 10/10; C22C 32/00; C22C 29/00; C22C 26/00; B33Y 70/00; G03F 7/004; B33Y 80/00

(52) U.S. Cl. CPC B22F 1/00; B22F 2301/052; B22F 3/225; C22C 1/0458; C22C 14/00; B22F 3/1035; C22C 33/0257; C22C 21/00; C22C 1/0416; C22C 19/03; C22C 38/12; B22F 3/10; B22F 10/10; C22C 32/00; B22F 2301/058; Y02P 10/25; C22C 29/005; C22C 26/00; B22F 2301/30; B22F 2203/11; B33Y 70/00; B22F 2301/20; B22F 2303/45; B22F 2301/15; G03F 7/0047; B33Y 80/00; C22C 1/0433

(57) ABSTRACT

The present invention relates to a method for the economic production of metallic parts, with high flexibility in the geometry attainable. It also relates to the material required for the manufacturing of those parts. The method of the present invention allows for a very fast manufacturing of the parts. Also some forming technologies applicable to polymers can be used. The method allows for the fast and economic production of complex geometry metallic parts.

### CROSS REFERENCE TO THE RELATED APPLICATION

This application is a continuation of Ser. No. 15/773,523 filed May 3, 2018, which is a 371 from International Application PCT/EP2016/076895 filed Nov. 7, 2016, which claims priority to EP 16382386.7 filed Aug. 4, 2016, ES 201630174 filed 15 Feb. 2016, ES 201630110 filed Jan. 29, 2016 and EP 15382549.2 Nov. 6, 2015, the contents of which are incorporated herein by reference.

### FIELD OF THE INVENTION

The present invention relates to a method for the economic production of metallic additive manufacturing parts. It also relates to the material required for the manufacturing of those parts. The method of the present invention allows for a very fast manufacturing of the parts. Also some forming technologies applicable to polymers can be used.

### SUMMARY

Materials properties are arguably one of the main limitation to engineering evolution. Often materials with higher mechanical resistance are desired together with other properties. Evolution in this area are mostly attained trough improvements in the understanding of the effect of alloying and microstructures attainable trough thermo-mechanical processing and lately even more trough the improvement of manufacturing processes. Another of the main limitations is design, and its implementation possibilities. In the past decades a great effort has been invested in the investigation of structures with exceptional properties, many replicated from evolutionary optimization in nature. The so-called bionic or nature replication structures, are often quite complex and thus not easy to manufacture with the conventional manufacturing systems. Additive Manufacturing (AM) is a set of technologies that have broadly increased the accuracy with which many structures can be replicated. Unfortunately Additive Manufacturing of metals is still a high cost manufacturing route mostly due to the high cost of the systems employed and the manufacturing speeds attainable in those high cost additive manufacturing systems.

For very high end applications as is the case in aeronautics, nuclear, military and tooling applications amongst others, a lot of attention is played in maximizing material performance. In this applications often complex (and cost intensive) manufacturing processes are employed, and the materials employed are also very often costly to manufacture.

In recent years significant efforts have been invested into reducing the cost of the materials required for additive manufacturing (normally powders and thin wires). Increase the speed of manufacturing of the AM machines and reduce their cost. Unfortunately, many technologically relevant materials have a quite high melting point, which means a quite high power density is required for their melting and the thermal management is challenging, since most metals have a noticeable thermal expansion coefficient. A nice characteristic of several AM materials is that they not require post-processing in the sense of a Heat Treatment (HT) after the AM process. But the material reaching the highest values of engineering relevant properties often require a HT after the AM process. Also the accuracy levels and rugosity presently attainable in an economic way through AM of metals is not sufficient for several applications, requiring a manufacturing post-processing.

The AM methods suitable for metallic materials based on localized melting (eventually sintering) tend to have speed limitations due to the high energy associated to the melting, and the complexity of trying to manage the thermal stresses. The whole manufactured component can be kept at a high temperature to reduce thermal gradient to the melting pool and thus reduce thermal stresses to better manage warpage, but it is energetically quite costly, and the efficiency is limited. Also the systems based on the usage of an inked glue or binder, require a sintering-like treatment where often shape retention is compromised for large and complex shapes unless very laborious steps are taken. Isotropy is often a challenge for AM of metallic components.

The additive manufacturing of polymeric materials is considerably more advanced and economic. Although some important constraints still exist in the kinds of materials that can be used, different technologies have been evolved to a point where the manufacturing of several components is already economically viable. Mostly due to the lower softening, and melting points of polymers and also due to the ability to set or cure trough exposition to certain wavelengths of some resins or through a chemical reaction, considerable faster deposition rates that in the case of metals are attainable. In most cases inhibitors have also been developed to further enhance the complexity of parts that can be manufactured. Also many systems are less costly to manufacture than the systems required for the AM of metals.

Also some AM systems are quite effective for rather small pieces with very complex geometries and quite hollow (considerably more air than material). But for rather massive structures or pieces, where most of the body enclosed by the contour of the piece is filled with material, almost all systems are rather inefficient unless the AM is applied to an already existing part. Building from scratch of filled pieces is not effective.

Other manufacturing processes can be applied as a shaping step, besides AM with some of the materials of the present invention. They need to be fast manufacturing processes. Most polymer shaping methodologies are an option (injection molding, blow-molding, thermoforming, casting, compression, pressing RIM, extrusion, rotomolding, dip molding, foam shaping . . . ). As an example the case of injection molding can be taken, where a process exist called Metal Injection Molding (MIM), which allows the obtaining of metallic components, but which is limited to a few hundred grams. With the method and materials of the present invention, much larger components can be manufactured, with enhanced functionality and in a considerably more economical way.

In the present invention a method is developed for the construction of cost effective pieces trough AM, or eventually another fast shaping process. The method is often valid for pieces with any kind of air to material ratio, and any kind of size or geometry.

Additive manufacturing using curable resins loaded is known for some ceramics: silica, alumina, hydroxyapatite. The main limitation is the limited selection of ceramics available and achievable size pieces, are only possible because small parts.

Also known additive manufacturing curable resins loaded by other metals and ceramics and even when very low particulate fillers used in the resin and subsequent infiltration proceeds to metal or other liquid. In these cases the volume fraction of the particles of interest is low.

The method has several realizations depending on the particular piece to be manufactured.

For pieces with a low air/material ratio, a system based on the configuration by removal can be employed. For pieces with a high air/material ratio, a shaping system based on aggregation or conformation is often preferred. Different shaping systems can be employed for the manufacturing of the piece either simultaneously or sequentially. The method of the present invention can work directly on direct metal aggregation, but for many applications it is though very advantageous to have a mixed polymer metal material.

The method of the present invention often includes at least one stage of conformation in which a base particulate material is employed where at least one polymeric material and at least one metallic material are present simultaneously. Then the consolidation for the preliminary shaping is mainly made through the polymeric material. In most cases a post processing operation takes place to consolidate the metallic material.

For many instances and AM systems the inventor has seen that it is very advantageous to have at least two different metallic materials in the feedstock, and even more advantageous when at least two of the materials have a considerable difference in their melting points. Furthermore it is for many systems advantageous if at least one of the metallic materials starts to melt before the shape retention of the polymeric matrix is completely lost. In some cases it is also very advantageous when the metallic material with lower melting point can diffuse into the base metallic material without causing severe embrittlement. For some applications it is also interesting that at least one of the metallic materials is an alloy with a wide range of melting temperature, particularly interesting for applications with complex geometries is when this alloy is one with a low melting start point. One further advantage can be attained, especially when a liquid phase is desirable, by choosing a system whose melting point will increase when diffusion takes place to be able to control the liquid phase volume fraction throughout all the process.

The present invention is especially advantageous for the light weight construction. Complex geometries can be attained with difficult to deform metallic base materials (high mechanical strength metallic materials desirable for light weight construction often have limited formability). Complex geometries allow to replicate optimized designs in nature for the maximum performance with the minimum material volume. Also alloys of light materials can be used: Ti, Al, Mg, Li . . . . Also some denser material but where very high mechanical properties can be achieved even in aggressive environments in the basis of Ni, Fe, Co, Cu, Mo, W, Ta . . . .

### STATE OF THE ART

Solid freeform fabrication or rapid prototyping (RP) is the automatic construction of physical objects using additive manufacturing (AM) technology, which is colloquially referred to as “3D printing”. This technology builds up parts and components by adding materials one layer at a time based on a computerized 3D solid model. It is considered by many authors as “the third industrial revolution” as it allows design optimization and production of customized parts on-demand. AM technologies can be classified in several categories, as presented in the document F2792-12a by the ASTM International, where seven classifications are considered: i) binder jetting, ii) directed energy deposition, iii) material extrusion, iv) material jetting, v) powder bed fusion, vi) sheet lamination, and vii) vat photopolymerization. Each technology classification includes a set of different material classifications and discrete manufacturing technologies. Thus, AM includes numerous technologies such as fused deposition modelling, selective laser sintering/melting, laser engineered net shaping, 3D printing, direct ink writing, laminated object manufacturing, digital light processing, and stereolithography among others. A wide range of ceramic, polymeric and metallic materials can be used in additive manufacturing and each technological classification have been developed towards a particular type of materials. Thus, the most extensively studied materials are polymers, for which the early studies focused on. Many common plastics and polymers (acrylonitrile butadiene styrene, polycarbonates, polylactide, polyamide, etc.) can be used, as well as waxes and epoxy based resins. The technologies included in binder jetting, material extrusion, material jetting, sheet lamination, and vat photopolymerization allow fabricating polymer 3D materials. For ceramics the most commonly used AM technologies are: fused deposition modeling (FDM), selective laser sintering/melting (SLS/SLM), 3D printing, direct ink writing, laminated object manufacturing, stereolithography, and digital light processing. In what respect to metallic components, these have always been a challenge for additive manufacturing technologies, as insufficient mechanical properties and high cost have been continuously pointed as the main drawbacks for its deployment. Laser sintering/melting processes are the main and most widely studied technologies for 3D-printing of metals, in which the feedstock is mainly presented in powder form although there are some systems using metal wire. Like other additive manufacturing systems, laser sintering/melting obtains the geometrical information from a 3D CAD model. The different process variations are based on the possible inclusion of other materials (e.g. multicomponent metal-polymer powder mixtures etc.) and subsequent post-treatments. The processes using powder feedstock are carried out through the selective melting of adjacent metal particles in a layer-by-layer fashion until the desired shape. This can be done in an indirect or direct form. The indirect form uses the process technology of polymers to manufacture metallic parts, where metal powders are coated with polymers. The relatively low melting of the polymer coating with respect the metallic material aid connecting the metal particles after solidification. The direct laser process includes the use of special multicomponent powder systems. Selective laser melting (SLM) is an enhancement of the direct selective laser sintering and a sintering process is subsequently applied at high temperatures in order to attain densification. However, the melting and re-melting processes create a large temperature gradient between the powder bed layers, which consequently affects the quality of the final metallic piece. This effect is even increased in metals with a high melting point, where expensive systems are required. These shortcomings have been addressed by several publications. Bampton et al presented an invention (U.S. Pat. No. 5,745,834) related to the free form fabrication of metallic components using selective laser binding through transient liquid sintering. The blended powders used in this invention were comprised of a parent or base metal alloy (75-85%), a lower melting temperature metal alloy (5-15%) and a polymer binder (5-15%). The base metals considered were metallic elements such as nickel, iron, cobalt, copper, tungsten, molybdenum, rhenium, titanium, and aluminium. As for the low-melting temperature metal alloy, this could be chosen among base metals with melting point depressants (Boron, silicon, carbon or phosphorus) in order to lower the melting point of the base alloy by approximately 300°−400° C. The method of SLS considered in this invention and other powder-based AM technologies strongly rely in the powder characteristics. Plastic, metal or ceramic particles can be coated with an adhesive and sinterable and/or glass forming fine-grained material as in the invention reported by Pfeifer & Shen in US2006/0251535 A1. In their work, fine grained material (which could be submicron or nanoparticles of plastic, metals or ceramics) is coated with organic or organo-metallic polymeric compounds. In the case of metallic powders, fine-grained material is preferably formed by Cu, Sn, Zn, Al, Bi, Fe and/or Pb. The activation of the adhesive could take place by laser irradiation which is made to sinter, or at least partially melt it in order to form bridges between adjacent powder particles. If the thermal treatment is performed below the glass-forming or sintering temperature of the powder material, virtually no sintering shrinkage of the complete body or green compact occurs. A green component is also obtained in other types of 3d-printing technologies as in the work of Walter Lengauer in DE102013004182, where a printing composition was presented for direct fused deposition modelling (FDM) process. The printing composition consists of an organic binder component of one or more polymers and an inorganic powder component consisting of metals or ceramic materials. The green compact formed could be subsequently subjected to a sintering process for obtaining the final component. A limited resolution and size of the components is imposed in FDM processes, as well as in other 3d-printing variations, like direct metal fabrication. In this aspect, Canzona et al presented a method (US2005/0191200 A) of direct metal fabrication to form a metal part which has a relative density of at least 96%. The powder blend presented in that work comprised a parent metal alloy, a powdered lower-melting-temperature alloy, and two organic polymer binders (a thermoplastic and a thermosetting organic polymers). Their powder blend could be used in other powder-bed related methods, such as in selective laser sintering where a supersolidus liquid phase sintering is carried out. Like in the work presented by Bampton, the lower-melting-temperature alloy is made by introducing into the alloy a minor amount of boron or scandium as the eutectic forming element. The abovementioned inventions, though intended to improve the characteristics of metal components fabricated by AM technologies, have not been able to provide an economical method for metal 3d-printing, especially when large components are intended. Therefore, the present invention aims at providing an innovative method for the economical manufacturing of large components by AM and other shaping methods known in the state of the art.

### DESCRIPTION OF FIGURES

FIG. 1—Binary phase diagram of Al—Ga (Temperature vs. Ga composition)

FIG. 2—Binary phase diagram of Al—Mg (Temperature vs. Mg composition)

FIG. 3—Types of interstices in the packing of spheres. Octahedral holes are formed by six spheres. Tetrahedral holes are formed by four spheres.

FIG. 4—Types of coating for metallic particles

FIG. 5A is a schematic representation of a component with a thermoregulatory system comprising channels inside for cooling/heating.

FIG. 5B is a schematic representation of a component with a thermoregulatory system comprising channels inside and superficial channels for cooling/heating.

FIG. 6A—Cross section of a system with sub-superficial fluid channels, formation of drops.

FIG. 6B—Distribution of the tube outlets.

FIG. 6C—Mould part manufactured by additive manufacturing.

FIG. 7A. is a schematic representation of a component comprising fine channels.

FIG. 7B is an aerial view of a close to the surface cross-section of a component comprising fine channels.

FIG. 8A shows a B-pilar manufactured with conventional methods.

FIG. 8B shows a B-pilar manufactured with the method of the present invention.

FIG. 9—Die component or mould with large hollows and tubular conductions of fluids in hollow zones.

FIG. 10—Introduction into the mold made by AM of a polymerizable resin containing in suspension the particles of interest. Evacuation of the mold.

FIG. 11—Die component or mould with large hollows and tubular conductions of fluids in hollow zones. The active surface is shown.

### DESCRIPTION OF THE INVENTION

In an embodiment the present invention refers to new Fe, Ni, Co, Cu, W, Mo, Al and Ti alloys. In an embodiment these new alloys are used for the fast and economic manufacture of metallic components. The present invention is particularly suitable for building components in aluminum or aluminum alloys. In particular it is especially suitable for building components with the composition expressed above in weight percent.

In an embodiment refers to a aluminium based alloy with the following composition, all percentages in weight percent:

| | | | |
|---|---|---|---|
| % Si: 0-50 | | % Cu: 0-20; | % Mn: 0-20; |
| (commonly 0-20); | | | |
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-8; |
| % B: 0-5; | % Mg: 0-50 | | % Ni: 0-50; |
| | (commonly 0-20); | | |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5 | % O: 0-15 | | |

The rest consisting on aluminium and trace elements

The nominal composition expressed herein can refer to particles with higher volume fraction and/or the general final composition. In cases where the presence of immiscible particles as ceramic reinforcements, graphene, nanotubes or other these are not counted on the nominal composition.

In this context trace elements refers to several elements, unless context clearly indicates otherwise, including but not limited to, H, He, Xe, F, Ne, Na, P, S, Cl, Ar, K, Br, Kr, Sr, Tc, Ru, Rh, Pd, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the alloy such as reducing cost production of the alloy and/or its presence may be unintentional and related mostly to the presence of impurities in the alloying elements and scraps used for the production of the alloy.

There are several applications wherein the presence of trace elements is detrimental for the overall properties of the aluminium based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the aluminium based alloy.

There are applications wherein aluminium based alloys are benefited from having a high aluminium (% Al) content but not necessary the aluminium being the majority component of the alloy. In an embodiment % Al is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Al is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Al is not the majority element in the aluminium based alloy.

For certain applications, it is especially interesting to use alloys with % Ga, % Bi, % Rb, % Cd, % Cs, % Sn, % Pb, % Zn and/or % In. Particularly interesting is the use of these low melting point promoting elements with the presence of % Ga of more than 2.2%, preferably more than 12%, more preferably 21% or more and even 54% or more. The aluminum alloy has in an embodiment % Ga in the alloy is above 32 ppm, in other embodiment above 0.0001%, in another embodiment above 0.015%, and even in other embodiment above 0.1%, in another embodiment generally has a 0.8% or more of the element (in this case % Ga), preferably 2.2% or more, more preferably 5.2% or more and even 12% or more. But there are other applications depending of the desired properties of the aluminium based alloy wherein % Ga contents of 30% or less are desired. In an embodiment the % Ga in the aluminium based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the aluminium based alloylt has been found that in some applications the % Ga can be replaced wholly or partially by Bi % (until % Bi maximum content of 20% by weight, in case % Ga being greater than 20%, the replacement with % Bi will be partial) with the amounts described in this paragraph for % Ga+% Bi. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % In with the amounts described above in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the items in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

The case of scandium (Sc) is exemplifying, because using them very interesting mechanical properties may be reached, but its cost makes interesting from an economic point of view to use the amount needed for the application of interest. Its high deoxidizing power is also interesting during alloys processing but also a challenge to maximize performance. So depending on the application you can move from situations wherein is not a desired element, in these applications it is preferred % Sc being in a low concentration, in an embodiment less than 0.9%, in other embodiment less than 0.6%, in other embodiment less than 0.3%, in other embodiment less than 0.1%, in other embodiment less than 0.01% and even in other embodiment absent from the aluminium based alloy, to a situations wherein a high content of this element is desired, in an embodiment 0.6% by weight or more, in another embodiment preferably 1.1% by weight or more, in another embodiment more preferably 1.6% by weight or more and even in another embodiment 4.2% or more.

It has been found that for some applications aluminum alloys the presence of silicon (% Si) is desirable, typically in an embodiment in contents of 0.2% by weight or higher, in another embodiment preferably 1.2% or more, in another embodiment preferably 2.1% or more, in another embodiment more preferably 6% or more or even in another embodiment 11% or more. In contrast, in some applications the presence of this element is rather detrimental in which case contents of less than 0.2% by weight are desired, preferably less than 0.08%, more preferably less than 0.02% and even less than 0.004%. Obviously there are cases where the desired nominal content is 0% or nominal absence of the element as with all elements for certain applications. For other applications in an embodiment contents of less than 39.8% by weight are desired, in another embodiment contents of less than 23.6% by weight are desired, in another embodiment contents of less than 14.4% by weight are desired, in another embodiment contents of less than 9.7% by weight are desired, in another embodiment contents of less than 4.2% by weight are desired, in another embodiment contents of less than 3.4% by weight are desired, and even in another embodiment contents of less than 1.4% by weight are desired.

It has been found that for some applications of aluminum alloys the presence of iron (% Fe) is desirable, in an embodiment typically in contents of 0.3% by weight or higher, in another embodiment preferably 0.6% or more, in another embodiment more preferably 1.2% or more or even in another embodiment 6% or more. In contrast, in some applications the presence of this element is rather detrimental, in those cases in an embodiment contents of less than 19.8% by weight are desired, in another embodiment contents of less than 13.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, in another embodiment contents of less than 0.2% by weight are desired, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of copper (% Cu) is desirable, typically in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of manganese (% Mn) is desirable, typically in an embodiment in content of 0.1% by weight or higher, in another embodiment preferably 0.6% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of magnesium (% Mg) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 34.8% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications. If magnesium is used mainly as destroying the alumina film on aluminum particles or aluminum alloy (sometimes it is introduced as a separate powder magnesium or magnesium alloy and also sometimes alloyed directly to the aluminum particles or alloy aluminum and also sometimes other particles such as particles of low melting) the final content of % Mg can be quite small, in these applications often greater than 0.001% content, preferably greater than 0.02% is desired, more preferably greater than 0.12% and even 3.6% above.

It has been found that for some applications in aluminum alloys the presence of nitrogen (% N) is desirable, typically in contents of 0.2% by weight or higher, preferably 1.2% or more, more preferably 3.2% or more or even 6.2% or more. For some applications it is interesting that the consolidation and/or densification of the particles with aluminum is carried out in atmosphere with high nitrogen content thus often reaction occurs particularly if consolidation and/or densification (eg sintering with or without liquid phase) occurs at elevated temperatures, the nitrogen will react with the aluminum and/or other elements forming nitrides and thus will appear as an element in the final composition. In these cases it is often useful to have in the final composition a nitrogen content of 0.002% or higher, preferably 0.02% or higher, more preferably 0.4% or higher and even 2.2% or higher.

The preceding two paragraphs also apply to alloys of other basic elements as described in future paragraphs (Ti, Fe, Ni, Mo, W, Li, Co, . . . ) when an aluminum alloy or aluminum is used as a low-melting point element. For some applications indications shown in the preceding two paragraphs refers to the particles of aluminum alloy or aluminum alone, for some other applications indications shown in the preceding two paragraphs it refers to the final composition but the values of percentage by weight have to be corrected by the weight fraction of aluminum particles or aluminum alloy with respect to total particles. This applies, for some applications, when used as low melting point particle any other type of particle that oxidizes rapidly in contact with air, such as magnesium alloys and magnesium, etc.

It has been found that for some applications of aluminum alloys the presence of Sn (% Sn) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of zinc (% Zn) is desirable, typically in an embodiment in content of 0.1% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of chromium (% Cr) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of titanium (% Ti) is desirable, typically in an embodiment in content of 0.05% by weight or higher, in another embodiment preferably 0.2% or more, in another embodiment more preferably 1.2% or more or even in another embodiment 4% or more. In contrast, in some applications the presence of this element is rather detrimental, in those cases in an embodiment contents of less than 23.8% by weight are desired, in another embodiment contents of less than 17.4% by weight are desired, in another embodiment contents of less than 13.6% by weight are desired, in another embodiment contents of less than 9.2% by weight are desired, in another embodiment contents of less than 4.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of zirconium (% Zr) is desirable, typically in an embodiment in content of 0.05% by weight or higher, in another embodiment preferably 0.2% or more, in another embodiment more preferably 1.2% or more or even in another embodiment 4% or more. In contrast, in some applications the presence of this element is rather detrimental, in those cases in an embodiment contents of less than 9.2% by weight are desired, in another embodiment contents of less than 7.1% by weight are desired, in another embodiment contents of less than 4.8% by weight are desired, in another embodiment contents of less than 3.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of aluminum alloys the presence of Boron (% B) is desirable, typically in an embodiment in content of 0.05% by weight or higher, in another embodiment preferably 0.2% or more, in another embodiment more preferably 0.42% or more or even in another embodiment 1.2% or more. In contrast, in some applications the presence of this element is rather detrimental, in those cases in an embodiment contents of less than 4.8% by weight are desired, in another embodiment contents of less than 3.3% by weight are desired, in another embodiment contents of less than 1.8% by weight are desired, are desired in an embodiment contents of less than 0.08% by weight, in another embodiment preferably less than 0.02%, in another embodiment more preferably less than 0.004% and even in another embodiment less than 0.0002%. Obviously there are cases where the desired nominal content is 0% or nominal absence of the element as occurs with all elements for certain applications.

It has been found that for some applications, the excessive presence of molybdenum (% Mo) and/or tungsten (% W) may be detrimental, for these applications a lower % Mo+1/2% W content is desirable, in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the aluminium based alloy. In contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, excessive presence of nickel (% Ni) may be detrimental, for these applications is desirable a % Ni content in an embodiment of less than 28%, in other embodiment preferably less than 19.8%, in other embodiment preferably less than 18%, in other embodiment preferably less than 14.8%, in other embodiment preferably less than 11.6%, in other embodiment more preferably less than 8%, and even in other embodiment less than 0.8% There are even some applications for a given application wherein in an embodiment % Ni is detrimental or not optimal for one reason or another, in these applications it is preferred % Ni being absent from the aluminium based alloy. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight in another embodiment amounts higher than 1.2% by weight are desired, in other embodiment higher than 2.2% by weight, in other embodiment preferably higher than 6% by weight, in other embodiment preferably higher than 8.3% by weight in other embodiment more preferably higher than 12%, in other embodiment more preferably higher than 16.2% and even in other embodiment higher than 22%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 7.4%, in other embodiment less than 4.1%, in other embodiment less than 2.6%, in other embodiment less than 1.3%. In an embodiment % As is detrimental or not optimal for one reason or another, in these applications it is preferred % As being absent from the aluminium based alloy.

There are applications wherein the presence of % Li in higher amounts is desirable for these applications in an embodiment is desirable % Li amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Li may be detrimental, for these applications is desirable % Li amount in an embodiment less than 7.4%, in other embodiment less than 4.1%, in other embodiment less than 2.6%, in other embodiment less than 1.3%. In an embodiment % Li is detrimental or not optimal for one reason or another, in these applications it is preferred % Li being absent from the aluminium based alloy.

There are applications wherein the presence of % V in higher amounts is desirable for these applications in an embodiment is desirable % V amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % V may be detrimental, for these applications is desirable % V amount in an embodiment less than 7.4%, in other embodiment less than 4.1%, in other embodiment less than 2.6%, in other embodiment less than 1.3%. In an embodiment % V is detrimental or not optimal for one reason or another, in these applications it is preferred % V being absent from the aluminium based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 7.4%, in other embodiment less than 4.1%, in other embodiment less than 2.6%, in other embodiment less than 1.3%. In an embodiment % Te is detrimental or not optimal for one reason or another, in these applications it is preferred % Te being absent from the aluminium based alloy.

There are applications wherein the presence of % La in higher amounts is desirable for these applications in an embodiment is desirable % La amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % La may be detrimental, for these applications is desirable % La amount in an embodiment less than 7.4%, in other embodiment less than 4.1%, in other embodiment less than 2.6%, in other embodiment less than 1.3%. In an embodiment % La is detrimental or not optimal for one reason or another, in these applications it is preferred % La being absent from the aluminium based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 7.4%, in other embodiment less than 4.1%, in other embodiment less than 2.6%, in other embodiment less than 1.3%. In an embodiment % Se is detrimental or not optimal for one reason or another, in these applications it is preferred % Se being absent from the aluminium based alloy.

It has been found that for some applications, the excessive presence of tantalum (% Ta) and/or niobium (% Nb) may be detrimental, for these applications is desirable % Ta+% Nb content in an embodiment of less than 14.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the aluminium based alloy. In contrast there are applications wherein higher amounts of % Ta and/or % Nb are desirable, especially % Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 7.4%, in other embodiment less than 4.1%, in other embodiment less than 2.6%, in other embodiment less than 1.3%. In an embodiment % Ca is detrimental or not optimal for one reason or another, in these applications it is preferred % Ca being absent from the aluminium based alloy.

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the aluminium based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, and even in another embodiment greater than 22%. There are other applications wherein it is desirable the % Co in an embodiment above 0.0001%, in other embodiment above 0.15%, in other embodiment above 0.9%, and even in other embodiment above 1.6%.

There are applications wherein the presence of % Hf in higher amounts is desirable for these applications in an embodiment is desirable % Hf amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Hf may be detrimental, for these applications is desirable % Hf amount in an embodiment less than 4.4%, in other embodiment less than 3.1%, in other embodiment less than 2.7%, in other embodiment less than 1.4%. In an embodiment % Hf is detrimental or not optimal for one reason or another, in these applications it is preferred % Hf being absent from the aluminium based alloy.

There are applications wherein the presence of Germanium (% Ge) is desired. In an embodiment, the % Ge is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Ge may be limited. In other embodiment the % Ge is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Ge is detrimental or not optimal for one reason or another, in these applications it is preferred % Ge being absent from the aluminium based alloy.

There are applications wherein the presence of antimony (% Sb) is desired. In an embodiment, the % Sb is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Sb may be limited. In other embodiment the % Sb is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Sb is detrimental or not optimal for one reason or another, in these applications it is preferred % Sb being absent from the aluminium based alloy.

There are applications wherein the presence of cerium (% Ce) is desired. In an embodiment, the % Ce is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Ce may be limited. In other embodiment the % Ce is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Ce is detrimental or not optimal for one reason or another, in these applications it is preferred % Ce being absent from the aluminium based alloy.

There are applications wherein the presence of beryllium (% Be) is desired. In an embodiment, the % Mo is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Be may be limited. In other embodiment the % Be is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Be is detrimental or not optimal for one reason or another, in these applications it is preferred % Be being absent from the aluminium based alloy.

The elements described in the preceding paragraphs may be desired separately or the combination of some of them or even all of them, as expected.

It has been seen that for some applications the excessive content of cesium, tantalum and thallium and can be detrimental, for these applications it is desirable the sum of % Cs+% Ta+% Tl less than 0.29, preferably less than 0.18%, more preferably less than 0.8%, and even less than 0.08% (without being mentioned, as in all instances in this document where amounts are mentioned as upper limits, 0% nominal content or nominal absence of the element, it is not only possible but is often desirable).

It has been seen that for some applications the excessive content of gold and silver can be detrimental, for these applications in an embodiment it is desirable the sum of % Au+% Ag less than 0.09%, in another embodiment preferably less than 0.04%, in another embodiment more preferably less than 0.008%, and even in another embodiment less than 0.002%.

It has been found that for some applications when high contents of % Ga and % Mg (both above 0.5%), it is often desirable to have hardening elements for solid solution, precipitation or hard second phase forming particles. In this sense, the sum % Mn+% Si+% Fe+% Cu+% Cr+% Zn+% V+% Ti+% Zr for these applications, in an embodiment is desirably greater than 0.002% by weight in another embodiment preferably greater than 0.02%, in another embodiment more preferably greater than 0.3% and even in another embodiment higher than 1.2%.

It has been found that for some applications when % Ga content is lower than 0.1%, it is often desirable to have some limitation in hardening elements for solid solution, precipitation or hard second phase forming particles. In this sense, in an embodiment the sum % Cu+% Si+% Zn is desirably less than 21% by weight for these applications, in another embodiment preferably less than 18%, in another embodiment more preferably less than 9% or even in another embodiment less than 3.8%.

It has been found that for some applications when content % Ga below 1% and there is significant presence of % Cr (between 3% and 5%), it is often desirable to have hardening elements for solid solution or precipitation or forming hard particles second stage. In this sense, the sum % Mg+% Cu in an embodiment is desirably higher than 0.52% by weight for these applications, in another embodiment preferably greater than 0.82%, more preferably greater than 1.2% and even higher than 3.2%. and/or the sum of % Ti+% Zr is desirable in another embodiment exceeds 0.012% by weight, preferably in another embodiment greater than 0055%, more preferably in another embodiment greater than 0.12% by weight and even in another embodiment higher than 0.55%.

It has been found that for some applications, especially those requiring a high mechanical strength, high resistance to high temperatures and/or high corrosion resistance, which can be very beneficial combination of gallium (% Ga) and scandium (% Sc). For these applications it is often desirable in an embodiment to have Sc contents above 0.12% wt %, preferably above 0.52%, more preferably greater than 0.82% and even 1.2% above. For these applications simultaneously is often desirable to have excess Ga 0.12% wt %, preferably above 0.52%, more preferably greater than 0.8%, more preferably greater than 2.2 more % and even higher 3.5%. For some of these applications is also interesting to further magnesium (Mg %), in another embodiment it is often desirable to have % Mg above 0.6% by weight, preferably greater than 1.2%, more preferably in another embodiment greater than 4.2% and even in another embodiment more than 6%. For some of these applications, especially improved resistance to corrosion is required, it is also interesting for the presence of zirconium (% Zr), in another embodiment often in excess of 0.06% weight amounts, preferably above in another embodiment 0.22%, more preferably in another embodiment above 0.52% and even in another embodiment greater than 1.2%. Obviously, like all other paragraphs herein any other element may be present in the amounts described in the preceding and coming paragraphs.

There are several elements such as Sr that are detrimental in specific applications especially for certain Si and/or Mg and/or Cu contents; For these applications in an embodiment with % Si between 9.3% and 11.8% and/or % Mg between 0.098% and 0.53%, % Sr is below 28.9 ppm, even in another embodiment with % Si between 9.3% and 11.8% and/or % Mg between 0.098% and 0.53%, Sr is absent from the composition. In another embodiment with % Si between 9.3% and 11.8% and/or % Mg between 0.098% and 0.53%, % Sr is above 303 ppm. In another embodiment with % Cu between 0.98% and 2.8% and/or % Mg between 0.098% and 3.16%, % Sr is below 48.9 ppm o even is absent composition. Even in another embodiment with % Cu between 0.98% and 2.8% and/or % Mg between 0.098% and 3.16%, % Sr is above 0.51%.

There are several applications wherein the presence of Na and Li in the composition is detrimental for the overall properties of the aluminium based alloy especially for certain Si and/or Ga and/or Mg contents. In an embodiment with % Si between 9.8% and 15.8% and/or % Mg above 0.157% and/or % Ga above 0.157%, % Na is below 29.7 ppm or even absent from the composition and/or % Li is below 29.7 ppm or even absent from the composition. Even in another embodiment with % Si between 9.8% and 15.8% and/or % Mg above 0.157% and/or % Ga above 0.157%, % Na is above 42 ppm and/or % Li is above 42 ppm.

It has been found that for some applications, certain contents of elements such as Hg may be detrimental especially for certain Ga contents. For these applications in an embodiment with % Ga between 0.0098% and 2.3%, % Hg is lower than 0.00098% or even Hg is absent from the composition. In another embodiment with % Ga between 0.0098% and 2.3%, % Hg is higher than 0.11%.

There are several elements such as Pb that are detrimental in specific applications especially for certain Si contents; For these applications in an embodiment with % Si between 0.98% and 12.3%, % Pb is below 2.8% or even absent from the composition. Even in another embodiment % Si between 0.98% and 12.3%, % Pb is above 15.3%.

It has been found that for some applications, certain contents of elements such as Co may be detrimental especially for certain Si and/or Mg contents. For these applications in an embodiment with % Si between 0.017% and 1.65% and/or % Mg between 0.24% and 6.65%, % Co is lower than 0.24% or even Co is absent from the composition. In another embodiment with % Si between 0.017% and 1.65% and/or % Mg between 0.24% and 6.65%, % Co is higher than 2.11%.

There are several elements such as Ag that are detrimental in specific applications especially for certain Si and/or Mg and/or Cu contents. In an embodiment with % Si between 7.3% and 11.6% and/or % Mg between 0.47% and 0.73% and/or % Cu between 3.57% and 4.92%, % Ag is below 0.098% or even is absent from the composition. Even in another embodiment with % Si between 7.3% and 11.6% and/or % Mg between 0.47% and 0.73% and/or % Cu between 3.57% and 4.92%, % Ag is above 0.33%.

There are several elements such rare earth (RE) elements that are detrimental in specific applications especially for certain Si and/or Mg and/or Ga contents; For these applications in an embodiment with % Si between 3.97% and 15.6% and/or % Mg between 0.097% and 5.23%, % RE is below 0.097% or even RE are absent from the composition. Even in another embodiment % Si between 0.37% and 11.6% and/or % Mg between 0.37% and 11.23% and/or % Ga between 0.00085% and 0.87%, % RE is below 0.00087% or even RE are absent from the composition. In another embodiment % Si between 0.37% and 11.6% and/or % Mg between 0.37% and 11.23% and/or % Ga between 0.00085% and 0.87%, % RE is above 0.087%.

It has been found that for some applications, certain contents of elements such as Ga may be detrimental especially for certain Si contents. For these applications in an embodiment with % Si between 3.98% and 14.3%, % Ga is lower than 0.098%. Even in another embodiment with % Si between 3.98% and 14.3%, % Ga is above 2.33%.

It has been found that for some applications, certain contents of elements such as Sn may be detrimental especially for certain Si contents. For these applications in an embodiment with % Si between 3.98% and 14.3%, % Sn is lower than 0.098% or even is absent from the composition. Even in another embodiment with % Si between 3.98% and 14.3%, % Sn is above 2.33%.

There are several elements such as Pb, Sn, In, Sb and Bi that are detrimental in specific applications especially for certain Si and/or Mg and/or Cu and/or Fe and/or Ga contents. In an embodiment with presence of Si and/or Mg and/or Cu and/or Fe and/or Ga, elements such as Pb and/or Sn and/or In and/or Sb and/or Bi are absent from the composition.

There are several applications wherein the presence of Ce and Er in the composition is detrimental for the overall properties of the aluminium based alloy especially for certain Si and/or Mg contents. In an embodiment with % Si between 6.77% and 7.52% and/or % Mg between 0.246% and 0.356%, % Ce is below 0.017% or even absent from the composition and/or % Er is below 0.0098% or even absent from the composition. Even in another embodiment with % Si between 6.77% and 7.52% and/or % Mg between 0.246% and 0.356%, % Ce is above 0.047% and/or % Er is above 0.033%.

It has been found that for some applications, certain contents of elements such as Te may be detrimental especially for certain Si contents. For these applications in an embodiment with % Si between 7.87% and 12.7%, % Te is lower than 0.043% or even is absent from the composition. Even in another embodiment with % Si between 7.87% and 12.7%, % Te is above 3.33%.

It has been found that for some applications, certain contents of elements such as In and Zn may be detrimental especially for certain Fe contents. For these applications in an embodiment with % Fe between 0.48% and 3.33%, % In is lower than 0.0098% or even is absent from the composition and/or % Zn is lower than 1.09% or even is absent from the composition. Even in another embodiment with % Fe between 0.48% and 3.33%, % In is above 2.33% and/or % Zn is above 4.33%.

It has been found that for some applications, certain contents of elements such as Fe and Ni may be detrimental especially for certain Si and/or Mg and/or Fe contents. For these applications in an embodiment with % Si between 0.018% and 2.63% and/or % Mg between 0.58% and 2.33%, % Ni is lower 0.47% or higher than 3.53%. In another embodiment with % Si between 0.018% and 1.33% and/or % Mg between 2.58% and 10.33%, % Ni is lower 1.98% or higher than 6.03%. In another embodiment with % Si between 5.97% and 19.63% and/or % Mg between 0.18% and 6.33%, % Fe is lower 0.087% or higher than 1.73%. Even in another embodiment with % Si between 0.0087% and 2.73% and/or % Mg between 0.58% and 3.83%, % Fe is lower 0.0098% or higher than 2.93%. In another embodiment with % Fe between 0.27% and 3.63%, % Ni is lower 0.078% or higher than 3.93%.

There are some applications wherein the presence of compounds phase in the aluminium based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the aluminium based alloy. There are other applications wherein the presence of compounds in the aluminium based alloy is beneficial. In another embodiment the % of compound phase in the aluminium based alloy is above 0.0001%, in another embodiment is above 0.3%, in another embodiment is above 3%, in another embodiment is above 13%, in another is above 43% and even in another embodiment is above 73%.

For some applications it is desirable that the above alloys have a melting point below 890° C., preferably below 640° C. the, more preferably below 180° C. or even below 46° C.

Any of the above Al alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an aluminium alloy for manufacturing metallic or at least partially metallic components.

The present invention is particularly suitable for the manufacture of components that can benefit from the properties of certain light elements and alloys, especially Mg, Li, Cu, Zn, Sn. (Copper and tin are not considered light alloys by its density but given its diffusion capacity are considered in this group in the present invention). In this case all the above for aluminum alloys applies both in range level and all the comments made on all paragraphs that refer to the aluminum based alloys for special applications, regarding maximum levels and/or minimum desired and/or preferred of these elements. Given that the rest will no longer be Al and minor elements, but the element in question (Mg/Li/Cu/Zn/Sn) and minority elements to be treated equally in the case of % Al. The only thing that happens is that the % Al and the base element in question (Mg/Li/Cu/Zn/Sn) exchange their numerical values.

The present invention is particularly suitable for the manufacture of components that can benefit from the properties of nickel and its alloys. Especially applications requiring high mechanical resistance at high temperatures y/o aggressive environments. In this sense, applying certain rules of alloy design and thermo-mechanical treatments, it is possible obtain very interesting features for applications in chemical industry, energy transformation, transport, tools, other machines or mechanisms, etc.

In an embodiment the invention refers to a nickel based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-2 | % Mn = 0-3 |
| % Al = 0-15 | % Mo = 0-20 | % W = 0-25 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Re = 0-50 | % As = 0-5 |
| % Sb = 0-5 | % Ca = 0-5, | % P = 0-6 | % Ga = 0-30 |
| % Bi = 0-10 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |

The rest consisting on Nickel (Ni) and trace elements

wherein % Ceq=% C+0.86*% N+1.2*% B

There are applications wherein nickel based alloys are benefited from having a high nickel (% Ni) content but not necessary the nickel being the majority component of the alloy. In an embodiment % Ni is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Ni is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Ni is not the majority element in the nickel based alloy.

In this context trace elements refers to several elements, unless context clearly indicates otherwise, including but not limited to: H, He, Xe, Be, O, F, Ne, Na, Mg, Cl, Ar, K, Sc, Br, Kr, Sr, Tc, Ru, Rh, Ag, I, Xe, Ba, Pr, Nd, Pm, Sm, Eu, Gd, Tb, Dy, Ho, Er, Tm, Yb, Lu, Re, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the nickel based alloy in an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the nickel based alloy

There are other applications wherein the presence of trace elements may reduce the cost of the alloy or attain any other additional beneficial effect without affecting the nickel based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For several applications it is especially interesting the use of alloys containing % Ga % Bi, % Rb, % Cd, % Cs, % Sn, % Pb, % Zn and/or % In. Particularly interesting is the use of these low melting point promoting elements with the presence of more than 2.2% in weight of % Ga, preferably more than 12%, and even more than 21% or more. Once incorporated and evaluating the overall composition measured as indicated in this application, the nickel resulting alloy in an embodiment above 0.0001%, in another embodiment above 0.015%, in another embodiment above 0.03%, and even in other embodiment above 0.1%, in another embodiment has generally a 0.2% or more of the element (in this case % Ga), in another embodiment preferably 1.2% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. But there are other applications depending of the desired properties of the nickel based alloy wherein % Ga contents of 30% or less are desired. In an embodiment the % Ga in the nickel based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the nickel based alloy it has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+Bi %. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications in an embodiment is desirable a % Cr content of less than 39% by weight, in another embodiment preferably less than 18%, in another embodiment more preferably less than 8.8% by weight and even in another embodiment less than 1.8%. There are other applications wherein even a lower % Cr content is desired, in an embodiment the % Cr in the nickel based alloy is less than 1.6%, in other embodiment less than 1.2%, in other embodiment less than 0.8%, in other embodiment less than 0.4%. There are even some applications for a given application wherein in an embodiment % Cr is detrimental or not optimal for one reason or another, in these applications it is preferred % Cr being absent from the nickel based alloy. By contrast there are applications wherein the presence of chromium at higher levels is desirable, especially when a high corrosion resistance and/or resistance to oxidation at high temperatures is required for these applications; for these applications in an embodiment amounts exceeding 2.2% by weight are desirable, in another embodiment preferably above 3.6%, in another embodiment preferably greater than 5.5% by weight, more preferably above 6.1%, more preferably above 8.9%, more preferably above 10.1%, more preferably above 13.8%, more preferably above 16.1%, more preferably above 18.9%, in another embodiment more preferably over 22%, more preferably above 26.4%, and even in another embodiment greater than 32%. But there are also other applications wherein a lower preferred minimum content is desired. In an embodiment, the % Cr in the nickel based alloy is above 0.0001%, in other embodiment above 0.045%, n other embodiment above 0.1%, in other embodiment above 0.8%, and even in other embodiment above 1.3%. There are other applications wherein a high content of % Cr is desired. In another embodiment of the invention the % Cr in the alloy is above 42.2%, and even above 46.1%.

It has been seen that for some applications the presence of excessive aluminum (% Al) can be detrimental, for these applications is desirable in an embodiment a % Al content of less than 12.9%, in another embodiment preferably less than 10.4%, in another embodiment preferably less than 8.4%, in another embodiment less than 7.8% by weight, in another embodiment preferably less than 6.1%, in another embodiment preferably less than 4.8%, preferably less than 3.4%, preferably less than 2.7%, in another embodiment more preferably less than 1.8% by weight and even in another embodiment less than 0.8%. There are even some applications for a given application wherein in an embodiment % Al is detrimental or not optimal for one reason or another, in these applications it is preferred % Al being absent from the molybdenum based alloy. In contrast there are applications wherein the presence of aluminum at higher levels is desirable, especially when a high hardening and/or environmental resistance are required, for these applications in an embodiment are desirable amounts, in another embodiment greater than 1.2% by weight, in another embodiment preferably greater than 2.4% preferably greater than 3.2% by weight, in another embodiment preferably greater than 4.8%, in another embodiment preferably greater than 6.1%, in another embodiment preferably greater than 7.3%, in another embodiment more preferably above 8.2% and even in another embodiment above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the molybdenum based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, in another embodiment more preferably greater than 22% and even in another embodiment greater than 32%. There are other applications wherein it is desirable the % Co in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 1.4% by weight, in another embodiment preferably less than 1.1%, in another embodiment preferably less than 0.8%, in another embodiment more preferably less than 0.46% by weight and even in another embodiment less than 0.08%. There are even some applications for a given application wherein in an embodiment % Ceq is detrimental or not optimal for one reason or another, in these applications it is preferred % Ceq being absent from the nickel based alloy. In contrast there are applications wherein the presence of carbon equivalent in higher amounts is desirable for these applications in an embodiment amounts exceeding 0.12% by weight are desirable, in another embodiment preferably greater than 0.52% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 0.38% by weight, in another embodiment preferably less than 0.26%, in another embodiment preferably less than 0.18%, in another embodiment more preferably less than 0.09% by weight and even in another embodiment less than 0.009%. There are even some applications for a given application wherein in an embodiment % C is detrimental or not optimal for one reason or another, in these applications it is preferred % C being absent from the nickel based alloy. In contrast there are applications where the presence of carbon at higher levels is desirable, especially when an increase on mechanical strength and/or hardness is desired. For these applications in an embodiment amounts exceeding 0.02% by weight are desirable, preferably in another embodiment greater than 0.12% by weight, in another embodiment more preferably greater than 0.22% and even in another embodiment greater than 0.32%.

It has been found that for some applications, the excessive presence of boron (% B) may be detrimental, for these applications in an embodiment is desirable a % B content of less than 0.9% by weight, in another embodiment preferably less than 0.65%, in another embodiment preferably less than 0.4%, in another embodiment more preferably less than 0.16% by weight and even in another embodiment less than 0.006%. There are even some applications for a given application wherein in an embodiment % B is detrimental or not optimal for one reason or another, in these applications it is preferred % B being absent from the nickel based alloy in contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.4%, in another embodiment more preferably less than 0.16% by weight and even in another embodiment less than 0.006%. There are even some applications for a given application wherein in an embodiment % N is detrimental or not optimal for one reason or another, in these applications in an embodiment it is preferred % N being absent from the nickel based alloy in contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.1%, and even in another embodiment preferably above 0.35%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of zirconium (% Zr) and/or hafnium (% Hf) may be detrimental, for these applications in an embodiment is desirable a content of % Zr+% Hf of less than 12.4% by weight, in another embodiment less than 9.8%, in another embodiment less than 7.8% by weight, I in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Zr and/or % Hf are detrimental or not optimal for one reason or another, in these applications in an embodiment it is preferred % Zr and/or % Hf being absent from the nickel based alloy in contrast there are applications where the presence of some of these elements at higher levels is desirable, especially where a high hardening and/or environmental resistance is required, for these applications in an embodiment amounts of % Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 12%.

It has been found that for some applications, the excessive presence of molybdenum (% Mo) and/or tungsten (% W) may be detrimental, for these applications a lower % Mo+½% W content is desirable in an embodimentless than 14% by weight, in another embodiment preferably less than 9%, in another embodiment more preferably less than 4.8% by weight and even in another embodiment below 1.8%. There are even some applications for a given application wherein in an embodiment % Mo and/or % W is/are detrimental or not optimal for one reason or another, in these applications in an embodiment it is preferred % Mo and/or W being absent from the nickel based alloy in contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, the excessive presence of rhenium (% Re) may be detrimental, for these applications is desirable % Re content less than 41.8% by weight, preferably less than 24.8%, more preferably less than 11.78% by weight and even less than 1.45%. In contrast there are applications wherein the presence of rhenium in higher amounts is desirable for these applications are desirable amounts exceeding 0.6% by weight, preferably greater than 1.2% by weight, more preferably greater than 13.2%, even above 22.2%. There are even applications wherein in an embodiment % Re is detrimental or not optimal for one reason or another, in these applications it is preferred % Re being absent from the alloy.

It has been found that for some applications, the excessive presence of Vanadium (% V) may be detrimental, for these applications in an embodiment is desirable % V content less than 6.3%, in another embodiment less than 4.8% by weight, in another embodiment less than 3.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the nickel based alloy in contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 1.2% by weight, in another embodiment more preferably greater than 2.2% and even in another embodiment above 4.2%.

It has been that for some applications, excessive presence of copper (% Cu) may be detrimental, for these applications in an embodiment is desirable % Cu content of less than 14% by weight, in another embodiment preferably less than 12.7%, in another embodiment preferably less than 9%, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the nickel based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 2.55% by weight, in another embodiment greater than 3.6% by weight, in another embodiment greater than 4.7% by weight, in another embodiment greater than 6% by weight are desirable, in another embodiment preferably greater than 8% by weight, in another embodiment more preferably above 12% and even in another embodiment exceeding 16%.

It has been that for some applications the presence of excessive iron (% Fe) may be detrimental, for these applications in an embodiment is desirable % Fe content of less than 58% by weight, in another embodiment preferably less than 36%, in another embodiment preferably less than 24%, preferably less than 18%, in another embodiment more preferably less than 12% by weight, in another embodiment more preferably less than 10.3% by weight, and even in another embodiment less than 7.5%, even in another embodiment less than 5.9%, in another embodiment less than 3.7%, in another embodiment less than 2.1%, or even in another embodiment less than 1.3%. There are even some applications for a given application wherein % Fe is detrimental or not optimal for one reason or another, in these applications in an embodiment it is preferred % Fe being absent from the nickel based alloy. In contrast there are applications where the presence of iron at higher levels is desirable, for these applications are desirable amounts in an embodiment greater than 0.1% by weigh, in another embodiment greater than 1.3% by weight, g in another embodiment greater than 2.7% by weight, in another embodiment greater than 4.1% by weight, in another embodiment greater than 6% by weight, in another embodiment preferably greater than 8% by weight, in another embodiment more preferably greater than 22% and even in another embodiment greater than 42%.

It has been found that for some applications, the excessive presence of titanium (% Ti) may be detrimental, for these applications is desirable % Ti content in an embodiment of less than 9% by weight, in another embodiment preferably less than 7.6%, in another embodiment preferably less than 6.1%, in another embodiment preferably less than 4.5%, in another embodiment preferably less than 3.3%, in another embodiment more preferably less than 2.9% by weight, in another embodiment more preferably less than 1.8, and even in another embodiment less than 0.9%. There are even some applications for a given application wherein % Ti is detrimental or not optimal for one reason or another, in these applications in an embodiment it is preferred % Ti being absent from the nickel based alloy. In contrast there are applications where the presence of titanium in higher amounts is desirable, especially when an increase on mechanical properties at high temperatures are desired. For these applications are desirable amounts in an embodiment greater than 0.01%, in another embodiment greater than 0.2%, in another embodiment greater than 0.7%, in another embodiment greater than 1.2% by weight, in another embodiment preferably greater than 3.2% by weight, in another embodiment preferably greater than 4.1% by weight, in another embodiment more preferably above 6% or even in another embodiment above 12%.

It has been found that for some applications, the excessive presence of tantalum (% Ta) and/or niobium (% Nb) may be detrimental, for these applications is desirable % Ta+% Nb content in an embodiment of less than 17.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the nickel based alloy in contrast there are applications wherein higher amounts of % Ta and/or % Nb are desirable, especially Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

It has been found that for some applications, the excessive presence of yttrium (% Y), cerium (% Ce) and/or lanthanide (% La) may be detrimental, for these applications is desirable % Y+% Ce+% La content in an embodiment of less than 12.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Y and/or % Ce and/or % La are detrimental or not optimal for one reason or another, in these applications in an embodiment it is preferred % Y and/or % Ce and/or % La being absent from the nickel based alloy. In contrast there are applications wherein higher amounts are desirable, especially when a high hardness is desired, for these applications in an embodiment is desired an amount of % Y+% Ce+% La greater than 0.1% by weight, in another embodiment preferably greater than 1.2% by weight, in another embodiment preferably greater than 2.1% by weight, in another embodiment more preferably above 6% or even in another embodiment above 12%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the nickel based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the nickel based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the nickel based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the nickel based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the nickel based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the nickel based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % Sb being absent from the nickel based alloy.

There are applications wherein the presence of % Si in higher amounts is desirable, especially when an increase on strength and/or resistance to oxidation is desired. For these applications in an embodiment is desirable % Si amount above 0.0001%, in other embodiment above 0.15%, in other embodiment above 0.9%, and even in other embodiment above 1.3%. In contrast it has been found that for some applications, the excessive presence of % Si may be detrimental, for these applications is desirable % Si amount in an embodiment less than 1.4%, in other embodiment less than 0.8%, in other embodiment less than 0.4%, in other embodiment less than 0.2%. In an embodiment % Si is detrimental or not optimal for one reason or another, in these applications it is preferred % Si being absent from the nickel based alloy.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.0001%, in other embodiment above 0.15%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%. In an embodiment % Mn is detrimental or not optimal for one reason or another, in these applications it is preferred % Mn being absent from the nickel based alloy.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the nickel based alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder magnesium or magnesium alloy and also sometimes alloyed directly to the aluminum particles or alloy aluminum and also sometimes other particles such as low melting particles) the final content of % Mg can be quite small, in these applications often greater than 0.001% content, preferably greater than 0.02% is desired, more preferably greater than 0.12% and even 3.6% above.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are some applications wherein the presence of compounds phase in the nickel based alloy is detrimental. In an embodiment the % of compound phase in the alloy is below 79%, in another embodiment is below 49%, in another embodiment is below 19%, in another embodiment is below 9%, in another embodiment is below 0.9% and even in another embodiment compounds are absent from the composition. There are other applications wherein the presence of compounds in the nickel based alloy is beneficial. In another embodiment % of compound phase in the alloy is above 0.0001%, in another embodiment is above 0.3%, in another embodiment is above 3%, in another embodiment is above 13%, in another embodiment is above 43% and even in another embodiment the is above 73%.

For several applications it is especially interesting the use of nickel based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Nickel based alloy is used as a coating layer. In an embodiment the nickel based alloy is used as a coating layer with thickness above 1.1 micrometer, in another embodiment the nickel based alloy is used as a coating layer with thickness above 21 micrometer, in another embodiment the nickel based alloy is used as a coating layer with thickness above 10 micrometre, in another embodiment the nickel based alloy is used as a coating layer with thickness above 510 micrometre, in another embodiment the nickel based alloy is used as a coating layer with thickness above 1.1 mm and even in another embodiment the nickel based alloy is used as a coating layer with thickness above 11 mm. In another embodiment the nickel based alloy is used as a coating layer with thickness below 27 mm, in another embodiment the nickel based alloy is used as a coating layer with thickness below 17 mm, in another embodiment the nickel based alloy is used as a coating layer with thickness below 7.7 mm, in another embodiment the nickel based alloy is used as a coating layer with thickness below 537 micrometer, in another embodiment the nickel based alloy is used as a coating layer with thickness below 117 micrometre, in another embodiment the nickel based alloy is used as a coating layer with thickness below 27 micrometre and even in another embodiment the nickel based alloy is used as a coating layer with thickness below 7.7 micrometre.

For several applications it is especially interesting the use of nickel based alloy having a high mechanical resistance. For those applications in an embodiment the resultant mechanical resistance of the nickel based alloy is above 52 MPa, in another embodiment the resultant mechanical resistance of the alloy is above 72 MPa, in another embodiment the resultant mechanical resistance of the alloy is above 82 MPa, in another embodiment the resultant mechanical resistance of the alloy is above 102 MPa, in another embodiment the resultant mechanical resistance of the alloy is above 112 MPa and even in another embodiment the resultant mechanical resistance of the alloy is above 122 MPa. In another embodiment the resultant mechanical resistance of the alloy is below 147 MPa, in another embodiment the resultant mechanical resistance of the alloy is below 127 MPa, in another embodiment the resultant mechanical resistance of the alloy is below 117 MPa, in another embodiment the resultant mechanical resistance of the alloy is below 107 MPa, in another embodiment the resultant mechanical resistance of the alloy is below 87 MPa, in another embodiment the resultant mechanical resistance of the alloy is below 77 MPa and even in another embodiment the resultant mechanical resistance of the alloy is below 57 MPa.

There are several technologies that are useful to deposit the nickel based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the nickel based alloy being in powder form. In an embodiment the nickel based alloy is manufactured in form of powder. In another embodiment the powder is spherical. In an embodiment refers to a spherical powder with a particle size distribution which may be unimodal, bimodal, trimodal and even multimodal depending of the specific application requirements.

The nickel based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

For some applications it is desirable that the above alloys have a melting point below 890° C., preferably below 640° C., more preferably below 180° C. or even below 46° C.

There are several elements such as Cr, Fe and V that are detrimental in specific applications especially for certain Ga contents; For these applications in an embodiment with % Ga between 5.2% and 13.8%, the total content of Cr and/or V is below 17%, even in another embodiment with % Ga between 5.2% and 13.8%, the total content of Cr and/or V is above 25%. In another embodiment with % Ga between 18 at. % and 34 at. %, % Fe is below 14 at. %. Even in another embodiment with % Ga between 18 at. % and 34 at. %, % Fe is above 47 at. %.

There are several applications wherein the presence of Mo, Fe, Y, Ce, Mn and Re in the composition is detrimental for the overall properties of the nickel based alloy especially for certain Cr and/or Ga contents. In an embodiment with % Cr between 11% and 17% and/or % Ga between 4% and 9%, % Mo is below 4% or even absent from the composition and/or % Fe is below 2.3% or even absent from the composition. Even in another embodiment with % Cr between 11% and 17% and/or % Ga between 4% and 9%, % Mo is above 8.7% and/or % Fe is above 11.6%. In another embodiment with % Cr between 5.2% and 15.7% and/or % Ga between 3.6% and 7.2%, % Y is below 0.1% or even absent from the composition and/or % Ce is below 0.03% or even absent from the composition. In another embodiment with % Cr between 5.2% and 15.7% and/or % Ga between 3.6% and 7.2%, % Y is above 0.74% and/or % Ce is above 0.33%. In another embodiment with % Cr between 9.7% and 23.7% and/or % Ga between 0.6% and 8.2%, % Mn is below 0.36% or even absent from the composition. In another embodiment with % Cr between 9.7% and 23.7% and/or % Ga between 0.6% and 8.2%, % Mn is above 2.6%. In another embodiment with % Cr between 6.2% and 8.7% and/or % Ga between 6.2% and 8.7%, % Mo is below 0.6% or even absent from the composition and/or % Re is below 2.03% or even absent from the composition. In another embodiment with % Cr between 6.2% and 8.7% and/or % Ga between 6.2% and 8.7%, % Mo is above 2.74% and/or % Re is above 4.33%.

It has been found that for some applications, certain contents of elements such as Sc, Al, Ge, Y, W, Si, Pd and rare earth elements (RE) may be detrimental especially for certain Cr contents. For these applications in an embodiment with % Cr between 11.1% and 16.6%, the total content of % Sc and/or % RE is lower than 0.087% or even in another embodiment Sc and RE are absent from the composition. In another embodiment with % Cr between 11.1% and 16.6%, the total content of % Sc and/or % RE is lower than 0.87%. In another embodiment with % Cr between 17.1% and 26.1%, % Al is below 4.3% or even absent from the composition. In another embodiment with % Cr between 17.1% and 26.1%, % Al is above 11.3%. In another embodiment with presence of Cr, Pd is preferred to be absent from the composition. In another embodiment with % Cr between 9 at. % and 51 at. %, the total content of Al and/or Si is below 4 at. %. In another embodiment with % Cr between 9 at. % and 51 at. %, the total content of Al and/or Si is above 26 at. %. In another embodiment with % Cr between 9% and 23%, % Al is below 0.87% or even absent from the composition and/or % Si is below 0.37% or even absent from the composition. In another embodiment with % Cr between 9% and 23%, % Al is above 6.87% and/or % Si is above 3.37%. In another embodiment with % Cr between 6.8% and 22.3%, % Ge is below 0.37% or even absent from the composition. In another embodiment with % Cr between 14.1% and 32.1%, % Y is below 0.3% or even absent from the composition. In another embodiment with % Cr between 14.1% and 32.1%, % Y is above 1.37%. Even in another embodiment with % Cr between 0.087% and 8.1%, % W is below 3.3% or even absent from the composition. In another embodiment with % Cr between 0.087% and 8.1%, % W is above 11.3%.

There are several applications wherein the presence of Ca, In, Y, and rare earth elements (RE) in the composition is detrimental for the overall properties of the nickel based alloy. For these applications in an embodiment % Ca and/or % RE are absent from the composition. In another embodiment, % Y is below 0.0087 at. % or even absent from the composition. In another embodiment % Y is above 0.37 at. %. Even in another embodiment, % In is lower than 0.8% or even In is absent from the composition.

There are several elements such as In, Sn and Sb that are detrimental in specific applications especially for certain Co and Fe contents; For these applications in an embodiment with % Co and/or % Fe between 0.0087 at. % and 17.8 at. %, the total content of In and/or Sn and/or Sb is below 4.1 at. %. Even in another embodiment with % Co and/or % Fe between 0.0087 at. % and 17.8 at. %, the total content of In and/or Sn and/or Sb is above 19.2 at. %.

It has been found that for some applications, certain contents of elements such as Ta and Hf may be detrimental especially for certain Cr and Al contents. For these applications in an embodiment with % Cr between 1.1% and 16.6% and/or % Al between 2.1% and 7.6%, % Ta is below 0.87% or even absent from the composition and/or % Hf is below 0.13% or even absent from the composition. Even in another embodiment with Cr between 1.1% and 16.6% and/or % Al between 2.1% and 7.6%, % Hf is above 4.1%.

Any of the above-described nickel alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of any nickel alloy for manufacturing metallic or at least partially metallic components.

The present invention is particularly suitable for applications that can benefit from iron-based alloys with high mechanical resistance. There are many applications that can benefit from an alloy iron base with high mechanical strength, to name a few: structural elements (in the transport industry, construction, energy transformation . . . ), tools (molds, dies, . . . ), drives or elements mechanical, etc. Applying certain rules of alloy design and processing these iron base alloys high strength may be provided with high environmental resistance (resistance to oxidation, corrosion, . . . ). In particular it is especially suitable for building components with a composition expressed below.

In an embodiment the invention refers to an iron based alloy having the following composition, all percentages being in weight percent:

| | | | |
|---|---|---|---|
| % Ceq = 0.15-4.5 | % C = 0.15-2.5 | % N = 0-2 | % B = 0-3.7 |
| % Cr = 0.1-20 | % Ni = 3-30 | % Si = 0.001-6 | % Mn = 0.008-3 |
| % Al = 0.2-15 | % Mo = 0-10 | % W = 0-15 | % Ti = 0-8 |
| % Ta = 0-5 | % Zr = 0-12 | % Hf = 0-6, | % V = 0-12 |
| % Nb = 0-10 | % Cu = 0-10 | % Co = 0-20 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-20 |
| % Sn = 0-10 | % Rb = 0-10 | % Cd = 0-10 | % Cs = 0-10 |
| % La = 0-5 | % Pb = 0-10 | % Zn = 0-10 | % In = 0-10 |
| % Ge = 0-5 | % Y = 0-5 | % Ce = 0-5 | |

The rest consisting on iron (Fe) and trace elements

wherein % Ceq=% C+0.86*% N+1.2*% B

Characterized in that

% Cr+% V+% Mo+% W+% Ga>3 and

% Al+% Mo+% Ti+% Ga>1.5

With the proviso that:

when % Ceq=0.45-2.5, then % V=0.6-12; o

when % Ceq=0.15-0.45, then % V=0.85-4; o

when % Ceq=0.15-0.45, then % Ti+% Hf+% Zr+% Ta=0.1-4; or

% Ga=0.01-15;

There are applications wherein iron based alloys are benefited from having a high iron (% Fe) content but not necessary iron being the majority component of the alloy. In an embodiment % Fe is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Fe is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Fe is not the majority element in the iron based alloy.

In this context trace elements refers to several elements, unless context clearly indicates otherwise, including but not limited to: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the iron based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the iron based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For several applications especially when sinterization in liquid phase is desired or at least high mobility is interesting the use of alloys containing % Ga, % Bi, % Rb, % Cd, % Cs, % Sn, % Pb, % Zn and/or % In. Particularly interesting is the use of these low melting point promoting elements with the presence of more than 2.2% in weight of % Ga, preferably more than 12%, and even more than 15.3% or more. Once incorporated and evaluating the overall composition measured as indicated in this application, the iron resulting alloy in an embodiment % Ga in the alloy is above 0.0001%, in another embodiment above 0.015%, and even in other embodiment above 0.1%, in another embodiment has generally a 0.2% or more of the element (in this case % Ga), in another embodiment preferably 1.2% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. But there are other applications depending of the desired properties of the iron based alloy wherein % Ga contents of less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the iron based alloy. It has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+Bi %. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or In % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloyed with these elements directly and not be incorporated into separate particles.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of nickel (% Ni) may be detrimental, for these applications is desirable a % Ni content in an embodiment of less than 24%, in other embodiment preferably less than 19.8%, in other embodiment preferably less than 16%, in other embodiment preferably less than 14.8%, in other embodiment more preferably less than 12%, and even in other embodiment less than 7.5%. For several applications it will be desired also lower % Ni, in an embodiment % Ni is preferably less than 6.3%, and even in other embodiment less than 4.8. In contrast there are applications wherein the presence of nickel at higher levels is desirable, especially when an increase on ductility and toughness is desired, and/or and increase on strength and/or to improve weldability is required, for those applications in an embodiment amounts higher than 3.7% by weight, in other embodiment higher than 6% by weight, in other embodiment preferably higher than 8.3% by weight in other embodiment more preferably higher than 8%, in other embodiment more preferably higher than 16.2% and even in other embodiment higher than 16%.

There are applications wherein the presence of % Si in higher amounts is desirable, especially when an increase on strength and/or resistance to oxidation is desired. For these applications in an embodiment is desirable % Si amount above 0.01%, in other embodiment above 0.15%, in other embodiment above 0.9%, in other embodiment above 1.6%, in other embodiment above 2.6%, and even in other embodiment above 3.2%. In contrast it has been found that for some applications, the excessive presence of % Si may be detrimental, for these applications is desirable % Si amount in an embodiment less than 3.4%, in other embodiment less than 1.8%, in other embodiment less than 0.8%, in other embodiment less than 0.4%.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.01%, in other embodiment above 0.3%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%.

It has been found that for some applications, excessive presence of chromium (% Cr) may be detrimental, for these applications in an embodiment is desirable a % Cr content of less than 14% by weight, in another embodiment preferably less than 9.8%, in another embodiment more preferably less than 8.8% by weight and even in another embodiment less than 6%. There are other applications wherein even a lower % Cr content is desired, in an embodiment the % Cr in the iron based alloy is less than 4.6%, in other embodiment less than 3.2%, in other embodiment less than 2.7%, in other embodiment less than 1.9%. By contrast there are applications wherein the presence of chromium at higher levels is desirable, especially when a high corrosion resistance and/or resistance to oxidation at high temperatures is required for these applications; for these applications in an embodiment amounts exceeding 1.2% by weight are desirable, in another embodiment preferably above 2.6%, in another embodiment preferably greater than 5.5% by weight, in another embodiment preferably above 6.1%, in another embodiment more preferably over 7%, in another embodiment more preferably above 10.4%, and even in another embodiment greater than 16%.

It has been seen that for some applications the presence of excessive aluminum (% Al) can be detrimental, for these applications is desirable in an embodiment a % Al content of less than 12.9%, in another embodiment preferably less than 10.4%, in another embodiment preferably less than 8.4%, in another embodiment less than 7.8% by weight, in another embodiment preferably less than 6.1%, in another embodiment preferably less than 4.8%, preferably less than 3.4%, preferably less than 2.7%, in another embodiment more preferably less than 1.8% by weight and even in another embodiment less than 0.8%. In contrast there are applications wherein the presence of aluminum at higher levels is desirable, especially when a high hardening and/or environmental resistance are required, for these applications in an embodiment are desirable amounts, in another embodiment greater than 1.2% by weight, in another embodiment preferably greater than 2.4% preferably greater than 3.2% by weight, in another embodiment preferably greater than 4.8%, in another embodiment preferably greater than 6.1%, in another embodiment preferably greater than 7.3%, in another embodiment more preferably above 8.2% and even in another embodiment above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+% Zn+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of cobalt (% Co) may be detrimental, for these applications is desirable in an embodiment a % Co content of less than 9.8% by weight, in another embodiment preferably less than 6.4%, in another embodiment preferably less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Co is detrimental or not optimal for one reason or another, in these applications it is preferred % Co being absent from the iron based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 4%, in another embodiment preferably higher than 5.6%, in another embodiment preferably higher than 6.4%, in another embodiment more preferably greater than 8% and even in another embodiment greater than 12%. There are other applications wherein it is desirable the % Co in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 2.4% by weight, in another embodiment preferably less than 2.1%, in another embodiment preferably less than 1.95%, in another embodiment preferably less than 1.8%, in another embodiment more preferably less than 0.9% by weight and even in another embodiment less than 0.58%. In contrast there are applications wherein the presence of carbon equivalent in higher amounts is desirable for these applications in an embodiment amounts exceeding 0.27% by weight are desirable, in another embodiment preferably greater than 0.52% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 1.8% by weight, in another embodiment preferably less than 1.4%, in another embodiment preferably less than 0.9%, in another embodiment more preferably less than 0.58% by weight and even in another embodiment less than 0.44%. In contrast there are applications where the presence of carbon at higher levels is desirable, especially when an increase on mechanical strength and/or hardness is desired. For these applications in an embodiment amounts exceeding 0.27% by weight are desirable, preferably in another embodiment greater than 0.52% by weight, in another embodiment more preferably greater than 0.82% and even in another embodiment greater than 1.2%.

It has been found that for some applications, the excessive presence of boron (% B) may be detrimental, for these applications in an embodiment is desirable a % B content of less than 1.8% by weight, in another embodiment preferably less than 1.4%, in another embodiment preferably less than 0.9%, in another embodiment more preferably less than 0.06% by weight and even in another embodiment less than 0.006%. There are even some applications for a given application wherein in an embodiment % B is detrimental or not optimal for one reason or another, in these applications it is preferred % B being absent from the iron based alloy. In contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.4%, in another embodiment more preferably less than 0.16% by weight and even in another embodiment less than 0.006%. There are even some applications for a given application wherein in an embodiment % N is detrimental or not optimal for one reason or another, in these applications in an embodiment it is preferred % N being absent from the iron based alloy. In contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.1%, and even in another embodiment preferably above 0.35%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of titanium (% Ti), zirconium (% Zr) and/or hafnium (% Hf) may be detrimental, for these applications in an embodiment is desirable a content of % Ti+% Zr+% Hf of less than 12.4% by weight, in another embodiment less than 9.8%, in another embodiment less than 7.8% by weight, in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Ti and/or % Zr and/or % Hf are detrimental or not optimal for one reason or another, in these applications in an embodiment it is preferred % Ti and/or % Zr and/or % Hf being absent from the iron based alloy. In contrast there are applications where the presence of some of these elements at higher levels is desirable, especially where a high hardening and/or environmental resistance is required, for these applications in an embodiment amounts of % Ti+% Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 12%.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the iron based alloy. In contrast there are applications where the presence of molybdenum and tungsten at higher levels is desirable, for these applications in an embodiment amounts of % Mo+½% W exceeding 1.2% by weight are desirable, in another embodiment preferably greater than 3.2% by weight, in another embodiment more preferably greater than 5.2% and even in another embodiment above 12%.

It has been found that for some applications, the excessive presence of Vanadium (% V) may be detrimental, for these applications in an embodiment is desirable % V content less than 11.3%, in another embodiment less than 9.8% by weight, in another embodiment less than 6.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the iron based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 2.2% by weight, in another embodiment more preferably greater than 4.2% and even in another embodiment above 10.2%.

It has been found that for some applications, the excessive presence of tantalum (% Ta) and/or niobium (% Nb) may be detrimental, for these applications is desirable % Ta+% Nb content in an embodiment of less than 14.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the iron based alloy. In contrast there are applications wherein higher amounts of % Ta and/or % Nb are desirable, especially Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

It has been that for some applications, excessive presence of copper (% Cu) may be detrimental, for these applications in an embodiment is desirable % Cu content of less than 8.2% by weight, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the iron based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 3.6% by weight, in another embodiment greater than 6% by weight and even in another embodiment exceeding 7.6%.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the iron based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the iron based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the iron based alloy.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the iron based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the iron based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the iron based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % P being absent from the iron based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the iron based alloy.

There are applications wherein the presence of % Y in higher amounts is desirable for these applications in an embodiment is desirable % Y amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Y may be detrimental, for these applications is desirable % Y amount in an embodiment less than 4.9%, in other embodiment less than 3.4%, in other embodiment less than 2.8%, in other embodiment less than 1.4%. In an embodiment % Y is detrimental or not optimal for one reason or another, in these applications it is preferred % Y being absent from the iron based alloy.

There are applications wherein the presence of % Ce in higher amounts is desirable for these applications in an embodiment is desirable % Ce amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ce may be detrimental, for these applications is desirable % Ce amount in an embodiment less than 4.4%, in other embodiment less than 3.1%, in other embodiment less than 2.7%, in other embodiment less than 1.4%. In an embodiment % Ce is detrimental or not optimal for one reason or another, in these applications it is preferred % Ce being absent from the iron based alloy.

There are applications wherein the presence of % La in higher amounts is desirable for these applications in an embodiment is desirable % La amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % La may be detrimental, for these applications is desirable % La amount in an embodiment less than 4.4%, in other embodiment less than 3.1%, in other embodiment less than 2.7%, in other embodiment less than 1.4%. In an embodiment % La is detrimental or not optimal for one reason or another, in these applications it is preferred % La being absent from the iron based alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder magnesium or magnesium alloy and also sometimes alloyed directly to the aluminum particles or alloy aluminum and also sometimes other particles such as low melting particles) the final content of % Mg can be quite small, in these applications often greater than 0.001% content, preferably greater than 0.02% is desired, more preferably greater than 0.12% and even 3.6% above.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Sn that are detrimental in specific applications especially for certain Cr and/or C contents; For these applications in an embodiment with % Cr between 0.47% and 5.8% and/or C between 0.7% and 2.74%, % Sn is below 0.087% or even absent from the composition, even in another embodiment with % Cr between 0.47% and 5.8% and/or C between 0.7% and 2.74%, % Sn is above 0.92%.

There are several applications wherein the presence of Si and B in the composition is detrimental for the overall properties of the steel, especially for certain Cu and/or B contents. For these applications in an embodiment with % Cu between 0.097 atomic % (at. %) and 3.33 at. %, the total content of % B and/or % Si is below 4.77 at. %, in another embodiment with % Cu between 0.097 at. % and 3.33 at. %, the total content of % B and/or % Si is below 1.33 at. %, in another embodiment with % Cu between 0.097 at. % and 3.33 at. %, % B is below 2.4 at. % and/or % Si is below 5.77 at. %, in another embodiment with % Cu between 0.097 at. % and 3.33 at. %, % B is above 16.2 at. % and/or % Si is above 27.2 at. %. In another embodiment with % Cu between 0.097 at. % and 3.33 at. %, the total content of % B and % Si is above 31 at. %, in another embodiment with % Cu between 0.097 at. % and 3.33 at. %, the total content of % B and % Si is above 31 at. %. In another embodiment with % Cu between 0.3 at. % and 1.7 at. %, % B is below 4.2 at. % and/or % Si is below 8.77 at. %, in another embodiment with % Cu between 0.3 at. % and 1.7 at. %, % B is above 9.2 at. % and/or % Si is above 17.2 at. %. In another embodiment with % Cu between 0.097 at. % and 3.33 at. %, % B is below 9.77 at. %, in another embodiment with % Cu between 0.097 at. % and 3.33 at. %, % B is above 22.2 at. % even in another embodiment with % Cu between 0.097 at. % and 3.33 at. %, % B is above 32.2 at. %. In another embodiment with % Cu between 0.97 at. % and 3.33 at. %, % B is below 9.77 at. %, in another embodiment with % Cu between 0.97 at. % and 3.33 at. %, % B is above 22.2 at. %. In another embodiment with % B between 0.97 at. % and 33.33 at. %, the total content of % B and/or % Si is below 1.33 at. %, in another embodiment with % B between 0.97 at. % and 33.33 at. %, the total content of % B and/or % Si is above 33.33 at. %.

It has been found that for some applications, certain contents of elements such as Si and B may be detrimental especially for certain Al and Ga contents. For these applications in an embodiment with % Al between 1.87 at. % and 16.6 at. %, % B is lower than 3.87%. In another embodiment with % Al between 1.87 at. % and 16.6 at. %, % B is higher than 23.87%. Even in another embodiment with % Al between 1.87 at. % and 16.6 at. % and/or % Ga between 0.43 at. % and 5.2 at. %, % B is below 1.33 at. % and/or % Si is below 0.43 at. %. In another embodiment with % Al between 1.87 at. % and 16.6 at. % and/or % Ga between 0.43 at. % and 5.2 at. %, % B is above 11.33 at. % and/or % Si is above 5.43 at. %.

There are several elements such as Co that are detrimental in specific applications especially for certain Ni contents; For these applications in an embodiment with % Ni between 24.47% and 35.8%, % Co is lower than 12.6%. Even in another embodiment with % Ni between 24.47% and 35.8%, % Co is higher than 26.6%.

There are several elements such as rare earth elements (RE) that are detrimental in specific applications; For these applications in an embodiment RE are absent from the composition.

For some applications it is desirable that the above alloys have a melting point below 890° C., preferably below 640° C., more preferably below 180° C. or even below 46° C.

Any of the above Fe alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an iron alloy for manufacturing metallic or at least partially metallic components.

The present invention is very interesting for applications that benefit from the properties of tool steels. It is a further implementation of the present invention the production of resins capable of polymerizing radiation loaded with tool steel particles. In this sense they are considered particles of tool steels having the composition those described below, or those combined with other results in the composition described below in way to be interpreted herein.

In an embodiment the invention refers to an iron based alloy having the following composition, all percentages being in weight percent:

| | | | |
|---|---|---|---|
| % Ceq = 0.15-3.5 | % C = 0.15-3.5 | % N = 0-2 | % B = 0-2.7 |
| % Cr = 0-20 | % Ni = 0-15 | % Si = 0-6 | % Mn = 0-3 |
| % Al = 0-15 | % Mo = 0-10 | % W = 0-15 | % Ti = 0-8 |
| % Ta = 0-5 | % Zr = 0-6 | % Hf = 0-6, | % V = 0-12 |
| % Nb = 0-10 | % Cu = 0-10 | % Co = 0-20 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-20 |
| % Sn = 0-10 | % Rb = 0-10 | % Cd = 0-10 | % Cs = 0-10 |
| % La = 0-5 | % Pb = 0-10 | % Zn = 0-10 | % In = 0-10 |
| % Ge = 0-5 | % Y = 0-5 | % Ce = 0-5 | |

The rest consisting on iron (Fe) and trace elements

wherein

% Ceq=% C+0.86*% N+1.2*% B,

Characterized in that

% Cr+% V+% Mo+% W+% Nb+% Ta+% Zr+% Ti>3

There are applications wherein iron based alloys are benefited from having a high iron (% Fe) content but not necessary iron being the majority component of the alloy. In an embodiment % Fe is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Fe is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Fe is not the majority element in the iron based alloy.

In this context trace elements refers to several elements, unless context clearly indicates otherwise, including but not limited to: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the iron based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the iron based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For several applications especially when sinterization in liquid phase is desired or at least high mobility is interesting the use of alloys containing % Ga % Bi, % Rb, % Cd, % Cs, % Sn, % Pb, % Zn and/or % In. Particularly interesting is the use of these low melting point promoting elements with the presence of more than 2.2% in weight of % Ga, preferably more than 12% and even more than 14.2% or more. Once incorporated and evaluating the overall composition measured as indicated in this application, the iron resulting alloy in an embodiment % Ga in the alloy is above 0.0001%, in another embodiment above 0.015%, and even in other embodiment above 0.1%, in another embodiment has generally a 0.2% or more of the element (in this case % Ga), in another embodiment preferably 1.2% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. But there are other applications depending of the desired properties of the iron based alloy wherein % Ga contents of less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the iron based alloy. It has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+Bi %. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or In % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of nickel (% Ni) may be detrimental, for these applications is desirable a % Ni content in an embodiment of less than 8%, in other embodiment preferably less than 4.6%, in other embodiment preferably less than 2.8%, in other embodiment preferably less than 2.3%, in other embodiment more preferably less than 1.8%, and even in other embodiment less than 0.008%. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight, in other embodiment higher than 1.2% by weight, in other embodiment preferably higher than 1.6% by weight, in other embodiment preferably higher than 2.2%, in other embodiment more preferably higher than 5.2%, in other embodiment more preferably higher than 7.3% and even in other embodiment higher than 11%.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.01%, in other embodiment above 0.3%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2% and even absent in other embodiment.

It has been found that for some applications, excessive presence of chromium (% Cr) may be detrimental, for these applications in an embodiment is desirable a % Cr content of less than 14% by weight, in another embodiment preferably less than 3.8%, in another embodiment more preferably less than 0.8% by weight and even in another embodiment less than 0.08%. There are even some applications for a given application wherein in an embodiment % Cr is detrimental or not optimal for one reason or another, in these applications it is preferred % Cr being absent from the iron based alloy. In contrast there are applications wherein the presence of chromium at higher levels is desirable, especially when a high corrosion resistance and/or resistance to oxidation at high temperatures is required for these applications; for these applications in an embodiment amounts exceeding 1.2% by weight are desirable, in another embodiment preferably above 2.6%, in another embodiment preferably greater than 5.5% by weight, in another embodiment preferably above 6.1%, in another embodiment more preferably over 7%, in another embodiment more preferably above 10.4%, and even in another embodiment greater than 16%.

It has been seen that for some applications the presence of excessive aluminum (% Al) can be detrimental, for these applications is desirable in an embodiment a % Al content of less than 12.9%, in another embodiment preferably less than 10.4%, in another embodiment preferably less than 8.4%, in another embodiment less than 7.8% by weight, in another embodiment preferably less than 6.1%, in another embodiment preferably less than 4.8%, preferably less than 3.4%, preferably less than 2.7%, in another embodiment more preferably less than 1.8% by weight and even in another embodiment less than 0.8%. In contrast there are applications wherein the presence of aluminum at higher levels is desirable, especially when a high hardening and/or environmental resistance are required, for these applications in an embodiment are desirable amounts, in another embodiment greater than 1.2% by weight, in another embodiment preferably greater than 2.4% preferably greater than 3.2% by weight, in another embodiment preferably greater than 4.8%, in another embodiment preferably greater than 6.1%, in another embodiment preferably greater than 7.3%, in another embodiment more preferably above 8.2% and even in another embodiment above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of cobalt (% Co) may be detrimental, for these applications is desirable in an embodiment a % Co content of less than 9.8% by weight, in another embodiment preferably less than 6.4%, in another embodiment preferably less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Co is detrimental or not optimal for one reason or another, in these applications it is preferred % Co being absent from the iron based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 4%, in another embodiment preferably higher than 5.6%, in another embodiment preferably higher than 6.4%, in another embodiment more preferably greater than 8% and even in another embodiment greater than 12%. There are other applications wherein it is desirable the % Co in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 2.4% by weight, in another embodiment preferably less than 2.1%, in another embodiment preferably less than 1.95%, in another embodiment preferably less than 1.8%, in another embodiment more preferably less than 0.9% by weight and even in another embodiment less than 0.38%. In contrast there are applications wherein the presence of carbon equivalent in higher amounts is desirable for these applications in an embodiment amounts exceeding 0.27% by weight are desirable, in another embodiment preferably greater than 0.42% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 1.8% by weight, in another embodiment preferably less than 1.4%, in another embodiment preferably less than 0.9%, in another embodiment more preferably less than 0.58% by weight and even in another embodiment less than 0.44%. In contrast there are applications where the presence of carbon at higher levels is desirable, especially when an increase on mechanical strength and/or hardness is desired. For these applications in an embodiment amounts exceeding 0.27% by weight are desirable, preferably in another embodiment greater than 0.32% by weight, in another embodiment more preferably greater than 0.42% and even in another embodiment greater than 1.2%.

It has been found that for some applications, the excessive presence of boron (% B) may be detrimental, for these applications in an embodiment is desirable a % B content of less than 1.8% by weight, in another embodiment preferably less than 1.4%, in another embodiment preferably less than 0.9%, in another embodiment more preferably less than 0.06% by weight and even in another embodiment less than 0.006%. There are even some applications for a given application wherein in an embodiment % B is detrimental or not optimal for one reason or another, in these applications it is preferred % B being absent from the iron based alloy. In contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been seen that for some applications the presence of excessive nitrogen (% N) can be harmful, for these applications is desirable a % N content of less than 1.4% by weight, preferably less than 0.9%, more preferably less than 0.06% by weight and even less than 0.006%. By contrast there are applications where the presence of nitrogen in higher amounts is desirable for these applications above 60 ppm amounts by weight are desirable, preferably above 200 ppm, more preferably greater than 0.2% and even above 1.2%.

It has been seen that there are applications for which the presence of nitrogen (% N) may be harmful and it is preferable to its absence (may not be economically viable remove beyond the content as an impurity, less than 0.1% by weight, preferably less to 0.008%, more preferably less than 0.0008% and even less than 0.00008%).

It has been found that for some applications, the excessive presence of zirconium (% Zr) and/or hafnium (% Hf) may be detrimental, for these applications in an embodiment is desirable a content of % Zr+% Hf of less than 11.4% by weight, in another embodiment less than 9.8%, in another embodiment less than 7.8% by weight, I in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Zr and/or % Hf are detrimental or not optimal for one reason or another, in these applications in an embodiment it is preferred % Zr and/or % Hf being absent from the iron based alloy. In contrast there are applications where the presence of some of these elements at higher levels is desirable, especially where a high hardening and/or environmental resistance is required, for these applications in an embodiment amounts of % Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 9.1%.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the iron based alloy. In contrast there are applications where the presence of molybdenum and tungsten at higher levels is desirable, for these applications in an embodiment amounts of % Mo+½% W exceeding 1.2% by weight are desirable, in another embodiment preferably greater than 3.2% by weight, in another embodiment more preferably greater than 5.2% and even in another embodiment above 12%.

It has been found that for some applications, the excessive presence of % Si may be detrimental, for these applications is desirable % Si amount in an embodiment less than 3.4%, in other embodiment less than 1.8%, in other embodiment less than 0.8%, in other embodiment preferably less than 0.45%, in an embodiment more preferably less than 0.8% by weight, and even in an embodiment less than 0.08% and even in another embodiment absent from the iron based alloy. In contrast there are applications wherein the presence of % Si in higher amounts is desirable, especially when an increase on strength and/or resistance to oxidation is desired. For these applications in an embodiment is desirable % Si amount above 0.01%, in other embodiment above 0.27%, in other embodiment preferably above 0.52%, in other embodiment more preferably above 0.82%, and even in other embodiment above 1.2%.

It has been found that for some applications, the excessive presence of Vanadium (% V) may be detrimental, for these applications in an embodiment is desirable % V content less than 11.3%, in another embodiment less than 9.8% by weight, in another embodiment less than 6.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the iron based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 2.2% by weight, in another embodiment more preferably greater than 4.2% and even in another embodiment above 10.2%.

It has been found that there are applications where the presence of titanium is desirable, especially when an increase on mechanical properties at high temperatures are desired. Normally in amounts in an embodiment greater than 0.05% by weight, in another embodiment preferably greater than 0.2% by weight, in another embodiment preferably greater than 4.1% by weight, in another embodiment more preferably above 1.2% or even in another embodiment above 4%. In contrast for some applications, the excessive presence of titanium (% Ti) may be detrimental, for these applications is desirable % Ti content in an embodiment of less than 1.8% by weight, in another embodiment preferably less than 1.4%, in another embodiment preferably less than 0.8%, in another embodiment preferably less than 0.4%, in another embodiment more preferably less than 0.02% by weight, and even in another embodiment less than 0.004%. There are even some applications for a given application wherein % Ti is detrimental or not optimal for one reason or another, in these applications in an embodiment it is preferred % Ti being absent from the iron based alloy.

It has been found that for some applications, the excessive presence of tantalum (% Ta) and/or niobium (% Nb) may be detrimental, for these applications is desirable % Ta+% Nb content in an embodiment of less than 14.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the iron based alloy. In contrast there are applications wherein higher amounts of % Ta and/or % Nb are desirable, especially Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

It has been that for some applications, excessive presence of copper (% Cu) may be detrimental, for these applications in an embodiment is desirable % Cu content of less than 8.2% by weight, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the iron based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 3.6% by weight, in another embodiment greater than 6% by weight and even in another embodiment exceeding 7.6%.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the iron based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the iron based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the iron based alloy.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the iron based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the iron based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the iron based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % P being absent from the iron based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the iron based alloy.

There are applications wherein the presence of % Y in higher amounts is desirable for these applications in an embodiment is desirable % Y amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Y may be detrimental, for these applications is desirable % Y amount in an embodiment less than 4.9%, in other embodiment less than 3.4%, in other embodiment less than 2.8%, in other embodiment less than 1.4%. In an embodiment % Y is detrimental or not optimal for one reason or another, in these applications it is preferred % Y being absent from the iron based alloy.

There are applications wherein the presence of % Ce in higher amounts is desirable for these applications in an embodiment is desirable % Ce amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ce may be detrimental, for these applications is desirable % Ce amount in an embodiment less than 4.4%, in other embodiment less than 3.1%, in other embodiment less than 2.7%, in other embodiment less than 1.4%. In an embodiment % Ce is detrimental or not optimal for one reason or another, in these applications it is preferred % Ce being absent from the iron based alloy.

There are applications wherein the presence of % La in higher amounts is desirable for these applications in an embodiment is desirable % La amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % La may be detrimental, for these applications is desirable % La amount in an embodiment less than 4.4%, in other embodiment less than 3.1%, in other embodiment less than 2.7%, in other embodiment less than 1.4%. In an embodiment % La is detrimental or not optimal for one reason or another, in these applications it is preferred % La being absent from the iron based alloy.

It has been found that for some applications it is interesting to have a silicon content simultaneously and/or manganese with generally high presence of zirconium and/or titanium which sometimes can be replaced by chromium. In this case the condition % Cr+% V+% Mo+% W+% Nb+% Ta+% Zr+% Ti>3 is reduced to % Cr+% V+% Mo+% W+% Nb+% Ta+% Zr+% Ti>1.5. For these cases it has been found that % Mn+% Si are desirable above 1.55%, preferably greater than 2.2%, more preferably 5.5% higher and even higher than 7.5%. For some applications of these cases it has been found that the content of % Mn+% Si should not be excessive, in these cases it is desirable to have contained less than 14%, preferably less than 9%, more preferably less than 6.8% and even below 5.9%. For some of these cases it has been seen that it is desirable to have % Mn content exceeding 2.1%, preferably greater than 4.1%, more preferably greater than 6.2% and even higher than 8.2%. For some of these cases has been that excessive content of % Mn can be harmful and is convenient to have % Mn content of less than 14%, preferably less than 9%, more preferably less than 6.8% and even less than 4.2%. For some of these cases it has been seen that it is convenient to have % Si content above 1.2% preferably greater than 1.6%, more preferably greater than 2.1% and even higher than 4.2%. For some of these cases it has been seen that an excessive content of % Si can be harmful and is convenient to have % Si content less than 9%, preferably less than 4.9%, more preferably less than 2.9% and even less than 1.9%. For some of these cases it has been seen that it is desirable to have % Ti content above 0.55% preferably greater than 1.2%, more preferably greater than 2.2% and even higher than 4.2%. For some of these cases has been that excessive content of % Ti can be harmful and is convenient to have contents of % Ti less than 8%, preferably less than 4%, more preferably less than 2.8% and even less than 0.8%. For some of these cases it has been seen that it is desirable to have higher contents of % Zr to 0.55%, preferably greater than 1.55%, more preferably greater than 3.2% and

even higher than 5.2%. For some of these cases has been that excessive content of % Zr can be harmful and is convenient to have content of % Zr less than 8%, preferably less than 5.8%, more preferably less than 4.8% and even less than 1.8%. For some of these cases it has been seen that it is desirable to have higher contents of % C to 0.31%, preferably greater than 0.41%, more preferably greater than 0.52% and even higher than 1.05%. For some of these cases has been that excessive content of % C can be harmful and is convenient to have content % lower C 2.8%, preferably less than 1.8%, more preferably less than 0.9% and even less than 0.48%. Obviously for these and other elements apply the requirements of special applications of the rest of the section they are all compatible with the special applications described in this paragraph (as in the rest of the document). These alloys are especially interesting for some applications if bainitic treatments are performed and/or treatments retained austenite to have large increases in hardness with the application of a low temperature treatment (below 790° C., preferably below 690° C., more preferably below 590° C. and even below 490° C.). It is suitable for some applications microstructure set to have a hardness increase of 6HRc or more, preferably 11 HRc or more, more preferably 16HRc or more and even more 21 HRc or. (If the microstructure is fine adjusted in some cases may be passed around to 200HB to 60 HRc in the low temperature treatment. Particles of these alloys are especially interesting also for processes of AM of metal melt particles (as is the case for many of the alloys presented herein although no special mention is made).

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder magnesium or magnesium alloy and also sometimes alloyed directly to the aluminum particles or alloy aluminum and also sometimes other particles such as low melting particles) the final content of % Mg can be quite small, in these applications often greater than 0.001% content, preferably greater than 0.02% is desired, more preferably greater than 0.12% and even 3.6% above.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Sn that are detrimental in specific applications especially for certain Cr and/or C contents; For these applications in an embodiment with % Cr between 0.47% and 5.8% and/or C between 0.7% and 2.74%, % Sn is below 0.087% or even absent from the composition, even in another embodiment with % Cr between 0.47% and 5.8% and/or C between 0.7% and 2.74%, % Sn is above 0.92%.

There are several applications wherein the presence of Si and B in the composition is detrimental for the overall properties of the steel, especially for certain Cu and/or B contents. For these applications in an embodiment with % Cu between 0.097 atomic % (at. %) and 3.33 at. %, the total content of % B and/or % Si is below 4.77 at. %, in another embodiment with % Cu between 0.097 at. % and 3.33 at. %, the total content of % B and/or % Si is below 1.33 at. %, in another embodiment with % Cu between 0.097 at. % and 3.33 at. %, % B is below 2.4 at. % and/or % Si is below 5.77 at. %, in another embodiment with % Cu between 0.097 at. % and 3.33 at. %, % B is above 16.2 at. % and/or % Si is above 27.2 at. %. In another embodiment with % Cu between 0.097 at. % and 3.33 at. %, the total content of % B and % Si is above 31 at. %, in another embodiment with % Cu between 0.097 at. % and 3.33 at. %, the total content of % B and % Si is above 31 at. %. In another embodiment with % Cu between 0.3 at. % and 1.7 at. %, % B is below 4.2 at. % and/or % Si is below 8.77 at. %, in another embodiment with % Cu between 0.3 at. % and 1.7 at. %, % B is above 9.2 at. % and/or % Si is above 17.2 at. %. In another embodiment with % Cu between 0.097 at. % and 3.33 at. %, % B is below 9.77 at. %, in another embodiment with % Cu between 0.097 at. % and 3.33 at. %, % B is above 22.2 at. % even in another embodiment with % Cu between 0.097 at. % and 3.33 at. %, % B is above 32.2 at. %. In another embodiment with % Cu between 0.97 at. % and 3.33 at. %, % B is below 9.77 at. %, in another embodiment with % Cu between 0.97 at. % and 3.33 at. %, % B is above 22.2 at. %. In another embodiment with % B between 0.97 at. % and 33.33 at. %, the total content of % B and/or % Si is below 1.33 at. %, in another embodiment with % B between 0.97 at. % and 33.33 at. %, the total content of % B and/or % Si is above 33.33 at. %.

It has been found that for some applications, certain contents of elements such as Si and B may be detrimental especially for certain Al and Ga contents. For these applications in an embodiment with % Al between 1.87 at. % and 16.6 at. %, % B is lower than 3.87%. In another embodiment with % Al between 1.87 at. % and 16.6 at. %, % B is higher than 23.87%. Even in another embodiment with % Al between 1.87 at. % and 16.6 at. % and/or % Ga between 0.43 at. % and 5.2 at. %, % B is below 1.33 at. % and/or % Si is below 0.43 at. %. In another embodiment with % Al between 1.87 at. % and 16.6 at. % and/or % Ga between 0.43 at. % and 5.2 at. %, % B is above 11.33 at. % and/or % Si is above 5.43 at. %.

There are several elements such as Co that are detrimental in specific applications especially for certain Ni contents; For these applications in an embodiment with % Ni between 24.47% and 35.8%, % Co is lower than 12.6%. Even in another embodiment with % Ni between 24.47% and 35.8%, % Co is higher than 26.6%.

There are several elements such as rare earth elements (RE) that are detrimental in specific applications; For these applications in an embodiment RE are absent from the composition.

For some applications it is desirable that the above alloys have a melting point below 890° C., preferably below 640° C., more preferably below 180° C. or even below 46° C.

Any of the above Fe alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an iron alloy for manufacturing metallic or at least partially metallic components.

The present invention is particularly suitable for building components in iron or iron alloys. In particular it is especially suitable for building components with a composition expressed below.

In an embodiment the invention refers to an iron based alloy having the following composition, all percentages being in weight percent:

| | | | |
|---|---|---|---|
| C = 0.0008-3.9 | % N = 0-1.0 | % B = 0-1.0 | % Ti = 0-2 |
| % Cr < 3.0 | % Ni = 0-6 | % Si = 0-1.4 | % Mn = 0-20 |
| % Al = 0-2.5 | % Mo = 0-10 | % W = 0-10 | % Sc: 0-20; |
| % Ta = 0-3 | % Zr = 0-3 | % Hf = 0-3 | % V = 0-4 |
| % Nb = 0-1.5 | % Cu = 0-20 | % Co = 0-6, | % Ce = 0-3 |
| % La = 0-3 | % Si: 0-15; | % Li: 0-20; | |
| % Mg: 0-20; | % Zn: 0-20; | | |

The rest consisting on iron (Fe) and trace elements

There are applications wherein iron based alloys are benefited from having a high iron (% Fe) content but not necessary iron being the majority component of the alloy. In an embodiment % Fe is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Fe is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Fe is not the majority element in the iron based alloy.

In this context trace elements refers to several elements, unless context clearly indicates otherwise, including but not limited to: H, He, Xe, Be, O, F, Ne, Na, P, S, Cl, Ar, K, Ca, Sc, Zn, Ga, Ge, As, Se, Br, Kr, Rb, Sr, Y, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Re, Os, Ir, Pt, Au, Hg, Tl, Pb, Bi, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the iron based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the iron based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

Desirable amounts of the individual elements for different applications may continue in this case the pattern in terms of desirable quantities as described in the preceding paragraphs identical to the case of high mechanical strength iron based alloys or the case of tool steels alloys, in both cases with the exception of the % elements C,% B,% N and % Cr and/or % Ni. in the case of corrosion resistant alloys.

It has been found that for some applications, excessive presence of nickel (% Ni) may be detrimental, for these applications is desirable a % Ni content in an embodiment of less than 8%, in other embodiment preferably less than 4.7%, in other embodiment preferably less than 2.8%, in other embodiment preferably less than 2.3%, in other embodiment more preferably less than 1.8%, and even in other embodiment less than 0.008% In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight, in other embodiment higher than 1.2% by weight, in other embodiment preferably higher than 8.3% by weight in other embodiment preferably higher than 3.2%, in other embodiment more preferably higher than 5.2% and even in other embodiment higher than 18%.

There are applications wherein the presence of % Si in higher amounts is desirable, especially when an increase on strength and/or resistance to oxidation is desired. For these applications in an embodiment is desirable % Si amount above 0.01%, in other embodiment above 0.15%, in other embodiment above 0.6%, even in other embodiment above 1.1%. In contrast it has been found that for some applications, the excessive presence of % Si may be detrimental, for these applications is desirable % Si amount in an embodiment less than 0.8%, in other embodiment less than 0.4%.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.01%, in other embodiment above 0.3%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%.

It has been found that for some applications, excessive presence of chromium (% Cr) may be detrimental, for these applications in an embodiment is desirable a % Cr content of less than 14%, in other embodiment less than 3.8%, in other embodiment less than 0.8%, in other embodiment less than 0.8%. In contrast there are applications wherein the presence of chromium at higher levels is desirable, especially when a high corrosion resistance and/or resistance to oxidation at high temperatures is required for these applications; for these applications in an embodiment amounts exceeding 1.2% by weight are desirable, in other embodiment amounts exceeding 1.6% by weight in other embodiment amounts exceeding 2.2% by weight and even in another embodiment preferably above 2.8%.

It has been seen that for some applications the presence of excessive aluminum (% Al) can be detrimental, for these applications is desirable in an embodiment a % Al content of less than 2.3%, in another embodiment more preferably less than 1.8% by weight and even in another embodiment less than 0.8%, and even absent from the iron based alloy. In contrast there are applications wherein the presence of aluminum at higher levels is desirable, especially when a high hardening and/or environmental resistance are required, for these applications in an embodiment are desirable amounts, in another embodiment greater than 1.2% by weight, and even in another embodiment above 1.9%.

It has been seen that for some applications, the excessive presence of cobalt (% Co) may be detrimental, for these applications is desirable in an embodiment a % Co content of less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Co is detrimental or not optimal for one reason or another, in these applications it is preferred % Co being absent from the iron based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 4%, and even in another embodiment preferably higher than 5.6%. There are other applications wherein it is desirable the % Co in an embodiment above 0.0001%, in other embodiment above 0.15%, in other embodiment above 0.9%, and even in other embodiment above 1.6%.

It has been found that for some applications, the presence of excess carbon (% C) may be detrimental, for these applications is desirable a % C content in an embodiment of less than 1.8% by weight, in another embodiment preferably less than 1.4%, in another embodiment preferably less than 0.9%, in another embodiment preferably less than 0.48% by weight in another embodiment, more preferably less than 0.18% and even in other embodiment 0.008%. In contrast there are applications where the presence of carbon at higher levels is desirable, especially when an increase on mechanical strength and/or hardness is desired. For these applications in an embodiment amounts exceeding 0.02% by weight are desirable, preferably in another embodiment greater than 0.12% by weight, in another embodiment more preferably greater than 0.42% and even in another embodiment greater than 3.2%.

It has been found that for some applications, the excessive presence of boron (% B) may be detrimental, for these applications in an embodiment is desirable a % B content of less than 0.48% by weight, in another embodiment preferably less than 0.19%, in another embodiment more preferably less than 0.06% by weight and even in another embodiment less than 0.006%. There are even some applications for a given application wherein in an embodiment % B is detrimental or not optimal for one reason or another, in these applications it is preferred % B being absent from the iron based alloy. In contrast there are applications wherein the presence of boron in higher amounts is desirable for these applications in another embodiment above 60 ppm amounts by weight are desirable, in another embodiment preferably above 200 ppm, in another embodiment preferably above 0.12%, and even in other embodiment greater than 0.52%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.46%, in another embodiment preferably less than 0.18% by weight in another embodiment preferably less than 0.06% by weight and even in another embodiment less than 0.0006%. There are even some applications for a given application wherein in an embodiment % N is detrimental or not optimal for one reason or another, in these applications in an embodiment it is preferred % N being absent from the iron based alloy. In contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.2%, and even in another embodiment preferably above 0.52%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of titanium (% Ti), zirconium (% Zr) and/or hafnium (% Hf) may be detrimental, for these applications in an embodiment is desirable a content of % Ti+% Zr+% Hf of less than 7.8% by weight, in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Ti and/or % Zr and/or % Hf are detrimental or not optimal for one reason or another, in these applications in an embodiment it is preferred % Ti and/or % Zr and/or % Hf being absent from the iron based alloy. In contrast there are applications where the presence of some of these elements at higher levels is desirable, especially where a high hardening and/or environmental resistance is required, for these applications in an embodiment amounts of % Ti+% Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 5.2%, or even in another embodiment above 6%.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the iron based alloy. In contrast there are applications where the presence of molybdenum and tungsten at higher levels is desirable, for these applications in an embodiment amounts of % Mo+½% W exceeding 1.2% by weight are desirable, in another embodiment preferably greater than 3.2% by weight, in another embodiment more preferably greater than 5.2% and even in another embodiment above 12%.

It has been found that for some applications, the excessive presence of Vanadium (% V) may be detrimental, for these applications in an embodiment is desirable % V content less than 3.8%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the iron based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 2.2% by weight, and even in another embodiment above 2.9%.

It has been found that for some applications, the excessive presence of tantalum (% Ta) and/or niobium (% Nb) may be detrimental, for these applications is desirable % Ta+% Nb content in an embodiment of less than 4.3%, in another embodiment preferably less than 3.4%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the iron based alloy. In contrast there are applications wherein higher amounts of % Ta and/or % Nb are desirable, especially Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, and even in another embodiment greater than 2.9%.

It has been that for some applications, excessive presence of copper (% Cu) may be detrimental, for these applications in an embodiment is desirable % Cu content of less than 1.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the iron based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 0.6% by weight, and even in another embodiment exceeding 1.1%.

There are applications wherein the presence of % La in higher amounts is desirable for these applications in an embodiment is desirable % La amount above 0.0001%, in other embodiment above 0.15%, in other embodiment above 0.9%, in other embodiment above 1.3%, in other embodiment above 1.6%, and even in other embodiment above 1.9%. In contrast it has been found that for some applications, the excessive presence of % La may be detrimental, for these applications is desirable % La amount in an embodiment less than 2.6%, in other embodiment less than 1.4%. In an embodiment % La is detrimental or not optimal for one reason or another, in these applications it is preferred % La being absent from the iron based alloy.

It has been seen that for some applications, the excessive presence of magnesium (% Mg) may be detrimental, for these applications is desirable in an embodiment a % Mg content of less than 9.8% by weight, in another embodiment preferably less than 6.4%, in another embodiment preferably less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Mg is detrimental or not optimal for one reason or another, in these applications it is preferred % Mg being absent from the iron based alloy. In contrast there are applications wherein the presence of magnesium in higher amounts is desirable. For these applications in an embodiment are desirable amounts exceeding 2.2% by weight, in another embodiment preferably higher than 4%, in another embodiment preferably higher than 5.6%, in another embodiment preferably higher than 6.4%, in another embodiment more preferably greater than 8% and even in another embodiment greater than 12%. There are other applications wherein it is desirable the % Mg in an embodiment above 0.0001%, in other embodiment above 0.15%, in other embodiment above 0.9%, and even in other embodiment above 1.6%.

It has been seen that for some applications, the excessive presence of zinc (% Zn) may be detrimental, for these applications is desirable in an embodiment a % Zn content of less than 9.8% by weight, in another embodiment preferably less than 6.4%, in another embodiment preferably less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Zn is detrimental or not optimal for one reason or another, in these applications it is preferred % Zn being absent from the iron based alloy. In contrast there are applications wherein the presence of zinc in higher amounts is desirable. For these applications in an embodiment are desirable amounts exceeding 2.2% by weight, in another embodiment preferably higher than 4%, in another embodiment preferably higher than 5.6%, in another embodiment preferably higher than 6.4%, in another embodiment more preferably greater than 8% and even in another embodiment greater than 12%. There are other applications wherein it is desirable the % Zn in an embodiment above 0.0001%, in other embodiment above 0.15%, in other embodiment above 0.9%, and even in other embodiment above 1.6%.

It has been seen that for some applications, the excessive presence of lithium (% Li) may be detrimental, for these applications is desirable in an embodiment a % Li content of less than 9.8% by weight, in another embodiment preferably less than 6.4%, in another embodiment preferably less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Li is detrimental or not optimal for one reason or another, in these applications it is preferred % Li being absent from the iron based alloy. In contrast there are applications wherein the presence of lithium in higher amounts is desirable. For these applications in an embodiment are desirable amounts exceeding 2.2% by weight, in another embodiment preferably higher than 4%, in another embodiment preferably higher than 5.6%, in another embodiment preferably higher than 6.4%, in another embodiment more preferably greater than 8% and even in another embodiment greater than 12%. There are other applications wherein it is desirable the % Li in an embodiment above 0.0001%, in other embodiment above 0.15%, in other embodiment above 0.9%, and even in other embodiment above 1.6%.

It has been seen that for some applications, the excessive presence of scandium (% Sc) may be detrimental, for these applications is desirable in an embodiment a % Sc content of less than 9.8% by weight, in another embodiment preferably less than 6.4%, in another embodiment preferably less than 5.8%, in another embodiment preferably less than 4.6%, in another embodiment preferably less than 3.4%, in another embodiment more preferably less than 2.8% by weight, more preferably less than 1.4%, and even in another embodiment less than 0.8%. There are even some applications for a given application wherein in an embodiment % Sc is detrimental or not optimal for one reason or another, in these applications it is preferred % Sc being absent from the iron based alloy. In contrast there are applications wherein the presence of scandium in higher amounts is desirable. For these applications in an embodiment are desirable amounts exceeding 2.2% by weight, in another embodiment preferably higher than 4%, in another embodiment preferably higher than 5.6%, in another embodiment preferably higher than 6.4%, in another embodiment more preferably greater than 8% and even in another embodiment greater than 12%. There are other applications wherein it is desirable the % Sc in an embodiment above 0.0001%, in other embodiment above 0.15%, in other embodiment above 0.9%, and even in other embodiment above 1.6%.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder magnesium or magnesium alloy and also sometimes alloyed directly to the aluminum particles or alloy aluminum and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Sn that are detrimental in specific applications especially for certain Cr and/or C contents; For these applications in an embodiment with % Cr between 0.47% and 5.8% and/or C between 0.7% and 2.74%, % Sn is below 0.087% or even absent from the composition, even in another embodiment with % Cr between 0.47% and 5.8% and/or C between 0.7% and 2.74%, % Sn is above 0.92%.

There are several applications wherein the presence of Si and B in the composition is detrimental for the overall properties of the steel, especially for certain Cu and/or B contents. For these applications in an embodiment with % Cu between 0.097 atomic % (at. %) and 3.33 at. %, the total content of % B and/or % Si is below 4.77 at. %, in another embodiment with % Cu between 0.097 at. % and 3.33 at. %, the total content of % B and/or % Si is below 1.33 at. %, in another embodiment with % Cu between 0.097 at. % and 3.33 at. %, % B is below 2.4 at. % and/or % Si is below 5.77 at. %, in another embodiment with % Cu between 0.097 at. % and 3.33 at. %, % B is above 16.2 at. % and/or % Si is above 27.2 at. %. In another embodiment with % Cu between 0.097 at. % and 3.33 at. %, the total content of % B and % Si is above 31 at. %, in another embodiment with % Cu between 0.097 at. % and 3.33 at. %, the total content of % B and % Si is above 31 at. %. In another embodiment with % Cu between 0.3 at. % and 1.7 at. %, % B is below 4.2 at. % and/or % Si is below 8.77 at. %, in another embodiment with % Cu between 0.3 at. % and 1.7 at. %, % B is above 9.2 at. % and/or % Si is above 17.2 at. %. In another embodiment with % Cu between 0.097 at. % and 3.33 at. %, % B is below 9.77 at. %, in another embodiment with % Cu between 0.097 at. % and 3.33 at. %, % B is above 22.2 at. % even in another embodiment with % Cu between 0.097 at. % and 3.33 at. %, % B is above 32.2 at. %. In another embodiment with % Cu between 0.97 at. % and 3.33 at. %, % B is below 9.77 at. %, in another embodiment with % Cu between 0.97 at. % and 3.33 at. %, % B is above 22.2 at. %. In another embodiment with % B between 0.97 at. % and 33.33 at. %, the total content of % B and/or % Si is below 1.33 at. %, in another embodiment with % B between 0.97 at. % and 33.33 at. %, the total content of % B and/or % Si is above 33.33 at. %.

It has been found that for some applications, certain contents of elements such as Si and B may be detrimental especially for certain Al and Ga contents. For these applications in an embodiment with % Al between 1.87 at. % and 16.6 at. %, % B is lower than 3.87%. In another embodiment with % Al between 1.87 at. % and 16.6 at. %, % B is higher than 23.87%. Even in another embodiment with % Al between 1.87 at. % and 16.6 at. % and/or % Ga between 0.43 at. % and 5.2 at. %, % B is below 1.33 at. % and/or % Si is below 0.43 at. %. In another embodiment with % Al between 1.87 at. % and 16.6 at. % and/or % Ga between 0.43 at. % and 5.2 at. %, % B is above 11.33 at. % and/or % Si is above 5.43 at. %.

There are several elements such as Co that are detrimental in specific applications especially for certain Ni contents; For these applications in an embodiment with % Ni between 24.47% and 35.8%, % Co is lower than 12.6%. Even in another embodiment with % Ni between 24.47% and 35.8%, % Co is higher than 26.6%.

There are several elements such as rare earth elements (RE) that are detrimental in specific applications; For these applications in an embodiment RE are absent from the composition.

For some applications it is desirable that the above alloys have a melting point below 890° C., preferably below 640° C., more preferably below 180° C. or even below 46° C.

Any of the above Fe alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an iron alloy for manufacturing metallic or at least partially metallic components.

The present invention is particularly suitable for the manufacture of components that can benefit from the properties of titanium and its alloys. Especially applications requiring high mechanical resistance at high temperatures y/o aggressive environments. In this sense, applying certain rules of alloy design and thermo-mechanical treatments, it is possible obtain very interesting features for applications in chemical industry, energy transformation, transport, tools, other machines or mechanisms, etc.

In an embodiment the invention refers to a titanium based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-5 | % Mn = 0-3 |
| % Al = 0-40 | % Mo = 0-20 | % W = 0-25 | % Ni = 0-40 |
| % Ta = 0-5 | % Zr = 0-8 | % Hf = 0-6, | % V = 0-15 |
| % Nb = 0-60 | % Cu = 0-20 | % Fe = 0-40 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % Pt = 0-5 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |
| % Pd = 0-5 | % Re = 0-5 | % Ru = 0-5 | |

The rest consisting on titanium (Ti) and trace elements

wherein % Ceq=% C+0.86*% N+1.2*% B

There are applications wherein titanium based alloys are benefited from having a high titanium (% Ti) content but not necessary the titanium being the majority component of the alloy. In an embodiment % Ti is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Ti is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Ti is not the majority element in the titanium based alloy.

In this context trace elements refers to several elements, unless context clearly indicates otherwise, including but not limited to: H, He, Xe, Be, O, F, Ne, Na, Mg, Cl, Ar, K, Sc, Br, Kr, Sr, Tc, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the titanium based alloy in an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the titanium based alloy

There are other applications wherein the presence of trace elements may reduce the cost of the alloy or attain any other additional beneficial effect without affecting the titanium based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For several applications it is especially interesting the use of alloys containing % Ga % Bi, % Rb, % Cd, % Cs, % Sn, % Pb, % Zn and/or % In. Particularly interesting is the use of these low melting point promoting elements with the presence of more than 12%, and even more than 21% or more. Once incorporated and evaluating the overall composition measured as indicated in this application, the titanium resulting alloy in an embodiment above 0.0001%, in another embodiment above 0.015%, in another embodiment above 0.03%, and even in other embodiment above 0.1%, in another embodiment has generally a 0.2% or more of the element (in this case % Ga), in another embodiment preferably 1.2% or more, in another embodiment preferably 1.35% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.04% by weight, preferably more than 0.12%, more preferably more than 0.24% by weight and even more than 0.32%. But there are other applications depending of the desired properties of the titanium based alloy wherein % Ga contents of 30% or less are desired. In an embodiment the % Ga in the titanium based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the titanium based alloy it has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+Bi %. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications in an embodiment is desirable a % Cr content of less than 39% by weight, in another embodiment preferably less than 18%, in another embodiment more preferably less than 8.8% by weight and even in another embodiment less than 1.8%. There are other applications wherein even a lower % Cr content is desired, in an embodiment the % Cr in the titanium based alloy is less than 1.6%, in other embodiment less than 1.2%, in other embodiment less than 0.8%, in other embodiment less than 0.4%. There are even some applications for a given application wherein in an embodiment % Cr is detrimental or not optimal for one reason or another, in these applications it is preferred % Cr being absent from the titanium based alloy. By contrast there are applications wherein the presence of chromium at higher levels is desirable, especially when a high corrosion resistance and/or resistance to oxidation at high temperatures is required for these applications; for these applications in an embodiment amounts exceeding 2.2% by weight are desirable, in another embodiment preferably above 3.6%, in another embodiment preferably greater than 5.5% by weight, more preferably above 6.1%, more preferably above 8.9%, more preferably above 10.1%, more preferably above 13.8%, more preferably above 16.1%, more preferably above 18.9%, in another embodiment more preferably over 22%, more preferably above 26.4%, and even in another embodiment greater than 32%. But there are also other applications wherein a lower preferred minimum content is desired. In an embodiment, the % Cr in the titanium based alloy is above 0.0001%, in other embodiment above 0.045%, n other embodiment above 0.1%, in other embodiment above 0.8%, and even in other embodiment above 1.3%. There are other applications wherein a high content of % Cr is desired. In another embodiment of the invention the % Cr in the alloy is above 42.2%, and even above 46.1%.

It has been seen that for some applications the presence of excessive aluminum (% Al) can be detrimental, for these applications in an embodiment is desirable % Al content lower than 28% by weight, in another embodiment preferably less than 18%, in another embodiment preferably less than 14.3%, in another embodiment more preferably less than 8.8% by weight, in another embodiment more preferably less than 4.7% by weight and even in another embodiment less than 0.8%. There are even some applications for a given application wherein in an embodiment % Al is detrimental or not optimal for one reason or another, in these applications it is preferred % Al being absent from the titanium based alloy. In contrast there are applications wherein the presence of aluminum at higher levels is desirable, especially when a high hardening and/or environmental resistance are required, for these applications in an embodiment are desirable amounts greater than 0.1% by weight, in another embodiment are desirable amounts greater than 1.2% by weight, in another embodiment are desirable amounts greater than 1.35% by weight, in another embodiment preferably greater than 3.2% by weight, in another embodiment preferably greater than 6.3% by weight, in another embodiment more preferably greater than 12% and even in another embodiment over 22%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

It has been found that for some applications, the excessive presence of rhenium (% Re) may be detrimental, for these applications is desirable % Re content less than 4.8% by weight, preferably less than 2.8%, more preferably less than 1.78% by weight and even less than 0.45%. In contrast there are applications wherein the presence of rhenium in higher amounts is desirable for these applications are desirable amounts exceeding 0.6% by weight, preferably greater than 1.2% by weight, more preferably greater than 2.6%, even above 3.8%. There are even applications wherein in an embodiment % Re is detrimental or not optimal for one reason or another, in these applications it is preferred % Re being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+% Zn+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the titanium based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, in another embodiment more preferably greater than 22% and even in another embodiment greater than 32%. There are other applications wherein it is desirable the % Co in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 1.8% by weight, in another embodiment preferably less than 1.4%, in another embodiment preferably less than 1.1%, in another embodiment less than 0.8%, in another embodiment preferably less than 0.46% by weight in another embodiment more preferably less than 0.18% by weight and even in another embodiment less than 0.08%. There are even some applications for a given application wherein in an embodiment % Ceq is detrimental or not optimal for one reason or another, in these applications it is preferred % Ceq being absent from the titanium based alloy. In contrast there are applications wherein the presence of carbon equivalent in higher amounts is desirable for these applications in an embodiment amounts exceeding 0.12% by weight are desirable, in another embodiment preferably greater than 0.22% in another embodiment more preferably greater than 0.52% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 0.38% by weight, in another embodiment preferably less than 0.26%, in another embodiment preferably less than 0.18%, in another embodiment more preferably less than 0.09% by weight and even in another embodiment less than 0.009%. There are even some applications for a given application wherein in an embodiment % C is detrimental or not optimal for one reason or another, in these applications it is preferred % C being absent from the titanium based alloy. In contrast there are applications where the presence of carbon at higher levels is desirable, especially when an increase on mechanical strength and/or hardness is desired. For these applications in an embodiment amounts exceeding 0.02% by weight are desirable, preferably in another embodiment greater than 0.12% by weight, in another embodiment more preferably greater than 0.22% and even in another embodiment greater than 0.32%.

It has been found that for some applications, the excessive presence of boron (% B) may be detrimental, for these applications in an embodiment is desirable a % B content of less than 0.9% by weight, in another embodiment preferably less than 0.65%, in another embodiment preferably less than 0.4%, in another embodiment more preferably less than 0.018% by weight and even in another embodiment less than 0.006%. There are even some applications for a given application wherein in an embodiment % B is detrimental or not optimal for one reason or another, in these applications it is preferred % B being absent from the titanium based alloy in contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.4%, in another embodiment more preferably less than 0.16% by weight and even in another embodiment less than 0.006%. There are even some applications for a given application wherein in an embodiment % N is detrimental or not optimal for one reason or another, in these applications in an embodiment it is preferred % N being absent from the titanium based alloy. In contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.1%, and even in another embodiment preferably above 0.35%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of zirconium (% Zr) and/or hafnium (% Hf) may be detrimental, for these applications in an embodiment is desirable a content of % Zr+% Hf of less than 12.4% by weight, in another embodiment less than 9.8%, in another embodiment less than 7.8% by weight, I in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Zr and/or % Hf are detrimental or not optimal for one reason or another, in these applications in an embodiment it is preferred % Zr and/or % Hf being absent from the titanium based alloy. In contrast there are applications where the presence of some of these elements at higher levels is desirable, especially where a high hardening and/or environmental resistance is required, for

these applications in an embodiment amounts of % Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 12%. For some applications if oxygen content is higher of 500 ppm, it has been seen that often is desired having Zr+% Hf below 3.8% by weight, preferably less than 2.8%, more preferably below 1.4% and even below 0.08%.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo and/or % W is/are detrimental or not optimal for one reason or another, in these applications in an embodiment it is preferred % Mo and/or W being absent from the titanium based alloy in contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, the excessive presence of Vanadium (% V) may be detrimental, for these applications in an embodiment is desirable % V content less than 12.3%, in another embodiment less than 8.7% by weight, in another embodiment less than 4.8% by weight, in another embodiment less than 3.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the titanium based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 1.2% by weight, in another embodiment preferably greater than 1.35% by weight, in another embodiment more preferably greater than 4.2%, in another embodiment more preferably greater than 5.6%, % and even in another embodiment above 6.2%.

It has been that for some applications, excessive presence of copper (% Cu) may be detrimental, for these applications in an embodiment is desirable % Cu content of less than 14% by weight, in another embodiment preferably less than 12.7%, in another embodiment preferably less than 9%, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the titanium based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 2.55% by weight, in another embodiment greater than 3.6% by weight, in another embodiment greater than 4.7% by weight, in another embodiment greater than 6% by weight are desirable, in another embodiment preferably greater than 8% by weight, in another embodiment more preferably above 12% and even in another embodiment exceeding 16%.

It has been that for some applications the presence of excessive iron (% Fe) may be detrimental, for these applications in an embodiment is desirable % Fe content of less than 38% by weight, in another embodiment preferably less than 36%, in another embodiment preferably less than 24%, preferably less than 18%, in another embodiment more preferably less than 12% by weight, in another embodiment more preferably less than 10.3% by weight, and even in another embodiment less than 7.5%, even in another embodiment less than 5.9%, in another embodiment less than 3.7%, in another embodiment less than 2.1%, or even in another embodiment less than 1.3%. There are even some applications for a given application wherein % Fe is detrimental or not optimal for one reason or another, in these applications in an embodiment it is preferred % Fe being absent from the titanium based alloy. In contrast there are applications where the presence of iron at higher levels is desirable, for these applications are desirable amounts in an embodiment greater than 0.1% by weigh, in another embodiment greater than 1.3% by weight, g in another embodiment greater than 2.7% by weight, in another embodiment greater than 4.1% by weight, in another embodiment greater than 6% by weight, in another embodiment preferably greater than 8% by weight, in another embodiment more preferably greater than 22% and even in another embodiment greater than 32%.

It has been that for some applications the presence of excessive nickel (% Ni) may be detrimental, for these applications in an embodiment is desirable % Ni content of less than 19% by weight, in another embodiment preferably less than 12.6%, in another embodiment preferably less than 9%, preferably less than 4.8%, in another embodiment more preferably less than 2.9% by weight, in another embodiment more preferably less than 1.3% by weight, and even in another embodiment less than 0.9% There are even some applications for a given application wherein % Ni is detrimental or not optimal for one reason or another, in these applications in an embodiment it is preferred % Ni being absent from the titanium based alloy. In contrast there are applications where the presence of nickel at higher levels is desirable, for these applications are desirable amounts in an embodiment greater than 0.1% by weigh, in another embodiment greater than 1.2% by weight, in another embodiment greater than 2.7% by weight, in another embodiment preferably greater than 3.2% by weight, in another embodiment greater than 6% by weight, in another embodiment preferably greater than 8.3% by weight, in another embodiment more preferably greater than 12.3% and even in another embodiment greater than 22%.

It has been found that for some applications, the excessive presence of tantalum (% Ta) may be detrimental, for these applications is desirable % Ta content in an embodiment of less than 3.8%, in another embodiment preferably less than 1.8% by weight, in another embodiment more preferably less than 0.8% by weight, and even in another embodiment less than 0.08%. There are even some applications for a given application wherein % Ta is detrimental or not optimal for one reason or another, in these applications in an embodiment it is preferred % Ta being absent from the titanium based alloy. In contrast there are applications wherein higher amounts of % Ta are desirable, for these applications in an embodiment is desired an amount of % Ta greater than 0.01% by weight, in another embodiment preferably greater than 0.6% by weight, in another embodiment preferably greater than 0.2% by weight, in another embodiment preferably greater than 1.2%, in another embodiment more preferably greater than 2.6% and even in another embodiment greater than 3.2%.

It has been found that for some applications, the excessive presence of niobium (% Nb) may be detrimental, for these applications is desirable Nb content in an embodiment of less than 48%, in another embodiment preferably less than 28% by weight, in another embodiment more preferably less than 4.8%, in another embodiment more preferably less than 1.8% by weight, and even in another embodiment less than 0.8%. There are even some applications for a given application wherein % Nb is detrimental or not optimal for one reason or another, in these applications in an embodiment it is preferred % Nb being absent from the titanium based alloy. In contrast there are applications wherein higher amounts of % Nb are desirable, especially Nb is added when an improve on the resistance to intergranular corrosion and/or enhance on mechanical properties at high temperatures is desired. for these applications in an embodiment is desired an amount of % Nb greater than 0.1% by weight, in another embodiment preferably greater than 0.6% by weight, in another embodiment preferably greater than 1.2% by weight, in another embodiment preferably greater than 2.1% by weight, in another embodiment more preferably greater than 12% and even in another embodiment greater than 52%.

It has been found that for some applications, the excessive presence of yttrium (% Y), cerium (% Ce) and/or lanthanide (% La) may be detrimental, for these applications is desirable % Y+% Ce+% La content in an embodiment of less than 12.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Y and/or % Ce and/or % La are detrimental or not optimal for one reason or another, in these applications in an embodiment it is preferred % Y and/or % Ce and/or % La being absent from the titanium based alloy. In contrast there are applications wherein higher amounts are desirable, especially when a high hardness is desired, for these applications in an embodiment is desired an amount of % Y+% Ce+% La greater than 0.1% by weight, in another embodiment preferably greater than 1.2% by weight, in another embodiment preferably greater than 2.1% by weight, in another embodiment more preferably above 6% or even in another embodiment above 12%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the titanium based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the titanium based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the titanium based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the titanium based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the titanium based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the titanium based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % Sb being absent from the titanium based alloy.

It has been seen that for some applications the presence of excessive silicon (% Si) can be detrimental, for these applications is desirable % Si content less than 0.8% by weight, preferably less than 0.46%, more preferably less than 0.18% by weight and even less than 0.08%. By contrast there are applications where the presence of silicon in higher amounts is desirable for these applications amounts greater than 0.12% by weight are desirable, preferably greater than 0.52% by weight, more preferably greater than 1.2% and even above 2.2%.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.0001%, in other embodiment above 0.15%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%. In an embodiment % Mn is detrimental or not optimal for one reason or another, in these applications it is preferred % Mn being absent from the titanium based alloy.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the titanium based alloy.

It has been found that for some applications the presence of excessive tin (% Sn) can be detrimental, for these applications is desirable % Sn content less than 4.8 wt %, preferably less than 1.8%, more preferably less than 0.78% by weight and even less than 0.45%. By contrast there are applications where the presence of tin in higher amounts is desirable for these applications amounts greater than 0.6% by weight are desirable, preferably greater than 1.2% by weight, more preferably greater than 3.2% and even above 6.2%.

It has been found that for some applications, excessive presence of palladium (% Pd) can be detrimental, for these applications is desirable % Pd content less than 0.9% by weight, preferably less than 0.4%, more preferably less than 0.018% by weight and even less than 0.006%. By contrast there are applications where the presence of palladium in higher amounts is desirable for these applications above 60 ppm amounts by weight are desirable, preferably above 200 ppm, more preferably greater than 0.52% and even above 1.2%.

It has been found that for some applications, the excessive presence of rhenium (% Re) can be detrimental, for these applications is desirable % Re content less than 0.9 wt %, preferably less than 0.4%, more preferably less than 0.018% by weight and even less than 0.006%. By contrast there are applications where the presence of rhenium in higher amounts is desirable for these applications above 60 ppm amounts by weight are desirable, preferably above 200 ppm, more preferably greater than 0.52% and even above 1.2%.

It has been found that for some applications, the excessive presence of ruthenium (% Ru) can be detrimental, for these applications is desirable % Ru content less than 0.9 wt %, preferably less than 0.4%, more preferably less than 0.018% by weight and even less than 0.006%. By contrast there are applications where the presence of ruthenium in higher amounts is desirable for these applications above 60 ppm amounts by weight are desirable, preferably above 200 ppm, more preferably greater than 0.52% and even above 1.2%.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Mo and B that are detrimental in specific applications especially for certain Al contents; For these applications in an embodiment with % Al between 1.7% and 6.7%, % Mo is below 6.8%, or even Mo is absent from the composition. In another embodiment with % Al between 41.7% and 6.7%, % Mo is above 13.2%. In another embodiment with % Al between 2.3% and 7.7%, % B is below 0.01%, or even B is absent from the composition. Even in another embodiment with % Al between 2.3% and 7.7%, % B is above 3.11%.

There are several elements such as P, C, N and B that are detrimental in specific applications; For these applications in an embodiment with, P, C, N and B are absent from the composition.

There are several elements such as Pd, Ag, Au, Cu, Hg and Pt that are detrimental in specific applications; For these applications in an embodiment Pd, Ag, Au, Cu, Hg and Pt are absent from the composition.

It has been found that for some applications, certain contents of elements such as rare earth elements (RE), including La and Y, may be detrimental especially for certain Ti contents. For these applications in an embodiment with % Ti between 32.5% and 62.5%, % RE, including La and Y, is lower than 0.087% or even RE including, La and Y, are absent from the composition. In another embodiment with % Ti between 32.5% and 62.5. % RE, including La and Y, is higher than 17. Even in another embodiment with any Ti content, % RE is lower than 1.3% or even RE are absent from the composition. In another embodiment with any Ti content, % RE is higher than 16.3%.

There are some applications wherein the presence of compounds phase in the titanium based alloy is detrimental. In an embodiment the % of compound phase in the alloy is below 79%, in another embodiment is below 49%, in another embodiment is below 19%, in another embodiment is below 9%, in another embodiment is below 0.9% and even in another embodiment compounds are absent from the composition. There are other applications wherein the presence of compounds in the titanium based alloy is beneficial. In another embodiment % of compound phase in the alloy is above 0.0001%, in another embodiment is above 0.3%, in another embodiment is above 3%, in another embodiment is above 13%, in another embodiment is above 43% and even in another embodiment the is above 73%.

For several applications it is especially interesting the use of titanium based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Titanium based alloy is used as a coating layer. In In an embodiment the titanium based alloy is used as a coating layer with thickness above 1.1 micrometer, in another embodiment the titanium based alloy is used as a coating layer with thickness above 21 micrometer, in another embodiment the titanium based alloy is used as a coating layer with thickness above 10 micrometre, in another embodiment the titanium based alloy is used as a coating layer with thickness above 510 micrometre, in another embodiment the titanium based alloy is used as a coating layer with thickness above 1.1 mm and even in another embodiment the titanium based alloy is used as a coating layer with thickness above 11 mm. In another embodiment the titanium based alloy is used as a coating layer with thickness below 27 mm, in another embodiment the titanium based alloy is used as a coating layer with thickness below 17 mm, in another embodiment the titanium based alloy is used as a coating layer with thickness below 7.7 mm, in another embodiment the titanium based alloy is used as a coating layer with thickness below 537 micrometer, in another embodiment the titanium based alloy is used as a coating layer with thickness below 117 micrometre, in another embodiment the titanium based alloy is used as a coating layer with thickness below 27 micrometre and even in another embodiment the titanium based alloy is used as a coating layer with thickness below 7.7 micrometre.

For several applications it is especially interesting the use of titanium based alloy having a high mechanical resistance. For those applications in an embodiment the resultant mechanical resistance of the titanium based alloy is above 52 MPa, in another embodiment the resultant mechanical resistance of the alloy is above 72 MPa, in another embodiment the resultant mechanical resistance of the alloy is above 82 MPa, in another embodiment the resultant mechanical resistance of the alloy is above 102 MPa, in another embodiment the resultant mechanical resistance of the alloy is above 112 MPa and even in another embodiment the resultant mechanical resistance of the alloy is above 122 MPa. In another embodiment the resultant mechanical resistance of the alloy is below 147 MPa, in another embodiment the resultant mechanical resistance of the alloy is below 127 MPa, in another embodiment the resultant mechanical resistance of the alloy is below 117 MPa, in another embodiment the resultant mechanical resistance of the alloy is below 107 MPa, in another embodiment the resultant mechanical resistance of the alloy is below 87 MPa, in another embodiment the resultant mechanical resistance of the alloy is below 77 MPa and even in another embodiment the resultant mechanical resistance of the alloy is below 57 MPa.

There are several technologies that are useful to deposit the titanium based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the titanium based alloy being in powder form. In an embodiment the titanium based alloy is manufactured in form of powder. In another embodiment the powder is spherical. In an embodiment refers to a spherical powder with a particle size distribution which may be unimodal, bimodal, trimodal and even multimodal depending of the specific application requirements.

For some applications it is desirable that the above alloys have a melting point below 890° C., preferably below 640° C., more preferably below 180° C. or even below 46° C.

The titanium based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

Any of the Ti based alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of a titanium alloy for manufacturing metallic or at least partially metallic components.

In an embodiment the invention refers to a cobalt based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % W = 0-25 | % Si = 0-2 | % Mn = 0-3 |
| % Al = 0-15 | % Mo = 0-20 | % Ni = 0-50 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % La = 0-5 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % Be = 0-10 |

The rest consisting on Cobalt (Co and trace elements

wherein % Ceq=% C+0.86*% N+1.2*% B

There are applications wherein cobalt based alloys are benefited from having a high Cobalt (% Co) content but not necessary the cobalt being the majority component of the alloy. In an embodiment % Co is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Co is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Co is not the majority element in the cobalt based alloy.

In this context trace elements refers to several elements, unless context clearly indicates otherwise, including but not limited to: H, He, Xe, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Re, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the alloy, such as reducing cost production of the alloy, and/or its presence may be unintentional and related mostly to the presence of impurities in the alloying elements and scraps used for the production of the alloyl.

There are several applications wherein the presence of trace elements is detrimental for the overall properties of the cobalt based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the cobalt based alloy.

There are other applications wherein the presence of trace elements may reduce the cost of the alloy or attain any other additional beneficial effect without affecting the cobalt based alloy desired properties.

In an embodiment each individual trace element has content below 2.0%, in other embodiment below 1.4%, in other embodiment below 0.8% in other embodiment below 0.2%, in other embodiment below 0.1% or even below 0.06%.

For several applications it is especially interesting the use of alloys containing % Ga % Bi, % Rb, % Cd, % Cs, % Sn, % Pb, % Zn and/or % In. It is particularly interesting the use of low melting point phases

Particularly interesting is the use of these low melting point promoting elements with the presence of more than 2.2% in weight of % Ga, preferably more than 12%, more preferably 21% or more, the cobalt resulting alloy in other embodiment above 0.0001%, in another embodiment above 0.015%, and even in other embodiment above 0.1%, in another embodiment has generally a 0.2% or more of the element (in this case % Ga), in another embodiment preferably 1.2% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. But there are other applications depending of the desired properties of the cobalt based alloy wherein % Ga contents of 30% or less are desired. In an embodiment the % Ga in the cobalt based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the cobalt based alloy. It has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications in an embodiment is desirable a % Cr content of less than 39% by weight, in another embodiment preferably less than 18%, in another embodiment more preferably less than 8.8% by weight and even in another embodiment less than 1.8%. There are other applications wherein even a lower % Cr content is desired, in an embodiment the % Cr in the tungsten bases alloy is less than 1.6%, in other embodiment less than 1.2%, in other embodiment less than 0.8%, in other embodiment less than 0.4%. There are even some applications for a given application wherein in an embodiment % Cr is detrimental or not optimal for one reason or another, in these applications it is preferred % Cr being absent from the cobalt based alloy. By contrast there are applications wherein the presence of chromium at higher levels is desirable, especially when a high corrosion resistance and/or resistance to oxidation at high temperatures is required for these applications; for these applications in an embodiment amounts exceeding 2.2% by weight are desirable, in another embodiment preferably above 3.6%, in another embodiment preferably greater than 5.5% by weight, more preferably above 6.1%, more preferably above 8.9%, more preferably above 10.1%, more preferably above 13.8%, more preferably above 16.1%, more preferably above 18.9%, in another embodiment more preferably over 22%, more preferably above 26.4%, and even in another embodiment greater than 32%. But there are also other applications wherein a lower preferred minimum content is desired. In an embodiment, the % Cr in the cobalt based alloy is above 0.0001%, in other embodiment above 0.045%, in other embodiment above 0.1%, in other embodiment above 0.8%, and even in other embodiment above 1.3%. There are other applications wherein a high content of % Cr is desired. In another embodiment of the invention the % Cr in the alloy is above 42.2%, and even above 46.1%.

It has been seen that for some applications the presence of excessive aluminum (% Al) can be detrimental, for these applications is desirable in an embodiment a % Al content of less than 12.9%, in another embodiment preferably less than 10.4%, in another embodiment preferably less than 8.4%, in another embodiment less than 7.8% by weight, in another embodiment preferably less than 6.1%, in another embodiment preferably less than 4.8%, preferably less than 3.4%, preferably less than 2.7%, in another embodiment more preferably less than 1.8% by weight and even in another embodiment less than 0.8%. There are even some applications for a given application wherein in an embodiment % Al is detrimental or not optimal for one reason or another, in these applications it is preferred % Al being absent from the cobalt based alloy. In contrast there are applications wherein the presence of aluminum at higher levels is desirable, especially when a high hardening and/or environmental resistance are required, for these applications in an embodiment are desirable amounts, in another embodiment greater than 1.2% by weight, in another embodiment preferably greater than 2.4% preferably greater than 3.2% by weight, in another embodiment preferably greater than 4.8%, in another embodiment preferably greater than 6.1%, in another embodiment preferably greater than 7.3%, in another embodiment more preferably above 8.2% and even in another embodiment above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of tungsten (% W) may be detrimental, for these applications is desirable in an embodiment a % W content of less than 28% by weight, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % W is detrimental or not optimal for one reason or another, in these applications it is preferred % W being absent from the cobalt based alloy. In contrast there are applications wherein the presence of tungsten in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, in another embodiment more preferably greater than 22% and even in another embodiment greater than 32%. There are other applications wherein it is desirable the % W in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 1.4%, in another embodiment preferably less than 1.1%, in another embodiment preferably less than 0.8%, in another embodiment more preferably less than 0.46% by weight and even in another embodiment less than 0.08%. There are even some applications for a given application wherein in an embodiment % Ceq is detrimental or not optimal for one reason or another, in these applications it is preferred % Ceq being absent from the cobalt based alloy. In contrast there are applications wherein the presence of carbon equivalent in higher amounts is desirable for these applications in an embodiment amounts exceeding 0.12% by weight are desirable, in another embodiment preferably greater than 0.52% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 0.38% by weight, in another embodiment preferably less than 0.26%, in another embodiment preferably less than 0.18%, in another embodiment more preferably less than 0.09% by weight and even in another embodiment less than 0.009%. There are even some applications for a given application wherein in an embodiment % C is detrimental or not optimal for one reason or another, in these applications it is preferred % C being absent from the cobalt based alloy. In contrast there are applications where the presence of carbon at higher levels is desirable, especially when an increase on mechanical strength and/or hardness is desired. For these applications in an embodiment amounts exceeding 0.02% by weight are desirable, preferably in another embodiment greater than 0.12% by weight, in another embodiment more preferably greater than 0.22% and even in another embodiment greater than 0.32%.

It has been found that for some applications, the excessive presence of boron (% B) may be detrimental, for these applications in an embodiment is desirable a % B content of less than 0.9% by weight, in another embodiment preferably less than 0.65%, in another embodiment preferably less than 0.4%, in another embodiment more preferably less than 0.16% by weight and even in another embodiment less than 0.006%. There are even some applications for a given application wherein in an embodiment % B is detrimental or not optimal for one reason or another, in these applications it is preferred % B being absent from the cobalt based alloy. In contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.4%, in another embodiment more preferably less than 0.16% by weight and even in another embodiment less than 0.006%. There are even some applications for a given application wherein in an embodiment % N is detrimental or not optimal for one reason or another, in these applications in an embodiment it is preferred % N being absent from the cobalt based alloy. In contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.1%, and even in another embodiment preferably above 0.35%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of zirconium (% Zr) and/or hafnium (% Hf) may be detrimental, for these applications in an embodiment is desirable a content of % Zr+% Hf of less than 12.4% by weight, in another embodiment less than 9.8%, in another embodiment less than 7.8% by weight, in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Zr and/or % Hf are detrimental or not optimal for one reason or another, in these applications in an embodiment it is preferred % Zr and/or % Hf being absent from the cobalt based alloy. In contrast there are applications where the presence of some of these elements at higher levels is desirable, especially where a high hardening and/or environmental resistance is required, for these applications in an embodiment amounts of % Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 12%.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the cobalt based alloy. In contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, the excessive presence of Vanadium (% V) may be detrimental, for these applications in an embodiment is desirable % V content less than 6.3%, in another embodiment less than 4.8% by weight, in another embodiment less than 3.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the cobalt based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 1.2% by weight, in another embodiment more preferably greater than 2.2% and even in another embodiment above 4.2%.

It has been that for some applications, excessive presence of copper (% Cu) may be detrimental, for these applications in an embodiment is desirable % Cu content of less than 14% by weight, in another embodiment preferably less than 12.7%, in another embodiment preferably less than 9%, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the cobalt based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 2.55% by weight, in another embodiment greater than 3.6% by weight, in another embodiment greater than 4.7% by weight, in another embodiment greater than 6% by weight are desirable, in another embodiment preferably greater than 8% by weight, in another embodiment more preferably above 12% and even in another embodiment exceeding 16%.

It has been that for some applications the presence of excessive iron (% Fe) may be detrimental, for these applications in an embodiment is desirable % Fe content of less than 58% by weight, in another embodiment preferably less than 36%, in another embodiment preferably less than 24%, preferably less than 18%, in another embodiment more preferably less than 12% by weight, in another embodiment more preferably less than 10.3% by weight, and even in another embodiment less than 7.5%, even in another embodiment less than 5.9%, in another embodiment less than 3.7%, in another embodiment less than 2.1%, or even in another embodiment less than 1.3%. There are even some applications for a given application wherein % Fe is detrimental or not optimal for one reason or another, in these applications in an embodiment it is preferred % Fe being absent from the cobalt based alloy. In contrast there are applications where the presence of iron at higher levels is desirable, for these applications are desirable amounts in an embodiment greater than 0.1% by weigh, in another embodiment greater than 1.3% by weight, g in another embodiment greater than 2.7% by weight, in another embodiment greater than 4.1% by weight, in another embodiment greater than 6% by weight, in another embodiment preferably greater than 8% by weight, in another embodiment more preferably greater than 22% and even in another embodiment greater than 42%.

It has been found that for some applications, the excessive presence of titanium (% Ti) may be detrimental, for these applications is desirable % Ti content in an embodiment of less than 9% by weight, in another embodiment preferably less than 7.6%, in another embodiment preferably less than 6.1%, in another embodiment preferably less than 4.5%, in another embodiment preferably less than 3.3%, in another embodiment more preferably less than 2.9% by weight, in another embodiment more preferably less than 1.8, and even in another embodiment less than 0.9%. There are even some applications for a given application wherein % Ti is detrimental or not optimal for one reason or another, in these applications in an embodiment it is preferred % Ti being absent from the cobalt based alloy. In contrast there are applications where the presence of titanium in higher amounts is desirable, especially when an increase on mechanical properties at high temperatures are desired. For these applications are desirable amounts in an embodiment greater than 0.01%, in another embodiment greater than 0.2%, in another embodiment greater than 0.7%, in another embodiment greater than 1.2% by weight, in another embodiment preferably greater than 3.2% by weight, in another embodiment preferably greater than 4.1% by weight, in another embodiment more preferably above 6% or even in another embodiment above 12%.

It has been found that for some applications, the excessive presence of tantalum (% Ta) and/or niobium (% Nb) may be detrimental, for these applications is desirable % Ta+% Nb content in an embodiment of less than 17.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the cobalt based alloy. In contrast there are applications wherein higher amounts of % Ta and/or % Nb are desirable, especially Nb is added when an improve on the resistance to intergranular corrosion and/or enhance on mechanical properties at high temperatures is desired. For these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

It has been found that for some applications, the excessive presence of yttrium (% Y), cerium (% Ce) and/or lanthanide (% La) may be detrimental, for these applications is desirable % Y+% Ce+% La content in an embodiment of less than 12.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Y and/or % Ce and/or % La are detrimental or not optimal for one reason or another, in these applications in an embodiment it is preferred % Y and/or % Ce and/or % La being absent from the cobalt based alloy. In contrast there are applications wherein higher amounts are desirable, especially when a high hardness is desired, for these applications in an embodiment is desired an amount of % Y+% Ce+% La greater than 0.1% by weight, in another embodiment preferably greater than 1.2% by weight, in another embodiment preferably greater than 2.1% by weight, in another embodiment more preferably above 6% or even in another embodiment above 12%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the cobalt based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the cobalt based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the cobalt based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the cobalt based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the cobalt based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the cobalt based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % Sb being absent from the cobalt based alloy.

There are applications wherein the presence of % Si in higher amounts is desirable, especially when an increase on strength and/or resistance to oxidation is desired. For these applications in an embodiment is desirable % Si amount above 0.0001%, in other embodiment above 0.15%, in other embodiment above 0.9%, and even in other embodiment above 1.3%. In contrast it has been found that for some applications, the excessive presence of % Si may be detrimental, for these applications is desirable % Si amount in an embodiment less than 1.4%, in other embodiment less than 0.8%, in other embodiment less than 0.4%, in other embodiment less than 0.2%. In an embodiment % Si is detrimental or not optimal for one reason or another, in these applications it is preferred % Si being absent from the cobalt based alloy.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.0001%, in other embodiment above 0.15%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%. In an embodiment % Mn is detrimental or not optimal for one reason or another, in these applications it is preferred % Mn being absent from the cobalt based alloy.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the cobalt based alloy.

It has been found that for some applications, excessive presence of nickel (% Ni) may be detrimental, for these applications is desirable a % Ni content in an embodiment of less than 28%, in other embodiment preferably less than 19.8%, in other embodiment preferably less than 18%, in other embodiment preferably less than 14.8%, in other embodiment preferably less than 11.6%, in other embodiment more preferably less than 8%, and even in other embodiment less than 0.8% There are even some applications for a given application wherein in an embodiment % Ni is detrimental or not optimal for one reason or another, in these applications it is preferred % Ni being absent from the cobalt based alloy. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight in another embodiment amounts higher than 1.2% by weight are desired, in other embodiment higher than 2.2% by weight, in other embodiment preferably higher than 6% by weight, in other embodiment preferably higher than 8.3% by weight in other embodiment more preferably higher than 12%, in other embodiment more preferably higher than 16.2% and even in other embodiment higher than 22%.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Pd that are detrimental in specific applications especially for high % Cr contents; for these applications in an embodiment with % Cr higher than 19% the % Pd in the cobalt based alloy is preferred below 51 ppm, and even in another embodiment Pd is preferred to be absent from the alloy.

There are several elements such as Pd, Pt, Au, Ir, Os, Rh and Ru that are detrimental in specific applications especially for high % Cr contents; for these applications in an embodiment with % Cr higher than 15.3% the sum of % Pd, % Pt, % Au, % Ir, % Os, % Rh and % Ru in the cobalt based alloy is preferred below 25%, and even in another embodiment with presence of Cr the sum of % Pd, % Pt, % Au, % Ir, % Os, % Rh and % Ru is preferred to be 0%.

It has been found that for some applications, certain contents of elements such as C, W, Co, N, Ga and Re may be detrimental for certain Cr contents. For these applications in an embodiment with % Cr higher than 11.8% and lower than 30.1% the % C in the cobalt based alloy is preferred to be higher than 0.12%. In another embodiment with % Cr higher than 11.8% and lower than 30.1% the % W in the cobalt based alloy is preferred to be lower than 7.8%. in another embodiment with % Cr higher than 11.8% and lower than 30.1% the % Co in the cobalt based alloy is preferred to be higher than 69% or lower than 42%. In another embodiment with % Cr above 10.2% the % N in the cobalt based alloy is preferred to be 0%. In another embodiment with % Cr higher than 11.8% and lower than 30.1%. Re is preferred to be absent from the alloy. Even in another embodiment with % Cr lower than 41% and higher than 9.9%. % Ga is preferred to be higher than 20.3% or lower than 0.9%

There are several elements such as rare earth elements that are detrimental in specific applications. For these applications, in an embodiment the sum of rare earth elements (%) is preferred to be below 14.6%, and even in another embodiment the sum of rare earth elements is preferred to be 0.

There are several applications wherein the presence of B, Si, Al, Mn, Ge, Fe and Ni in the composition is detrimental for the overall properties of the cobalt based alloy. In an embodiment the alloy does not contain Si and B at the same time, in another embodiment the alloy does not contain Fe and Ni at the same time, in another embodiment the alloy does not contain Al and Ni at the same time, in another embodiment the alloy does not contain Si and Ni at the same time, in another embodiment the alloy does not contain Mn and Ge at the same time. Even in another embodiment the alloy does not contain Mn, Si and B at the same time.

There are several properties of the alloy such as magnetic properties that are detrimental in specific applications. In an embodiment the cobalt based alloy is preferred not to be magnetic.

There are other applications wherein the presence of certain elements such as Re are detrimental for certain properties especially for embodiments containing Co, Si and Ti. For these applications in an embodiment containing Co, Si and Ti at the same time, Re is absent from the alloy.

There are several elements such as Ti, P, Zn and Ni that are detrimental in specific applications especially for some % Ga contents; for these applications in an embodiment with presence of % Ga, elements such as Ti and/or P and/or Zn are absent from the alloy. Even in another embodiment with presence of % Ga, elements such as Ti and/or P and/or Zn are absent from the alloy and/or elements such as Ni are present in the composition.

It has been found that for some applications, certain contents of elements such as Fe, Ni, Mn, and Al may be detrimental. For these applications, in an embodiment containing Fe and/or Ni, % Al is preferred below 2.9% and/or Mn is absent from the alloy. Even in another embodiment containing Fe and/or Ni, % Al is preferred above 13.1% and/or Mn is absent from the alloy.

For some applications it is desirable that the above alloys have a melting point below 890° C., preferably below 640° C., more preferably below 180° C. or even below 46° C.

There are some applications wherein the presence of compounds phase in the cobalt based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the Cobalt based alloy. There are other applications wherein the presence of compounds in the cobalt based alloy is beneficial. In another embodiment the % of compound phase in the Cobalt based alloy is above 0.0001%, in another embodiment is above 0.3%, in another embodiment is above 3%, in another embodiment is above 13%, in another is above 43% and even in another embodiment is above 73%.

For several applications it is especially interesting the use of cobalt based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Cobalt based alloy is used as a coating layer. In another embodiment the Cobalt based alloy is used as a coating layer with a thickness above 0.11 micrometres, in another embodiment the Cobalt based alloy is used as a coating layer with a thickness above 1.1 micrometres, in another embodiment the coating layer has a thickness above 21 micrometres, in another embodiment above 105 micrometres, in another embodiment above 510 micrometres, in another embodiment above 1.1 mm and even in another embodiment above 11 mm. For other applications a thinker layer is desired. In an embodiment the Cobalt based alloy is used as a coating layer with thickness below 17 mm, in another embodiment below 7.7 mm, in another embodiment below 537 micrometres, in another embodiment below 117 micrometres, in another embodiment below 27 micrometres and even in another embodiment below 7.7 micrometres.

There are several technologies that are useful to deposit the cobalt based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the cobalt based alloy being in powder form. In an embodiment the cobalt based alloy is manufactured in form of powder. In another embodiment the powder is spherical.

The present invention is particularly suitable for the manufacture of components that can benefit from the properties of cobalt and its alloys. Especially applications requiring high strength at elevated temperature, high elastic modulus and/or high densities (and resulting properties such as the ability to minimize vibration, . . . ). In this sense, applying certain rules of alloy design and thermo-mechanical treatments, it is possible obtain very interesting features for applications in chemical industry, energy transformation, transport, tools, other machines or mechanisms, etc.

The cobalt based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

Any of the above Co based alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment refers to a copper based alloy with the following composition, all percentages in weight percent:

| % Si: 0-50 | | % Al: 0-20; | % Mn: 0-20; |
|---|---|---|---|
| (commonly 0-20); | | | |
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-2; |
| % B: 0-5; | % Mg: 0-50 | | % Ni: 0-50; |
| | (commonly 0-20); | | |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5; | % 0: 0-15; | | |

The rest consisting on copper and trace elements

The nominal composition expressed herein can refer to particles with higher volume fraction and/or the general final composition. In cases where the presence of immiscible particles as ceramic reinforcements, graphene, nanotubes or other these are not counted on the nominal composition.

In this context trace elements refers to several elements, unless context clearly indicates otherwise, including but not limited to, H, He, Xe, F, Ne, Na, P, S, Cl, Ar, K, Br, Kr, Sr, Tc, Ru, Rh, Pd, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the alloy, such as reducing cost production of the alloy and/or its presence may be unintentional and related mostly to the presence of impurities in the alloying elements and scraps used for the production of the alloy.

There are several applications wherein the presence of trace elements is detrimental for the overall properties of the copper based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the copper based alloy.

There are applications wherein copper based alloys are benefited from having a high copper (% Cu) content but not necessary the copper being the majority component of the alloy. In an embodiment % Cu is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Al is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Cu is not the majority element in the copper based alloy.

For certain applications, it is especially interesting to use alloys with % Ga, % Bi, % Rb, % Cd, % Cs, % Sn, % Pb, % Zn and/or % In. Particularly interesting is the use of these low melting point promoting elements with the presence of % Ga of more than 2.2%, preferably more than 12%, more preferably 21% or more and even 54% or more. The copper alloy has in an embodiment % Ga in the alloy is above 32 ppm, in other embodiment above 0.0001%, in another embodiment above 0.015%, and even in other embodiment above 0.1%, in another embodiment generally has a 0.8% or more of the element (in this case % Ga), preferably 2.2% or more, more preferably 5.2% or more and even 12% or more. But there are other applications depending of the desired properties of the copper based alloy wherein % Ga contents of 30% or less are desired. In an embodiment the % Ga in the copper based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the copper based alloy. It has been found that in some applications the % Ga can be replaced wholly or partially by Bi % (until % Bi maximum content of 20% by weight, in case % Ga being greater than 20%, the replacement with % Bi will be partial) with the amounts described in this paragraph for % Ga+% Bi. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % In with the amounts described above in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the items in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

The case of scandium (Sc) is exemplifying, because using them very interesting mechanical properties may be reached, but its cost makes interesting from an economic point of view to use the amount needed for the application of interest. Its high deoxidizing power is also interesting during alloys processing but also a challenge to maximize performance. So depending on the application you can move from situations wherein is not a desired element, in these applications it is preferred % Sc being in a low concentration, in an embodiment less than 0.9%, in other embodiment less than 0.6%, in other embodiment less than 0.3%, in other embodiment less than 0.1%, in other embodiment less than 0.01% and even in other embodiment absent from the copper based alloy, to a situations wherein a high content of this element is desired, in an embodiment 0.6% by weight or more, in another embodiment preferably 1.1% by weight or more, in another embodiment more preferably 1.6% by weight or more and even in another embodiment 4.2% or more.

It has been found that for some applications copper alloys the presence of silicon (% Si) is desirable, typically in an embodiment in contents of 0.2% by weight or higher, in another embodiment preferably 1.2% or more, in another embodiment preferably 2.1% or more, in another embodiment more preferably 6% or more or even in another embodiment 11% or more. In contrast, in some applications the presence of this element is rather detrimental in which case contents of less than 0.2% by weight are desired, preferably less than 0.08%, more preferably less than 0.02% and even less than 0.004%. Obviously there are cases where the desired nominal content is 0% or nominal absence of the element as with all elements for certain applications. For other applications in an embodiment contents of less than 39.8% by weight are desired, in another embodiment contents of less than 23.6% by weight are desired, in another embodiment contents of less than 14.4% by weight are desired, in another embodiment contents of less than 9.7% by weight are desired, in another embodiment contents of less than 4.2% by weight are desired, in another embodiment contents of less than 3.4% by weight are desired, and even in another embodiment contents of less than 1.4% by weight are desired.

It has been found that for some applications of copper alloys the presence of iron (% Fe) is desirable, in an embodiment typically in contents of 0.3% by weight or higher, in another embodiment preferably 0.6% or more, in another embodiment more preferably 1.2% or more or even in another embodiment 6% or more. In contrast, in some applications the presence of this element is rather detrimental, in those cases in an embodiment contents of less than 19.8% by weight are desired, in another embodiment contents of less than 13.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, in another embodiment contents of less than 0.2% by weight are desired, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of aluminium (% Al) is desirable, typically in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of manganese (% Mn) is desirable, typically in an embodiment in content of 0.1% by weight or higher, in another embodiment preferably 0.6% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of magnesium (% Mg) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 34.8% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of Sn (% Sn) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of zinc (% Zn) is desirable, typically in an embodiment in content of 0.1% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of chromium (% Cr) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of titanium (% Ti) is desirable, typically in an embodiment in content of 0.05% by weight or higher, in another embodiment preferably 0.2% or more, in another embodiment more preferably 1.2% or more or even in another embodiment 4% or more. In contrast, in some applications the presence of this element is rather detrimental, in those cases in an embodiment contents of less than 23.8% by weight are desired, in another embodiment contents of less than 17.4% by weight are desired, in another embodiment contents of less than 13.6% by weight are desired, in another embodiment contents of less than 9.2% by weight are desired, in another embodiment contents of less than 4.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of zirconium (% Zr) is desirable, typically in an embodiment in content of 0.05% by weight or higher, in another embodiment preferably 0.2% or more, in another embodiment more preferably 1.2% or more or even in another embodiment 4% or more. In contrast, in some applications the presence of this element is rather detrimental, in those cases in an embodiment contents of less than 9.2% by weight are desired, in another embodiment contents of less than 7.1% by weight are desired, in another embodiment contents of less than 4.8% by weight are desired, in another embodiment contents of less than 3.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of copper alloys the presence of Boron (% B) is desirable, typically in an embodiment in content of 0.05% by weight or higher, in another embodiment preferably 0.2% or more, in another embodiment more preferably 0.42% or more or even in another embodiment 1.2% or more. In contrast, in some applications the presence of this element is rather detrimental, in those cases in an embodiment contents of less than 4.8% by weight are desired, in another embodiment contents of less than 3.3% by weight are desired, in another embodiment contents of less than 1.8% by weight are desired, are desired in an embodiment contents of less than 0.08% by weight, in another embodiment preferably less than 0.02%, in another embodiment more preferably less than 0.004% and even in another embodiment less than 0.0002%. Obviously there are cases where the desired nominal content is 0% or nominal absence of the element as occurs with all elements for certain applications.

It has been found that for some applications in aluminum alloys the presence of nitrogen (% N) is desirable, typically in contents of 0.2% by weight or higher, preferably 1.2% or more, more preferably 3.2% or more or even 4.8% or more. For some applications it is interesting that the consolidation and/or densification of the particles with aluminum is carried out in atmosphere with high nitrogen content thus often reaction occurs particularly if consolidation and/or densification (eg sintering with or without liquid phase) occurs at elevated temperatures, the nitrogen will react with the aluminum and/or other elements forming nitrides and thus will appear as an element in the final composition. In these cases it is often useful to have in the final composition a nitrogen content of 0.002% or higher, preferably 0.02% or higher, more preferably 0.4% or higher and even 2.2% or higher.

It has been found that for some applications, the excessive presence of molybdenum (% Mo) and/or tungsten (% W) may be detrimental, for these applications a lower % Mo+½% W content is desirable, in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the copper based alloy. In contrast there are applications where the presence of molybdenum and tungsten at higher levels is desirable, for these applications in an embodiment amounts of % Mo+½% W exceeding 1.2% by weight are desirable, in another embodiment preferably greater than 3.2% by weight, in another embodiment more preferably greater than 5.2% and even in another embodiment above 12%.

It has been found that for some applications, excessive presence of nickel (% Ni) may be detrimental, for these applications is desirable a % Ni content in an embodiment of less than 28%, in other embodiment preferably less than 19.8%, in other embodiment preferably less than 18%, in other embodiment preferably less than 14.8%, in other embodiment preferably less than 11.6%, in other embodiment more preferably less than 8%, and even in other embodiment less than 0.8% There are even some applications for a given application wherein in an embodiment % Ni is detrimental or not optimal for one reason or another, in these applications it is preferred % Ni being absent from the copper based alloy. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight in another embodiment amounts higher than 1.2% by weight are desired, in other embodiment higher than 2.2% by weight, in other embodiment preferably higher than 6% by weight, in other embodiment preferably higher than 8.3% by weight in other embodiment more preferably higher than 12%, in other embodiment more preferably higher than 16.2% and even in other embodiment higher than 22%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 7.4%, in other embodiment less than 4.1%, in other embodiment less than 2.6%, in other embodiment less than 1.3%. In an embodiment % As is detrimental or not optimal for one reason or another, in these applications it is preferred % As being absent from the copper based alloy.

There are applications wherein the presence of % Li in higher amounts is desirable for these applications in an embodiment is desirable % Li amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Li may be detrimental, for these applications is desirable % Li amount in an embodiment less than 7.4%, in other embodiment less than 4.1%, in other embodiment less than 2.6%, in other embodiment less than 1.3%. In an embodiment % Li is detrimental or not optimal for one reason or another, in these applications it is preferred % Li being absent from the copper based alloy.

There are applications wherein the presence of % V in higher amounts is desirable for these applications in an embodiment is desirable % V amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % V may be detrimental, for these applications is desirable % V amount in an embodiment less than 7.4%, in other embodiment less than 4.1%, in other embodiment less than 2.6%, in other embodiment less than 1.3%. In an embodiment % V is detrimental or not optimal for one reason or another, in these applications it is preferred % V being absent from the copper based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 7.4%, in other embodiment less than 4.1%, in other embodiment less than 2.6%, in other embodiment less than 1.3%. In an embodiment % Te is detrimental or not optimal for one reason or another, in these applications it is preferred % Te being absent from the copper based alloy.

There are applications wherein the presence of % La in higher amounts is desirable for these applications in an embodiment is desirable % La amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % La may be detrimental, for these applications is desirable % La amount in an embodiment less than 7.4%, in other embodiment less than 4.1%, in other embodiment less than 2.6%, in other embodiment less than 1.3%. In an embodiment % La is detrimental or not optimal for one reason or another, in these applications it is preferred % La being absent from the copper based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 7.4%, in other embodiment less than 4.1%, in other embodiment less than 2.6%, in other embodiment less than 1.3%. In an embodiment % Se is detrimental or not optimal for one reason or another, in these applications it is preferred % Se being absent from the copper based alloy.

It has been found that for some applications, the excessive presence of tantalum (% Ta) and/or niobium (% Nb) may be detrimental, for these applications is desirable % Ta+% Nb content in an embodiment of less than 14.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the copper based alloy. In contrast there are applications wherein higher amounts of % Ta and/or % Nb are desirable, especially % Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 7.4%, in other embodiment less than 4.1%, in other embodiment less than 2.6%, in other embodiment less than 1.3%. In an embodiment % Ca is detrimental or not optimal for one reason or another, in these applications it is preferred % Ca being absent from the copper based alloy.

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the copper based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, and even in another embodiment greater than 22%. There are other applications wherein it is desirable the % Co in an embodiment above 0.0001%, in other embodiment above 0.15%, in other embodiment above 0.9%, and even in other embodiment above 1.6%.

There are applications wherein the presence of % Hf in higher amounts is desirable for these applications in an embodiment is desirable % Hf amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Hf may be detrimental, for these applications is desirable % Hf amount in an embodiment less than 4.4%, in other embodiment less than 3.1%, in other embodiment less than 2.7%, in other embodiment less than 1.4%. In an embodiment % Hf is detrimental or not optimal for one reason or another, in these applications it is preferred % Hf being absent from the copper based alloy.

There are applications wherein the presence of Germanium (% Ge) is desired. In an embodiment, the % Ge is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Ge may be limited. In other embodiment the % Ge is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Ge is detrimental or not optimal for one reason or another, in these applications it is preferred % Ge being absent from the copper based alloy.

There are applications wherein the presence of antimony (% Sb) is desired. In an embodiment, the % Sb is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Sb may be limited. In other embodiment the % Sb is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Sb is detrimental or not optimal for one reason or another, in these applications it is preferred % Sb being absent from the copper based alloy.

There are applications wherein the presence of cerium (% Ce) is desired. In an embodiment, the % Ce is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Ce may be limited. In other embodiment the % Ce is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Ce is detrimental or not optimal for one reason or another, in these applications it is preferred % Ce being absent from the copper based alloy.

There are applications wherein the presence of beryllium (% Be) is desired. In an embodiment, the % Mo is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Be may be limited. In other embodiment the % Be is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Be is detrimental or not optimal for one reason or another, in these applications it is preferred % Be being absent from the copper based alloy.

The elements described in the preceding paragraphs may be desired separately or the combination of some of them or even all of them, as expected.

It has been seen that for some applications the excessive content of cesium, tantalum and thallium and can be detrimental, for these applications it is desirable the sum of % Cs+% Ta+% Tl less than 0.29, preferably less than 0.18%, more preferably less than 0.8%, and even less than 0.08% (without being mentioned, as in all instances in this document where amounts are mentioned as upper limits, 0% nominal content or nominal absence of the element, it is not only possible but is often desirable).

It has been seen that for some applications the excessive content of gold and silver can be detrimental, for these applications in an embodiment it is desirable the sum of % Au+% Ag less than 0.09%, in another embodiment preferably less than 0.04%, in another embodiment more preferably less than 0.008%, and even in another embodiment less than 0.002%.

It has been found that for some applications when high contents of % Ga and % Mg (both above 0.5%), it is often desirable to have hardening elements for solid solution, precipitation or hard second phase forming particles. In this sense, the sum % Mn+% Si+% Fe+% Al+% Cr+% Zn+% V+% Ti+% Zr for these applications, in an embodiment is desirably greater than 0.002% by weight in another embodiment preferably greater than 0.02%, in another embodiment more preferably greater than 0.3% and even in another embodiment higher than 1.2%.

It has been found that for some applications when % Ga content is lower than 0.1%, it is often desirable to have some limitation in hardening elements for solid solution, precipitation or hard second phase forming particles. In this sense, in an embodiment the sum % Al+% Si+% Zn is desirably less than 21% by weight for these applications, in another embodiment preferably less than 18%, in another embodiment more preferably less than 9% or even in another embodiment less than 3.8%.

It has been found that for some applications when content % Ga below 1% and there is significant presence of % Cr (between 3% and 5%), it is often desirable to have hardening elements for solid solution or precipitation or forming hard particles second stage. In this sense, the sum % Mg+% Al in an embodiment is desirably higher than 0.52% by weight for these applications, in another embodiment preferably greater than 0.82%, more preferably greater than 1.2% and even higher than 3.2%. and/or the sum of % Ti+% Zr is desirable in another embodiment exceeds 0.012% by weight, preferably in another embodiment greater than 0055%, more preferably in another embodiment greater than 0.12% by weight and even in another embodiment higher than 0.55%.

It has been found that for some applications, especially those requiring a high mechanical strength, high resistance to high temperatures and/or high corrosion resistance, which can be very beneficial combination of gallium (% Ga) and scandium (% Sc). For these applications it is often desirable in an embodiment to have contents above 0.12% Sc wt %, preferably above 0.52%, more preferably greater than 0.82% and even above 1.2% For these applications simultaneously is often desirable to have Ga in excess of 0.12% wt %, preferably above 0.52%, more preferably greater than 0.8%, more preferably greater than 2.2 more % and even higher 3.5%. For some of these applications is also interesting to further magnesium (% Mg), in another embodiment it is often desirable to have % Mg above 0.6% by weight, preferably greater than 1.2%, more preferably in another embodiment greater than 4.2% and even in another embodiment more than 6%. For some of these applications, especially improved resistance to corrosion is required, it is also interesting for the presence of zirconium (% Zr), in another embodiment often in excess of 0.06% weight amounts, preferably above in another embodiment 0.22%, more preferably in another embodiment above 0.52% and even in another embodiment greater than 1.2%. Obviously, like all other paragraphs herein any other element may be present in the amounts described in the preceding and coming paragraphs.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Ag and Mn that are detrimental in specific applications especially for certain Ga contents; For these applications in an embodiment with % Ga between 4.3% and 16.7%, % Ag is below 18.8%, or even Ag is absent from the composition. In another embodiment with % Ga between 4.3% and 16.7%, % Ag is above 44%. In another embodiment with % Ga between 4.3% and 12.7%, % Mn is below 7.8%, or even Mn is absent from the composition. Even in another embodiment with % Ga between 4.3% and 12.7%, % Mn is above 14.8%. %. In another embodiment with % Ga between 1.5% and 4.1%, % Ag is below 5.8%, or even Ag is absent from the composition. Even in another embodiment with % Ga between 1.5% and 4.1%, % Ag is above 10.8%.

There are several elements such as P, S, As, Pb and B that are detrimental in specific applications especially for certain Ga contents; For these applications in an embodiment with % Ga between 0.0008% and 6.3%, at least one of P, S, As, Pb and B are absent from the composition.

It has been found that for some applications, certain contents of elements such as P may be detrimental especially for certain Fe and/or Co contents. For these applications in an embodiment with % Fe between 0.0087% and 3.8%, % P is lower than 0.0087% or even P is absent from the composition. In another embodiment with % Fe between 0.0087% and 3.8%, % P is higher than 0.17%, in another embodiment with % Fe between 0.0087% and 3.8%, % P is higher than 0.35%, in another embodiment with % Fe between 0.0087% and 3.8%, % P is higher than 0.56% and even in another embodiment with % Fe between 0.0087% and 3.8%, % P is higher than 1.8%. In another embodiment with % Co between 0.0087% and 3.8%, % P is lower than 0.008% or even absent from the composition. Even in another embodiment with Co between 0.0087% and 3.8%, % P is higher than 0.68%.

There are several applications wherein the presence of Si, P, Sn and Fe in the composition is detrimental for the overall properties of the copper based alloy especially for certain Ni and/or Zn contents. In an embodiment with % Ni between 0.34% and 5.2%, % Si is below 0.03% or even absent from the composition or % Si is above 2.3%. Even in another embodiment with % Ni between 0.087% and 32.8%, % P is below 0.087% or absent from the composition or % P is above 0.48% and/or % Sn is below 0.08% or even absent or % Sn is above 3.87%. In another embodiment with % Ni between 0.87% and 2.8%, % Fe is below 1.22% or absent from the composition or % Fe is above 3.24%. Even in another embodiment with % Zn between 0.087% and 4.2%, % Si is below 4.1% or % Si is higher than 6.1%. In another embodiment where the copper alloy contains Zn, % P is absent from the composition or % P is above 45 ppm.

There are several elements such as P, Sb, As and Bi that are detrimental in specific applications; For these applications in an embodiment at least one of P, Sb, As and Bi are absent from the composition.

There are several applications wherein the presence of Nb and Ti in the composition is detrimental for the overall properties of the copper based alloy especially for certain Fe and/or Cr contents. In an embodiment with % Fe and/or % Cr above 0.0086%, % Nb and/or % Ti is below 0.087% or even absent from the composition.

There are several elements such as Cd, Cr, Co, Pd and Si that are detrimental in specific applications especially for certain Ga, Ge and Sb contents; For these applications in an embodiment containing Ga and/or Ge and/or Sb, at least one of Cd, Cr, Co, Pd and Si are absent from the composition.

It has been found that for some applications, certain contents of elements such as In, Eu, Tm, Cr, Co, B and Si may be detrimental especially for certain Ga contents. For these applications in an embodiment with % Ga between 0.087% and 0.31%, % Cr is lower than 0.77% and/or % Co is lower than 0.97% or even at least one of them absent from the composition. In another embodiment with % Ga between 0.087% and 0.31%, % Cr is higher than 1.77% and/or % Co is higher than 1.97%. In an embodiment with % Ga between 2.37% and 7.31%, % Si is lower than 17.7% and/or % B is lower than 1.27% or even at least one of them absent from the composition. In another embodiment with % Ga between 2.37% and 6.31%, % Si is higher than 27.7% and/or % B is higher than 5.17%. Even in another an embodiment with % Ga between 0.37% and 1.31%, % In is lower than 4.7% even absent from the composition. In another embodiment with % Ga between 0.37% and 1.31%, % In is higher than 11.7%. In another embodiment with % Ga between 0.025% and 0.061%, % Eu is below 0.025% and/or % Tm is below 0.015% or even at least one of them absent from the composition. In an embodiment with % Ga between 0.025% and 0.061%, % Eu is above 0.051% and/or % Tm is above 0.041%.

There are several elements such as Co that are detrimental in specific applications especially for certain Al contents; For these applications in an embodiment with % Al between 5.3% and 14.3%, % Co is lower than 0.37% or even is absent from the composition. In another embodiment with % Al between 5.3% and 14.3%, % Co is higher than 3.37%

There are several elements such as rare earth elements (RE) that are detrimental in specific applications; For these applications in an embodiment RE are absent from the composition.

There are some applications wherein the presence of compounds phase in the copper based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the copper based alloy. There are other applications wherein the presence of compounds in the copper based alloy is beneficial. In another embodiment the % of compound phase in the copper based alloy is above 0.0001%, in another embodiment is above 0.3%, in another embodiment is above 3%, in another embodiment is above 13%, in another is above 43% and even in another embodiment is above 73%.

For some applications it is desirable that the above alloys have a melting point below 890° C., preferably below 640° C. the, more preferably below 180° C. or even below 46° C.

Any of the above Cu alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an copper alloy for manufacturing metallic or at least partially metallic components.

In an embodiment the invention refers to a molybdenum based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-2 | % Mn = 0-3 |
| % Al = 0-15 | % Mo = 0-20 | % Ni = 0-50 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % Re = 0-50 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |

The rest consisting on Molybdenum (Mo) and trace elements

wherein % Ceq=% C+0.86*% N+1.2*% B

There are applications wherein molybdenum based alloys are benefited from having a high molybdenum (% Mo) content but not necessary the molybdenum being the majority component of the alloy. In an embodiment % Mo is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Mo is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Mo is not the majority element in the molybdenum based alloy.

In this context trace elements refers to several elements, unless context clearly indicates otherwise, including but not limited to: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the molybdenum based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the molybdenum based alloy.

There are other applications wherein the presence of trace elements may reduce the cost of the alloy or attain any other additional beneficial effect without affecting the molybdenum based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For several applications it is especially interesting the use of alloys containing % Ga % Bi, % Rb, % Cd, % Cs, % Sn, % Pb, % Zn and/or % In. Particularly interesting is the use of these low melting point promoting elements with the presence of more than 2.2% in weight of % Ga, preferably more than 12%, more preferably 21% and even more than 24.2% or more Once incorporated and evaluating the overall composition measured as indicated in this application, the molybdenum resulting alloy in an embodiment above 0.0001%, in another embodiment above 0.015%, in another embodiment above 0.03%, and even in other embodiment above 0.1%, in another embodiment has generally a 0.2% or more of the element (in this case % Ga), in another embodiment preferably 1.2% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. But there are other applications depending of the desired properties of the molybdenum based alloy wherein % Ga contents of 30% or less are desired. In an embodiment the % Ga in the molybdenum based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the molybdenum based alloy. It has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+Bi %. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications in an embodiment is desirable a % Cr content of less than 39% by weight, in another embodiment preferably less than 18%, in another embodiment more preferably less than 8.8% by weight and even in another embodiment less than 1.8%. There are other applications wherein even a lower % Cr content is desired, in an embodiment the % Cr in the molybdenum based alloy is less than 1.6%, in other embodiment less than 1.2%, in other embodiment less than 0.8%, in other embodiment less than 0.4%. There are even some applications for a given application wherein in an embodiment % Cr is detrimental or not optimal for one reason or another, in these applications it is preferred % Cr being absent from the molybdenum based alloy. By contrast there are applications wherein the presence of chromium at higher levels is desirable, especially when a high corrosion resistance and/or resistance to oxidation at high temperatures is required for these applications; for these applications in an embodiment amounts exceeding 2.2% by weight are desirable, in another embodiment preferably above 3.6%, in another embodiment preferably greater than 5.5% by weight, more preferably above 6.1%, more preferably above 8.9%, more preferably above 10.1%, more preferably above 13.8%, more preferably above 16.1%, more preferably above 18.9%, in another embodiment more preferably over 22%, more preferably above 26.4%, and even in another embodiment greater than 32%. But there are also other applications wherein a lower preferred minimum content is desired. In an embodiment, the % Cr in the molybdenum based alloy is above 0.0001%, in other embodiment above 0.045%, n other embodiment above 0.1%, in other embodiment above 0.8%, and even in other embodiment above 1.3%. There are other applications wherein a high content of % Cr is desired. In another embodiment of the invention the % Cr in the alloy is above 42.2%, and even above 46.1%.

It has been seen that for some applications the presence of excessive aluminum (% Al) can be detrimental, for these applications is desirable in an embodiment a % Al content of less than 12.9%, in another embodiment preferably less than 10.4%, in another embodiment preferably less than 8.4%, in another embodiment less than 7.8% by weight, in another embodiment preferably less than 6.1%, in another embodiment preferably less than 4.8%, preferably less than 3.4%, preferably less than 2.7%, in another embodiment more preferably less than 1.8% by weight and even in another embodiment less than 0.8%. There are even some applications for a given application wherein in an embodiment % Al is detrimental or not optimal for one reason or another, in these applications it is preferred % Al being absent from the molybdenum based alloy. In contrast there are applications wherein the presence of aluminum at higher levels is desirable, especially when a high hardening and/or environmental resistance are required, for these applications in an embodiment are desirable amounts, in another embodiment greater than 1.2% by weight, in another embodiment preferably greater than 2.4% preferably greater than 3.2% by weight, in another embodiment preferably greater than 4.8%, in another embodiment preferably greater than 6.1%, in another embodiment preferably greater than 7.3%, in another embodiment more preferably above 8.2% and even in another embodiment above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the molybdenum based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, in another embodiment more preferably greater than 22% and even in another embodiment greater than 32%. There are other applications wherein it is desirable the % Co in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 1.4% by weight, in another embodiment preferably less than 1.4%, in another embodiment preferably less than 1.1%, in another embodiment preferably less than 0.8%, in another embodiment more preferably less than 0.46% by weight and even in another embodiment less than 0.08%. There are even some applications for a given application wherein in an embodiment % Ceq is detrimental or not optimal for one reason or another, in these applications it is preferred % Ceq being absent from the molybdenum based alloy. In contrast there are applications wherein the presence of carbon equivalent in higher amounts is desirable for these applications in an embodiment amounts exceeding 0.12% by weight are desirable, in another embodiment preferably greater than 0.52% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 0.38% by weight, in another embodiment preferably less than 0.26%, in another embodiment preferably less than 0.18%, in another embodiment more preferably less than 0.09% by weight and even in another embodiment less than 0.009%. There are even some applications for a given application wherein in an embodiment % C is detrimental or not optimal for one reason or another, in these applications it is preferred % C being absent from the tmolybdenum based alloy. In contrast there are applications where the presence of carbon at higher levels is desirable, especially when an increase on mechanical strength and/or hardness is desired. For these applications in an embodiment amounts exceeding 0.02% by weight are desirable, preferably in another embodiment greater than 0.12% by weight, in another embodiment more preferably greater than 0.22% and even in another embodiment greater than 0.32%.

It has been found that for some applications, the excessive presence of boron (% B) may be detrimental, for these applications in an embodiment is desirable a % B content of less than 0.9% by weight, in another embodiment preferably less than 0.65%, in another embodiment preferably less than 0.4%, in another embodiment more preferably less than 0.16% by weight and even in another embodiment less than 0.006%. There are even some applications for a given application wherein in an embodiment % B is detrimental or not optimal for one reason or another, in these applications it is preferred % B being absent from the molybdenum based alloy. In contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.4%, in another embodiment more preferably less than 0.16% by weight and even in another embodiment less than 0.006%. There are even some applications for a given application wherein in an embodiment % N is detrimental or not optimal for one reason or another, in these applications in an embodiment it is preferred % N being absent from the molybdenum based alloy. In contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.1%, and even in another embodiment preferably above 0.35%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of zirconium (% Zr) and/or hafnium (% Hf) may be detrimental, for these applications in an embodiment is desirable a content of % Zr+% Hf of less than 12.4% by weight, in another embodiment less than 9.8%, in another embodiment less than 7.8% by weight, I in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Zr and/or % Hf are detrimental or not optimal for one reason or another, in these applications in an embodiment it is preferred % Zr and/or % Hf being absent from the molybdenum based alloy. In contrast there are applications where the presence of some of these elements at higher levels is desirable, especially where a high hardening and/or environmental resistance is required, for these applications in an embodiment amounts of % Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 12%.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the molybdenum based alloy. In contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, the excessive presence of Vanadium (% V) may be detrimental, for these applications in an embodiment is desirable % V content less than 6.3%, in another embodiment less than 4.8% by weight, in another embodiment less than 3.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the molybdenum based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 1.2% by weight, in another embodiment more preferably greater than 2.2% and even in another embodiment above 4.2%.

It has been that for some applications, excessive presence of copper (% Cu) may be detrimental, for these applications in an embodiment is desirable % Cu content of less than 14% by weight, in another embodiment preferably less than 12.7%, in another embodiment preferably less than 9%, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the molybdenum based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 2.55% by weight, in another embodiment greater than 3.6% by weight, in another embodiment greater than 4.7% by weight, in another embodiment greater than 6% by weight are desirable, in another embodiment preferably greater than 8% by weight, in another embodiment more preferably above 12% and even in another embodiment exceeding 16%.

It has been that for some applications the presence of excessive iron (% Fe) may be detrimental, for these applications in an embodiment is desirable % Fe content of less than 58% by weight, in another embodiment preferably less than 36%, in another embodiment preferably less than 24%, preferably less than 18%, in another embodiment more preferably less than 12% by weight, in another embodiment more preferably less than 10.3% by weight, and even in another embodiment less than 7.5%, even in another embodiment less than 5.9%, in another embodiment less than 3.7%, in another embodiment less than 2.1%, or even in another embodiment less than 1.3%. There are even some applications for a given application wherein % Fe is detrimental or not optimal for one reason or another, in these applications in an embodiment it is preferred % Fe being absent from the molybdenum based alloy. In contrast there are applications where the presence of iron at higher levels is desirable, for these applications are desirable amounts in an embodiment greater than 0.1% by weigh, in another embodiment greater than 1.3% by weight, g in another embodiment greater than 2.7% by weight, in another embodiment greater than 4.1% by weight, in another embodiment greater than 6% by weight, in another embodiment preferably greater than 8% by weight, in another embodiment more preferably greater than 22% and even in another embodiment greater than 42%.

It has been found that for some applications, the excessive presence of titanium (% Ti) may be detrimental, for these applications is desirable % Ti content in an embodiment of less than 9% by weight, in another embodiment preferably less than 7.6%, in another embodiment preferably less than 6.1%, in another embodiment preferably less than 4.5%, in another embodiment preferably less than 3.3%, in another embodiment more preferably less than 2.9% by weight, in another embodiment more preferably less than 1.8, and even in another embodiment less than 0.9%. There are even some applications for a given application wherein % Ti is detrimental or not optimal for one reason or another, in these applications in an embodiment it is preferred % Ti being absent from the molybdenum based alloy. In contrast there are applications where the presence of titanium in higher amounts is desirable, especially when an increase on mechanical properties at high temperatures are desired. For these applications are desirable amounts in an embodiment greater than 0.01%, in another embodiment greater than 0.2%, in another embodiment greater than 0.7%, in another embodiment greater than 1.2% by weight, in another embodiment preferably greater than 3.2% by weight, in another embodiment preferably greater than 4.1% by weight, in another embodiment more preferably above 6% or even in another embodiment above 12%.

It has been found that for some applications, the excessive presence of tantalum (% Ta) and/or niobium (% Nb) may be detrimental, for these applications is desirable % Ta+% Nb content in an embodiment of less than 17.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the molybdenum based alloy. In contrast there are applications wherein higher amounts of % Ta and/or % Nb are desirable, especially Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

It has been found that for some applications, the excessive presence of yttrium (% Y), cerium (% Ce) and/or lanthanide (% La) may be detrimental, for these applications is desirable % Y+% Ce+% La content in an embodiment of less than 12.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Y and/or % Ce and/or % La are detrimental or not optimal for one reason or another, in these applications in an embodiment it is preferred % Y and/or % Ce and/or % La being absent from the molybdenum based alloy. In contrast there are applications wherein higher amounts are desirable, especially when a high hardness is desired, for these applications in an embodiment is desired an amount of % Y+% Ce+% La greater than 0.1% by weight, in another embodiment preferably greater than 1.2% by weight, in another embodiment preferably greater than 2.1% by weight, in another embodiment more preferably above 6% or even in another embodiment above 12%.

It has been found that for some applications, the excessive presence of rhenium (% Re) may be detrimental, for these applications is desirable % Re content less than 41.8% by weight, preferably less than 24.8%, more preferably less than 11.78% by weight and even less than 1.45%. In contrast there are applications wherein the presence of rhenium in higher amounts is desirable for these applications are desirable amounts exceeding 0.6% by weight, preferably greater than 1.2% by weight, more preferably greater than 13.2%, even above 22.2%. There are even applications wherein in an embodiment % Re is detrimental or not optimal for one reason or another, in these applications it is preferred % Re being absent from the alloy.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the molybdenum based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the molybdenum based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the molybdenum based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the molybdenum based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the molybdenum based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the molybdenum based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % Sb being absent from the molybdenum based alloy.

There are applications wherein the presence of % Si in higher amounts is desirable, especially when an increase on strength and/or resistance to oxidation is desired. For these applications in an embodiment is desirable % Si amount above 0.0001%, in other embodiment above 0.15%, in other embodiment above 0.9%, and even in other embodiment above 1.3%. In contrast it has been found that for some applications, the excessive presence of % Si may be detrimental, for these applications is desirable % Si amount in an embodiment less than 1.4%, in other embodiment less than 0.8%, in other embodiment less than 0.4%, in other embodiment less than 0.2%. In an embodiment % Si is detrimental or not optimal for one reason or another, in these applications it is preferred % Si being absent from the molybdenum based alloy.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.0001%, in other embodiment above 0.15%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%. In an embodiment % Mn is detrimental or not optimal for one reason or another, in these applications it is preferred % Mn being absent from the molybdenum based alloy.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the molybdenum based alloy.

It has been found that for some applications, excessive presence of nickel (% Ni) may be detrimental, for these applications is desirable a % Ni content in an embodiment of less than 28%, in other embodiment preferably less than 19.8%, in other embodiment preferably less than 18%, in other embodiment preferably less than 14.8%, in other embodiment preferably less than 11.6%, in other embodiment more preferably less than 8%, and even in other embodiment less than 0.8% There are even some applications for a given application wherein in an embodiment % Ni is detrimental or not optimal for one reason or another, in these applications it is preferred % Ni being absent from the molybdenum based alloy. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight in another embodiment amounts higher than 1.2% by weight are desired, in other embodiment higher than 2.2% by weight, in other embodiment preferably higher than 6% by weight, in other embodiment preferably higher than 8.3% by weight in other embodiment more preferably higher than 12%, in other embodiment more preferably higher than 16.2% and even in other embodiment higher than 22%.

For some applications it is desirable that the above alloys have a melting point below 890° C., preferably below 640° C., more preferably below 180° C. or even below 46° C.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are some applications wherein the presence of compounds phase in the molybdenum based alloy is detrimental. In an embodiment the % of compound phase in the alloy is below 79%, in another embodiment is below 49%, in another embodiment is below 19%, in another embodiment is below 9%, in another embodiment is below 0.9% and even in another embodiment compounds are absent from the composition. There are other applications wherein the presence of compounds in the molybdenum based alloy is beneficial. In another embodiment % of compound phase in the alloy is above 0.0001%, in another embodiment is above 0.3%, in another embodiment is above 3%, in another embodiment is above 13%, in another embodiment is above 43% and even in another embodiment the is above 73%.

For several applications it is especially interesting the use of molybdenum based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Molybdenum based alloy is used as a coating layer. In In an embodiment the molybdenum based alloy is used as a coating layer with thickness above 1.1 micrometer, in another embodiment the molybdenum based alloy is used as a coating layer with thickness above 21 micrometer, in another embodiment the molybdenum based alloy is used as a coating layer with thickness above 10 micrometre, in another embodiment the molybdenum based alloy is used as a coating layer with thickness above 510 micrometre, in another embodiment the molybdenum based alloy is used as a coating layer with thickness above 1.1 mm and even in another embodiment the molybdenum based alloy is used as a coating layer with thickness above 11 mm. In another embodiment the molybdenum based alloy is used as a coating layer with thickness below 27 mm, in another embodiment the molybdenum based alloy is used as a coating layer with thickness below 17 mm, in another embodiment the molybdenum based alloy is used as a coating layer with thickness below 7.7 mm, in another embodiment the molybdenum based alloy is used as a coating layer with thickness below 537 micrometer, in another embodiment the molybdenum based alloy is used as a coating layer with thickness below 117 micrometre, in another embodiment the molybdenum based alloy is used as a coating layer with thickness below 27 micrometre and even in another embodiment the molybdenum based alloy is used as a coating layer with thickness below 7.7 micrometre.

For several applications it is especially interesting the use of molybdenum based alloy having a high mechanical resistance. For those applications in an embodiment the resultant mechanical resistance of the molybdenum based alloy is above 52 MPa, in another embodiment the resultant mechanical resistance of the alloy is above 72 MPa, in another embodiment the resultant mechanical resistance of the alloy is above 82 MPa, in another embodiment the resultant mechanical resistance of the alloy is above 102 MPa, in another embodiment the resultant mechanical resistance of the alloy is above 112 MPa and even in another embodiment the resultant mechanical resistance of the alloy is above 122 MPa. In another embodiment the resultant mechanical resistance of the alloy is below 147 MPa, in another embodiment the resultant mechanical resistance of the alloy is below 127 MPa, in another embodiment the resultant mechanical resistance of the alloy is below 117 MPa, in another embodiment the resultant mechanical resistance of the alloy is below 107 MPa, in another embodiment the resultant mechanical resistance of the alloy is below 87 MPa, in another embodiment the resultant mechanical resistance of the alloy is below 77 MPa and even in another embodiment the resultant mechanical resistance of the alloy is below 57 MPa.

There are several technologies that are useful to deposit the molybdenum based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the molybdenum based alloy being in powder form. In an embodiment the molybdenum based alloy is manufactured in form of powder. In another embodiment the powder is spherical. In an embodiment refers to a spherical powder with a particle size distribution which may be unimodal, bimodal, trimodal and even multimodal depending of the specific application requirements.

The present invention is particularly suitable for the manufacture of components that can benefit from the properties of molybdenum and its alloys. Especially applications requiring high mechanical resistance at high temperatures. In this sense, applying certain rules of alloy design and thermo-mechanical treatments, it is possible obtain very interesting features for applications in chemical industry, energy transformation, transport, tools, other machines or mechanisms, etc.

The molybdenum based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

Any of the above Mo based alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of molybdenum based alloy for manufacturing metallic or at least partially metallic components.

In an embodiment the invention refers to a tungsten based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-2 | % Mn = 0-3 |
| % Al = 0-15 | % Mo = 0-20 | % Ni = 0-50 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % K = 0-600 ppm | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |
| % Re = 0-50 | | | |

The rest consisting on Tungsten O) and trace elements

wherein % Ceq=% C+0.86*% N+1.2*% B

There are applications wherein tungsten based alloys are benefited from having a high tungsten (% w) content but not necessary the tungsten being the majority component of the alloy. In an embodiment % W is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % W is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % W is not the majority element in the tungsten based alloy.

In this context trace elements refers to several elements, unless context clearly indicates otherwise, including but not limited to: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the tungsten based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the tungsten based alloy.

There are several elements such as % K that are detrimental in specific applications. In an embodiment the % K in the tungsten based alloy is preferred below 1.98 ppm, and even in another embodiment K is preferred to be absent from the alloy.

There are other applications wherein the presence of trace elements may reduce the cost of the alloy or attain any other additional beneficial effect without affecting the tungsten based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For several applications it is especially interesting the use of alloys containing % Ga % Bi, % Rb, % Cd, % Cs, % Sn, % Pb, % Zn and/or % In. Particularly interesting is the use of these low melting point promoting elements with the presence of more than 2.2% in weight of % Ga, preferably more than 12%, more preferably 21% and even more than 54% or more Once incorporated and evaluating the overall composition measured as indicated in this application, the tungsten resulting alloy in an embodiment % Ga in the alloy is above 32 ppm, in other embodiment above 0.0001%, in another embodiment above 0.015%, and even in other embodiment above 0.1%, in another embodiment has generally a 0.2% or more of the element (in this case % Ga), in another embodiment preferably 1.2% or more, in another embodiment more preferably 6% or more, and even in another embodiment 12% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. But there are other applications depending of the desired properties of the tungsten based alloy wherein % Ga contents of 30% or less are desired. In an embodiment the % Ga in the tungsten based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the tungsten based alloy. It has been found that in some applications the % Ga can be replaced wholly or partially by % Bi (until % Bi maximum content of 10% by weight, in case % Ga being greater than 10%, the replacement with % Bi will be partial) with the amounts described above in this paragraph for % Ga+Bi %. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % with the amounts described in this paragraph, in this case for % Ga+% Bi+% Cd+% Cs+% Sn+% Pb+% Zn+% Rb+% In, wherein depending on the application may be interesting the absence of any of them (ie although the sum is in line with the values given any element can be absent and have a nominal content of 0%, this being advantageous for a given application wherein the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications in an embodiment is desirable a % Cr content of less than 39% by weight, in another embodiment preferably less than 18%, in another embodiment more preferably less than 8.8% by weight and even in another embodiment less than 1.8%. There are other applications wherein even a lower % Cr content is desired, in an embodiment the % Cr in the tungsten bases alloy is less than 1.6%, in other embodiment less than 1.2%, in other embodiment less than 0.8%, in other embodiment less than 0.4%. There are even some applications for a given application wherein in an embodiment % Cr is detrimental or not optimal for one reason or another, in these applications it is preferred % Cr being absent from the tungsten based alloy. By contrast there are applications wherein the presence of chromium at higher levels is desirable, especially when a high corrosion resistance and/or resistance to oxidation at high temperatures is required for these applications; for these applications in an embodiment amounts exceeding 2.2% by weight are desirable, in another embodiment preferably above 3.6%, in another embodiment preferably greater than 5.5% by weight, more preferably above 6.1%, more preferably above 8.9%, more preferably above 10.1%, more preferably above 13.8%, more preferably above 16.1%, more preferably above 18.9%, in another embodiment more preferably over 22%, more preferably above 26.4%, and even in another embodiment greater than 32%. But there are also other applications wherein a lower preferred minimum content is desired. In an embodiment, the % Cr in the tungsten based alloy is above 0.0001%, in other embodiment above 0.045%, n other embodiment above 0.1%, in other embodiment above 0.8%, and even in other embodiment above 1.3%. There are other applications wherein a high content of % Cr is desired. In another embodiment of the invention the % Cr in the alloy is above 42.2%, and even above 46.1%.

It has been seen that for some applications the presence of excessive aluminum (% Al) can be detrimental, for these applications is desirable in an embodiment a % Al content of less than 12.9%, in another embodiment preferably less than 10.4%, in another embodiment preferably less than 8.4%, in another embodiment less than 7.8% by weight, in another embodiment preferably less than 6.1%, in another embodiment preferably less than 4.8%, preferably less than 3.4%, preferably less than 2.7%, in another embodiment more preferably less than 1.8% by weight and even in another embodiment less than 0.8%. There are even some applications for a given application wherein in an embodiment % Al is detrimental or not optimal for one reason or another, in these applications it is preferred % Al being absent from the tungsten based alloy. In contrast there are applications wherein the presence of aluminum at higher levels is desirable, especially when a high hardening and/or environmental resistance are required, for these applications in an embodiment are desirable amounts, in another embodiment greater than 1.2% by weight, in another embodiment preferably greater than 2.4% preferably greater than 3.2% by weight, in another embodiment preferably greater than 4.8%, in another embodiment preferably greater than 6.1%, in another embodiment preferably greater than 7.3%, in another embodiment more preferably above 8.2% and even in another embodiment above 12%.

It has been found that for some applications, the excessive presence of rhenium (% Re) may be detrimental, for these applications is desirable % Re content less than 41.8% by weight, preferably less than 24.8%, more preferably less than 11.78% by weight and even less than 1.45%. In contrast there are applications wherein the presence of rhenium in higher amounts is desirable for these applications are desirable amounts exceeding 0.6% by weight, preferably greater than 1.2% by weight, more preferably greater than 13.2%, even above 22.2%. There are even applications wherein in an embodiment % Re is detrimental or not optimal for one reason or another, in these applications it is preferred % Re being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another). For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the tungsten based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, in another embodiment more preferably greater than 22% and even in another embodiment greater than 32%. There are other applications wherein it is desirable the % Co in an embodiment above 0.0001%, in other embodiment above 0.15%, in other embodiment above 0.9%, and even in other embodiment above 1.6%.

It has been seen that for some applications the presence of excessive carbon equivalent (% Ceq) may be detrimental, for these applications is desirable a % Ceq content in an embodiment of less than 1.4% by weight, in another embodiment preferably less than 1.4%, in another embodiment preferably less than 1.1%, in another embodiment preferably less than 0.8%, in another embodiment more preferably less than 0.46% by weight and even in another embodiment less than 0.08%. There are even some applications for a given application wherein in an embodiment % Ceq is detrimental or not optimal for one reason or another, in these applications it is preferred % Ceq being absent from the tungsten based alloy. In contrast there are applications wherein the presence of carbon equivalent in higher amounts is desirable for these applications in an embodiment amounts exceeding 0.12% by weight are desirable, in another embodiment preferably greater than 0.52% by weight, in another embodiment more preferably greater than 0.82% and even in another embodiment greater than 1.2%.

It has been found that for some applications, the presence of excess carbon (% C) may be detrimental, for these applications is desirable a % C content in an embodiment of less than 0.38% by weight, in another embodiment preferably less than 0.26%, in another embodiment preferably less than 0.18%, in another embodiment more preferably less than 0.09% by weight and even in another embodiment less than 0.009%. There are even some applications for a given application wherein in an embodiment % C is detrimental or not optimal for one reason or another, in these applications it is preferred % C being absent from the tungsten based alloy. In contrast there are applications where the presence of carbon at higher levels is desirable, especially when an increase on mechanical strength and/or hardness is desired. For these applications in an embodiment amounts exceeding 0.02% by weight are desirable, preferably in another embodiment greater than 0.12% by weight, in another embodiment more preferably greater than 0.22% and even in another embodiment greater than 0.32%.

It has been seen that for some applications, the excessive presence of potassium (% K) may be detrimental, for these applications is desirable a % K content of less than 528 ppm by weight, preferably less than 287 ppm, more preferably less than 108 ppm by weight, even less than 48.8 ppm and even less than 12.8 ppm. In contrast there are applications wherein the presence of potassium in higher amounts is desirable. For these applications are desirable amounts exceeding 2.2 ppm by weight, preferably higher than 8.8 ppm by weight, more preferably greater than 58 ppm, even greater than 108 ppm and even greater than 578 ppm. There are even applications wherein in an embodiment % K is detrimental or not optimal for one reason or another, in these applications it is preferred % K being absent from the alloy.

It has been found that for some applications, the excessive presence of boron (% B) may be detrimental, for these applications in an embodiment is desirable a % B content of less than 0.9% by weight, in another embodiment preferably less than 0.65%, in another embodiment preferably less than 0.4%, in another embodiment more preferably less than 0.16% by weight and even in another embodiment less than 0.006%. There are even some applications for a given application wherein in an embodiment % B is detrimental or not optimal for one reason or another, in these applications it is preferred % B being absent from the tungsten based alloy. In contrast there are applications wherein the presence of boron in higher amounts is desirable for these applications in another embodiment above 60 ppm amounts by weight are desirable, in another embodiment preferably above 200 ppm, in another embodiment preferably above 0.1%, in another embodiment preferably above 0.35%, in another embodiment more preferably greater than 0.52% and even in another embodiment above 1.2%. It has been seen that there are applications for which the presence of boron (% B) may be detrimental and it is preferable its absence (it may not be economically viable remove beyond the content as an impurity, in an embodiment less than 0.1% by weight, in another embodiment preferably less to 0.008%, in another embodiment more preferably less than 0.0008% and even in another embodiment less than 0.00008%).

It has been found that for some applications, the excessive presence of nitrogen (% N) may be detrimental, for these applications in an embodiment is desirable a % N content of less than 0.4%, in another embodiment more preferably less than 0.16% by weight and even in another embodiment less than 0.006%. There are even some applications for a given application wherein in an embodiment % N is detrimental or not optimal for one reason or another, in these applications in an embodiment it is preferred % N being absent from the tungsten based alloy. In contrast there are applications wherein the presence of nitrogen in higher amounts is desirable especially when a high resistance to localized corrosion is desired. For these applications in an embodiment above 60 ppm amounts by weight are desirable, in another embodiment preferably above 200 ppm, in another embodiment preferably above 0.1%, and even in another embodiment preferably above 0.35%. It has been seen that there are applications for which the presence of nitrogen (% N) may be detrimental and it is preferable in an embodiment to its absence (may not be economically viable remove beyond the content as an impurity, in another embodiment less than 0.1% by weight, in another embodiment preferably less to 0.008%, in another embodiment more preferably less than 0.0008% and even in another embodiment less than 0.00008%).

It has been found that for some applications, the excessive presence of zirconium (% Zr) and/or hafnium (% Hf) may be detrimental, for these applications in an embodiment is desirable a content of % Zr+% Hf of less than 12.4% by weight, in another embodiment less than 9.8%, in another embodiment less than 7.8% by weight, I in another embodiment less than 6.3%, in another embodiment preferably less than 4.8%, preferably less than 3.2%, preferably less than 2.6%, in another embodiment more preferably less than 1.8% by weight and even in another embodiment below 0.8%. There are even some applications for a given application wherein % Zr and/or % Hf are detrimental or not optimal for one reason or another, in these applications in an embodiment it is preferred % Zr and/or % Hf being absent from the tungsten based alloy. In contrast there are applications where the presence of some of these elements at higher levels is desirable, especially where a high hardening and/or environmental resistance is required, for these applications in an embodiment amounts of % Zr+% Hf greater than 0.1% by weight are desirable, in another embodiment preferably greater than 1.2% by weight, in another embodiment preferably greater than 2.6% by weight, in another embodiment preferably greater than 4.1% by weight, in another embodiment more preferably above 6%, in another embodiment more preferably above 7.9%, or even in another embodiment above 12%.

There are applications wherein the presence of Molybdenum is desired, especially when a high corrosion resistance is required and/or an increase on mechanical strength and/or on hardness at higher tempering temperatures due to its effect on carbide precipitation is required for those applications. In an embodiment, the % Mo is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Mo may be limited. In other embodiment the % Mo is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Mo is detrimental or not optimal for one reason or another, in these applications it is preferred % Mo being absent from the tungsten based alloy.

It has been found that for some applications, the excessive presence of molybdenum (% Mo) and/or tungsten (% W) may be detrimental, for these applications a lower % Mo+½% W content is desirable in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the tungsten based alloy. In contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, the excessive presence of Vanadium (% V) may be detrimental, for these applications in an embodiment is desirable % V content less than 6.3%, in another embodiment less than 4.8% by weight, in another embodiment less than 3.9%, in another embodiment less than 2.7%, in another embodiment less than 2.1%, in another embodiment preferably less than 1.8%, in another embodiment more preferably less than 0.78% by weight and even in another embodiment less than 0.45%. There are even some applications for a given application wherein % V is detrimental or not optimal for one reason or another, in these applications in an embodiment it is preferred % V being absent from the tungsten based alloy. In contrast there are applications wherein the presence of vanadium in higher amounts is desirable for these applications in an embodiment are desirable amounts exceeding 0.01% by weight, in another embodiment exceeding 0.2% by weight, in another embodiment exceeding 0.6% by weight, in another embodiment preferably greater than 1.2% by weight, in another embodiment more preferably greater than 2.2% and even in another embodiment above 4.2%.

It has been that for some applications, excessive presence of copper (% Cu) may be detrimental, for these applications in an embodiment is desirable % Cu content of less than 14% by weight, in another embodiment preferably less than 12.7%, in another embodiment preferably less than 9%, in another embodiment preferably less than 7.1%, in another embodiment preferably less than 5.4%, in another embodiment more preferably less than 4.5% by weight in another embodiment more preferably less than 3.3% by weight, in another embodiment more preferably less than 2.6% by weight, in another embodiment more preferably less than 1.4% by weight, and even in another embodiment less than 0.9%. There are even some applications for a given application wherein % Cu is detrimental or not optimal for one reason or another, in these applications in an embodiment it is preferred % Cu being absent from the tungsten based alloy. In contrast there are applications where the presence of copper at higher levels is desirable, especially when corrosion resistance to certain acids and/or improved machinability and/or decrease work hardening is desired. For these applications in an embodiment amounts greater than 0.1% by weight, in another embodiment greater than 1.3% by weight, in another embodiment greater than 2.55% by weight, in another embodiment greater than 3.6% by weight, in another embodiment greater than 4.7% by weight, in another embodiment greater than 6% by weight are desirable, in another embodiment preferably greater than 8% by weight, in another embodiment more preferably above 12% and even in another embodiment exceeding 16%.

It has been that for some applications the presence of excessive iron (% Fe) may be detrimental, for these applications in an embodiment is desirable % Fe content of less than 58% by weight, in another embodiment preferably less than 36%, in another embodiment preferably less than 24%, preferably less than 18%, in another embodiment more preferably less than 12% by weight, in another embodiment more preferably less than 10.3% by weight, and even in another embodiment less than 7.5%, even in another embodiment less than 5.9%, in another embodiment less than 3.7%, in another embodiment less than 2.1%, or even in another embodiment less than 1.3%. There are even some applications for a given application wherein % Fe is detrimental or not optimal for one reason or another, in these applications in an embodiment it is preferred % Fe being absent from the tungsten based alloy. In contrast there are applications where the presence of iron at higher levels is desirable, for these applications are desirable amounts in an embodiment greater than 0.1% by weigh, in another embodiment greater than 1.3% by weight, g in another embodiment greater than 2.7% by weight, in another embodiment greater than 4.1% by weight, in another embodiment greater than 6% by weight, in another embodiment preferably greater than 8% by weight, in another embodiment more preferably greater than 22% and even in another embodiment greater than 42%.

It has been found that for some applications, the excessive presence of titanium (% Ti) may be detrimental, for these applications is desirable % Ti content in an embodiment of less than 9% by weight, in another embodiment preferably less than 7.6%, in another embodiment preferably less than 6.1%, in another embodiment preferably less than 4.5%, in another embodiment preferably less than 3.3%, in another embodiment more preferably less than 2.9% by weight, in another embodiment more preferably less than 1.8, and even in another embodiment less than 0.9%. There are even some applications for a given application wherein % Ti is detrimental or not optimal for one reason or another, in these applications in an embodiment it is preferred % Ti being absent from the tungsten based alloy. In contrast there are applications where the presence of titanium in higher amounts is desirable, especially when an increase on mechanical properties at high temperatures are desired. For these applications are desirable amounts in an embodiment greater than 0.01%, in another embodiment greater than 0.2%, in another embodiment greater than 0.7%, in another embodiment greater than 1.2% by weight, in another embodiment preferably greater than 3.2% by weight, in another embodiment preferably greater than 4.1% by weight, in another embodiment more preferably above 6% or even in another embodiment above 12%.

It has been found that for some applications, the excessive presence of tantalum (% Ta) and/or niobium (% Nb) may be detrimental, for these applications is desirable % Ta+% Nb content in an embodiment of less than 17.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the tungsten based alloy. In contrast there are applications wherein higher amounts of % Ta and/or % Nb are desirable, especially Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

It has been found that for some applications, the excessive presence of yttrium (% Y), cerium (% Ce) and/or lanthanide (% La) may be detrimental, for these applications is desirable % Y+% Ce+% La content in an embodiment of less than 12.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Y and/or % Ce and/or % La are detrimental or not optimal for one reason or another, in these applications in an embodiment it is preferred % Y and/or % Ce and/or % La being absent from the tungsten based alloy. In contrast there are applications wherein higher amounts are desirable, especially when a high hardness is desired, for these applications in an embodiment is desired an amount of % Y+% Ce+% La greater than 0.1% by weight, in another embodiment preferably greater than 1.2% by weight, in another embodiment preferably greater than 2.1% by weight, in another embodiment more preferably above 6% or even in another embodiment above 12%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 4.4%, in other embodiment less than 3.1%, in other embodiment less than 2.7%, in other embodiment less than 1.4%. In an embodiment % As is detrimental or not optimal for one reason or another, in these applications it is preferred % As being absent from the tungsten based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 4.4%, in other embodiment less than 3.1%, in other embodiment less than 2.7%, in other embodiment less than 1.4%. In an embodiment % Te is detrimental or not optimal for one reason or another, in these applications it is preferred % Te being absent from the tungsten based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 4.4%, in other embodiment less than 3.1%, in other embodiment less than 2.7%, in other embodiment less than 1.4%. In an embodiment % Se is detrimental or not optimal for one reason or another, in these applications it is preferred % Se being absent from the tungsten based alloy.

There are applications wherein the presence of % Sb in higher amounts is desirable for these applications in an embodiment is desirable % Sb amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Sb may be detrimental, for these applications is desirable % Sb amount in an embodiment less than 4.4%, in other embodiment less than 3.1%, in other embodiment less than 2.7%, in other embodiment less than 1.4%. In an embodiment % Sb is detrimental or not optimal for one reason or another, in these applications it is preferred % Sb being absent from the tungsten based alloy.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 4.4%, in other embodiment less than 3.1%, in other embodiment less than 2.7%, in other embodiment less than 1.4%. In an embodiment % Ca is detrimental or not optimal for one reason or another, in these applications it is preferred % Ca being absent from the tungsten based alloy.

There are applications wherein the presence of % Ge in higher amounts is desirable for these applications in an embodiment is desirable % Ge amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ge may be detrimental, for these applications is desirable % Ge amount in an embodiment less than 4.4%, in other embodiment less than 3.1%, in other embodiment less than 2.7%, in other embodiment less than 1.4%. In an embodiment % Ge is detrimental or not optimal for one reason or another, in these applications it is preferred % Ge being absent from the tungsten based alloy.

There are applications wherein the presence of % P in higher amounts is desirable for these applications in an embodiment is desirable % P amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % P may be detrimental, for these applications is desirable % P amount in an embodiment less than 4.9%, in other embodiment less than 3.4%, in other embodiment less than 2.8%, in other embodiment less than 1.4%. In an embodiment % P is detrimental or not optimal for one reason or another, in these applications it is preferred % P being absent from the tungsten based alloy.

There are applications wherein the presence of % Si in higher amounts is desirable, especially when an increase on strength and/or resistance to oxidation is desired. For these applications in an embodiment is desirable % Si amount above 0.0001%, in other embodiment above 0.15%, in other embodiment above 0.9%, and even in other embodiment above 1.3%. In contrast it has been found that for some applications, the excessive presence of % Si may be detrimental, for these applications is desirable % Si amount in an embodiment less than 1.4%, in other embodiment less than 0.8%, in other embodiment less than 0.4%, in other embodiment less than 0.2%. In an embodiment % Si is detrimental or not optimal for one reason or another, in these applications it is preferred % Si being absent from the tungsten based alloy.

There are applications wherein the presence of % Mn in higher amounts is desirable, especially when improved hot ductility and/or an increase on strength, toughness and/or hardenability and/or increase of solubility of nitrogen is desired. For these applications in an embodiment is desirable % Mn amount above 0.0001%, in other embodiment above 0.15%, in other embodiment above 0.9%, in other embodiment above 1.3%, and even in other embodiment above 1.9%. In contrast it has been found that for some applications, the excessive presence of % Mn may be detrimental, for these applications is desirable % Mn amount in an embodiment less than 2.7%, in other embodiment less than 1.4%, in other embodiment less than 0.6%, in other embodiment less than 0.2%. In an embodiment % Mn is detrimental or not optimal for one reason or another, in these applications it is preferred % Mn being absent from the tungsten based alloy.

There are applications wherein the presence of % S in higher amounts is desirable for these applications in an embodiment is desirable % S amount above 0.0001%, in other embodiment above 0.15%, in other embodiment above 0.9%, in other embodiment above 1.3%, and even in other embodiment above 1.9%. In contrast it has been found that for some applications, the excessive presence of % S may be detrimental, for these applications is desirable % S amount in an embodiment less than 2.7%, in other embodiment less than 1.4%, in other embodiment less than 0.6%, in other embodiment less than 0.2%. In an embodiment % S is detrimental or not optimal for one reason or another, in these applications it is preferred % S being absent from the tungsten based alloy.

It has been found that for some applications, excessive presence of nickel (% Ni) may be detrimental, for these applications is desirable a % Ni content in an embodiment of less than 28%, in other embodiment preferably less than 19.8%, in other embodiment preferably less than 18%, in other embodiment preferably less than 14.8%, in other embodiment preferably less than 11.6%, in other embodiment more preferably less than 8%, and even in other embodiment less than 0.8% There are even some applications for a given application wherein in an embodiment % Ni is detrimental or not optimal for one reason or another, in these applications it is preferred % Ni being absent from the tungsten based alloy. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight in another embodiment amounts higher than 1.2% by weight are desired, in other embodiment higher than 2.2% by weight, in other embodiment preferably higher than 6% by weight, in other embodiment preferably higher than 8.3% by weight in other embodiment more preferably higher than 12%, in other embodiment more preferably higher than 16.2% and even in other embodiment higher than 22%.

For some applications it is desirable that the above alloys have a melting point below 890° C., preferably below 640° C., more preferably below 180° C. or even below 46° C.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

For several applications it may be especially interesting the absence of carbides in the tungsten based alloy, there may be applications wherein it is particularly interesting the absence of tungsten carbides (WC) in the tungsten based alloy. In an embodiment tungsten % WC in the Tungsten based alloy is below 79%, in another embodiment is below 49%, in another embodiment is below 19%, in another embodiment is below 9% and even in another embodiment is below 0.9%. In another applications it may be especially interesting the presence of carbides in the alloy, there may be applications wherein it is particularly interesting the presence of tungsten carbides (% WC) in the tungsten based alloy. In an embodiment % WC in the Tungsten based alloy is above 0.0001%, in another embodiment is above 0.3%, in another embodiment is above 3%, in another embodiment is above 13%, in another embodiment is above 43% and even in another embodiment is above 73%.

There are some applications wherein the presence of compounds phase in the tungsten based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the Tungsten based alloy. There are other applications wherein the presence of compounds in the tungsten based alloy is beneficial. In another embodiment the % of compound phase in the Tungsten based alloy is above 0.0001%, in another embodiment is above 0.3%, in another embodiment is above 3%, in another embodiment is above 13%, in another is above 43% and even in another embodiment is above 73%

For several applications it is especially interesting the use of tungsten based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Tungsten based alloy is used as a coating layer. In another embodiment the Tungsten based alloy is used as a coating layer with a thickness above 1.1 micrometres, in another embodiment the coating layer has a thickness above 21 micrometres, in another embodiment above 105 micrometres, in another embodiment above 510 micrometres, in another embodiment above 1.1 mm and even in another embodiment above 11 mm. For other applications a thinker layer is desired. In an embodiment the Tungsten based alloy is used as a coating layer with thickness below 17 mm, in another embodiment below 7.7 mm, in another embodiment below 537 micrometres, in another embodiment below 117 micrometres, in another embodiment below 27 micrometres and even in another embodiment below 7.7 micrometres.

There are several technologies that are useful to deposit the tungsten based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the tungsten based alloy being in powder form. In an embodiment the tungsten based alloy is manufactured in form of powder. In another embodiment the powder is spherical. In an embodiment refers to a spherical powder with a particle size distribution which may be unimodal, bimodal, trimodal and even multimodal depending of the specific application requirements.

The present invention is particularly suitable for the manufacture of components that can benefit from the properties of tungsten and its alloys. Especially applications requiring high strength at elevated temperature, high elastic modulus and/or high densities (and resulting properties such as the ability to minimize vibration, . . . ). In this sense, applying certain rules of alloy design and thermo-mechanical treatments, it is possible obtain very interesting features for applications in chemical industry, energy transformation, transport, tools, other machines or mechanisms, etc.

The tungsten based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

Any of the above tungsten based alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of tungsten based alloy for manufacturing metallic or at least partially metallic components.

In an embodiment refers to a magnesium based alloy with the following composition, all percentages in weight percent:

| % Si: 0-50 (commonly 0-20); | | % Cu: 0-20; | % Mn: 0-20; |
|---|---|---|---|
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-2; |
| % B: 0-5; | % Al: 0-50 (commonly 0-20); | | % Ni: 0-50; |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5; | % 0: 0-15; | | |

The rest consisting on magnesium and trace elements

The nominal composition expressed herein can refer to particles with higher volume fraction and/or the general final composition. In cases where the presence of immiscible particles as ceramic reinforcements, graphene, nanotubes or other these are not counted on the nominal composition.

In this context trace elements refers to several elements, unless context clearly indicates otherwise, including but not limited to, H, He, Xe, F, Ne, Na, P, S, Cl, Ar, K, Br, Kr, Sr, Tc, Ru, Rh, Pd, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the alloy, such as reducing cost production of the alloy and/or its presence may be unintentional and related mostly to the presence of impurities in the alloying elements and scraps used for the production of the alloy.

There are several applications wherein the presence of trace elements is detrimental for the overall properties of the magnesium based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the magnesium based alloy.

There are applications wherein magnesium based alloys are benefited from having a high magnesium (% Mg) content but not necessary the magnesium being the majority component of the alloy. In an embodiment % Mg is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Al is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Mg is not the majority element in the magnesium based alloy.

For certain applications, it is especially interesting to use alloys with % Ga, % Bi, % Rb, % Cd, % Cs, % Sn, % Pb, % Zn and/or % In. Particularly interesting is the use of these low melting point promoting elements with the presence of % Ga of more than 2.2%, preferably more than 12%, more preferably 21% or more and even 54% or more. The magnesium alloy has in an embodiment % Ga in the alloy is above 32 ppm, in other embodiment above 0.0001%, in another embodiment above 0.015%, and even in other embodiment above 0.1%, in another embodiment generally has a 0.8% or more of the element (in this case % Ga), preferably 2.2% or more, more preferably 5.2% or more and even 12% or more. But there are other applications depending of the desired properties of the magnesium based alloy wherein % Ga contents of 30% or less are desired. In an embodiment the % Ga in the magnesium based alloy is less than 29%, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the magnesium based alloy. It has been found that in some applications the % Ga can be replaced wholly or partially by Bi % (until % Bi maximum content of 10% by weight, in case % Ga being greater than 20%, the replacement with % Bi will be partial) with the amounts described in this paragraph for % Ga+% Bi. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % In with the amounts described above in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the items in question are detrimental or not optimal for one reason or another). These elements do not necessarily have to be incorporated in highly pure state, but often it is economically more interesting the use of alloys of these elements, given that the alloys in question have sufficiently low melting point.

For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

The case of scandium (Sc) is exemplifying, because using them very interesting mechanical properties may be reached, but its cost makes interesting from an economic point of view to use the amount needed for the application of interest. Its high deoxidizing power is also interesting during alloys processing but also a challenge to maximize performance. So depending on the application you can move from situations wherein is not a desired element, in these applications it is preferred % Sc being in a low concentration, in an embodiment less than 0.9%, in other embodiment less than 0.6%, in other embodiment less than 0.3%, in other embodiment less than 0.1%, in other embodiment less than 0.01% and even in other embodiment absent from the magnesium based alloy, to a situations wherein a high content of this element is desired, in an embodiment 0.6% by weight or more, in another embodiment preferably 1.1% by weight or more, in another embodiment more preferably 1.6% by weight or more and even in another embodiment 4.2% or more.

It has been found that for some applications magnesium alloys the presence of silicon (% Si) is desirable, typically in an embodiment in contents of 0.2% by weight or higher, in another embodiment preferably 1.2% or more, in another embodiment preferably 2.1% or more, in another embodiment more preferably 6% or more or even in another embodiment 11% or more. In contrast, in some applications the presence of this element is rather detrimental in which case contents of less than 0.2% by weight are desired, preferably less than 0.08%, more preferably less than 0.02% and even less than 0.004%. Obviously there are cases where the desired nominal content is 0% or nominal absence of the element as with all elements for certain applications. For other applications in an embodiment contents of less than 39.8% by weight are desired, in another embodiment contents of less than 23.6% by weight are desired, in another embodiment contents of less than 14.4% by weight are desired, in another embodiment contents of less than 9.7% by weight are desired, in another embodiment contents of less than 4.2% by weight are desired, in another embodiment contents of less than 3.4% by weight are desired, and even in another embodiment contents of less than 1.4% by weight are desired.

It has been found that for some applications of magnesium alloys the presence of iron (% Fe) is desirable, in an embodiment typically in contents of 0.3% by weight or higher, in another embodiment preferably 0.6% or more, in another embodiment more preferably 1.2% or more or even in another embodiment 6% or more. In contrast, in some applications the presence of this element is rather detrimental, in those cases in an embodiment contents of less than 19.8% by weight are desired, in another embodiment contents of less than 13.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, in another embodiment contents of less than 0.2% by weight are desired, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of aluminium (% Al) is desirable, typically in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%.

It has been found that for some applications of magnesium alloys the presence of manganese (% Mn) is desirable, typically in an embodiment in content of 0.1% by weight or higher, in another embodiment preferably 0.6% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of magnesium (% Mg) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 34.8% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of zinc (% Zn) is desirable, typically in an embodiment in content of 0.1% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of chromium (% Cr) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of titanium (% Ti) is desirable, typically in an embodiment in content of 0.05% by weight or higher, in another embodiment preferably 0.2% or more, in another embodiment more preferably 1.2% or more or even in another embodiment 4% or more. In contrast, in some applications the presence of this element is rather detrimental, in those cases in an embodiment contents of less than 23.8% by weight are desired, in another embodiment contents of less than 17.4% by weight are desired, in another embodiment contents of less than 13.6% by weight are desired, in another embodiment contents of less than 9.2% by weight are desired, in another embodiment contents of less than 4.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of Sn (% Sn) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of zirconium (% Zr) is desirable, typically in an embodiment in content of 0.05% by weight or higher, in another embodiment preferably 0.2% or more, in another embodiment more preferably 1.2% or more or even in another embodiment 4% or more. In contrast, in some applications the presence of this element is rather detrimental, in those cases in an embodiment contents of less than 9.2% by weight are desired, in another embodiment contents of less than 7.1% by weight are desired, in another embodiment contents of less than 4.8% by weight are desired, in another embodiment contents of less than 3.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications of magnesium alloys the presence of Boron (% B) is desirable, typically in an embodiment in content of 0.05% by weight or higher, in another embodiment preferably 0.2% or more, in another embodiment more preferably 0.42% or more or even in another embodiment 1.2% or more. In contrast, in some applications the presence of this element is rather detrimental, in those cases in an embodiment contents of less than 4.8% by weight are desired, in another embodiment contents of less than 3.3% by weight are desired, in another embodiment contents of less than 1.8% by weight are desired, are desired in an embodiment contents of less than 0.08% by weight, in another embodiment preferably less than 0.02%, in another embodiment more preferably less than 0.004% and even in another embodiment less than 0.0002%. Obviously there are cases where the desired nominal content is 0% or nominal absence of the element as occurs with all elements for certain applications.

It has been found that for some applications in aluminum alloys the presence of nitrogen (% N) is desirable, typically in contents of 0.2% by weight or higher, preferably 1.2% or more, more preferably 3.2% or more or even 11% or more. For some applications it is interesting that the consolidation and/or densification of the particles with aluminum is carried out in atmosphere with high nitrogen content thus often reaction occurs particularly if consolidation and/or densification (eg sintering with or without liquid phase) occurs at elevated temperatures, the nitrogen will react with the aluminum and/or other elements forming nitrides and thus will appear as an element in the final composition. In these cases it is often useful to have in the final composition a nitrogen content of 0.002% or higher, preferably 0.02% or higher, more preferably 0.4% or higher and even 2.2% or higher.

It has been found that for some applications, the excessive presence of molybdenum (% Mo) and/or tungsten (% W) may be detrimental, for these applications a lower % Mo+½% W content is desirable, in an embodiment less than 14% by weight, in another embodiment preferably less than 9%, in another embodiment more preferably less than 4.8% by weight and even in another embodiment below 1.8%. There are even some applications for a given application wherein in an embodiment % Mo is detrimental or not optimal for one reason or another, in these applications in an embodiment it is preferred % Mo being absent from the magnesium based alloy. In contrast there are applications where the presence of molybdenum and tungsten at higher levels is desirable, for these applications in an embodiment amounts of 1.2% Mo+% W exceeding 1.2% by weight are desirable, in another embodiment preferably greater than 3.2% by weight, in another embodiment more preferably greater than 5.2% and even in another embodiment above 12%.

It has been found that for some applications, excessive presence of nickel (% Ni) may be detrimental, for these applications is desirable a % Ni content in an embodiment of less than 28%, in other embodiment preferably less than 19.8%, in other embodiment preferably less than 18%, in other embodiment preferably less than 14.8%, in other embodiment preferably less than 11.6%, in other embodiment more preferably less than 8%, and even in other embodiment less than 0.8% There are even some applications for a given application wherein in an embodiment % Ni is detrimental or not optimal for one reason or another, in these applications it is preferred % Ni being absent from the magnesium based alloy. In contrast there are applications wherein the presence of nickel at higher levels is desirable, especially when an increase on ductility and toughness is desired, and/or and increase on strength and/or to improve weldability is required, for those applications in an embodiment amounts higher than 0.1% by weight, in another embodiment higher than 0.65% by weight in another embodiment amounts higher than 1.2% by weight are desired, in other embodiment higher than 2.2% by weight, in other embodiment preferably higher than 6% by weight, in other embodiment preferably higher than 8.3% by weight in other embodiment more preferably higher than 12%, in other embodiment more preferably higher than 16.2% and even in other embodiment higher than 22%.

There are applications wherein the presence of % As in higher amounts is desirable for these applications in an embodiment is desirable % As amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % As may be detrimental, for these applications is desirable % As amount in an embodiment less than 7.4%, in other embodiment less than 4.1%, in other embodiment less than 2.6%, in other embodiment less than 1.3%. In an embodiment % As is detrimental or not optimal for one reason or another, in these applications it is preferred % As being absent from the magnesium based alloy.

There are applications wherein the presence of % Li in higher amounts is desirable for these applications in an embodiment is desirable % Li amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Li may be detrimental, for these applications is desirable % Li amount in an embodiment less than 7.4%, in other embodiment less than 4.1%, in other embodiment less than 2.6%, in other embodiment less than 1.3%. In an embodiment % Li is detrimental or not optimal for one reason or another, in these applications it is preferred % Li being absent from the magnesium based alloy.

There are applications wherein the presence of % V in higher amounts is desirable for these applications in an embodiment is desirable % V amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % V may be detrimental, for these applications is desirable % V amount in an embodiment less than 7.4%, in other embodiment less than 4.1%, in other embodiment less than 2.6%, in other embodiment less than 1.3%. In an embodiment % V is detrimental or not optimal for one reason or another, in these applications it is preferred % V being absent from the magnesium based alloy.

There are applications wherein the presence of % Te in higher amounts is desirable for these applications in an embodiment is desirable % Te amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Te may be detrimental, for these applications is desirable % Te amount in an embodiment less than 7.4%, in other embodiment less than 4.1%, in other embodiment less than 2.6%, in other embodiment less than 1.3%. In an embodiment % Te is detrimental or not optimal for one reason or another, in these applications it is preferred % Te being absent from the magnesium based alloy.

There are applications wherein the presence of % La in higher amounts is desirable for these applications in an embodiment is desirable % La amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % La may be detrimental, for these applications is desirable % La amount in an embodiment less than 7.4%, in other embodiment less than 4.1%, in other embodiment less than 2.6%, in other embodiment less than 1.3%. In an embodiment % La is detrimental or not optimal for one reason or another, in these applications it is preferred % La being absent from the magnesium based alloy.

There are applications wherein the presence of % Se in higher amounts is desirable for these applications in an embodiment is desirable % Se amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Se may be detrimental, for these applications is desirable % Se amount in an embodiment less than 7.4%, in other embodiment less than 4.1%, in other embodiment less than 2.6%, in other embodiment less than 1.3%. In an embodiment % Se is detrimental or not optimal for one reason or another, in these applications it is preferred % Se being absent from the magnesium based alloy.

It has been found that for some applications, the excessive presence of tantalum (% Ta) and/or niobium (% Nb) may be detrimental, for these applications is desirable % Ta+% Nb content in an embodiment of less than 14.3%, in another embodiment less than 7.8% by weight, in another embodiment preferably less than 4.8%, in another embodiment more preferably less than 1.8% by weight, and even in another embodiment less than 0.8%. There are even some applications for a given application wherein % Ta and/or % Nb are detrimental or not optimal for one reason or another, in these applications in an embodiment it is preferred % Ta and/or % Nb being absent from the magnesium based alloy. In contrast there are applications wherein higher amounts of % Ta and/or % Nb are desirable, especially % Nb is added when an improve on the resistance to intergranular corrosion and/or enhance on mechanical properties at high temperatures is desired. for these applications in an embodiment is desired an amount of % Nb+% Ta greater than 0.1% by weight, in another embodiment preferably greater than 0.6% by weight, in another embodiment preferably greater than 1.2% by weight, in another embodiment preferably greater than 2.1% by weight, in another embodiment more preferably greater than 6% and even in another embodiment greater than 12%.

There are applications wherein the presence of % Ca in higher amounts is desirable for these applications in an embodiment is desirable % Ca amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Ca may be detrimental, for these applications is desirable % Ca amount in an embodiment less than 7.4%, in other embodiment less than 4.1%, in other embodiment less than 2.6%, in other embodiment less than 1.3%. In an embodiment % Ca is detrimental or not optimal for one reason or another, in these applications it is preferred % Ca being absent from the magnesium based alloy.

It has been seen that for some applications, the excessive presence of Cobalt (% Co) may be detrimental, for these applications is desirable in an embodiment a % Co content of less than 28% by weight, in another embodiment preferably less than 26.3%, in another embodiment preferably less than 23.4%, preferably less than 19.9%, in another embodiment preferably less than 18%, in another embodiment preferably less than 13.4%, in another embodiment more preferably less than 8.8% by weight, more preferably less than 6.1%, more preferably less than 4.2%, more preferably less than 2.7%, and even in another embodiment less than 1.8%. There are even some applications for a given application wherein in an embodiment % Co is detrimental or not optimal for one reason or another, in these applications it is preferred % Co being absent from the magnesium based alloy. In contrast there are applications wherein the presence of cobalt in higher amounts is desirable, especially when improved hardness and/or tempering resistance are required. For these applications in an embodiment are desirable amounts exceeding 2.2% by weight, in another embodiment preferably higher than 5.9%, in another embodiment preferably higher than 7.6%, in another embodiment preferably higher than 9.6%, in another embodiment preferably higher than 12% by weight, in another embodiment preferably higher than 15.4%, in another embodiment preferably higher than 18.9%, and even in another embodiment greater than 22%. There are other applications wherein it is desirable the % Co in an embodiment above 0.0001%, in other embodiment above 0.15%, in other embodiment above 0.9%, and even in other embodiment above 1.6%.

There are applications wherein the presence of % Hf in higher amounts is desirable for these applications in an embodiment is desirable % Hf amount above 0.0001%, in other embodiment above 0.15%, in other embodiment above 0.9%, in other embodiment above 1.3%, in other embodiment above 2.6%, and even in other embodiment above 3.2%. In contrast it has been found that for some applications, the excessive presence of % Hf may be detrimental, for these applications is desirable % Hf amount in an embodiment less than 4.4%, in other embodiment less than 3.1%, in other embodiment less than 2.7%, in other embodiment less than 1.4%. In an embodiment % Hf is detrimental or not optimal for one reason or another, in these applications it is preferred % Hf being absent from the magnesium based alloy.

There are applications wherein the presence of Germanium (% Ge) is desired. In an embodiment, the % Ge is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Ge may be limited. In other embodiment the % Ge is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Ge is detrimental or not optimal for one reason or another, in these applications it is preferred % Ge being absent from the magnesium based alloy.

There are applications wherein the presence of antimony (% Sb) is desired. In an embodiment, the % Sb is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Sb may be limited. In other embodiment the % Sb is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Sb is detrimental or not optimal for one reason or another, in these applications it is preferred % Sb being absent from the magnesium based alloy.

There are applications wherein the presence of cerium (% Ce) is desired. In an embodiment, the % Ce is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Ce may be limited. In other embodiment the % Ce is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Ce is detrimental or not optimal for one reason or another, in these applications it is preferred % Ce being absent from the magnesium based alloy.

There are applications wherein the presence of beryllium (% Be) is desired. In an embodiment, the % Mo is above 0.0001%, in other embodiment above 0.09%, in other embodiment above 0.4%, in other embodiment above 0.91%, in other embodiment above 1.39%, in other embodiment above 2.15%, in other embodiment above 3.4%, in other embodiment above 4.6%, in other embodiment above 6.3%, and even in other embodiment above 7.1%. Although there are other applications wherein % Be may be limited. In other embodiment the % Be is less than 9.3%, in other embodiment less than 7.4%, in other embodiment less than 6.3%, in other embodiment less than 4.1%, in other embodiment less than 3.1%, in other embodiment less than 2.45%, in other embodiment less than 1.3%. here are even some applications for a given application wherein in an embodiment % Be is detrimental or not optimal for one reason or another, in these applications it is preferred % Be being absent from the magnesium based alloy.

The elements described in the preceding paragraphs may be desired separately or the combination of some of them or even all of them, as expected.

It has been seen that for some applications the excessive content of cesium, tantalum and thallium and can be detrimental, for these applications it is desirable the sum of % Cs+% Ta+% Tl less than 0.29, preferably less than 0.18%, more preferably less than 0.8%, and even less than 0.08% (without being mentioned, as in all instances in this document where amounts are mentioned as upper limits, 0% nominal content or nominal absence of the element, it is not only possible but is often desirable).

It has been seen that for some applications the excessive content of gold and silver can be detrimental, for these applications in an embodiment it is desirable the sum of % Au+% Ag less than 0.09%, in another embodiment preferably less than 0.04%, in another embodiment more preferably less than 0.008%, and even in another embodiment less than 0.002%.

It has been found that for some applications when high contents of % Ga and % Mg (both above 0.5%), it is often desirable to have hardening elements for solid solution, precipitation or hard second phase forming particles. In this sense, the sum % Mn+% Si+% Fe+% Cu+% Cr+% Zn+% V+% Ti+% Zr for these applications, in an embodiment is desirably greater than 0.002% by weight in another embodiment preferably greater than 0.02%, in another embodiment more preferably greater than 0.3% and even in another embodiment higher than 1.2%.

It has been found that for some applications when % Ga content is lower than 0.1%, it is often desirable to have some limitation in hardening elements for solid solution, precipitation or hard second phase forming particles. In this sense, in an embodiment the sum % Cu+% Si+% Zn is desirably less than 21% by weight for these applications, in another embodiment preferably less than 18%, in another embodiment more preferably less than 9% or even in another embodiment less than 3.8%.

It has been found that for some applications when content % Ga below 1% and there is significant presence of % Cr (between 3% and 5%), it is often desirable to have hardening elements for solid solution or precipitation or forming hard particles second stage. In this sense, the sum % Mg+% Cu in an embodiment is desirably higher than 0.52% by weight for these applications, in another embodiment preferably greater than 0.82%, more preferably greater than 1.2% and even higher than 3.2%. and/or the sum of % Ti+% Zr is desirable in another embodiment exceeds 0.012% by weight, preferably in another embodiment greater than 0055%, more preferably in another embodiment greater than 0.12% by weight and even in another embodiment higher than 0.55%.

It has been found that for some applications, especially those requiring a high mechanical strength, high resistance to high temperatures and/or high corrosion resistance, which can be very beneficial combination of gallium (% Ga) and scandium (% Sc). For these applications it is often desirable in an embodiment to have contents above 0.12% Sc wt %, preferably above 0.52%, more preferably greater than 0.82% and even above 1.2% For these applications simultaneously is often desirable to have Ga in excess of 0.12% wt %, preferably above 0.52%, more preferably greater than 0.8%, more preferably greater than 2.2 more % and even higher 3.5%. For some of these applications is also interesting to further magnesium (Mg %), in another embodiment it is often desirable to have % Mg above 0.6% by weight, preferably greater than 1.2%, more preferably in another embodiment greater than 4.2% and even in another embodiment more than 6%. For some of these applications, especially improved resistance to corrosion is required, it is also interesting for the presence of zirconium (% Zr), in another embodiment often in excess of 0.06% weight amounts, preferably above in another embodiment 0.22%, more preferably in another embodiment above 0.52% and even in another embodiment greater than 1.2%. Obviously, like all other paragraphs herein any other element may be present in the amounts described in the preceding and coming paragraphs.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as rare earth elements (RE) that are detrimental in specific applications; For these applications in an embodiment RE are absent from the composition.

There are some applications wherein the presence of compounds phase in the magnesium based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the magnesium based alloy. There are other applications wherein the presence of compounds in the magnesium based alloy is beneficial. In another embodiment the % of compound phase in the magnesium based alloy is above 0.0001%, in another embodiment is above 0.3%, in another embodiment is above 3%, in another embodiment is above 13%, in another is above 43% and even in another embodiment is above 73%.

For some applications it is desirable that the above alloys have a melting point below 890° C., preferably below 640° C. the, more preferably below 180° C. or even below 46° C.

Any of the above Mg alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of a magnesium alloy for manufacturing metallic or at least partially metallic components.

In an embodiment the present invention refers to AlGa, NiGa, CuGa, MgGa, SnGa and MgGa alloys. In an embodiment these gallium containing alloys are used for the fast and economic manufacture of metallic components.

In an embodiment the invention refers to a AlGa alloy with the following composition, all percentages in weight percent:

| | | | |
|---|---|---|---|
| % Cu: 0-30; | % Mn: 0-40; | % Fe: 0-5; | % Zn: 0-15; |
| % Pb: 0-20; | % Zr: 0-10; | % Cr: 0-15; | % V: 0-8; |
| % Ti: 0-10; | % Ga: 0-60; | % Bi: 0-20; | % W: 0-10; |
| % Ni: 0-15; | % Co: 0-25; | % Sn: 0-50; | % Cd: 0-10; |
| % In: 0-20; | % Cs: 0-20; | % Mo: 0-3; | % Rb: 0-20; |

| | |
|---|---|
| % Mg: 0-80 (commonly 0-20); | % Ni: 0-15; |

The rest consisting on aluminium and trace elements

In an embodiment the nominal composition expressed herein can refer to particles with lower volume fraction in the powder mixture and/or the general final composition of the low melting point alloy. In an embodiment in cases where the presence of immiscible particles as ceramic reinforcements, graphene, nanotubes or other these are also included in the alloy, their contribution to the alloy is not counted on the above nominal composition.

In this context trace elements refers to several elements, unless context clearly indicates otherwise, including but not limited to B, N, Li, Sc, Ta, Si, Be, Ca, La Se, Te, As, Ge, Hf, Nb, Ce, C, H, He, O, F, Ne, Na, P, S, Cl, Ar, K, Br, Kr, Sr, Tc, Ru, Rh, Pd, Ag, I, Xe, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the AlGa alloy, especially when their have and important impact on the melting point of the alloy, depending of the elements present in the alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the AlGa alloy.

There are applications wherein AlGa alloys are benefited from having a high aluminium (% Al) content but not necessary the aluminium being the majority component of the alloy. In an embodiment Ga is the main component of the alloy. In an embodiment % Al is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Al is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Al is not the majority element in the aluminium based alloy.

For certain applications, it is especially interesting to use alloys with % Ga, % Bi, % Rb, % Cd, % Cs, % Sn, % Pb, % Zn and/or % In. In an embodiment it is particularly interesting having low melting point compounds providing the alloy with a low melting point. In an embodiment the AlGa alloy comprises a % Ga of more than 0.1% by weight, in other embodiment more than 2.2%, in other embodiment more than 3.6%, in other embodiment more than 5.4%, in other embodiment more than 6.2%, in other embodiment more than 8.3% in other embodiment more than 12% in other embodiment more than 21% in other embodiment more than 29%, in other embodiment more than 36%, and even in other embodiment more than 54%. There are other applications depending of the desired properties of the AlGa alloy, and sometimes also based in the cost of the alloy, where lower amounts or gallium are interesting, in an embodiment lower than 43%. In an embodiment the % Ga is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the alloy.

It has been found that in some applications the % Ga can be replaced wholly or partially by % Bi (in an embodiment the replacement is made until % Bi maximum content of 20% by weight in the alloy, in case % Ga being greater than 20%, the replacement with % Bi will be partial, and also replacement with other elements is possible). In an embodiment, this replacement also allow obtain a low melting point alloy with the amounts described in this paragraph for % Ga+% Bi. In some applications it is advantageous the total replacement of gallium, this means the absence of %. Ga in the alloy. It has been found that it is even interesting for some applications the partial replacement of % Ga and/or % Bi by % Cd, % Cs, % Sn, % Pb, % Zn, % Rb or % In, where depending on the application may be interesting the absence of any of them (ie although the sum is in line with the values given any element can be absent and have a nominal content of 0%, this being advantageous for a given application where the items in question are detrimental or not optimal for one reason or another).

In an embodiment % Ga+% Bi+% Cd+% Cs+% Sn+% Pb+% Zn+% Rb+% In, is more than 2.2% by weight, in other embodiment more than 12%, in other embodiment more than 21% in other embodiment more than 21% in other embodiment more than 29%, in other embodiment more than 36%, and even in other embodiment more than 54%. In an embodiment and depending of the application the contain of these elements may be limited due its tendency to cause embrittlement in the alloy. In an embodiment % Ga+% Bi+% Cd+% Cs+% Sn+% Pb+% Zn+% Rb+% In is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. In an embodiment not all of these element are present in the alloy at the same time. In an embodiment % Bi is absent from the alloy. In an embodiment % Ga is absent from the alloy. In an embodiment % Cd is absent from the alloy. In an embodiment % Cs is absent from the alloy. In an embodiment % Sn is absent from the alloy. In an embodiment % Pb is absent from the alloy. In an embodiment % Zn is absent from the alloy. In an embodiment % Rb is absent from the alloy. In an embodiment % In is absent from the alloy.

It has been found that for some applications an AlGa alloys the presence of % Fe, % W, % Mo and/or % Ti is desirable, but their use must be done carefully due are elements which in small contains, depending of the overall composition of the alloy, produce an increase in the melting point of the alloy.

In an embodiment the contain of % Fe in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % W in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Mo in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ti in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Fe+% W+% Mo+% Ti<0.4; in another embodiment % Fe+% W+% Mo+% Ti<0.1; in another embodiment % Fe+% W+% Mo+% Ti<0.01. In an embodiment any of them may be absent. It has been found that for some applications an AlGa alloys the presence of % Co, % Ni, % Cr and % V is desirable, but their use must be done carefully due are elements which in small contains, depending of the overall composition of the alloy, produce an increase in the melting point of the alloy, although its effect is lower than produced by % Fe, % W, % Mo and/or % Ti.

In an embodiment the contain of % V in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Co in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Cr in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ni in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Co+% Ni+% Cr+% V<1.6; in another embodiment % Co+% Cr+% V<0.8; in another embodiment % Co+% Cr+% V<0.1. In an embodiment any of them may be absent.

It has been found that for some applications the presence of copper (% Cu) is desirable, in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of manganese (% Mn) is desirable, in an embodiment in content of 0.06% by weight or higher, in another embodiment 0.2% or more, in another embodiment 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of magnesium (% Mg) is desirable, in an embodiment in content of 0.2% by weight or higher, in another embodiment 1.2% or more, in another embodiment 6.4% or more or even in another embodiment 18.3% or more. In contrast, in some applications the presence of this element is rather detrimental, in those cases in an embodiment contents of less than 27.3% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

In an embodiment the elements described in the preceding paragraphs may be desired separately or the combination of some of them or even all of them, as expected.

In an embodiment there are several applications that may benefit from the AlGa alloy being in powder form. In an embodiment the disclosed AlGa alloy is especially suitable for use as low melting point alloy in powder form in the powder mixture. In an embodiment the AlGa alloy is manufactured in form of powder.

In the alloy preparation, in some cases these elements do not necessarily have to be incorporated in highly pure state to the AlGa alloy, but often it is economically more interesting the use of alloys of these elements, given that the alloys in question have sufficiently low melting point. In an embodiment elements from the alloys used to obtain the AlGa alloy contains other elements, disclosed as trace elements in their composition.

In an embodiment this AlGa alloy is suitable for use in powder form in the powder mixture and in the method of the invention for manufacturing a metallic or at least partially metallic component. In an embodiment this AlGa alloy is used as low melting point alloy in a powder mixture. In an embodiment this AlGa alloy is used as low melting point alloy in a powder mixture comprising at least a low melting point alloy and a high melting point alloy.

In an embodiment the GaAl alloys have a melting point below 890° C., preferably below 640° C. the, more preferably below 180° C. or even below 46° C.

In an embodiment this AlGa alloy is suitable for use in powder form in the powder mixture and in the method of the invention for manufacturing a metallic or at least partially metallic component. In an embodiment this AlGa alloy is used as low melting point alloy in a powder mixture. In an embodiment this AlGa alloy is used as low melting point alloy in a powder mixture comprising at least a low melting point alloy and a high melting point alloy.

Any of the above-described GaAl alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to a CuGa alloy with the following composition, all percentages in weight percent:

| | | | |
|---|---|---|---|
| % Al: 0-30; | % Mn: 0-40; | % Fe: 0-5; | % Zn: 0-15; |
| % Pb: 0-20; | % Zr: 0-10; | % Cr: 0-15; | % V: 0-8; |
| % Ti: 0-10; | % Ga: 0-60; | % Bi: 0-20; | % W: 0-10; |
| % Ni: 0-15; | % Co: 0-25; | % Sn: 0-50; | % Cd: 0-10; |
| % In: 0-20; | % Cs: 0-20; | % Mo: 0-3; | % Rb: 0-20; |

% Mg: 0-80 (commonly 0-20);

The rest consisting on copper and trace elements

In an embodiment the nominal composition expressed herein can refer to particles with lower volume fraction in the powder mixture and/or the general final composition of the low melting point alloy. In an embodiment in cases where the presence of immiscible particles as ceramic reinforcements, graphene, nanotubes or other these are also included in the alloy, their contribution to the alloy is not counted on the above nominal composition.

In this context trace elements refers to several elements, unless context clearly indicates otherwise, including but not limited to C, B, N, Li, Sc, Ta, Si, Be, Ca, La Se, Te, As, Ge, Hf, Nb, Ce, C, H, He, Xe, O, F, Ne, Na, Mg, P, S, Cl, Ar, K, Br, Kr, Sr, Tc, Ru, Rh, Pd, Ag, I, Xe, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the CuGa alloy, especially when their have and important impact on the melting point of the alloy, depending of the elements present in the alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the CuGa alloy.

There are applications wherein CuGa alloys are benefited from having a high copper (% Cu) content but not necessary the copper being the majority component of the alloy. In an embodiment Ga is the main component of the alloy. In an embodiment % Cu is above 1.3%, in another embodiment is above 3.1%, in another embodiment is above 4.1%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Cu is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Al is not the majority element in the CuGa alloy.

For certain applications, it is especially interesting to use alloys with % Ga, % Bi, % Rb, % Cd, % Cs, % Sn, % Pb, % Zn and/or % In. In an embodiment it is particularly interesting having low melting point compounds providing the alloy with a low melting point. In an embodiment the CuGa alloy comprises a % Ga of more than 2.2% by weight, in other embodiment more than 12%, in other embodiment more than 21% in other embodiment more than 21% in other embodiment more than 29%, in other embodiment more than 36%, and even in other embodiment more than 54%. There are other applications depending of the desired properties of the CuGa alloy, and sometimes also based in the cost of the alloy, where lower amounts or gallium are interesting, in an embodiment lower than 43%. In an embodiment the % Ga is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the alloy. It has been found that in some applications the % Ga can be replaced wholly or partially by % Bi (in an embodiment the replacement is made until % Bi maximum content of 20% by weight in the alloy, in case % Ga being greater than 20%, the replacement with % Bi will be partial, and also replacement with other elements is possible). In an embodiment, this replacement also allow obtain a low melting point alloy with the amounts described in this paragraph for % Ga+% Bi. In some applications it is advantageous the total replacement of gallium, this means the absence of % Ga in the alloy. It has been found that it is even interesting for some applications the partial replacement of % Ga and/or % Bi by % Cd, % Cs, % Sn, % Pb, % Zn, % Rb or % In, where depending on the application may be interesting the absence of any of them (ie although the sum is in line with the values given any element can be absent and have a nominal content of 0%, this being advantageous for a given application where the items in question are detrimental or not optimal for one reason or another).

In an embodiment % Ga+% Bi+% Cd+% Cs+% Sn+% Pb+% Zn+% Rb+% In, is more than 2.2% by weight, in other embodiment more than 12%, in other embodiment more than 21% in other embodiment more than 21% in other embodiment more than 29%, in other embodiment more than 36%, and even in other embodiment more than 54%. In an embodiment and depending of the application the contain of these elements may be limited due its tendency to cause embrittlement in the alloy. In an embodiment % Ga+% Bi+% Cd+% Cs+% Sn+% Pb+% Zn+% Rb+% In is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. In an embodiment not all of these element are present in the alloy at the same time. In an embodiment % Bi is absent from the alloy. In an embodiment % Ga is absent from the alloy. In an embodiment % Cd is absent from the alloy. In an embodiment % Cs is absent from the alloy. In an embodiment % Sn is absent from the alloy. In an embodiment % Pb is absent from the alloy. In an embodiment % Zn is absent from the alloy. In an embodiment % Rb is absent from the alloy. In an embodiment % In is absent from the alloy.

It has been found that for some applications an CuGa alloys the presence of % Fe, % W, % Mo and/or % Ti is desirable, but their use must be done carefully due are elements which in small contains, depending of the overall composition of the alloy, produce an increase in the melting point of the alloy.

In an embodiment the contain of % Fe in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % W in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Mo in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ti in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Fe+% W+% Mo+% Ti<0.4; in another embodiment % Co+% Cr+% V<0.1; in another embodiment % Co+% Cr+% V<0.01. In an embodiment any of them may be absent.

It has been found that for some applications an CuGa alloys the presence of % Co, % Ni, % Cr and % V is desirable, but their use must be done carefully due are elements which in small contains, depending of the overall composition of the alloy, produce an increase in the melting point of the alloy, although its effect is lower than produced by % Fe, % W, % Mo and/or % Ti.

In an embodiment the contain of % V in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Co in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Cr in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ni in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Co+% Ni+% Cr+% V<1.6; in another embodiment % Fe+% W+% Mo+% Ti<0.8; in another embodiment % Fe+% W+% Mo+% Ti<0.1. In an embodiment any of them may be absent.

It has been found that for some applications the presence of aluminium (% Al) is desirable, in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of manganese (% Mn) is desirable, in an embodiment in content of 0.06% by weight or higher, in another embodiment 0.2% or more, in another embodiment 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of magnesium (% Mg) is desirable, in an embodiment in content of 0.2% by weight or higher, in another embodiment 1.2% or more, in another embodiment 6.4% or more or even in another embodiment 18.3% or more. In contrast, in some applications the presence of this element is rather detrimental, in those cases in an embodiment contents of less than 27.3% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

In an embodiment the elements described in the preceding paragraphs may be desired separately or the combination of some of them or even all of them, as expected.

In an embodiment there are several applications that may benefit from the CuGa alloy being in powder form. In an embodiment the disclosed CuGa alloy is especially suitable for use as low melting point alloy in powder form in the powder mixture. In an embodiment the CuGa alloy is manufactured in form of powder.

In the alloy preparation, in some cases these elements do not necessarily have to be incorporated in highly pure state to the CuGa alloy, but often it is economically more interesting the use of alloys of these elements, given that the alloys in question have sufficiently low melting point. In an embodiment elements from the alloys used to obtain the CuGa alloy contains other elements, disclosed as trace elements in their composition.

In an embodiment the CuGa alloys have a melting point below 890° C., preferably below 640° C. the, more preferably below 180° C. or even below 46° C.

In an embodiment this CuGa alloy is suitable for use in powder form in the powder mixture and in the method of the invention for manufacturing a metallic or at least partially metallic component. In an embodiment this CuGa alloy is used as low melting point alloy in a powder mixture. In an embodiment this CuGa alloy is used as low melting point alloy in a powder mixture comprising at least a low melting point alloy and a high melting point alloy.

The above-described CuGa alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to a SnGa alloy with the following composition, all percentages in weight percent:

| | | | |
|---|---|---|---|
| % Cu: 0-30; | % Mn: 0-40; | % Fe: 0-5; | % Zn: 0-15; |
| % Pb: 0-20; | % Zr: 0-10; | % Cr: 0-15; | % V: 0-8; |
| % Ti: 0-10; | % Ga: 0-60; | % Bi: 0-20; | % W: 0-10; |
| % Ni: 0-15; | % Co: 0-25; | % Al: 0-50; | % Cd: 0-10; |
| % In: 0-20; | % Cs: 0-20; | % Mo: 0-3; | % Rb: 0-20; |

% Mg: 0-80 (commonly 0-20);

The rest consisting on tin (Sn) and trace elements.

In an embodiment the nominal composition expressed herein can refer to particles with lower volume fraction in the powder mixture and/or the general final composition of the low melting point alloy. In an embodiment in cases where the presence of immiscible particles as ceramic reinforcements, graphene, nanotubes or other these are also included in the alloy, their contribution to the alloy is not counted on the above nominal composition.

In this context trace elements refers to several elements, unless context clearly indicates otherwise, including but not limited to, B, N, Li, Sc, Ta, Si, Be, Ca, La Se, Te, As, Ge, Hf, Nb, Ce, C, H, He, O, F, Ne, Na, P, S, Cl, Ar, K, Br, Kr, Sr, Tc, Ru, Rh, Pd, Ag, I, Xe, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the SnGa alloy, especially when their have and important impact on the melting point of the alloy, depending of the elements present in the alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the SnGa alloy.

There are applications wherein SnGa alloys are benefited from having a high Sn content but not necessary the Sn being the majority component of the alloy. In an embodiment Ga is the main component of the alloy. In an embodiment % Sn is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Sn is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Sn is not the majority element in the tin based alloy.

For certain applications, it is especially interesting to use alloys with % Ga, % Bi, % Rb, % Cd, % Cs, % Pb, % Zn and/or % In. In an embodiment it is particularly interesting having low melting point compounds providing the alloy with a low melting point. In an embodiment the SnGa alloy comprises a % Ga of more than 2.2% by weight, in other embodiment more than 12%, in other embodiment more than 21% in other embodiment more than 21% in other embodiment more than 29%, in other embodiment more than 36%, and even in other embodiment more than 54%. There are other applications depending of the desired properties of the SnGa alloy, and sometimes also based in the cost of the alloy, where lower amounts or gallium are interesting, in an embodiment lower than 43%. In an embodiment the % Ga is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the alloy. It has been found that in some applications the % Ga can be replaced wholly or partially by % Bi (in an embodiment the replacement is made until % Bi maximum content of 20% by weight in the alloy, in case % Ga being greater than 20%, the replacement with % Bi will be partial, and also replacement with other elements is possible) In an embodiment, this replacement also allow obtain a low melting point alloy with the amounts described in this paragraph for % Ga+% Bi.

In some applications it is

advantageous the total replacement of gallium, this means the absence of %. Ga in the alloy. It has been found that it is even interesting for some applications the partial replacement of % Ga and/or % Bi by % Cd, % Cs, % Pb, % Zn, % Rb or % In, where depending on the application may be interesting the absence of any of them (ie although the sum is in line with the values given any element can be absent and have a nominal content of 0%, this being advantageous for a given application where the items in question are detrimental or not optimal for one reason or another).

In an embodiment % Ga+% Bi+% Cd+% Cs+% Pb+% Zn+% Rb+% In, is more than 2.2% by weight, in other embodiment more than 12%, in other embodiment more than 21% in other embodiment more than 21% in other embodiment more than 29%, in other embodiment more than 36%, and even in other embodiment more than 54%. In an embodiment and depending of the application the contain of these elements may be limited due its tendency to cause embrittlement in the alloy. In an embodiment % Ga+% Bi+% Cd+% Cs+% Pb+% Zn+% Rb+% In is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. In an embodiment not all of these element are present in the alloy at the same time. In an embodiment % Bi is absent from the alloy. In an embodiment % Ga is absent from the alloy. In an embodiment % Cd is absent from the alloy. In an embodiment % Cs is absent from the alloy. In an embodiment % Pb is absent from the alloy. In an embodiment % Zn is absent from the alloy. In an embodiment % Rb is absent from the alloy. In an embodiment % In is absent from the alloy.

It has been found that for some applications an SnGa alloys the presence of % Fe, % W, % Mo and/or % Ti is desirable, but their use must be done carefully due are elements which in small contains, depending of the overall composition of the alloy, produce an increase in the melting point of the alloy.

In an embodiment the contain of % Fe in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % W in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Mo in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Aluminium in the alloy is of 0.3% by weight or higher, in another embodiment 0.6% or more, in another embodiment 1.2% or more or even in another embodiment 1.9% or more. In contrast, in some applications the presence of this element is rather detrimental, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Fe+% W+% Mo+% Ti<0.4; in another embodiment % Fe+% W+% Mo+% Ti<0.1; in another embodiment % Fe+% W+% Mo+% Ti<0.01. In an embodiment any of them may be absent.

It has been found that for some applications an SnGa alloys the presence of % Co, % Ni, % Cr and % V is desirable, but their use must be done carefully due are elements which in small contains, depending of the overall composition of the alloy, produce an increase in the melting point of the alloy, although its effect is lower than produced by % Fe, % W, % Mo and/or % Ti.

In an embodiment the contain of % V in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Co in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Cr in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ni in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Co+% Ni+% Cr+% V<1.6; in another embodiment % Co+% Cr+% V<0.8; in another embodiment % Co+% Cr+% V<0.1. In an embodiment any of them may be absent.

It has been found that for some applications the presence of copper (% Cu) is desirable, in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of manganese (% Mn) is desirable, in an embodiment in content of 0.06% by weight or higher, in another embodiment 0.2% or more, in another embodiment 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of magnesium (% Mg) is desirable, in an embodiment in content of 0.2% by weight or higher, in another embodiment 1.2% or more, in another embodiment 6.4% or more or even in another embodiment 18.3% or more. In contrast, in some applications the presence of this element is rather detrimental, in those cases in an embodiment contents of less than 27.3% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

In an embodiment the elements described in the preceding paragraphs may be desired separately or the combination of some of them or even all of them, as expected.

In an embodiment there are several applications that may benefit from the SnGa alloy being in powder form. In an embodiment the disclosed SnGa alloy is especially suitable for use as low melting point alloy in powder form in the powder mixture. In an embodiment the SnGa alloy is manufactured in form of powder.

In the alloy preparation, in some cases these elements do not necessarily have to be incorporated in highly pure state to the SnGa alloy, but often it is economically more interesting the use of alloys of these elements, given that the alloys in question have sufficiently low melting point. In an embodiment elements from the alloys used to obtain the SnGa alloy contains other elements, disclosed as trace elements in their composition.

In an embodiment this SnGa alloy is suitable for use in powder form in the powder mixture and in the method of the invention for manufacturing a metallic or at least partially metallic component. In an embodiment this SnGa alloy is used as low melting point alloy in a powder mixture. In an embodiment this SnGa alloy is used as low melting point alloy in a powder mixture comprising at least a low melting point alloy and a high melting point alloy.

In an embodiment the SnGa alloys have a melting point below 890° C., preferably below 640° C. the, more preferably below 180° C. or even below 46° C.

The above-described SnGa alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to a MgGa alloy with the following composition, all percentages in weight percent:

| | | | |
|---|---|---|---|
| % Cu: 0-30; | % Mn: 0-40; | % Fe: 0-5; | % Zn: 0-15; |
| % Pb: 0-20; | % Zr: 0-10; | % Cr: 0-15; | % V: 0-8; |
| % Ti: 0-10; | % Ga: 0-60; | % Bi: 0-20; | % W: 0-10; |
| % Ni: 0-15; | % Co: 0-25; | % Sn: 0-50; | % Cd: 0-10; |
| % In: 0-20; | % Cs: 0-20; | % Mo: 0-3; | % Rb: 0-20; |

The rest consisting on magnesium and trace elements.

In an embodiment the nominal composition expressed herein can refer to particles with lower volume fraction in the powder mixture and/or the general final composition of the low melting point alloy.

In an embodiment in cases where the presence of immiscible particles as ceramic reinforcements, graphene, nanotubes or other these are also included in the alloy, their contribution to the alloy is not counted on the above nominal composition.

In this context trace elements refers to several elements, unless context clearly indicates otherwise, including but not limited to Al, B, N, Li, Sc, Ta, Si, Be, Ca, La Se, Te, As, Ge, Hf, Nb, Ce, C, H, He, O, F, Ne, Na, P, S, Cl, Ar, K, Br, Kr, Sr, Tc, Ru, Rh, Pd, Ag, I, Xe, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the MgGa alloy, especially when their have and important impact on the melting point of the alloy, depending of the elements present in the alloy. In an embodiment all trace elements as a sum have content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the MgGa alloy.

There are applications wherein MgGa alloys are benefited from having a high Magnesium content but not necessary the Magnesium being the majority component of the alloy. In an embodiment Ga is the main component of the alloy. In an embodiment % Magnesium is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Magnesium is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Magnesium is not the majority element in the magnesium based alloy.

For certain applications, it is especially interesting to use alloys with % Ga, % Bi, % Rb, % Cd, % Cs, % Sn, % Pb, % Zn and/or % In. In an embodiment it is particularly interesting having low melting point compounds providing the alloy with a low melting point. In an embodiment the MgGa alloy comprises a % Ga of more than 2.2% by weight, in other embodiment more than 3.4%, in other embodiment more than 4.2% in other embodiment more than 6.8%, in other embodiment more than 12.1% in other embodiment more than 21% in other embodiment more than 29%, in other embodiment more than 36%, and even in other embodiment more than 54%. There are other applications depending of the desired properties of the GaAl alloy, and sometimes also based in the cost of the alloy, where lower amounts or gallium are interesting, in an embodiment lower than 43%. In an embodiment the % Ga is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the alloy. It has been found that in some applications the % Ga can be replaced wholly or partially by % Bi (in an embodiment the replacement is made until % Bi maximum content of 20% by weight in the alloy, in case % Ga being greater than 20%, the replacement with % Bi will be partial, and also replacement with other elements is possible) In an embodiment, this replacement also allow obtain a low melting point alloy with the amounts described in this paragraph for % Ga+% Bi. In some applications it is advantageous the total replacement of gallium, this means the absence of %. Ga in the alloy. It has been found that it is even interesting for some applications the partial replacement of % Ga and/or % Bi by % Cd, % Cs, % Sn, % Pb, % Zn, % Rb or % In, where depending on the application may be interesting the absence of any of them (ie although the sum is in line with the values given any element can be absent and have a nominal content of 0%, this being advantageous for a given application where the items in question are detrimental or not optimal for one reason or another).

In an embodiment % Ga+% Bi+% Cd+% Cs+% Sn+% Pb+% Zn+% Rb+% In, is more than 2.2% by weight, in other embodiment more than 12%, in other embodiment more than 21% in other embodiment more than 21% in other embodiment more than 29%, in other embodiment more than 36%, and even in other embodiment more than 54%. In an embodiment and depending of the application the contain of these elements may be limited due its tendency to cause embrittlement in the alloy. In an embodiment % Ga+% Bi+% Cd+% Cs+% Sn+% Pb+% Zn+% Rb+% In is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. In an embodiment not all of these elements are present in the alloy at the same time. In an embodiment % Bi is absent from the alloy. In an embodiment % Ga is absent from the alloy. In an embodiment % Cd is absent from the alloy. In an embodiment % Cs is absent from the alloy. In an embodiment % Sn is absent from the alloy. In an embodiment % Pb is absent from the alloy. In an embodiment % Zn is absent from the alloy. In an embodiment % Rb is absent from the alloy. In an embodiment % In is absent from the alloy.

It has been found that for some applications an MgGa alloys the presence of % Fe, % W, % Mo and/or % Ti is desirable, but their use must be done carefully due are elements which in small contains, depending of the overall composition of the alloy, produce an increase in the melting point of the alloy.

In an embodiment the contain of % Fe in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % W in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Mo in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ti in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Fe+% W+% Mo+% Ti<0.4; in another embodiment % Fe+% W+% Mo+% Ti<0.1; in another embodiment % Fe+% W+% Mo+% Ti<0.01. In an embodiment any of them may be absent. It has been found that for some applications an MgGa alloys the presence of % Co, % Ni, % Cr and % V is desirable, but their use must be done carefully due are elements which in small contains, depending of the overall composition of the alloy, produce an increase in the melting point of the alloy, although its effect is lower than produced by % Fe, % W, % Mo and/or % Ti.

In an embodiment the contain of % V in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Co in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Cr in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ni in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Co+% Ni+% Cr+% V<1.6; in another embodiment % Co+% Cr+% V<0.8; in another embodiment % Co+% Cr+% V<0.1. In an embodiment any of them may be absent.

It has been found that for some applications the presence of copper (% Cu) is desirable, in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of manganese (% Mn) is desirable, in an embodiment in content of 0.06% by weight or higher, in another embodiment 0.2% or more, in another embodiment 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of magnesium (% Mg) is desirable, in an embodiment in content of 0.2% by weight or higher, in another embodiment 1.2% or more, in another embodiment 6.4% or more or even in another embodiment 18.3% or more. In contrast, in some applications the presence of this element is rather detrimental, in those cases in an embodiment contents of less than 27.3% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

In an embodiment the elements described in the preceding paragraphs may be desired separately or the combination of some of them or even all of them, as expected.

In an embodiment there are several applications that may benefit from the MgGa alloy being in powder form. In an embodiment the disclosed MgGa alloy is especially suitable for use as low melting point alloy in powder form in the powder mixture. In an embodiment the MgGa alloy is manufactured in form of powder.

In the alloy preparation, in some cases these elements do not necessarily have to be incorporated in highly pure state to the MgGa alloy, but often it is economically more interesting the use of alloys of these elements, given that the alloys in question have sufficiently low melting point. In an embodiment elements from the alloys used to obtain the MgGa alloy contains other elements, disclosed as trace elements in their composition.

In an embodiment this MgGa alloy is suitable for use in powder form in the powder mixture and in the method of the invention for manufacturing a metallic or at least partially metallic component. In an embodiment this MgGa alloy is used as low melting point alloy in a powder mixture. In an embodiment this MgGa alloy is used as low melting point alloy in a powder mixture comprising at least a low melting point alloy and a high melting point alloy.

In an embodiment the MgGa alloys have a melting point below 890° C., preferably below 640° C. the, more preferably below 180° C. or even below 46° C.

The above-described MgGa alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to a MnGa alloy with the following composition, all percentages in weight percent:

| | | | |
|---|---|---|---|
| % Cu: 0-30; | % Al: 0-40; | % Fe: 0-5; | % Zn: 0-15; |
| % Pb: 0-20; | % Zr: 0-10; | % Cr: 0-15; | % V: 0-8; |
| % Ti: 0-10; | % Ga: 0-60; | % Bi: 0-20; | % W: 0-10; |
| % Ni: 0-15; | % Co: 0-25; | % Sn: 0-50; | % Cd: 0-10; |
| % In: 0-20; | % Cs: 0-20; | % Mo: 0-3; | % Rb: 0-20; |

% Mg: 0-80 (commonly 0-20);

The rest consisting on manganese and trace elements.

In an embodiment the nominal composition expressed herein can refer to particles with lower volume fraction in the powder mixture and/or the general final composition of the low melting point alloy. In an embodiment in cases where the presence of immiscible particles as ceramic reinforcements, graphene, nanotubes or other these are also included in the alloy, their contribution to the alloy is not counted on the above nominal composition.

In this context trace elements refers to several elements, unless context clearly indicates otherwise, including but not limited to B, N, Li, Sc, Ta, Si, Be, Ca, La Se, Te, As, Ge, Hf, Nb, Ce, C, H, HeO, F, Ne, Na, P, S, Cl, Ar, K, Br, Kr, Sr, Tc, Ru, Rh, Pd, Ag, I, Xe, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the MnGa alloy, especially when their have and important impact on the melting point of the alloy, depending of the elements present in the alloy. In an embodiment all trace elements as a sum have content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the MnGa alloy.

There are applications wherein MnGa alloys are benefited from having a high Manganese content but not necessary the Manganese being the majority component of the alloy. In an embodiment Ga is the main component of the alloy. In an embodiment % Manganese is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Manganese is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Manganese is not the majority element in the manganese based alloy.

For certain applications, it is especially interesting to use alloys with % Ga, % Bi, % Rb, % Cd, % Cs, % Sn, % Pb, % Zn and/or % In. In an embodiment it is particularly interesting having low melting point compounds providing the alloy with a low melting point. In an embodiment the MnGa alloy comprises a % Ga of more than 2.2% by weight, in other embodiment more than 3.8%, in other embodiment more than 6.8% in other embodiment more than 9.3%, in other embodiment more than 12.2% in other embodiment more than 21% in other embodiment more than 29%, in other embodiment more than 36%, and even in other embodiment more than 54%. There are other applications depending of the desired properties of the MnGa alloy, and sometimes also based in the cost of the alloy, where lower amounts or gallium are interesting, in an embodiment lower than 43%. In an embodiment the % Ga is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the alloy. It has been found that in some applications the % Ga can be replaced wholly or partially by % Bi (in an embodiment the replacement is made until % Bi maximum content of 20% by weight in the alloy, in case % Ga being greater than 20%, the replacement with % Bi will be partial, and also replacement with other elements is possible) In an embodiment, this replacement also allow obtain a low melting point alloy with the amounts described in this paragraph for % Ga+% Bi. In some applications it is advantageous the total replacement of gallium, this means the absence of %. Ga in the alloy. It has been found that it is even interesting for some applications the partial replacement of % Ga and/or % Bi by % Cd, % Cs, % Sn, % Pb, % Zn, % Rb or % In, where depending on the application may be interesting the absence of any of them (ie although the sum is in line with the values given any element can be absent and have a nominal content of 0%, this being advantageous for a given application where the items in question are detrimental or not optimal for one reason or another).

In an embodiment % Ga+% Bi+% Cd+% Cs+% Sn+% Pb+% Zn+% Rb+% In, is more than 2.2% by weight, in other embodiment more than 12%, in other embodiment more than 21% in other embodiment more than 21% in other embodiment more than 29%, in other embodiment more than 36%, and even in other embodiment more than 54%. In an embodiment and depending of the application the contain of these elements may be limited due its tendency to cause embrittlement in the alloy. In an embodiment % Ga+% Bi+% Cd+% Cs+% Sn+% Pb+% Zn+% Rb+% In is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. In an embodiment not all of these element are present in the alloy at the same time. In an embodiment % Bi is absent from the alloy. In an embodiment % Ga is absent from the alloy. In an embodiment % Cd is absent from the alloy. In an embodiment % Cs is absent from the alloy. In an embodiment % Sn is absent from the alloy. In an embodiment % Pb is absent from the alloy. In an embodiment % Zn is absent from the alloy. In an embodiment % Rb is absent from the alloy. In an embodiment % In is absent from the alloy.

It has been found that for some applications an MnGa alloys the presence of % Fe, % W, % Mo and/or % Ti is desirable, but their use must be done carefully due are elements which in small contains, depending of the overall composition of the alloy, produce an increase in the melting point of the alloy.

In an embodiment the contain of % Fe in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % W in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Mo in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ti in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Fe+% W+% Mo+% Ti<0.4; in another embodiment % Fe+% W+% Mo+% Ti<0.1; in another embodiment % Fe+% W+% Mo+% Ti<0.01. In an embodiment any of them may be absent.

It has been found that for some applications an MnGa alloys the presence of % Co, % Ni, % Cr and % V is desirable, but their use must be done carefully due are elements which in small contains, depending of the overall composition of the alloy, produce an increase in the melting point of the alloy, although its effect is lower than produced by % Fe, % W, % Mo and/or % Ti.

In an embodiment the contain of % V in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Co in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Cr in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ni in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Co+% Ni+% Cr+% V<1.6; in another embodiment % Co+% Cr+% V<0.8; in another embodiment % Co+% Cr+% V<0.1. In an embodiment any of them may be absent.

It has been found that for some applications the presence of copper (% Cu) is desirable, in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of Aluminium (% Al) is desirable, in an embodiment in content of 0.06% by weight or higher, in another embodiment 0.2% or more, in another embodiment 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of magnesium (% Mg) is desirable, in an embodiment in content of 0.2% by weight or higher, in another embodiment 1.2% or more, in another embodiment 6.4% or more or even in another embodiment 18.3% or more. In contrast, in some applications the presence of this element is rather detrimental, in those cases in an embodiment contents of less than 27.3% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

In an embodiment the elements described in the preceding paragraphs may be desired separately or the combination of some of them or even all of them, as expected.

In an embodiment there are several applications that may benefit from the MnGa alloy being in powder form. In an embodiment the disclosed MnGa alloy is especially suitable for use as low melting point alloy in powder form in the powder mixture. In an embodiment the MnGa alloy is manufactured in form of powder.

In the alloy preparation, in some cases these elements do not necessarily have to be incorporated in highly pure state to the MnGa alloy, but often it is economically more interesting the use of alloys of these elements, given that the alloys in question have sufficiently low melting point. In an embodiment elements from the alloys used to obtain the MnGa alloy contains other elements, disclosed as trace elements in their composition.

In an embodiment this MnGa alloy is suitable for use in powder form in the powder mixture and in the method of the invention for manufacturing a metallic or at least partially metallic component. In an embodiment this MnGa alloy is used as low melting point alloy in a powder mixture. In an embodiment this MnGa alloy is used as low melting point alloy in a powder mixture comprising at least a low melting point alloy and a high melting point alloy.

In an embodiment the MnGa alloys have a melting point below 890° C., preferably below 640° C. the, more preferably below 180° C. or even below 46° C.

The above-described MnGa alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to a NiGa alloy with the following composition, all percentages in weight percent:

| | | | |
|---|---|---|---|
| % Cu: 0-30; | % Al: 0-40; | % Fe: 0-5; | % Zn: 0-15; |
| % Pb: 0-20; | % Zr: 0-10; | % Cr: 0-15; | % V: 0-8; |
| % Ti: 0-10; | % Ga: 0-60; | % Bi: 0-20; | % W: 0-10; |
| % Al: 0-30; | % Co: 0-25; | % Sn: 0-50; | % Cd: 0-10; |
| % In: 0-20; | % Cs: 0-20; | % Mo: 0-3; | % Rb: 0-20; |

% Mg: 0-80 (commonly 0-20);

The rest consisting on nickel and trace elements.

In an embodiment the nominal composition expressed herein can refer to particles with lower volume fraction in the powder mixture and/or the general final composition of the low melting point alloy. In an embodiment in cases where the presence of immiscible particles as ceramic reinforcements, graphene, nanotubes or other these are also included in the alloy, their contribution to the alloy is not counted on the above nominal composition.

In this context trace elements refers to several elements, unless context clearly indicates otherwise, including but not limited to, B, N, Li, Sc, Ta, Si, Be, Ca, La Se, Te, As, Ge, Hf, Nb, Ce, C, H, He, O, F, Ne, Na, P, S, Cl, Ar, K, Br, Kr, Sr, Tc, Ru, Rh, Pd, Ag, I, Xe, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the NiGa alloy, especially when their have and important impact on the melting point of the alloy, depending of the elements present in the alloy. In an embodiment all trace elements as a sum have content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the NiGa alloy.

There are applications wherein NiGa alloys are benefited from having a high Nickel content but not necessary the Nickel being the majority component of the alloy. In an embodiment Ga is the main component of the alloy. In an embodiment % Nickel is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Nickel is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Nickel is not the majority element in the nickel based alloy.

For certain applications, it is especially interesting to use alloys with % Ga, % Bi, % Rb, % Cd, % Cs, % Sn, % Pb, % Zn and/or % In. In an embodiment it is particularly interesting having low melting point compounds providing the alloy with a low melting point. In an embodiment the NiGa alloy comprises a % Ga of more than 2.2% by weight, in other embodiment more than 12%, in other embodiment more than 21% in other embodiment more than 21% in other embodiment more than 29%, in other embodiment more than 36%, and even in other embodiment more than 54%. There are other applications depending of the desired properties of the NiGa alloy, and sometimes also based in the cost of the alloy, where lower amounts or gallium are interesting, in an embodiment lower than 43%. In an embodiment the % Ga is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. There are even some applications for a given application wherein in an embodiment % Ga is detrimental or not optimal for one reason or another, in these applications it is preferred % Ga being absent from the alloy. It has been found that in some applications the % Ga can be replaced wholly or partially by % Bi (in an embodiment the replacement is made until % Bi maximum content of 20% by weight in the alloy, in case % Ga being greater than 20%, the replacement with % Bi will be partial, and also replacement with other elements is possible) In an embodiment, this replacement also allow obtain a low melting point alloy with the amounts described in this paragraph for % Ga+% Bi. In some applications it is advantageous the total replacement of gallium, this means the absence of %. Ga in the alloy. It has been found that it is even interesting for some applications the partial replacement of % Ga and/or % Bi by % Cd, % Cs, % Sn, % Pb, % Zn, % Rb or % In, where depending on the application may be interesting the absence of any of them (ie although the sum is in line with the values given any element can be absent and have a nominal content of 0%, this being advantageous for a given application where the items in question are detrimental or not optimal for one reason or another).

In an embodiment % Ga+% Bi+% Cd+% Cs+% Sn+% Pb+% Zn+% Rb+% In, is more than 2.2% by weight, in other embodiment more than 12%, in other embodiment more than 21% in other embodiment more than 21% in other embodiment more than 29%, in other embodiment more than 36%, and even in other embodiment more than 54%. In an embodiment and depending of the application the contain of these elements may be limited due its tendency to cause embrittlement in the alloy. In an embodiment % Ga+% Bi+% Cd+% Cs+% Sn+% Pb+% Zn+% Rb+% In is less than 29% by weight, in other embodiment less than 22%, in other embodiment less than 16%, in other embodiment less than 9%, in other embodiment less than 6.4%, in other embodiment less than 4.1%, in other embodiment less than 3.2%, in other embodiment less than 2.4%, in other embodiment less than 1.2%. In an embodiment not all of these element are present in the alloy at the same time. In an embodiment % Bi is absent from the alloy. In an embodiment % Ga is absent from the alloy. In an embodiment % Cd is absent from the alloy. In an embodiment % Cs is absent from the alloy. In an embodiment % Sn is absent from the alloy. In an embodiment % Pb is absent from the alloy. In an embodiment % Zn is absent from the alloy. In an embodiment % Rb is absent from the alloy. In an embodiment % In is absent from the alloy.

It has been found that for some applications an NiGa alloys the presence of % Fe, % W, % Mo and/or % Ti is desirable, but their use must be done carefully due are elements which in small contains, depending of the overall composition of the alloy, produce an increase in the melting point of the alloy.

In an embodiment the contain of % Fe in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % W in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Mo in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Ti in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Fe+% W+% Mo+% Ti<0.4; in another embodiment % Fe+% W+% Mo+% Ti<0.1; in another embodiment % Fe+% W+% Mo+% Ti<0.01. In an embodiment any of them may be absent.

It has been found that for some applications an NiGa alloys the presence of % Co, % Cr and % V is desirable, but their use must be done carefully due are elements which in small contains, depending of the overall composition of the alloy, produce an increase in the melting point of the alloy, although its effect is lower than produced by % Fe, % W, % Mo and/or % Ti.

In an embodiment the contain of % V in the alloy is of 0.3% by weight or higher, in another embodiment 0.6% or more, in another embodiment 1.2% or more or even in another embodiment 4% or more. In contrast, in some applications the presence of this element is rather detrimental and causes and excessive increase in the melting point, furthermore if other elements which tends to raise melting point are present at the same time in the alloy, in those cases in an embodiment contents of less than 1.9% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Co in the alloy is of 0.3% by weight or higher, in another embodiment 0.6% or more, in another embodiment 1.2% or more or even in another embodiment 6% or more. In contrast, in some applications the presence of this element is rather detrimental and causes and excessive increase in the melting point, furthermore if other elements which tends to raise melting point are present at the same time in the alloy, in those cases in an embodiment contents of less than 3.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment the contain of % Cr in the alloy is of 0.3% by weight or higher, in another embodiment 0.6% or more, in another embodiment 1.2% or more or even in another embodiment 1.9% or more. In contrast, in some applications the presence of this element is rather detrimental and causes and excessive increase in the melting point, furthermore if other elements which tends to raise melting point are present at the same time in the alloy, in those cases in an embodiment contents of less than 1.2% by weight are desired, in another embodiment contents of less than 0.4% by weight are desired, in another embodiment contents of less than 0.09% by weight are desired, in another embodiment contents of less than 0.009% by weight and even in another embodiment less than 0.0003%. In an embodiment there are cases where the desired nominal content is 0% or nominal absence of the element.

In an embodiment % Co+% Cr+% V<1.6; in another embodiment % Co+% Cr+% V<0.8; in another embodiment % Co+% Cr+% V<0.1. In an embodiment any of them may be absent.

It has been found that for some applications the presence of copper (% Cu) is desirable, in an embodiment in content of 0.06% by weight or higher, in another embodiment preferably 0.2% or more, in another embodiment more preferably 1.2% or more or even in another embodiment 6% or more. In contrast, in some applications the presence of this element is rather detrimental, in those cases in an embodiment contents of less than 14.8% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of Aluminium (% Al) is desirable, in an embodiment in content of 0.06% by weight or higher, in another embodiment 0.2% or more, in another embodiment 1.2% or more or even in another embodiment 6% or more. In contrast, in some applications the presence of this element is rather detrimental, in those cases in an embodiment contents of less than 14.8% by weight are desired, in another embodiment contents of less than 12.6% by weight are desired, in another embodiment contents of less than 9.4% by weight are desired, in another embodiment contents of less than 6.3% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

It has been found that for some applications the presence of magnesium (% Mg) is desirable, in an embodiment in content of 0.2% by weight or higher, in another embodiment 1.2% or more, in another embodiment 6.4% or more or even in another embodiment 18.3% or more. In contrast, in some applications the presence of this element is rather detrimental, in those cases in an embodiment contents of less than 27.3% by weight are desired, in another embodiment contents of less than 22.6% by weight are desired, in another embodiment contents of less than 14.4% by weight are desired, in another embodiment contents of less than 9.2% by weight are desired, in another embodiment contents of less than 4.2% by weight are desired, in another embodiment contents of less than 2.3% by weight are desired, in another embodiment contents of less than 1.8% by weight are desired, are desired in an embodiment contents of less than 0.2% by weight, in another embodiment preferably less than 0.08%, in another embodiment more preferably less than 0.02% and even in another embodiment less than 0.004%. Obviously there are cases where the desired nominal content is 0% or nominal absence of the element as occurs with all elements for certain applications.

In an embodiment the elements described in the preceding paragraphs may be desired separately or the combination of some of them or even all of them, as expected.

In an embodiment there are several applications that may benefit from the NiGa alloy being in powder form. In an embodiment the disclosed NiGa alloy is especially suitable for use as low melting point alloy in powder form in the powder mixture. In an embodiment the NiGa alloy is manufactured in form of powder.

In the alloy preparation, in some cases these elements do not necessarily have to be incorporated in highly pure state to the NiGa alloy, but often it is economically more interesting the use of alloys of these elements, given that the alloys in question have sufficiently low melting point. In an embodiment elements from the alloys used to obtain the NiGa alloy contains other elements, disclosed as trace elements in their composition.

In an embodiment this NiGa alloy is suitable for use in powder form in the powder mixture and in the method of the invention for manufacturing a metallic or at least partially metallic component. In an embodiment this NiGa alloy is used as low melting point alloy in a powder mixture. In an embodiment this NiGa alloy is used as low melting point alloy in a powder mixture comprising at least a low melting point alloy and a high melting point alloy.

In an embodiment the NiGa alloys have a melting point below 890° C., preferably below 640° C. the, more preferably below 180° C. or even below 46° C.

The above-described NiGa alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to a powder mixture comprising at least one metallic powder. In an embodiment this at least metallic powder comprises any Fe, Ni, Co, Cu, Mg, W, Mo, Al and Ti alloys in powder form. In an embodiment the invention refers to the use of the powder mixture for manufacturing a metallic or at least partially metallic component.

In an embodiment Fe, Ni, Co, Cu, Mg, W, Mo, Al and Ti based alloy refers to any existing alloy containing at least Fe, Ni, Co, Cu, Mg, W, Mo, Al and Ti respectively including also the Fe, Ni, Co, Cu, Mg, W, Mo, Al and Ti based alloys disclosed in the present application and any other Fe, Ni, Co, Cu, Mg, W, Mo, Al and Ti based alloy developed in the future which is suitable for the powder mixture and/or the method of the present application.

Examples of existing Ni based alloys are commercial pure and low alloy nickels (such as for example nickel 200, nickel 201, nickel 205, nickel 270, nickel 290, permanickel alloy 300, duranickel alloy 301 among others) nickel-chromium and nickel chromium-iron series (such as for example alloy 600, nimonic alloys, alloy 600, alloy x750, alloy 718, alloy x, waspaloy, alloy 625, alloy g3/g30, alloy c-276, alloy 690 among others), iron-nickel-chromium alloys (such as alloy 800, alloy 800HT, alloy 801, alloy 802, alloy 825 among others), nickel-iron low expansion alloys (such as invar, alloy 42, alloy 52 among others. Examples of existing Co based alloys are cobalt base material alloyed with chrome, nickel, and tungsten among others, such as grades MTEK 6, R30006, MTEK 21, R30021, MTEK 31 and R 30031, Hastelloy, FSX-414, F75 and F799 (Co—Cr—Mo alloys with very similar composition yet slightly different production processes), F90 (Co—Cr—W—Ni alloy), F562 (Co—Ni—Cr—Mo—Ti alloy, Stellite. Examples of existing Al based alloys are Aluzinc, Al 2024, Al 6061, Al 3003, Duralumin, Alclad. In an embodiment Mo based alloys refers but is not limited to TZM, MHC, Mo-17.8Ni-4.3Cr-1.0Si-1.0Fe-0.8, Mo-3Mo2C. Examples of existing W based alloys are Tungsten, Nickel and Iron Alloys (HD17D, HD17.5, HD18D, HD18.5), Tungsten, Nickel and Copper Alloys (HD17, HD18), WHD 13, WHD 11, WHD 14, WHD 12, WHD 15. Examples of existing Mg alloys are Magnox, AZ63, AZ81, AZ31, Elektron 21, Elektron 675. Examples of existing Ti based alloys are Ti-5AL-2SN-ELI, Ti-8AL-1MO-1V, Ti-6Al-2Sn-4Zr-2Mo, Ti-5Al-5Sn-2Zr-2Mo, IMI 685, Ti 1100, Ti 1100, Ti6Al4V among others.

In an embodiment the invention refers to a powder mixture comprising at least two metallic powders. In another embodiment the powder mixture comprises at least two metallic powders with different melting point. In an embodiment the powder mixture comprises at least a low melting point alloy in powder form and a high melting point alloy in powder form. In an embodiment the low melting point metallic powder is selected from a Fe, Ni, Co, Cu, Mg, W, Mo, Al and Ti based alloy containing at least an element whose binary diagram with the selected alloy presents any kind of liquid phase at low allowing contents and low temperatures when added to the alloy. In an embodiment the low melting point alloy in powder form is selected from a Fe, Ni, Co, Cu, Mg, W, Mo, Al and Ti based alloy containing at least an element selected from: Ga, Bi, Pb, Rb, Zn, Cd, In, Sn, K, Na, Mn, B, Sc, Si, and/or Mg and/or any combination of them among others. In an embodiment the low melting point alloy is selected from: gallium alloy, AlGa alloy, CuGa alloy, SnGa alloy, MgGa alloy, MnGa alloy, NiGa alloy, high manganese containing alloy, high manganese containing Fe based alloy further comprising carbon (steel), Al based alloy containing Mg, Al based alloy containing Sc, Al based alloy containing Sn, Al based alloy containing more than 90% by weight Al. In an embodiment the high melting point alloy is selected from a Fe, Ni, Co, Cu, Mg, W, Mo. In an embodiment the invention refers to the use of the powder mixture for manufacturing a metallic or at least partially metallic component Al and Ti based alloy. In an embodiment the powder mixture further comprises an organic compound. In an embodiment a low melting point alloy is selected from the new Fe, Ni, Co, Cu, Mg, W, Mo, Al or Ti based alloy disclosed in the present document containing at least one element with low melting point or promoting low melting point eutectics with other elements of the alloy among others. In an embodiment a low melting point alloy is selected from existing Fe, Ni, Co, Cu, Mg, W, Mo, Al or Ti based alloys to which is added at least one element with low melting point or promoting low melting point eutectics with an element contained in the alloy among others.

In an embodiment a low melting point alloy is a Fe based alloy containing at least one element with low melting point or promoting low melting point eutectics with an element contained in the alloy.

In an embodiment the low melting point alloy is a Ni based alloy containing at least one element with low melting point or promoting low melting point eutectics with an element contained in the alloy.

In an embodiment a low melting point alloy is a Co based alloy containing at least one element with low melting point or promoting low melting point eutectics with an element contained in the alloy.

In an embodiment the low melting point alloy is a Cu based alloy containing at least one element with low melting point or promoting low melting point eutectics with an element contained in the alloy.

In an embodiment a low melting point alloy is a Mg based alloy containing at least one element with low melting point or promoting low melting point eutectics with an element contained in the alloy.

In an embodiment the low melting point alloy is a W based alloy containing at least one element with low melting point or promoting low melting point eutectics with an element contained in the alloy.

In an embodiment a low melting point alloy is a Mo based alloy containing at least one element with low melting point or promoting low melting point eutectics with an element contained in the alloy.

In an embodiment the low melting point alloy is an Al based alloy containing at least one element with low melting point or promoting low melting point eutectics with an element contained in the alloy.

In an embodiment the low melting point alloy is a Ti based alloy containing at least one element with low melting point or promoting low melting point eutectics with an element contained in the alloy.

In an embodiment an element with low melting point or promoting low melting point eutectics is selected from Ga, Bi, Pb, Rb, Zn, Cd, In, Sn, K, Na, Mn, B, Sc, Si, and/or Mg and/or any combination of them among others

In an embodiment a low melting point alloy is be selected from any element whose binary phase diagram with a Fe, Ni, Co, Cu, Mg, W, Mo, Al or Ti based alloy, presents any kind of liquid phase at low alloying contents and at low temperatures is susceptible to enhance diffusivity and the formation of a liquid phase at lower temperatures when added to the alloy.

In an embodiment low allowing content of an element is when this element has a percentage in the alloy of less than 20% by weight, in other embodiment less than 16%, in other embodiment less than 12%, in other embodiment less than 9%, in other embodiment less than 7%, in other embodiment less than 4%, in other embodiment less than 1.8%, and even in other embodiment less than 0.3%.

In an embodiment phase diagram is a chart used to show conditions (% in weight, % in volume, % atomic) at which thermodynamically distinct phases occur and coexists at equilibrium.

In an embodiment binary phase diagram is a temperature-composition (% in weight, % in volume and/or % atomic) map which indicates the equilibrium phases present at a given temperature and composition.

In an embodiment a low melting point alloy is selected from any element whose binary phase diagram with a Fe based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Ni based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Co based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Cu based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Mg based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a W based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Mo based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Al based alloy material presents any kind of liquid phase at low alloying contents and at low temperatures is susceptible to enhance diffusivity and the formation of a liquid phase at lower temperatures when added to the alloy.

In other aspect a low melting point alloy may be selected from any element whose binary phase diagram with a Ti based alloy material presents any kind of liquid phase at low alloying contents and at low temperatures is susceptible to enhance diffusivity and the formation of a liquid phase at lower temperatures when added to the alloy.

In an embodiment a low melting point alloy is selected from: a Fe, Ni, Co, Cu, Mg, W, Mo, Al or Ti based alloy containing at least one element selected from Ga, Bi, Pb, Rb, Zn, Cd, In, Sn, K, Na, Mn, B, Sc, Si, and/or Mg and/or any combination of them among others.

In an embodiment a low melting point alloy is selected from: a Fe alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: a Ni alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: an Al alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: a Co alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: a Cu alloy containing at least one element selected from, Ga, Bi, Pb, Rb, Zn, Cd, In, Sn, K, Na, Mn, B, Sc, Si, and/or Mg and/or any combination of them.

In an embodiment a low melting point alloy is selected from: a Mg alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: a W alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: a Mo alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from: a Ti alloy containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Fe, Ni, Co, Cu, Mg, W, Mo, Al or Ti based alloy containing at least one element selected from Ga, Bi, Pb, Rb, Zn, Cd, In, Sn, K, Na, Mn, B, Sc, Si, and/or Mg and/or any combination of them among others. In an embodiment a low melting point alloy is selected from existing Fe, Ni, Co, Cu, Mg, W, Mo, Al or Ti based alloy to which is added at least one element selected from Ga, Bi, Pb, Rb, Zn, Cd, In, Sn, K, Na, Mn, B, Sc, Si, and/or Mg and/or any combination of them among others.

In an embodiment a low melting point alloy is selected from existing Fe alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Fe alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Ni alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Ni alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Al alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Al alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Co alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Co alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Cu alloy containing at least one element selected from, Ga, Bi, Pb, Rb, Zn, Cd, In, Sn, K, Na, Mn, B, Sc, Si, and/or Mg and/or any combination of them. In an embodiment a low melting point alloy is selected from existing Cu alloy to which is added at least one element selected from, Ga, Bi, Pb, Rb, Zn, Cd, In, Sn, K, Na, Mn, B, Sc, Si, and/or Mg and/or any combination of them.

In an embodiment a low melting point alloy is selected from existing Mg alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Mg alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing W alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing W alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Mo alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Mo alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from existing Ti alloy containing at least one element selected from Ga, Bi, Pb, Rb, Zn, Cd, In, Sn, K, Na, Mn, B, Sc, Si, and/or Mg and/or any combination of them. In an embodiment a low melting point alloy is selected from existing Ti alloy to which is added at least one element selected from Ga, Bi, Pb, Rb, Zn, Cd, In, Sn, K, Na, Mn, B, Sc, Si, and/or Mg and/or any combination of them.

In an embodiment a low melting point alloy is selected from new Fe, Ni, Co, Cu, Mg, W, Mo, Al or Ti based alloy disclosed in the present document containing at least one element selected from Ga, Bi, Pb, Rb, Zn, Cd, In, Sn, K, Na, Mn, B, Sc, Si, and/or Mg and/or any combination of them among others.

In an embodiment a low melting point alloy is selected from Fe alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from Ni alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from Al alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from Co alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from Cu alloy disclosed in the present document containing at least one element selected from, Ga, Bi, Pb, Rb, Zn, Cd, In, Sn, K, Na, Mn, B, Sc, Si, and/or Mg and/or any combination of them.

In an embodiment a low melting point alloy is selected from existing Mg alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from W alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from Mo alloy disclosed in the present document containing at least one element selected from Ga, Bi, Pb, Rb, Zn, Cd, In, Sn, K, Na, Mn, B, Sc, Si, and/or Mg and/or any combination of them.

In an embodiment a low melting point alloy is selected from Ti alloy disclosed in the present document containing at least one element selected from Ga, Bi, Pb, Rb, Zn, Cd, In, Sn, K, Na, Mn, B, Sc, Si, and/or Mg and/or any combination of them.

The size of the metallic particulates is quite critical for some applications of the present invention. Amongst others and in general terms a finer powder is easier to consolidate and thus to attain higher final densities, and also permits resolve finer details and thus allows for higher accuracy and tolerances, but it is more costly and thus renders some geometries as not economically viable. As has been seen sometimes it is advantageous in the present invention to have different phases in different nominal sizes, in such cases normally the desired nominal sizes are related to the nominal size of the main constituent. Nominal size of metallic powders, when not otherwise stated, refers to D50. Also other than the interstice filling distribution, that is to say tailored or random distributions can be advantageous for some applications. When metallic powders are used, for some applications requiring a fine detail or fast diffusion amongst others, rather fine powders can be used with a d50 of 78 microns or less, preferably 48 microns or less, more preferably 18 microns or less and even 8 microns or less. For some other applications rather coarser powders are acceptable with d50 of 780 microns or less, preferably 380 microns or less, more preferably 180 microns or less and even 120 microns or less. In some applications fine powders are even disadvantageous, so that powders with d50 of 12 microns or more are desired, preferably 22 microns or more, even more preferably 42 microns or more and even 72 microns or more. When several metallic phases are present in the form of particulates, and sizes of different phases are given a percentage of the majoritarian metallic powder spices, then the previous d50 values refer to the latter.

In an embodiment particle size distribution” (PSD) is an index (means of expression) indicating what sizes (particle size) of particles are present in what proportions (relative particle amount as a percentage where the total amount of particles is 100%) in the sample particle group to be measured. Volume, area, length, and quantity are used as standards (dimensions) for particle amount. However, generally, the volume standard is apparently often used. Frequency distribution indicates in percentage the amounts of particles existing in respective particle size intervals after the range of target particle sizes is divided into separate intervals. Whereas, cumulative distribution (for particles passing the sieve) expresses the percentage of the amounts of particles of a specific particle size or below. Alternatively, cumulative distribution (for particles remaining on the sieve) expresses the percentage of the amounts of particles of a specific particle size or above.

In an embodiment particle size distribution is determined using sieve method: this method continues to be used for many measurements because of its simplicity, cheapness, and ease of interpretation. Methods may be simple shaking of the sample in sieves until the amount retained becomes more or less constant.

In an embodiment particle size distribution is determined using laser light scattering: this method depend upon analysis of the “halo” of diffracted light produced when a laser beam passes through a dispersion of particles in air or in a liquid. The angle of diffraction increases as particle size decreases, so that this method is particularly good for measuring sizes between 0.1 and 3,000 pm. Advances in sophisticated data processing and automation have allowed this to become the dominant method used in industrial PSD determination. This technique is relatively fast and can be performed on very small samples. A particular advantage is that the technique can generate a continuous measurement for analyzing process streams. Laser diffraction measures particle size distributions by measuring the angular variation in intensity of light scattered as a laser beam passes through a dispersed particulate sample. Large particles scatter light at small angles relative to the laser beam and small particles scatter light at large angles, as illustrated below. The angular scattering intensity data is then analyzed to calculate the size of the particles responsible for creating the scattering pattern, using the Mie theory of light scattering. The particle size is reported as a volume equivalent sphere diameter. Currently, there are two variations: dynamic light scattering (DLS) and Fraunhofer diffraction (FD). The choice is dictated by the size range under investigation. DLS works for sizes from a few nanometers up to about one micron (1,000 nm) and FD works from about one micron up to millimeters. In an embodiment the method for determine particle size distribution is dynamic light scattering (DLS). In an embodiment the method for determine particle size distribution is Fraunhofer diffraction (FD).

In an embodiment d50 of the powders is 78 microns or less, in other embodiment 48 microns or less, in other embodiment 18 microns or less and even in other embodiment 8 microns or less.

In an embodiment d50 of the powders is 780 microns or less, in other embodiment 380 microns or less, in other embodiment 180 microns or less and even in other embodiment 120 microns or less.

In an embodiment the highest mode value of the powder mixture is 78 microns or less, in other embodiment 48 microns or less, in other embodiment 18 microns or less and even in other embodiment 8 microns or less.

In an embodiment the highest mode value of the powder mixture is 780 microns or less, in other embodiment 380 microns or less, in other embodiment 180 microns or less and even in other embodiment 120 microns or less.

In an embodiment the main metallic powder has a uni-modal size distribution wherein the d50 value is 780 microns or less, in another embodiment preferably 380 microns or less, in another embodiment preferably 180 microns or less, in another embodiment preferably 120 microns or less, 78 microns or less, in another embodiment preferably 48 microns or less, preferably 18 microns or less and even 8 micros or less.

In an embodiment the main metallic powder has a bi-modal size distribution wherein the higher mode value is 780 microns or less, in another embodiment preferably 380 microns or less, in another embodiment preferably 180 microns or less, in another embodiment preferably 120 microns or less, 78 microns or less, in another embodiment preferably 48 microns or less, preferably 18 microns or less and even 8 micros or less.

In an embodiment the main metallic powder has a tri-modal size distribution wherein the higher mode value is 780 microns or less, in another embodiment preferably 380 microns or less, in another embodiment preferably 180 microns or less, in another embodiment preferably 120 microns or less, 78 microns or less, in another embodiment preferably 48 microns or less, preferably 18 microns or less and even 8 micros or less.

In the present invention, the inventor has seen that is beneficial for many applications the usage of a material which contains a polymer and at least two different metallic materials. The inventor has seen that the size of the metallic materials and also their morphology plays a very important role in the final properties that can be obtained in pieces manufactured according to the present invention. The shape of the powder is also important in terms of active surface and maximum volume fraction attainable, influenced by the spherical shape and particle size distribution.

Each metal powder can be characterized by a statistical distribution of different sizes. In an embodiment, this distribution can be characterized by statistical parameters such as the mean, median, and mode of the distribution population. In an embodiment in this regard, the mean is the average size of the population, the median is the size where 50% of the population is below and above the size value, and the mode is the size with highest frequency. Thus, the types of particle size distribution curves that can be presented are normal, skewed and multimodal. In an embodiment the normal or Gaussian distribution will be considered as the symmetric and bell-shaped curve that is characterized by the mean of the population and its standard deviation. Sweked distributions are asymmetric curves where one tail is longer than the other, resulting in left-skewed (long left tail) and right-skewed (long right tail) distributions. In an embodiment, when a curve is not symmetric the median is often the best parameter for characterization. An embodiment of the invention comprises a bimodal distribution of particle sizes, where two modes are differentiated as distinct peaks in the probability distribution curve. Another embodiments considers the presence of three, four or more modes, giving place to trimodal (3), quatrimodal (4), and so on.

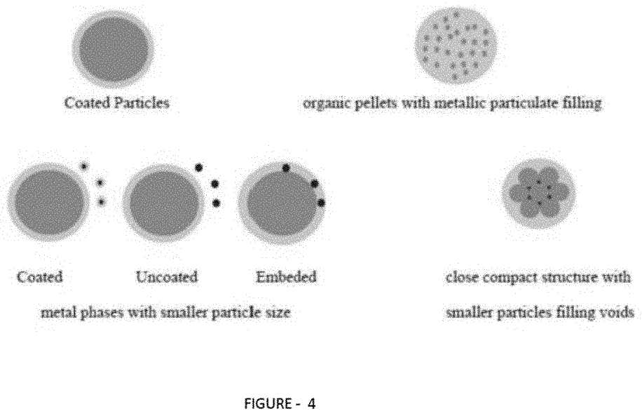

If very high volume fractions of metal are desired then the powder should be quite spherical and the particle size distribution quite narrow. The sphericity of the powder, is a dimensionless parameter defined as the ratio between the surface area of a sphere having the same volume as the particle and the surface area of the particle and for some applications it may be preferably greater than 0.53, more preferably greater than 0.76, even more preferably greater than 0.86, and even more preferably greater than 0.92. When in the present invention high metallic particulate compactation is desired often a high sphericity of the metallic powder is desirable preferably greater than 0.92, more preferably greater than 0.94, even more preferably greater than 0.98 and even 1. When speaking of sphericity, for some applications the sphericity can be evaluated for just the majority of the powder in terms of the average sphericity of the most spherical particulates. The 60% of the volume of powder employed or more, preferably 78% or more, more preferably 83% or more and even more preferably 96% or more should be considered to calculate the average. Some applications where active surface is determinant on the quality of the diffusion during the sintering, tend to benefit from powders with greater active surface, and thus high sphericity in then not necessarily desirable, in such cases sometimes sphericities below 0.94, preferably below 0.88%, more preferably below 0.68% and even below 0.48 can be advantageous. In an embodiment at least part of the metallic powders is coated and/or embedded, or in any other possible configuration as explained in FIG. 4, in this case in an embodiment the sphericity is referred to the AM particulates. The inventor has seen that for many instances of the present invention the mean particle size of the metallic powders used, along with particle distribution and sphericity can play a capital role not only on the final properties but even on the geometries that can be attained. In an embodiment different size fractions of at least two metallic powders and one polymer are mixed together. In many cases the organic material may be added to the mixture in powder form, with their own particle size distribution. In other embodiments a metallic powder or the mixture of more than two powders with different melting points may be coated and/or embedded, or in any other possible configuration as explained in FIG. 4, in this case in an embodiment the system is assimilate to as de case of one metallic powder distribution wherein the sizes are referred to the AM particulates (as defined through this document). If high densities are required, which is often the case when high mechanical properties of the final component are desired, a high density of metallic powder mix is desirable, even as near as possible to close packing in the case of spherical powders. In an embodiment a high apparent density allows avoiding subsequent defects during compaction and several models have been developed for predicting it. In an embodiment it is beneficial for enhancing the packing density to consider a non-uniform size distribution.

As it is clear from the description in this document for some implementations of the present invention one of the critical parameters to determine attainable accuracy is the AM Particulate size, while for other implementations is rather the metallic powder size.

As is clear from the description in this document for some implementations of the present invention one of the critical parameters to determine attainable accuracy is the AM Particulate size, while for other implementations is rather the metallic powder size. It has also been seen that for many instances of the present invention, not a great accuracy is required in such instances and when speed of manufacturing is priorized, when accuracy is determined by the AM Particulate size, often AM particulates with an equivalent mean diameter of 22 microns or bigger, preferably 55 microns or bigger, more preferably 102 microns or bigger, and even 220 microns or bigger can be used. In the same scenario but for technologies where metallic powder size determines accuracy, equivalent mean diameters of 16 microns or more are often desirable, preferably 32 microns or more, more preferably 52 microns or more and even 106 microns or more. On the other hand, for cases where higher accuracy is advisable, the inventor has seen that when accuracy is determined by the AM particulate size, often AM particulates with an equivalent mean diameter of 88 microns or smaller, preferably 38 microns or smaller, more preferably 18 microns or smaller, and even 8 microns or smaller can be used. In the same scenario but for technologies where metallic powder size determines accuracy, equivalent mean diameters of 48 microns or smaller are often desirable, preferably 28 microns or less.

In an embodiment AM particulates used have an equivalent mean diameter of 16 microns or more, in other embodiment 22 microns or more, in other embodiment 32 microns or more, in other embodiment 52 microns or more, in other embodiment 55 microns or more, in other embodiment 102 microns or more, in other embodiment 106 microns or more, and even in other embodiment 220 microns or more.

In other embodiment AM particulates used have an equivalent mean diameter of 88 microns or smaller, in other embodiment 38 microns or smaller, in other embodiment 18 microns or smaller, and even in other embodiment 8 microns or smaller.

In an embodiment it would be interesting to have a bimodal distribution for a more dense packing and even in other embodiment in order to have even a more dense packing to have a trimodal particle size distribution, this not exclude than for certain applications more complex size distribution are required.

In this aspect, it is often particularly advantageous for the proper mixing and further metallic powder volume fraction in the particulates to choose different particle size, so that for example the main powder size is chosen so that it will tend to occupy the main positions of the close packed structure, in an embodiment it is interesting to choose a secondary powder with a size distribution lower than the main particle size. In a particular application the secondary powder size is chosen so that it tends to occupy the octahedral interstices, in a particular application thus the relation between the main and the secondary particle size should be roughly 1:0.414. In some applications it is interesting to choose a third powder size coinciding with another size distribution lower than the main and secondary particle size. In a particular application a third powder is chosen to have a size so that it tends to fill the tetrahedral sites, thus the relation of sizes between the main and third powder should be roughly 1:0.225).

Depending on the AM technology or other shaping technique chosen and the associated powder binding technology the polymer or mix of polymers (and eventually other functional constituents like wax, pigments, any kind of charge . . . ) is chosen accordingly. If high densities are required, which is often the case when high mechanical properties of the final component are desired, a high density of metallic powder mix is desirable, even as near as possible to close packing in the case of spherical powders. It is often particularly advantageous for the proper mixing and further metallic powder volume fraction in the particulates to choose different particle sizes for the different metallic powders, so that for example the main powder size is chosen so that it will tend to occupy the main positions of the close packed structure, while the secondary powder size is chosen so that it tends to occupy the octahedral interstices, thus the relation of sizes should be roughly 1:0.414. Eventually a third powder is chosen to have a size so that it tends to fill the tetrahedral sites, thus the relation of sizes should be roughly 1:0.225.

In an embodiment the powder mixture has a main powder, a secondary powder with a relation between the main and the secondary particle size 1:0.414. In another embodiment the powder mixture further comprises a third powder with a relation between the main and the third powder particle size 1:0.225. In an embodiment this relation is made respect to the d50 of the main powder in other embodiment to the highest mode value of the main powder.

In an embodiment the octahedral and/or tetrahedral holes of the main powder are wholly occupied by a secondary powder. In other embodiment ¾ or less of the octahedral and/or tetrahedral holes of the main powder are occupied by a secondary powder. In other embodiment ½ or less of the octahedral and/or tetrahedral holes of the main powder are occupied by a secondary powder. In other embodiment ⅓ or less of the octahedral and/or tetrahedral holes of the main powder are occupied by a secondary powder. In other embodiment ¼ or less of the octahedral and/or tetrahedral holes of the main powder are occupied by a secondary powder.

In an embodiment the octahedral and/or tetrahedral holes of the main powder are wholly occupied by a secondary and a third powder. In other embodiment ¾ or less of the octahedral and/or tetrahedral holes of the main powder are occupied by a secondary and a third powder. In other embodiment ½ or less of the octahedral and/or tetrahedral holes of the main powder are occupied by a secondary and a third powder. In other embodiment ⅓ or less of the octahedral and/or tetrahedral holes of the main powder are occupied by a secondary and a third powder. In other embodiment ¼ or less of the octahedral and/or tetrahedral holes of the main powder are occupied by a secondary and a third powder.

In an embodiment it is often particularly advantageous for the proper mixing and further metallic powder volume fraction in the particulates to choose different particle size, so that for example the main powder size is chosen so that it will tend to occupy the main positions of the close packed structure, in an embodiment it is interesting to choose a secondary powder with a size distribution lower than the main particle size. In a particular application the secondary powder size is chosen so that it tends to occupy the interstices of main powder, in a particular application thus the relation between the main and the secondary particle size should be roughly 1:0.125. In some applications it is interesting to choose a third powder size to occupy the interstices of main powder together with the secondary powder, for example if the cost of the secondary powder is high or if the composition of the secondary powder has elements which are not desired in high contain in the powder mixture, thus the relation of sizes between the main and third powder should be roughly 1:0.125).

In an embodiment the powder mixture has a main powder, a secondary powder with a relation between the main and the secondary particle size 1:0.125. In another embodiment the powder mixture further comprises a third powder with a relation between the main and the third powder particle size 1:0.125. In an embodiment this relation is made respect to the d50 of the main powder in other embodiment to the highest mode value of the main powder. In another embodiment more than two powders having a relation of sizes with the main powder 1:0.125 may be added to the powder mixture.

In an embodiment it is often particularly advantageous for the proper mixing and further metallic powder volume fraction in the particulates to choose different particle size, so that for example the main powder size is chosen so that it will tend to occupy the main positions of the close packed structure, but also part of the insterticies between the particles of highest size of the main powder, in an embodiment for example having a main powder having a bimodal distribution of particles size. in an embodiment it is interesting to choose this second size of the main powder particle distribution with a relation between the highest particles of the main powder (the particles of the highest mode value of the main powder) and the smaller particles be roughly 1:0.125.

In an embodiment the powder mixture further comprise particles with a size relation between the main and this particles of 1:0.154. In an embodiment these particles are from the main powder. In other embodiment these particles are from the secondary powder. In other embodiment these particles are from the third powder.

In an embodiment the inventor has been able to observe the surprisingly beneficial effect of homogeinity of properties and in a particular case a lack of micro-segregation when the tetrahedral or octahedral holes of main particles are wholly occupied or round fraction of ½, ⅓ or ¼. By close to a round fraction is understood a difference of +/−10% or less, preferably +/−8% or less, more preferably +/−4% or less and even +/−2% or less related to the round fraction.

In an embodiment main power refers to the metallic powder having the highest % in volume of all the metallic powders.

In an embodiment main power refers to the metallic powder having the highest % in weight of all the metallic powders.

In an embodiment and depending of the application the main powder may be a low melting point alloy and in other applications a high melting point alloy.

In an embodiment main power refers to a high melting point alloy.

In an embodiment main power refers to a the high melting point alloy having the highest weight percentage of the high melting point alloys of the powder mixture.

In an embodiment main power refers to a the high melting point alloy having the highest volume percentage of the high melting point alloys of the powder mixture.

In an embodiment main power refers to a low melting point alloy.

In an embodiment main power refers to a the low melting point alloy having the highest weight percentage of the low melting point alloys of the powder mixture.

In an embodiment main power refers to a the low melting point alloy having the highest volume percentage of the low melting point alloys of the powder mixture.

In an embodiment it is interesting have even smaller particles (referred in this document as Small Particles). In an embodiment the relation between the main and this small particles is 0.18 or less the main particle size, in other embodiment 0.165 or less, in other embodiment 0.145 or less, in other embodiment 0.12 or less, and even in other embodiment 0.095 or less. In an embodiment this relation is made respect to the d50 of the main powder in other embodiment to the highest mode value of the main powder. In an embodiment these Small Particles are 5.3% in volume or more, in another embodiment 6.4% or more, in another embodiment 7.0% or more, in another embodiment 7.3% or more, in another embodiment to be 9.3%, in another embodiment to be 11.2% in volume or more, in another embodiment 14.7% or more, in another embodiment 18.7% or more, in another embodiment 21.4% or more, in another embodiment 24.3% or more, in another embodiment 28.2% in volume or more, in other embodiment to be 29.2% or more, and even in other embodiment to be 32.6% or more. of the powder mixture.

In an embodiment the voids of the main powder are wholly occupied by Small Particles from a secondary powder. In other embodiment ¾ or less of the octahedral and/or tetrahedral holes of the main powder are occupied by Small Particles from a secondary powder. In other embodiment ½ or less of the octahedral and/or tetrahedral holes of the main powder are occupied by Small Particles from a secondary powder. In other embodiment ⅓ or less of the octahedral and/or tetrahedral holes of the main powder are occupied by Small Particles from a secondary powder. In other embodiment ¼ or less of the octahedral and/or tetrahedral holes of the main powder are occupied by a Small Particles from a secondary powder.

In an embodiment the voids of the main powder are wholly occupied by Small Particles from a secondary and a third powder. In other embodiment ¾ or less of the octahedral and/or tetrahedral holes of the main powder are occupied by Small Particles from a secondary and a third powder. In other embodiment ½ or less of the octahedral and/or tetrahedral holes of the main powder are occupied by Small Particles from a secondary and a third powder. In other embodiment ⅓ or less of the octahedral and/or tetrahedral holes of the main powder are occupied by Small Particles from a secondary and a third powder. In other embodiment ¼ or less of the octahedral and/or tetrahedral holes of the main powder are occupied by a Small Particles from a secondary and a third powder.

In an embodiment the Small Particles are 5.3% in volume or more of the powder mixture, in other embodiment to be 6.4% or more, in other embodiment 7.0% or more, in another embodiment 7.3% or more in other embodiment 9.3% or more, in other embodiment to be 11.2% or more, in other embodiment to be 14.7% or more, in other embodiment 18.7% or more, in other embodiment 21.4% or more, in other embodiment to be 24.3% or more, in other embodiment to be 27.1% or more, in another embodiment 28.2% in volume or more in other embodiment to be 29.2% or more, and even in other embodiment to be 32.6% or more.

In an embodiment the Small Particles are 5.3% in volume or more of the metallic phase (the sum of all metallic powders in the powder mixture), in other embodiment to be 6.4% or more, in other embodiment 7.0% or more, in another embodiment 7.3% or more in other embodiment 9.3% or more, in other embodiment to be 11.2% or more, in other embodiment to be 14.7% or more, in other embodiment 18.7% or more, in other embodiment 21.4% or more, in other embodiment to be 24.3% or more, in other embodiment to be 27.1% or more, in another embodiment 28.2% in volume or more in other embodiment to be 29.2% or more, and even in other embodiment to be 32.6% or more.

In an embodiment the Small Particles are 33.1% in volume or less of the powder mixture, in other embodiment to be 29.3% or less, in other embodiment to be 26.4% or less, in other embodiment 22.9% or less, in other embodiment 18.6% or less, in other embodiment to be 15.6% or less, in other embodiment to be 12.7% or less, in other embodiment 9.3% or less, in other embodiment 8.1% or less, in other embodiment to be 6.1% or less, in other embodiment to be 4.2% or less, in other embodiment to be 3.2% or less, and even in other embodiment to be 1.9% or less.

In an embodiment the Small Particles are 33.1% in volume or less of the metallic phase (the sum of all metallic powders in the powder mixture), in other embodiment to be 29.3% or less, in other embodiment to be 26.4% or less, in other embodiment 22.9% or less, in other embodiment 18.6% or less, in other embodiment to be 15.6% or less, in other embodiment to be 12.7% or less, in other embodiment 9.3% or less, in other embodiment 8.1% or less, in other embodiment to be 6.1% or less, in other embodiment to be 4.2% or less, in other embodiment to be 3.2% or less, and even in other embodiment to be 1.9% or less.

In an embodiment these small particles are filling the voids of the particles from main powder.

In an embodiment these small particles are from a low melting point alloy and are filling the voids of the particles from a main powder. In an embodiment this main powder is a high melting point alloy.

In an embodiment the powder mixture comprises small particles from at least one low melting point alloy in powder form.

In an embodiment the powder mixture comprises a main powder and a secondary powder wherein the particle size relation between the main and this particles from the secondary powder is 0.18 or less the main particle size, in other embodiment 0.165 or less, in other embodiment 0.145 or less, in other embodiment 0.12 or less, and even in other embodiment 0.095 or less.

In an embodiment to obtain a high tap density of the powder mixture, bi-modal and/or tri-modal size distributions are used, having the powder mixture a narrow size distribution of the particle size around each mode value of the distribution and particles with a high sphericity. In an embodiment the bi-modal distributions, have a main particle size, corresponding with the higher mode value of the particle size distribution being also the higher volume percentage of the powder mixture, and other mode value corresponding with particles of small size (with a diameter around 0.414 times the diameter of main size particles) used to fill totally or at least partially the octaedrical voids between the particles of the main size. In an embodiment tri-modal particle size distributions are used, wherein even smaller particles (with a diameter around 0.215 times the diameter of main size particles) are used to totally or at least partially fill the tetraedrical voids between the particles of the main size

In an embodiment mixtures of two or three powder sizes are preferred. In an embodiment a bimodal distribution of the powder mixture is selected, having a main fraction of particles, which are more than 70% in volume of the powder mixture, and other fraction of smaller particles having a diameter 0.125 times the diameter of the particles of the main fraction.

In an embodiment the powder mixture comprises small particles from at least one low melting point alloy in powder form.

In an embodiment the powder mixture comprises small particles from at least one high melting point alloy in powder form.

In an embodiment the powder mixture comprises small particles from at least one low melting point alloy in powder form and a high melting point alloy in powder form.

In an embodiment the powder mixture comprises further a third metallic powder having also a particle size relation between the main and this particles from the third powder is 0.18 or less the main particle size, in other embodiment 0.165 or less, in other embodiment 0.145 or less, in other embodiment 0.12 or less, and even in other embodiment 0.095 or less.

In another embodiment the main powder has also a size distribution wherein further contains small particles.

In an embodiment at least 26% of the small particles are from the main powder. In other embodiment 33% or more. In other embodiment 46% or more. In other embodiment 61% or more. In other embodiment 72% or more and even in other embodiment 84% or more.

In an embodiment at least 26% of the small particles are from a high melting point alloy. In other embodiment 33% or more. In other embodiment 46% or more in other embodiment 61% or more. In other embodiment 72% or more and even in other embodiment 84% or more.

In an embodiment the powder mixture has a packing density higher than 41.3%, in another embodiment higher than 52.7%, in another embodiment higher than 64.3%, in another embodiment higher than 71.6%, in another embodiment higher than 77.3%, in another embodiment higher than 86.8% and in another embodiment higher than 91.2%, in another embodiment higher than 93.8% and even in another embodiment higher than 96.6%.

In an embodiment the powder mixture is vibrated.

Depending on the importance of the metallic volume fraction in the AM particulates and the importance of the homogeneous mixing of the different metallic and in some cases polymer powders, narrow size distributions of the powders have to be used. In this sense the inventor has seen that it is desirable for a good close compacting to have a size distribution with a geometric standard deviation below 1.8, preferably below 1.4, more preferably below 0.8 and even more preferably below 0.4. In an embodiment where there are more than one mode values in the distribution this geometric standard deviation refers to the size distribution around any of the different mode values (to clarify this for example where two powder mixtures are considered having two or more mode values there will be two or more geometric standard deviations one around each mode value and the geometric standard deviation for the two or more mode values may has a narrow size distribution). In the case of having some of the particles filling a particular type of interstice it is desirable to have a mean particle size (d50) which is within a 38% deviation from the theoretical interstice size, preferably within a 22% more preferably within a 12% and even within a 4%. Such deviation is calculated as follows: for example in the case of the octahedral interstices

d50(large particle)×0.414×(1+X%)>d50(small particle)>d50(large particle)×0.414×(1−X%)

where X % is the percentual deviation.

In an embodiment the size distribution of the particles in the powder mixture have a geometric standard deviation below 1.8, preferably below 1.4, more preferably below 0.8 and even more preferably below 0.4.

In an embodiment the metallic phase (the sum of all metallic powders comprised in the powder mixture) is 24% by weight or more of the total composition of the powder mixture, in another embodiment 36% or more, in another embodiment 56% or more, and even in another embodiment 72% or more.

In an embodiment the invention refers to a powder mixture comprising at least one metallic powder or more than one metallic powder with similar melting point. In an embodiment this at least one metallic powder is any of the Fe based alloys disclosed in the present document in powder form. In an embodiment the powder mixture further comprises an organic compound. The at least one metallic powder; in an embodiment the metallic powder particles have an sphericity of 0.53 or more, in another embodiment greater than 0.76, and even in another embodiment greater than 0.86, in another embodiment greater than 0.92. In another embodiment greater than 0.94, and even in another embodiment greater than 0.98. in another embodiment the metallic powder has a size distribution such as to obtain a packing density of the powder mixture higher than 41.3%, in another embodiment higher than 52.7%, in another embodiment higher than 64.3%, in another embodiment higher than 71.6%, in another embodiment higher than 77.3%, in another embodiment higher than 86.8% and in another embodiment higher than 91.2%, in another embodiment higher than 93.8% and even in another embodiment higher than 96.6%. In an embodiment this powder mixture by means of a fasting shaping method, and often post-processing treatments allows the manufacture of a metallic or at least partially metallic component. In an embodiment the invention refers to the use of this powder mixture to the manufacture of a metallic or at least partially metallic component.

In an embodiment the invention refers to a powder mixture comprising at least one metallic powder.

In an embodiment when only one metallic powder from an alloy is contained in the powder mixture, metallic phase is referred to this metallic powder. In another embodiment, when more than one metallic powders from different alloys are contained in the powder mixture, metallic phase refers to all the metallic powders.

In an embodiment the invention refers to a powder mixture comprising at least two metallic powders.

In an embodiment the invention refers to a powder mixture comprising at least one low melting point alloy and a high melting point alloy in powder form.

In an embodiment the low melting point alloy is a gallium alloy. In an embodiment the low melting point is a gallium alloy containing more than 51% by weight Ga, in another embodiment more than 62%, in another embodiment more than 71%, in another embodiment more than 83%, in another embodiment more than 91%, and even in another embodiment more than 96%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%.

In an embodiment the low melting point alloy is an AlGa alloy. In an embodiment the low melting point is an Al based alloy containing more than 0.1% by weight Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%.

In an embodiment the low melting point alloy is a SnGa alloy. In an embodiment the low melting point alloy is a Sn based alloy, containing more than 0.1% Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. In an embodiment the low melting point is a existing Sn based alloy containing more than 0.1% Ga, in another embodiment more than 1.2%, in another embodiment more than 3.4%, in another embodiment more than 5.7%, in another embodiment more than 7.1%, and even in another embodiment more than 9.6%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%.

In an embodiment the low melting point alloy is a MgGa alloy. In an embodiment the low melting point alloy is a Mg based alloy, containing more than 0.1% Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. For some applications gallium content of the gallium alloy may be replaced by Sn, Bi, Sc, Mn, B, K, Na, Mg and/or Si, in an embodiment at least 5% by weight of gallium in the gallium alloy is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%

In an embodiment the low melting point alloy is a CuGa alloy. In an embodiment the low melting point alloy is a Cu based alloy, containing more than 0.1% Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. In an embodiment the low melting point is a existing Cu based alloy containing more than 0.1% Ga, in another embodiment more than 1.2%, in another embodiment more than 3.4%, in another embodiment more than 5.7%, in another embodiment more than 7.1%, and even in another embodiment more than 9.6%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%.

In an embodiment the low melting point alloy is a MnGa alloy. In an embodiment the low melting point alloy is a Mn based alloy, containing more than 0.1% by weight Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%—

In an embodiment the low melting point alloy is a NiGa alloy. In an embodiment the low melting point alloy is a Ni based alloy, containing more than 0.1% by weight Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%.

In an embodiment the low melting point alloy is a high manganese containing alloy. In an embodiment the low melting point alloy is a high manganese Fe based alloy containing carbon. In an embodiment the low melting point is a Fe based alloy containing carbon (and alloy comprising iron, manganese and gallium) and more than 0.1% by weight Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%.

In another embodiment the low melting point alloy is a MgAl alloy. In an embodiment the low melting point is a Mg based alloy (and alloy comprising manganese and gallium) containing more than 0.1% by weight Ga, in another embodiment more than 1.2%, in another embodiment more than 3.4%, in another embodiment more than 5.7%, in another embodiment more than 7.1%, in another embodiment more than 9.6%, in another embodiment more than 14.3%, in another embodiment more than 19.1%, and even in another embodiment more than 24%. For some applications gallium content of the gallium alloy may be replaced by Sn, Bi, Sc, Mn, B, K, Na, Mg and/or Si, in an embodiment at least 5% by weight of gallium is replaced with an element selected from Bi, Pb, Rb, Zn, Cd, In, Sn, K, Na, Mn, B, Sc, Si, and/or Mg in another embodiment at least 10%, in another embodiment at least 15%, in another embodiment at least 25% and even in another embodiment at least 30%.

In an embodiment a high melting point alloy is selected from: a Fe, Ni, Co, Cu, Mg, W, Mo, Al or Ti based alloy.

In an embodiment the Fe based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Ni based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Co based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Cu based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Mg based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the W based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Mo based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Al based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the Ti based alloy particles have a d50 value of 780 microns or less, in another embodiment 380 microns or less, in another embodiment 180 microns or less, in another embodiment 120 microns or less, 78 microns or less, in another embodiment 48 microns or less, in another embodiment 18 microns or less and even in another embodiment 8 micros or less.

In an embodiment the high melting point alloy is any existing Fe alloy. In an embodiment a high melting point alloy is any of the Fe based alloy disclosed in the present document. In an embodiment a high melting point alloy is any Fe based alloy discovered in the future suitable for the powder mixture of the present invention.

In an embodiment the high melting point alloy is any existing Ni alloy. In an embodiment a high melting point alloy is the Ni based alloy disclosed in the present document. In an embodiment a high melting point alloy is any Ni based alloy discovered in the future suitable for the powder mixture of the present invention.

In an embodiment the high melting point alloy is any existing Co alloy. In an embodiment a high melting point alloy is the Co based alloy disclosed in the present document. In an embodiment a high melting point alloy is any Co based alloy discovered in the future suitable for the powder mixture of the present invention.

In an embodiment the high melting point alloy is any existing Cu alloy. In an embodiment a high melting point alloy is the Cu based alloy disclosed in the present document. In an embodiment a high melting point alloy is any Cu based alloy discovered in the future suitable for the powder mixture of the present invention.

In an embodiment the high melting point alloy is any existing Mg alloy. In an embodiment a high melting point alloy is the Mg based alloy disclosed in the present document. In an embodiment a high melting point alloy is any Mg based alloy discovered in the future suitable for the powder mixture of the present invention.

In an embodiment the high melting point alloy is any existing W alloy. In an embodiment a high melting point alloy is the W based alloy disclosed in the present document. In an embodiment a high melting point alloy is any W based alloy discovered in the future suitable for the powder mixture of the present invention.

In an embodiment the high melting point alloy is any existing Mo alloy. In an embodiment a high melting point alloy is the Mo based alloy disclosed in the present document. In an embodiment a high melting point alloy is any Mo based alloy discovered in the future suitable for the powder mixture of the present invention.

In an embodiment the high melting point alloy is any existing Al alloy. In an embodiment a high melting point alloy is the Al based alloy disclosed in the present document. In an embodiment a high melting point alloy is any Al based alloy discovered in the future suitable for the powder mixture of the present invention.

In an embodiment the high melting point alloy is any existing Ti alloy. In an embodiment a high melting point alloy is the Ti based alloy disclosed in the present document. In an embodiment a high melting point alloy is any Ti based alloy discovered in the future suitable for the powder mixture of the present invention.

In an embodiment the invention refers to a powder mixture comprising at least a low melting point alloy and a high melting point metallic alloy in powder form wherein the low melting point alloy is an Al based alloy having more than 90% by weight Al and the high melting point alloy is an Fe based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is an Ni based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is a Co based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is a Cu based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is an Al based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is an Ti based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is an W based alloy and optionally an organic compound.

In an embodiment the invention refers to a powder mixture comprising at least a low melting point alloy and a high melting point metallic alloy in powder form wherein the low melting point alloy is an Al based alloy having more than 90% by weight Al and the high melting point alloy is an Mo based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an AlGa and the high melting point alloy is a Cu based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an AlGa alloy and the high melting point alloy is an Mo based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is a Cu based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an CuGa alloy and the high melting point alloy is an Mo based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is a Cu based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an NiGa alloy and the high melting point alloy is an Mo based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is a Cu based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an SnGa alloy and the high melting point alloy is an Mo based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is a Cu based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an MgGa alloy and the high melting point alloy is an Mo based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is a Cu based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an MnGa alloy and the high melting point alloy is an Mo based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is an Fe based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is an Ni based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is a Co based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is a Cu based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is an Al based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is an Ti based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is an W based alloy and optionally an organic compound.

In an embodiment the invention refers to a powder mixture comprising at least a low melting point alloy and a high melting point metallic alloy in powder form wherein the low melting point alloy is an Gallium alloy and the high melting point alloy is an Mo based alloy and optionally an organic compound.

In an embodiment the packing density of the powder mixture is higher than 41.3%, in another embodiment higher than 52.7%, in another embodiment higher than 64.3%, in another embodiment higher than 71.6%, in another embodiment higher than 77.3%, in another embodiment higher than 86.8% and in another embodiment higher than 91.2%, in another embodiment higher than 93.8% and even in another embodiment higher than 96.6%.

In an embodiment the high melting point alloy is the main powder of the powder mixture.

In an embodiment the low melting point alloy is selected to fill the octaedrical and/or tetraedrical holes of the particles of the high melting point alloy

In an embodiment the low melting point alloy is selected to fill the voids of the particles from main powder.

In an embodiment the low melting point has a particle size relation is 0.18 or less of the high melting point particle size, in other embodiment 0.165 or less, in other embodiment 0.145 or less, in other embodiment 0.12 or less, and even in other embodiment 0.095 or less.

In an embodiment the invention refers to the use of a powder mixture comprising at least one metallic powder and optionally an organic compound to manufacture a metallic or at least partially metallic component

In an embodiment the invention refers to the use of a powder mixture comprising at least two metallic powders with different melting point and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Al based alloy having more than 90% by weight Al and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an AlGa alloy and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an CuGa alloy and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an NiGa alloy and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an SnGa alloy and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MgGa alloy and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an MnGa alloy and the high melting point alloy is an Mo based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is an Fe based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is an Ni based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is a Co based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is a Cu based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is an Al based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is an Ti based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is an W based alloy and optionally an organic compound to manufacture a metallic or at least partially metallic component.

In an embodiment the invention refers to the use of a powder mixture comprising at least a low melting point alloy and a high melting point metallic alloy in powder form wherein the low melting point alloy is an Gallium alloy and the high melting point alloy is an Mo based alloy and optionally an organic compound to manufacture a metallic or at least partially metallic component.

In an embodiment the invention refers to method for the manufacturing of at least partly metallic objects such as pieces, parts, components or tools, comprising the following steps:

a. providing a component which contains at least one organic phase and at least one metallic phase;

b. shaping the component with a manufacturing process where the shape retention is mostly provided by the organic phase;

c. subjecting the component to a temperature above 0.35*Tm, wherein Tm is the melting temperature of the metallic phase having the lowest melting point, and allowing sufficient time for the formation of a liquid phase and/or adequate diffusion between the metallic phases, thereby ensuring that the shape retention process in the metallic phases is completed before the at least one organic phase is degraded.

In an embodiment the invention refers to a method according to claim 1 where the component contains at least two metallic phases and the difference in the melting temperature between the metallic phases is 110° C. or more.

In an embodiment the invention refers to a method according to claim 1 or 2 where the component contains at least one metallic phase with a melting temperature of 490° C. or less.

In an embodiment the invention refers to a method according to any one of claims 1 to 3 where the component contains at least one metallic phase whose domain of coexistence of a liquid and a solid phase extends over 110° C. or more.

In an embodiment the invention refers to a method according to any one of claims 1 to 4 where the component contains at least one metallic phase whose melting temperature increases at least 110° C. at the within the implementation of step c) as a result of incorporation through diffusion or dissolution of at least one chemical element of a another metallic phase.

In an embodiment the invention refers to a method according to any one of claims 1 to 5 where the component contains at least one metallic phase with 0.1 wt % or more Gallium.

In an embodiment the invention refers to a method according to any one of claims 1 to 6 where the shape-retention manufacturing process in step b) is an Additive Manufacturing method.

In an embodiment the invention refers to a method according to any one of claims 1 to 7 where the shape-retention manufacturing process in step b) of the method is an Additive Manufacturing method based on the selective curing of a photo-sensible resin.

In an embodiment the invention refers to a method according to any one of claims 1 to 8 where the shape-retention manufacturing process in step b) of the method is an Additive Manufacturing method based on the selective curing of a resin through a chemical reaction.

In an embodiment the invention refers to a method according to any one of claims 1 to 9 where the shape-retention manufacturing process in step b) of the method is an Additive Manufacturing method based on the selective melting or plastification of a polymer.

In an embodiment the invention refers to a method according to any one of claims 1 to 10 where the shape-retention manufacturing process in step b) of the method is an Additive Manufacturing method based on localized melting or softening of a polymer where the temperature gradient for the selective melting or softening is achieved through an additive or agent that either intensifies or prevents the energy flow from a broader source into the polymer and said agent can be applied in controlled patterns.

In an embodiment the invention refers to a method according to any one of claims 1 to 11 where the shape-retention manufacturing process in step b) of the method is a polymer shaping method selected from the group consisting of injection molding, blow-molding, thermoforming, casting, compression, pressing, RIM, extrusion, rotomolding, dip molding and foam shaping.

In an embodiment the invention refers to a method according to any one of claims 1 to 12 where the shape-retention manufacturing process in step b) of the method is an Additive Manufacturing method based on the curing of a photo-sensible resin where a continuous curing method is employed.

In a method according to any one of claims 1 to 13 wherein, in step c), the component is subjected to a temperature above 0.35*Tm, wherein Tm is the melting temperature of the metallic phase having the lowest melting point, and below the highest degradation temperature of the at least one organic phases, and then permitting sufficient time to allow an increase of concentration at 10 micrometres under the surface of the particulates of the majoritarian metallic phases of at least one element of the low melting point metallic phases, adds up to a relative weighted average of a 3% or more (only the 30% with the highest values has been considered to calculate the mean). Wherein the distance under the surface is measured orthogonal to the contact plain between the two different nature particulates on the normal crossing the first point of contact.

In an embodiment the invention refers to a method according to any one of claims 1 to 14 where at some point during steps b) or c) of the method at least a 1 vol % metallic liquid phase is formed.

In an embodiment the invention refers to a feedstock containing at least one organic phase and at least one metallic phase with a melting temperature lower than twice the highest degradation temperature of the organic phases, where the melting temperature of the at least one metallic phase and the degradation temperature of the at least one organic phase are expressed in Kelvin degrees, and where the metallic phases represent a volume fraction of 36% or more.

In the present invention a method is developed for the construction of cost effective pieces trough AM, or eventually another fast shaping process. The method is often valid for pieces with any kind of air to material ratio, and any kind of size or geometry. In an embodiment the method allows the manufacture of big components that can not be obtained with traditional manufacturing methods. In an embodiment the present invention relates to the manufacture of metallic or at least partially metallic components, using a powder mixture comprising at least one metallic powder by shaping the component and in some embodiments subjecting the component obtained after shaping to a post-processing treatment. In an embodiment an organic material is further comprised in the powder mixture. In another embodiment a polymer is comprised in the powder mixture. In an embodiment at least one powder is partially and/or totally coated by an organic material. In an embodiment when there are more than one metallic powder in the powder mixture, any of the powders may be at least partially coated with a polymer and there may be more than one polymer totally or at least partially coating each metallic powder and/or different polymers may be used for coating totally or at least partially each metallic powder. The method has several realizations depending on the particular piece to be manufactured.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound shaping the powder mixture with a shaping technique resulting in a shaped component subjecting the shaped component to at least one post-processing treatment In an embodiment the invention refers to a method which allows the manufacture of components in a fast way and with lower prices when compared to traditional manufacturing processes. In another embodiment the invention allows the manufacture of complex geometries which cannot be obtained using traditional manufacturing processes such as forging, casting, stamping, sandblasting, die cutting, case hardening and/or soldering among other manufacturing processes for metallic or at least partially metallic components.

In an embodiment shaped component refers to the component obtained after submit the powder mixture to a shaping technique.

In an embodiment metallic powder refers to an alloy in powder form. In an embodiment metallic powder refers to a Fe, Ni, Mo, Ti, Al, W, Cu, Co and/or Mg based alloy in powder form.

In an embodiment a powder mixture comprising at least one metallic powder refers to a mixture of one or more alloys in powder form.

In an embodiment alloy refers to a mixture of metals optionally comprising other non-metallic components.

In an embodiment any of previously described alloys in powder form are suitable for use as metallic powder in the method of the invention. In an embodiment any of previously described powder mixtures comprising at least one high melting point and low melting point are suitable for use as metallic powder in the method of the invention.

For pieces with a low air/material ratio, a system based on the configuration by removal can be employed. For pieces with a high air/material ratio, a shaping system based on aggregation or conformation is often preferred. Different shaping systems can be employed for the manufacturing of the piece either simultaneously or sequentially. The method of the present invention can work directly on direct metal aggregation, but for many applications it is though very advantageous to have a mixed polymer metal material.

In an embodiment components are referred to structures, tools, pieces, moulds and/or dies among others. In an embodiment components with complex geometries may be obtained using the method of the present invention.

In an embodiment components are referred to structures. In an embodiment components are referred to tools. In an embodiment components are referred to structures. In an embodiment components are referred to moulds. In an embodiment components are referred to dies. In an embodiment components are referred to pieces.

In several embodiments complex geometries refers to geometries which cannot be obtained using injection molding, in other embodiment to geometries which cannot be made in an economic way using injection molding in respect of best practices guidelines of plastic injection moulding of American mould builders association, in other embodiment to geometries which cannot be obtained using stamping dies, in other embodiment to geometries which cannot be made in an economic way using stamping dies, in other embodiment structures which cannot be obtained using commercially available profiles, in an embodiment components which US plastic injection association would estimate a cost over 1000 US$ for the mould to manufacturing this component (costs in date January, 2010), in other embodiment geometries which cannot be obtained by lox wax casting and/or sand casting, in other embodimentdies which cannot be obtained using traditional manufacturing methods for die manufacturing such as milling, boring and/or electro-erosion among others.

In an embodiment, when referring to metal injection moulding (MIM), big components refers to components of 25 g or more, in other embodiment 55 g or more, in other embodiment 155 g or more, in other embodiment 210 g or more, in other embodiment 320 g or more, and even in other embodiment 1 Kg or more.

In an embodiment partially metallic components refers to components having metals and other constituents different from metals in their composition. In an embodiment constituents different from metals refers to constituents such as, but not limited to, ceramics, polymers, grapheme and/or cellulose among others. In an embodiment partially metallic components refers to components having more than 0.1% in volume of other constituents different from metals in their composition, in other embodiment more than 11% in volume, in other embodiment more than 23%, in other embodiment more than 48%, in other embodiment more than 67%, in other embodiment more than 83% and even in other embodiment more than 91%.

In an embodiment the previously disclosed powder mixtures comprising any of the new Fe, Ni, Co, Cu, Mg, W, Mo, Al or Ti based alloys in powder form is especially suitable to be used with the method of the invention.

In an embodiment previously disclosed powder mixtures having a high packing density are suitable for use in the method of the invention.

In the case that the effect of the low melting point metallic constituent in the final component can only be held as non-detrimental for small concentrations of the elements of this low melting point alloy, the inventor has seen that there are several ways to proceed In order to have small concentration of such alloy yet enough contribution to the shape retention upon degradation of the polymer that provides shape retention during the manufacturing step. It has been observed that in general terms close compact structures with high volume fractions of metal in the feedstock help, and amongst others so does a homogeneous distribution of the low melting point metallic constituent. For example, if an 90%+ aluminum alloy is used as low melting point metallic constituent on a steel base metallic constituent, it is known that for many steels low % Al can have rather beneficial effects, like increasing strength through precipitation, limiting austenite grain growth, deoxidizing, providing quite hard nitriding layers . . . but those effects are achieved for rather small % Al contents in the order of magnitude between weight 0.1% and 1% (and rather closer to the lower end). So one way to deal with this situation is providing a high density close compact structure of the intended steel particulates (quite spherical shape and narrow size distribution help this purpose). Then a roughly 7.0% in volume is provided of metallic particulates with a diameter d50 being around 0.41 times the d50 diameter of the main particulates, to fill the octahedral holes. This particulates can have the same nature as the main metallic constituent or another particularly chosen to provide the desired functionality once the diffusion and all other treatments are concluded (again here spherical shape and a narrow size distribution help). Then a fine powder of the 90%+ aluminum alloy is provided with a d50 diameter being around 0.225 times the d50 diameter of the main particulates, roughly a 0.6% in volume should be provided with the intend of filling the tetrahedral holes (again here spherical shape and a narrow size distribution help). Given densities of aluminum and steel this volume fraction roughly represents 0.15% in weight of the 90%+ aluminum alloy in the final product which is within the range of generalized positive contribution of Al into steel.

In an embodiment an Al based alloy containing more than 90% by weight aluminium, is used as low melting point alloy and a steel based alloy is used as high melting point alloy in a powder mixture used for manufacturing a metallic or at least partially metallic component, in an embodiment this Al based alloy containing more than 90% by weight aluminium is less than 10% in volume of all metallic constituents. In an embodiment a 7% in volume of all metallic constituents are Al based alloy containing more than 90% by weight aluminium particles with a d50 diameter being around 0.41 times the d50 diameter of the main particulates of the steel based alloy and a 0.6% in volume of all metallic constituents are Al based alloy containing more than 90% by weight aluminium particles with a d50 diameter being around 0.225 times the d50 diameter of the main particulates of the steel based alloy.

In an embodiment the invention refers to a method of manufacturing a metallic or at least partially metallic component from a powder mixture by a shaping technique.

In an embodiment the shaping technique is an AM technique.

In an embodiment the shaping technique is an AM technique such as, but not limited to: 3D Printing, Ink-jetting, S-Print, M-Print technologies, technologies where focused energy generates a melt pool into which feedstock (powder or wire material) is deposited using a laser (Laser Deposition and Laser Consolidation), arc or e-beam heat source (Direct Metal Deposition and Electron Beam Direct Melting), fused deposition modelling (FDM), Material jetting, direct metal laser sintering (DMLS), selective laser melting (SLM), electron beam melting (EBM), selection laser sintering (SLS), stereolithography and digital light processing (DLP) among others.

In an embodiment the shaping technique is a Polymer shaping technique. In an embodiment the shaping technique is metal injection molding. In an embodiment the shaping technique is sintering. In an embodiment the shaping technique is sinter forging. In an embodiment the shaping technique is Hot Isostatic Pressing (HIP). In an embodiment the shaping technique is Cold Isostatic Pressing (CIP). In an embodiment the invention refers to a method of manufacturing metallic or at least partially metallic component from a powder mixture by a shaping technique, wherein the final metallic or at least partially metallic component is obtained after the shaping.

In an embodiment the invention refers to a method of manufacturing metallic or at least partially metallic component from a powder mixture by a shaping technique, wherein the metallic or at least partially metallic component obtained after the shaping (the green component) is submitted to at least one post-processing treatment.

In an embodiment all post-treatment may be combined between them in any suitable form.

In an embodiment the post-processing treatment is a debinding.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a debinding

subjecting the component obtained in step c to a heat treatment and optionally to a sintering and/or HIP

In an embodiment the post-processing treatment is a Heat Treatment.

In an embodiment the invention refers to a method of manufacturing metallic or at least partially metallic components such as pieces, parts, components or tools, comprising the following steps:

providing a powder mixture comprising at least a low melting point alloy and a high melting point alloy

and optionally and organic compound

shaping the powder mixture with a shaping technique

subjecting the shaped component to a Heat treatment

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a Heat treatment

subjecting the component obtained in step c to a sintering

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a Heat treatment

subjecting the component obtained in step c to a HIP

In an embodiment the post-processing treatment is a sintering.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a sintering

In an embodiment sintering is made at a temperature above 0.7*Tm of high melting point alloy (temperature 0.7 times the melting temperature of high melting point alloy). In an embodiment sintering is made at a temperature above 0.75*Tm of high melting point alloy (temperature 0.75 times the melting temperature of high melting point alloy. In an embodiment sintering is made at a temperature above 0.8*Tm of high melting point alloy (temperature 0.8 times the melting temperature of high melting point alloy. In an embodiment sintering is made at a temperature above 0.85*Tm of high melting point alloy (temperature 0.85 times the melting temperature of high melting point alloy. In an embodiment sintering is made at a temperature above 0.9*Tm of high melting point alloy (temperature 0.9 times the melting temperature of high melting point alloy. In an embodiment sintering is made at a temperature above 0.95*Tm of high melting point alloy (temperature 0.7 times the melting temperature of high melting point alloy.

In an embodiment the component is submitted to a sintering treatment before debinding. In an embodiment the component is submitted to a sintering treatment before Heat Treatment. In an embodiment the component is submitted to a sinter forging treatment before Heat Treatment.

In an embodiment the component is submitted to a HIP treatment before debinding. n an embodiment the component is submitted to a HIP treatment before debinding. In an embodiment the component is submitted to a HIP treatment before Heat Treatment.

In an embodiment the post-processing treatment is a sinter forging.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a sinter forging

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a Heat treatment

subjecting the component obtained in step c to a sinter forging

In an embodiment the post-processing treatment is a HIP.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a HIP

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a Heat treatment

subjecting the component obtained in step c to a HIP

In an embodiment the post-processing treatment is a CIP.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a CIP

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique

subjecting the shaped component to a Heat treatment

subjecting the component obtained in step c to a CIP

In an embodiment the system used to transfer heat during any treatment involving heat treatment is made using microwave, induction, convection, radiation and/or conduction.

In an embodiment the system used to transfer heat during any treatment involving heat treatment is made using microwave.

In an embodiment the system used to transfer heat during any treatment involving heat treatment is made using induction.

In an embodiment the system used to transfer heat during any treatment involving heat treatment is made using convection.

In an embodiment the system used to transfer heat during any treatment involving heat treatment is made using radiation.

In an embodiment the system used to transfer heat during any treatment involving heat treatment is made using conduction.

In an embodiment systems used to transfer heat during any treatment involving heat treatment include but is not limited to, heat treatment disclosed in this document, sintering, debinding or HIP among others.

In an embodiment post-processing treatments can be made under vacuum, low pressure, high pressure, inert atmosphere, reductive atmosphere, oxidative atmosphere among others.

In an embodiment the invention refers to a method of manufacturing a metallic or at least partially metallic component by shaping a powder mixture comprising at least one metallic powder using an AM technique, such as MIM, a HIP process, a CIP process, Sinter forging, Sintering and/or any technique suitable for powder conformation and/or any combination thereof among others; In an embodiment the powder mixture further comprises an organic compound. In another embodiment the invention refers to a method of manufacturing a metallic or at least partially metallic component by shaping a powder mixture comprising one metallic powder using an AM technique, a Polymer shaping technique, such as MIM, a HIP process, a CIP process, Sinter forging, Sintering and/or any technique suitable for powder conformation and/or any combination thereof among others; In an embodiment the powder mixture further comprises an organic compound. In another embodiment the invention refers to a method of manufacturing a metallic or at least partially metallic component by shaping a powder mixture comprising more than one metallic powders with similar melting points using an AM technique, a Polymer shaping technique, such as MIM, a HIP process, a CIP process, Sinter forging, Sintering and/or any technique suitable for powder conformation and/or any combination thereof among others. In an embodiment the powder mixture further comprises an organic compound.

In an embodiment the invention refers to a method of manufacturing a metallic or at least partially metallic component by shaping a powder mixture comprising at least two metallic powders using an AM technique, a Polymer shaping technique, such as MIM, a HIP process, a CIP process, Sinter forging, Sintering and/or any technique suitable for powder conformation and/or any combination thereof among others. In an embodiment the powder mixture further comprises an organic compound. In another embodiment the invention refers to a method of manufacturing a metallic or at least partially metallic component by shaping a powder mixture comprising at least two metallic powders with different melting point using an AM technique, a Polymer shaping technique, such as MIM, a HIP process, a CIP process, Sinter forging, Sintering and/or any technique suitable for powder conformation and/or any combination thereof among others. In an embodiment the powder mixture further comprises an organic compound. In an embodiment the invention refers to a method of manufacturing a metallic or at least partially metallic component by shaping a powder mixture comprising at least a low melting point metallic powder and a high melting point metallic powder using an AM technique, a Polymer shaping technique, such as MIM, a HIP process, a CIP process, Sinter forging, Sintering and/or any technique suitable for powder conformation and/or any combination thereof among others. In an embodiment the powder mixture further comprises an organic compound. In another embodiment the invention refers to a method of manufacturing a metallic or at least partially metallic component by shaping a powder mixture comprising more than one metallic powders with similar melting points using an AM technique, a Polymer shaping technique, such as MIM, a HIP process, a CIP process, Sinter forging, Sintering and/or any technique suitable for powder conformation and/or any combination thereof among others, wherein the low melting point metallic powder is selected from a Fe, Ni, Co, Cu, Mg, W, Mo, Al and Ti based alloy containing at least an element whose binary diagram with the selected alloy presents any kind of liquid phase at low allowing contents and low temperatures when added to the alloy and a high melting point alloy selected from Fe, Ni, Co, Cu, Mg, W, Mo, Al or Ti based alloy. In an embodiment the powder mixture further comprises an organic compound.

In an embodiment the invention refers to a method of manufacturing a metallic or at least partially metallic component by shaping a powder mixture comprising at least a low melting point metallic powder and a high melting point metallic powder using an AM technique, a Polymer shaping technique, such as MIM, a HIP process, a CIP process, Sinter forging, Sintering and/or any technique suitable for powder conformation and/or any combination thereof among others, wherein the low melting point metallic powder is selected from a Fe, Ni, Co, Cu, Mg, W, Mo, Al and Ti based alloy containing at least an element selected from: Ga, Bi, Pb, Rb, Zn, Cd, In, Sn, K, Na, Mn, B, Sc, Si, and/or Mg and/or any combination thereof among others and a high melting point alloy selected from Fe, Ni, Co, Cu, Mg, W, Mo, Al or Ti based alloy. In an embodiment the powder mixture further comprises an organic compound. In an embodiment the invention refers to a method of manufacturing metallic or at least partially metallic powders by shaping a powder mixture comprising at least a low melting point metallic powder and a high melting point metallic powder using an AM technique, a Polymer shaping technique, such as MIM, a HIP process, a CIP process, Sinter forging, Sintering and/or any technique suitable for powder conformation and/or any combination thereof among others wherein the low melting point metallic powder is selected from: gallium alloy, AlGa alloy, CuGa alloy, SnGa alloy, MgGa alloy, MnGa alloy, NiGa alloy, high manganese containing alloy, high manganese containing Fe based alloy further comprising carbon (steel), Al based alloy containing Mg, Al based alloy containing Sc, Al based alloy containing Sn, Al based alloy containing more than 90% by weight Al and a high melting point alloy selected from Fe, Ni, Co, Cu, Mg, W, Mo, Al or Ti based alloy. In an embodiment the powder mixture further comprises an organic compound.

In an embodiment melting temperature is the temperature where the first liquid forms under equilibrium conditions.

In an embodiment in a powder mixture having two metallic powders, low melting point is referred to the metallic powder having the lowest melting point and high melting point alloy refers to the metallic powder having the high melting point, providing that there is a difference of at least 62° C. or more, between their melting points, in other embodiment 110° C. or more, in other embodiment 230° C. or more, in other embodiment 110° C. or more, in other embodiment 230° C. or more, in other embodiment 420° C. or more, in other embodiment 640° C. or more and even in other embodiment 820° C. or more.

In an embodiment melting point of a metallic powder refers to the temperature where the first liquid forms under equilibrium conditions.

In an embodiment Tm of the low melting point alloy refers to the melting temperature of this alloy.

In an embodiment Tm of the high melting point alloy refers to the melting temperature of this alloy.

In an embodiment when there are more than one low melting point alloys in a powder mixture. In an embodiment Tm of the low melting point alloy refers to the Tm of the low melting point alloy having a higher weight/volume percentage in the powder mixture/metallic phase.

In an embodiment Tm of the low melting point alloy refers to the Tm of the alloy having the lowest melting point.

In an embodiment Tm of the high melting point alloy refers to the Tm of the alloy (excluding the alloy with lower melting point) having the higher weight percentage in the metallic phase. In an embodiment if there more than one alloy (excluding the alloy with lower melting point) having the same weight percentage being the highest values in the powder mixture/metallic phase, Tm refers to the alloy having the lowest Tm between them.

In an embodiment Tm of the high melting point alloy refers to the Tm of the alloy (excluding the alloy with lower melting point) having the higher weight percentage in the powder mixture. In an embodiment if there more than one alloy (excluding the alloy with lower melting point) having the same weight percentage being the highest values in the powder mixture/metallic phase, Tm refers to the alloy having the lowest Tm between them.

In an embodiment Tm of the high melting point alloy refers to the Tm of the alloy (excluding the alloy with lower melting point) having the higher volume percentage in the powder mixture. In an embodiment if there more than one alloy (excluding the alloy with lower melting point) having the same volume percentage being the highest values in the powder mixture/metallic phase, Tm refers to the alloy having the lowest Tm between them.

In an embodiment Tm of the high melting point alloy refers to the Tm of the alloy (excluding the alloy with lower melting point) having the higher volume percentage in the metallic phase. In an embodiment if there more than one alloy (excluding the alloy with lower melting point) having the same volume percentage being the highest values in the powder mixture/metallic phase, Tm refers to the alloy having the lowest Tm between them.

In an embodiment when there are more than one low melting point alloy in a powder mixture. In an embodiment Tm of the low melting point refers to the lower Tm of all low melting point alloys (excluding melting point alloys being less than 1% by weight of the powder mixture). In another embodiment Tm of the low melting point refers to the lower Tm of all low melting point alloys (excluding low melting point alloys being less than 2.4% by weight of the powder mixture In another embodiment Tm of the low melting point refers to the lower Tm of all low melting point alloys (excluding low melting point alloys being less than 3.8% by weight of the powder mixture (the sum of all metallic powders in the powder mixture). In another embodiment Tm of the low melting point refers to the lower Tm of all low melting point alloys (excluding melting point alloys being less than 4.8% by weight of the powder mixture. In another embodiment Tm of the low melting point refers to the lower Tm of all low melting point alloys (excluding low melting point alloys being less than 7% by weight of the powder mixture/metallic phase (the sum of all metallic powders in the powder mixture).

In an embodiment when there are more than one low melting point alloy in a powder mixture. In an embodiment Tm of the low melting point refers to the lower Tm of all low melting point alloys (excluding melting point alloys being less than 1% by weight of the powder mixture). In another embodiment Tm of the low melting point refers to the lower Tm of all low melting point alloys (excluding low melting point alloys being less than 2.4% by weight of the powder mixture In another embodiment Tm of the low melting point refers to the lower Tm of all low melting point alloys (excluding low melting point alloys being less than 3.8% by weight of the powder mixture (the sum of all metallic powders in the powder mixture). In another embodiment Tm of the low melting point refers to the lower Tm of all low melting point alloys (excluding melting point alloys being less than 4.8% by weight of the powder mixture. In another embodiment Tm of the low melting point refers to the lower Tm of all low melting point alloys (excluding low melting point alloys being less than 7% by weight of the powder mixture/metallic phase (the sum of all metallic powders in the powder mixture).

In an embodiment when there are more than one low melting point alloy in a powder mixture. In an embodiment Tm of the low melting point refers to the lower Tm of all low melting point alloys (excluding melting point alloys being less than 1% by volume of the powder mixture). In another embodiment Tm of the low melting point refers to the lower Tm of all low melting point alloys (excluding low melting point alloys being less than 2.4% by volume of the powder metallic phase (the sum of all metallic powders in the powder mixture). In another embodiment m of the low melting point refers to the lower Tm of all low melting point alloys (excluding low melting point alloys being less than 3.8% by volume of the powder metallic phase (the sum of all metallic powders in the powder mixture). In another embodiment Tm of the low melting point refers to the lower Tm of all low melting point alloys (excluding melting point alloys being less than 4.8% by volume of the powder metallic phase (the sum of all metallic powders in the powder mixture). In another embodiment Tm of the low melting point refers to the lower Tm of all low melting point alloys (excluding low melting point alloys being less than 7% by volume of the metallic phase (the sum of all metallic powders in the powder mixture).

In an embodiment when there are more than one low melting point alloy in a powder mixture. In an embodiment Tm of the low melting point refers to the lower Tm of all low melting point alloys (excluding melting point alloys being less than 1% by weight of the powder mixture). In another embodiment Tm of the low melting point refers to the highest Tm of all low melting point alloys (excluding low melting point alloys being less than 2.4% by weight of the powder mixture In another embodiment Tm of the low melting point refers to the highest Tm of all low melting point alloys (excluding low melting point alloys being less than 3.8% by weight of the powder mixture (the sum of all metallic powders in the powder mixture). In another embodiment Tm of the low melting point refers to the lower Tm of all low melting point alloys (excluding melting point alloys being less than 4.8% by weight of the powder mixture. In another embodiment Tm of the low melting point refers to the highest Tm of all low melting point alloys (excluding low melting point alloys being less than 7% by weight of the powder mixture/metallic phase (the sum of all metallic powders in the powder mixture).

In an embodiment when there are more than one low melting point alloy in a powder mixture. In an embodiment Tm of the low melting point refers to the highest Tm of all low melting point alloys (excluding melting point alloys being less than 1% by weight of the powder mixture). In another embodiment Tm of the low melting point refers to the highest Tm of all low melting point alloys (excluding low melting point alloys being less than 2.4% by weight of the powder mixture In another embodiment Tm of the low melting point refers to the lower Tm of all low melting point alloys (excluding low melting point alloys being less than 3.8% by weight of the powder mixture. In another embodiment Tm of the low melting point refers to the lower Tm of all low melting point alloys (excluding melting point alloys being less than 4.8% by weight of the powder mixture. In another embodiment Tm of the low melting point refers to the highest Tm of all low melting point alloys (excluding low melting point alloys being less than 7% by weight of the powder mixture

In an embodiment when there are more than one low melting point alloy in a powder mixture. In an embodiment Tm of the low melting point refers to the highest Tm of all low melting point alloys (excluding melting point alloys being less than 1% by volume of the powder mixture). In another embodiment Tm of the low melting point refers to the highest Tm of all low melting point alloys (excluding low melting point alloys being less than 2.4% by volume of the powder metallic phase (the sum of all metallic powders in the powder mixture). In another embodiment Tm of the low melting point refers to the highest Tm of all low melting point alloys (excluding low melting point alloys being less than 3.8% by volume of the powder metallic phase (the sum of all metallic powders in the powder mixture). In another embodiment m of the low melting point refers to the highest Tm of all low melting point alloys (excluding melting point alloys being less than 4.8% by volume of the powder metallic phase (the sum of all metallic powders in the powder mixture). In another embodiment Tm of the low melting point refers to the highest Tm of all low melting point alloys (excluding low melting point alloys being less than 7% by volume of the powder metallic phase (the sum of all metallic powders in the powder mixture).

In an embodiment when there are more than one low melting point alloy in a powder mixture. In an embodiment Tm of the low melting point refers to the highest Tm of all low melting point alloys (excluding melting point alloys being less than 1% by volume of the powder mixture). In another embodiment Tm of the low melting point refers to the highest Tm of all low melting point alloys (excluding low melting point alloys being less than 2.4% by volume of the powder mixture In another embodiment Tm of the low melting point refers to the lower Tm of all low melting point alloys (excluding low melting point alloys being less than 3.8% by volume of the powder mixture. In another embodiment Tm of the low melting point refers to the lower Tm of all low melting point alloys (excluding melting point alloys being less than 4.8% by volume of the powder mixture. In another embodiment Tm of the low melting point refers to the highest Tm of all low melting point alloys (excluding low melting point alloys being less than 7% by volume of the powder mixture

In an embodiment when there are more than one low melting point alloy in a powder mixture. In an embodiment Tm of the low melting point refers to the highest Tm of all low melting point alloys (excluding melting point alloys being less than 1% by weight of the powder mixture). In another embodiment Tm of the low melting point refers to the highest Tm of all low melting point alloys (excluding low melting point alloys being less than 2.4% by weight of the powder metallic phase (the sum of all metallic powders in the powder mixture). In another embodiment Tm of the low melting point refers to the highest Tm of all low melting point alloys (excluding low melting point alloys being less than 3.8% by weight of the powder metallic phase (the sum of all metallic powders in the powder mixture). In another embodiment m of the low melting point refers to the highest Tm of all low melting point alloys (excluding melting point alloys being less than 4.8% by weight of the powder metallic phase (the sum of all metallic powders in the powder mixture). In another embodiment Tm of the low melting point refers to the highest Tm of all low melting point alloys (excluding low melting point alloys being less than 7% by weight of the powder metallic phase (the sum of all metallic powders in the powder mixture).

In an embodiment Tm of the high melting point alloy refers to the melting temperature of this alloy.

In an embodiment when there are more than one melting point alloy in a powder mixture. In an embodiment Tm of the high melting point alloy refers to the Tm of the low melting point alloy having a higher weight percentage in the powder mixture.

In an embodiment when there are more than one melting point alloy in a powder mixture. In an embodiment Tm of the high melting point alloy refers to the Tm of the low melting point alloy having a higher volume percentage in the powder mixture.

In an embodiment when there are more than one melting point alloy in a powder mixture. In an embodiment Tm of the high melting point alloy refers to the Tm of the low melting point alloy having a lower weight percentage in the powder mixture.

In an embodiment when there are more than one melting point alloy in a powder mixture. In an embodiment Tm of the high melting point alloy refers to the Tm of the low melting point alloy having a lower volume percentage in the powder mixture.

In an embodiment when there are more than one melting point alloy in a powder mixture. In an embodiment Tm of the high melting point alloy refers to the Tm of the low melting point alloy having a higher weight percentage in the metallic phase (the sum of all metallic powders in the powder mixture).

In an embodiment when there are more than one melting point alloy in a powder mixture. In an embodiment Tm of the high melting point alloy refers to the Tm of the low melting point alloy having a higher volume percentage in the powder metallic phase (the sum of all metallic powders in the powder mixture).

In an embodiment when there are more than one melting point alloy in a powder mixture. In an embodiment Tm of the high melting point alloy refers to the Tm of the low melting point alloy having a lower weight percentage in the powder metallic phase (the sum of all metallic powders in the powder mixture).

In an embodiment when there are more than one melting point alloy in a powder mixture. In an embodiment Tm of the high melting point alloy refers to the Tm of the low melting point alloy having a lower volume percentage in the powder metallic phase (the sum of all metallic powders in the powder mixture).

In an embodiment when in the mixture there are more than one high melting point alloy, having similar weight percentages (similar volume percentage refers to a difference of less than 10%), and being the high melting point alloys with higher weight percentages of the powder mixture, Tm of the high melting point alloy refers to the lower Tm value of these alloys having similar volume percentage.

In an embodiment when in the mixture there are more than one high melting point alloy, having similar volume percentages (similar weight percentage refers to a difference of less than 10%), and being the high melting point alloys with higher volume percentages of the powder mixture, Tm of the high melting point alloy refers to the lower Tm value of these alloys having similar weight percentage.

In an embodiment when in the mixture there are more than one high melting point alloy, having similar weight percentages (similar volume percentage refers to a difference of less than 10%), and being the high melting point alloys with higher weight percentages of the powder mixture, Tm of the high melting point alloy refers to the highest Tm value of these alloys having similar volume percentage.

In an embodiment when in the mixture there are more than one high melting point alloy, having similar volume percentages (similar weight percentage refers to a difference of less than 10%), and being the high melting point alloys with higher volume percentages of the powder mixture, Tm of the high melting point alloy refers to the highest Tm value of these alloys having similar weight percentage.

In an embodiment when there are more than one high melting point alloy in a powder mixture. In an embodiment Tm of the high melting point refers to the lower Tm of all high melting point alloys (excluding high melting point alloys being less than 1% by weight of the powder mixture. In another embodiment Tm of the low melting point refers to the lower Tm of all low melting point alloys (excluding melting point alloys being less than 3.4% by weight of the powder mixture. In another embodiment Tm of the low melting point refers to the lower Tm of all low melting point alloys (excluding high melting point alloys being less than 6.2% by weight of the powder mixture.

In an embodiment when there are more than one high melting point alloy in a powder mixture. In an embodiment Tm of the high melting point refers to the lower Tm of all high melting point alloys (excluding high melting point alloys being less than 1% by weight of the metallic phase (the sum of all metallic powders in the powder mixture). In another embodiment Tm of the low melting point refers to the lower Tm of all low melting point alloys (excluding melting point alloys being less than 3.4% by weight of the metallic phase (the sum of all metallic powders in the powder mixture. In another embodiment Tm of the low melting point refers to the lower Tm of all low melting point alloys (excluding high melting point alloys being less than 6.2% by weight of the metallic phase (the sum of all metallic powders in the powder mixture.

In an embodiment when there are more than one high melting point alloy in a powder mixture. In an embodiment Tm of the high melting point refers to the lower Tm of all high melting point alloys (excluding high melting point alloys being less than 1% by weight of the powder mixture. In another embodiment Tm of the low melting point refers to the lower Tm of all low melting point alloys (excluding melting point alloys being less than 3.4% by weight/volume of the powder mixture/metallic phase (the sum of all metallic powders in the powder mixture. In another embodiment Tm of the low melting point refers to the lower Tm of all low melting point alloys (excluding high melting point alloys being less than 6.2% by weight of the powder mixture

In an embodiment the final component is obtained after the shaping. In an embodiment when the powder conformation technique selected to shape the powder mixture is sintering, sinter forging, CIP, and/or HIP among other the component obtained after shaping is the final component.

In an embodiment the component obtained after the shaping shall be subjected to a post-processing treatment. In an embodiment when the powder conformation technique selected to shape the powder mixture is sintering, sinter forging, and/or HIP the component obtained after shaping is the final component.

In an embodiment the component obtained after the shaping is a green component wherein a post-processing until obtain the metallic or at least partially metallic component. In an embodiment the post-processing includes a debinding, a Heat Treatment to promote PMSRT or MSRT, a sintering, a sinter forging a CIP and/or a HIP.

In an embodiment debinding, or at least partial debinding takes place during the Heat treatment disclosed in this document. In other embodiments, a debinding takes place before the Heat treatment.

In an embodiment green component refers to a component obtained after shaping the powder mixture, using an AM, or a Polymer shaping technique which may be subjected to a post-processing treatment until obtain the final metallic or at least partially metallic component.

In an embodiment post-processing refers to the treatments that receives a green component until obtain the final component. In an embodiment this post-processing treatments includes but is not limited to a heat treatment to promote PMSRT or MSRT, debinding HIP, CIP sinter forging and/or sintering and/or any combination of them among other treatments suitable for densification and/or conformation of a green component until the final desired component.

In an embodiment, when at least two metal powders with different melting point are comprised in the powder mixture and a polymer, and correct selection of the powder size distribution and particle sizes is made to have a high tap density of the green component, the treatment required to degrade (at least partially) the polymer and enable the metallic phase being the responsible for shape retention, may be made at low temperatures (compared to traditional method used during post-processing of green materials until reach the final component) so that the component suffer lower thermal stresses and/or residual stresses, during conformation.

Additive Manufacturing (AM) is a set of technologies that have broadly increased the accuracy with which many structures can be replicated

Actually, AM technologies are classified in several categories, according to ASTM International, document F2792-12a are grouped in: i) binder jetting, ii) directed energy deposition, iii) material extrusion, iv) material jetting, v) powder bed fusion, vi) sheet lamination, and vii) vat photopolymerization. This classification summarizes a big variety of technologies, including, but not limited to: 3D Printing, Ink-jetting, S-Print, M-Print technologies, technologies where focused energy generates a melt pool into which feedstock (powder or wire material) is deposited using a laser (Laser Deposition and Laser Consolidation), arc or e-beam heat source (Direct Metal Deposition and Electron Beam Direct Melting), fused deposition modelling (FDM), Material jetting, direct metal laser sintering (DMLS), selective laser melting (SLM), electron beam melting (EBM), selection laser sintering (SLS), stereolithography and digital light processing (DLP) among others.

In an embodiment the method of the present invention comprises and step of shaping a powder mixture to manufacture a metallic or partially metallic component using any AM technique. In an embodiment for several of these AM technologies the use of a powder mixture containing at least one metallic powder along with an organic compound may be suitable.

In an embodiment the shaping step is made using binder jetting technologies, including 3D Printing, Ink-jetting, S-Print, and M-Print technologies. In an embodiment the invention refers to a method of manufacturing a metallic or at least partially metallic component, using a powder mixture of at least one metallic powder and optionally an organic compound by shaping the powder mixture using 3D Printing, Ink-jetting, S-Print, and/or M-Print technique.

In an embodiment the shaping step is made using Direct energy deposition technologies, including all technologies where focused energy generates a melt pool into which feedstock (powder or wire material) is deposited using a laser (Laser Deposition and Laser Consolidation), arc or e-beam heat source (Direct Metal Deposition and Electron Beam Direct Melting). In an embodiment the invention refers to a method of manufacturing a metallic or at least partially metallic component, using a powder mixture of at least one metallic powder and optionally an organic compound by shaping the powder mixture using Direct energy deposition technologies, including all technologies where focused energy generates a melt pool into which feedstock (powder or wire material) is deposited using a laser (Laser Deposition and Laser Consolidation), arc or e-beam heat source (Direct Metal Deposition and Electron Beam Direct Melting)

In an embodiment the shaping step is made using a method through material extrusion wherein the objects are created by dispensing material through a nozzle where it is heated and then deposited layer by layer. The nozzle and the platform can be moved horizontally and vertically respectively after each new layer is deposited, as in fused deposition modelling (FDM), the most common material extrusion technique. In an embodiment the invention refers to a method of manufacturing a metallic or at least partially metallic component, using a powder mixture of at least one metallic powder and optionally an organic compound by shaping the powder mixture using a method through material extrusion wherein the objects are created by dispensing material through a nozzle where it is heated and then deposited layer by layer. The nozzle and the platform can be moved horizontally and vertically respectively after each new layer is deposited, as in fused deposition modelling (FDM), the most common material extrusion technique.

In an embodiment the shaping step is made using material jetting, a similar technique to that of a two dimensional ink jet printer, where material (polymers and waxes) is jetted onto a build surface platform where it solidifies until the model is built layer by layer and the material layers are then cured or hardened using ultraviolet (UV) light. In an embodiment the invention refers to a method of manufacturing a metallic or at least partially metallic component, using a powder mixture of at least one metallic powder and optionally an organic compound by shaping the powder mixture using material jetting, a similar technique to that of a two dimensional ink jet printer, where material (polymers and waxes) is jetted onto a build surface platform where it solidifies until the model is built layer by layer and the material layers are then cured or hardened using ultraviolet (UV) light.

In an embodiment the shaping step is made using Powder bed fusion which encompasses all technologies where focused energy (electron beam or laser beam) is used to selectively melt or sinter a layer of a powder bed (metal, polymer or ceramic). Thus, several technologies exist nowadays: direct metal laser sintering (DMLS), selective laser melting (SLM), electron beam melting (EBM), selective laser sintering (SLS). In an embodiment the invention refers to a method of manufacturing a metallic or at least partially metallic component, using a powder mixture of at least one metallic powder and optionally an organic compound by shaping the powder mixture using Powder bed fusion which encompasses all technologies where focused energy (electron beam or laser beam) is used to selectively melt or sinter a layer of a powder bed (metal, polymer or ceramic). Thus, several technologies exist nowadays: direct metal laser sintering (DMLS), selective laser melting (SLM), electron beam melting (EBM), selective laser sintering (SLS).

In an embodiment the shaping step is made using Sheet lamination which uses stacking of precision cut metal sheets into 2D part slices to form a 3D object. It includes ultrasonic consolidation and laminated object manufacturing. The former uses ultrasonic welding for bonding sheets using a sonotrode while the latter uses paper as material and adhesive instead of welding. In an embodiment the invention refers to a method of manufacturing a metallic or at least partially metallic component, using a powder mixture of at least one metallic powder and optionally an organic compound by shaping the powder mixture using Sheet lamination which uses stacking of precision cut metal sheets into 2D part slices to form a 3D object. It includes ultrasonic consolidation and laminated object manufacturing. The former uses ultrasonic welding for bonding sheets using a sonotrode while the latter uses paper as material and adhesive instead of welding.

In an embodiment the shaping step is made using VAT polymerization which uses a vat of liquid photopolymer resin, out of which the 3D model is constructed layer by layer using electromagnetic radiation as curing agent wherein the cross-sectional layers are successively and selectively cured to build the model with the aid of moving platform which in many cases uses a photopolymer resin. The main technologies are the stereolithography and digital light processing (DLP), where a projector light is used rather than a laser to cure the photo-sensitive resin. In an embodiment the invention refers to a method of manufacturing a metallic or at least partially metallic component, using a powder mixture of at least one metallic powder and an organic compound by shaping the powder mixture using VAT polymerization which uses a vat of liquid photopolymer resin, out of which the 3D model is constructed layer by layer using electromagnetic radiation as curing agent wherein the cross-sectional layers are successively and selectively cured to build the model with the aid of moving platform which in many cases uses a photopolymer resin. The main technologies are the stereolithography and digital light processing (DLP), where a projector light is used rather than a laser to cure the photo-sensitive resin.

The additive manufacturing methods for the manufacturing of metallic objects, can be divided in two groups for the purpose of clarifying this point: methods based on direct melting and/or sintering of the metal and thus not necessarily requiring a sintering step after the AM, and methods based on the binding trough an adhesive and thus requiring a sintering step after the AM. In an embodiment the AM method is only intended to provide shape and retain it for a while. In an embodiment among sintering other post-processing treatments may be necessary before obtaining the final product.

The inventor has seen that one interesting implementation of the present invention, arises when a very fast AM process is chosen for the shaping step. That is so given that the present invention in most cases involves a post-processing step, which is normally not necessary in the AM processes.

In an embodiment the method for shaping the powder mixture is using a technique involving laser in the shaping process, chosen for example but not limited to these processes wherein a mixture of at least one metallic powder, and optionally an organic compound are deposited using a laser (usually direct energy deposition), and those processes when focused energy (usually using a laser beam) is used to selectively melt or sinter a powder bed containing the powder mixture of at least one metallic powder, and optionally an organic compound.

The powder mixtures disclosed in this document are especially suitable for use with this technique involving laser in the shaping process.

In an embodiment the invention refers to a method for manufacturing objects using technique involving laser in the shaping process, chosen for example but not limited to these processes wherein a mixture of at least one metallic powder, and optionally an organic compound are deposited using a laser (usually direct energy deposition), and those processes when focused energy (usually using a laser beam) is used to selectively melt or sinter a powder bed containing the powder mixture of at least one metallic powder, and optionally an organic compound.

In an embodiment the invention refers to a method for manufacturing a component using technique involving laser in the shaping process, chosen for example but not limited to these processes wherein a mixture of at least one metallic powder, and optionally an organic compound are deposited using a laser (usually direct energy deposition), and those processes when focused energy (usually using a laser beam) is used to selectively melt or sinter a powder bed containing the powder mixture of at least one metallic powder, and optionally an organic compound.

In an embodiment the inventor has seen that a very advantageous application of the method of the present invention arises when a technique involving laser in the shaping process is chosen for example but not limited to these processes wherein a powder mixture of at least one metallic powder, and optionally an organic compound are deposited using a laser (usually direct energy deposition), and those processes when focused energy (usually using a laser beam) is used to selectively melt or sinter a powder bed containing the mixture of at least one metallic powder, and optionally anorganic compound, due to the high packing density obtained when using appropriate size distribution of the powder mixture, as disclosed in the present document.

In an embodiment when a technique involving laser in the shaping process is chosen for example but not limited to those processes when focus energy (usually a laser beam) is used to selectively melt or sinter a powder bed containing a powder mixture of at least one metallic powder, and optionally other non metallic components when using the method and the different powder mixtures of the invention disclosed and detailed in this document mainly when the mixture contains at least two metallic powders with different melting points, the process can be made at lower temperatures compared to known methods in the prior art which implies lower energy inputs during the shaping process, and thus lower cost in the manufacturing process of the component in addition to lower thermal stresses and/or residual stresses (sometimes both of them) in the component. In an embodiment this shaped component needs post-processing until the desired final component is attained. In contrast in other embodiment the final component is obtained directly after this shaping process.

In an embodiment when a technique involving laser in the shaping process is chosen for example but not limited to those processes when focus energy (usually a laser beam) is used to selectively melt or sinter a powder bed containing the powder mixture of metallic powder, and optionally other non metallic components when using the method and powder mixtures of the invention disclosed and detailed in this document when the mixture contains at least one metallic powders or more than one metallic powders with similar melting points and the process also involves lower temperature inputs during the shaping process compared to known methods in the prior art which implies lower energy, due to the higher packing density of the powder mixture and also lower thermal stresses and/or residual stresses (sometimes both of them) in the shaped component. In many cases this shaped component needs post-processing until the desired final component is attained. In contrast in other cases the final component is obtained directly after this shaping process.

In an embodiment depending on the particle size distribution of the powder mixture (sometimes AM particulates) chosen for each application, high powder bed packing density may be reached for example but not limited to when using one or more than one metallic powders with multi-modal size distributions designed to reduce voids as described further in this document (in many cases using at least two metallic powders with different melting points as described in detail in this document, wherein in an embodiment at least one low melting point alloy is used to whole or at least partially occupy the octahedral and/or tetrahedral voids of the main metallic powder having high melting point which results on high packing density densities). In an embodiment when a technique involving laser in the shaping process is chosen for example but not limited to those processes when focus energy (usually a laser beam) are used to selectively melt or sinter a powder bed containing the powder mixture, and optionally an organic compounds the powder packing density in the bed (before the shaping process) is above 75%, in other embodiments above 79.3%, in other embodiment above 83.5%, and even in other embodiment above 87%. In an embodiment especially in those previously described when correctly selecting a high powder bed packing density very high tap densities of the shaped component using the previously described processes are reached. In an embodiment vibration is used to obtain, together with a correct particle size distribution, high density packing of the powder bed. In other embodiments any other method for enhance correct particle distribution to improve package of the powder bed is suitable for being combined with the invention.

In an embodiment when a technique involving laser for the shaping process is chosen for example but not limited to those processes when focus energy (usually a laser beam) is used to selectively melt or sinter a powder bed containing the mixture of metallic powder, and optionally other non metallic components, tap densities of the shaped component obtained are above 89.3%, in another embodiment above 92.7%, in another embodiment above 95.5%, and another embodiment above 97.6%, in another embodiment above 98.9% and even in another embodiment full density of the component is obtained directly with this shaping process. In an embodiment these tap densities are reached when the metallic powder mixture contained in the powder bed has at least one metallic powder with a particle size distribution that allows a powder packing density in the bed above 75%, in other embodiments above 79.3%, in other embodiment above 83.5%, and even in other embodiment above 87%. In an embodiment the metallic particles are coated, embedded and/or in any other configuration in relation with the polymer as shown in FIG. 4. In an embodiment particle size distribution.

In an embodiment the invention refers to a method of manufacturing a metallic or at least partially metallic component by shaping a powder mixture comprising at least one metallic powders using an a technique involving laser in the shaping process is chosen for example but not limited to those processes when focus energy (usually a laser beam) are used to selectively melt or sinter a powder bed containing the powder mixture, and optionally an organic compound wherein the powder packing density in the bed is above 75%, in other embodiment above 79.3%, in other embodiment above 83.5%, and even in other embodiment above 87% characterized in that tap densities of the shaped component obtained are above 89.3%, in another embodiment above 92.7%, in another embodiment above 95.5%, and another embodiment above 97.6%, in another embodiment above 98.9% and even in another embodiment full density.

In an embodiment the invention refers to a method of manufacturing a metallic or at least partially metallic component by shaping a powder mixture comprising at least two metallic powders with different melting point using an a technique involving laser in the shaping process is chosen for example but not limited to those processes when focus energy (usually a laser beam) are used to selectively melt or sinter a powder bed containing the powder mixture, and optionally an organic compound wherein the powder packing density in the bed is above 75%, in other embodiment above 79.3%, in other embodiment above 83.5%, and even in other embodiment above 87% characterized in that tap densities of the shaped component obtained are above 89.3%, in another embodiment above 92.7%, in another embodiment above 95.5%, and another embodiment above 97.6%, in another embodiment above 98.9% and even in another embodiment full density.

In an embodiment the invention refers to a method of manufacturing a metallic or at least partially metallic component by shaping a powder mixture comprising at least a low melting point metallic powder and a high melting point metallic powder, using an a technique involving laser in the shaping process is chosen for example but not limited to those processes when focus energy (usually a laser beam) are used to selectively melt or sinter a powder bed containing the powder mixture, and optionally an organic compound wherein the powder packing density in the bed is above 75%, in other embodiment above 79.3%, in other embodiment above 83.5%, and even in other embodiment above 87% characterized in that tap densities of the shaped component obtained are above 89.3%, in another embodiment above 92.7%, in another embodiment above 95.5%, and another embodiment above 97.6%, in another embodiment above 98.9% and even in another embodiment full density.

In terms of high densities and compactation of the metallic powder mixture and optionally an organic compound, in the document are detailed different powder size distributions and several embodiments suitable for the method of the invention, which may be directly applied to the recent described technique involving a laser in the shaping process for example but not limited to these processes wherein a mixture of at least one metallic powder, and optionally other non metallic components, are deposited using a laser (usually direct energy deposition), and those processes when focused energy (usually using a laser beam) is used to selectively melt or sinter a powder bed containing the mixture. In some embodiments when the metallic particles are coated, embedded and/or in any other configuration in relation with the polymer as shown in FIG. 4, particles is referred to AM particulates. In an embodiment, when high mechanical properties of the final component are desired, a high density of metallic powder mixture is desirable, even as near possible to close packing, so in an embodiment bi-modal narrow particle size distributions of particles in the powder mixture are chosen. In another embodiment tri-modal narrow particle size distributions of particle are chosen. In an embodiment when more than one powder is comprised in the mixture different particle size distributions may be chosen, for example one of the powders may be selected to have the highest particle size, and the other powders to tend to fill the voids of the metallic powder with the highest particle size, and also this powder with the highest particle size, having a multi-modal particle size distribution (usually bi-modal and/or tri-modal) to fill also the voids between the particle size distribution, and even in other embodiment, having all the metallic powders of the mixture a multi-modal particle size distribution, with a high particle size and other size distributions selected to tend to fill the voids between the particles of higher size. In an embodiment the particle size distributions, are selected to have a narrow size distribution. In other embodiment when bi-modal distributions are used, this means the powder size distribution having two mode values and a narrow size distribution around these two mode values. In another embodiment when tri-modal distributions are used, this means the powder size distribution having three mode values and a narrow size distribution around these three mode values. Furthermore in several embodiments different mixtures of metallic powders, have been disclosed in this document, and are especially suitable for used with this shaping method to obtain these high tap densities of the shaped component.

In an embodiment when a technique involving laser in the shaping process is chosen for example but not limited to those processes wherein a mixture of at least one metallic powders, and optionally other organic compounds, such as a polymer are deposited using a laser (usually direct energy deposition) tap densities of the shaped component obtained are above 89.3%, in another embodiment above 92.7%, in another embodiment above 95.5%, and another embodiment above 97.6%, in another embodiment above 98.9% and even in another embodiment full density are attained directly with this shaping process. In an embodiment in terms of high densities and compactation of the powder mixture and optionally an organic compound in the feedstock that allows reach these high tap densities, later in the document are detailed different powder size distributions and several embodiments suitable for the method of the invention, which may be directly applied to the above disclosed technique involving a laser in the shaping process for example but not limited to these processes wherein a powder mixture of at least one metallic powder, and optionally other organic components, are deposited using a laser (usually direct energy deposition). In some embodiments when the metallic particles are coated, embedded and/or in any other configuration in relation with the polymer as shown in FIG. 4, particles is referred to AM particulates. Furthermore in several embodiments different mixtures of metallic powders, many of them comprising at least two metallic powders have been disclosed in this document, and are especially well suitable for used with this shaping method to obtain these high tap densities of the shaped component.

In an embodiment the invention refers to a method of manufacturing a metallic or at least partially metallic component by shaping a powder mixture comprising at least one metallic powder using a technique involving laser in the shaping process chosen for example but not limited to those processes wherein a powder mixture is deposited using a laser (usually direct energy deposition) wherein tap densities of the shaped component obtained are above 89.3%, in another embodiment above 92.7%, in another embodiment above 95.5%, and another embodiment above 97.6%, in another embodiment above 98.9% and even in another embodiment full density.

In an embodiment the invention refers to a method of manufacturing a metallic or at least partially metallic component by shaping a powder mixture comprising at least a low melting point metallic powder and a high melting point metallic powder, using a technique involving laser in the shaping process chosen for example but not limited to those processes wherein a powder mixture is deposited using a laser (usually direct energy deposition) wherein tap densities of the shaped component obtained are above 89.3%, in another embodiment above 92.7%, in another embodiment above 95.5%, and another embodiment above 97.6%, in another embodiment above 98.9% and even in another embodiment full density.

In an embodiment the component obtained using a technique involving laser in the shaping process chosen for example but not limited to those processes wherein a powder mixture is deposited using a laser (usually direct energy deposition) is the metallic or at least partially metallic component.

In an embodiment the component obtained using a technique involving laser in the shaping process chosen for example but not limited to those processes wherein a powder mixture is deposited using a laser (usually direct energy deposition) is a green component, and this green component is submitted to a post processing step to obtain the metallic or at least partially metallic component.

In an embodiment the component obtained using a technique involving a laser in the shaping process wherein focused energy (usually using a laser beam) are used to selectively melt or sinter a powder bed containing the powder mixture is the metallic or at least partially metallic component.

In an embodiment the component obtained using a technique involving a laser in the shaping process wherein focused energy (usually using a laser beam) are used to selectively melt or sinter a powder bed containing the powder mixture) is a green component and this green component is submitted to a post processing step to obtain the metallic or at least partially metallic component.

Any of the above-described embodiments can be combined with any other embodiment herein described in any combination, to the extent that the respective features are not incompatible.

As previously disclosed, one implementation of the present invention considers the usage of net-shape or near-net-shape technologies which are not strictly AM, but which benefit from the particulates used in most instances of the present invention, namely particulates containing metallic materials and organic materials, where shape retention is not compromised during the degradation of the organic material. That comprises any technique capitalizing the formability advantages of the organic material, and taking advantage of the shape retention capabilities of the particulates of the present invention.

Other manufacturing processes can be applied as a shaping step, besides AM with some of the materials of the present invention. They need to be fast manufacturing processes. Most polymer shaping methodologies are an option (injection molding, blow-molding, thermoforming, casting, compression, pressing RIM, extrusion, rotomolding, dip molding, foam shaping . . . ). As an example the case of injection molding can be taken, where a process exist called Metal Injection Molding (MIM), which allows the obtaining of metallic components, but which is limited to a few hundred grams. With the method and materials of the present invention, much larger components can be manufactured, with enhanced functionality and in a considerably more economical way.

For illustration purposes and because it is a technique where such combination is especially advantageous and thus illustrative, a more detailed view in the case of Metal Injection Molding (MIM) is provided. This technique allows for the production of complex geometry pieces (although the geometrical constraints are often higher than those for most AM technologies) but has a very clear limiting factor which is the size of component that can be reasonably produced. This has to do with the maximum amount of material which can be injected in one single shot which is commonly less than 200 gr. This is related amongst others to the rheology of the feedstock, and the pressure required to inject it, which in turn is related to the large volume fraction of metallic powder in the mix. The powder fraction and injection pressure need to be so high to assure shape retention upon debinding. The inventor has seen that MIM is a valid technique for the manufacturing of quite large pieces when using some of the feedstock of the present invention (especially those with at least two types of metallic powders one of them with a noticeably lower melting point that starts melting in a sufficient amount before the polymer loses its shape retention capacity)(but also single powder or mixture of phases but at least one with a low melting point or diffusion activated at low temperatures). Considerably lower metallic volume fractions and/or injection pressures can be used, thus allowing for a much higher ability to flow, thus making the filling of big and complex shapes possible. The material injected in this way (with such lower volume fraction metallic content and/or pressure) would disintegrate upon debinding were it not thanks to the liquid phase and/or strong diffusion bridges formed before the full decomposition of the polymer which assures the shape retention until diffusion provides with the final shape and properties. For one application or another almost all feedstock described in the present invention can be used advantageously.

In an embodiment the invention is directed to a method of manufacturing metallic or partially metallic components from a powder mixture comprising at least one metallic powder, and an organic compound, that further may contain other components added to the mixture for a particular desired property of the metallic or at least partially metallic component manufactured, wherein the shape is obtained using polymer shaping methodologies, including but not limited to injection molding, metal injection molding, blow-molding, thermoforming, casting, compression, pressing RIM, extrusion, rotomolding, dip molding, and/or foam shaping among others. In an embodiment the component obtained through polymer shaping methodologies, is a “green component” that further may be submitted to a post-processing to allow densification and consolidation of the metallic or at least partially metallic component.

In an embodiment the invention is directed to a method of manufacturing metallic or partially metallic components from a powder mixture comprising at least a low melting point metallic powder and a high melting point metallic powder, wherein the low melting point metallic powder is selected from a Fe, Ni, Co, Cu, Mg, W, Mo, Al and Ti based alloy containing at least an element selected from: Ga, Bi, Pb, Rb, Zn, Cd, In, Sn, K, Na, Mn, B, Sc, Si, and/or Mg and/or any combination of them among others and a high melting point alloy selected from Fe, Ni, Co, Cu, Mg, W, Mo, Al or Ti based alloy, and an organic compound, that further may contain other components added to the mixture for a particular desired property of the metallic or at least partially metallic component manufactured, wherein the shape is obtained using polymer shaping methodologies, including but not limited to injection molding, metal injection molding, blow-molding, thermoforming, casting, compression, pressing RIM, extrusion, rotomolding, dip molding, and/or foam shaping among others. In an embodiment the component obtained through polymer shaping methodologies, is a “green component” that further may be submitted to a post-processing to allow densification and consolidation of the metallic or at least partially metallic component.

In an embodiment the invention is directed to a method of manufacturing metallic or partially metallic components from a mixture comprising at least one metallic powder, and an organic compound, that further may contain other components added to the mixture for a particular desired property of the metallic or at least partially metallic component manufactured, wherein the shape is obtained through MIM. In an embodiment the component obtained through MIM, is a “green component” that further may be submitted to a post-processing to allow densification and consolidation of the metallic or at least partially metallic component.

In an embodiment the invention is directed to a method of manufacturing metallic or partially metallic components from a mixture comprising at least a low melting point metallic powder and a high melting point metallic powder, wherein the shaping of the powder mixture is made through MIM. In an embodiment the component obtained through MIM, is the metallic or at least partially metallic component. In an embodiment the component obtained through MIM, is a “green component” that further may be submitted to a post-processing to allow densification and consolidation of the metallic or at least partially metallic component.

In an embodiment there are other shaping technologies which are useful to implement the method of the invention, such as Hot Isostatic Pressure (HIP), Cold Isostatic Pressing (CIP), sinter forging and sintering. In an embodiment these processes are applied to the powder mixture to obtain the final desired metallic or at least partially metallic component; in other embodiment HIP, sinter forging, CIP and/or sintering are applied during post-processing treatment after another previous shaping technique such as AM technologies and/or polymer injection technologies to allow densification and consolidation of the metallic or at least partially metallic component.

In an embodiment Hot Isostatic Pressure (HIP) is a manufacturing method in which powder materials are encapsulated in a sealed container called die before uniaxial pressure is applied at elevated temperature in order to sintering it into a dense compact solid. Argon is usually used as fluid medium for the application of packing density pressure in the 100-3300 MPa range and the temperature is normally set in the 1000-1200° C. range. Among the three sintering mechanisms—diffusion, power-law creep, and yield-diffusion serves as the main sintering mechanism. The temperature at which diffusion bonding occurs during hot isostatic process is normally around 50-70% of the melting point of low melting point material. Diffusion bonding involves no melting of either material, hence there is no segregation, no shrinkage crack formation at the interfacial mixed zone. Sometimes diffusion layer is used to prevent diffusion of undesirable elements from top layer to substrate. The rate of the diffusion mechanisms will depend heavily on the particle size. The main goal in sintering with an applied gas pressure is to achieve a full theoretical density. As the die is filled, the arrangement of the particles and the consequent distribution of voids between the particles have a major influence on the subsequent behavior of the powder mass.

In an embodiment the invention is directed to a method of manufacturing metallic or partially metallic components from a powder mixture containing at least one metallic phase, that further may contain an organic compound wherein the component is obtained through HIP.

In an embodiment Cold Isostatic pressing is a powder-forming process where packing density takes place under isostatic or near-isostatic pressure conditions. Two main process variants exist, wet-bag and dry-bag. The former is mainly used for prototypes or low-production while the latter is a mass production process. Both variants render low geometric precision. The metal powder is placed in a flexible mould around a solid core rod. The mould is usually made of rubber or urethane or PVC. The assembly is then pressurized hydrostatically in a chamber to pressures of 400 to 1000 MPa.

In an embodiment the invention is directed to a method of manufacturing metallic or partially metallic components from a powder mixture comprising at least one metallic powder, that further may contain an organic compound added to the mixture for a particular desired property of the metallic or at least partially metallic component manufactured, wherein the component is obtained through Cold Isostatic Pressing.

In an embodiment Sintering is the heating of compacted metal powders to a temperature above their recrystallization temperature but below their melting point. Sintering mechanisms are highly complex in nature and depends on the composition of the metal powder and the processing parameters.

In an embodiment sintering is made at a temperature which allows high densification without massive deterioration of properties.

In an embodiment the component of the invention is subjected to a post processing step consisting in a sintering.

In an embodiment, before the heat treatment, the component is subjected to a sintering.

In an embodiment sintering is made at a temperature above 0.7*Tm of high melting point alloy (temperature 0.7 times the melting temperature of high melting point alloy). In other embodiment sintering is made at a temperature above 0.75*Tm of high melting point alloy (temperature 0.75 times the melting temperature of high melting point alloy). In an embodiment sintering is made at a temperature above 0.8*Tm (temperature 0.8 times the melting temperature of high melting point alloy) of high melting point alloy. In an embodiment sintering is made at a temperature above 0.85*Tm (temperature 0.85 times the melting temperature of high melting point alloy) of high melting point alloy. In an embodiment sintering is made at a temperature above 0.9*Tm (temperature 0.9 times the melting temperature of high melting point alloy) of high melting point alloy. In an embodiment sintering is made at a temperature above 0.95*Tm (temperature 0.95 times the melting temperature of high melting point alloy) of high melting point alloy.

In an embodiment sintering is made for 5 h or less. In an embodiment sintering is made for 3 h or less. In an embodiment sintering is made for 2 h or less.

In an embodiment tap density after sintering is 90% or more, in other embodiment 0.94% or more and even 96% or more.

Any of the above-described embodiments can be combined with any other embodiment herein described in any combination, to the extent that the respective features are not incompatible.

In an embodiment the invention is directed to a method of manufacturing metallic or partially metallic components from a powder mixture containing at least one metallic powder, that further may contain an organic compound added to the mixture for a particular desired property of the metallic or at least partially metallic component manufactured, wherein the component is obtained through sintering.

Other manufacturing methods of pieces and components widely used in 2012, like powder metallurgy (sintering of pressed metallic powders), machining, etc are often particularly well suit for the method of the present invention.

In other aspect, the present invention refers to a method of manufacturing a metallic or at least partially metallic component by shaping a powder mixture containing at least one metallic powder.

A particular application of the present method is when at least two different metallic powders with different melting temperatures are mixed together.

Any of the above-described embodiments can be combined with any other embodiment herein described in any combination, to the extent that the respective features are not incompatible.

In an embodiment the present invention refers to a method for manufacturing a metallic or at least partially metallic component from a powder mixture of at least two powders with different melting points.

In an embodiment powder mixtures disclosed in this document containing at least two metallic powders with different melting point are especially suitable for the method hereinafter disclosed. As previously disclosed in an embodiment a low melting point alloy suitable for use in the method of the invention is selected from: Ga and/or gallium alloy, AlGa alloy, SnGa alloy, CuGa alloy, MgGa alloy, MnGa alloy, NiGa alloy, AlMg alloy, high Mn containing alloy, high Mn containing Fe based alloy further containing carbon (steel), AlSc alloy, AlSn alloy, Al alloy and/or aluminium alloy containing more than 90% by weight aluminium. In an embodiment the high melting point alloy suitable for use in the method of the invention is selected from Fe, Ni, Co, Cu, Mg, W, Mo, Al and Ti alloys.

In an embodiment the invention refers to a method of manufacturing metallic or at least partially metallic component, from a mixture containing at least two metallic powders. In an embodiment the invention refers to a method of manufacturing metallic or at least partially metallic component, from a mixture containing at least two metallic powders. This mixture may be shaped by any of the preceding disclosed additive manufacturing (AM) process, as well as other non-additive manufacturing methodologies such as those for polymer shaping and/or any technique suitable for powder conformation and also any shaping technique developed in the future suitable for use with the mixture of at least one metallic powder disclosed in this document and in some cases submitted to at least one post-processing treatment, to achieve the final component.

When referring to high melting point and low melting point alloys, metallic constituents, phases, particulates, . . . in this document it can sometimes be read in absolute terms and even more often in relative terms. So most of the times what makes low and high melting point alloy is the difference between their melting points and not the absolute values where both can be high melting or low melting depending on the application. In this sense often a difference on the melting point of the two of 62° C. or more can be found, preferably 110° C. or more, preferably 230° C. or more, more preferably 420° C. or more, more preferably 640° C. or more, or even 820° C. or more. This temperature difference often relates to the difference in the melting temperature as defined in this document between the metallic phase with the highest value and the metallic phase with the lowest value when more than two metallic constituents are present.

When referring to high melting point and low melting point alloys, metallic constituents, phases, particulates, . . . in this document it can sometimes be read in absolute terms and even more often in relative terms. So most of the times what makes low and high melting point alloy is the difference between their melting points and not the absolute values where both can be high melting or low melting depending on the application. In this sense often a difference on the melting point of the two of 62° C. or more can be found, preferably 110° C. or more, preferably 230° C. or more, more preferably 420° C. or more, more preferably 640° C. or more, or even 820° C. or more. This temperature difference often relates to the difference in the melting temperature as defined in this document between the metallic phase with the highest value and the metallic phase with the lowest value when more than two metallic constituents are present.

In an embodiment, when there are three or more alloys in powder form in the powder mixture, to define if an alloy is a low or high melting point, reference is made to the metal powder having the lowest melting point. In an embodiment a metal powder having more than 62° C. in melting temperature than the metal powder having the lowest melting point is considered a high melting point alloy. In an embodiment a metal powder having more than 110° C. in melting temperature than the metal powder having the lowest melting point is considered a high melting point alloy. In an embodiment a metal powder having more than 230° C. in melting temperature than the metal powder having the lowest melting point is considered a high melting point alloy. In an embodiment a metal powder having more than 420° C. in melting temperature than the metal powder having a low melting point is considered a high melting point alloy. In an embodiment a metal powder having more than 640° C. in melting temperature than the metal powder having a low melting point is considered a high melting point alloy. In an embodiment a metal powder having more than 820° C. in melting temperature than the metal powder having a low melting point is considered a high melting point alloy.

In an embodiment to consider an alloy as the lowest melting point alloy, it may be least 1% in weight of the powder mixture.

In an embodiment when there are three or more metallic powders in the powder mixture and two or more of them are low melting point alloys, to calculate which is the Tm of the low melting point alloy, low melting point alloys being less than 1% by weight of the powder mixture are not considered.

In an embodiment when there are three or more metallic powders in the powder mixture and two or more of them are low melting point alloys, to calculate which is the Tm of the low melting point alloy, low melting point alloys being less than 3.8% by weight of the powder mixture are not considered.

In an embodiment when there are three or more metallic powders in the powder mixture and two or more of them are low melting point alloys, to calculate which is the Tm of the low melting point alloy, low melting point alloys being less than 4.2% by weight of the powder mixture are not considered.

In an embodiment when there are three or more metallic powders in the powder mixture and two or more of them are low melting point alloys, to calculate which is the Tm of the low melting point alloy, low melting point alloys being less than 1% by weight of metallic phase (the sum of all metallic powders in the powder mixture are not considered.

In an embodiment when there are three or more metallic powders in the powder mixture and two or more of them are low melting point alloys, to calculate which is the Tm of the low melting point alloy, low melting point alloys being less than 3.8% by weight of the metallic phase (the sum of all metallic powders in the powder mixture are not considered.

In an embodiment when there are three or more metallic powders in the powder mixture and two or more of them are low melting point alloys, to calculate which is the Tm of the low melting point alloy, low melting point alloys being less than 4.2% by weight of the metallic phase (the sum of all metallic powders in the powder mixture are not considered.

In an embodiment when there are three or more metallic powders in the powder mixture, to define if an alloy is a low or high melting point, reference is made to the metal powder having a higher melting point. In an embodiment a metal powder having less than 62° C. than the metal powder having the highest melting point is considered a low melting point alloy. In an embodiment a metal powder having less than 110° C. than the metal powder having the highest melting point is considered a low melting point alloy. In an embodiment a metal powder having less than 230° C. than the metal powder having the highest melting point is considered a low melting point alloy. In an embodiment a metal powder having less than 420° C. than the metal powder having the highest melting point is considered a low melting point alloy. In an embodiment a metal powder having less than 640° C. than the metal powder having the highest melting point is considered a low melting point alloy. In an embodiment a metal powder having less than 820° C. than the metal powder having the highest melting point is considered a low melting point alloy.

In an embodiment to consider an alloy as a highest melting point alloy, it may be least 1% in weight of the powder mixture.

In an embodiment when there are three or more metallic powders in the powder mixture and two or more of them are high melting point alloys, to calculate which is the Tm of the high melting point alloy, high melting point alloys being less than 1% by weight of the powder mixture are not considered.

In an embodiment when there are three or more metallic powders in the powder mixture and two or more of them are high melting point alloys, to calculate which is the Tm of the high melting point alloy, high melting point alloys being less than 3.8% by weight of the powder mixture are not considered.

In an embodiment when there are three or more metallic powders in the powder mixture and two or more of them are high melting point alloys, to calculate which is the Tm of the high melting point alloy, high melting point alloys being less than 4.2% by weight of the powder mixture are not considered.

In an embodiment when there are three or more metallic powders in the powder mixture and two or more of them are high melting point alloys, to calculate which is the Tm of the high melting point alloy, high melting point alloys being less than 1% by weight of the metallic phase (the sum of all metallic powders in the powder mixture) are not considered.

In an embodiment when there are three or more metallic powders in the powder mixture and two or more of them are high melting point alloys, to calculate which is the Tm of the high melting point alloy, high melting point alloys being less than 3.8% by weight of the metallic phase (the sum of all metallic powders in the powder mixture) are not considered.

In an embodiment when there are three or more metallic powders in the powder mixture and two or more of them are high melting point alloys, to calculate which is the Tm of the high melting point alloy, high melting point alloys being less than 4.2% by weight of the metallic phase (the sum of all metallic powders in the powder mixture) are not considered.

In an embodiment when there are two or more high melting point alloys in a powder mixture. Tm of the high melting point alloy, refers to the Tm of the high melting point alloy having the highest weight percentage of all the high melting point alloys.

In an embodiment when there are two or more high melting point alloys in a powder mixture. Tm of the high melting point alloy refers to the Tm of the high melting point alloy having the highest volume percentage of all the high melting point alloys.

In an embodiment when there are two or more low melting point alloys in a powder mixture. Tm of the low melting point alloy, refers to the Tm of the low melting point alloy having the highest volume percentage of all the low melting point alloys.

In an embodiment when there are two or more low melting point alloys in a powder mixture. Tm of the low melting point alloy, refers to the Tm of the low melting point alloy having the highest weight percentage of all the low melting point alloys.

In an embodiment when there are two or more high melting point alloys in a powder mixture. Tm of the high melting point alloy, refers to the Tm of the high melting point alloy having the lowest weight percentage of all the high melting point alloys.

In an embodiment when there are two or more high melting point alloys in a powder mixture. Tm of the high melting point alloy refers to the Tm of the high melting point alloy having the lowest volume percentage of all the high melting point alloys.

In an embodiment when there are two or more low melting point alloys in a powder mixture. Tm of the low melting point alloy, refers to the Tm of the low melting point alloy having the lowest volume percentage of all the low melting point alloys.

In an embodiment when there are two or more low melting point alloys in a powder mixture. Tm of the low melting point alloy, refers to the Tm of the low melting point alloy having the lowest weight percentage of all the low melting point alloys.

In an embodiment when there are three or more metallic powders in the powder mixture, Tm of the high melting point refers to Tm of the component having 62° C. or more melting temperature than the metallic powder having lowest melting point of the powder mixture, having the highest weight percentage of all high melting point alloys. In an embodiment if there are more than one high melting point alloy with the same weight percentage, Tm refers to the melting temperature of the metallic powder having high Tm, between them.

In an embodiment when there are three or more metallic powders in the powder mixture, Tm of the high melting point refers to Tm of the component having 62° C. or more melting temperature than the metallic powder having lowest melting point of the powder mixture, having the highest weight percentage of all high melting point alloys. In an embodiment if there are more than one high melting point alloy with the same weight percentage, Tm refers to the melting temperature of the metallic powder having high Tm, between them.

In an embodiment when there are three or more metallic powders in the powder mixture, Tm of the high melting point refers to Tm of the component having 110° C. or more melting temperature than the metallic powder having lowest melting point of the powder mixture, having the highest weight percentage of all high melting point alloys. In an embodiment if there are more than one high melting point alloy with the same weight percentage, Tm refers to the melting temperature of the metallic powder having high Tm, between them.

In an embodiment when there are three or more metallic powders in the powder mixture, Tm of the high melting point refers to Tm of the component having 110° C. or more melting temperature than the metallic powder having lowest melting point of the powder mixture, having the highest weight percentage of all high melting point alloys. In an embodiment if there are more than one high melting point alloy with the same weight percentage, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 1% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 1% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 62° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 62° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 62° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 62° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 62° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 62° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 62° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 62° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 110° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 110° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 110° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 110° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 110° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 110° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 110° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 110° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 230° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 420° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 420° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 420° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 420° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 420° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 420° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 420° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 420° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 640° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

an embodiment when there are three or more metallic powders in the powder mixture, Tm of the high melting point refers to Tm of the component having 820° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 820° C. or more melting temperature than the metallic powder having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 820° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 820° C. or more melting temperature than the metallic powder having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

In an embodiment when there are three or more metallic powders in the powder mixture, Tm of the high melting point refers to Tm of the component having 820° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having high Tm, between them.

In an embodiment when there are three or more metallic powders in the powder mixture, Tm of the high melting point refers to Tm of the component having 820° C. or more melting temperature than the metallic phase (the sum of all metallic powders in the powder mixture) having lowest melting point of the powder mixture (being at least 3.8% in weight of the powder mixture with the highest weight percentage. In an embodiment if there are more than one metal powders having the same weight percentage, being the highest values, Tm refers to the melting temperature of the metallic powder having less Tm, between them.

In an embodiment when there are three or more metallic powders in the powder mixture, Tm of the high melting point refers to Tm of the component having 820° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having high Tm, between them.

In an embodiment when there are three or more metallic powders in the powder mixture, Tm of the high melting point refers to Tm of the component having 820° C. or more melting temperature than the metallic phase (the sum of all metallic powders in the powder mixture) having lowest melting point of the powder mixture (being at least 3.8% in volume of the powder mixture with the highest weight percentage. In an embodiment if there are more than one metal powders having the same volume percentage, being the highest values, Tm refers to the melting temperature of the metallic powder having less Tm, between them.

The metallic powder is then often either coated or mixed within a polymer. The inventor has seen that for some applications the way the feedstock is configured can have a strong influence in the properties attained and the geometries that are possible. In FIGURE—4, different types of configurations relating to the polymer and metallic phases relative location. Two main configurations arise: coated particles and organic pellets with metallic particulate filling. As has been seen the organic compounds can even be in a non-solid state with the metallic particulates mixed in as a suspension. But even in some of those applications it is beneficial to prepare the mixing of organic compounds and metallic phases in an earlier stage and it is not uncommon to then have an intermediate state where the organic compounds are solid and the metallic phases are mixed in to then proceed to another step where this feedstock is fluidized again. When the organic compounds are in a solid state depending on the application a different configuration will be more desirable. Also different ways arise when incorporating a second or more metallic phase as some examples can be seen in FIGURE-4. For some applications it is very advantageous to have a multitude of metallic particulates within every feedstock particle bound mainly by the organic compound, which allows amongst others to better control the packing of the metallic phase or phases. On the other hand for some applications, where the amount of organic compound is to be minimized and/or where the binding during the shaping step occurs mainly through the surface of the feedstock particulates an mainly the organic compound is responsible for shape retention at that stage, then the coated metallic particles configuration will often be preferred. One example is the case of photo binding of the particulates, or localized plastification or melting of a polymer, in which both feedstock configurations can be used, but somewhat more often the coated particles configuration. One very interesting configuration based on the organic pellets with metallic particulate filling arises when two or more metallic phases are to be employed with a special nominal size relation to favor the filling of certain particulate voids in a close compact structure. Then the desired configuration can already be provided within the feedstock, with considerable advantage for several shaping processes, especially some of the AM related ones. In the case of coated particles, the metal phases with smaller particle size can be provided coated, uncoated or even embedded in the coating, each solution being better for different applications.

In an embodiment the powder mixture further comprises an organic material.

In an embodiment the organic material is a polymer. In other embodiment the organic material is a resin. In other embodiment the resin is a photocurable resin. In an embodiment the organic material is in powder form. In an embodiment the polymer material is in powder form. In an embodiment at least one powder is partially and/or totally coated by an organic material. In an embodiment at least one powder is partially and/or totally coated by a polymer. In an embodiment at least one powder is coated by an organic material. In an embodiment at least one powder is coated by a polymer.

In an embodiment at least part of one of the metallic powders, and for several embodiments at least totally one of the metallic powders is coated and/or embedded by an organic material, in other embodiments at least one of the metallic powders (for several embodiments at least partially and for other embodiments totally) in the powder mixture is in other of possible configuration explained in FIG. 4. In other embodiments at least two metallic powders and in other embodiments all the metallic powders of the mixture are coated and/or embedded and/or in other of possible configuration explained in FIG. 4. In other embodiments in contrast the organic compound is also in powder form.

In an embodiments in this application when referring to metallic powders coated and/or embedded and/or in another possible configuration as explained in FIG. 4, reference is made to AM particulates instead powder particulates. In several embodiments AM particulate size refers to the size of the coated and/or embedded and/or filled in an organic pellet metallic powder particulates and/or any other possible configuration as shown in FIG. 4.

In an embodiment there are many possible configurations for the powder mixture of at least one metallic powder with respect to the configuration of the metallic particles and the organic compound, one or another will be more interesting depending of concrete shaping technique chosen. In an embodiment when the powder mixture comprises more than two metallic powders, for some applications it is interesting having only one of the metallic powders at least partially and in another embodiments entirely, coated by an organic compound. In other embodiment the other metal powders of the mixture are also at least partially and in some embodiments entirely, coated by an organic material, in some embodiments the same organic material coats all the metallic powders but in other embodiments each metallic powder is coated by a different organic compound, and even in other embodiment different organic compounds are used for coating one metallic powder.

In an embodiment when the powder mixture comprises more than two metallic powders, for some applications it is interesting having only one of the metallic powders at least partially and in another embodiments entirely, embedded in an organic compound. In other embodiment the other metal powders of the mixture are also at least partially and in some embodiments entirely, embedded in an organic material, in some embodiments all the metallic powders are embedded in the same organic material but in other embodiments each metallic powder is embedded in a different organic compound, and even in other embodiment one metallic powder is embedded in different organic compound.

In an embodiment this particular application is especially interesting when the mixture of at least two metallic powders with different melting temperatures is coated or mixed or in other possible configuration as shown in FIG. 4, within a polymer. The polymer is responsible for the shape configuration and retention during the AM process or any other shaping process applied to the metallic powder mixture (for example MIM) and the handling of this piece in this “green state” for those cases wherein post-processing is required to at least partially eliminate the polymer and carry on the densification and consolidation of the metallic or at least partially metallic component until the final component with required properties is obtained.

In an embodiment at least one low melting point alloy in the powder mixture is partially and/or totally coated by an organic material. In an embodiment at least one low melting point alloy in the powder mixture is coated by an organic material. In an embodiment at least one low melting point alloy in the powder mixture is partially and/or totally coated by a polymer. In an embodiment at least one low melting point alloy in the powder mixture is coated by a polymer

In an embodiment at least one high melting point alloy in the powder mixture is partially and/or totally coated by an organic material. In an embodiment at least one high melting point alloy in the powder mixture is coated by an organic material. In an embodiment at least one high melting point alloy in the powder mixture is partially and/or totally coated by a polymer. In an embodiment at least one high melting point alloy in the powder mixture is coated by a polymer.

As metallic phases is understood anything that behaves in the proper way for the implementation of the method of the present invention, so at least some intermetallic alloys, metal base composites, metalloids . . . are candidates to fit the definition of metallic phase as employed in the present invention.

in an embodiment organic compound refers to natural and synthetic compounds (polymers) which may be filed with an inorganic compound including but not limited to oxides, carbides, nitrides, borides, ceramic components, graphite, talc, mica, waxes, greases, and/or any susceptible natural organic compound (like sugars, proteins, lipids, natural oils and fats, peptides, carbohydrates . . . ), yeasts, teflón, halons, cyanides, . . . . In an embodiment the organic compound further contains metals which in an embodiment are eliminated during the post-processing, in other embodiment are alloyed with the main metallic constituents and in other embodiment remain as an infiltration in the component.

Although the metallic phases are indispensable for the present invention, the organic compound might have any kind of filling and also components of another nature can be brought in for any purpose. In this aspect any inorganic compound that can be used as a filling of a polymer or any other organic compound suited for the method of the present invention, as well as any purposeful phase of non-metallic origin: to increase wear performance (like oxides, carbides, nitrides, borides or any other ceramic), to affect sliding performance (graphite, talc, mica, . . . ), to affect any physical or mechanical property, etc. In summary besides the organic compound and the metallic phase or phases any other phase might be present to provide additional functionality.

Polymer can have any kind of organic and/or inorganic charging or mixing for whatever reason it might be (as one example in thousands the mixing of wax for better flowing, pigments for color . . . ). And/or any susceptible natural organic compound (like sugars, proteins, lipids, natural oils and fats, peptides, carbohydrates . . . ), yeasts, teflón, halons, cyanides, . . . . In fact the word polymer as the material bringing shape retention functionality in the conformation or shaping process (trough AM, injection . . . ) can be replaced by any component that offers shape retention in the manufacturing process and can afterwards be eliminated without degrading the metallic constituents. Among others examples can be waxes, greases, talc, metals . . . . The case of metals is a singular one, since they can be chosen to be eliminated or to be alloyed with the main metallic constituents or remain as an infiltration.

The inventor has seen that in particular it is required for some applications The inventor has seen that in particular it is required for some applications a mixture containing at least one non metallic components, for many embodiments an organic compound and at least one metallic component in the mixture having a melting temperature, as described in this document, lower than 3.2 times the highest degradation temperature of the organic material, where the melting temperatures are expressed in Kelvin degrees, preferably lower than 2.6 times, more preferably lower than 2 times and even lower than 1.6 times. This mixture can also be interesting for some alternative application.

In an embodiment the present invention relates to a method of manufacturing a metallic or at least partially metallic component, using a powder mixture comprising at least one metallic powder and an organic compound characterized in that at least one of the metallic powders of the mixture has a melting temperature (expressed in Kelvin degrees) lower than 3.2 times the highest degradation temperature of the organic material, in other embodiment lower than 2.6 times, in other embodiment lower than 2 times and even in other embodiment lower than 1.6 times, wherein the component is shaped using any shaped technique suitable including but not limited to any additive manufacturing (AM) technique, as well as other non-additive manufacturing technique such as those for polymer shaping and also any shaping technique developed in the future suitable for use with the mixture of at least one metallic powders and an organic compound disclosed in this document. The manufacturing method in some embodiments requires a post treatment of the shaped component until obtain the desired component.

In an embodiment the present invention relates to a method of manufacturing a metallic or at least partially metallic component, using a powder mixture comprising at least a low melting point metallic powder and a high melting point metallic powder, wherein the low melting point metallic powder is selected from a Fe, Ni, Co, Cu, Mg, W, Mo, Al and Ti based alloy containing at least an element selected from: Ga, Bi, Pb, Rb, Zn, Cd, In, Sn, K, Na, Mn, B, Sc, Si, and/or Mg and/or any combination of them among others and a high melting point alloy selected from Fe, Ni, Co, Cu, Mg, W, Mo, Al or Ti based alloy and an organic compound characterized in that at least one of the metallic powders of the mixture has a melting temperature (expressed in Kelvin degrees) lower than 3.2 times the highest degradation temperature of the organic material, in other embodiment lower than 2.6 times, in other embodiment lower than 2 times and even in other embodiment lower than 1.6 times, wherein the component is shaped using any shaped technique suitable including but not limited to any additive manufacturing (AM) technique, as well as other non-additive manufacturing technique such as those for polymer shaping and also any shaping technique developed in the future suitable for use with the mixture of at least one metallic powders and an organic compound disclosed in this document. The manufacturing method in some embodiments requires a post treatment of the shaped component until obtain the desired component.

In an embodiment when the organic compound is a mixture of more than one component, the highest degradation temperature of an organic compound refers to the melting temperature of the component with higher melting point in the mixture, in other embodiments is referred to the melting temperature of the majority component of the mixture. In other embodiments where the organic material is a polymeric material and there are not more components this higher degradation temperature corresponds with the degradation temperature of the polymeric material.

In an embodiment organic compounds such as polymer degradation refers to a change in the properties—tensile strength, color, shape, etc.—of a polymer or polymer-based product under the influence of one or more environmental factors such as heat, light or chemicals. The changes in properties are often termed “aging”. Deteriorative reactions occur during processing, when polymers are subjected to heat, oxygen and mechanical stress, and during the useful life of the materials when oxygen and sunlight are the most important degradative agencies. In more specialized applications, degradation may be induced by high-energy radiation, ozone, atmospheric pollutants, mechanical stress, biological action, hydrolysis and many other influences.

In an embodiment thermal degradation of organic compounds such as polymers refers to a molecular deterioration because of overheating. At high temperatures, the components of the long chain backbone of the polymer can begin to separate (molecular scission) and react with one another to change the properties of the polymer. The chemical reactions involved in thermal degradation lead to physical and optical property changes relative to the initially specified properties. Thermal degradation generally involves changes to the molecular weight (and molecular weight distribution) of the polymer and typical property, changes include reduced ductility and embrittlement, chalking, color changes, cracking, general reduction in most other desirable physical properties.

In an embodiment the temperature at which changes starts is the degradation temperature of a the organic compound.

In an embodiment the temperature at which changes starts in the polymer is the degradation temperature of a polymer.

In an embodiment the temperature at which changes starts is the degradation temperature of a polymer.

In an embodiment thermal degradation of the organic compound is measured by means of DSC analysis.

In an embodiment thermal degradation of the organic compound is measured by means of DTA analysis.

In an embodiment thermal degradation of the polymer is measured by means of DSC analysis.

In an embodiment thermal degradation of the polymer is measured by means of DTA analysis.

In an embodiment the basic principle underlying DSC (Differential scanning calorimetry) is that when the sample undergoes a physical transformation, more or less heat will need to flow to it than the reference to maintain both at the same temperature. Whether less or more heat must flow to the sample depends on whether the process is exothermic or endothermic. By observing the difference in heat flow between the sample and reference, differential scanning calorimeters are able to measure the amount of heat absorbed or released during such transitions.

In an embodiment In DTA, the heat flow to the sample and reference remains the same rather than the temperature. When the sample and reference are heated identically, phase changes and other thermal processes cause a difference in temperature between the sample and reference.

In an embodiment DSC is used for examining polymeric materials to determine their thermal transitions. Melting points and glass transition temperatures for most polymers are available from standard compilations, and the method can show polymer degradation by the lowering of the expected melting point, Tm, for example. Tm depends on the molecular weight of the polymer and thermal history, so lower grades may have lower melting points than expected. The percent crystalline content of a polymer can be estimated from the crystallization/melting peaks of the DSC graph as reference heats of fusion can be found in the literature.

In an embodiment thermogravimetric Analysis (TGA) is used for decomposition behavior determination of organic compounds. Impurities in polymers can be determined by examining thermograms for anomalous peaks, and plasticizers can be detected at their characteristic boiling points.

In an embodiment TGA is used for measurement of organic compounds degradation.

In an embodiment TGA is used for measurement of polymer degradation.

In an embodiment the invention refers to a method of manufacturing a metallic or at least partially metallic component, using a powder mixture comprising at least two metallic powder with different melting point, and a organic compound, characterized in that at least one of the metallic powders of the mixture has a melting temperature (expressed in Kelvin degrees) lower than 3.2 times the highest degradation temperature of the organic material, in other embodiment lower than 2.6 times, in other embodiment lower than 2 times and even in other embodiment lower than 1.6 times, wherein the component is shaped using any shaped technique suitable including but not limited to any additive manufacturing (AM) technique, as well as other non-additive manufacturing technologies such as those for polymer shaping and also any shaping technique developed at the time of filing this application but suitable for use with the mixture of at least two metallic powders and an organic compound disclosed in this document. The manufacturing method in some embodiments requires a post treatment of the shaped component until obtain the desired component.

The inventor has seen that most mechanical properties benefit from a high volume fraction of metallic constituents in the feedstock, but on the other hand in some applications where the feedstock is made to flow the viscosity might negatively be affected by an excessive volume fraction of metallic constituents in the feedstock. In the same way some AM technologies and some other shaping processes employed are easier to implement with somewhat less charged feedstock, since a minimum quantity of the functional for the shaping process organic compound is required. So when mechanical properties or density amongst others are the priority, it is desirable to have at least 42% volume fraction of non-organic constituents, preferably 56% or more, more preferably 68% or more and even 76% or more. If inorganic charges and ceramic reinforcements are not looked upon, then in this case it is often desirable to have at least 36% volume fraction of metallic constituents in the feedstock, preferably 52% or more, more preferably 62% or more or even 75% or more. Also the amount of high melting point metallic constituents within the metallic constituents is quite significant for some applications, too high poses difficulties for the consolidation while too low might induce excessive deformation amongst others. In this sense often a volume fraction of high melting point metallic constituents higher than 32% of all metallic constituents, preferably higher than 52%, more preferably higher than 72%, and even higher than 92% can be desirable for applications where long diffusion treatments are acceptable. On the other side volume fraction of high melting point metallic constituents lower than 94% of all metallic constituents, preferably lower than 88%, more preferably lower than 77%, and even lower than 68% can be desirable for economic reasons, especially in view of a faster consolidation.

The inventor has seen that it is also quite interesting for some applications the metallic phase (the sum of all metallic powders contained in the powder mixture) representing a volume fraction of 24% or more, preferably 36% or more, more preferably 56% or more, and even 72% or more.

In an embodiment the volume fraction of metallic powder, in the powder mixture comprising an organic compound and at least one metallic powders or more than one metallic powders with similar melting point, used in the method of the invention is above 24%, in another embodiment above 36%, in another embodiment above 56%, and even in another embodiment above 72%, the rest consisting on organic compounds. In other embodiment higher volume fractions of metallic powders are used sometimes 78% or more, in other embodiment 84% or more, in other embodiment 91% or more and even in some embodiments having no other components different from the metallic powder mixture. In an embodiment the volume fraction of high melting point metallic constituents of all metallic constituents is higher than 32%, preferably higher than 52%, in other embodiment higher than 72%, and even in another embodiment higher than 92%. On the other side in other embodiment a volume fraction of high melting point metallic constituents of all metallic constituents is lower than 94%, in other embodiment lower than 88%, in other embodiment lower than 77%, and even in other embodiment lower than 68%.

In an embodiment the volume fraction of metallic powders, in the powder mixture comprising an organic compound and at least two metallic powders, with different melting point, used in the method of the invention is above 24%, in another embodiment above 36%, in another embodiment above 56%, and even in another embodiment above 72%, the rest consisting on organic compounds. In other embodiment higher volume fractions of metallic powders are used sometimes 78% or more, in other embodiment 84% or more, in other embodiment 91% or more and even in some embodiments having no other components different from the metallic powder mixture of at least two metal powders with different melting point temperature. In an embodiment the volume fraction of high melting point metallic constituents of all metallic constituents is higher than 32%, preferably higher than 52%, in other embodiment higher than 72%, and even in another embodiment higher than 92%. On the other side in other embodiment a volume fraction of high melting point metallic constituents of all metallic constituents is lower than 94%, in other embodiment lower than 88%, in other embodiment lower than 77%, and even in other embodiment lower than 68%.

In an embodiment the volume fraction of high melting point metallic constituents is higher than 32% by weight of all metallic constituents in other embodiment higher than 52%, in other embodiment higher than 72%, and even in another embodiment higher than 92%. On the other side in other embodiment a volume fraction of high melting point metallic constituents of all metallic constituents is lower than 94%, in other embodiment lower than 88%, in other embodiment lower than 77%, and even in other embodiment lower than 68%.

The size of the metallic particulates is quite critical for some applications of the present invention. Amongst others and in general terms a finer powder is easier to consolidate and thus to attain higher final densities, and also permits resolve finer details and thus allows for higher accuracy and tolerances, but it is more costly and thus renders some geometries as not economically viable. As has been seen sometimes it is advantageous in the present invention to have different phases in different nominal sizes, in such cases normally the desired nominal sizes are related to the nominal size of the main constituent. Nominal size of metallic powders, when not otherwise stated, refers to D50. Also other than the interstice filling distribution, that is to say tailored or random distributions can be advantageous for some applications. When metallic powders are used, for some applications requiring a fine detail or fast diffusion amongst others, rather fine powders can be used with a d50 of 78 microns or less, preferably 48 microns or less, more preferably 18 microns or less and even 8 microns or less. For some other applications rather coarser powders are acceptable with d50 of 780 microns or less, preferably 380 microns or less, more preferably 180 microns or less and even 120 microns or less. In some applications fine powders are even disadvantageous, so that powders with d50 of 12 microns or more are desired, preferably 22 microns or more, even more preferably 42 microns or more and even 72 microns or more. When several metallic phases are present in the form of particulates, and sizes of different phases are given a percentage of the majoritarian metallic powder spices, then the previous d50 values refer to the latter.

In the present invention, the inventor has seen that is beneficial for many applications the usage of a material which contains a polymer and at least two different metallic materials. The inventor has seen that the size of the metallic materials and also their morphology plays a very important role in the final properties that can be obtained in pieces manufactured according to the present invention. The shape of the powder is also important in terms of active surface and maximum volume fraction attainable, influenced by the spherical shape and particle size distribution.

In the case that the effect of the low melting point metallic constituent in the final component can only be held as non-detrimental for small concentrations of the elements of this low melting point alloy, the inventor has seen that there are several ways to proceed In order to have small concentration of such alloy yet enough contribution to the shape retention upon degradation of the polymer that provides shape retention during the manufacturing step. It has been observed that in general terms close compact structures with high volume fractions of metal in the feedstock help, and amongst others so does a homogeneous distribution of the low melting point metallic constituent. For example, if an 90%+ aluminum alloy is used as low melting point metallic constituent on a steel base metallic constituent, it is known that for many steels low % Al can have rather beneficial effects, like increasing strength through precipitation, limiting austenite grain growth, deoxidizing, providing quite hard nitriding layers . . . but those effects are achieved for rather small % Al contents in the order of magnitude between weight 0.1% and 1% (and rather closer to the lower end). So one way to deal with this situation is providing a high density close compact structure of the intended steel particulates (quite spherical shape and narrow size distribution help this purpose). Then a roughly 7.0% in volume is provided of metallic particulates with a diameter d50 being around 0.41 times the d50 diameter of the main particulates, to fill the octahedral holes. This particulates can have the same nature as the main metallic constituent or another particularly chosen to provide the desired functionality once the diffusion and all other treatments are concluded (again here spherical shape and a narrow size distribution help). Then a fine powder of the 90%+ aluminum alloy is provided with a d50 diameter being around 0.225 times the d50 diameter of the main particulates, roughly a 0.6% in volume should be provided with the intend of filling the tetrahedral holes (again here spherical shape and a narrow size distribution help). Given densities of aluminum and steel this volume fraction roughly represents 0.15% in weight of the 90%+ aluminum alloy in the final product which is within the range of generalized positive contribution of Al into steel.

In an embodiment an Al based alloy containing more than 90% by weight aluminium, is used as low melting point alloy and a steel based alloy is used as high melting point alloy in a powder mixture used for manufacturing a metallic or at least partially metallic component, in an embodiment this Al based alloy containing more than 90% by weight aluminium is less than 10% in volume of all metallic constituents. In an embodiment a 7% in volume of all metallic constituents are Al based alloy containing more than 90% by weight aluminium particles with a d50 diameter being around 0.41 times the d50 diameter of the main particulates of the steel based alloy and a 0.6% in volume of all metallic constituents are Al based alloy containing more than 90% by weight aluminium particles with a d50 diameter being around 0.225 times the d50 diameter of the main particulates of the steel based alloy.

The inventor has seen that one interesting implementation of the present invention, arises when a very fast AM or other shaping process is chosen for the shaping step. That is so given that the present invention in most cases involves a post-processing step, which is normally not necessary in the AM processes. In principle a post-processing step is perceived as a drawback, and only occasionally post processing steps to attain a superior accuracy are considered. But the inventor has seen that the disadvantage of having a post-processing step can be overcome by the flexibility and the increase in speed that the present method can offer, since it is easier to achieve faster speeds in polymer based AM processes than in metal based ones. This is more so when the post-processing can be applied to many components at simultaneously either through batches of several components in an oven or through a continuous process where several pieces are processed at the same time though every piece is at a somewhat different stage of the process. Then the effective processing time of the post-processing cycle can be strongly reduced since what really matters in the amount of pieces processed in one hour rather than the length of the cycle to which each piece is exposed. So the inventor has seen that what could be considered a rather laborious post-processing is effectively not so if the batches processed simultaneously are large enough. For example a 2h (3600 sec) post-processing debinding and diffusion treatment applied to a batch of 2000 pieces at once, renders an effective processing time per piece of less than 2 seconds.

In an embodiment the post processing of more than 500 pieces is made simultaneously, in other embodiment more than 800 pieces, in other embodiment more than 1200 pieces, in other embodiment more than 1600 pieces and even in other embodiment 2000 pieces or more.

In an embodiment the post processing time per piece is 10 seconds or less, in other embodiment 7 seconds or less, in other embodiment 4 second or less and even in other embodiment 2 seconds or less.

In an embodiment there are several post-processing treatments that may be applied to the shaped component, many of them including exposure of the component to certain temperatures.

In an embodiment when reference is made to “green compact”, “green material”, “green body” and/or “green component” it may be understood an intermediate component obtained by any shape method, as disclosed in the document, further containing a non metallic material (in many cases an organic material, such as for example but not limited to a polymeric material), which may be submitted to at least one post treatment with heat before obtaining the final component. In many applications this green component is subjected to a debinding process, to at least partially eliminate the organic compounds (binders).

When resistance of a green material is measured through the transverse rupture strength (TSR) method, using a three-point bending test, values close to 4 to 25 MPa are found for the materials and methods used and known in the state of the art. But when the green component is submitted to a debinding process and the binder is fully degraded values higher than 1 MPa are difficult to attain with the materials and methods used in the state of the art for the manufacture of metallic or at least partially metallic components, especially when big components are manufactured, which in some cases implies the use of molds or other elements to help with shape retention until sintering and/or HIP treatments are applied to consolidate the piece.

In an embodiment transverse rupture strength is a material property, defined as the stress in a material just before it yields in a flexure test.

In an embodiment transverse rupture strength is determined in a transverse bending test in which a specimen having either a circular or rectangular cross-section is bent until fracture or yielding using a three point flexural test technique. The flexural strength represents the highest stress experienced within the material at its moment of failure.

In some cases of the state of the art during the debinding process the organic material is not fully degraded and the transverse rupture strength (TSR) measurements of the component (sometimes named brown component in the state of the art, but not a brown component in the meaning of the present document) may be close to those of the green material, due to the presence of the organic compound usually to help handling the piece before sintering, HIP and/or application of any other post-treatment to consolidate the piece. In these cases when a heat treatment is carried out, and the organic compound is fully degraded before reach sintering and/or HIP temperature, often the remaining organic compound is fully degraded at the time of heating to reach the sintering and/or HIP temperatures. In the moment that the organic material is degraded, the minimum value of transverse strength (TRS) for these pieces is reach and this values hardily are over 2 MPa (the same values that would be obtained if a total debinding of the piece is made in the debinding process).

The inventor has seen that when employing the method of the invention and a mixture comprising at least two metallic powders and other non metallic components, which in many cases comprises an organic material, such as for example, but not limited to a polymeric material, the adequate choice of particle size distribution, along with the selection of the high melting and low melting metallic powder alloys in the mixture as previously explained allows a high compactation in the green material shaped, which translates into a high tap density and high resistance values of the green component along with higher resistance of the green component.

In an embodiment, when a partial debinding has been made, and/or when the green component is directly submitted to a Heat Treatment to transfer the shape retention from polymer to the metallic phase, the transverse rupture strength value of the component after the Heat treatment in the most critical point of the process (the critical point of the process refers to the moment wherein transverse rupture strength value reaches the minimum value during the elimination of the organic compound and the transference of the shape retention to the metallic component, and before sintering, HIP and/or another treatment at high temperature that depending of the alloy system in many cases it may occur when a temperature of at least 500° C. has reached, but far below the sintering temperature, in an embodiment 100° C. or more below the sintering and/or HIP temperature, in another embodiment 200° C. or more, in another embodiment 400° C. or more, and even in another embodiment 600° C. or more, and/or in other cases this may occur when the shape retention is made through the metallic components instead the organic compounds).

In an embodiment, when a fully debinding has been made the brown component obtained, wherein the component has been submitted to a Heat Treatment below the sintering temperature, have a transverse rupture strength value at room temperature of 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment transverse rupture strength is measured using ISO 3325:1996.

In an embodiment the green component is submitted to a Heat Treatment wherein at least partially PMSRT takes place.

In an embodiment the green component is submitted to a Heat Treatment wherein at least partially MSRT takes place.

In an embodiment during Heat Treatment at least partial debinding takes place.

In an embodiment the green component is submitted to a Heat Treatment wherein PMSRT takes place.

In an embodiment the green component is submitted to a Heat Treatment wherein MSRT takes place.

In an embodiment during Heat Treatment debinding takes place.

In an embodiment the post-processing treatment comprises at least a Heat Treatment wherein MSRT takes place.

In an embodiment the green component is subjected to a Heat Treatment.

In an embodiment the Heat Treatment is made between 0.35*Tm of the low melting point alloy and the temperature at which 20% of polymer is degraded. In an embodiment the Heat Treatment is made between 0.35*Tm of the low melting point alloy and the temperature at which 29% of polymer is degraded. In an embodiment the Heat Treatment is made between 0.35*Tm of the low melting point alloy and the temperature at which 36% of polymer is degraded. In an embodiment the Heat Treatment is made between 0.35*Tm of the low melting point alloy and the temperature at which 48% of polymer is degraded. In an embodiment the Heat Treatment is made between 0.35*Tm of the low melting point alloy and the temperature at which 69% of polymer is degraded. In an embodiment the Heat Treatment is made between 0.35*Tm of the low melting point alloy and the temperature at which 81% of polymer is degraded. In an embodiment the Heat Treatment is made between 0.35*Tm of the low melting point alloy and the temperature at which 92% of polymer is degraded. In an embodiment the Heat Treatment is made between 0.35*Tm of the low melting point alloy and the temperature at which polymer is fully degraded.

In an embodiment a polymer is 20% degraded when the polymer has the 20% of the mechanical strength measured according to ISO 6892 compared with the mechanical strength of the polymer in the green state under the same conditions.

In an embodiment a polymer is 20% degraded when the organic polymer has the 20% of the tensile strength measured according to ISO 6892 compared with the tensile strength of the polymer in the green state under the same conditions.

In an embodiment a polymer compound is 20% degraded when the polymer has the 20% of the transverse strength according to ISO 3325:1996 compared with the transverse strength of the polymer in the green state under the same conditions.

In an embodiment a polymer is 29% degraded when the polymer has the 29% of the mechanical strength measured according to ISO 6892 compared with the mechanical strength of the polymer in the green state under the same conditions.

In an embodiment a polymer compound is 29% degraded when the organic polymer has the 29% of the tensile strength measured according to ISO 6892 compared with the tensile strength of the polymer in the green state under the same conditions.

In an embodiment a polymer is 29% degraded when the polymer has the 29% of the transverse strength according to ISO 3325:1996 compared with the transverse strength of the polymer in the green state under the same conditions.

In an embodiment a polymer is 36% degraded when the polymer has the 36% of the mechanical strength measured according to ISO 6892 compared with the mechanical strength of the polymer in the green state under the same conditions.

In an embodiment a polymer is 36% degraded when the organic polymer has the 36% of the tensile strength measured according to ISO 6892 compared with the tensile strength of the polymer in the green state under the same conditions.

In an embodiment a polymer is 36% degraded when the polymer has the 36% of the transverse strength according to ISO 3325:1996 compared with the transverse strength of the polymer in the green state under the same conditions.

In an embodiment a polymer is 48% degraded when the polymer has the 48% of the mechanical strength measured according to ISO 6892 compared with the mechanical strength of the polymer in the green state under the same conditions.

In an embodiment a polymer is 48% degraded when the organic polymer has the 48% of the tensile strength measured according to ISO 6892 compared with the tensile strength of the polymer in the green state under the same conditions.

In an embodiment a polymer is 48% degraded when the polymer has the 69% of the transverse strength according to ISO 3325:1996 compared with the transverse strength of the polymer in the green state under the same conditions.

In an embodiment a polymer is 69% degraded when the polymer has the 69% of the mechanical strength measured according to ISO 6892 compared with the mechanical strength of the polymer in the green state under the same conditions.

In an embodiment a polymer is 69% degraded when the organic polymer has the 69% of the tensile strength measured according to ISO 6892 compared with the tensile strength of the polymer in the green state under the same conditions.

In an embodiment a polymer is 69% degraded when the polymer has the 69% of the transverse strength according to ISO 3325:1996 compared with the transverse strength of the polymer in the green state under the same conditions.

In an embodiment a polymer is 81% degraded when the polymer has the 81% of the mechanical strength measured according to ISO 6892 compared with the mechanical strength of the polymer in the green state under the same conditions.

In an embodiment a polymer is 81% degraded when the organic polymer has the 81% of the tensile strength measured according to ISO 6892 compared with the tensile strength of the polymer in the green state under the same conditions.

In an embodiment a polymer is 81% degraded when the polymer has the 81% of the transverse strength according to ISO 3325:1996 compared with the transverse strength of the polymer in the green state under the same conditions.

In an embodiment a polymer is 92% degraded when the polymer has the 92% of the mechanical strength measured according to ISO 6892 compared with the mechanical strength of the polymer in the green state under the same conditions.

In an embodiment a polymer is 92% degraded when the polymer has the 92% of the tensile strength measured according to ISO 6892 compared with the tensile strength of the polymer in the green state under the same conditions.

In an embodiment a polymer is 92% degraded when the polymer has the 92% of the transverse strength according to ISO 3325:1996 compared with the transverse strength of the polymer in the green state under the same conditions.

In an embodiment the Heat Treatment is made between 0.35*Tm of the low melting point alloy and 0.39*Tm of high melting point alloy in other embodiment between 0.35*Tm of the low melting point alloy and 0.49*Tm of high melting point alloy, in other embodiment between 0.35*Tm of the low melting point alloy and 0.55 Tm of high melting point alloy. In other embodiment between 0.35*Tm of the low melting point alloy and 0.64 Tm of high melting point alloy.

In an embodiment the Heat Treatment is made for a time enough to obtain a mechanical strength of the metallic or at least metallic component at room temperature of 0.7 MPa or more, in other embodiment 0.9 MPa or more, in other embodiment 1.2 MPa or more, in other embodiment 1.5 MPa or more, in other embodiment 2.3 MPa or more, in other embodiment 3.4 MPa or more, in other embodiment 4.6 MPa or more, in other embodiment 5.2 MPa or more, in other embodiment 6.3 MPa or more, in other embodiment 8.1 MPa or more, in other embodiment 10.5 MPa or more, in other embodiment 14.3 MPa or more, in other embodiment 19.6 MPa or more, in other embodiment 27.2 MPa or more, in other embodiment 32.6 MPa or more, in other embodiment 51.2 MPa or more, in other embodiment 84.3 MPa or more, in other embodiment 102 MPa or more, and even in other embodiment 110 MPa or more.

In an embodiment mechanical strength refers to Compressive strength or compression strength, which is the capacity of a material or structure to withstand loads tending to reduce size, as opposed to tensile strength, which withstands loads tending to elongate.

In an embodiment a compression test is the method used for determining the behavior of materials under a compressive load. Compression tests are conducted by loading the test specimen between two plates, and then applying a force to the specimen by moving the crossheads together. During the test, the specimen is compressed, and deformation versus the applied load is recorded. The compression test is used to determine elastic limit, proportional limit, yield point, yield strength, and (for some materials) compressive strength.

In an embodiment the standard test used to determining mechanical strength is the ASTM E9: standard test methods of compression testing of metallic materials at room temperature.

In an embodiment the standard test used to determining mechanical strength is the ASTM 209: standard test methods of compression testing of metallic materials at high temperatures temperature (above room temperature

In an embodiment mechanical strength refers to Compressive strength or compression strength, which is the capacity of a material or structure to withstand loads tending to reduce size, as opposed to tensile strength, which withstands loads tending to elongate.

In an embodiment a compression test is the method used for determining the behavior of materials under a compressive load. Compression tests are conducted by loading the test specimen between two plates, and then applying a force to the specimen by moving the crossheads together. During the test, the specimen is compressed, and deformation versus the applied load is recorded. The compression test is used to determine elastic limit, proportional limit, yield point, yield strength, and (for some materials) compressive strength.

In an embodiment the standard test used to determining mechanical strength is the ASTM E9: standard test methods of compression testing of metallic materials at room temperature.

In an embodiment the standard test used to determining mechanical strength is the ASTM 209: standard test methods of compression testing of metallic materials at high temperatures temperature (above room temperature).

In an embodiment the invention refers to a method of manufacturing metallic or at least partially metallic components such as pieces, parts, components or tools, comprising the following steps:
a. providing a powder mixture comprising at least a low melting point alloy and a high melting point alloy and optionally and organic compound
b. shaping the powder mixture with a shaping technique resulting in a shaped component
c. subjecting the shaped component to at least one heat treatment at a temperature between 0.35 times the melting temperature of the low melting point alloy and 0.39 times the melting temperature of the high melting point alloy, until the component reaches a mechanical strength of at least 1.2 MPa, wherein, when there are more than two metallic alloys, the Tm of the low melting point alloy is defined as the melting temperature of the alloy having the lowest melting point among the alloys present in an amount of at least 1% volume of the powder mixture, and the melting temperature of high melting point alloy is defined as the Tm of the alloy having the highest % volume among the high melting point alloys present in an amount of at least 3.8% volume of the powder mixture, and wherein any alloy having a melting temperature which is at least 110° C. higher than the low melting point alloy is considered a high melting point alloy

In an embodiment the invention refers to a method of manufacturing metallic or at least partially metallic components such as pieces, parts, components or tools, comprising the following steps:
a. providing a powder mixture comprising at least a low melting point alloy and a high melting point alloy and optionally and organic compound
b. shaping the powder mixture with a shaping technique resulting in a shaped component
c. subjecting the shaped component to at least one heat treatment at a temperature between 0.35 times the melting temperature of the low melting point alloy and 0.49 times the melting temperature of the high melting point alloy, until the component reaches a mechanical strength of at least 1.2 MPa, wherein, when there are more than two metallic alloys, the Tm of the low melting point alloy is defined as the melting temperature of the alloy having the lowest melting point among the alloys present in an amount of at least 1% volume of the powder mixture, and the melting temperature of high melting point alloy is defined as the Tm of the alloy having the highest % volume among the high melting point alloys present in an amount of at least 3.8% volume of the powder mixture, and wherein any alloy having a melting temperature which is at least 110° C. higher than the low melting point alloy is considered a high melting point alloy

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique resulting in a shaped component

subjecting the shaped component to a Heat treatment

In an embodiment in materials science, the strength of a material is its ability to withstand an applied load without failure or plastic deformation. The applied loads may be axial (tensile or compressive), or [shear strength shear]. Material strength refers to the point on the engineering stress-strain curve (yield stress) beyond which the material experiences deformations that will not be completely reversed upon removal of the loading and as a result the member will have a permanent deflection. The ultimate strength refers to the point on the engineering stress-strain curve corresponding to the stress that produces fracture.

In an embodiment the Heat Treatment is made for a time enough to obtain a mechanical strength of the metallic or at least metallic component at the temperature of the component in the moment of stopping the Heat Treatment for made the measurement of 0.7 MPa or more, in other embodiment 0.9 MPa or more, in other embodiment 1.2 MPa or more, in other embodiment 1.5 MPa or more, in other embodiment 2.3 MPa or more, in other embodiment 3.4 MPa or more, in other embodiment 4.6 MPa or more, in other embodiment 5.2 MPa or more, in other embodiment 6.3 MPa or more, in other embodiment 8.1 MPa or more, in other embodiment 10.5MP or more a, in other embodiment 14.3 MPa or more, in other embodiment 19.6 MPa or more, in other embodiment 27.2 MPa or more, in other embodiment 32.6 MPa or more, in other embodiment 51.2 MPa or more, in other embodiment 84.3 MPa or more, in other embodiment 102 MPa or more, and even in other embodiment 110 MPa or more.

In an embodiment the metallic or at least metallic component obtained before the Heat treatment has a mechanical strength at room temperature of 0.7 MPa or more, in other embodiment 0.9 MPa or more, in other embodiment 1.2 MPa or more, in other embodiment 1.5 MPa or more, in other embodiment 2.3 MPa or more, in other embodiment 3.4 MPa or more, in other embodiment 4.6 MPa or more, in other embodiment 5.2 MPa or more, in other embodiment 6.3 MPa or more, in other embodiment 8.1 MPa or more, in other embodiment 10.5MP or more a, in other embodiment 14.3 MPa or more, in other embodiment 19.6 MPa or more, in other embodiment 27.2 MPa or more, in other embodiment 32.6 MPa or more, in other embodiment 51.2 MPa or more, in other embodiment 84.3 MPa or more, in other embodiment 102 MPa or more, and even in other embodiment 110 MPa or more.

In an embodiment the metallic or at least metallic component obtained before the Heat treatment has a mechanical strength at the temperature of the component in the moment of stopping the Heat Treatment of 0.7 MPa or more, in other embodiment 0.9 MPa or more, in other embodiment 1.2 MPa or more, in other embodiment 1.5 MPa or more, in other embodiment 2.3 MPa or more, in other embodiment 3.4 MPa or more, in other embodiment 4.6 MPa or more, in other embodiment 5.2 MPa or more, in other embodiment 6.3 MPa or more, in other embodiment 8.1 MPa or more, in other embodiment 10.5MP or more a, in other embodiment 14.3 MPa or more, in other embodiment 19.6 MPa or more, in other embodiment 27.2 MPa or more, in other embodiment 32.6 MPa or more, in other embodiment 51.2 MPa or more, in other embodiment 84.3 MPa or more, in other embodiment 102 MPa or more, and even in other embodiment 110 MPa or more.

In an embodiment when the component obtained before the heat treatment further comprises organic compound is submitted to a non-thermal debinding, such as chemical debinding until full degradation of the organic compound before measuring the mechanical strength.

In an embodiment the shaped component is submitted to a Heat Treatment between 0.35*Tm of the low melting point alloy and 0.39*Tm of high melting point alloy for a time enough to obtain a mechanical strength of the metallic or at least partially component higher than 1.2 MPa at room temperature.

In an embodiment the shaped component is submitted to a heat treatment between 0.35*Tm of the low melting point alloy and 0.39*Tm of high melting point alloy for a time enough to obtain a mechanical strength of the metallic or at least partially component higher than 0.7 MPa at the temperature of the component in the moment of stopping the Heat Treatment for made the measurement

In an embodiment, when there is only one metallic powder in the powder mixture, the shaped component is submitted to a heat treatment between 0.35*Tm and 0.39*Tm of the metallic powder melting point. In an embodiment, when there is only one metallic powder in the powder mixture, the shaped component is submitted to a heat treatment between 0.35*Tm and 0.49*Tm of the metallic powder melting point. In an embodiment, when there are only one metallic powder in the powder mixture, the post-processing treatment consisting on a heat treatment made between 0.35*Tm and 0.55 Tm of the metallic powder melting point. In an embodiment, when there are only one metallic powder in the powder mixture, the post-processing treatment consisting on a heat treatment made between 0.35*Tm and 0.64 Tm of the metallic powder melting point.

In an embodiment when there is only one metallic powder in the powder mixture the Heat Treatment is made for a time enough to obtain a mechanical strength of the metallic or at least metallic component at room temperature of 0.7 MPa or more, in other embodiment 0.9 MPa, in other embodiment 1.2 MPa, in other embodiment 1.5 MPa, in other embodiment 2.3 MPa, in other embodiment 3.4 MPa, in other embodiment 4.6 MPa, in other embodiment 5.2 MPa, in other embodiment 6.3 MPa, in other embodiment 8.1 MPa, in other embodiment 10.5 MPa, in other embodiment 14.3 MPa, in other embodiment 19.6 MPa, in other embodiment 27.2 MPa, in other embodiment 32.6 MPa, in other embodiment 51.2 MPa, in other embodiment 84.3 MPa, in other embodiment 102 MPa, and even in other embodiment 110 MPa or more.

In an embodiment when there is only one metallic powder in the powder mixture the Heat Treatment is made for a time enough to obtain a mechanical strength of the metallic or at least metallic component at the temperature of the component in the moment of stopping the Heat Treatment for made the measurement of 0.7 MPa or more, in other embodiment 0.9 MPa, in other embodiment 1.2 MPa, in other embodiment 1.5 MPa, in other embodiment 2.3 MPa, in other embodiment 3.4 MPa, in other embodiment 4.6 MPa, in other embodiment 5.2 MPa, in other embodiment 6.3 MPa, in other embodiment 8.1 MPa, in other embodiment 10.5 MPa, in other embodiment 14.3 MPa, in other embodiment 19.6 MPa, in other embodiment 27.2 MPa, in other embodiment 32.6 MPa, in other embodiment 51.2 MPa, in other embodiment 84.3 MPa, in other embodiment 102 MPa, and even in other embodiment 110 MPa or more.

In an embodiment thanks to bleaching and direct contact between grains, there is an improvement between the thermal conductivity of the green component and brown component.

In an embodiment there is an improvement of more than 12% in thermal conductivity between brown and green component. In an embodiment there is an improvement of more than 22% in thermal conductivity between brown and green component. In an embodiment there is an improvement of more than 52% in thermal conductivity between brown and green component. In an embodiment there is an improvement of more than 110% in thermal conductivity between brown and green component.

In an embodiment thanks to bleaching and direct contact between grains, there is an improvement between the electrical conductivity of the green component and brown component.

In an embodiment there is an improvement of more than 12% in electrical conductivity between brown and green component. In an embodiment there is an improvement of more than 22% in electrical conductivity between brown and green component. In an embodiment there is an improvement of more than 52% in electrical conductivity between brown and green component. In an embodiment there is an improvement of more than 110% in electrical conductivity between brown and green component.

In an embodiment thanks to bleaching and direct contact between grains, there is an improvement between the thermal conductivity of the equivalent green component and brown component.

In an embodiment thanks to bleaching and direct contact between grains, there is an improvement between the thermal conductivity of the equivalent green component and brown component.

In an embodiment there is an improvement of more than 12% in thermal conductivity between brown and equivalent green component. In an embodiment there is an improvement of more than 22% in thermal conductivity between brown and equivalent green component. In an embodiment there is an improvement of more than 52% in thermal conductivity between brown and equivalent green component. In an embodiment there is an improvement of more than 110% in thermal conductivity between brown and equivalent green component.

In an embodiment thanks to bleaching and direct contact between grains, there is an improvement between the electrical conductivity of the equivalent green component and brown component.

In an embodiment there is an improvement of more than 12% in electrical conductivity between brown and equivalent green component. In an embodiment there is an improvement of more than 22% in electrical conductivity between brown and equivalent green component. In an embodiment there is an improvement of more than 52% in electrical conductivity between brown and equivalent green component. In an embodiment there is an improvement of more than 110% in electrical conductivity between brown and equivalent green component.

In an embodiment thanks to bleaching and direct contact between grains, there is an improvement between the thermal conductivity of the equivalent green component and brown component.

In an embodiment equivalent green component refers to an equivalent component to green component without polymer.

In an embodiment green component is submitted to a non-thermal debinding, such as chemical debinding until full degradation of the organic compound to obtain the equivalent green component before measuring the thermal or electrical conductivity.

In an embodiment sintering temperature is 0.7*Tm or more of high melting point alloy. In an embodiment sintering temperature is 0.75*Tm or more of high melting point alloy. In an embodiment sintering temperature is 0.8*Tm or more of high melting point alloy. In an embodiment sintering temperature is 0.85*Tm or more of high melting point alloy. In an embodiment sintering temperature is 0.9*Tm or more of high melting point alloy. In an embodiment sintering temperature is 0.95*Tm or more of high melting point alloy.

In an embodiment the invention refers to a method of manufacturing metallic or at least partially metallic components such as pieces, parts, components or tools, comprising the following steps:

providing a powder mixture comprising at least a low melting point alloy and a high melting point alloy and optionally and organic compound

shaping the powder mixture with a shaping technique resulting in a shaped component

subjecting the shaped component to a Heat treatment

subjecting the component obtained in step c to a sintering

In an embodiment the minimum transverse rupture strength values obtained after submit the green component to a post treatment involving a heat treatment before reaching 0.7*Tm of high melting point alloy at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment the minimum transverse rupture strength values obtained after submit the green component to a post treatment involving a heat treatment before reaching 0.75*Tm of high melting point alloy at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment the minimum transverse rupture strength values obtained after submit the green component to a post treatment involving a heat treatment before reaching 0.8*Tm of high melting point alloy at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment the minimum transverse rupture strength values obtained after submit the green component to a post treatment involving a heat treatment before reaching 0.85*Tm of high melting point alloy at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment the minimum transverse rupture strength values obtained after submit the green component to a post treatment involving a heat treatment before reaching 0.9*Tm of high melting point alloy at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment the minimum transverse rupture strength values obtained after submit the green component to a post treatment involving a heat treatment but before 0.95*Tm of high melting point alloy at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment when reference is made to “brown compact”, “brown material”, “brown body” and/or “brown component” it may be understood an intermediate component obtained after submitting the green component to at least a post-processing treatment, wherein the full degradation of the organic compound takes place.

In an embodiment “brown compact”, “brown material”, “brown body” and/or “brown component” refers to greem component after total degradation of the organic compound, and before reach sintering temperature.

In an embodiment the transverse rupture strength of the brown component at room temperature is 0.3

MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more.

In an embodiment the transverse rupture strength of the brown component at room temperature is

In other embodiment transverse rupture strength determination is made at the temperature of the component in the moment of stopping the post-processing treatment for made the measurement.

In an embodiment, component is maintained at this temperature for made the measurement.

In other embodiment transverse rupture strength determination is made at a temperature of the component lower than 0.7*Tm of high melting point alloy

In an embodiment if there is only one metallic powder in the powder mixture, transverse rupture strength determination is made at a temperature of the component lower than 0.7*TM of the metallic powder melting point.

In an embodiment the transverse rupture strength values obtained after submit the green component to a post-processing treatment such as debinding and/or PMSRT at room temperature is 0.3 MPa or more, in other embodiment 0.55 MPa, in other embodiment 0.6 MPa, in other embodiment 0.8 MPa, in other embodiment 1.1 MPa, in other embodiment 1.6 MPa, in other embodiment 2.3 MPa, in other embodiment 2.6 MPa, in other embodiment 3.1 MPa, in other embodiment 4.1 MPa, in other embodiment 5.2 MPa, in other embodiment 7.2 MPa, in other embodiment 9.3 MPa, in other embodiment 13.6 MPa, in other embodiment 15.9 MPa, in other embodiment 25.3 MPa, in other embodiment 41.2 MPa, in other embodiment 51 MPa, and even in other embodiment 56 MPa or more. in the moment where full degradation of the organic compound takes place.

In an embodiment, for some applications, especially when high mechanical properties in the component are desired a debinding process to at least partially eliminate the organic compound is required. It is advantageous for some applications to choose at least one of the metallic powders to help with the shape retention during the debinding process. In such instances at least one of the metallic powders is chosen to melt in some amount or strongly diffuse into the metallic powder with the highest volume fraction, before the polymer is degraded to an extent that it cannot retain the shape. It is particularly interesting for many applications to have for this purpose a metallic alloy with an extended range of solidification, so that the amount of liquid phase can be purposefully controlled. A higher volume fraction of liquid helps densification but an excessive amount can cause slumping. In some instances where amongst others high densification is desired without excessive post-processing (HIP, . . . ) and slumping, cavity formation and all other disadvantages associated with excessive liquid phase are of not excessive concern then volume fractions of liquid above 6%, preferably above 12%, more preferably above 22% and even above 33% can be used. On the contrary when densification is not such a concern, or it is desirable to attain it by other means or slumping or other undesirable effects of excessive liquid phase are not desirable then liquid phases below 18%, preferably below 12%, more preferably below 8% and even below 3% can be used. In some instances of the present invention the liquid phase is only desired to promote diffusion in such cases more than a 1% in volume, preferably more than a 4%, more preferably more than an 8% or even more than a 16% can be desirable.

In an embodiment the liquid volume fraction refers to the total volume of the metallic phase which produces the liquid phase.

In an embodiment the liquid volume fraction refers to the total volume of the metallic phase (the sum of al metallic phases.

In an embodiment the liquid volume fraction refers to the total volume of the component.

The control of the atmosphere during all treatments is very important for some applications, since oxidation of internal voids and also of the surface is often not desirable, but sometimes even advantageous. So often controlled atmospheres are advantageous, inert atmospheres and even for some cases reducing atmospheres are very advantageous to reduce or eliminate the oxidation layers. Sometimes the atmosphere is used to activate the surfaces, and this can be done not only by reduction but sometimes by some kind of etching or even oxidation. In an embodiment debinding is made in an inert atmosphere. In other embodiment in reducing atmospheres.

In an embodiment debinding is made in a controlled atmosphere. In an embodiment debinding is made in inert atmosphere. In other embodiment debinding is made in reducing atmosphere. In other embodiment debinding is made in a oxidative atmosphere. in an embodiment mechanical strength is applied to the metallic or at least partially metallic component during the debinding. In other embodiment is applied pressure to the component during the debinding, in an embodiment pressure applied is isostatic in other embodiment pressure applied is directed to different parts of the component. In other embodiment debinding is made under vacuum, in other embodiment debinding is made under low pressure conditions.

In an embodiment debinding is a thermal debinding.

In other embodiment debinding is a non-thermal debinding.

In an embodiment the green component shaped from a powder mixture using an AM technique, a Polymer shaping technique, such as MIM, a HIP process, a CIP process, Sinter forging, Sintering and/or any technique suitable for powder conformation and/or any combination thereof among others, is subjected to a post processing treatment comprising a debinding. In an embodiment debinding is a thermal debinding wherein the organic compound is at least partially degraded. In other embodiment debinding is a thermal debinding wherein the organic compound is fully degraded and the PMSRT takes place before full degradation of the organic compound.

In an embodiment at least partial debinding occurs during Heat Treatment.

In an embodiment partial debinding refers to a treatment directed to organic compound degradation wherein the organic compound is not fully degraded.

In An embodiment the partial debinding is a thermal debinding.

In other embodiment the partial debinding is a non-thermal debinding.

In an embodiment a partial thermal debinding is made before Heat Treatment.

In an embodiment a partial non-thermal debinding is made before Heat Treatment.

In an embodiment a partial non-thermal debinding is made before Heat Treatment. and PMSRT occurs during this non-thermal debinding.

In an embodiment when at least partially PMSRT occurs during thermal debinding, the component may be submitted directly to sintering and/or CIP an d/or HIP.

In an embodiment when at least partially PMSRT occurs during non-thermal debinding, the component may be submitted directly to sintering and/or CIP an d/or HIP.

In an embodiment a total degradation of the organic compound is made during thermal debinding is made and PMSRT occurs during thermal debinding

In an embodiment a total degradation of the organic compound is made during non-thermal debinding is made and PMSRT occurs during thermal debinding

In an embodiment a partial non-thermal debinding is made before Heat Treatment.

In an embodiment during debinding a liquid phase is formed.

In an embodiment during debinding a liquid phase from the low melting point alloy is formed.

In an embodiment at least 1% in volume of liquid phase is formed during debinding treatment. In an embodiment at least 2.1% in volume of liquid phase is formed during debinding treatment. In an embodiment at least 3.8% in volume of liquid phase is formed during debinding treatment. In an embodiment at least 5.3% in volume of liquid phase is formed during debinding. In an embodiment at least 8.6% in volume of liquid phase is formed during debinding treatment. In an embodiment at least 8.6% in volume of liquid phase is formed during debinding treatment. In an embodiment at least 12.9% in volume of liquid phase is formed during debinding.

In an embodiment at least 1% in volume of liquid phase is formed during Heat Treatment. In an embodiment at least 2.1% in volume of liquid phase is formed during Heat treatment. In an embodiment at least 3.8% in volume of liquid phase is formed during any Heat Treatment. In an embodiment at least 5.3% in volume of liquid phase is formed during Heat Treatment. In an embodiment at least 8.6% in volume of liquid phase is formed during Heat Treatment. In an embodiment at least 12.9% in volume of liquid phase is formed during Heat Treatment. In an embodiment at least 18.4% in volume of liquid phase is formed during Heat Treatment.

In an embodiment the maximum amount of liquid phase during Heat treatment is below 34%, in other embodiment below 27% in other embodiment below 14% or even in other embodiment below 6%.

In an embodiment at least 1% in volume of liquid phase is formed during Sintering. In an embodiment at least 2.1% in volume of liquid phase is formed during Sintering. In an embodiment at least 3.8% in volume of liquid phase is formed during Sintering. In an embodiment at least 5.3% in volume of liquid phase is formed during Sintering. In an embodiment at least 8.6% in volume of liquid phase is formed during Sintering. In an embodiment at least 12.9% in volume of liquid phase is formed during Sintering. In an embodiment at least 18.4% in volume of liquid phase is formed during Sintering.

In an embodiment the maximum amount of liquid phase during sintering is below 34%, in other embodiment below 27% in other embodiment below 14% or even in other embodiment below 6%.

In an embodiment at least 1% in volume of liquid phase is formed during Sinter forging. In an embodiment at least 2.1% in volume of liquid phase is formed during Sinter forging. In an embodiment at least 3.8% in volume of liquid phase is formed during Sinter forging. In an embodiment at least 5.3% in volume of liquid phase is formed during Sinter forging. In an embodiment at least 8.6% in volume of liquid phase is formed during Sinter forging. In an embodiment at least 12.9% in volume of liquid phase is formed during Sinter forging. In an embodiment at least 18.4% in volume of liquid phase is formed during Sinter forging.

In an embodiment the maximum amount of liquid phase during Sinter forging. is below 34%, in other embodiment below 27% in other embodiment below 14% or even in other embodiment below 6%.

In an embodiment at least 1% in volume of liquid phase is formed during HIP. In an embodiment at least 2.1% in volume of liquid phase is formed during HIP. In an embodiment at least 3.8% in volume of liquid phase is formed during HIP. In an embodiment at least 5.3% in volume of liquid phase is formed during HIP. In an embodiment at least 8.6% in volume of liquid phase is formed during HIP. In an embodiment at least 8.6% in volume of liquid phase is formed during HIP. In an embodiment at least 12.9% in volume of liquid phase is formed during HIP. In an embodiment at least 18.4% in volume of liquid phase is formed during HIP.

In an embodiment the control of the liquid phase during post-processing treatment allows the control the diffusion of at least one element between metallic phases.

In an embodiment during post-processing treatments at least one element from a high melting point alloy difundes into at least one low melting point alloy.

In an embodiment during post-processing treatments at least one element from a low melting point alloy difundes into at least one high melting point alloy.

In an embodiment the control of liquid phase during post-processing treatment allows control in homogeneity of the metallic or at least partially metallic component.

In an embodiment the control of liquid phase during post-processing treatments allows obtain a metallic or at least partially metallic component with low segregation.

In an embodiment the control of liquid phase during post-processing treatment allows obtain a metallic or at least partially metallic component with segregation in different areas of the component.

In an embodiment the control of the liquid phase during post-processing treatment allows control the densification of the metallic or at least partially metallic component.

In an embodiment the control of the liquid phase allows during post-processing treatment control the densification of the metallic or at least partially metallic component.

In an embodiment the control of the liquid phase allows during post-processing treatment allows prevent slumping of the metallic or at least partially metallic component.

In an embodiment the control of the liquid phase allows during post-processing treatment allows control the cavity formations in the metallic or at least partially metallic component.

In an embodiment the control of the liquid phase allows during post-processing treatment avoids excessive post treatment of the metallic or at least partially metallic component.

In an embodiment for a powder mixture, the liquid phase formed may be determined by means of diffusion models so that the temperature and time of the treatment may be determined depending of the liquid phase desired during the treatment.

In an embodiment computer aided design is used to model and simulate the process. In an embodiment computer aid design (cad) is used to select the temperature, time and liquid phase desired during the post-processing treatments.

In an embodiment during debinding a low melting point alloy melts in some amount or strongly diffuse into the metallic powder with the highest volume fraction. In an embodiment during debinding a liquid phase is formed from at least one low melting point alloy in the powder mixture before the polymer is fully degraded.

Moreover the inventor has seen that the way the liquid surrounds the solid particulates considerably affects some properties. Thus for applications where liquid penetration is desirable care has to be taken to assure a dihedral angle below 110°, preferably below 40°, more preferably below 20° or even below 5°. Furthermore it is interesting for some applications to have the diffusion of the low melting point metallic powder with at least one of the high melting point metallic alloys with an associated raise in the melting temperature, so that the liquid phase does not become excessive and thus compromise the shape retention before enough overall diffusion has taken place. In these cases it is desirable to have a melting temperature increase of 60° C. or more, preferably 110° C. or more, more preferably 260° C. or more or even 380° C. or more. In an embodiment the increase of temperature refers to an increase of the melting point of at least one low melting point alloy. Also in this manner the maximum amount of liquid phase at any given stage of the process can be controlled, so that for some instances it can remain below 34%, preferably below 27% more preferably below 14% or even below 6%. In some applications it is desirable to have a mushy behavior of the liquid phase, in such cases it is important to choose an alloy properly in order to have a large melting range (in this document melting range is the difference between the temperature at which the last droplet of the alloy solidifies under equilibrium conditions and the temperature where the first liquid forms under the same conditions). So when mushy state is desirable a melting range of 65° C. or more, preferably 110° C. or more, more preferably 260° C. or more or even 420° C. or more can be desirable. For some applications under very high demands it is also important that the resulting part has very high compromise of mechanical (evnt. electrical and thermal) properties. In this sense the choosing of the different metallic powders has to be made in a compatible way so that the resulting alloy does have the required properties. As an example of such cases it is interesting for some high end applications that the metallic powders diffuse into one another to a high degree, especially when homogeneity is appreciated, and the resulting alloy after the diffusion alloying has the appropriate mechanical properties. In this sense, for the cited applications it is desirable to have less than an 18% variation in a particular element when 2 different control areas are analyzed, preferably less than a 14%, more preferably less than an 8% and even less than a 4%. In this sense, the smaller the control area, the smaller the micro-segregation, so for applications sensible to micro-segregation it is desirable to have a control area of 8000 square micrometers or less, more preferably 800 square micrometers or less, more preferably 80 square micrometers or less or even 8 square micrometers or less. Often Toughness, fracture toughness, ductility and such kind of “toughness in the broad sense” properties are quite susceptible to the presence in considerable amounts of certain alloying elements, and precisely the elements with low melting point or promoting low melting point eutectics with other elements are often contaminants to some of the most relevant higher melting temperature alloys (Ti, Fe, Ni, Co, Mo, W, . . . based alloys) and even to the lower melting point alloys (Cu, Al, Mg, Li, Sn, Zn . . . based). So choosing the proper low melting point powders is not trivial.

In an embodiment a dihedral angle between the liquid phase and the particles of metallic powder with the highest volume fraction is below 110°, in other embodiment below 40°, in other embodiment below 20° or even in other embodiment below 5°.

In an embodiment a dihedral angle between the liquid phase and the particles of the high melting point alloy is below 110°, in other embodiment below 40°, in other embodiment below 20° or even in other embodiment below 5°.

In an embodiment during debinding an increase in the melting point of at least one low melting point alloy is 60° C. or more, in other embodiment 110° C. or more, in other embodiment 260° C. or more or even in other embodiment 380° C. or more.

In an embodiment the maximum amount of liquid phase during debinding is below 34%, in other embodiment below 27% in other embodiment below 14% or even in other embodiment below 6%.

In an embodiment the low melting point alloy has a melting range of 65° C. or more, in other embodiment 110° C. or more, in other embodiment 260° C. or more or even in other embodiment 420° C. or more.

In an embodiment during debinding diffusion between at least one element from the metallic powders takes place. In an embodiment during debinding diffusion of at least one element from the low melting point alloy to the high melting point alloy takes place. In an embodiment during debinding diffusion of at least one element from the high melting point alloy to the low melting point alloy takes place.

In an embodiment when diffusion between the metallic powders takes place a low segregation in the component is produced.

In an embodiment low segregation refers to when there is less than an 18% variation in a particular element when 2 different control areas are analyzed, in other embodiment less than a 14%, in other embodiment less than an 8% and even in other embodiment less than a 4%.

In contrast, in an embodiment it is preferable to have a component with segregation, and in another embodiment having segregation in different areas of the component, in such a way that it may be certain areas of the component where there are no segregation, and other areas of the component with segregation. In an embodiment a component with segregation is obtained. In an embodiment a component with segregation in different areas is obtained.

In an embodiment segregation refers to when there is more than an 18% variation in a particular element when 2 different control areas are analyzed, in other embodiment more than a 24%, in other embodiment more than an 30% and even in other embodiment more than a 34%.

In an embodiment the control area analyzed is of 8000 square micrometers or less, in other embodiment 800 square micrometers or less, in other embodiment 80 square micrometers or less or even in other embodiment 8 square micrometers or less.

In an embodiment segregation refers to a variation of more than 18% in a control area of 8000 square micrometers or less.

Although thermal debinding is often the preferred alternative for the present invention, other debinding systems can be applied like catalytic, wicking, drying, supercritical extraction, organic solvent extraction, water-based solvent extraction, freeze drying, etc. And also combined systems. Sometimes when using liquid phase and a debinding system that does not incorporate thermal decomposition, it is quite interesting to use a metallic phase with a particularly low melting point which can be easily achieved prior to the debinding or while debinding (since many debinding processes can be done at a higher than room temperature). In such cases a metallic phase with a melting point below 190° C., preferably below 130° C., more preferably below 90° C. and even below 45° C. is appreciated.

In an embodiment the debinding is a non-thermal debinding. In an embodiment the non-thermal debinding is selected from catalytic, wicking, drying, supercritical extraction, organic solvent extraction, water-based solvent extraction, and/or freeze drying debinding system among others.

In an embodiment when the fully or at least partially elimination of organic compound is made trough a non thermal debinding the powder mixture used to manufacturing a metallic or at least partially metallic component comprises a low melting point alloy having a melting point below 190° C., in other embodiment below 130° C., in other embodiment below 90° C. and even in other embodiment below 45° C.

In an embodiment a heat treatment to promote diffusion may be done before, after and/or during non thermal debinding to allow the retention of shape thought the metallic phase (PMSRT), in an embodiment this heat treatment is done using a temperature lower than the required temperature for at least partially eliminate the organic compound, in an embodiment this heat treatment to promote diffusion before after and/or during the non thermal debinding, is done at a temperature above 0.3 Tm, in other embodiment above 0.5Tm, and even in other embodiment above 0.7*Tm, wherein Tm refers to the melting temperature of the low melting point alloy comprised in the powder mixture having a melting point below 190° C., in other embodiment below 130° C., in other embodiment below 90° C. and even in other embodiment below 45° C.

In an embodiment the method of the invention is characterized in that the shape retention is made trough the metallic phase before the full degradation of the organic compound. In other embodiment the method of the invention is characterized in that there is a change in shape retention from organic compound to metal phase during debinding. In an embodiment the shape of the component is retained by the metallic phase after debinding. In other embodiment the method of the invention is characterized in that there is a change in shape retention from organic compound to metal phase during partial debinding. In an embodiment the shape of the component is retained by the metallic phase after partial debinding.

In an embodiment partial debinding refers to a post processing treatment wherein less than 90% of the organic compound is degraded, in other embodiment less than 78%, in other embodiment less than 64%, and even in other embodiment less than 52%.

In some cases it might even be permissible to have a combination where the shape retention of the organic material is lost before the diffusion of the metallic components can guarantee the shape retention. In those cases alternative systems to preserve the shape in between have to be used. Such systems can be as trivial as laying a sand or other particulate bed on top of the manufactured pieces before the degradation of the organic compound, and removing this sand or bed once the shape retention trough metallic particulates is guarantee (to any extent of diffusion, from only shape retention to full diffusion). Such alternatives are sometimes interesting when very fast AM systems are used (like those described in this document: DLP or other “continuous printing” system on photo-curable resins, projection methods, ink-jets, . . . ) especially when some special cost issues arise.

In an embodiment in the method of the invention, during post-processing treatments, systems to preserve the shape are used. In an embodiment in the method of the invention, systems to preserve the shape are used before degradation of the organic compound to retain the shape of the component during post-processing treatments. In an embodiment the systems to preserve the shape consist on laying a sand or other particulate bed on top of the component.

This procedure allows to choose the possible alloys to act as diffusion enhancers and shape retention helpers in the implementations of the present invention requiring such performances. Choosing one alloy from all the possible ones can follow through various criteria, amongst others: control of the amounts of liquid phase during the whole process, ease of diffusion with the main metallic particles, cost of manufacturing, environmental friendliness, ease of handling, final mechanical properties after conclusion of diffusion, final thermal/electrical/magnetic properties.

In an embodiment the composition of the low melting point alloy used in the powder mixture for manufacturing a metallic or at least metallic component by shaping this powder mixture optionally containing an organic compound using an AM technique, a Polymer shaping technique, such as MIM, a HIP process, a CIP process, Sinter forging, Sintering and/or any technique suitable for powder conformation and/or any combination thereof among others, is selected based on the amount of liquid phase, diffusion between at least one element from different metallic powders, final mechanical, chemical and/or physical properties desired in the final component.

In an embodiment low melting point alloy is selected to form at least 1% of liquid phase, in other embodiment at least 3%, in other embodiment at least 5%, and even in other embodiment at least 10% before fully degradation of the organic compound.

In an embodiment liquid phase volume is measured

The incorporation or diffusion of the liquid into the main metallic constituents or vice-versa can also be capitalized to control the dimensional changes associated to the diffusion treatment, when properly choosing the alloy systems to be employed (expansion through alloying counteracting contraction due to densification).

In an embodiment the liquid phase is used to control the dimensional changes of the component.

When a liquid phase forms within at least one of the metallic constituents, depending on the wettability of the other metallic phases by this liquid, coercive capillarity forces can form that can contribute to the densification. For some applications requiring high apparent densities it can be beneficial to have a liquid phase with a high wettability to main metallic phase. When that is the case it is desirable to have a wetting angle smaller than 80°, preferably smaller than 48°, more preferably smaller than 34° and even smaller than 18°. Also as widely explained in this document when the main powder is soluble in the liquid this can be capitalized to control the amount of the liquid phase at all times.

In an embodiment it is beneficial the increase of the wetting angle between liquid phase and the metallic phase for obtaining higher tap densities in the component. In an embodiment, a flux agent may be added to the powder mixture to increase wettability. This flux agent, comprising a chemical agent, may be added to the powder mixture in the form of a solid or liquid before or during the process involving wettability, this means during the presence of liquid phase in the post-processing treatment of the component. In a particular embodiment the flux may be mixed with the metallic powders or applied as a separate layer. Fluxes can increase wettability by means of several effects. In some embodiments, fluxes provide a cleaning action during melting by reacting with oxides of the metals and other contaminants such as sulfur and phosphorus among others. In some embodiments, fluxes may act as a shield from the atmosphere. In other embodiments, the flux material might promote a better control of temperature during the processes involving any source of heating. In some other embodiments, the flux may compensate the loss of volatized elements during processing or to contribute with other elements. All the above mention processes influence the solid-liquid interface tension surface energy and therefore favor wettability during processing. In an embodiment fluxes are inorganic, organic, and rosin fluxes. In an embodiment Inorganic fluxes comprise inorganic acids and salts such as hydrochloric acid, hydrofluoric acid, stannous chloride, sodium or potassium fluoride, and zinc chloride, among others. In an embodiment organic fluxes are organic acids with or without the use of halides as activators. In an embodiment rosin fluxes are glassy solids made from a mixture of organic acids (resin acids, mainly abietic acid, with pimaric acid, isopimaric acid, neoabietic acid, dihydroabietic acid, and dehydroabietic acid).

In an embodiment a flux is added to the powder mixture and/or is applied as a separate layer during the shaping of the component to favor wettability during post processing treatment.

In an embodiment a flux is added to the powder mixture and/or is applied as a separate layer during the shaping of the component to have a wetting angle smaller than 80°, in other embodiment smaller than 48°, in other embodiment smaller than 34° and even in other embodiment than 18° between the liquid phase from the low melting point metallic alloy and the metallic particles of the high melting point alloy during the post processing treatments

In an embodiment a flux is added to the powder mixture to have a wetting angle smaller than 80°, in other embodiment smaller than 48°, in other embodiment smaller than 34° and even in other embodiment than 18° between the liquid phase and the metallic particles.

In an embodiment at least 0.1% by weight of fluxes is added to the powder mixture and/or during the shaping of the component.

In an embodiment at least 1.2% by weight of fluxes is added to the powder mixture and/or during the shaping of the component.

In an embodiment at least 1.7% by weight of fluxes is added to the powder mixture and/or during the shaping of the component

In an embodiment the invention refers to a method of manufacturing a metallic or at least partially metallic component shaping a powder mixture comprising at least two metallic powders with different melting point and optionally and organic compound characterized in that a flux is added to the powder mixture to have a wetting angle smaller than 80°, in other embodiment smaller than 48°, in other embodiment smaller than 34° and even in other embodiment than 18° between the liquid phase from the low melting point metallic alloy and the metallic particles of the high melting point alloy during the post processing treatments. In an embodiment, this main constituent is a high melting point alloy.

The inventor has been able to observe the surprising beneficial effect to homogeneity of properties, and lack of micro-segregation, when the alloy that produces a liquid phase is occupying a particular site on a close compact structure of other mainly metallic particles in the feedstock. Even more so when they are wholly occupying the octahedral or tetrahedral holes or are at least close to a round fraction like ½, ⅓ or ¼. By close to a round fraction is understood a difference of +/−10% or less, preferably +/−8% or less, more preferably +/−4% or less and even +/−2% or less. In other embodiments micro-segregation in specific areas of the component may be advantageous, for these applications a packing far away from close packing may be preferred.

In an embodiment the metallic powder alloy which produces the liquid phase is occupying the tetrahedral and/or octahedral voids between the particles of the main powder. In an embodiment the main powder is a high melting point alloy. In another embodiment the metallic powder which produces the liquid phase is a low melting point alloy.

The incorporation or diffusion of the liquid into the main metallic constituents or vice-versa can also be capitalized to control the dimensional changes associated to the diffusion treatment, when properly choosing the alloy systems to be employed (expansion through alloying counteracting contraction due to densification).

The inventor has seen that most mechanical properties benefit from a high volume fraction of metallic constituents in the feedstock, but on the other hand in some applications where the feedstock is made to flow the viscosity might negatively be affected by an excessive volume fraction of metallic constituents in the feedstock. In the same way some AM technologies are easier to implement with somewhat less charged feedstock, since a minimum quantity of the functional for the shaping process organic compound is required. So when mechanical properties or density amongst others are the priority, it is desirable to have at least 42% volume fraction of non-organic constituents, preferably 56% or more, more preferably 68% or more and even 76% or more. If inorganic charges and ceramic reinforcements are not looked upon, then in this case it is often desirable to have at least 36% volume fraction of metallic constituents in the feedstock, preferably 52% or more, more preferably 62% or more or even 75% or more. Also the amount of high melting point metallic constituents within the metallic constituents is quite significant for some applications, too high poses difficulties for the consolidation while too low might induce excessive deformation amongst others. In this sense often a volume fraction of high melting point metallic constituents higher than 32% of all metallic constituents, preferably higher than 52%, more preferably higher than 72%, and even higher than 92% can be desirable for applications where long diffusion treatments are acceptable. On the other side volume fraction of high melting point metallic constituents lower than 94% of all metallic constituents, preferably lower than 88%, more preferably lower than 77%, and even lower than 68% can be desirable for economic reasons, especially in view of a faster consolidation.

In an embodiment when a powder mixture comprising at least a low melting point alloy in powder form and a high melting point alloy in powder form and optionally an organic compound, in an embodiment the volume fraction of the high melting point metallic powders is higher than 52%, in other embodiment higher than 72%, and even in other embodiment higher than 92% with respect to the metallic phase (the sum of all metallic components of the powder mixture).

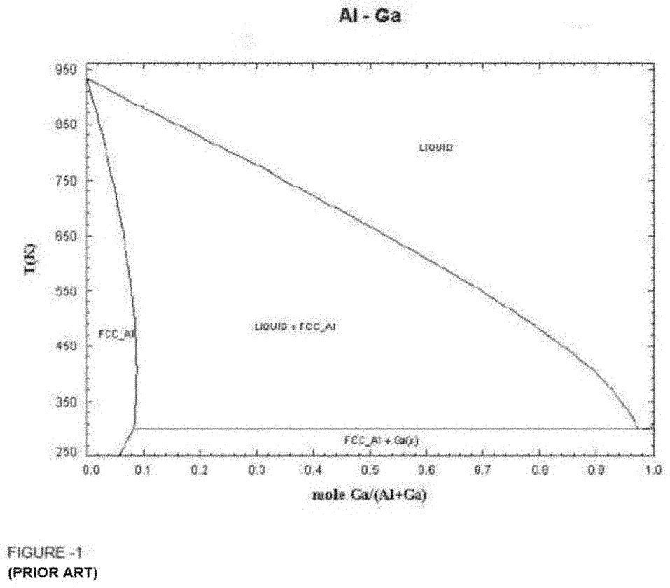

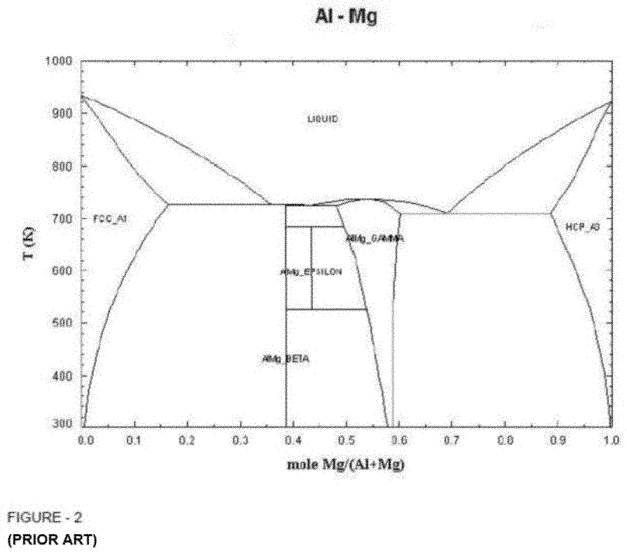

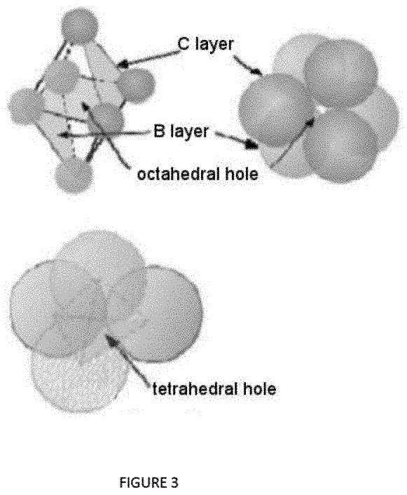

As an example in the case of Ti-base alloys, most alloys having a low melting point include elements which are reportedly causing embrittlement (Bi, Cd, Pb, . . . ). For some alloys Sn is a good candidate since it is an alloying element. Unfortunately one of the mostly used Ti alloys, grade 5, does not have Sn as an alloying element. In this case the author has seen that a part of the % Al can be successfully replaced with % Ga without a detrimental effect on the properties, in some cases even with a slight improvement. This is quite convenient since GaAl alloys with a % Ga between 20% and 99.2% in weight present a quite extended melting range, starting at around 30° C. (what would be named melting point in this document) and finishing at a considerably higher temperature that depends on the actual composition but can even exceed 600° C.—as can be seen in FIG. 1—. For applications where 30° C. as a temperature where the first liquid appears is too low, a bit lower % Ga in weight raises the melting temperature quite sharply (alternatively alloying the GaAl alloy with a third or further elements can also be used to set the melting temperature at the level desired). Moreover Diffusion of Ti into this alloys causes melting point to raise and even raise quite sharply if the proper measures are taken. This allows to raise the temperature until the desired sintering or hot isostatic pressing (HIP) desired temperature without risking shape retention. Then during the sintering, HIP or any other process involving a high temperature (often above 0.36*Tm, preferably above 0.52*Tm, more preferably above 0.62*Tm and even above 0.82*Tm) not only densification is achieved but also solid state alloying takes place trough diffusion. The smaller the particle size of the powders employed the faster the diffusion will be completed. For some applications not a very high level of completeness of the diffusion process is necessary since in-homogeneities can be accepted to a certain level, and as reported in the following paragraphs it can be beneficial in certain cases. One possible way to evaluate such in-homogeneities is by the difference of concentration of a particular element, but avoiding to account for singularities like contamination. A compositional mapping can be made with EDX or similar technique and look for significant segregation. Significant implies that both areas, the one with high concentration and the one with low concentration are big enough in terms of surface fraction when a representative amount of total area of the component is evaluated, and also that the areas are large enough in terms of equivalent diameter to avoid the counting of carbides, intermetallic precipitates, . . . . In this sense, an area can often be considered to be large enough when it represents at least a 1% surface fraction, preferably at least a 2.2%, more preferably at least a 4.2%, and even at least a 6%. In terms of equivalent diameter (diameter of the circle with the same total area) is often desirable to be 16 square micrometers or bigger, preferably 42 square micrometers or bigger, more preferably 62 square micrometers or bigger or even 115 square micrometers or bigger. Then significant differences in at least one relevant element (relevant in the sense of having an effect on the desired property) often in the range of 3% in weight or more, preferably 6% or more, more preferably 22% or more and even 54% or more. Differences relate to the relative difference in content between the two, so the larger divided by the smaller in percent.

The initial conditions and steps required to attain full density in the final product are quite stringent and thus costly. The flexibility, and therefore also possibilities for cost reduction, is much higher if some porosity can be accepted in the final component. Also the more random the porosity can be the further the flexibility. Unfortunately the mechanical properties associated to toughness (like fracture toughness, resilience, elongation at fracture, . . . ) and also the thermal and electrical properties amongst others tend to decay when porosity is present. For many applications the drop in mechanical properties is quite critical. The inventor has seen that there are several ways to mitigate this effect, and thus make the correlation between porosity volume fraction and lack of toughness related mechanical properties far less disadvantageous, surprisingly enough some of this approaches are specially effective for low porosity volume fractions where the differential of the property loss is often the highest. Two of these such approaches consist on the controlling of the fracture toughness of the material around the pores and on the provision of a material which stops a possible nucleated crack by plastic deformation at the crack tip or by changing the stress field at the crack tip and making it more compressive. For this purpose the inventor has seen that for some applications it is desirable to have an overall fracture toughness of 23 MPa*m½ or more, preferably 44 MPa*m½ or more, more preferably 72 MPa*m½ or more and even 122 MPa*m½ or more. It has been observed that for some cases what should be controlled is not the overall fracture toughness, but rather that of the dominant phase around the porosities (from all phases sharing a surface with porosity the one that has highest amount of surface shared with porosity). In such cases it is often desirable to have a fracture toughness in the dominant phase around the porosities of 26 MPa*m½ or more, preferably 51 MPa*m½ or more, more preferably 105 MPa*m½ or more and even 152 MPa*m½ or more. When trying to stop a potentially nucleated crack emanating from a porosity, one possible way to proceed is to procure a low yield strength and preferably also high elongation phase surrounding the porosity or at least in the critical areas of the porosity (when not spherical, the triple points or any other singularity that can act as a stress concentrator). In this sense, for some applications it is desirable to have a phase with a yield stress of 780 MPa or less yield stress, preferably 480 MPa or less, more preferably 280 MPa or less and even 85 MPa or less surrounding the porosity. This realization often implies quite remarkable inhomogeneity within the material, which are not always desirable. One possible way to achieve such effect is by providing a material with a rather low yield strength even after certain amount of diffusion, sufficient to provide shape retention, in the octahedral or tetrahedral sites, and then stop the diffusion treatment at a point where this alloy still has such low yield strength. In such cases having such a low yield strength alloy present a liquid phase during the process which on top has high wettability helps the distribution of such alloy around the porosity. The shape of the porosity itself can be affected by wetting angle when a liquid metallic phase is present in the process. Furthermore, as commented above, it is possible in some cases to follow a strategy oriented to make the stress field ahead of any emanating crack as compressive as possible. Amongst others a possible way to implement this strategy is to have a phase surrounding the porosity which is capable to have a stress induced phase transformation. It is particularly convenient when the phase transformation has an induced volume expansion, like is often the case when going from a close pack structure to one that is not (for example austenite to martensite). One example on how to illustrate how to follow such strategy can be found in Fe base alloys containing carbon and where a martensitic or bainitic structure can be expected at room temperature and where the material intended for the octahedral or tetrahedral holes has a high manganese content. If diffusion is incomplete and areas with sufficiently high % Mn remain around the pores, they are prone to remain as retained austenite with capability to transform to martensite or bainite when the proper stress field approaches them. If the stress field in question is that of a crack tip, this stress field can be affected by the transformation due to the associated volume change.

Fracture toughness is an indication of the amount of stress required to propagate a preexisting flaw that can appear as cracks, voids, metallurgical inclusions, weld defects, design discontinuities, or some combination thereof. A parameter called the stress-intensity factor, K is used to determine the fracture toughness. The fracture toughness Kic is the critical value of the stress intensity factor at a crack tip needed to produce catastrophic failure under simple uniaxial loading and can measured according to ASTM E399 standard. This test method involves testing of notched specimens that have been precracked in fatigue by loading either in tension or three-point bending.

In an embodiment the metallic or at least partially metallic component has a fracture toughness (Kic) of 23 MPa*m½ or more, in other embodiment 44 MPa*m½ or more, in other embodiment 72 MPa*m½ or more and even in other embodiment 122 MPa*m½ or more.

The inventor has seen that in the previous presented case and in many others, when the low melting point phases are intended to have their melting point raise to prevent excessive liquid phase, this can be seen in terms of melting temperature raise trough the phase diagram or in terms of percentage of the element causing the raise in the melting point entering in solution. In terms of melting temperature raise for several applications where shape retention could be compromised and depending on the particular alloys systems, a raise of 120° C. or more can be desirable, preferably 220° C. or more, more desirable 440° C. or more, and even 640° C. or more. For some systems lower values are also acceptable and even desirable. In terms of percentage of element entering into solution in the low melting point alloy, for some applications it is desirable to have a 2% or more, preferably 4% or more, even more preferably 12% or more, and even 22% or more. In the past example this could be % Ti entering the GaAl alloy.

In an embodiment there is diffusion between the high melting point alloy and the low melting point alloy.

In an embodiment diffusion of at least one element between different metallic powders is a solid/solid and/or solid/liquid diffusion.

In an embodiment 2% or more of at least one element from a high melting point alloy enters in solution into the low melting point alloy, in other embodiment 4% or more, in other embodiment 12% or more, and even in other embodiment 22% or more

In the cases that % Ga is used, the final weight percent present as a mean in the component (since for some applications in-homogeneities are unavoidable, acceptable or even desirable) will be different depending on the application. For some applications, especially also when the main metallic element present has a high melting point (more than 900° C.), it is often desirable to have 1% in weight or more, preferably 2% or more, more preferably 6% or more, and even 12% or more. On some other cases, and especially when the main metallic element present has a low melting point, it is often desirable to have 2% in weight or more, preferably 4% in weight or more, more preferably 8% or more and even 24% or more.

In an embodiment when the low melting point alloy comprises Ga, the weight percent of gallium in the final metallic or at least partially metallic component is 1% by weight or more, in other embodiment 2% or more, in other embodiment 6% or more, and even in other embodiment 12% or more. In other embodiment, the weight percent of gallium in the final metallic or at least partially metallic component is 2% by weight or more, in other embodiment 4% in weight or more, in other embodiment 8% or more and even in other embodiment 24% or more.

One particular advantage of some instances of the present invention, is that the manufactured parts can have a controlled porosity and rugosity, due to the possibility to select the volume fraction of metallic constituents in the feedstock, the amount of liquid phase during the debinding and diffusion intensive treatment, and the possibility to interrupt the diffusion treatment at any stage. This is particularly convenient for applications where interconnected porosity is desirable, for example in membranes, filters, selective lids or tools that allow gases but not liquids get through, etc. Needless to say when liquid infiltration is applied, the control over the interconnected porosity is very convenient. Also the control over the surface rugosity is interesting for applications requiring a determined friction coefficient, also when some kind of coating or paint is to be applied in order to have the proper anchoring points, applications that need lubricant reservoirs in the surface, or a surface rugosity that favors hydrodynamic lubrication, amongst many others. In fact the case of selective lids and tools that allow gases to get through but not polymers or even liquids deserve a special mention, since the solutions existing for those applications often have a complex shapes which are difficult to attain with conventional methods given the tendency of the pores to close on the surface when conventional machining techniques are applied. With the method of the present invention, by controlling the metallic volume fraction in the feedstock and the amount of diffusion during the post-processing a controlled porosity can be attained with a great flexibility in the geometry that can be accomplished. For the applications where only a gas should be evacuated often an interconnected porosity of a 4% in volume or more, preferably 8% or more, more preferably 12% or more or even 17% or more are employed. In the case of metal infiltration higher volume fractions of interconnected porosity are employed generally above 32% in volume, preferably above 46%, more preferably above 56% or even above 66%. This interconnected porosity, or at least most of it, is the one filled by the liquid metal during metal infiltration.

In an embodiment porosity is the ratio, usually expressed as a percentage, of the total volume of voids of a given porous medium to the total volume of the porous medium (ASTM).

In an embodiment the component is infiltrated with a metal during the post-processing treatment.

In an embodiment interconnected porosity is controlled by the selection of the volume fraction of metallic constituents in the powder mixture. In an embodiment interconnected porosity is controlled by the control of liquid phase amount during the debinding. In other embodiment interconnected porosity is controlled by the diffusion treatments applied during post-processing.

In an

In an embodiment the interconnected porosity of the metallic or at least partially metallic component is 4% in volume or more, in other embodiment 8% or more, in other embodiment 12% or more or even in other embodiment 17% or more are employed. In other embodiment when there is metal infiltration the interconnected porosity of the metallic or at least partially metallic component is above 32% in volume, in other embodiment above 46%, in other embodiment above 56% or even in other embodiment above 66%.

The inventor has seen that the method of the current invention, besides the commented economic advantages, for several instances solves two of the major technical problems associated with the manufacturing of large metallic components trough additive manufacturing. The additive manufacturing methods for the manufacturing of metallic objects, can be divided in two groups for the purpose of clarifying this point: methods based on direct melting and/or sintering of the metal and thus not necessarily requiring a sintering step after the AM, and methods based on the binding trough an adhesive and thus requiring a sintering step after the AM. The systems belonging to the first group tend to have trouble with the thermal stresses generated through the sudden increase and decrease of temperature of the molten zone due to the thermal gradient with respect to the unprocessed powder and the already partly manufactured component, which often leads to wrapping when trying to manufacture complex large shapes. The methods based on the ink-jetting or other way to temporarily joint the metal powder with an organic binder or glue, suffer from the same short-comings as MIM technique and thus are limited to small pieces or have to be sintered in a complex way in a sand bed to assure shape retention, which makes the method overly expensive and often impracticable for certain large complex geometries.

For some applications, especially when the accuracy required is not excessive, the inventor has seen that is very recommendable for geometries needing build-up to use a powder projection system. In this case the powder is projected in the areas where build up is desired, and generation of the body of the manufactured piece proceeds through the plastic deformation of the particulates due to the impact. The binding force at this stage strongly depends on the momentum at the impact so projection speed is quite determinant, as is deformability of the projected particulates, which can be increased by raising their temperature at the moment of the impact (pre-heating them before projection, projecting with warm/hot air, . . . another further solution consists on having a much smaller binding force of the particulates to the surface which is being generated, but then use a stronger binding source. An example of such case is the usage of small kinetic energy projection, or polarization of the powder and the sticking of it to the generated surface trough electrostatic binding, then curing the powder with a stronger binding in the interesting areas (chemical, UV, . . . ) and finally removing the powder which has not been strongly bond with compressed air, sudden manufactured piece polarity change, . . . . For some applications requiring high density of the metallic green body, it is interesting to have quite some plastification during positioning of the powder before the secondary curing or binding takes place.

One shortcoming when it comes to the economics of most AM processes for polymers is related to the need for high mechanical properties in the manufactured pieces which poses limitations in the usable polymers and the maximum deposition speeds attainable. For many instances of the present invention the polymer only has mainly a shape retention function and thus much lower mechanical properties are acceptable, allowing for faster deposition systems. Also for some systems the limitation comes from the poor thermal conductivity of most polymers, making the thermal management critical. The particulates of the present invention have generally a considerably higher thermal conductivity due to the high metallic content.

The inventor has seen that an advantageous application of the present invention for several applications, is achieved when the resulting alloy after the diffusion processes are concluded does not suffer a detrimental embrittlement. The way to evaluate whether the resulting alloy suffers detrimental embrittlement in the present document is the following.

The closest alloy without the elements that drive down the melting point is chosen. That is the final nominal resulting alloy (its composition experimentally measured or simulated) is taken. For some applications there is no need for a very homogeneous composition, in this case also the nominal composition is taken, which is the theoretical or experimentally measured average.

The nominal alloy is the nominal composition with the same microstructure of the resulting alloy, so if any heat treatment should be applied to replicate what happens to the produced pieces it is done.

Samples of the nominal alloy are prepared to measure the fracture toughness according to ASTM E399, mechanical strength and elongation according to EN ISO 6892-1 B:2010 and resilience according to EN ISO 148-1.

Then the nominal composition is stripped of the doping elements (the doping elements are those which have a low melting point or tend to form euthectics with a low melting point: Bi, Cd, Ga, Pb, Sn . . . ) A literature search is performed to find the closest composition and heat treatment (from all alloys within a 10% variation in mechanical strength [whatever heat treatment they might need to undergo, and choosing the heat treatment that delivers the highest elongation if more than one is possible], the alloys that can be considered only if no element, other than the striped doping elements, has a variation of more than a 15% with respect to the nominal composition, and the addition of the variation of all elements does not exceed a 40%) it is then named the comparable alloy.

Then samples are prepared from the comparable alloy to measure the fracture toughness according to ASTM E399, mechanical strength and elongation according to EN ISO 6892-1 B:2010 and resilience according to EN ISO 148-1.

The percent loss in elongation, fracture toughness and resilience are evaluated as the loss from the nominal composition in contrast to the comparable alloy.

The embrittlement is the maximum percent loss of the three.

In many applications an embrittlement of a 48% or less should be implemented, preferably 38% or less, more preferably 24% or less and even 8% or less.

In an embodiment the final metallic or at least partially metallic component has an embrittlement of a 48% or less, in other embodiment 38% or less, in other embodiment 24% or less and even in other embodiment 8% or less.

This procedure allows to choose the possible alloys to act as diffusion enhancers and shape retention helpers in the implementations of the present invention requiring such performances. Choosing one alloy from all the possible ones can follow through various criteria, amongst others: control of the amounts of liquid phase during the whole process, ease of diffusion with the main metallic particles, cost of manufacturing, environmental friendliness, ease of handling, final mechanical properties after conclusion of diffusion, final thermal/electrical/magnetic properties . . . .

Elsewhere in this document the example of a Ti, an Al, a Mg and a Fe base alloy are provided. As an example short example here, Ni base alloys can be chosen. Several Ni base alloys rely on the precipitation hardening strengthening strategy. Aluminum is one precipitate forming element with Ni which is often employed. Aluminum has a considerably lower melting point than Ni, and solid diffusion of Al into Ni is quite fast if the proper conditions are provided. Al can also be alloyed with Ga amongst others to further reduce the melting point.

For some metallic powders with a lower melting point or enhanced diffusion, it is possible to implement the following invention with just one metallic phase, or with several phases but with small differences in the melting point. That is so because then the shape retention can be attained directly with the main powder. If very long diffusion times are possible then this can be implemented with phases where melting starts at a temperature below 1080° C., preferably below 980° C., more preferably below 880° C. and even below 790° C. When the temperatures are high then shape retention on the side of the polymer has to be maintained to high temperatures, posing restrictions in the side of at least one of the organic compounds chosen. In this case the polymeric matrix cannot be fully degraded on its shape retention function below 310° C., preferably not below 360° C., more preferably not below 410° C. and even not below 460° C. If less constraining requirements on the shape retention of the organic compound are desired then the temperature at which melting starts is often chosen to be below 740° C., preferably below 690° C., more preferably below 640° C., more preferably below 590° C. and even below 540° C. In some applications it is strongly desired that at least one of the metallic phases starts to melt before the loss of shape retention from the side of the polymer, in this case it can only be implemented with one metallic phase or several metallic phases but with similar melting points when the melting starts at a considerably lower temperature normally below 490° C., preferably below 440° C., more preferably below 390° C. and even below 340° C.

In an embodiment the invention refers to a method for manufacturing a metallic or at least partially metallic component, wherein a powder mixture comprising one metallic powder or more than one metallic powders with similar melting point is shaped using an AM technique, a Polymer shaping technique, such as MIM, a HIP process, a CIP process, Sinter forging, Sintering and/or any technique suitable for powder conformation and/or any combination thereof among others.

In an embodiment the invention refers to a method for manufacturing a metallic or at least partially metallic component, wherein a powder mixture comprising one metallic powder or more than one metallic powders with similar melting point using an AM technique, a Polymer shaping technique, such as MIM, a HIP process, a CIP process, Sinter forging, Sintering and/or any technique suitable for powder conformation and/or any combination thereof among others. In an embodiment the metal shape retention (MSRT) is attained directly with the metallic phase. In an embodiment the powder mixture have a melting point below 1080° C., in an embodiment below 980° C., in an embodiment below 880° C. and even in an embodiment below 790° C.

As an example the cases of two low melting point alloys will be somewhat further developed for illustrative purposes. The lower melting point metals chosen are Aluminum and Magnesium. Pure Aluminum has a melting point 660° C., which means that at roughly 195° C. diffusion can be considered effective enough fora diffusion treatment (even at lower temperatures if very long times are affordable). Shape retention to 200° C. trough the polymeric matrix is not difficult to attain. Nonetheless to attain shape retention trough the metallic phase in such a case demands quite high metallic phase volume fraction in the feedstock and long diffusion treatment times. With some well-chosen polymeric systems, some shape retention can be held to even over 400° C. and exceptionally over 500° C. This means that the translation from the polymer shape retention to the metallic shape retention can be made at even above 0.7Tm which is already reasonable, but still demands long treatment times and quite high metal volume fractions. To increase the flexibility and reduce the cost of the polymer to metal shape retention translation treatment (PMSRT) it is convenient to use alloys with improved diffusion or even with some amount of liquid phase during the PMSRT. Moreover in most industrial applications and specially those related to the transport vehicles (automobile, aeronautic, marine, train . . . ) do not use pure aluminum but rather alloys with better mechanical properties. Other industries are rather interested in the improvement of the physical properties (thermal, electrical, wettability, melting . . . ) but in any case mostly alloys of Aluminum rather than pure aluminum. So a complex process for the choosing of the aluminum alloy to be used in the present invention initiates. Basically the desired mechanical or physical properties are priorized, but care is taken about the steps in the present invention, especially also the PMSRT and thus when more than one alloying strategy is possible that favouring diffusion at lower temperatures or even the presence of a liquid phase are chosen. Also the possibility of a small sacrifice on the desired properties in trade of an improvement of the diffusion and/or liquid phase presence should always be considered. In general, some alloying elements are rather diffusion-retardants in aluminum like for example molybdenum, zirconium . . . while others are diffusion-enhancers like magnesium, tin . . . . Several commercial alloys are alloyed with Sn and Mg and present enhanced diffusion, some somewhat more experimental alloys with higher Mg contents and without diffusion retardants are encountered. The inventor has seen that the addition of gallium, tin, sodium, potassium or any other element whose binary phase diagram with aluminum presents any kind of liquid phase at low alloying contents and low temperatures is susceptible to enhance diffusivity and the formation of a liquid phase at lower temperatures when added to most aluminum alloys. In this sense low alloying in the binary phase diagram is meant by 38% or less atomic percent, preferably 18% or less, more preferably 8% or less, or even 2% or less. In some instances of the present invention it is more advantageous to make a weight percent evaluation of low alloying in the binary phase diagram in which case it would mean 46% or less weight percent, preferably 38% or less, more preferably 18% or less and even 8% or less. Also in this sense, low temperatures in the binary phase diagram for the presence of some kind of liquid phase refers to temperatures below 380° C., preferably below 290° C., more preferably below 240° C., more preferably below 190° C. or even below 80° C. One potential problem arises when one of the desired properties is creep resistance, since then it is rather convenient to retard diffusion which difficult the implementation of the present invention by raising the cost. But even in such cases solutions can be found, by making diffusion easier during the conformation and the PMSRT treatment yet have diffusion rather impeded at least at the end of the processing, even if an additional step is required. As an illustration of such a process: Mg is a diffusion enhancer as previously discussed and can have a noticeable effect on lowering the melting point of Al as can be seen in the phase diagram of FIGURE-2, specially with contents of 12% atomic or higher, where a liquid phase starts to form at around 450° C. Silicon also promotes diffusion in Aluminum, but a bit less. An aluminum alloy with Mg and Si in solid solution can have a quite lower melting start point and also enhanced diffusion, but if the conditions are provided for Mg and Si to form the Mg2Si phase, the effect can be reversed and the alloy can present a very good creep behavior.

So in the case of Aluminum and its alloys the present invention can be applied with two or more metallic phases where at least two of them present a significant difference in the melting point, but it can also be applied with just one metallic phase or a plurality of metallic phases but with similar melting temperatures. The route selected will depend on the piece to be manufactured. In this document the melting point of an alloy refers to the temperature at which the first liquid is formed. In the case of aluminum and its alloys a significant difference in the melting point is 60° C. or more, preferably 120° C. or more, more preferably 170° C. or more or even 240° C. or more. In the first case it will often make sense to use some or all of the possible advantageous solutions presented in this document for other alloy systems, like selection of sizes for a closer compacting of the metal to attain big volume fractions and good distribution, selection of the composition of the low melting point phase or phases so that their melting temperature can be raised during the PMSRT as a result of the ongoing diffusion, for a better control of the volume fraction of the liquid phase present (in the cases that liquid phase is desired) . . . but also a single metal phase or several but without significant differences in the melting point can be chosen, provided the PMSRT treatment is adapted to the diffusion ability of the metal phase/phases chosen and their “green” compaction (liquid phase is also possible depending on the polymer and the alloy chosen). As an example if one choses an alloy with roughly 8% (atomic) Ga in solid solution, the melting starts below 100° C. One can have only this metallic phase, and the PMSRT is quite easy to adjust and there is a vast possible selection for the polymeric part of the feedstock, but an 8 atomic % Ga strongly affects the cost of the alloy and poses some relevant constraints on the attainable properties. Alternatively, one can have an Al alloy with the desired properties made of quite spherical powder for a good compactation, and fill half of the octahedral holes with the 8 atomic % Ga alloy (providing it also as rather spherical powder or 0.4 times the diameter of the Al alloy powder. In this case the total weight amount of % Ga is roughly 0.5% with the obvious effect on alloying cost and flexibility on the properties, where many existing alloys can slightly be accommodated to contain 0.5% Ga but it is much more difficult with roughly 16% (8% atomic). In the case of the 8 atomic % Ga alloy only in half of the octahedral holes, PMSRT can be adapted to have a desired amount of liquid phase during polymer degradation given that the diffusion with the Al alloy bigger metallic particles dilutes the % Ga which translates into a quite sharp increase in the melting point of the Aluminum Gallium alloy. So properly choosing polymer (temperature at which it has to be degraded), particle size (diffusion path) treatment temperatures and ramp and holding times the amount of liquid phase is controlled (composition evolves in a determined manner). Another example could be made with an Aluminum alloy with 15 to 30 atomic % Mg, depending on the amount of liquid phase desired at a given point of the diffusion heat treatment. Melting point in this case is slightly over 430° C. This alloy has also quite enhanced diffusion. Again it can be used as main alloy with the associated limitations, given that Mg is a common alloying element for Aluminum alloys (5xxx and 6xxx series) but usually with lower weight percent. If used as described before, but this time covering all the octahedral holes, the effective Mg alloying coming from the low melting point powder is roughly between a 1-2% in weight which is more in the line of the existing aluminum alloys (the rest of % Mg, in case more is desired, and the other elements can be alloyed in the main metallic particulates). Probably the present invention is even more interesting for alloys presenting little formability, because with the present invention complex shapes can be attained regardless of the formability of the material employed, thus the higher 7xxx series and other experimental alloys with some interesting values of relevant properties but rather limited formability benefit even stronger from the present invention, but the invention is not restricted to any particular alloy in general terms, just for certain applications (this extends to all metals, not only aluminum alloys). For Aluminum alloys the less common method without polymer can also be employed in some cases.

In general most of what has been said about aluminum alloys in the preceding paragraphs applies to magnesium alloys, with the proper adapting. Given that Aluminum is one of the most employed alloying elements, one such case can be used as an example. An alloy with a 12-30% atomic percent aluminum will have a melting point (in the sense of the present invention) of somewhat above 400° C. This can be employed as only metallic constituent if so desired, but liquid phase before polymer degradation requires a fine choosing of the polymer constituents, and solid diffusion alone, often requires somewhat greater metal volume fractions and time. If used as an octahedral holes filling powder the overall % Al contribution coming from the intensified diffusion powder is considerably smaller (less than a 4% in weight). As in the rest of the document where octahedral holes were chosen as an illustrative example, tetrahedral holes could have been chosen instead, as well as substitution of main locations, etc. even if not specifically mentioned for the sake of extension of the present document. Again for the sake of limiting the extension of the present document there is no need to repeat all what has been said for any other group of alloys or for metals in general: like extra advantage of applying the method to limited formability alloys, the validity of the method or at least part of it for practically all alloys, . . . . Again for magnesium alloys and some specific applications the method without polymer can be employed, as is the case for most other alloys.

The evaluation of the temperature at which shape retention is fully degraded is evaluated with a simple thermogravimetric experiment.

In an embodiment polymer to metal shape retention (PMSRT) is a phenomena characterized in that the shape retention of the green component is translated from the organic compound to the metallic phase.

In an embodiment PMSRT is characterized in that the shape retention is translated from the organic material to the metallic phase.

In an embodiment PMSRT is reached before reaching the sintering temperature.

In an embodiment PMSRT is reached before the fully degradation of the organic compound. In an embodiment the shape of the brown component is retained by the metallic phase. In an embodiment the shape of the component is retained by the metallic phase before sintering and/or sinter forging and/or HIP and/or CIP post-processing.

In an embodiment the fully degradation of the organic compound may determined with a thermo-gravimetric experiment.

When it comes to PMSRT, the inventor has seen that for many applications, the initial tap density of the metallic powder or particulates play an important role on the maximum density, eventual controlled porosity, and several physical and mechanical property values that can be achieved. So for different applications different initial tap densities are desirable. For applications requiring high final densities, and also when shrinkage during the PMSRT is to be minimized, it is desirable to have high initial tap densities of 45% or more, preferably 56% or more, more preferably 67% or more and even 78% or more.

In an embodiment tap density is an increased bulk density attained after mechanically tapping a container containing the powder sample.

In an embodiment the tap density is obtained by mechanically tapping a graduated measuring cylinder or vessel containing the powder sample. After observing the initial powder volume or mass, the measuring cylinder or vessel is mechanically tapped, and volume or mass readings are taken until little further volume or mass change is observed. The mechanical tapping is achieved by raising the cylinder or vessel and allowing it to drop, under its own mass, a specified distance.

In an embodiment the tap densities of the powder mixture is 45% or more, in other embodiment 56% or more, in other embodiment 67% or more and even in other embodiment 78% or more.

In an embodiment before the debinding process, when is necessary, and sometimes directly over the green material obtained after the shaping process of the powder mixture a heat treatment to promote diffusion may be carried in order to transfer the shape retention of the component from the organic material, to the metallic phase (which will be referred in this document PMSRT). In an embodiment this heat treatment includes a constant heating of the component until a desired temperature is reached, and then the component is maintained at this temperature during a determined time. In other embodiment, for example when liquid phase is present in the lower melting point metallic phase, sometimes in order to control the diffusion process, the heat management during this PMSRT step may be applied in a different way, and temperature may be decreased and increased depending of the concrete situation and necessity for the better management of the process.

In an embodiment it is interesting control and/or modify other physical variables during the PMSRT treatment. In an embodiment the atmosphere in which this heat treatment to promote diffusion is made is controlled (the control of the atmosphere during all treatments is very important for some applications, since oxidation of internal voids and also of the surface is often not desirable, but sometimes even advantageous. So often controlled atmospheres are advantageous, inert atmospheres and even for some cases reducing atmospheres are very advantageous to reduce or eliminate the oxidation layers. Sometimes the atmosphere is used to activate the surfaces, and this can be done not only by reduction but sometimes by some kind of etching or even oxidation). In an embodiment PMSRT is made in an inert atmosphere. In other embodiment in reducing atmospheres. in other embodiment mechanical strength is applied a during the PMSRT. In other embodiment pressure is applied during the PMSRT, which may be isostatic or directed to different parts of the component. In other embodiment PMSRT is made under vacuum or low pressure conditions.

In an embodiment at least part of the PMSRT takes place during debinding treatment. In an embodiment PMSRT takes place during debinding treatment. In other embodiment PMSRT is reached in a separate HeatTreatment. In an embodiment PMSRT is reached before other post-processing such as sintering, sinter forging, HIP and/or CIP treatments.

During the PMSRT treatment it is desirable to provide shape retention trough metallic components, although this might also have taken place already in the debinding step, when such step is necessary. So often diffusion either solid-solid and/or liquid-solid (when a liquid phase is present) have to be tailored to achieve the desired properties during the PMSRT. Amongst others, in many applications sufficient diffusion has to be attained, together with the debinding treatment in many instances it has been seen that a step with an exposition at a temperature above 0.35*Tm (Tm is the melting point, as defined in the present invention, expressed in degrees Kelvin) is convenient, preferably above 0.53*Tm, more preferably above 0.62*Tm and even above 0.77*Tm. For some applications this Tm refers to the metallic phase with the lowest melting point, other times to the mean of all metallic constituents, in some other cases it refers to the metallic phase with the highest volume fraction, in some cases it refers to the metallic phase with the highest melting temperature, and also in some cases to the mean of all metallic phases with the highest volume fraction required to add up to a 52% of all metallic constituents in weight. The holding times are calculated on an application basis to match the level of diffusion desired, in terms of full or partial mechanical alloying, closure of voids, mechanical properties attained or any other relevant parameter to determine the amount of diffusion required, which can be calculated then once the exposition temperatures are fixed also, trough modeling of the diffusion. In the one hand during debinding when applied and/or during PMSRT very often it is necessary to sufficient time for diffusion and/or the formation of a liquid phase, amongst at least one of the metallic phases, to assure shape retention trough the metallic phases before the organic compound or phases are degraded is often desirable, and a good metric. Shape retention is provided when there is no permanent change in the shape by its own weight even if 72h are allowed and in some cases even no permanent change takes place when small loads, often lower than 9 MPa are applied, preferably lower than 4 MPa, more preferably lower than 2 MPa and even lower than 0.4 MPa. Although less often effective, for some applications shape retention can be evaluated in terms of mean distance traveled by certain elements or evolution of the composition of certain metallic particulates.

In an embodiment PMSRT is reached when there is no permanent change in the shape of the component by its own weight in 72 h.

In an embodiment PMSRT is reached when there is no permanent change in the shape of the component when loads are applied to the component. In an embodiment the loads applied are higher than 0.4 MPa, in other embodiment the loads applied are higher than 2 MPa, in other embodiment the loads applied are higher than 4 MPa, and even in other embodiment the loads applied are higher than 9 MPa

In an embodiment PMSRT takes place partially during debinding, and an additional heat treatment is made to finish PMSRT before sintering, sinter forging, HIP and/or CIP post-processing.

In an embodiment PMSRT is made trough a heat treatment wherein the green component is submitted to a temperature above 0.35*Tm, in other embodiment above 0.53*Tm, in other embodiment above 0.62*Tm and even in other embodiment above 0.77*Tm, wherein Tm is the melting point of the low melting metallic alloy expressed in degrees Kelvin.

In an embodiment the temperature of the heat treatment for achieving PMSRT and/or MSRT is reached by a temperature gradient.

In another embodiment increasing temperature gradients are used during the Heat treatment. In other embodiments after an inicial temperature gradient the temperature is hold and then increasing and/or decreasing temperature gradients are used to promote PMSRT or MSRT.

In some applications one proper way to evaluate whether diffusion has been enough (determining the holding time once temperature has been fixed, and even when the treatment is defined in a numerical way through diffusion models or simulation) is through the evaluation of the increase of concentration of at least one of the elements present in a phase at least at a higher concentration that in another metallic phase, and then evaluating the increase of concentration occurred at certain distance from the surface in a representative volume fraction of the phases with a lower concentration of the element. Often in applications where a phase with a much higher melting point than another phase is used, the first being majoritarian and even more when the second turns at least partially into a liquid phase during the treatments, then often it is some element in the low melting point phase diffusing into the high melting point phase that is evaluated or the other way around some element in the high melting point phase diffusing into the lower melting point phase (the strategy of continuously increasing melting point or melting range is explained elsewhere in this document). The measuring point is often resulting from taking a certain distance inwards of the particle on the orthogonal line to the contact plain between the two different nature particulates on the normal crossing the first point of contact. Alternatively the mean of composition of the circumference sharing the same centre of mass than the original particulate and defined by the equivalent radius of the original particulate where the desired distance has been subtracted. The inventor has seen that as desired distance for some applications is 2 micrometres or more, preferably 6 micrometres or more, more preferably 10 or more, and even 16 micrometres or more. For some applications, especially also when strong diffusion is desired and/or big particulates used, desired distance might be 22 microns or more, preferably 32 microns or more, more preferably 54 microns or more and even 105 microns or more. Sometimes it makes more sense to define the desired distance in terms of a fraction of the original equivalent diameter (often in average terms), often then for some applications desired distances of 2% of the original equivalent diameter or more, preferably 6% or more, more preferably 12% or more and even 27% or more. As explained elsewhere in this document, intensity of diffusion to determine temperature time combination of the PMSRT treatment can be defined in terms of remaining porosity (full density included) and in terms of overall homogeneity or segregation for a particular element or for all elements. The increase in a particular element desirable for many applications is a 0.02% or more, preferably a 0.2% or more, more preferably a 1.2% or more and even a 6% or more in absolute weight percentage terms. Often it is more advantageous to measure the increase in relative terms that is to say which percentage increase with respect of the original nominal or average percentage of the phase, within the ones involved in the evaluation of the diffusion, with the highest content of the element (that is to say 100% would be the same content as the phase with the highest content had at previous to the treatment). In such cases a 1.2% or more increase, preferably a 3% or more increase, more preferably a 5.5% increase and even a 22% increase can be desirable. Often this values are not constant throughout the manufactured component, in which case the average is sometimes used for some applications, for others also a weighted average, where only a certain percentage of the highest or alternatively lowest values obtained is considered. For such cases it is sometimes desirable to consider a 10% or more of the values, preferably a 20% or more, more preferably a 30% or more and even a 55% or more to calculate the average.

When determining the temperature and heating and cooling rates for the PMSRT or MSRT treatments, many things are often taken into account besides the shape retention. So, smart compromises need to be made. When it comes to shape retention, often the criteria for the selection of heating and cooling rates are the complexity of the piece and interest in minimizing thermal stresses due to different temperatures in different areas of the component when excessive heating or cooling is taken. Sometimes fast cooling/heating is desirable either for microstructural purposes (often to avoid or minimize a certain phase transformation) and sometimes to be able to maximize the temperature at which shape retention from the organic component is still providing shape retention but in such case, often a further condition is imposed in terms of upper limit for the dwell time. So, in most cases a simple temperature distribution simulation and good knowledge about the organic phases degradation patterns will suffice to determine the heating and cooling rates. As per the temperatures themselves at which holding takes place (and thus the corresponding dwell time is applied) are also determined as a compromise of the effects on all functional characteristics to be observed, but when it comes to shape retention, equilibria simulations for all the present phases are used, finding the possible strategies that render the desired shape retention. Organic phase, when present, is relevant in terms of degradation and metallic phases in terms of controlling the amount of liquid phase when present, or impeding its formation trough the diffusion of the right atoms. Melting temperatures in the equilibrium state are easily calculated to determine desired alloying trough diffusion. Alternatively, when there is no liking for simulation, phase equilibria diagrams can be employed to determine a first approximation that then is contrasted with one or two simple experiments, in this way quite daring assumptions can be made that make the equilibria calculations much more simple.

When determining the preferable dwell times for the post processing, and especially in the case of the PMSRT or MSRT treatment, the inventor has seen that a convenient way to proceed consists on determining the desired dwell time according to all the functionalities desired on the heat treatment (shape retention, debinding, stress relieving, microstructure evolution . . . ). In most cases a minimum time will be determined and it is in principle the desired one or economic reasons, but some functionalities, especially those related to eventual deleterious microstructure evolutions, might determine a maximum desirable dwell time. When each dwell time for each relevant functionality lays before, a best compromise choice often needs to be made. In the instances in which all relevant functionalities require a minimum time, the longest of them all is chosen for obvious reasons. For most functionalities, since they are not the principal purpose of the present invention, experience, simulation, open literature, etc. can be used to determine the desired dwell times for each functionality. In the case of shape retention, the time is determined as a function of the desired amount of diffusion. The desired amount of diffusion can be determined with the equilibria diagrams (nowadays CALPHAD simulation) to achieve a structure with the desired melting temperature. Once the amount of desired concentration is decided and as a function of the particle sizes chosen, Fick's laws can be used to determine the required dwell time at the chosen temperature (also normally done with simulation packages). To avoid needing to have very accurate measures of the diffusivities and also in the case that manual calculations are made and assumptions taken to simplify the calculations, it is best to use the calculations as a starting approximation and then make a test (holding at the chosen temperature for the calculated time) and observe the result to make the corresponding corrections. With good will, at most two rounds are required for an accurate enough determination of the dwell time. If one feels lazy it is also possible to just take a big enough over-estimate for the dwell time straight out from the simulation/calculation. Even, the simplification of taking only the main alloying element of each type of powder can be done for rather dilute alloys. For the application of Fick's laws values of diffusivities are required. Often the values for the diffusivities of the different elements of interest in the alloy of interest can be found in the literature and specific databases. When that is not the case, then they can be either measured or modeled, the inventor has seen that which of the two ways is chosen and what specific model or measuring technique is not all too important due to the low accuracy required as explained. Different measuring techniques render somewhat different measures and different models also render different approximations, but the level of accuracy in the determination of the diffusivities does not need to be all too high as explained so this differences are not relevant in this case. This applies to the other properties described in this document also. The nice thing about simulation of diffusivities is that some simulation packages already incorporate some models. Obviously is best to use models that have been developed for a similar system to the one considered, but if nothing better is at hand, the usage of a general model is perfectly fine. In the case of diffusion into a liquid phase, if nothing better is at hand, any model combining Sutherland-Einstein formula with Kaptay's unified equation on the dynamic viscosity can be employed like in Equation 12 in Xuping Su et al. in JPEDAV (2010) 31: pg. 333-340 (D01: 10.1007/s11669-010-9726-4) can be used. Also corrosion data as dissolution in the liquid metal can be employed (as an example for the case of gallium and aluminum Yatsenko et al. in Journal of Physics 98(2008)062032—DOI: 10.1088/1742—6596/98/6/062032). In the case of solid-solid diffusion, when nothing better is at hand, models based on the work of Le Claire can be used. Also ab-initio techniques can be employed for the determination of the diffusion characteristics, like density-functional theory (DFT) calculations often using computer aid like the SIESTA package. As said any existing method is good for the measurement of the diffusion coefficients given the rather low accuracy required in the present method. Often the tracer method (using grinding for high temperatures or diffusion coefficients and sputter section techniques for low temperatures and diffusion coefficients) as described by Paul Heitjans and Jörg Karger in their Diffusion in Condensed Matter Handbook can be used (but also SIMS, EMPA, AES, RBS, NRA, FG NMR or the indirect methods).

In an embodiment PMSRT and/or MSRT are reached when no permanent change takes place when loads, lower than 9 MPa are applied to the component, in other embodiment lower than 4 MPa, in other embodiment lower than 2 MPa and even in other embodiment lower than 0.4 MPa and when there is no permanent change in the shape by its own weight during 72h.

In an embodiment the PMSRT is reached after the organic compound is fully degraded.

In an embodiment segregation variation takes place during heat treatment for PMSRT

In an embodiment, when PMSRT is reached and fully degradation of organic compound has occurred the component, have a transverse rupture strength value higher than 1.55 MPa, in another embodiment higher than 2.1 MPa, in another embodiment higher than 4.2 MPa, in another embodiment higher than 8.2 MPa, in another embodiment higher than 12 MPa, in another embodiment higher than 18 MPa, and even in another embodiment higher than 22 MPa.

In an embodiment, when MSRT is reached the component, have a transverse rupture strength value higher than 1.55 MPa, in another embodiment higher than 2.1 MPa, in another embodiment higher than 4.2 MPa, in another embodiment higher than 8.2 MPa, in another embodiment higher than 12 MPa, in another embodiment higher than 18 MPa, and even in another embodiment higher than 22 MPa.

In an embodiment before debinding when required and/or heat treatment to achieve PMSRT another post-processing processes are applied to the component. In an embodiment these post-processing treatment are selected from sintering, sinter forging, HIP and/or CIP among others.

For some applications it is very convenient to favor the diffusion and/or closure of voids, in such cases it can be convenient to use vacuum and/or pressure to this extend. An example of how to apply pressure at the same time that diffusion is activated with temperature can be found with the Hot Isostatic Pressing (HIP) process. Also the control of the atmosphere during all treatments is very important for some applications, since oxidation of internal voids and also of the surface is often not desirable, but sometimes even advantageous. So often controlled atmospheres are advantageous, inert atmospheres and even for some cases reducing atmospheres are very advantageous to reduce or eliminate the oxidation layers. Sometimes the atmosphere is used to activate the surfaces, and this can be done not only by reduction but sometimes by some kind of etching or even oxidation.

Quite often in the applications of the present invention, a higher density of the final product is desirable compared to the density of the metallic constituents alone right after the manufacturing step. Thus trough diffusion, capillary force of liquid phase, pressure or any other the metal particulates suffer some displacement to close voids, with the associated shrinkage. For some applications the management of this shrinkage is quite relevant for the functionality of the piece. The inventor has seen that for some of those applications it is important to predict trough models, simulation or others the shrinkage so that it can be taken into account in the design phase to avoid or minimize machining post-processing. The accuracy level comes at a cost so it is important to have the right amount. The inventor has seen that uncertainties in the final dimensions of +/−0.8 mm or less, preferably +/−0.4 mm or less, more preferably +/−0.09 or less and even +/−0.04 or less. In some cases it makes more sense to fix the maximum level of uncertainty when estimating the shrinkage, in this sense for many applications it is desirable to have an uncertainty of 2% or less, preferably 0.8% or less, more preferably 0.38% or less and even 0.08% or less. In some cases it is interesting to limit the total shrinkage in the process to 18% or less, preferably 14% or less, more preferably 8% or less and even 4% or less.

The inventor has seen that for some applications it is interesting not to degrade and eliminate the polymer, since it might have an interesting functionality, yet the mechanical properties of the polymer are not sufficient for the intended application. In such cases the low melting point metallic constituent is the one that performs the bridging of the metallic pieces but without full degradation of the polymer. One such interesting applications arises for example when the lubricant character of certain polymers is to be capitalized. PTFE (tetrafluoro-ethylene polymer) has good sliding properties with steel but rather poor mechanical properties and thermal conductivity. With adequate charging, it can be exposed to well over 260° C., which is high enough for some metallic alloys to even form a liquid phase as has been seen in this document. A metallic structure can then be created which provides for improved mechanical properties and heat extraction capacity. Some parts requiring mechanical stability, good sliding behavior and good thermal management (even if it is just to extract the heat from the friction) can be manufactured in this way, by means of the present invention in terms of the metallic phases but without full degradation and elimination of the polymer.

For some applications it is advantageous to have a in-line multi-stage forming, with a displacement of the components being manufactured sequentially from one stage to the next, and in every stage one or several features are shaped, sometimes as an intermediate stage also. The transferring from one station to the next can be made in several ways amongst others also in the ways that is done in a progressive die press line.

The inventor has seen that the method of the present invention is especially indicated for the manufacturing of large components that surprisingly become economically meaningful thanks to the method of the present invention. Thus the method of the present invention allows to use additive manufacturing shaping techniques for the manufacturing of large pieces, with complex geometries and high mechanical demands which are manufactured in great numbers like is the case of body-in-white components for the automobile industry. In particular the present invention allows to manufacture in an economic way components of more than 1 Kg, preferably more than 2 Kg, more preferably more than 6 Kg and even more than 11 Kg. More importantly the method of the present invention allows to integrate components that are normally weld into a single component. Also the method of the present invention is very adequate for the light weight construction, since it allows for considerable weight reductions on structurally demanded components like the mentioned body-in-white components amongst others. The inventor has seen that to solve the problem of reducing automobile emissions it is possible through the use of AM and similar techniques to produce body-in-white components with a weight which is a 89% or less, preferably a 69% or less, more preferably a 49% or less and even a 29% or less than the same component or component with the same functionality which is the lightest of all the ones published in the ULSAB-AVC project between 2004 and 2010. The method of the present invention is particularly well suited.

The inventor has seen that the method of the present invention is especially well suit for the manufacturing of pieces that are generally produced by die-casting. This include parts which in 2012 were mostly manufactured trough high pressure die casting, gravity casting, low pressure die casting, tixo-molding, or similar process. Such components are several components of the power train of a vehicle (motor, gear box, clutch box, . . . ), structural components, rims, household appliances components, consumer electronics cases, etc. The inventor has seen that to make the method of the present invention cost effective weight reduction of the component is critical in many instances. For such instances the inventor has seen the importance of manufacturing a component which is a 89% or less, preferably a 69% or less, more preferably a 49% or less and even a 29% or less than the same component or component with the same functionality manufactured with the casting technique that was most common for that type of component at 21. October 2015. In some instances this weight reduction has a strong incidence on the part economic viability.

The inventor has seen that in some cases the combination of weight reduction, speed and cost effectiveness of the manufacturing method and low cost of the materials employed that makes a manufacturing technique based on AM viable. Weight reductions in the order of magnitude expressed in the two preceding particular cases can be generalized for many other components, together with the speeds of manufacturing described later on in this document but also very important is the cost of the material used for building with the AM technique. In such case, it is desirable to have metallic particulates that have a cost per kilogram of manufactured component which is 4.8 times or less the cost of the lowest cost material that can be used to manufacture a component with the same functionality when using the most common traditional manufacturing process used for the manufacturing of such component at 21. October 2015, preferably 2.8 times or less, more preferably 1.4 times or less and even 0.8 times or less. For some instances it is sufficient to have only two of this factors, and for some instances even just one. This is also the case for some components manufactured with the other manufacturing techniques described in this document.

Also in the case of some components that in 2012 were mostly manufactured trough close die forging, are especially well suit to the method of the present invention. Crack shafts, pinions, gears, etc

Other manufacturing methods of pieces and components widely used in 2012, like powder metallurgy (sintering of pressed metallic powders), machining, etc are often particularly well suit for the method of the present invention.

In the case of the two preceding paragraphs, amongst others, the inventor has seen that many manufacturing steps can be used for the shaping and the presence of the organic compounds is not mandatory for all of them. A mixture of metallic particulates as described in the present invention (nature, particle shape, morphology, volume fraction . . . ) can be prepared with or without organic constituents. Then the mixture is compressed in a mold with a shape or filled, preferably with vibration or any other means to attain high densification, into a mold or container with a desired shape (the container should withstand the temperature required to provide shape retention, until this shape retention is provided within the manufactured component itself, but it might or might not be reusable). Then the diffusion treatment according to the present invention is carried out. This way of proceeding is particularly advantageous for rather bulky components with little or no internal voids. An illustrative example is the construction of a mold with the desired shape out of a cost effective ceramic, polymeric or Cementous material, filling the mold with a mixture of metallic powders (which might incorporate some organic constituents to improve friction or other functionality), subjecting the powder mixture to temperature like in the PMSRT taking into account that only sometimes debinding might be necessary. The mold is often build in at least two parts so that compression can also be applied to the metallic particulates in a fashion as described in WO200914115. Also in the case that sufficient tap density is achieved or porosity is not annoying or even desired a perishable mold can be used, like a plastic mold or similar that contains the metallic particulates with the desired shape while shape retention is provided through low temperature diffusion with or without metal phase. Once shape retention is provided through the metallic phases, the mold can be extracted or just simply degrade

The inventor has also seen that the techniques involving photo-curable polymers can be made especially well suited for a fast deposition and thus manufacturing within the method of the present invention. That is especially so because since the curing results from the short exposition of the polymer to a certain wavelength (and where often inhibition of the reaction can also be used to provide extra speed and design flexibility), this can often be achieved with a method of exposition to the desired wavelength based on a surface at a time, rather than the traditional rather cylindrical or elliptical cursor that has to follow the whole perimeter or surface to be cured on every single layer. Even systems that expose the whole layer at a time with the desired pattern can be used very favorably.

The inventor has seen that surprisingly it is advantageous for the manufacturing of large structural components in large numbers, and also for many other components especially when manufactured in large series, when using a AM technique involving metal particulates to instead of using high quality metallic particulates to achieve the desired mechanical properties (often plasma atomization, crucible-less atomization or at least gas atomization of the same alloy, or very similar, that would be used in a conventionally manufactured product) to instead use a cheap manufacturing route for the particulates (water atomization [including high pressure for finer particulates], reduction of oxides, centrifugation, . . . ), often sacrificing some mechanical properties which can be compensated by the usage of a higher value alloying concept. In fact for some of the components manufactured with the present invention the manufacturing cost of the powder particulates is of capital importance and should be 1.9 times the alloying price according to London metal exchange market or less, preferably 1.48 times or less, more preferably 1.18 times or less, and even 1.08 times or less. The inventor has seen that the tradeoff is surprisingly positive. This is more so for properties which are often negatively affected by most AM processes, like the ones related to toughness and elongation. This is so because to achieve close to nominal bulk product in such properties, not only high constraints are placed on the morphology of the particulates, but also in the whole AM process. Even a small amount of porosity will compromise those properties, so that complex post processing (including HIP or other energy intensive processes to achieve full density) is required to attain close to nominal values. On the other hand using alloying concepts that deliver higher fracture toughness for the same or even higher level of mechanical strength, or alloying concepts that allow for a local plastification to stop the propagation of the porosity stress intensifier edges into cracks can work in a surprisingly more economical way. Alternatively it is also possible to use the complex post processing route to achieve full density, often involving energy and time intensive processes like HIP, but in such case it is critical to work with large batches being treated simultaneously in one or more installations. The inventor has seen that in this case it is favorable if at least a mean of 600 pieces are treated simultaneously, preferably 1200 pieces or more, more preferably 3200 pieces or more, and even 12.000 pieces or more. An intermediate level, the inventor has seen is the usage of a controlled liquid phase formation as described as a possible implementation of the method of the present invention, to achieve full density or at least smaller porosity with less sharp edges in a way that is economically viable. Besides the usage of low cost manufacturing processes for the fabrication of the metallic particulates, the inventor has also seen that to be able to manufacture such large components in large quantities in a competitive way, it is very advantageous to use fast AM systems with a low investment cost. This often involves a renounce on accuracy attainable, and even more often on mechanical properties of the as AM component, but when using the method described in this document this can be overcome and surprisingly attain sufficient values of dimensional accuracy and mechanical properties, especially if proper design is employed (also given that the real values of accuracy required according to the inventor are considerable laxer than the ones currently aimed at by the AM industry). Thus for the inventor has seen that for some applications of the present invention, especially those related to the manufacturing of large series, it is important to select the right AM technique. For some applications that refers mainly to the fabrication cost of the AM system which should be $190.000 or less, preferably $88.000 or less, more preferably $49.000 or less, and even $18.000 or less. Additionally for some cases, an important parameter is the maximum surface of the table where AM is performed, and thus the maximum surface projection that the manufactured component can have, which often is desirably bigger than 20.000 cm2, preferably bigger than 550.000 cm2, preferably bigger than 1.2 m2 or even bigger than 3.2 m2. Also for some cases the inventor has seen that a minimum speed of manufacturing is required, in those cases the parameter to be observed is the time required to manufacture 1 mm of height of the worst possible geometry with a projected section of 10 cm2. In such cases it is desirable to have 95 seconds or less, preferably 45 seconds or less, more preferably 0.9 seconds or less or even 0.09 seconds or less. The inventor has seen that for some applications, the critical parameter to select the adequate AM system to be able to produce large components in large series in a cost effective way, is the parameter that evaluates the investment cost per unit effective area of impression. This results through the division of the investment cost of the system through the effective area of manufacturing (maximum area where components can be manufactured in the system). Investment cost of the system is understood as the minimum amount required to get the machine with the required functionality into operation, supposing that all required supplies are present and at no cost, same as building and any others. Often 190 $/cm2 or less are desired, preferably 90 $/cm2 or less, more preferably 42 $/cm2 or less, and even 22$/cm2 or less. Taking into account that to achieve such values renounces in accuracy and mechanical properties of the as additive manufactured component (organic element or substitute providing shape retention). For components where processing cost is capital, further renounces have to be made to have 4 $/cm2 or less, preferably 0.9 $/cm2 or less, more preferably 0.4 $/cm2 or less, or even 0.01 $/cm2 or less. For some applications, especially when very large series are required, the inventor has seen that for the manufacturing of the components an AM system has to be selected with the adequate value of the parameter resulting from the division of the investment cost of the system divided by the maximum throughput in cm3/h attainable with the system. The parameter that has $*h/cm3 units for the cases mentioned has a desirable value of 48 or less, preferably 18 or less, more preferably 0.8 or less and even 0.08 or less. When it comes to accuracy the inventor has seen that surprisingly for many components an accuracy of +/−0.06 mm or worse is sufficient, preferably +/−0.15 mm or worse, more preferably +/−0.32 or worse, or even +/−0.52 or worse. Then again some components due request high accuracy desirably +/−95 microns or better, preferably +/−45 microns or better, more preferably +/−22 microns or better or even +/−8 microns or better.

The inventor has seen that in many instances production costs of large components manufactured in large series like is the case of body-in-white parts in the automobile industry amongst others, have been optimized during many years and thus are very difficult to match, especially with a new manufacturing technique. Thus in many cases of the present invention the components manufactured can only be manufactured in an economically reasonable way if a significant weight reduction is achieved. To this goal, the flexibility of design of the method of the present invention is of great help. For this end the usage of bionic structures and generally replication of nature optimized structures. Also some structural components have different demands in different areas of the same component, thus for example having areas where the resistance to deforming or indeformability is capital and other areas where the capability of absorbing energy is rather preferred. Also some structural components are designed to avoid failure, but on the event of an unexpected higher demand, it is desirable that they fail in a specific way (as an example the components in the car structure that assure the integrity of the passenger compartment are designed not to fail, but on the event of a severe accident, collision at high speed, moose falling on top, . . . it is desirable to have the system fail in a way that provides the highest chances for the passengers to survive, thus amongst others absorbing the maximum possible energy while respecting the vital space. Thus for several components having areas with different properties is clearly advantageous and can also contribute to their light weight design. The inventor has seen that this can be attained in several ways, but in the framework of the present invention three methodologies or their combination are particularly well suited, that being said any other methodology is not excluded. The three most suited ways are design, multi-material and partial heat-treatment. Design refers to any kind of strategy related to the geometry at all levels of the component, to provide some examples: different thicknesses, different stiffness (especially significant trough bionic design), determining the path of deformation on a definite loading pattern, having an area that acts as mechanical fuse (is less resistant, deforms more, porosity is left to reduce fracture toughness, . . . ). Once again, bionic design and in general the flexibility of design of AM permits to achieve quite different behaviors by the generation of certain patterns and structures at mini, micro and with the help of material even at nano levels. Multi-material refers to the usage of different materials in different areas of the components, it is quite self-explanatory but to provide an example one can use a material with high stiffness in a particular area, and a material with high deformability and energy absorption in another area. Partial heat treatment refers to having areas that receive different heat treatments to attain different properties, this is normally related to the material, since often is the one that determines what properties can be attained upon the application of different heat treatments. In the present invention one more singular case arises besides most of the ones that can be found in the literature, and that is having different degrees of diffusion in different areas of the manufactured component and thus having different compositions although the same feedstock was used.

The inventor has seen that a feedstock as the ones required in the different implementations of the present invention can be advantageous for other applications also. In particular for some applications a feedstock containing at least one organic compound and at least one metallic phase. Even more so if the melting temperature, as described in this document, of at least one of the metallic phases is lower than 3.2× the highest degradation temperature of the organic compounds, where the melting temperatures are expressed in Kelvin degrees, preferably lower than 2.6×, more preferably lower than 2× and even lower than 1.6×. And it is also quite interesting for some applications when the metallic phases represent a volume fraction of 24% or more, preferably 36% or more, more preferably 56% or more, and even 72% or more. Any other type of feedstock, or feedstock attributes defined in this document can also in principle be interesting for some alternative application.

Taking into account that for some instances of the present invention the AM or manufacturing step is only intended to provide shape and retain it for a while, thus posing much lower mechanical requests on the part that for many other applications, often many more organic materials can be employed for a given manufacturing technique that what is presently common or even known. As AM technique and as has also been already mentioned any technique can be used, but the advantages are critical for a particular method for a given application. Powder bed fusion methods, direct energy deposition, methods based on powder projection and even methods based on material fast elimination can be used, with particular advantage for different applications. The organic material chosen often varies as a function of the manufacturing technique chosen. In the case of systems based on the softening or melting of a polymer, it is particularly interesting for some applications to choose a low cost one, while for others is rather the decomposition temperature that matters amongst others. The inventor has seen that for many of the components manufactured with the method of the present invention it is especially advantageous the usage of thermos-setting polymers (like epoxy and other kind of high strength resins). That is the case in the manufacturing of structural and other components for vehicles and other moving or at least transportable devices. Ink-jetting like systems are especially interesting for this purpose. In the case of UV or other wavelength curing technologies it is interesting to have especially fast curing and/or low cost organic compounds, even when not such high mechanical strength is achieved. Fast curing is a resin requiring less than 2 seconds to cure a 1 micron layer, preferably less than 0.8 seconds, more preferably less than 0.4 seconds, and even less than 0.1 seconds. Low cost is less than 70 $/liter, preferably less than 45 $/liter, more preferably less than 14 $/liter and even less than 4 $/liter (cost refers to lowest possible manufacturing cost in US territory and with dollar value of 01/November/2015).

Generally for very large components the preferred way of manufacturing are those based on material projection or material erosion, rather than those based on a continuous bed of material where a definite pattern is cured layer by layer. Material projection includes any type of localized supply of feedstock, even if not all the feedstock is used like in the case of systems that supply more feedstock than required, cure a part of it and remove the rest. Needless to say, projection systems are the ones where material combinations are easier, but it can also be implemented in almost any other system.

The inventor has seen that the present invention is particularly well suit for the implementation of bionic designs. Although most bionic design, have almost constantly varying sections, some of them can be viewed in a simplified way as a wire mesh. Again this is a simplified view since often the shape is not that of a wire and hardly ever the cross-section is a constant one. But is the actual bionic design is reduced for easy interpretation to a mesh of wires where each segment has the mean cross-section of the real design in that area, then general guidelines are not so complex to provide. The inventor has seen that some considerations can be made regarding the cross section and length of the wires of the simplified system representing the actual design. If we define the representative component surface as the addition of the maximum projected surface (in this document when the term projected surface is used alone it refers to the projected surface that renders the maximum area) plus twice the maximum projected surface on a plane to the plane of the maximum projected surface. The inventor has seen that the length of equivalent wire on a square meter of representative component surface is an important parameter to take into account for the proper manufacturing of several components. For components requiring very high mechanical strength and where weight is not a main concern the inventor has seen that one can have 210 m or more, preferably 610 m or more, more preferably 1050m or more or even 2100 m or more. On the other hand for certain applications where weight is of significance, the inventor has seen that it is desirable to have 890 m or less, preferably 580 m or less, more preferably 190 m or less and even 40 m or less. When it comes to the equivalent wire cross-section (mean cross section of the real elements) for some light components the inventor has seen that is desirable to have 340 mm2 or less, preferably 90 mm2 or less, more preferably 3.4 mm2 or less, and even 0.9 or less.

The inventor has seen that the alloys resulting by using one of the strategies of the present invention, namely the usage of AlGa alloys or other low melting point alloys containing Ga, especially when the main metallic constituent is an alloy based on Fe, Ti, Co, Al, Mg or Ni, delivers resulting alloying systems after the diffusion treatment which are very well suited for vehicle (space-ship, airplane, car, train, boat, . . . ) components. So alloys, or alloying systems (understood as the general composition, even if strong segregation exists and locally the compositions are quite different) containing % Ga in the amounts described in the present invention are particularly well suited for the manufacture of components for the aeronautic, automobile, marine, aerospace, and railway industries.

Additional embodiments of the invention are described in the dependent claims.

The technical features of all the embodiments herein described can be combined with each other in any combination.

The present invention relates to a method for efficient production of components by stereolithography. It also refers to material required to manufacture these parts. The method of the present invention allows very rapid production of parts. The method allows the manufacture of components with various materials, organic, metallic and/or ceramic.

The present invention is especially advantageous for lightweight construction. Complex geometries can be achieved with metal based difficult to deform (metallic materials of high mechanical strength desirable for lightweight construction often have limited formability). Complex geometries allow optimized replicate nature for maximized performance with minimum volume of material designs. Also alloys can be used light materials: Ti, Al, Mg, Li . . . . Also denser materials where they can get very high mechanical properties even in harsh environments based on Ni, Fe, Co, Cu, Mo, W, Ta . . . . The present invention is also interesting for the construction of ceramics with curable resins having UV index of refraction very uneven. A very important aspect of the present invention is that it allows the manufacture of medium and large components.

In an embodiment the invention refers to a method for manufacturing components using stereolithography.

In an embodiment the invention refers to a method for manufacturing components using stereolithography.

In an embodiment the invention refers to a method for manufacturing ceramic components using stereolithography comprising a resin loaded with several materials such as but not limited to ceramic, organic, metallic and any combination of them.

In an embodiment resin is a photopolymer (polymer photo-curable).

In an embodiment photopolymers comprises thermo-setting polymers.

In an embodiment a thermo-setting polymer is a polymer in a soft solid or viscous state that changes irreversibly into an infusible, insoluble polymer network by curing. Curing is induced by the action of heat or suitable radiation, often under high pressure. In an embodiment a cured thermosetting resin is called a thermoset or a thermosetting plastic/polymer.

In an embodiment thermo-setting polymer are polyester fiberglass systems: sheet molding compounds and bulk molding compounds, Polyurethanes: insulating foams, mattresses, coatings, adhesives, car parts, print rollers, shoe soles, flooring, synthetic fibers, etc. Polyurethane polymers, Vulcanized rubber, Bakelite, a phenol-formaldehyde resin used in electrical insulators and plasticware, Duroplast, Urea-formaldehyde foam used in plywood, particleboard and medium-density fiberboard, Melamine resin, Diallyl-phthalate (DAP), Epoxy resin, Polyimide, Cyanate esters or polycyanurates, Mold or mold runners, Polyester resins among others.

In an embodiment a photopolymer is a polymer that changes its properties when exposed to light, often in the ultraviolet or visible region of the electromagnetic spectrum. These changes are often manifested structurally, for example, hardening of the material occurs because of cross-linking when exposed to light. An example is shown below depicting a mixture of monomers, oligomers, and photoinitiators that conform into a hardened polymeric material through a process called curing.

In an embodiment a photopolymer consists of a mixture of multifunctional monomers and oligomers in order to achieve the desired physical properties, and therefore a wide variety of monomers and oligomers have been developed that can polymerize in the presence of light either through internal or external initiation. Photopolymers undergo a process called curing, where oligomers are cross-linked upon exposure to light, forming what is known as a network polymer. The result of photo curing is the formation of a thermoset network of polymers. One of the advantages of photo-curing is that it can be done selectively using high energy light sources, for example lasers, however, most systems are not readily activated by light, and in this case a photoinitiator is required. Photoinitiators are compounds that upon radiation of light decompose into reactive species that activate polymerization of specific functional groups on the oligomers.

In an embodiment the light sources for curing a resin are 1100 lumens or more in the spectra with capability to cure the employed resin, in other embodiment 2200 lumens or more, in other embodiment 4200 or more and even in other embodiment 11000 or more.

In an embodiment the invention refers to a composition comprising a resin filled with particles characterized in that is photo-curable.

In an embodiment the invention refers to a photo-curable composition comprising a resin filled with particles characterized in that, the composition is photo-curable at wavelengths above 460 nm, in other embodiment above 560 nm, in other embodiment above 760 nm, in other embodiment above 860 nm.

In an embodiment resins are curable at a wavelength above 460 nm, in other embodiment above 560 nm, in other embodiment above 760 nm, in other embodiment above 860 nm.

In an embodiment particles refers to ceramic materials such as Al2O3, SiO2 and COH, organic materials, metallic materials and any combination of them.

In an embodiment the powder mixtures disclosed in this document, and any of the new alloys further disclosed in this document is suitable to be filled in the resin.

In an embodiment the invention refers to the use of any of the alloys disclosed in this document in powder form for filling the resin.

In an embodiment the wavelength used for curing the photo-curable composition is above 460 nm, in other embodiment above 560 nm, in other embodiment above 760 nm, and even in other embodiment above 860 nm.

In an embodiment the invention refers to a photocurable resin filled with particles suitable for manufacturing metallic or at least partially metallic components using stereolitography.

In an embodiment stereolithography is made using wavelength for curing the resin filled with particles above 460 nm, in other embodiment above 560 nm, in other embodiment above 760 nm, in other embodiment above 860 nm.

The present invention relates to a method for efficient production of components by stereolithography. The method allows the manufacture of components with various materials, organic, metallic and/or ceramic.

Some AM processes are incorporating curing resins or other polymers by exposure, often localized to a certain radiation. Some of these processes have been evolved to a state in which the economic production of parts of complex geometry and high level of detail is possible. Examples of this technique use masked radiation over a surface of resin surface (SLA), or a volume of resin (continuous liquid interface production CLIP-SLA), some other examples use an inhibitor or enhancer for which a desired geometry is generated and radiation is applied to the entire surface (such as POLY JET system).

In an embodiment the invention refers to a method of manufacturing a metallic or at least partially metallic component by shaping a powder mixture comprising at least a metallic powder and a thermo-setting polymer using an AM technique consisting on a Ink-jetting system In an embodiment less than 2 seconds are needed to cure a 1 micron layer of the thermo-setting polymer, preferably less than 0.8 seconds, more preferably less than 0.4 seconds, and even less than 0.1 seconds. In an embodiment the thermo-setting polymer is filled with the powder mixture.

In an embodiment a thermo-setting polymer is a polymer in a soft solid or viscous state that changes irreversibly into an infusible, insoluble polymer network by curing. Curing is induced by the action of heat or suitable radiation, often under high pressure. In an embodiment a cured thermosetting resin is called a thermoset or a thermosetting plastic/polymer.

In an embodiment thermo-setting polymer are polyester fiberglass systems: sheet molding compounds and bulk molding compounds, Polyurethanes: insulating foams, mattresses, coatings, adhesives, car parts, print rollers, shoe soles, flooring, synthetic fibers, etc. Polyurethane polymers, Vulcanized rubber, Bakelite, a phenol-formaldehyde resin used in electrical insulators and plasticware, Duroplast, Urea-formaldehyde foam used in plywood, particleboard and medium-density fiberboard, Melamine resin, Diallyl-phthalate (DAP), Epoxy resin, Polyimide, Cyanate esters or polycyanurates, Mold or mold runners, Polyester resins among others.

There are some efforts for the application of these technologies to the manufacture of ceramic components, or ceramic infiltrated with liquid metal. The main idea is the use of the technologies described in the preceding paragraphs but using curable resins loaded with particles. Unfortunately, this is currently only applicable to certain ceramic materials, mainly silica, alumina and hydroxyapatite and to a lesser extent zirconia and others. The main problem is that it is not possible to achieve the critical curing energy to a sufficient depth due to the absorption of radiation by the medium (filled resin). All serious research groups have reported that the problem is the incompatibility of refractive indices of the resin and the particle which weakens radiation weakens due to the constant refraction in high loaded resins.

In order to overcome this problem two alternatives have been suggested: On the one hand the ceramics described above have been used and on the other hand low volume fractions of particles have been used, that is lightly loaded resins. The problem is that with low volume fractions of ceramic particles significant densities can't be achieved, with the consequent deterioration of metallic properties. As a palliative solution infiltration by liquid metal is occasionally used, but the metallic properties that can be achieved are usually far away from the “bulk materials” (whole material, fully densified). When densification is carried out after the resin is removed, if the start density is low normally cracking of parts occurs. This is a problem inherent in this manufacturing system, also in the case of ceramics with suitable refractive index, where only small parts can be manufactured because otherwise cracking might take place during the densification step.

The problem reported resides in the existing limitation to change the refractive index of the resins curable by radiation.

The problem to be solved is to produce systems that allow the manufacture of parts by the curing of a resin, with special mention of AM processes, in which high loaded resins can be effectively used, in order to obtain good parts with a high degree of densification in metallic and ceramic systems of interest.

The inventor has made a number of important observations and some of them very surprising that allow to achieve the objective described in the previous section for a multitude of systems in which it was not possible by the prior art.

In an embodiment the invention refers to a method os manufacturing metallic or at least partially metallic components using SLA.

In an embodiment the component obtained by shaping a powder mixture filled in a resin is a metallic or partially metallic component.

In an embodiment the invention refers to a method os manufacturing ceramic components using SLA.

In an embodiment the component obtained by shaping a ceramic powder mixture filled in a resin is ceramic component.

In an embodiment the component obtained by shaping a powder mixture filled in a resin is a green component that shall be subjected to a post-processing treatment to obtain the metallic or partially metallic component.

In an embodiment the refractive index or index of refraction n of a material is a dimensionless number that describes how light propagates through that medium. The refractive index determines how much light is bent, or refracted, when entering a material. The refractive index can be seen as the factor by which the speed and the wavelength of the radiation are reduced with respect to their vacuum values. The refractive index varies with the wavelength of light. This is called dispersion and causes the splitting of white light into its constituent colors.

In an embodiment the refractive index is measured using interferometry.

In an embodiment the refractive index is measured using the deviation method.

In an embodiment the refractive index is measured using the Brewster Angle method.

Firstly, some of the limitations described have been confirmed and have been proven true, in second place several additional observations have been made, which will be mentioned in the section of the detailed description of the invention. The inventor has found that for many systems is more convenient to change the refractive index of the particle, by acting on the particle itself or by acting on the environment, including the correct selection of the wavelength of the radiation used. Additionally, important progress for working with small curing depths has been made. Also they have commented on how to increase the distance of curing even when you can not have a profound impact on the dispersion of radiation in the resin system. Additionally, surprising observations have been made on how to work on systems with not very high initial densities. Without intending to be exhaustive with the list of observations at this point, it is worth to the observations on systems of interest made by the inventor in this invention.

For many cases, the inventor has found that it is very advantageous to have at least two different metallic materials dispersed in the resin, and even more advantageous when at least two of the materials have a considerable difference in their melting points. It is also very advantageous for many systems if at least one of metallic materials begins to melt before the shape retention or geometry by the polymer matrix is completely lost (PMSRT). In some cases it is also very advantageous when the metallic material with the lowest melting point can diffuse into the metallic base material without causing severe embrittlement. For some applications it is also interesting that at least one of the metallic materials is an alloy with a wide range of melting temperature, it is particularly interesting for applications with complex geometries when this alloy presents a low starting melting point. Another advantage can be achieved, especially when a liquid phase is desired, choosing a system the melting point of which increases when the diffusion takes place in order to control the volume fraction of the liquid phase throughout the process.

The present invention is also interesting for the construction of ceramics having an index of refraction very uneven for UV curable resins. A very important aspect of the present invention is that it enables manufacturing medium and large components.

In an embodiment Radiation intensity_is the power transferred per unit area, where the area is measured on the plane perpendicular to the direction of propagation of the energy. It has units watts per square metre (W/m²).

By AM of ceramic pieces with high performance by loaded curable resins, parts of complex geometries can be obtained, although quite small. In addition these systems are limited to manufacturing ceramics with refractive index in the range [340-420 nm] similar to the resin employed if high loads are to be employed ceramic in order to produce integral and useful parts. Even when the refractive index of the resin can be adjusted to become close to the desired ceramic, the variation range is limited (typically between 1.3 to 1.7 for 365 nm radiation). Since the maximum permissible difference in the refraction indices to still employ high loads (concentration of more than 50% by volume of particles and a conversion of the resin above 50%) is less than 0.4 it is easily deducible that the particles used should have a refractive index between 0.9 and 2.1 and preferably between 1.1 and 1.9 in order to apply this manufacturing system according to the literature. Some ceramics meet this condition such as silica (SiO2—1.564), alumina (Al2O3-1.787), hydroxyapatite (COH—1.645). Unfortunately for these wavelengths the refractive indices of many other industrial ceramic systems of interest do not meet such condition such as silicon carbide (SiC around 2.5).

For the most interesting industrial metals an interesting phenomenon occurs. While some metals clearly not meet the requirement as aluminum (Al 0.376), magnesium (Mg 0.16), etc. Other metals meet the condition such as iron (Fe—2.0) and nickel (Ni—1.62), but when the inventor has tried to obtain an acceptable curing depth with these metals and some of its alloys according to the state of art, surprisingly the results have not been the expected, and in some cases disappointing. It is also very remarkable the fact that there are serious publications in this regard, suggesting that other researchers found the same problem.

The inventor has found that surprisingly for metallic fillers reflectivity is even more important than refraction and therefore it should be taken into prime consideration. In this respect the inventor has found that for many applications of the present invention when resins with metallic fillers are used it is interesting to have metal particles having a reflectivity (reflexion) of 0.42 or more, preferably 0.56 or more, more preferably 0.72 or more, or even 0.92 or more for the preferred wavelength. The preferred wavelength is the one that has a higher reflectivity with the material of the majority of particles between all the wavelengths of radiation used capable of polymerizing the resin. In this respect, for these applications the aluminum and most of its alloys can be used for virtually any wavelength. This is also true for other particles with a reflection coefficient highly enough (as above paragraph) for the chosen wave length, surprisingly also for metal particles. For these same application (surprisingly for iron and most of its alloys (including steels) as well as for nickel and most of its alloys) contrarily to what it would be expected because of the compatibility of refraction index, resins curable by the exposure to ultraviolet radiation should not be used. Resins curable at wavelengths above 460 nm, preferably above 560 nm, more preferably exceeding 760 nm and even higher than 860 nm resins should be used.

In an embodiment the resin is filled with high loads of particles.

In an embodiment resin is filled with a powder mixture.

In an embodiment resin is filled with a ceramic.

In an embodiment resin is filled with a powder mixture comprising at least a metallic alloy in powder form.

In an embodiment resin is filled with a powder mixture comprising at least a low melting point alloy and a high melting point alloy in powder form.

In an embodiment the powder mixture is especially suitable for filled the resin.

In an embodiment high loads refers to a concentration of more than 50% by volume of particles in the photo-curable composition.

In an embodiment high loads refers to a concentration of more than 50% by volume of particles in the resin.

In an embodiment high loads refers to a concentration of more than 50% by volume of particles in the resin wherein the conversion of the resin is %50 or more.

In an embodiment the invention refers to a photo-curable composition wherein the particles used for fill the resin are metal particles having a reflectivity for chosen wavelength of 0.42 or more, in other embodiment at 0.56 or more, in other embodiment at 0.72 or more, or even in other embodiment at 0.92 or more.

In an embodiment the invention refers to a photo-curable composition wherein the particles used for fill the resin are metal particles having a reflectivity for a wavelength above 460 nm of 0.42 or more, in other embodiment at 0.56 or more, in other embodiment at 0.72 or more, or even in other embodiment at 0.92 or more.

In an embodiment the invention refers to a photo-curable composition wherein the particles used for fill the resin are metal particles having a reflectivity for a wavelength above 560 nm of 0.42 or more, in other embodiment at 0.56 or more, in other embodiment at 0.72 or more, or even in other embodiment at 0.92 or more.

In an embodiment the invention refers to a photo-curable composition wherein the particles used for fill the resin are metal particles having a reflectivity for a wavelength above 760 nm of 0.42 or more, in other embodiment at 0.56 or more, in other embodiment at 0.72 or more, or even in other embodiment at 0.92 or more.

In an embodiment the invention refers to a photo-curable composition wherein the particles used for fill the resin are metal particles having a reflectivity for a wavelength above 860 nm of 0.42 or more, in other embodiment at 0.56 or more, in other embodiment at 0.72 or more, or even in other embodiment at 0.92 or more.

In an embodiment chosen wavelength is above 460 nm, in other embodiment above 560 nm, in other embodiment above 760 nm, and even in other embodiment above 860 nm.

In an embodiment the resin used is filled with more than 6% by volume of particles, in other embodiment more than 12% by volume, in other embodiment more than 23% by volume in other embodiment more than 42% by volume, in other embodiment more than 52% by volume, in other embodiment more than 62% by volume, in other embodiment more than 72%, in other embodiment more than 82% by volume, in other embodiment more than 86% by volume, and even in other embodiment more than 94%.

In an embodiment the photo-curable composition further comprises a photo-initiator.

In an embodiment resins used have a curing times of 0.8 seconds or less, in other embodiment 0.4 seconds or less, in other embodiment 0.08 seconds or less and even in other embodiment 0.008 seconds or less.

In an embodiment the photo-curable composition further comprises a other components such as solvents, dispersants, binders, resins, radiation absorbers, additives, and other required components for each specific application

In an embodiment a powder mixture containing one or more metallic powder is used for filling the resin.

In an embodiment any of previously described powder mixtures through this document is suitable for filling the resin used in the method of manufacturing a component using stereolitography.

In an embodiment the invention refers to a method of manufacturing components using stereolitography wherein the resin used is curable at wavelengths above 460 nm, in other embodiment above 560 nm, in other embodiment above 760 nm, in other embodiment above 860 nm.

The inventor has seen can also be made with the method of the present invention manufacturing techniques involving photo-curable polymers especially for fast and thus deposition. This is especially so because the results of curing short exposure of the polymer to a certain wavelength (and where often the inhibition of the reaction can be used to provide extra speed and flexibility in design) can be achieved often with a method of exposure to the desired wavelength based on a surface at a time, rather than the traditional, cylindrical or elliptical cursor just follow the perimeter or surface to be cured in each layer. You can even use very favorably systems that expose the entire layer at a time with the desired pattern.

For some applications the index of reflection and refraction are both important. In some of these applications the effect of both should be assessed, for which the R parameter is interesting: R=reflection index particle−ABSOLUTE VALUE [particle refractive (indice refraccion) index−refractive index resin].

In an embodiment the resin and material used for filling the resin are chosen based in its reflection and refraction index at a wavelength above 460 nm.

In an embodiment the invention refers to a photo-curable composition wherein the particles and resin have a value of parameter R 0.12 or more, in other embodiment more than 0.42, in other embodiment more than 0.62 and even in other embodiment than 0.82.

In an embodiment the value of R parameter for the filled resin is 0.12 or more, in other embodiment more than 0.42, in other embodiment more than 0.62 and even in other embodiment than 0.82.

In an embodiment for a wavelength the value of R parameter for the filled resin is 0.12 or more, in other embodiment more than 0.42, in other embodiment more than 0.62 and even in other embodiment than 0.82.

In an embodiment for a wavelength above 460 nm the value of R parameter for the filled resin is 0.12 or more, in other embodiment more than 0.42, in other embodiment more than 0.62 and even in other embodiment than 0.82.

In an embodiment for a wavelength above 460 nm the value of R parameter for the filled resin is 0.12 or more, in other embodiment more than 0.42, in other embodiment more than 0.62 and even in other embodiment than 0.82.

In an embodiment for a wavelength above 560 nm the value of R parameter for the filled resin is 0.12 or more, in other embodiment more than 0.42, in other embodiment more than 0.62 and even in other embodiment than 0.82.

In an embodiment for a wavelength above 760 nm the value of R parameter for the filled resin is 0.12 or more, in other embodiment more than 0.42, in other embodiment more than 0.62 and even in other embodiment than 0.82.

In an embodiment for a wavelength above 860 nm the value of R parameter for the filled resin is 0.12 or more, in other embodiment more than 0.42, in other embodiment more than 0.62 and even in other embodiment than 0.82.

In an embodiment R value is determined as the difference between the reflection index of the particles and the absolute value of the difference between the refractive index of the particles and resin.

In an embodiment for photo-curable compositions wherein the resin is filled with more than one particle, such as for example different metallic components, metallic components and ceramic components or any other possible load, R value is calculated individually for each component filled in the resin, and each value individually shall be 0.12 or more, in other embodiment more than 0.42, in other embodiment more than 0.62 and even in other embodiment than 0.82.

In an embodiment when particles contain different metallic, ceramic and/or organic compounds, those which are less than 29% by volume, these particles being less than 19% by volume of the photo-curable composition, in other embodiment less than 9%, in other embodiment less than 4%, in other embodiment less than 1.8%, and even being less than 0.1% are not taken into account for calculate R value.

For some interesting applications it has been observed that the particle, resin and wavelength system must be chosen in such a way that the R parameter is greater than 0.12, preferably greater than 0.42, more preferably greater than 0.62 and even greater than 0.82 system.

In an embodiment the invention refers to a method of manufacturing components using stereolitography wherein the resin used is filled with particles characterized in that R parameter is 0.12 or more, in an embodiment 0.42 or more, in an embodiment 0.62 or more, and even in an embodiment 0.82 or more.

In an embodiment for resins filled with more than 22% particles, and particles with low reflectivity for radiation in UV are near visible UV, use a wavelength lower than 510 nm,

For many applications of the present invention the inventor has found that it is surprisingly convenient to prioritize particle-resin-wavelength systems where the reflection rate increases even if it is at the cost of greater refractive index difference of particle and resin. In this sense for many systems and particularly when loads of particles are high (greater than 22% by volume) and particularly for particles with a low reflectivity for radiation in the ultraviolet (UV) and/or near visible ultraviolet (lower wavelengths at 510 nm) it is often desirable or even necessary in the present invention to move away from conventional cure systems with ultraviolet radiation or visible radiation close to UV. For some of these systems the inventor has found that curing in between visible and near infrared (wavelengths greater than or equal to 510 nm), near infrared (NIR) or higher wavelengths is very convenient.

A particular application of the present invention is the additive manufacturing og highly loaded resins sensitive to high wavelength radiation, and the manufacture of the resins themselves. In this regard, resins are understood to be curable by radiation with wavelengths above 460 nm, preferably above 560 nm, more preferably exceeding 760 nm and even higher than 860 nm. For a resin to be curable at these wavelengths, it is often required that the monomer or monomers (which may also be oligomers) chosen allow polymerization with these wavelengths when a photoinitiator sensitive to these wavelengths is used (in the following paragraphs some examples are provided). In this regard, the term loaded resins is often applied to resins that have a particle suspension (primarily metallic and/or ceramic, but may also be other functional particles as nanotubes, graphene, cellulose, glass fibers or carbon, etc. That is any particle or solid) phase where the content by volume of said particles is more than 6%, preferably more than 12%, more preferably more than 23% or even above 42%. For some applications, such as the often case of applications where the resin is removed and the particles are consolidated in order to obtain a high densification, it is desirable to use resins with higher loading, in some embodoments 52% or more in volume or more preferably greater than 62%, more preferably greater than 72% and even more than 82%, in fact for some of these applications, when the viscosity is not excessively high and the curing is enough, higher loads are preferred, in some cases even higher than 86% by volume and even higher than 91%.

Longer wavelengths present a greater penetration capability. For some applications it is interesting to have a high flexibility in the geometry produced. In this sense, the inventor has found that a system based on local modulation of the radiation system is very advantageous in order to have different exposure levels in different places (often levels of exposure in production systems layer by layer) [Examples: CCD, DLP, . . . ]. Once the light is modulated, it can be converted (systems with luminescent materials), diverted (with mirrors or other), diffracted, concentrated or dispersed according to the definition required for the particular application (often with lenses), or any other action that it can be done with optical or electronic systems to modify the radiation expediently. Thus although it is not difficult to have radiation sources in the NIR such as diodes, it is not necessary since the generation of the modulation can be done at a wavelength different from the wavelength used for curing. What is important is to have a resin system that cures in the chosen wave length. There are many researches that are relevant to resins, photo-initiators and loaded with specific ceramic (Al2O3, SiO2 and COH) for curing the UV and/or visible next to ultraviolet resins, but almost nothing for higher wavelengths. In this sense, the inventor has found that it is often a problem of lack of interest since at a first glance these systems didn't seem interesting, therefore the difficulty of finding resins and photo-initiators once it is discovered that type of systems may be indeed interesting, especially for certain resins loaded with particles in which the material has a reflectivity higher in these wavelengths than the UV. As an illustrative example, a system of this type is formed by a resin based on phthalic diglycol diacrylate (PDDA) a cationic photoinitiator based cyanine dye-borate (1,3,3,1′,3′,3′-hexamethyl-11chloro-10,12-propylenetricarbocyanine triphenylbutylborate), with the corresponding solvents, dispersants, binders, resins, radiation absorbers, additives, and other required components for each specific application. Any other example could have been chosen to illustrate a valid system for the present invention. The inventor has found that it is important for the implementation of the present invention that the system chosen present enough conversion to exposure dose to the length/wavelengths chosen. In this respect the inventor has found that in some applications of the present invention, it is desirable to have a higher conversion to 42%, preferably higher than 52% more preferably exceeding 62% and even more than 82%. Especially for advanced systems based on stereo-lithography and specially trained to work with viscous suspensions, it would be possible to work with conversions not very high, in some embodiments greater than 16% conversion may be sufficient, preferably greater than 22%, more preferably greater 32% and even more than 36%. This is also the case of some other system. In several applications, the inventor has found that it is very important that the level of critical conversion is achieved with a suitable dose, in this sense 290 mJ/cm2 (intensidad de radiacion) or less, preferably 90 mJ/cm2 or less, more preferably 40 mJ/cm2 or and even less 6 mJ/cm2 or less. For some applications it has been found that it is important to achieve acceptable curing (as described above) with a moderate radiation power, for these applications powers of 89 mW/cm2 or less are desirable, preferably 19 mW/cm2 or less, more preferably 8 mW/cm2 or less or even 0.8 mW/cm2 or less. For some applications it has been found that it is important that the cured indicated in the above lines is measured at a certain depth. For these applications it is often desirable that the conversion level indicated (with or without dose constraints or radiation power) occurs at a depth of 2 microns or more, preferably 26 microns or more, more preferably 56 microns or more or 106 microns or even more.

In an embodiment the resin is phthalic diglycol diacrylate (PDDA) a cationic photoinitiator based cyanine dye-borate (1,3,3,1′,3′,3′-hexamethyl-11chloro-10,12-propylenetricarbocyanine triphenylbutylborate), with the corresponding solvents, dispersants, binders, resins, radiation absorbers, additives, and other required components for each specific application.

In an embodiment conversion refers to a volume of resin cured.

In an embodiment conversion is above 42%, in other embodiment higher than 52%, in other embodiment exceeding 62% and even in other embodiment more than 82%.

In an embodiment conversion is above 42%, in other embodiment higher than 52%, in other embodiment exceeding 62% and even in other embodiment more than 82% when using a radiation intensity of 290 mJ/cm2.

In an embodiment conversion is above 42%, in other embodiment higher than 52%, in other embodiment exceeding 62% and even in other embodiment more than 82% when using a intensity of 90 mW/cm2 or less.

In an embodiment conversion is above 42%, in other embodiment higher than 52%, in other embodiment exceeding 62% and even in other embodiment more than 82% when using intensity of 40 mJ/cm2 or less.

In an embodiment conversion is above 42%, in other embodiment higher than 52%, in other embodiment exceeding 62% and even in other embodiment more than 82% when using intensity of 6 mJ/cm2 or less.

In an embodiment the radiation power used is 89 mW/cm2 or less, in other embodiment 19 mW/cm2 or less, in other embodiment 8 mW/cm2 or less or even in other embodiment 0.8 mW/cm2 or less.

In an embodiment the radiation intensity is 290 mJ/cm2 or less, in other embodiment 90 mJ/cm2 or less, in other embodiment 40 mJ/cm2 or less and even in other embodiment 6 mJ/cm2 or less.

For some applications of the present invention, the components are subjected to different types of post processed, indeed any post-processing or post-processed sequence that makes sense can be applied. A fairly typical post-processing involves resin removal and compacting of particles contained in the resin. In many applications it is not determinant which medium is used for resin removal (for example, dissolution, etching, thermal decomposition, . . . ) and/or consolidation of the particles (sintered, HIP, liquid infiltration, . . . ). The post-processing applied can be very diverse, from surface conditionings (polished electro-chemical, tribo-mechanical or any other combination, machined, blasted, . . . ) to mass or surface thermal treatments, coatings, etc. The inventor has found that in some applications with post-processing removal and consolidation resin particle, what is important is the bulk density of the component just after removal of the resin and before consolidation of particles. In this respect it has been found that for some of these applications it is desirable to set a bulk density of 45% or more, preferably 56% or more of, more preferably 68% or more even 82% or more. For some applications, especially for those with particles of low melting and/or liquid phase sintering, it is often necessary to fix the filler content of the resin and the process parameters, including elimination of the resin to have a bulk density of 63% or more, preferably 73% or more, more preferably 86% or more or even 92% or more, when the resin has lost its ability to retain the shape of the workpiece and before proceeding to consolidated at elevated temperatures (if applicable). In some applications it is especially important to set the parameters to ensure avoid excessive compaction before sintering, in this sense it is necessary for these applications to set the tap density to 93% or less, preferably 88% or less, more preferably 78% or less or even 58% or less. For some applications it is interesting to formulate the resin in such a way that it is disposed without waste, however in other applications it is interesting that the resin release any alloying element or reactive with the particles or their surface oxides (or other compounds).

The inventor has seen that for some applications is important to control the amount of particles filling the resin system. For some applications the total amount of solid particles have to be controlled. In these cases sometimes the volume fraction is important while in other applications what is important is the content by weight. For some applications 42% or more by volume, preferably 52% or more one, more preferably 62% or more and even 72% or more is required. For some applications the important thing is the amount of the particles of the major species, for others however what matters is the total amount.

For some applications it is more appropriate to set the percentage by weight of particles or the majority of particles.

The inventor has found that for some applications, especially when the particle content is especially high, it may be desirable to use any medium for dispersing particles, in this regard the use of more appropriate medium primarily depends on the type of particle and resin used. Examples of particles dispersants are pH adjusters, electro-steric dispersants, hydrophobic polymers, or cationic colloidal dispersants, etc.

The inventor has found that for some applications, the viscosity of the loaded resin system is of great importance. Often, an excessively high viscosity leads to the formation of uncontrolled porosities and other geometric defects during the selective curing. It can be mediated by using systems that are specially prepared to work with highly viscous resins, such as systems using pressurized gas or mechanically activated systems and even also with systems that have an arm for spreading the resin especially if the resin is degassed. In any case it can be interesting to use a diluent to lower the viscosity. There are many potential diluents and any of them can be suitable for a particular application. Examples: phosphate ester monomers such as styrene, . . . .

For some applications it is even possible to use systems with resins or polymers that can be selectively cured by a different system to that of direct radiation exposure such as systems with blocking masks, masks activators, chemical activation, thermal, . . . .

Due to the densification mechanism often employed in the present invention, it is interesting for various applications to use hard particles or reinforcement fibers to confer a specific tribological behavior and/or to increase the mechanical properties. In this sense some applications benefit from the use of reinforcement particles with 2% by volume or more, preferably 5.5% or more, more preferably 11% or more or even 22% or more. These reinforcing particles are not necessarily introduced separately, they can be embedded in another phase or can be synthesized during the process. Typical reinforcing particles are those with high hardness such as diamond, cubic boron nitride (cBN), oxides (aluminum, zirconium, iron, etc.), nitrides (titanium, vanadium, chromium, molybdenum, etc.), carbides (titanium, vanadium, tungsten, iron, etc.), borides (titanium, vanadium, etc.) mixtures thereof and generally any particle with a hardness of 11 GPa or more, preferably 21 GPa or more, more preferably 26 GPa or more, and even 36 GPa or more. On the other hand, mainly in applications that benefit from increased mechanical properties, they can be used as reinforcing particles, any particle which is known which can have a positive effect on the mechanical properties as fibers (glass, carbon, etc.), wiskers, nanotubes, etc.

In an embodiment the invention refers to a method for the production of at least partially metal components, comprising the following steps:

a. Preparation of a radiation polymerizable resin, loaded with a particle content of 42% by volume or more.

b. Choosing at least one wavelength for curing the loaded resin to which the particles wavelength and resin system characterized by:
R>=0.12 and/or reflectivity of the majority particles of 0.42 or higher;

c. Choosing components unfilled resin (no dispersed particles) according to the wavelength selected in the previous section, so that the resin system uncharged and chosen wave length characterized by:
A conversion of 42% or more for a dose of 40 mJ/cm2 or less.

d. Producing a component through selective polymerization of the charged resin.

In an embodiment the method further comprises the steps:

e. Removal of the resin by pyrolysis or chemical dissolution.

f. Subjecting the component to a consolidation process of particles like. sintering or homolog—

In an embodiment the component is submitted to a process of polishing, electro-chemical, chemical, thermal and/or mechanical.

In an embodiment the loaded curable resin with 12% by volume or more particle cured by radiation, is characterized in that:
There is Metal particles containing aluminum, magnesium or other metal with a reflectivity of ultraviolet radiation of 0.42 or higher
And/or resin contains photoinitiators and/or monomers (or oligomers) sensitive to radiation of 460 nm or higher.

In an embodiment selective polymerization of the resin loaded with particles is performed layer by layer, simultaneously polymerizing a surface rather than a line or point.

In an embodiment selective polymerization is performed by a DLP system.

In an embodiment the green component obtained after stereolithography may be submitted to any of the post processing treatments disclosed in this document.

In an embodiment the invention refers to a method of manufacturing a metallic or at least partially metallic component by shaping a powder mixture comprising at least a metallic powder using an AM technique consisting on a Ink-jetting system. In an embodiment less than 2 seconds are needed to cure a 1 micron layer of the thermo-setting polymer, preferably less than 0.8 seconds, more preferably less than 0.4 seconds, and even less than 0.1 seconds.

In an embodiment the invention refers to a method of manufacturing a metallic or at least partially metallic component by shaping a powder mixture comprising at least a low melting point metallic powder and a high melting point metallic powder and a thermo-setting polymer using an AM technique consisting on a Ink-jetting system, in an embodiment less than 2 seconds are needed to cure a 1 micron layer of the thermo-setting polymer, preferably less than 0.8 seconds, more preferably less than 0.4 seconds, and even less than 0.1 seconds.

In an embodiment the shaping technique used is ink-jetting system. In an embodiment the organic material is a thermosetting polymer.

In an embodiment the technique used for shaping the powder mixture is using Ink-jetting.

In an embodiment the technique used for shaping the powder mixture is using Ink-jetting wherein a DLP (Direct Light Processing) projector shining the appropriate wavelength on the intended “pixels” of the layer manufactured at that point in time.

In an embodiment the invention refers to a method of manufacturing metallic or at least partially metallic component using Ink-jetting.

In an embodiment when using DLP, a resin is filled with the powder mixture.

In an embodiment the invention refers to a method for manufacturing objects using a DLP (Direct Light Processing) projector shining the appropriate wavelength on the intended “pixels” of the layer manufactured at that point in time.

In an embodiment the invention refers to a method for manufacturing a component using a DLP (Direct Light Processing) projector shining the appropriate wavelength on the intended “pixels” of the layer manufactured at that point in time.

The powder mixtures disclosed in this document are especially suitable for use with this technique involving a DLP (Direct Light Processing) projector shining the appropriate wavelength on the intended “pixels” of the layer manufactured at that point in time.

Given that fast AM processes for the shaping of polymers can be quite advantageous for some instances of the application of the present invention, any fast AM process of organic materials where a metallic particulate filling of the feedstock is possible is advantageous for the present invention, even fast manufacturing processes which are not considered AM. A couple such processes will be described to serve illustrative purposes. Firstly, in the photo-curing family of AM processes, speed can easily be gained through the projection of light patterns in a plain, to achieve plane by plane simultaneous curing. So in every step a whole pattern of light (or other relevant wavelength for the chosen resin) is applied to the surface to be shaped in that very moment, achieving a simultaneous curing of the whole shape intended in the layer that is being processed at that very moment. This can be achieved amongst others trough the usage of a system resembling a DLP (Direct Light Processing) projector shining the appropriate wavelength on the intended “pixels” of the layer manufactured at that point in time. Also supplementary techniques can be used to add further flexibility on the geometrical complexity that can be attained. One example can be the usage of photo-polymers where the curing reaction can be impeded by some means, p.e. oxygen presence, even on the event of exposure to the proper wavelength for curing. In such example, quite complex geometries can be achieved in a very fast way. The metallic constituents are often in suspension in the resin bath. In the case of a “projector type” system where a whole area is cured at once, the inventor has seen that for some instances of the present invention it is advantageous to use a system with many pixels, in such instances it is desirable to have 0.9M (M stands for million) pixels or more, preferably 2M or more, more preferably 8M or more and even 10M or more. The inventor has noticed that for some large components the resolution does not need to be too high, and thus fairly large pixel sizes are acceptable at the surface where curing is taking place. Fur such cases a pixel size of 12 square microns or more, preferably 55 square microns or more, more preferably 120 square microns or more and even 510 square microns or more. On the other hand some components require a higher resolution and thus aim at pixel sizes of 195 microns or less, preferably 95 microns or less, more preferably 45 microns or less and even 8 microns or less. The inventor has seen that for large components or components where very high resolution is desired, it is advantageous to have a matrix of such projection systems to cover a bigger area, or a single projector that sequentially displaces to the different points of the matrix, taking several exposures for every manufactured layer. The source of light (visible or not, that is to say whatever the wavelength chosen) can also be another than DLP projector as long as it is capable to do Continuous Printing, or at least simultaneous curing in several points of the curing surface. The inventor has seen that for the sake of speed amongst others it is for some applications advantageous to have a high density of proper photons reaching the resin surface. In this sense it is for some applications advisable to have a light source with high luminesce power in the right spectra, namely the wavelengths appropriate for the curing of the resin employed. Often 1100 lumens or more in the spectra with capability to cure the employed resin can be desired, preferably 2200 lumens or more, more preferably 4200 or more and even 11000 or more. For the sake of cost optimization it can be recommendable to have light sources with most of the emitted light in the wavelength with potential to cure the employed resin, for some applications it is desirable 27% or more, preferably 52% or more, more preferably 78% or more and even 96% or more. The inventor has seen that it is also interesting for some applications to employ photon intensifiers, desirably with an overall photon gain of 3000 or more, preferably 8400 or more, more preferably 12000 or more, more preferably 23000 or more and even 110000 or more. The inventor has seen that it is often interesting in such cases to use photocathodes with a quantum efficiency of 12% or more, preferably 22% or more, more preferably 32% or more, more preferably 43% or more and even 52% or more in the (efficiency is the maximum efficiency within the wavelength range that can cure the resin employed in an efficient way). For some applications photocathodes based on GaAs and even GaAsP are particularly advantageous. The inventor has seen that then fast curing resins can be employed in this aspect for such applications curing times of 0.8 seconds or less, preferably 0.4 seconds or less, more preferably 0.08 seconds or less and even 0.008 seconds or less can be desirable. When such photon densities and/or fast curing resins are employed, then high framerate projectors or in more generalized way pattern selectors are often desirable. 32 fps or more, preferably 64 fps or more, more preferably 102 fps or more and even 220 fps or more. The inventor has seen that the approaches described in this paragraph are also very interesting when used on an organic material or several, without the necessary inclusion of metallic phases, and where the manufactured component might or might not have a post-treatment including exposure to certain temperatures.

In an embodiment the light sources for curing a resin are 1100 lumens or more in the spectra with capability to cure the employed resin, in other embodiment 2200 lumens or more, in other embodiment 4200 or more and even in other embodiment 11000 or more.

In an embodiment resins used have a curing times of 0.8 seconds or less, in other embodiment 0.4 seconds or less, in other embodiment 0.08 seconds or less and even in other embodiment 0.008 seconds or less.

In an embodiment in DLP (Direct Light Processing) pattern selectors are desirable. 32 fps or more, in other embodiment 64 fps or more, in other embodiment 102 fps or more and even in other embodiment 220 fps or more.

In an embodiment in DLP (Direct Light Processing) for some applications it is also interesting to employ photon intensifiers, with an overall photon gain of 3000 or more, in other embodiment 8400 or more, in other embodiment 12000 or more, in other embodiment 23000 or more and even in other embodiment 110000 or more.

In an embodiment in DLP (Direct Light Processing) for some applications it is also interesting to use photocathodes with a quantum efficiency of 12% or more, in other embodiment 22% or more, in other embodiment 32% or more, in other embodiment 43% or more and even in other embodiment 52% or more.

Especially when high curing speeds are employed, but also in general for several applications of the method of the present invention, it is sometimes advantageous in the present invention to help the bed of material being manufactured flow. This is particularly the case also when using fluids with high viscosities (like, as an example, photocurable resins with metallic particulate additions). Several techniques can be employed to make the material flow to where it should (as when a layer has been finished and the manufactured component is displaced and the material being manufactured has to flow to fill the open void). In this cases the inventor has seen that technologies based on the suction or pressurizing of the bed or bath are very advantageous. Pressurization can be done with a gas, or a plate that has a dead weight or an actuator, amongst others. Suction can be implemented with a vacuum system and a selective membrane, amongst others.

Another example arises with the deposition by projection of a polymer which has been activated (often simply by heating it up), so that it bonds as it gains contact with the manufactured part. In such case if precision requirements are not high a fast speed can be achieved. The mechanical characteristics normally attained are rather poor for AM standards but the inventor has surprisingly seen that the tradeoff speed increase at the expense of mechanical properties of the piece while bond by the polymer is often very advantageous for the present invention, since practically it suffices for shape retention to be assured. In the same way taking advantage that mechanical properties of the polymer after the shaping process are not so important, several AM new processes come into consideration, in fact any that has the required accuracy, assures shape retention and is fast or otherwise cost effective. The inventor has also observed that in the present invention many geometries that cannot be considered for AM with the existing technologies can be economically manufactured with the method of the present invention, and surprisingly many such components have far less stringent accuracy requirements than the typical geometries considered for AM. So for several applications of the present invention AM processes trading accuracy and mechanical properties of the bound polymer for increased speed are very interesting, such technologies do not come into consideration for conventional AM. As said the concepts applicable are too many to attempt any listing. One last example of such concept is the projection of photo-curable polymer powder which has embedded the corresponding metallic constituents and which is polarized and projected against the building area which is electrically charged to attain a good surface distribution of the powder due to the electrostatic effect, then the desired pattern of light for that layer is projected to bond the intended powder, the piece id discharged and the not bound powder sucked or blown away, to proceed with the next layer in the same manner.

In an embodiment the invention refers to the projection of photo-curable polymer powder embedded with metallic constituents which is polarized.

In an embodiment the photo-curable polymer powder is embedded with the powder mixture containing at least one metallic powder.

In an embodiment the photo-curable polymer powder is embedded with the powder mixture containing at least two metallic powders.

In an embodiment the photo-curable polymer is projected against the building area which is electrically charged.

Regardless of the system used to obtain the desired geometry, in many cases, the system resin+metal particle compositionally optimized for a particular application, constitutes in itself an invention.

The claims describe further embodiments of the invention.

Any of the above-described embodiments can be combined with any other embodiment herein described in any combination, to the extent that the respective features are not incompatible.

The inventor has seen that an embodiment of the present invention arises when the present invention is implemented in a way that the powder, or mixture of powders has a minimum velocity or a minimum kinematic energy when reaching the component being manufactured. This is specially the case for the embodiments of the present invention where at least one powder phase is used where such powder phase is above 0.35*Tm when reaching the projection surface (Tm here refers also to the melting temperature of the phase in absolute temperature scale Kelvin). In an embodiment, the temperature is higher than 0.52*Tm, in another embodiment higher than 0.62*Tm, in another embodiment higher than 0.84*Tm, and even in another embodiment higher than Tm. In this realization, the powder is accelerated by some means (a typical example would be an accelerated gas like in a thermal spray or cold spray system, or a mechanical system like an impeller wheel among others) and projected towards the surface to be built. This kind of systems belong to the solid-state deposition processes that encompasses a variety of coating processes in which metals, polymers, ceramics, cermets, and other materials are applied onto a substrate, which in turn can be a metal, polymer, ceramic and/or a combination thereof. In an embodiment, these systems can be used as shaping methods for the material of the present invention.

One of this type of process is the thermal spray process which involves heating a material to its molten or semi-molten state and propelling it against a substrate in order to produce a suitably adherent coating. There are five different types: i) powder combustion; ii) wire (rod) combustion; iii) twin-wire arc;

iv) plasma arc; v) high velocity oxy/fuel. The coatings produce by thermal spraying allow providing corrosion protection to iron-based metals and in other cases they also provide significant improvements in what respect to wear resistance and/or thermal conductivity. The mixture of powders of the present invention can be used accordingly in any of variants of the thermal spray methods or any other similar method developed or to be developed.

Another type of these processes is cold spray, in which the kinetic energy from propelling allows to produce a dense coating or freeform at relatively low temperatures. In a certain embodiment, the material particles have a ballistic impingement on the substrate at a speed equal to 300 m/s or below, in other embodiments 500 m/s or below, in other embodiments 800 m/s or below, in other embodiments 1000 m/s or below, in other embodiments 1200 m/s or below, and even in other embodiments 2500 m/s or below.

In an embodiment, the solid powders are accelerated in a “De Laval” nozzle toward a substrate. In another embodiment, the solid powders are accelerated by means of any other accelerated device. The “De Laval” nozzle is also called a convergent-divergent nozzle and it consist on a tube that is pinched in the middle, making a carefully balanced, asymmetric hourglass shape. When the particles exceed a certain threshold value of impact velocity they suffer plastic deformation and adhere to the surface of the substrate. Contrarily to thermal spraying, cold spraying uses kinetic rather than thermal energy in order to carry out deposition and formation of coating. The predominant bonding mechanism in cold spraying is attributed to thermal softening in competition with rate effects and work hardening. Besides causing bonding, work hardening favors distortion of grain structure and dislocations. The heat generated by plastic work softens the material and at a certain point thermal softening dominates over work hardening such that eventually stress falls with increasing strain. As a result, the material becomes locally unstable and additional imposed strain tends to accumulate in a narrow band. Therefore, both mechanical and thermal properties of the powder material are important in particle-substrate bonding.

Taking into account the abovementioned, these types of metal projection techniques can attain quite significant deposition rates but pose quite some limitations when rather massive components are to be build. One of the major challenges resides in the managing of the induced thermal stresses mentioned above. The high temperature thermal spray systems allow to work with a big range of projected materials, but the thermal stresses originated trough the solidification and rather fast temperature drop once the projection surface is reached, make it difficult to attain big deposition thicknesses and to realize very complex surfaces. Alternatively, cold spraying can be managed with less thermal stresses but is very difficult to implement with materials which are not highly deformable, and also for very thick builds and complex shapes, residual stresses remain an issue. During cold spraying, plastic deformation is accompanied by a large number of dislocations, which can also spawn from existing dislocations, and from defects, grain boundaries and surface irregularities.

Within this realization a particularly interesting embodiment results when at least one of the low melting point powders of the present invention is used together with at least one powder with higher melting point. In another embodiment of this realization at least one low melting point powder of the present invention is used. Depending on the low melting point powder used, room temperature or slightly over room temperature temperatures can suffice to realize a sufficiently consistent build. In an embodiment 48° C. or less, in another embodiment 95° C. or less, in another embodiment 140° C. or less, in another embodiment 190° C. or less, and even in another embodiment 380° C. or less. As it will be further explained below, in an embodiment of this realization it is interesting to hold the component being built at a specific temperature, low enough so there is form retention and self-diffusion yet high enough so that there is restoration at least in one of the highly deforming phases. Restoration allows to enhance dislocation motion for relieving internal strain energy which in turn restores some material's properties such as electrical and thermal conductivity. The building of the component at a certain temperature must be controlled in order to avoid the excessive formation of a liquid phase and hence slumping. In an embodiment, the deformation of one of the metallic phases might be enough for consolidate the component and carry out diffusion. In order to avoid the formation of an oxide layer, the process should be performed in a protected atmosphere.

There are currently two main types of cold spray systems, the high and low pressure type. In the former the particles are injected prior the spray nozzle throat from a high-pressure gas supply while in the latter the powders are injected in the diverging section of the spray nozzle from a low-pressure gas supply.

In both types of cold spraying systems, the temperature of the gas stream is always below the particle material's melting point. In a certain embodiment, the temperature of the gas stream is below 48° C., in another embodiment below 95° C., in another embodiment below 140° C., in another embodiment below 190° C., and even in other embodiments below 380° C.

The nozzle operation is very important for both low and high pressure systems, and a careful attention should be paid in order to control severe wear and clogging, especially in high pressure systems. In fluid dynamics, the Mach number (Ma) allows representing the ratio of flow velocity past a boundary to the local speed of sound. Thus, the nozzle designed should be restricted to an exit Mach number equal to or below 1.2, in other embodiments equal to or below 2.1, in other embodiments equal to or below 3.1, and even in other embodiments equal to or below 4.2.

The inlet pressure is also restricted, in an embodiment equal or below 5.2 MPa, in another embodiment equal or below 2.9 MPa, in other embodiments equal or below 1.9 MPa, and even in other embodiments equal or below 0.9 MPa.

Increasing the temperature of the powder mixture will result in a decrease of the critical velocity and a higher level of plastic deformation. In a certain embodiment, the temperature of the particle can be pre-heated to an intermediate temperature of 0.92*Tm or above, in other embodiments to 0.78*Tm or above, in other embodiments 0.56*Tm or above, in other embodiments 0.48*Tm or above, in other embodiments 0.37*Tm or above and even in other embodiments 0.15*Tm or above, where Tm is the average melting point temperature of the low melting point metallic powder as described through this document.

In another embodiment, the temperature of the particle can be pre-heated to an intermediate temperature of 0.92*Tm or above, in other embodiments to 0.78*Tm or above, in other embodiments 0.56*Tm or above, in other embodiments 0.48*Tm or above, in other embodiments 0.37*Tm or above and even in other embodiments 0.15*Tm or above, where Tm is the lowest melting point temperature of metallic powder mixture as described through this document.

In another embodiment, the temperature of the particle can be pre-heated to an intermediate temperature of 0.92*Tm or above, in other embodiments to 0.78*Tm or above, in other embodiments 0.56*Tm or above, in other embodiments 0.48*Tm or above, in other embodiments 0.37*Tm or above and even in other embodiments 0.15*Tm or above, where Tm is temperature of the metallic powder mixture as described through this document.

Another variation of the process considers placing the substrate specimen in a vacuum tank with a pressure that is substantially less than the atmospheric pressure (Pa), in a certain embodiment equal or less than 0.98*Pa, in another embodiment equal or less than 0.75*Pa, in another embodiment equal or less than 0.56*Pa, in another embodiment equal or less than 0.45*Pa, and even in another embodiment equal or less than 0.28*Pa.

In another embodiment, the propellant gas pressure (Pg) might be below the atmospheric pressure (Pa) to 0.98*Pa or less, in another embodiment 0.75*Pa or less, in another embodiment 0.56*Pa or less, in another embodiment 0.45*Pa or less, and even in another embodiment 0.28*Pa or less.

The interaction of the impinging particle and the substrate interaction during the deposition process and the resultant bonding is of great importance. The characteristics of the material of the present invention allows to enhance the process carried out during metal projection systems such as cold spraying, thermal spraying, etc. This is because the bridging effect promoted by the present invention allows consolidating the mechanical anchorage of particles after the plastic deformation. When the impinging particles are maintained at a certain temperature (the possibilities of temperature and pressure combinations are included in the present invention although other variations not covered by the present state of the art that might be developed in the future are also considered with the method of the present invention) and the specimen that is formed is also maintained a certain temperature (Ts), residual stresses are significantly reduced, which aid to build dense coatings and components such as the three dimensional parts. In an embodiment Ts is equal or above 0.16*Tm, in another embodiment is 0.41*Tm or above, in another embodiment is 0.52*Tm or above, in another embodiment is 0.62*Tm or above, and even in another embodiment is 0.82*Tm, where Tm refers to melting temperature of the low melting point alloy.

In order to reduce the thermal gradients and residual stresses of metal projection techniques (cold spray, thermal spray, etc.), laser metal deposition methods were developed. The most representative methods are direct metal deposition (DMD) and the LENS™ process. DMD is a laser cladding process that involves using a beam from a high power laser for creating a melt pool on the surface of a solid substrate into which a metallic powder is injected. The most influential parameters of DMD are powder mass flow rate, feed rate, and laser power. Because of the advantages with respect thermal gradients and stress relieve, the material of the present invention is very suitable for laser deposition methods.

In a certain embodiment of the present invention, the mass flow rate of the powder mixture of the present invention is equal to 0.5 g/min or above, in another embodiment is 1.1 g/min or above, in another embodiment is 2.9 g/min or above, in another embodiment is 6.5 g/min or above, and even in another embodiment 10.5 g/min or above.

In an embodiment, the method of the present invention allows working at low temperatures of the melt pool.

In another embodiment, when Fe, Mo, and/or W alloys described in this document are used, the temperature of the melt pool may be 1390° C. or below, in another embodiment 1220° C. or below, in another embodiment 990° C. or below, in another embodiment 490° C. or below and even in another embodiment 190° C. or below.

In another embodiment, when Ti and/or Ni alloys described in this document are used, the temperature of the melt pool may be 1090° C. or below, in another embodiment 940° C. or below, in another embodiment 840° C. or below, in another embodiment 490° C. or below and even in another embodiment 190° C. or below.

In another embodiment, when Cu alloys described in this document are used, the temperature of the melt pool may be 980° C. or below, in another embodiment 740° C. or below, in another embodiment 540° C. or below, in another embodiment 390° C. or below and even in another embodiment 190° C. or below.

In another embodiment, when Al and/or Mg alloys described in this document are used, the temperature of the melt pool may be 590° C. or below, in another embodiment 440° C. or below, in another embodiment 340° C. or below, and even in another embodiment 190° C. or below.

In a certain embodiment, the feed rate of powder is 150 mm/min or below, in another embodiment is 250 mm/min or below, in another embodiment 450 mm/min or below, and even in another embodiment 700 mm/min or below.

As described above, in an embodiment, the method of the present invention allows working with lower temperatures than conventional processes, thus not too excessive laser systems may be used. In an embodiment a laser power of 500 watts or below, in another embodiment 1500 watts or below, in another embodiment 2000 watts or below, in another embodiment 2500 watts or below, in another embodiment 3000 watts or below, and even in another embodiment 4000 watts or below.

The abovementioned parameters are in any case a limitation of the present invention and can be also applied to other laser deposition methods.

In another embodiment of the present invention, the Laser Engineered Net Shaping (LENS™) can also be used with the material of the present invention. The LENS™ process is a type of DMD process that uses a stream of powder and a focused laser beam as a heat source to melt the metallic powder and create a solid, three-dimensional object with near net shape full density. In this additive manufacturing process, a part is built by melting metal powder that is injected into a specific location. It becomes molten with the use of a high-powered laser beam. Then, the material solidifies when it is cooled down. The process occurs in a closed chamber with an argon atmosphere. A particularity of this process is that it can produce components with varying composition in either a stepped or graded fashion.

In the LENS™ process, a Neodymium doped Yttria Alumina Garnet (Nd-YAG) solid state laser is used as the energy user. In a certain embodiment, a wavelength of 1064 nm or below is used, in another embodiment 532 nm or below, and in another embodiment 355 nm or below.

The laser is focused onto a metal substrate at a certain radiation. In an embodiment, the method of the present invention allows working with lower temperatures than conventional processes, thus not too excessive laser systems may be used. In an embodiment, the focused laser radiation is 300 watts or below, in another embodiments 450 watts or below, in another embodiment 600 watts or below, and even in another embodiment 750 watts or below.

In an embodiment, different strategies for heating and/or cooling the metallic mixture may be used during laser shaping.

In an embodiment, heating and/or cooling strategies may be carried out by means of the laser heads. In another embodiment, heating and/or cooling may be carried out locally.

In another embodiment heating and/or cooling strategies may be carried out for a certain part of the laser-shaped geometry.

In another embodiment heating and/or cooling strategies may be applied for obtaining a liquid phase.

In another embodiment heating and/or cooling strategies may be applied for relieving the stress caused by the thermal gradients of the process.

In another embodiment heating and/or cooling strategies may be applied for favoring the bridging of metallic elements as described elsewhere in this document.

In a certain embodiment, the metallic powder with the characteristics (particle size distribution and sphericity) disclosed in the present invention is entrained in argon and injected into the molten pool.

Multiple powder nozzles are used and the system is set up such that the intersection points of the powder streams and the laser focus point are coincident. In a certain embodiment of the present invention the number of nozzles is 1 or more, in another embodiment is 2 or more, and even in another embodiment 4 or more.

Once the mixture of powders enters the molten pool it quickly melts and the molten pool expands into a bead of molten metal. The growth of the molten metal bead when coupled with the X-Y motion of the platform results in a layer-by-layer construction where the metal is continuously deposited until the 3D part is formed.

One of the challenges of the conventional process is the absorption of laser wavelength by the material being processes. Due to the fact that the material of the present invention possesses lower thermal requirements (i.e. because it has a low melting temperature then lower heat inputs are required) less losses due to absorption are presented with the material of the present invention.

One problem in this process could be the residual stresses by uneven heating and cooling processes that can be significant in high-precision processes. Like in the metal projection systems mentioned above, the thermal gradients occurring in these processes can be significantly reduced by using at least one of the low melting point powders of the present invention together with at least one powder with higher melting point. Depending on the low melting point powder used, room temperature or slightly over room temperature temperatures can suffice to realize a sufficiently consistent build. In an embodiment 48° C. or less, in another embodiment 95° C. or less, in another embodiment 140° C. or less, in another embodiment 190° C. or less, in another embodiment 380° C. or less, and even in another embodiment 500° C. This temperature requirements are much lower than conventional laser deposition processes (as mentioned above DMD, LENS™), which results in much lower thermal gradients during building, reducing the risk of crack formation. In an embodiment of this realization it is interesting to hold the component being built at a specific temperature, low enough so there is form retention and self-diffusion yet high enough so that there is restoration and stress relieve in at least in one of the highly deforming phases. When the component being formed is maintained at a certain temperature Tc (the possibilities of temperature and pressure combinations are included in the present invention although other variations not covered by the present state of the art that might be developed in the future are also considered with the method of the present invention), the building process is enhanced. In a certain embodiment, Tc is equal or above 0.15*Tm, in other embodiments 0.37*Tm or above, in other embodiments 0.48*Tm or above, in other embodiments 0.56*Tm or above, in other embodiments to 0.78*Tm or above, and even in other embodiments to 0.92*Tm or above, where Tm refers to the average melting temperature low melting point powder.

In an embodiment, the component shaped by the abovementioned metal projection techniques (thermal spray, cold spray, DMD, LENS™, among others) may be subjected to any post-processing method as described through this document as well as by any other post-processing method that may be beneficial to the component.

The claims describe further embodiments of the invention.

Any of the above-described embodiments can be combined with any other embodiment herein described in any combination, to the extent that the respective features are not incompatible.

The present invention relates to a method for the efficient production of metal and/or ceramic parts often using additive manufacturing as an intermediate step. It is especially suitable for components with a complex geometry.

The additive manufacturing methods for ceramic materials are often complex and costly.

In an embodiment the invention refers to the use of an organic mold manufactured using an AM technique, a Polymer shaping technique, such as MIM, and any other technique suitable for mold manufacturing.

In an embodiment the invention refers to the use of an organic mold for manufacturing a metal and/or ceramic material.

In an embodiment the mold is manufactured using an AM technique.

In an embodiment the mold is manufactured using an a, a Polymer shaping technique.

In an embodiment the mold is manufactured using MIM.

In an embodiment the mold has a geometry that is the negative of the part to obtain.

In an embodiment the invention refers to the use of a mold manufactured using any AM technique for producing ceramic components.

Any of the above-described embodiments can be combined with any other embodiment herein described in any combination, to the extent that the respective features are not incompatible.

In an embodiment the invention refers to the use of an organic mold manufactured using any AM technique for producing ceramic components.

The present invention allows to produce parts of complex geometry with organic materials using AM technologies or similar processes by creating a container that has a cavity in a shape such that it allows to obtain a geometrical part made of metal and/or ceramic material after all the stages of the manufacturing process. This organic compound is then used for the molding of metal and/or ceramic material.

Once the cavity is filled with powder, liquid or fluidized mixture among other possibilities, the consolidation of the molding and its removal is carried out. In some embodiments, the extraction is often performed by destructing the mold by pyrolysis or other method.

A key point is the conservation of the form if the organic mold is destroyed, since the degradation temperature of the organic mold is often too low to activate a mechanism for densification or binding of metal and/or ceramic powders inside the mold. The present invention often uses a powder mixture in which at least one type of powder has at least one phase with a not too high melting temperature for promoting solid state diffusion or liquid phase sintering at temperatures in which the shape retention by the organic material of the mold is still possible. Additionally, different paths for the shape retention can be followed such as introducing the mold into a fluidized bed of particles or directly introducing a fluid that fills the space left by the mold destroyed and preventing the destruction of the shape formed by the metallic and/or particles in order to reach the necessary conditions for stabilizing the geometric retention. Also by infiltrating the particles with a fluid acting as binder, this fluid may have a high melting temperature and destroy the organic mold by replacing the space or not (if it destroys the mold then it might be harder to retain some internal geometries in the part to be built). The binder fluid may be another polymer, which may or not be destroyed at a later stage of construction of the piece. For retaining certain geometries, it is not as problematic and it can be achieved with the correct choice and filling density of the metal and/or ceramic powders employed.

The problem of obtaining parts with a metal and/or ceramic basis and very complex geometry at low cost can be solved by building a mold of organic material (this material can include inorganic fillers such as metal particles, intermetallic, ceramic, . . . ) by AM with the geometry of the negative of the piece that is intended to be obtained (in some embodiments the final geometry of the piece may be not necessary at this stage since the resulting part can be post-processed). The model is then filled with metal and/or ceramics particles with the desired filling densities before proceeding to unify the process particles for which various methods can be employed although the present invention highlights some preferred methods for certain applications. It should be noted that throughout this document the term “metal and/or ceramic.” for particles refers to any particle having a phase of metallic, ceramic and/or a material with similar nature (this means that intermetallic composite materials and any other of similar material are also included) (a typical example is that of a hard metal or carbide metal binder, e.g.: the carbides of tungsten, vanadium, tantalum, molybdenum, chromium, niobium, titanium, zirconium, hafnium and/or mixed carbides, nitrides and/or borides of the aforementioned elements and/or mixtures in-nitro-boride carbo system without forgetting boron nitride, with metal binders such as Ni, Co, Fe, Al Ti, Mg, Mo, W and/or their alloys). The metal and/or ceramic particles may be introduced alone or in a suspension with a fluid that is often organic in nature. Liquids of low melting temperature or thick state at low temperatures may be also introduced into the organic mold in these aggregation states. The term of organic mold in this document refers to a mold whose material has some organic compound, but may also contain other non-organic compounds (such as ceramic particles, metallic, . . . ). The present invention is particularly advantageous for the economic manufacture of highly demanded and complex geometries of metal and/or ceramic material.

The present invention has various possible implementations.

Generally the preferred implementation uses a rapid and low cost technique for the manufacture of a mold that contains a geometry that is mostly the negative of the part that is intended to be obtained plus some corrections (these corrections take into account the deformations and loss or increase in dimensions that may occur during and/or after the subsequent processes) and often incorporating other functionalities to facilitate the subsequent steps of the manufacturing process. For this step, additive manufacturing (AM) is particularly suitable. Generally, the material used in this step has an organic origin, although sometimes inorganic fillers can be used, and in some embodiments, these inorganic fillers can be the majority of the material in both weight and even in volume. Then, with the possibility of having some preparatory intermediate steps, the cavity is filled with the desired material (sometimes a carrier material is also used). The desired metallic and/or ceramic material may be mainly incorporated during this step in different states of aggregation. In many applications, the preferred state is the powder (or multitude of particles) of one or more materials with a special application when any of the materials has a markedly lower melting point. In some of these applications the powder once introduced is infiltrated with a liquid metal. In other applications, the preferred aggregation status is that of a suspension of particles in a fluid. In some applications, even the aggregation state of the metal may be liquid, for materials having a not excessively high melting point. Subsequently, often with some intermediate steps, the mold is removed. Often the mold is removed by pyrolysis but also the removal can be carried out mechanically, chemically or by other means. In many applications after removal of the mold the part is subjected to a stage of consolidation and/or densification. Finally, various types of post-treatments may be applied (mass or surface treatments, machining, polishing-mechanical, chemical, tribological, thermal, or combinations of both, etc. . . . ). For many applications, a critical stage is the retention of geometry during mold removal. For some applications with a simple geometry the mold may be reusable (if extraction functionality of the piece is incorporated without massive destruction of the mold). Any technique that allows the production of a mold with the desired geometry and an at least a partially organic material is valid.

In an embodiment the mold is filled with a suspension of particles in a fluid.

For the manufacture of the mold any additive manufacturing technique (AM) may be used and each of them has advantages for certain applications. For some applications it is advantageous to make the mold with technologies that are not considered AM, such as any polymer shaping methodology (injection molding, blow molding, thermoforming, casting, compression, pressing RIM, extrusion, roto-molding, dip molding, forming foams . . . ). Any AM technique may be advantageous for a particular application of the invention, among the technologies that are most commonly advantageous for a particular application include the technologies based on photo-sensitive materials such as methods based on polymerization by radiation (SLA, DLP, two-photon polymerization, liquid crystal, etc.), methods based on extrusion (FDM FFF, etc.), methods based on powder, any masking process, methods using binders, accelerators, activators or other additives which may or may not be applied in defined patterns (3DP, SHS, SLS, etc.), methods based in the manufacture of sheets (as LOM), and any other method. As it was mentioned before, the mold is often made of an organic compound or at least partially of an organic compound, although it may be also made integrally with inorganic compounds, besides plastics (thermo-plastics, thermo-setting, . . . ) many materials (plaster, mud, rubber, clay, paper, other cellulose derivatives, carbohydrates, etc.) may be used and these may be mixed with any other material (organic, ceramic, metals, intermetallics, nanotubes, fibers of any type, etc.).

In several applications one of the critical stages is the level of filling the mold with the desired material. In the case of powder several techniques may be used in order to help achieving high filling densities, such as the correct selection of particles size distribution, use of mechanical percussion, vibration or even the use of gas streams and/or other fluid (by pressure, vacuum, pressure gradients of thermal origin or others). In several applications in which suspensions are used to fill the mold, especially when these have a high viscosity, minimize porosity is a major challenge. The use of degassed suspensions and the use of vibration, vacuum, or other means during filling can be very advantageous for some applications. It is especially interesting since the functionality required in the mold for effective vacuum can be incorporated at a very low cost.

To assure shape retention it is very advantageous to have a material that generates some liquid phase or that can be brought to a state of high diffusion activity at a temperature lower than that of the degradation of the mold material or molding part. As the molding part is usually organic, at least partially, it is particularly interesting to have a material, in at least a part of the metallic load, with melting point below 180° C., preferably below 140° C., more preferably below 80° C. and even below 40° C. Materials with a higher degrading temperature can also be used like in the case of polymeric resins loaded with ceramic particles among others, in this case it is often especially advantageous that in order to preserve the geometry during mold removal by pyrolysis to have at least partially any metallic material with a melting point of less than 580° C., preferably below 480° C., more preferably below 380° C. and even less than 280° C.

In an embodiment the powder mixture used for filling the mold contain is at least a metallic material with a melting point below 580° C., in some embodiments less than 480° C., in other embodiments below 380° C. and in other embodiments even less than 280° C.

For some applications, the surface quality of the component obtained is of great importance. There are applications that require a high performance of the component material. There are also applications with geometric configurations that are difficult to obtain. For these reasons among others, the inventor has found that among other things, the filling of the mold of the negative part manufactured by AM may be of paramount importance. It has been found that if the filling is made with particles of the desired material for the component, the average size of these particles can be of great importance. The material may be introduced in disintegrated manner, that means that different materials are introduced and wholly or partially combined in subsequent steps of the manufacturing process of the desired component, which in turn may be a highly segregated material (different local compositions, at micro or macro scale). When the material is introduced in the form of particles, these may be introduced alone or in a suspension (which may be a predominantly organic or predominantly inorganic fluid depending on the application of interest, and may also have a high viscosity so that looks more like a paste). In what respect to the average size, this refers to the mean diameter, i.e. the volume diameter equivalent to a value of 50% cumulative frequency. (In this document De50 and D50 are used interchangeably whether the particles are perfectly spherical or not). It has been found that for some applications it is desirable to have a De50 of the particles of less than or equal to 980 microns, preferably less than 480 microns, more preferably less than 240 microns and even less than 95 microns. It has been found that for some applications it is desirable to have smaller particle sizes, such as when geometric fine details are desired, fine surface finish, etc., for some of these applications is desirable to have a De50 of particles of equal to 80 micrometers or less, more desired 48 microns or less, more desired 24 microns or less and even more desired 9 microns or less. It has been found that for some applications it is desirable to use super-fine particles, for example when geometric fine details, special mechanical properties, fine surface fnishing etc. are desired. For some of these applications is desirable to have a De50 equal to 4 microns of less, preferably less than 1.8 microns, more preferably less than 0.9 microns and even less than 0.45 micrometers. For some applications a particle size too small may be negative, in these cases a De50 higher than 1.2 microns, preferably greater than 28 microns, more preferably greater than 120 micrometers and even exceeding 520 micrometers

is desirable. For some applications, it is important that the particle size distribution is not too broad, in this case the relative standard deviation RSD=DEG/De50 where DEG is the geometric standard deviation DEG=De84.13/De50 is used. It has been found that for some applications it is desirable to have RSD exceeding 0.3, in other embodiments less than 0.14, preferably less than 0.09 and even less than 0.009. For some applications it is important to have particles of different sizes in order to have a more homogeneous mixing, so having a type of particles that tend to occupy a particular type of interstices left by the other particles is desirable. In this case the considerations for De50 and RSD mentioned above would apply to all or just one particle type as required by the application, but in any case, De50 calculations and RSD are made separately for each type of particle. In some cases a very high particle packing is desirable, which in some of cases it is desirable that the size distribution of particles follow a FULLER diagram, with a deviation of less than 30%, in other embodiments less than 18%, in other embodiments less than 8% or in other embodiments even less than 4%. For some applications, it has been found that it is important that the apparent density of the filling mold manufactured by AM is desirably less than 42%, preferably less than 54%, more preferably less than 66%, and even less than 76% For some applications, for example for those where a certain final porosity wants to be managed in order to be or not infiltrated, it has been seen that it is important that the apparent density of the filled mold manufactured by AM is desirably equal to or below 68%, preferably equal to or below 58%, more preferably equal to or less than 48% and even equal to or below 28%. In the case that the particles are introduced in slurry form, for some applications the viscosity of the suspension can play an important role. It has been found that for some applications it is desirable that the dynamic viscosity 120 cP or more, preferably 540 cP or more, more preferably 1200 cP or more or even 5500 cP or more. For some applications it has been found that an excessively high viscosity is negative, among other things because it hinders the filling and favors the formation of porosities, for some of these applications a lower dynamic viscosity at 980 cP is desirable, preferably less than 450 cP, more preferably less than 90 cP, and even more preferably even less than 18 cP.

In an embodiment the material is introduced in the form of particles.

In an embodiment the particles are introduced alone.

In an embodiment the particles are introduced in a suspensión.

In an embodiment the mold is filled with a suspension.

In an embodiment the suspension is a organic fluid.

In an embodiment the suspensión is a inorganic fluid.

In an embodiment the dynamic viscosity of the suspensión is 120 cP or more, in other embodiments 540 cP or more, in other embodiments 1200 cP or more or in other embodiments even 5500 cP or more.

In an embodiment the dynamic viscosity of the suspensión is 980 cP is desirable, preferably less than 450 cP, more preferably less than 90 cP, and even more preferably even less than 18 cP.

In an embodiment the De50 of the particles filling the mold is less than or equal to 980 microns, in other embodiment less than 480 microns, in other embodiments less than 240 microns and in other embodiments even less than 95 micron.

In an embodiment the mold is filled to an apparent density equal to or below 68%, in other embodiments equal to or below 58%, in other embodiments equal to or less than 48% and even in other embodiments equal to or below 28%.

Any of the above-described embodiments can be combined with any other embodiment herein described in any combination, to the extent that the respective features are not incompatible.

Throughout the document if a desired amount is described as less than a certain value (with any nomenclature: a certain value or less, below a certain value, below a certain value, a certain value or lower, . . . ) it will be desirable that for some applications described the desirable value is the nominal absence or even the complete absence with 0 or 0% depending on the case, unless otherwise specified (at all levels within the measurable or nominal level, and meaning deviations that are costly to control are accepted). The same can be said of the amounts that are desired to be above a certain value, and where otherwise specified, it will be desirable that for a subset of the applications described the desirable value is the largest possible. For the “unless otherwise specified” it that can be sometimes referred to only a subset of applications, which means that a subset of applications may need a value of 0 while others not. This case often occurs when for a certain group of applications the values of a property less than a X value are desired, for example set of applications A. Simultaneously for another application (for example set of applications B) values of the same property are desired to be above, and unless specified otherwise it should be expected that sets A and B have an intersection where the applications requires values greater than Y but less than X. Moreover, if otherwise not indicated, it is expected that there is a part of the set of applications A that does not intersect with the set B where a value of the property less than X is desired. For at least a subset of these applications is desirable a property value of 0 or 0% (nominal or absolute) unless otherwise indicated. If otherwise not stated is to be expected that there is a part of the set of applications B that does not intersect with the set of applications A, where a value of the property greater than X is desired to reach the maximum value achievable for at least a subset of these applications, unless otherwise indicated.

When using some of the technologies of the present invention for the construction of tools (molds, dies, punches, cutting tools, etc.), and for most components in which the material used is high-cost, it is economically interesting to try to minimize the amount of material employed, even though the AM mold may be more complex and/or possess more material than the filling itself. In this regard, for some applications, it is interesting to attain lightweight constructions in order to save material. Sometimes the material itself is not too expensive but it is the morphology in which it must be used especially if the particles require strict morphological requirements such as sphericity, and/or narrow distribution of particle size which can be mono-modal, bimodal or polymodal. For lightweight construction, often finite element programs are used and algorithms for topological optimization. Bionic optimization may also be of aid for finally reduce the amount of material used. To achieve that, complex systems withstand loads of some components, also in the case of some tools, it is common to use ribbings, casts, braces, etc. in order to reduce the weight and thus the amount of material used.

Sometimes the final geometry resembles to what it would be used if the component could be obtained by casting, but with thinner walls, more intricate details or more severe castings. The castings may also be conducted with a high level of detail in very small components such as cutting punches, small slides, ejectors, cores, etc.

For some applications it is important to have a severe casting and for these applications it is desirable that compared with the minimum hexahedron containing component only 74% or less of the volume is filled, preferably 48% or less, more preferably 28% or less and even 18% or less. For some applications, it is convenient to exclude the active surface, counting only the material contained in the minimum hexahedron containing the component and excluding the maximum volume generated by the active surface and the plane that cuts it.

For some components, it is interesting to take one or more intermediate steps. An example of an intermediate step is the introduction into the AM mold of a polymerizable resin that contains suspended particles of the material of interest, instead of directly introducing the particles as in previous cases. The resin can be removed at a later stage by pyrolysis, dissolution etching . . . . It has been seen that in such cases it is difficult to get a component without too many internal porosities and a way to achieve this is through the evacuation of the mold as a first step and/or simultaneous filling with the resin with particles in suspension. A schematic representation, for illustrative purposes, can be seen in FIG. 5.

Although in this case it is easier to achieve more complex geometries by destroying the AM mold and subsequently eliminating the resin by pyrolysis and sintering of the particles introduced into a bed of particles or sand to preserve the geometry of interest among points of degradation of the resin or other organic compound and sintering, it is often desirable to have particles of low melting point to facilitate strategies to remove gases from the pyrolysis of the resin or other organic compound (and allow AM destruction of mold at the same time).

For all components manufactured according to the present invention it may be of interest for some application to use a post-processing. The post-processing applied can be very diverse, from surface conditionings (polished electro-chemical, tribo-mechanical or any other combination, machined, blasted, . . . ) to thermal mass or surface treatments, coatings, etc. Any type of coating may be of interest for a particular application, because the coating layer itself can have a great impact on the component's functionality. All the technique developed so far and the one that will be developed for thin films is applicable. Without any intention of drawing up an exhaustive list but in order to provide some illustrative examples it is worth to mention the mostly soft type of electrochemical coatings, by liquid bath, etc. Coatings that can be both soft and hard: thermal projections, kinetic projections (cold spray, . . . ), hooks friction, diffusion or other technologies. Mostly hard coatings such as PVD, CVD, and other vapor coating or plasma. And as mentioned any other technique that allows to change the surface functionality of the component in any way that may be of interest to the particular application. The coating may be of any singular or composite nature.

Due to the densification mechanism often employed in the present invention, it is interesting for various applications the use of hard particles or reinforcement fibers to confer a specific tribological behavior and/or to increase the mechanical properties. In this sense some applications benefit from the use of reinforcement particle of 2% by volume or more, preferably 5.5% or more, more preferably 11% or more or even 22% or more. These reinforcing particles not necessarily have to be introduced separately, they can be embedded in another phase or can be synthesized during the process. Typical reinforcing particles are those with high hardness such as diamond, cubic boron nitride (cBN), oxides (aluminum, zirconium, iron, etc.), nitrides (titanium, vanadium, chromium, molybdenum, etc.), carbides (titanium, vanadium, tungsten, iron, etc.), borides (titanium, vanadium, etc.) mixtures thereof and generally any particle with a hardness of 11 GPa or more, preferably 21 GPa or more, more preferably 26 GPa or more, and even 36 GPa or more. On the other hand, mainly for applications that benefit from increased mechanical properties, any particle which is known that can have a positive effect on the mechanical properties such as fibers (glass, carbon, etc.), wiskers, nanotubes, etc may be used as reinforcing particles.

In an embodiment the particles filling the mold comprises reinforcement particles being 2% by volume or more of the powder mixture, in other embodiments 5.5% or more, in other embodiments 11% or more or even in other embodiments 22% or more

In an embodiment reinforcement particles have a hardness of 11 GPa or more, in other embodiment 21 GPa or more, in other embodiment 26 GPa or more, and even in other embodiment 36 GPa or more.

For the densification of particles is interesting for some applications to use special atmospheres, from vacuum to reducing and/or inert gases and/or reaction accelerators gases etc. often accompanied by certain strategies to increase and maintain the temperature at the stage of densification and/or consolidation. Any combination of temperature and atmosphere is possible. The number of combinations is innumerable and therefore a few illustrative examples are mentioned. For consolidation and/or densification of aluminum particles or aluminum alloys it may be of interest for some applications the use of an atmosphere containing high nitrogen (above 82%), for some applications it is even interesting to have some reducing gas and/or accelerator, for some applications it is interesting to have some magnesium vapor, for some applications it is interesting to have water vapor content exceeding 0.01 mbar, for some applications the water vapor content must be less than 0.2 mbar, for some applications the water vapor content must be less than 0.01 mbar. For consolidation and/or densification of iron alloys it may be interesting to reduce possible oxides on the surface of the powder using a reducing atmosphere for its carbon potential higher than that of the particles or their hydrogen content among others, the reduction is especially effective in a specific range of temperatures especially if other effects must be taken into consideration.

The metal particles of the present invention (with their compositional requirements depending on the particular application) may be used in other manufacturing systems components, which may be mixed with photosensitive resins, with or without any other organic compound. Often there are machining steps at the end, but in some cases they can be avoided.

Especially when high curing speeds are used, but also generally for several applications of the present invention, it may be advantageous sometimes to aid the bed material flowing. This is particularly the case when fluids with high viscosities are used (for example, photo-curable resins with additions of metal particles).

Some of these elements such as Mg and Sn promote sintering by breaking the aluminum oxide film, and the author has seen that many liquid phases have the same positive effect.

The inventor has found that the method of the present invention is particularly suitable for the manufacture of parts that are usually produced by casting. This includes parts which were manufactured in 2012 mainly by high pressure casting, gravity casting, casting, low pressure casting, thixomolding and similar processes. Also for components manufactured by forging processes or the like. For these cases, the inventor has found the importance of making a component which is 89% or less, preferably 69% or less, more preferably 49% or even 29% or less than the same component or components with the same functionality made of casting technique that was more common for that type of component on 21 Oct. 2015. In some cases, this weight reduction has strong impact on the economic viability.

Alternatively, it is also possible to use complex post-processing routes in order to achieve an overall density, often involving intensive processes in time and energy as HIP, especially if it is for high value-added components. An intermediate level, the inventor has found that the use of a liquid phase controlled as described is one possible implementation of the method of the present invention, to achieve full density or at least less porosity with less sharp edges in a more economically way. In addition, processes using low-cost production for the manufacture of metal particles, the inventor has also seen that in order to make these major components competitively, it is very advantageous to use quick AM systems with low investment cost. This often involves giving up on the accuracy that can be achieved, and even more often in the mechanical properties of the AM component, but when the method described in this document is used, this can be overcome and surprisingly enough values of dimensional accuracy and mechanical properties can be obtained, especially if the right design is used (given also the actual values of accuracy required according to the inventor, these are considerably more relax than the values sought by the AM industry). The inventor has found that in many cases the production costs of large components with high complexity have been optimized for many years and are therefore very difficult to fit, especially with a new manufacturing technique. Thus, in many cases of the present invention, the components can only be manufactured in an economically reasonable way if a significant weight reduction is achieved. For this purpose, the flexibility of the method of the present invention is very helpful. For this purpose, the use of bionic structures and generally the replica of optimized structures from nature can be used. Also some structural components have different requirements in different areas of the same component, for example having areas where resistance to deformation or deformability is capital and other areas where the energy absorption capacity is more preferred. Also some structural components are designed to prevent failure, but in the case of an unexpected solicitation is desirable to concretely fail or act as mechanical fuses. Thus, for various components having areas with different properties, it is clearly advantageous and can contribute to its lightweight design. The inventor has found that this can be achieved in various ways, but in the context of the present invention three methodologies or their combination are particularly suitable; Having said this, not any other methodology is excluded. The three best ways are design, multi-material and heat treatment-sided. Design refers to any type of strategy related to the geometry at all levels of the component, to provide some examples: different thickness, different stiffness (especially significant by bionic design), determining the path of deformation in a pattern defined load, taking an area acting as a mechanical fuse (if less resistant, deforms more, the porosity is maintained to reduce fracture toughness . . . ). Again, the bionic design and the overall design flexibility of AM achieves quite different behaviors by generating certain patterns and structures at mini and/or micro level and even with the aid of material at nano level. Multi-material refers to the use of different materials in different areas of the components; It is pretty self-descriptive but to give one example, one can use material with high rigidity in a particular area, and a material with high deformability and energy absorption in another area. The partial heat treatment refers to having areas that receive different heat treatments in order to achieve different properties; this is normally related to the material, as it is often what determines which properties can be achieved by applying different heat treatments. In the present invention, another special case appears besides what can be found in the literature, and that is having different degrees of diffusion in different areas of the component manufactured and therefore having different compositions even though the same supply of material is used.

In an embodiment the invention refers to a method for the production of metal objects at least partly, partially intermetallic and/or ceramic part, comprising the following steps:

a. Manufacturing a negative mold of the component to be obtained by FA;

b. Filling the mold from the previous step at least partially with the material of the piece to be obtained (the material can be disintegrated, ie different materials are introduced in a later stage are combined to obtain the desired material);

c. Remove the mold without destroying the shape of the component to manufacture.

In an embodiment the method further comprises the following additional step: d. Consolidate and/or densify the manufactured component.

In an embodiment the material in step b) is introduced in particulate form.

In an embodiment the material from step b) is introduced in powder form with an average equivalent diameter (ED50) of 980 microns or less.

In an embodiment the material from step b) is introduced in powder form with an average equivalent diameter (ED50) of 80 microns or less.

In an embodiment the material from step b) is introduced as a particle suspension.

In an embodiment the material from step b) is introduced as a particle suspension where the carrier fluid is organic.

In an embodiment the material of the component to obtain introduced in step b) represents a filling density of 54% or more.

Any of the above-described embodiments can be combined with any other embodiment herein described in any combination, to the extent that the respective features are not incompatible.

In an embodiment the invention refers to the final composition of the metallic or at least partially metallic component manufacture.

In an embodiment refers to a aluminium based alloy with the following composition, all percentages in weight percent:

| % Si: 0-50 (commonly 0-20); | | % Cu: 0-20; | % Mn: 0-20; |
|---|---|---|---|
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-8; |
| % B: 0-5; | % Mg: 0-50 (commonly 0-20); | | % Ni: 0-50; |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5 | % O: 0-15 | | |

The rest consisting on aluminium and trace elements

In this context trace elements refers to any element of the list: H, He, Xe, F, Ne, Na, P, S, Cl, Ar, K, Br, Kr, Sr, Tc, Ru, Rh, Pd, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the alloy, such as reducing cost production of the alloy, and/or its presence may be unintentional and related mostly to the presence of impurities in the alloying elements and scraps used for the production of the alloy.

There are several applications wherein the presence of trace elements is detrimental for the overall properties of the aluminium based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the aluminium based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

There are applications wherein aluminium based alloys are benefited from having a high aluminium (% Al) content but not necessary the aluminium being the majority component of the alloy. In an embodiment % Al is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Al is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Al is not the majority element in the aluminium based alloy.

The nominal composition expressed herein can refer to particles with higher volume fraction and/or to the overall final composition once the resin or other organic component if present, is removed, even if there are several phases, important segregations or others. In cases where there are presence of immiscible particles as ceramic reinforcements, graphene, nanotubes or others, these are not counted in the nominal composition.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 54% or more when incorporating these phases. Once incorporated and when evaluating the overall composition measured as stated in this application, the resulting aluminium alloy generally has a 0.8% or more of the element (in this case % Ga), preferably 2.2% or more, more preferably 5.2% or more and even 12% or more. It has been found that in some applications the % Ga can be replaced wholly or partially by Bi % with the amounts described in this paragraph for % Ga+% Bi. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C. the, more preferably below 180° C. or even below 46° C. For some applications it is more interesting alloy with these elements directly and not incorporate in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

The case of scandium (Sc) is exemplifying, because using them very interesting mechanical properties may be reached, but its cost makes interesting from an economic point of view to use the amount needed for the application of interest. Its high deoxidizing power is also interesting during alloys processing but also a challenge to maximize performance. So depending on the application you can move from situations wherein is not a desired element, to a situations wherein a high content of this element is desired, 0.6% by weight or more, preferably 1.1% by weight or more, more preferably 1.6% by weight or more and even 4.2% or more. There are even applications wherein in an embodiment % Sc is detrimental or not optimal for one reason or another, in these applications it is preferred % Sc being absent from the alloy.

It has been found that for some applications aluminum alloys the presence of silicon (% Si) is desirable, typically in contents of 0.2% by weight or higher, preferably 1.2% or more, more preferably 6% or more or even 11% or more. In contrast, in some applications the presence of this element is rather detrimental in which case contents of less than 0.2% by weight are desired, preferably less than 0.08%, more preferably less than 0.02% and even less than 0.004%. Obviously there are cases where the desired nominal content is 0% or nominal absence of the element as with all elements for certain applications.

It has been found that for some applications of aluminum alloys the presence of iron (% Fe) is desirable, typically in contents of 0.3% by weight or higher, preferably 0.6% or more, more preferably 1.2% or more or even 6% or more. In contrast, in some applications the presence of this element is rather detrimental, in those cases contents of less than 0.2% by weight are desired, preferably less than 0.08%, more preferably less than 0.02% and even less than 0.004%. Obviously there are cases where the desired nominal content is 0% or nominal absence of the element as occurs with all elements for certain applications.

It has been found that for some applications of aluminum alloys the presence of copper (% Cu) is desirable, typically in content of 0.06% by weight or higher, preferably 0.2% or more, more preferably 1.2% or more or even 6% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of aluminum alloys the presence of manganese (% Mn) is desirable, typically in content of 0.1% by weight or higher, preferably 0.6% or more, more preferably 1.2% or more or even 6% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of aluminum alloys the presence of magnesium (% Mg) is desirable, typically in content of 0.2% by weight or higher, preferably 1.2% or more, more preferably 6% or more or even 11% or more. In contrast, in some applications the presence of this element is rather detrimental, in those cases contents of less than 1.8% by weight are desired, are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications. If magnesium is used mainly for destroying the alumina film in aluminum particles or in aluminum alloy (sometimes it is introduced as a magnesium separate powder or magnesium alloy and also sometimes is alloyed directly on the aluminum particles or aluminum alloy and also sometimes in other particles such as low melting point particles) the final content of % Mg can be quite small, in these applications often is desired a content greater than 0.001%, preferably greater than 0.02%, more preferably greater than 0.12% and even above 3.6%.

It has been found that for some applications in aluminum alloys the presence of nitrogen (% N) is desirable, typically in contents of 0.2% by weight or higher, preferably 1.2% or more, more preferably 3.2% or more or even 4.6% or more. For some applications it is interesting that the consolidation and/or densification of the particles with aluminum is carried out in atmosphere with high nitrogen content thus often reaction occurs particularly if consolidation and/or densification (eg sintering with or without liquid phase) occurs at elevated temperatures, the nitrogen will react with the aluminum and/or other elements forming nitrides and thus will appear as an element in the final composition. In these cases it is often useful to have in the final composition a nitrogen content of 0.002% or higher, preferably 0.02% or higher, more preferably 0.4% or higher and even 2.2% or higher. There are even applications wherein in an embodiment % N is detrimental or not optimal for one reason or another, in these applications it is preferred % N being absent from the alloy.

The preceding two paragraphs also apply to alloys of other basic elements as described in future paragraphs (Ti, Fe, Ni, Mo, W, Li, Co, . . . ) when an aluminum alloy or aluminum is used as a low-melting point element. For some applications indications shown in the preceding two paragraphs refers to the particles of aluminum alloy or aluminum alone, for some other applications indications shown in the preceding two paragraphs it refers to the final composition but the values of percentage by weight have to be corrected by the weight fraction of aluminum particles or aluminum alloy with respect to total particles. This applies, for some applications, when used as low melting point particle any other type of particle that oxidizes rapidly in contact with air, such as magnesium alloys and magnesium, etc.

It has been found that for some applications of aluminum alloys the presence of Sn (% Sn) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 1.8% by weight are desired, preferably less than 0.2% by weight, more preferably less than 0.08%, and even less than 0.004%. Obviously there are cases where the desired nominal content is 0% or nominal absence of the element as occurs with all elements for certain applications.

It has been found that for some applications of aluminum alloys the presence of zinc (% Zn) is desirable, typically in content of 0.1% by weight or higher, preferably 1.2% or more, more preferably 6% or more or even 11% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of aluminum alloys the presence of chromium (% Cr) is desirable, typically in content of 0.2% by weight or higher, preferably 1.2% or more, more preferably 6% or more or even 11% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications

It has been found that for some applications of aluminum alloys the presence of titanium (% Ti) is desirable, typically in content of 0.05% by weight or higher, preferably 0.2% or more, more preferably 1.2% or more or even 4% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of aluminium alloys the presence of zirconium (% Zr) is desirable, typically in content of 0.05% by weight or higher, preferably 0.2% or more, more preferably 1.2% or more or even 4% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of aluminium alloys the presence of Boron (% B) is desirable, typically in content of 0.05% by weight or higher, preferably 0.2% or more, more preferably 0.42% or more or even 1.2% or more. In contrast, in some applications the presence of this element is rather detrimental, in those cases are desired contents of less than 0.08% by weight, preferably less than 0.02%, more preferably less than 0.004% and even less than 0.0002%. Obviously there are cases where the desired nominal content is 0% or nominal absence of the element as occurs with all elements for certain applications.

The elements described in the preceding paragraphs may be desired separately or the combination of some of them or even all of them, as expected.

It has been seen that for some applications the excessive content of cesium, tantalum and thallium and can be detrimental, for these applications it is desirable the sum of % Cs+% Ta+% Tl less than 0.29%, preferably less than 0.18%, more preferably less than 0.8%, and even less than 0.08% (without being mentioned, as in all instances in this document where amounts are mentioned as upper limits, 0% nominal content or nominal absence of the element, it is not only possible but is often desirable).

It has been seen that for some applications the excessive content of gold and silver can be detrimental, for these applications it is desirable the sum of % Au+% Ag less than 0.09%, preferably less than 0.04%, more preferably less than 0.008%, and even less than 0.002%. There are even applications wherein in an embodiment % Au is detrimental or not optimal for one reason or another, in these applications it is preferred % Au being absent from the alloy. There are even applications wherein in an embodiment % Ag is detrimental or not optimal for one reason or another, in these applications it is preferred % Ag being absent from the alloy.

It has been found that for some applications when high contents of % Ga and % Mg (both above 0.5%), it is often desirable to have hardening elements for solid solution, precipitation or hard second phase forming particles. In this sense, the sum % Mn+% Si+% Fe+% Cu+% Cr+% Zn+% V+% Ti+% Zr for these applications, is desirably greater than 0.002% by weight preferably greater than 0.02%, more preferably greater than 0.3% and even higher than 1.2%.

It has been found that for some applications when % Ga content is lower than 0.1%, it is often desirable to have some limitation in hardening elements for solid solution, precipitation or hard second phase forming particles. In this sense, the sum % Cu+% Si+% Zn is desirably less than 21% by weight for these applications, preferably less than 18%, more preferably less than 9% or less than 3.8%. There are even applications wherein in an embodiment % Ga is detrimental or not optimal for one reason or another, in these applications it is preferred % Ga being absent from the alloy.

It has been found that for some applications when content % Ga below 1% and there is significant presence of % Cr (between 3% and 5%), it is often desirable to have hardening elements for solid solution or precipitation or forming hard particles second stage. In this sense, the sum % Mg+% Cu is desirably higher than 0.52% by weight for these applications, preferably greater than 0.82%, more preferably greater than 1.2% and even higher than 3.2%. and/or the sum of % Ti+% Zr is desirable exceeds 0.012% by weight, preferably greater than 0.055%, more preferably greater than 0.12% by weight and even higher than 0.55%. There are even applications wherein in an embodiment % Cu is detrimental or not optimal for one reason or another, in these applications it is preferred % Cu being absent from the alloy.

It has been found that for some applications, especially those requiring a high mechanical strength, high resistance to high temperatures and/or high corrosion resistance, which can be very beneficial combination of gallium (% Ga) and scandium (% Sc). For these applications it is often desirable to have contents above 0.12% wt % of Sc, preferably above 0.52%, more preferably greater than 0.82% and even above 1.2% For these applications simultaneously is often desirable to have Ga in excess of 0.12% wt %, preferably above 0.52%, more preferably greater than 0.8%, more preferably greater than 2.2% and even higher 3.5%. For some of these applications is also interesting to have further magnesium (Mg %), it is often desirable to have % Mg above 0.6% by weight, preferably greater than 1.2%, more preferably greater than 4.2% and even more than 6%. For some of these applications, especially improved resistance to corrosion is required, it is also interesting for the presence of zirconium (% Zr), often in excess of 0.06% weight amounts, preferably above 0.22%, more preferably above 0.52% and even greater than 1.2%. Obviously, like all other paragraphs herein any other element may be present in the amounts described in the preceding and coming paragraphs.

There are several elements such as Sr that are detrimental in specific applications especially for certain Si and/or Mg and/or Cu contents; For these applications in an embodiment with % Si between 9.3% and 11.8% and/or % Mg between 0.098% and 0.53%, % Sr is below 28.9 ppm, even in another embodiment with % Si between 9.3% and 11.8% and/or % Mg between 0.098% and 0.53%, Sr is absent from the composition. In another embodiment with % Si between 9.3% and 11.8% and/or % Mg between 0.098% and 0.53%, % Sr is above 303 ppm. In another embodiment with % Cu between 0.98% and 2.8% and/or % Mg between 0.098% and 3.16%, % Sr is below 48.9 ppm o even is absent composition. Even in another embodiment with % Cu between 0.98% and 2.8% and/or % Mg between 0.098% and 3.16%, % Sr is above 0.51%.

There are several applications wherein the presence of Na and Li in the composition is detrimental for the overall properties of the aluminium based alloy especially for certain Si and/or Ga and/or Mg contents. In an embodiment with % Si between 9.8% and 15.8% and/or % Mg above 0.157% and/or % Ga above 0.157%, % Na is below 29.7 ppm or even absent from the composition and/or % Li is below 29.7 ppm or even absent from the composition. Even in another embodiment with % Si between 9.8% and 15.8% and/or % Mg above 0.157% and/or % Ga above 0.157%, % Na is above 42 ppm and/or % Li is above 42 ppm.

It has been found that for some applications, certain contents of elements such as Hg may be detrimental especially for certain Ga contents. For these applications in an embodiment with % Ga between 0.0098% and 2.3%, % Hg is lower than 0.00098% or even Hg is absent from the composition. In another embodiment with % Ga between 0.0098% and 2.3%, % Hg is higher than 0.11%.

There are several elements such as Pb that are detrimental in specific applications especially for certain Si contents; For these applications in an embodiment with % Si between 0.98% and 12.3%, % Pb is below 2.8% or even absent from the composition. Even in another embodiment % Si between 0.98% and 12.3%, % Pb is above 15.3%.

It has been found that for some applications, certain contents of elements such as Co may be detrimental especially for certain Si and/or Mg contents. For these applications in an embodiment with % Si between 0.017% and 1.65% and/or % Mg between 0.24% and 6.65%, % Co is lower than 0.24% or even Co is absent from the composition. In another embodiment with % Si between 0.017% and 1.65% and/or % Mg between 0.24% and 6.65%, % Co is higher than 2.11%.

There are several elements such as Ag that are detrimental in specific applications especially for certain Si and/or Mg and/or Cu contents. In an embodiment with % Si between 7.3% and 11.6% and/or % Mg between 0.47% and 0.73% and/or % Cu between 3.57% and 4.92%, % Ag is below 0.098% or even is absent from the composition. Even in another embodiment with % Si between 7.3% and 11.6% and/or % Mg between 0.47% and 0.73% and/or % Cu between 3.57% and 4.92%, % Ag is above 0.33%.

There are several elements such rare earth (RE) elements that are detrimental in specific applications especially for certain Si and/or Mg and/or Ga contents; For these applications in an embodiment with % Si between 3.97% and 15.6% and/or % Mg between 0.097% and 5.23%, % RE is below 0.097% or even RE are absent from the composition. Even in another embodiment % Si between 0.37% and 11.6% and/or % Mg between 0.37% and 11.23% and/or % Ga between 0.00085% and 0.87%, % RE is below 0.00087% or even RE are absent from the composition. In another embodiment % Si between 0.37% and 11.6% and/or % Mg between 0.37% and 11.23% and/or % Ga between 0.00085% and 0.87%, % RE is above 0.087%.

It has been found that for some applications, certain contents of elements such as Ga may be detrimental especially for certain Si contents. For these applications in an embodiment with % Si between 3.98% and 14.3%, % Ga is lower than 0.098%. Even in another embodiment with % Si between 3.98% and 14.3%, % Ga is above 2.33%.

It has been found that for some applications, certain contents of elements such as Sn may be detrimental especially for certain Si contents. For these applications in an embodiment with % Si between 3.98% and 14.3%, % Sn is lower than 0.098% or even is absent from the composition. Even in another embodiment with % Si between 3.98% and 14.3%, % Sn is above 2.33%.

There are several elements such as Pb, Sn, In, Sb and Bi that are detrimental in specific applications especially for certain Si and/or Mg and/or Cu and/or Fe and/or Ga contents. In an embodiment with presence of Si and/or Mg and/or Cu and/or Fe and/or Ga, elements such as Pb and/or Sn and/or In and/or Sb and/or Bi are absent from the composition.

There are several applications wherein the presence of Ce and Er in the composition is detrimental for the overall properties of the aluminium based alloy especially for certain Si and/or Mg contents. In an embodiment with % Si between 6.77% and 7.52% and/or % Mg between 0.246% and 0.356%, % Ce is below 0.017% or even absent from the composition and/or % Er is below 0.0098% or even absent from the composition. Even in another embodiment with % Si between 6.77% and 7.52% and/or % Mg between 0.246% and 0.356%, % Ce is above 0.047% and/or % Er is above 0.033%.

It has been found that for some applications, certain contents of elements such as Te may be detrimental especially for certain Si contents. For these applications in an embodiment with % Si between 7.87% and 12.7%, % Te is lower than 0.043% or even is absent from the composition. Even in another embodiment with % Si between 7.87% and 12.7%, % Te is above 3.33%.

It has been found that for some applications, certain contents of elements such as In and Zn may be detrimental especially for certain Fe contents. For these applications in an embodiment with % Fe between 0.48% and 3.33%, % In is lower than 0.0098% or even is absent from the composition and/or % Zn is lower than 1.09% or even is absent from the composition. Even in another embodiment with % Fe between 0.48% and 3.33%, % In is above 2.33% and/or % Zn is above 4.33%.

It has been found that for some applications, certain contents of elements such as Fe and Ni may be detrimental especially for certain Si and/or Mg and/or Fe contents. For these applications in an embodiment with % Si between 0.018% and 2.63% and/or % Mg between 0.58% and 2.33%, % Ni is lower 0.47% or higher than 3.53%. In another embodiment with % Si between 0.018% and 1.33% and/or % Mg between 2.58% and 10.33%, % Ni is lower 1.98% or higher than 6.03%. In another embodiment with % Si between 5.97% and 19.63% and/or % Mg between 0.18% and 6.33%, % Fe is lower 0.087% or higher than 1.73%. Even in another embodiment with % Si between 0.0087% and 2.73% and/or % Mg between 0.58% and 3.83%, % Fe is lower 0.0098% or higher than 2.93%. In another embodiment with % Fe between 0.27% and 3.63%, % Ni is lower 0.078% or higher than 3.93%.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are some applications wherein the presence of compounds phase in the aluminium based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the aluminium based alloy. There are other applications wherein the presence of compounds in the aluminium based alloy is beneficial. In another embodiment the % of compound phase in the aluminium based alloy is above 0.0001%, in another embodiment is above 0.3%, in another embodiment is above 3%, in another embodiment is above 13%, in another is above 43% and even in another embodiment is above 73%.

Any of the above Al alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an aluminium alloy for manufacturing metallic or at least partially metallic components.

The present invention is particularly suitable for the manufacture of components that can benefit from the properties of certain light elements and alloys, especially Mg, Li, Cu, Zn, Sn. (Copper and tin are not considered light alloys by its density but given its diffusion capacity are considered in this group in the present invention). In this case all the above for aluminum alloys applies both in range level and all the comments made on all paragraphs that refer to the aluminum based alloys for special applications, regarding maximum levels and/or minimum desired and/or preferred of these elements. Given that the rest will no longer be Al and minor elements, but the element in question (Mg/Li/Cu/Zn/Sn) and minority elements to be treated equally in the case of % Al. The only thing that happens is that the % Al and the base element in question (Mg/Li/Cu/Zn/Sn) exchange their numerical values.

As has been described hardening ceramic particles and other types having electrical, magnetic, piezoelectric, pyroelectric, thermal, etc. properties may also be incorporated in the present invention. Non-ceramic nature particles may also be incorporated. These particles can be incorporated into different volume fractions and even be the majority according to the requirements of the application. In this sense, for the case wherein the metal component is the minority, it is usually denominated binder, but still applies the requirements of the present invention for the different types of metals described. A typical example are applications that may benefit from properties of composites such as hard metal or the so-called carbides, ie materials with a large amount of hard particles and a metal binder as described in the preceding paragraphs. In this case the alloy percentages for the metal phase refer only to the metallic phase, ie without incorporating the hard particles, in terms of possible segregations. Thus for example there are applications wherein it is advantageous the use of hard metal with metal binder according to the present invention, ie the use of a mixture of hard ceramic particles with binder particles according to the compositions described according to the application in particular.

Some of the metal particles compositions described in the present invention may constitute an invention per se as they are compositions unknown in the state of the art.

It is sometimes desirable to introduce in particles form or even in pieces, elements which may be incorporated into the composition or not, with the purpose of trapping the remaining oxygen in the process chamber even after evacuation and/or protective gas filling. Examples are those oxygen-starved materials, such as various rare earths, scandium, francium, rubidium, sodium, . . . . And more commonly even Ti, Al, Mg, Si, Ca, . . . .

In an embodiment refers to a magnesium based alloy with the following composition, all percentages in weight percent:

| % Si: 0-50 (commonly 0-20); | | % Cu: 0-20; | % Mn: 0-20; |
|---|---|---|---|
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-8; |
| % B: 0-5; | % Al: 0-50 (commonly 0-20); | | % Ni: 0-50; |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5 | % O: 0-15 | | |

The rest consisting on magnesium and trace elements

In this context trace elements refers to any element of the list: H, He, Xe, F, Ne, Na, P, S, Cl, Ar, K, Br, Kr, Sr, Tc, Ru, Rh, Pd, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the alloy such as reducing cost production of the alloy and/or its presence may be unintentional and related mostly to the presence of impurities in the alloying elements and scraps used for the production of the alloy

There are several applications wherein the presence of trace elements is detrimental for the overall properties of the magnesium based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the magnesium based alloy.

There are other applications wherein the presence of trace elements may reduce the cost of the alloy or attain any other additional beneficial effect without affecting the magnesium based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

There are applications wherein magnesium based alloys are benefited from having a high magnesium (% Mg) content but not necessary the magnesium being the majority component of the alloy. In an embodiment % Mg is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%.

In an embodiment % Mg is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Mg is not the majority element in the magnesium based alloy.

The nominal composition expressed herein can refer to particles with higher volume fraction and/or to the overall final composition once the resin or other organic component if present, is removed, even if there are several phases, important segregations or others. In cases where there are presence of immiscible particles as ceramic reinforcements, graphene, nanotubes or others, these are not counted in the nominal composition.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 54% or more when incorporating these phases. Once incorporated and when evaluating the overall composition measured as stated in this application, the resulting magnesium alloy generally has a 0.8% or more of the element (in this case % Ga), preferably 2.2% or more, more preferably 5.2% or more and even 12% or more. It has been found that in some applications the % Ga can be replaced wholly or partially by % Bi with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C. the, more preferably below 180° C. or even below 46° C. For some applications it is more interesting alloy with these elements directly and not incorporate in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

The case of scandium (Sc) is exemplifying, because using them very interesting mechanical properties may be reached, but its cost makes interesting from an economic point of view to use the amount needed for the application of interest. Its high deoxidizing power is also interesting during alloys processing but also a challenge to maximize performance. So depending on the application you can move from situations wherein is not a desired element, to a situations wherein a high content of this element is desired, 0.6% by weight or more, preferably 1.1% by weight or more, more preferably 1.6% by weight or more and even 4.2% or more. There are even applications wherein in an embodiment % Sc is detrimental or not optimal for one reason or another, in these applications it is preferred % Sc being absent from the alloy.

It has been found that for some applications magnesium alloys the presence of silicon (% Si) is desirable, typically in contents of 0.2% by weight or higher, preferably 1.2% or more, more preferably 6% or more or even 11% or more. In contrast, in some applications the presence of this element is rather detrimental in which case contents of less than 0.2% by weight are desired, preferably less than 0.08%, more preferably less than 0.02% and even less than 0.004%. Obviously there are cases where the desired nominal content is 0% or nominal absence of the element as with all elements for certain applications.

It has been found that for some applications of magnesium alloys the presence of iron (% Fe) is desirable, typically in contents of 0.3% by weight or higher, preferably 0.6% or more, more preferably 1.2% or more or even 6% or more. In contrast, in some applications the presence of this element is rather detrimental, in those cases contents of less than 0.2% by weight are desired, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of copper (% Cu) is desirable, typically in content of 0.06% by weight or higher, preferably 0.2% or more, more preferably 1.2% or more or even 6% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of manganese (% Mn) is desirable, typically in content of 0.1% by weight or higher, preferably 0.6% or more, more preferably 1.2% or more or even 6% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of aluminium (% Al) is desirable, typically in content of 0.2% by weight or higher, preferably 1.2% or more, more preferably 6% or more or even 11% or more. In contrast, in some applications the presence of this element is rather detrimental, in those cases contents of less than 1.8% by weight are desired, are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications in magnesium alloys the presence of nitrogen (% N) is desirable, typically in contents of 0.2% by weight or higher, preferably 1.2% or more, more preferably 3.2% or more or even 4.2% or more. For some applications it is interesting that the consolidation and/or densification of the particles with magnesium is carried out in atmosphere with high nitrogen content thus often reaction occurs particularly if consolidation and/or densification (eg sintering with or without liquid phase) occurs at elevated temperatures, the nitrogen will react with the magnesium and/or other elements forming nitrides and thus will appear as an element in the final composition. In these cases it is often useful to have in the final composition a nitrogen content of 0.002% or higher, preferably 0.02% or higher, more preferably 0.4% or higher and even 2.2% or higher. There are even applications wherein in an embodiment % N is detrimental or not optimal for one reason or another, in these applications it is preferred % N being absent from the alloy.

It has been found that for some applications of magnesium alloys the presence of Sn (% Sn) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 1.8% by weight are desired, preferably less than 0.2% by weight, more preferably less than 0.08%, and even less than 0.004%. Obviously there are cases where the desired nominal content is 0% or nominal absence of the element as occurs with all elements for certain applications.

It has been found that for some applications of magnesium alloys the presence of zinc (% Zn) is desirable, typically in content of 0.1% by weight or higher, preferably 1.2% or more, more preferably 6% or more or even 11% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of chromium (% Cr) is desirable, typically in content of 0.2% by weight or higher, preferably 1.2% or more, more preferably 6% or more or even 11% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of titanium (% Ti) is desirable, typically in content of 0.05% by weight or higher, preferably 0.2% or more, more preferably 1.2% or more or even 4% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of zirconium (% Zr) is desirable, typically in content of 0.05% by weight or higher, preferably 0.2% or more, more preferably 1.2% or more or even 4% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of magnesium alloys the presence of Boron (% B) is desirable, typically in content of 0.05% by weight or higher, preferably 0.2% or more, more preferably 0.42% or more or even 1.2% or more. In contrast, in some applications the presence of this element is rather detrimental, in those cases are desired contents of less than 0.08% by weight, preferably less than 0.02%, more preferably less than 0.004% and even less than 0.0002%. Obviously there are cases where the desired nominal content is 0% or nominal absence of the element as occurs with all elements for certain applications.

The elements described in the preceding paragraphs may be desired separately or the combination of some of them or even all of them, as expected.

It has been seen that for some applications the excessive content of cesium, tantalum and thallium and can be detrimental, for these applications it is desirable the sum of % Cs+% Ta+% Tl less than 0.29, preferably less than 0.18%, more preferably less than 0.8%, and even less than 0.08% (without being mentioned, as in all instances in this document where amounts are mentioned as upper limits, 0% nominal content or nominal absence of the element, it is not only possible but is often desirable).

It has been seen that for some applications the excessive content of gold and silver can be detrimental, for these applications it is desirable the sum of % Au+% Ag less than 0.09%, preferably less than 0.04%, more preferably less than 0.008%, and even less than 0.002%. There are even applications wherein in an embodiment % Au is detrimental or not optimal for one reason or another, in these applications it is preferred % Au being absent from the alloy. There are even applications wherein in an embodiment % Ag is detrimental or not optimal for one reason or another, in these applications it is preferred % Ag being absent from the alloy.

It has been found that for some applications when high contents of % Ga and % Al (both above 0.5%), it is often desirable to have hardening elements for solid solution, precipitation or hard second phase forming particles. In this sense, the sum % Mn+% Si+% Fe+% Cu+% Cr+% Zn+% V+% Ti+% Zr for these applications, is desirably greater than 0.002% by weight preferably greater than 0.02%, more preferably greater than 0.3% and even higher than 1.2%.

It has been found that for some applications when % Ga content is lower than 0.1%, it is often desirable to have some limitation in hardening elements for solid solution, precipitation or hard second phase forming particles. In this sense, the sum % Cu+% Si+% Zn is desirably less than 21% by weight for these applications, preferably less than 18%, more preferably less than 9% or less than 3.8%. There are even applications wherein in an embodiment % Ga is detrimental or not optimal for one reason or another, in these applications it is preferred % Ga being absent from the alloy.

It has been found that for some applications when content % Ga below 1% and there is significant presence of % Cr (between 3% and 5%), it is often desirable to have hardening elements for solid solution or precipitation or forming hard particles second stage. In this sense, the sum % Al+% Cu is desirably higher than 0.52% by weight for these applications, preferably greater than 0.82%, more preferably greater than 1.2% and even higher than 3.2%. and/or the sum of % Ti+% Zr is desirable exceeding 0.012% by weight, preferably greater than 0055%, more preferably greater than 0.12% by weight and even higher than 0.55%.

It has been found that for some applications, especially those requiring a high mechanical strength, high resistance to high temperatures and/or high corrosion resistance, which can be very beneficial combination of gallium (% Ga) and scandium (% Sc). For these applications it is often desirable to have contents above 0.12% by weight of % Sc, preferably above 0.52%, more preferably greater than 0.82% and even above 1.2% For these applications simultaneously is often desirable to have Ga in excess of 0.12% by weight, preferably above 0.52%, more preferably greater than 0.8%, more preferably greater than 2.2% and even higher 3.5%. For some of these applications is also interesting to have further aluminium (Al %), it is often desirable to have % Al above 0.6% by weight, preferably greater than 1.2%, more preferably greater than 4.2% and even more than 6%. For some of these applications, especially when improved resistance to corrosion is required, it is also interesting the presence of zirconium (% Zr), often in excess of 0.06% weight amounts, preferably above 0.22%, more preferably above 0.52% and even greater than 1.2%. Obviously, like all other paragraphs herein any other element may be present in the amounts described in the preceding and coming paragraphs.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are several elements such as rare earth elements (RE) that are detrimental in specific applications; For these applications in an embodiment RE are absent from the composition.

Any of the above Mg alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of a magnesium alloy for manufacturing metallic or at least partially metallic components.

In an embodiment refers to a copper based alloy with the following composition, all percentages in weight percent:

| % Si: 0-50 (commonly 0-20); | | % Al: 0-20; | % Mn: 0-20; |
|---|---|---|---|
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-8; |
| % B: 0-5; | % Mg: 0-50 (commonly 0-20); | | % Ni: 0-50; |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5 | % O: 0-15 | | |

The rest consisting on copper and trace elements

In this context trace elements refers to any element of the list: H, He, Xe, F, Ne, Na, P, S, Cl, Ar, K, Br, Kr, Sr, Tc, Ru, Rh, Pd, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt. The inventor has found that it is important for some applications of the present invention limit the content of trace elements to amounts of less than 1.8%, preferably less than 0.8%, more preferably less than 0.1% and even below 0.03% by weight, alone and/or in combination.

Trace elements can be added intentionally to attain a particular functionality to the alloy such as reducing cost production of the alloy and/or its presence may be unintentional and related mostly to the presence of impurities in the alloying elements and scraps used for the production of the alloy

There are several applications wherein the presence of trace elements is detrimental for the overall properties of the copper based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the copper based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

There are applications wherein copper based alloys are benefited from having a high copper (% Cu) content but not necessary the copper being the majority component of the alloy. In an embodiment % Cu is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Cu is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Cu is not the majority element in the copper based alloy.

The nominal composition expressed herein can refer to particles with higher volume fraction and/or to the overall final composition once the resin or other organic component if present, is removed, even if there are several phases, important segregations or others. In cases where there are presence of immiscible particles as ceramic reinforcements, graphene, nanotubes or others, these are not counted in the nominal composition.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 54% or more when incorporating these phases. Once incorporated and when evaluating the overall composition measured as stated in this application, the resulting copper alloy generally has a 0.8% or more of the element (in this case % Ga), preferably 2.2% or more, more preferably 5.2% or more and even 12% or more. It has been found that in some applications the % Ga can be replaced wholly or partially by Bi % with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C. the, more preferably below 180° C. or even below 46° C. For some applications it is more interesting alloy with these elements directly and not incorporate in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

The case of scandium (Sc) is exemplifying, because using them very interesting mechanical properties may be reached, but its cost makes interesting from an economic point of view to use the amount needed for the application of interest. Its high deoxidizing power is also interesting during alloys processing but also a challenge to maximize performance. So depending on the application you can move from situations wherein is not a desired element, to a situations wherein a high content of this element is desired, 0.6% by weight or more, preferably 1.1% by weight or more, more preferably 1.6% by weight or more and even 4.2% or more. There are even applications wherein in an embodiment % Sc is detrimental or not optimal for one reason or another, in these applications it is preferred % Sc being absent from the alloy.

It has been found that for some applications copper alloys the presence of silicon (% Si) is desirable, typically in contents of 0.2% by weight or higher, preferably 1.2% or more, more preferably 6% or more or even 11% or more. In contrast, in some applications the presence of this element is rather detrimental in which case contents of less than 0.2% by weight are desired, preferably less than 0.08%, more preferably less than 0.02% and even less than 0.004%. Obviously there are cases where the desired nominal content is 0% or nominal absence of the element as with all elements for certain applications.

It has been found that for some applications of copper alloys the presence of iron (% Fe) is desirable, typically in contents of 0.3% by weight or higher, preferably 0.6% or more, more preferably 1.2% or more or even 6% or more. In contrast, in some applications the presence of this element is rather detrimental, in those cases contents of less than 0.2% by weight are desired, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of copper (% Cu) is desirable, typically in content of 0.06% by weight or higher, preferably 0.2% or more, more preferably 1.2% or more or even 6% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of manganese (% Mn) is desirable, typically in content of 0.1% by weight or higher, preferably 0.6% or more, more preferably 1.2% or more or even 6% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of aluminium (% Al) is desirable, typically in content of 0.2% by weight or higher, preferably 1.2% or more, more preferably 6% or more or even 11% or more. In contrast, in some applications the presence of this element is rather detrimental, in those cases contents of less than 1.8% by weight are desired, are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications in copper alloys the presence of nitrogen (% N) is desirable, typically in contents of 0.2% by weight or higher, preferably 1.2% or more, more preferably 3.2% or more or even 4.2% or more. For some applications it is interesting that the consolidation and/or densification of the particles with copper is carried out in atmosphere with high nitrogen content thus often reaction occurs particularly if consolidation and/or densification (eg sintering with or without liquid phase) occurs at elevated temperatures, the nitrogen will react with the copper and/or other elements forming nitrides and thus will appear as an element in the final composition. In these cases it is often useful to have in the final composition a nitrogen content of 0.002% or higher, preferably 0.02% or higher, more preferably 0.4% or higher and even 2.2% or higher. There are even applications wherein in an embodiment % N is detrimental or not optimal for one reason or another, in these applications it is preferred % N being absent from the alloy.

It has been found that for some applications of copper alloys the presence of Sn (% Sn) is desirable, typically in an embodiment in content of 0.2% by weight or higher, in another embodiment preferably 1.2% or more, in another embodiment more preferably 6% or more or even in another embodiment 11% or more. In contrast, in some applications the presence of this element is rather detrimental, in those cases in an embodiment contents of less than 1.8% by weight are desired, preferably less than 0.2% by weight, more preferably less than 0.08%, and even less than 0.004%. Obviously there are cases where the desired nominal content is 0% or nominal absence of the element as occurs with all elements for certain applications.

It has been found that for some applications of copper alloys the presence of zinc (% Zn) is desirable, typically in content of 0.1% by weight or higher, preferably 1.2% or more, more preferably 6% or more or even 11% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of chromium (% Cr) is desirable, typically in content of 0.2% by weight or higher, preferably 1.2% or more, more preferably 6% or more or even 11% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of titanium (% Ti) is desirable, typically in content of 0.05% by weight or higher, preferably 0.2% or more, more preferably 1.2% or more or even 4% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of zirconium (% Zr) is desirable, typically in content of 0.05% by weight or higher, preferably 0.2% or more, more preferably 1.2% or more or even 4% or more. In contrast, in some applications the presence of this element is rather detrimental, in those cases are desired contents of less than 0.2% by weight, preferably less than 0.08%, more preferably less than 0.02% and even less than 0.004%. Obviously there are cases where the desired nominal content is 0% or nominal absence of the element as occurs with all elements for certain applications.

It has been found that for some applications of copper alloys the presence of Boron (% B) is desirable, typically in content of 0.05% by weight or higher, preferably 0.2% or more, more preferably 0.42% or more or even 1.2% or more. In contrast, in some applications the presence of this element is rather detrimental, in those cases are desired contents of less than 0.08% by weight, preferably less than 0.02%, more preferably less than 0.004% and even less than 0.0002%. Obviously there are cases where the desired nominal content is 0% or nominal absence of the element as occurs with all elements for certain applications.

The elements described in the preceding paragraphs may be desired separately or the combination of some of them or even all of them, as expected.

It has been seen that for some applications the excessive content of cesium, tantalum and thallium and can be detrimental, for these applications it is desirable the sum of % Cs+% Ta+% Tl less than 0.29, preferably less than 0.18%, more preferably less than 0.8%, and even less than 0.08% (without being mentioned, as in all instances in this document where amounts are mentioned as upper limits, 0% nominal content or nominal absence of the element, it is not only possible but is often desirable).

It has been seen that for some applications the excessive content of gold and silver can be detrimental, for these applications it is desirable the sum of % Au+% Ag less than 0.09%, preferably less than 0.04%, more preferably less than 0.008%, and even less than 0.002%. There are even applications wherein in an embodiment % Au is detrimental or not optimal for one reason or another, in these applications it is preferred % Au being absent from the alloy. There are even applications wherein in an embodiment % Ag is detrimental or not optimal for one reason or another, in these applications it is preferred % Ag being absent from the alloy.

It has been found that for some applications when high contents of % Ga and % Mg (both above 0.5%), it is often desirable to have hardening elements for solid solution, precipitation or hard second phase forming particles. In this sense, the sum % Mn+% Si+% Fe+% Al+% Cr+% Zn+% V+% Ti+% Zr for these applications, is desirably greater than 0.002% by weight preferably greater than 0.02%, more preferably greater than 0.3% and even higher than 1.2%.

It has been found that for some applications when % Ga content is lower than 0.1%, it is often desirable to have some limitation in hardening elements for solid solution, precipitation or hard second phase forming particles. In this sense, the sum % Al+% Si+% Zn is desirably less than 21% by weight for these applications, preferably less than 18%, more preferably less than 9% or less than 3.8%. There are even applications wherein in an embodiment % Ga is detrimental or not optimal for one reason or another, in these applications it is preferred % Ga being absent from the alloy.

It has been found that for some applications when content % Ga below 1% and there is significant presence of % Cr (between 3% and 5%), it is often desirable to have hardening elements for solid solution or precipitation or forming hard particles second stage. In this sense, the sum % Mg+% Al is desirably higher than 0.52% by weight for these applications, preferably greater than 0.82%, more preferably greater than 1.2% and even higher than 3.2%. and/or the sum of % Ti+% Zr is desirable exceeds 0.012% by weight, preferably greater than 0055%, more preferably greater than 0.12% by weight and even higher than 0.55%.

It has been found that for some applications, especially those requiring a high mechanical strength, high resistance to high temperatures and/or high corrosion resistance, which can be very beneficial combination of gallium (% Ga) and scandium (% Sc). For these applications it is often desirable to have contents above 0.12% wt % of Sc, preferably above 0.52%, more preferably greater than 0.82% and even above 1.2% For these applications simultaneously is often desirable to have Ga in excess of 0.12% wt %, preferably above 0.52%, more preferably greater than 0.8%, more preferably greater than 2.2 more % and even higher 3.5%. For some of these applications is also interesting to have further magnesium (% Mg), it is often desirable to have % Mg above 0.6% by weight, preferably greater than 1.2%, more preferably greater than 4.2% and even more than 6%. For some of these applications, especially improved resistance to corrosion is required, it is also interesting for the presence of zirconium (% Zr), often amounts in excess of 0.06% weight, preferably above 0.22%, more preferably above 0.52% and even greater than 1.2%. Obviously, like all other paragraphs herein any other element may be present in the amounts described in the preceding and coming paragraphs.

There are several elements such as Ag and Mn that are detrimental in specific applications especially for certain Ga contents; For these applications in an embodiment with % Ga between 4.3% and 16.7%, % Ag is below 18.8%, or even Ag is absent from the composition. In another embodiment with % Ga between 4.3% and 16.7%, % Ag is above 44%. In another embodiment with % Ga between 4.3% and 12.7%, % Mn is below 7.8%, or even Mn is absent from the composition. Even in another embodiment with % Ga between 4.3% and 12.7%, % Mn is above 14.8%. %. In another embodiment with % Ga between 1.5% and 4.1%, % Ag is below 5.8%, or even Ag is absent from the composition. Even in another embodiment with % Ga between 1.5% and 4.1%, % Ag is above 10.8%.

There are several elements such as P, S, As, Pb and B that are detrimental in specific applications especially for certain Ga contents; For these applications in an embodiment with % Ga between 0.0008% and 6.3%, at least one of P, S, As, Pb and B are absent from the composition.

It has been found that for some applications, certain contents of elements such as P may be detrimental especially for certain Fe and/or Co contents. For these applications in an embodiment with % Fe between 0.0087% and 3.8%, % P is lower than 0.0087% or even P is absent from the composition. In another embodiment with % Fe between 0.0087% and 3.8%, % P is higher than 0.17%, in another embodiment with % Fe between 0.0087% and 3.8%, % P is higher than 0.35%, in another embodiment with % Fe between 0.0087% and 3.8%, % P is higher than 0.56% and even in another embodiment with % Fe between 0.0087% and 3.8%, % P is higher than 1.8%. In another embodiment with % Co between 0.0087% and 3.8%, % P is lower than 0.008% or even absent from the composition. Even in another embodiment with Co between 0.0087% and 3.8%, % P is higher than 0.68%.

There are several applications wherein the presence of Si, P, Sn and Fe in the composition is detrimental for the overall properties of the copper based alloy especially for certain Ni and/or Zn contents. In an embodiment with % Ni between 0.34% and 5.2%, % Si is below 0.03% or even absent from the composition or % Si is above 2.3%. Even in another embodiment with % Ni between 0.087% and 32.8%, % P is below 0.087% or absent from the composition or % P is above 0.48% and/or % Sn is below 0.08% or even absent or % Sn is above 3.87%. In another embodiment with % Ni between 0.87% and 2.8%, % Fe is below 1.22% or absent from the composition or % Fe is above 3.24%. Even in another embodiment with % Zn between 0.087% and 4.2%, % Si is below 4.1% or % Si is higher than 6.1%. In another embodiment where the copper alloy contains Zn, % P is absent from the composition or % P is above 45 ppm.

There are several elements such as P, Sb, As and Bi that are detrimental in specific applications; For these applications in an embodiment at least one of P, Sb, As and Bi are absent from the composition.

There are several applications wherein the presence of Nb and Ti in the composition is detrimental for the overall properties of the copper based alloy especially for certain Fe and/or Cr contents. In an embodiment with % Fe and/or % Cr above 0.0086%, % Nb and/or % Ti is below 0.087% or even absent from the composition.

There are several elements such as Cd, Cr, Co, Pd and Si that are detrimental in specific applications especially for certain Ga, Ge and Sb contents; For these applications in an embodiment containing Ga and/or Ge and/or Sb, at least one of Cd, Cr, Co, Pd and Si are absent from the composition.

It has been found that for some applications, certain contents of elements such as In, Eu, Tm, Cr, Co, B and Si may be detrimental especially for certain Ga contents. For these applications in an embodiment with % Ga between 0.087% and 0.31%, % Cr is lower than 0.77% and/or % Co is lower than 0.97% or even at least one of them absent from the composition. In another embodiment with % Ga between 0.087% and 0.31%, % Cr is higher than 1.77% and/or % Co is higher than 1.97%. In an embodiment with % Ga between 2.37% and 7.31%, % Si is lower than 17.7% and/or % B is lower than 1.27% or even at least one of them absent from the composition. In another embodiment with % Ga between 2.37% and 6.31%, % Si is higher than 27.7% and/or % B is higher than 5.17%. Even in another an embodiment with % Ga between 0.37% and 1.31%, % In is lower than 4.7% even absent from the composition. In another embodiment with % Ga between 0.37% and 1.31%, % In is higher than 11.7%. In another embodiment with % Ga between 0.025% and 0.061%, % Eu is below 0.025% and/or % Tm is below 0.015% or even at least one of them absent from the composition. In an embodiment with % Ga between 0.025% and 0.061%, % Eu is above 0.051% and/or % Tm is above 0.041%.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are several elements such as Co that are detrimental in specific applications especially for certain Al contents; For these applications in an embodiment with % Al between 5.3% and 14.3%, % Co is lower than 0.37% or even is absent from the composition. In another embodiment with % Al between 5.3% and 14.3%, % Co is higher than 3.37%

There are several elements such as rare earth elements (RE) that are detrimental in specific applications; For these applications in an embodiment RE are absent from the composition.

Any of the above Cu alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of a copper alloy for manufacturing metallic or at least partially metallic components.

The present invention is particularly suitable for applications that can benefit from iron-based alloys with high mechanical resistance. There are many applications that can benefit from an alloy iron base with high mechanical strength, to name a few: structural elements (in the transport industry, construction, energy transformation . . . ), tools (molds, dies, . . . ), drives or elements mechanical, etc. Applying certain rules of alloy design and processing these iron base alloys high strength may be provided with high environmental resistance (resistance to oxidation, corrosion, . . . ). In particular it is especially suitable for building components with a composition expressed below.

In an embodiment the invention refers to an iron based alloy having the following composition, all percentages being in weight percent:

| | | | |
|---|---|---|---|
| % Ceq = 0.15-4.5 | % C = 0.15-2.5 | % N = 0-2 | % B = 0-3.7 |
| % Cr = 0.1-20 | % Ni = 3-30 | % Si = 0.001-6 | % Mn = 0.008-3 |
| % Al = 0.2-15 | % Mo = 0-10 | % W = 0-15 | % Ti = 0-8 |
| % Ta = 0-5 | % Zr = 0-12 | % Hf = 0-6, | % V = 0-12 |
| % Nb = 0-10 | % Cu = 0-10 | % Co = 0-20 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-20 |
| % Sn = 0-10 | % Rb = 0-10 | % Cd = 0-10 | % Cs = 0-10 |
| % La = 0-5 | % Pb = 0-10 | % Zn = 0-10 | % In = 0-10 |
| % Ge = 0-5 | % Y = 0-5 | % Ce = 0-5 | |

The rest consisting on iron (Fe) and trace elements

wherein % Ceq=% C+0.86*% N+1.2*% B

Characterized in that

% Cr+% V+% Mo+% W+% Ga>3 and

% Al+% Mo+% Ti+% Ga>1.5

With the proviso that:

when % Ceq=0.45-2.5, then % V=0.6-12; o

when % Ceq=0.15-0.45, then % V=0.85-4; o

when % Ceq=0.15-0.45, then % Ti+% Hf+% Zr+% Ta=0.1-4; or

% Ga=0.01-15;

There are applications wherein iron based alloys are benefited from having a high iron (% Fe) content but not necessary iron being the majority component of the alloy. In an embodiment % Fe is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Fe is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Fe is not the majority element in the iron based alloy.

In this context trace elements refers to any element of the list: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the iron based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the iron based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 14% or more and even 19% or more when incorporating these phases. Once incorporated and when evaluating the overall composition measured as stated in this application, the resulting iron alloy generally has a 0.2% or more of the element (in this case % Ga), preferably 1.2% or more, more preferably 2.2% or more and even 6% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. It has been found that in some applications the % Ga can be replaced wholly or partially by % Bi with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C. the, more preferably below 180° C. or even below 46° C. For some applications it is more interesting alloy with these elements directly and not incorporate in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

It has been found that for some applications, excessive presence of nickel (% Ni) may be detrimental, for these applications is desirable a % Ni content of less than 24%, more preferably less than 12%, and even less than 7.5%. In contrast there are applications wherein the presence of nickel at higher levels is desirable for those applications higher than 6% by weight, more preferably higher than 8%, and even higher than 16%. There are even applications wherein in an embodiment % Ni is detrimental or not optimal for one reason or another, in these applications it is preferred % Ni being absent from the alloy.

It has been found that for some applications, excessive presence of chromium (% Cr) may be detrimental, for these applications is desirable a % Cr content of less than 14% by weight, preferably less than 9.8%, more preferably less than 8.8% by weight and even less than 6%. By contrast there are applications wherein the presence of chromium at higher levels is desirable; for these applications amounts exceeding 1.2% by weight are desirable, preferably greater than 5.5% by weight, more preferably over 7%, in another embodiment and even greater than 16%. There are even applications wherein in an embodiment % Cr is detrimental or not optimal for one reason or another, in these applications it is preferred % Cr being absent from the alloy.

It has been seen that for some applications the presence of excessive aluminum (% Al) can be detrimental, for these applications is desirable a % Al content of less than 7.8% by weight, preferably less than 4.8%, more preferably less than 1.8% by weight and even less than 0.8%. In contrast there are applications wherein the presence of aluminum at higher levels is desirable, especially when a high hardening and/or environmental resistance are required, for these applications are desirable amounts, greater than 1.2% by weight, preferably greater than 3.2% by weight, more preferably above 8.2% and even above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi, % Cd, % Cs, % Sn, % Pb, % Zn, % Rb or % In with the amounts described in this paragraph, and to the definitions of s and T, the % Ga is replaced by the sum: % Ga+% Bi+% Cd+% Cs+% Sn+% Pb+% Zn+% Rb+% In, where depending on the application may be interesting the absence of any of them (ie although the sum is in line with the values given any of the elements may be absent and have a nominal content of 0%, this being advantageous for a given application where the element in question are detrimental or not optimal for one reason or another).

It has been seen that for some applications, the excessive presence of cobalt (% Co) may be detrimental, for these applications is desirable a % Co content of less than 9.8% by weight, preferably less than 4.6%, more preferably less than 2.8% by weight, and eve less than 0.8%. In contrast there are applications wherein the presence of cobalt in higher amounts is desirable. For these applications are desirable amounts exceeding 2.2% by weight, preferably higher than 4%, more preferably greater than 8% and even greater than 12%. There are even applications wherein in an embodiment % Co is detrimental or not optimal for one reason or another, in these applications it is preferred % Co being absent from the alloy.

It has been seen that for some applications the presence of excessive carbon equivalent (% Ceq) may be detrimental, for these applications is desirable a % Ceq content of less than 2.4% by weight, preferably less than 1.8%, more preferably less than 0.9% by weight and even less than 0.58%. In contrast there are applications wherein the presence of carbon equivalent in higher amounts is desirable for these applications amounts exceeding 0.27% by weight are desirable, preferably greater than 0.52% by weight, more preferably greater than 0.82% and even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 1.8% by weight, preferably less than 0.9%, more preferably less than 0.58% by weight and even less than 0.44%. In contrast there are applications where the presence of carbon at higher levels is desirable. For these applications amounts exceeding 0.27% by weight are desirable, preferably greater than 0.52% by weight, more preferably greater than 0.82% and even greater than 1.2%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 1.8% by weight preferably less than 0.9%, more preferably less than 0.06% by weight and even less than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that there are applications for which the presence of nitrogen (% N) may be detrimental and it is preferable to its absence (may not be economically viable remove beyond the content as an impurity, less than 0.1% by weight, preferably less to 0.008%, more preferably less than 0.0008% and even less than 0.00008%). It has been seen that there are applications for which the presence of boron (% B) may be detrimental and it is preferable its absence (it may not be economically viable remove beyond the content as an impurity, less than 0.1% by weight, preferably less to 0.008%, more preferably less than 0.0008% and even less than 0.00008%). There are even applications wherein in an embodiment % B is detrimental or not optimal for one reason or another, in these applications it is preferred % B being absent from the alloy.

It has been found that for some applications, the excessive presence of titanium (% Ti), zirconium (% Zr) and/or hafnium (% Hl may be detrimental, for these applications is desirable a content of % Ti+% Zr+% Hf of less than 7.8% by weight, preferably less than 4.8%, more preferably less than 1.8% by weight and even below 0.8%. In contrast there are applications where the presence of some of these elements at higher levels is desirable, especially where a high hardening and/or environmental resistance is required, for these applications amounts of % Ti+% Zr+% Hf greater than 0.1% by weight are desirable, preferably greater than 1.2% by weight, by weight, more preferably above 6%, or even above 12%. There are even applications wherein in an embodiment % Ti is detrimental or not optimal for one reason or another, in these applications it is preferred % Ti being absent from the alloy.

It has been found that for some applications, the excessive presence of molybdenum (% Mo) and/or tungsten (% W) may be detrimental, for these applications a lower % Mo+½% W content is desirable of less than 14% by weight, preferably less than 9%, more preferably less than 4.8% by weight and even below 1.8%. In contrast there are applications where the presence of molybdenum and tungsten at higher levels is desirable, for these applications amounts of % Mo+½% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been found that for some applications, the excessive presence of Vanadium (% V) may be detrimental, for these applications is desirable % V content less than 9.8% by weight, preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 2.2% by weight, more preferably greater than 4.2% and even above 10.2%. There are even applications wherein in an embodiment % V is detrimental or not optimal for one reason or another, in these applications it is preferred % V being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Sn that are detrimental in specific applications especially for certain Cr and/or C contents; For these applications in an embodiment with % Cr between 0.47% and 5.8% and/or C between 0.7% and 2.74%, % Sn is below 0.087% or even absent from the composition, even in another embodiment with % Cr between 0.47% and 5.8% and/or C between 0.7% and 2.74%, % Sn is above 0.92%.

There are several applications wherein the presence of Si and B in the composition is detrimental for the overall properties of the steel, especially for certain Cu and/or B contents. For these applications in an embodiment with % Cu between 0.097 atomic % (at. %) and 3.33 at. %, the total content of % B and/or % Si is below 4.77 at. %, in another embodiment with % Cu between 0.097 at. % and 3.33 at. %, the total content of % B and/or % Si is below 1.33 at. %, in another embodiment with % Cu between 0.097 at. % and 3.33 at. %, % B is below 2.4 at. % and/or % Si is below 5.77 at. %, in another embodiment with % Cu between 0.097 at. % and 3.33 at. %, % B is above 16.2 at. % and/or % Si is above 27.2 at. %. In another embodiment with % Cu between 0.097 at. % and 3.33 at. %, the total content of % B and % Si is above 31 at. %, in another embodiment with % Cu between 0.097 at. % and 3.33 at. %, the total content of % B and % Si is above 31 at. %. In another embodiment with % Cu between 0.3 at. % and 1.7 at. %, % B is below 4.2 at. % and/or % Si is below 8.77 at. %, in another embodiment with % Cu between 0.3 at. % and 1.7 at. %, % B is above 9.2 at. % and/or % Si is above 17.2 at. %. In another embodiment with % Cu between 0.097 at. % and 3.33 at. %, % B is below 9.77 at. %, in another embodiment with % Cu between 0.097 at. % and 3.33 at. %, % B is above 22.2 at. % even in another embodiment with % Cu between 0.097 at. % and 3.33 at. %, % B is above 32.2 at. %. In another embodiment with % Cu between 0.97 at. % and 3.33 at. %, % B is below 9.77 at. %, in another embodiment with % Cu between 0.97 at. % and 3.33 at. %, % B is above 22.2 at. %. In another embodiment with % B between 0.97 at. % and 33.33 at. %, the total content of % B and/or % Si is below 1.33 at. %, in another embodiment with % B between 0.97 at. % and 33.33 at. %, the total content of % B and/or % Si is above 33.33 at. %.

It has been found that for some applications, certain contents of elements such as Si and B may be detrimental especially for certain Al and Ga contents. For these applications in an embodiment with % Al between 1.87 at. % and 16.6 at. %, % B is lower than 3.87%. In another embodiment with % Al between 1.87 at. % and 16.6 at. %, % B is higher than 23.87%. Even in another embodiment with % Al between 1.87 at. % and 16.6 at. % and/or % Ga between 0.43 at. % and 5.2 at. %, % B is below 1.33 at. % and/or % Si is below 0.43 at. %. In another embodiment with % Al between 1.87 at. % and 16.6 at. % and/or % Ga between 0.43 at. % and 5.2 at. %, % B is above 11.33 at. % and/or % Si is above 5.43 at. %.

There are several elements such as Co that are detrimental in specific applications especially for certain Ni contents; For these applications in an embodiment with % Ni between 24.47% and 35.8%, % Co is lower than 12.6%. Even in another embodiment with % Ni between 24.47% and 35.8%, % Co is higher than 26.6%.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are several elements such as rare earth elements (RE) that are detrimental in specific applications; For these applications in an embodiment RE are absent from the composition.

Any of the above Fe alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an iron alloy for manufacturing metallic or at least partially metallic components.

The present invention is very interesting for applications that benefit from the properties of tool steels. It is a further implementation of the present invention the production of resins capable of polymerizing radiation loaded with tool steel particles. In this sense they are considered particles of tool steels having the composition those described below, or those combined with other results in the composition described below in way to be interpreted herein.

In an embodiment the invention refers to an iron based alloy having the following composition, all percentages being in weight percent:

| | | | |
|---|---|---|---|
| % Ceq = 0.15-3.5 | % C = 0.15-3.5 | % N = 0-2 | % B = 0-2.7 |
| % Cr = 0-20 | % Ni = 0-15 | % Si = 0-6 | % Mn = 0-3 |
| % Al = 0-15 | % Mo = 0-10 | % W = 0-15 | % Ti = 0-8 |
| % Ta = 0-5 | % Zr = 0-6 | % Hf = 0-6, | % V = 0-12 |
| % Nb = 0-10 | % Cu = 0-10 | % Co = 0-20 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-20 |
| % Sn = 0-10 | % Rb = 0-10 | % Cd = 0-10 | % Cs = 0-10 |
| % La = 0-5 | % Pb = 0-10 | % Zn = 0-10 | % In = 0-10 |
| % Ge = 0-5 | % Y = 0-5 | % Ce = 0-5 | |

The rest consisting on iron (Fe) and trace elements

wherein

% Ceq=% C+0.86*% N+1.2*% B,

Characterized in that

% Cr+% V+% Mo+% W+% Nb+% Ta+% Zr+% Ti>3

There are applications wherein iron based alloys are benefited from having a high iron (% Fe) content but not necessary iron being the majority component of the alloy. In an embodiment % Fe is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Fe is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Fe is not the majority element in the iron based alloy.

In this context trace elements refers to any element of the list: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Re, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the iron based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the iron based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 14% or more and even 19% or more when incorporating these phases. Once incorporated and when evaluating the overall composition measured as stated in this application, the resulting iron alloy generally has a 0.2% or more of the element (in this case % Ga), preferably 1.2% or more, more preferably 2.2% or more and even 6% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. It has been found that in some applications the % Ga can be replaced wholly or partially by % Bi with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C. the, more preferably below 180° C. or even below 46° C. For some applications it is more interesting alloy with these elements directly and not incorporate in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

It has been found that for some applications, excessive presence of nickel (% Ni) may be detrimental, for these applications is desirable a % Ni content of less than 8%, preferably less than 2.8%, more preferably less than 1.8%, and even less than 0.008%. In contrast there are applications wherein the presence of nickel at higher levels is desirable for those applications higher than 1.2% by weight, preferably higher than 2.2%, more preferably higher than 5.2%, and even higher than 11%. There are even applications wherein in an embodiment % Ni is detrimental or not optimal for one reason or another, in these applications it is preferred % Ni being absent from the alloy.

It has been found that for some applications, excessive presence of chromium (% Cr) may be detrimental, for these applications is desirable a % Cr content of less than 14% by weight, preferably less than 3.8%, more preferably less than 0.8% by weight and even less than 0.08%. In contrast there are applications wherein the presence of chromium at higher levels is desirable, for these applications amounts exceeding 1.2% by weight are desirable, preferably greater than 5.5% by weight, more preferably over 7%, in another embodiment and even greater than 16%. There are even applications wherein in an embodiment % Cr is detrimental or not optimal for one reason or another, in these applications it is preferred % Cr being absent from the alloy.

It has been found that for some applications, the excessive presence of molybdenum (% Mo) and/or tungsten (% W) may be detrimental, for these applications a lower % Mo+½% W content is desirable of less than 14% by weight, preferably less than 9%, more preferably less than 4.8% by weight and even below 1.8%. In contrast there are applications where the presence of molybdenum and tungsten at higher levels is desirable, for these applications amounts of % Mo+½% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been seen that for some applications the presence of excessive carbon equivalent (% Ceq) may be detrimental, for these applications is desirable a % Ceq content of less than 2.4% by weight, preferably less than 1.8%, more preferably less than 0.9% by weight and even less than 0.38%. In contrast there are applications wherein the presence of carbon equivalent in higher amounts is desirable for these applications amounts exceeding 0.27% by weight are desirable, preferably greater than 0.42% by weight, more preferably greater than 0.82% and even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 1.8% by weight, preferably less than 0.9%, more preferably less than 0.58% by weight and even less than 0.44%. In contrast there are applications where the presence of carbon at higher levels is desirable. For these applications amounts exceeding 0.27% by weight are desirable, preferably greater than 0.32% by weight, more preferably greater than 0.42% and even greater than 1.2%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 1.8% by weight, preferably less than 0.9%, more preferably less than 0.06% by weight and even less than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that for some applications the presence of excessive nitrogen (% N) can be harmful, for these applications is desirable a % N content of less than 1.4% by weight, preferably less than 0.9%, more preferably less than 0.06% by weight and even less than 0.006%. By contrast there are applications where the presence of nitrogen in higher amounts is desirable for these applications above 60 ppm amounts by weight are desirable, preferably above 200 ppm, more preferably greater than 0.2% and even above 1.2%. There are even applications wherein in an embodiment % N is detrimental or not optimal for one reason or another, in these applications it is preferred % N being absent from the alloy.

It has been seen that there are applications for which the presence of nitrogen (% N) may be harmful and it is preferable to its absence (may not be economically viable remove beyond the content as an impurity, less than 0.1% by weight, preferably less to 0.008%, more preferably less than 0.0008% and even less than 0.00008%). It has been seen that there are applications for which the presence of boron (% B) may be detrimental and it is preferable its absence (it may not be economically viable remove beyond the content as an impurity, less than 0.1% by weight, preferably less to 0.008%, more preferably less than 0.0008% and even less than 0.00008%).

It has been found that for some applications, the excessive presence of % Si may be detrimental, for these applications is desirable % Si amount less than 1.8%, preferably less than 0.45%, more preferably less than 0.8% by weight, and even less than 0.08% In contrast there are applications wherein the presence of % Si in higher amounts is desirable above 0.27% preferably above 0.52%, more preferably above 0.82%, above 1.2%. There are even applications wherein in an embodiment % Si is detrimental or not optimal for one reason or another, in these applications it is preferred % Si being absent from the alloy.

It has been found that for some applications, the excessive presence of Vanadium (% V) may be detrimental, for these applications is desirable % V content less than 9.8% by weight preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 2.2% by weight, more preferably greater than 4.2% and even above 10.2%. There are even applications wherein in an embodiment % V is detrimental or not optimal for one reason or another, in these applications it is preferred % V being absent from the alloy.

It has been seen that for some applications the presence of excessive aluminum (% Al) can be detrimental, for these applications is desirable a % Al content of less than 7.8% by weight, preferably preferably less than 4.8%, more preferably less than 1.8% by weight and even less than 0.8%. In contrast there are applications wherein the presence of aluminum at higher levels is desirable, especially when a high hardening and/or environmental resistance are required, for these applications are desirable amounts, greater than 1.2% by weight, preferably greater than 3.2% by weight, more preferably above 8.2% and even above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=5*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi, % Cd, % Cs, % Sn, % Pb, % Zn, % Rb or % In with the amounts described in this paragraph, and to the definitions of s and T, the % Ga is replaced by the sum: % Ga+% Bi+% Cd+% Cs+% Sn+% Pb+% Zn+% Rb+% In, where depending on the application may be interesting the absence of any of them (ie although the sum is in line with the values given any of the elements may be absent and have a nominal content of 0%, this being advantageous for a given application where the elements in question are detrimental or not optimal for one reason or another).

It has been found that there are applications where the presence of titanium is desirable. Normally in amounts greater than 0.05% by weight, preferably greater than 0.2% by weight, more preferably above 1.2% or even above 4%. In contrast for some applications, the excessive presence of titanium (% Ti) may be detrimental, for these applications is desirable % Ti content of less than 1.8% by weight, preferably less than 0.8%, more preferably less than 0.02% by weight, and even less than 0.004%. There are even some applications for a given application wherein % Ti is detrimental or not optimal for one reason or another, in these applications in an embodiment it is preferred % Ti being absent from the iron based alloy.

It has been found that for some applications it is interesting to have a silicon content simultaneously and/or manganese with generally high presence of zirconium and/or titanium which sometimes can be replaced by chromium. In this case the condition % Cr+% V+% Mo+% W+% Nb+% Ta+% Zr+% Ti>3 is reduced to % Cr+% V+% Mo+% W+% Nb+% Ta+% Zr+% Ti>1.5. For these cases it has been found that % Mn+% Si if desirable are above 1.55%, preferably greater than 2.2%, more preferably 5.5% higher and even higher than 7.5%. For some applications of these cases it has been found that the content of % Mn+% Si should not be excessive, in these cases it is desirable to have contained less than 14%, preferably less than 9%, more preferably less than 6.8% and even below 5.9%. For some of these cases it has been seen that it is desirable to have % Mn content exceeding 2.1%, preferably greater than 4.1%, more preferably greater than 6.2% and even higher than 8.2%. For some of these cases has been that excessive content of % Mn can be harmful and is convenient to have content of % Mn less than 14%, preferably less than 9%, more preferably less than 6.8% and even less than 4.2%. For some of these cases it has been seen that it is convenient to have content above 1.2% Si %, preferably greater than 1.6%, more preferably greater than 2.1% and even higher than 4.2%. For some of these cases it has been seen that an excessive content of % Si can be harmful and is convenient to have content % Si less than 9%, preferably less than 4.9%, more preferably less than 2.9% and even less than 1.9%. For some of these cases it has been seen that it is desirable to have content above 0.55% % Ti, preferably greater than 1.2%, more preferably greater than 2.2% and even higher than 4.2%. For some of these cases has been that excessive content of % Ti can be harmful and is convenient to have contents of % Ti less than 8%, preferably less than 4%, more preferably less than 2.8% and even less than 0.8%. For some of these cases it has been seen that it is desirable to have higher contents of % Zr to 0.55%, preferably greater than 1.55%, more preferably greater than 3.2% and even higher than 5.2%. For some of these cases has been that excessive content of % Zr can be harmful and is convenient to have content of % Zr less than 8%, preferably less than 5.8%, more preferably less than 4.8% and even less than 1.8%. For some of these cases it has been seen that it is desirable to have higher contents of % C to 0.31%, preferably greater than 0.41%, more preferably greater than 0.52% and even higher than 1.05%. For some of these cases has been that excessive content of % C can be harmful and is convenient to have % C content lower than 2.8%, preferably less than 1.8%, more preferably less than 0.9% and even less than 0.48%. Obviously for these and other elements apply the requirements of special applications of the rest of the section they are all compatible with the special applications described in this paragraph (as in the rest of the document). These alloys are especially interesting for some applications if bainitic treatments are performed and/or treatments retained austenite to have large increases in hardness with the application of a low temperature treatment (below 790° C., preferably below 690° C., more preferably below 590° C. and even below 490° C.). It is suitable for some applications microstructure set to have a hardness increase of 6HRc or more, preferably 11HRc or more, more preferably 16HRc or more and even more 21 HRc or. (If the microstructure is fine adjusted in some cases may be passed around to 200HB to 60 HRc in the low temperature treatment. Particles of these alloys are especially interesting also for processes of AM of metal melt particles (as is the case for many of the alloys presented herein although no special mention is made).

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Sn that are detrimental in specific applications especially for certain Cr and/or C contents; For these applications in an embodiment with % Cr between 0.47% and 5.8% and/or C between 0.7% and 2.74%, % Sn is below 0.087% or even absent from the composition, even in another embodiment with % Cr between 0.47% and 5.8% and/or C between 0.7% and 2.74%, % Sn is above 0.92%.

There are several applications wherein the presence of Si and B in the composition is detrimental for the overall properties of the steel, especially for certain Cu and/or B contents. For these applications in an embodiment with % Cu between 0.097 atomic % (at. %) and 3.33 at. %, the total content of % B and/or % Si is below 4.77 at. %, in another embodiment with % Cu between 0.097 at. % and 3.33 at. %, the total content of % B and/or % Si is below 1.33 at. %, in another embodiment with % Cu between 0.097 at. % and 3.33 at. %, % B is below 2.4 at. % and/or % Si is below 5.77 at. %, in another embodiment with % Cu between 0.097 at. % and 3.33 at. %, % B is above 16.2 at. % and/or % Si is above 27.2 at. %. In another embodiment with % Cu between 0.097 at. % and 3.33 at. %, the total content of % B and % Si is above 31 at. %, in another embodiment with % Cu between 0.097 at. % and 3.33 at. %, the total content of % B and % Si is above 31 at. %. In another embodiment with % Cu between 0.3 at. % and 1.7 at. %, % B is below 4.2 at. % and/or % Si is below 8.77 at. %, in another embodiment with % Cu between 0.3 at. % and 1.7 at. %, % B is above 9.2 at. % and/or % Si is above 17.2 at. %. In another embodiment with % Cu between 0.097 at. % and 3.33 at. %, % B is below 9.77 at. %, in another embodiment with % Cu between 0.097 at. % and 3.33 at. %, % B is above 22.2 at. % even in another embodiment with % Cu between 0.097 at. % and 3.33 at. %, % B is above 32.2 at. %. In another embodiment with % Cu between 0.97 at. % and 3.33 at. %, % B is below 9.77 at. %, in another embodiment with % Cu between 0.97 at. % and 3.33 at. %, % B is above 22.2 at. %. In another embodiment with % B between 0.97 at. % and 33.33 at. %, the total content of % B and/or % Si is below 1.33 at. %, in another embodiment with % B between 0.97 at. % and 33.33 at. %, the total content of % B and/or % Si is above 33.33 at. %.

It has been found that for some applications, certain contents of elements such as Si and B may be detrimental especially for certain Al and Ga contents. For these applications in an embodiment with % Al between 1.87 at. % and 16.6 at. %, % B is lower than 3.87%. In another embodiment with % Al between 1.87 at. % and 16.6 at. %, % B is higher than 23.87%. Even in another embodiment with % Al between 1.87 at. % and 16.6 at. % and/or % Ga between 0.43 at. % and 5.2 at. %, % B is below 1.33 at. % and/or % Si is below 0.43 at. %. In another embodiment with % Al between 1.87 at. % and 16.6 at. % and/or % Ga between 0.43 at. % and 5.2 at. %, % B is above 11.33 at. % and/or % Si is above 5.43 at. %.

There are several elements such as Co that are detrimental in specific applications especially for certain Ni contents; For these applications in an embodiment with % Ni between 24.47% and 35.8%, % Co is lower than 12.6%. Even in another embodiment with % Ni between 24.47% and 35.8%, % Co is higher than 26.6%.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are several elements such as rare earth elements (RE) that are detrimental in specific applications; For these applications in an embodiment RE are absent from the composition.

Any of the above Fe alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an iron alloy for manufacturing metallic or at least partially metallic components.

The present invention is particularly suitable for building components in iron or iron alloys. In particular it is especially suitable for building components with a composition expressed below.

In an embodiment the invention refers to an iron based alloy having the following composition, all percentages being in weight percent:

| | | | |
|---|---|---|---|
| C = 0.0008-3.9 | % N = 0-1.0 | % B = 0-1.0 | % Ti = 0-2 |
| % Cr < 3.0 | % Ni = 0-6 | % Si = 0-1.4 | % Zn: 0-20; |
| % Al = 0-2.5 | % Mo = 0-10 | % W = 0-10 | % Sc: 0-20; |
| % Ta = 0-3 | % Zr = 0-3 | % Hf = 0-3 | % V = 0-4 |
| % Nb = 0-1.5 | % Li: 0-20; | % Co = 0-6, | % Ce = 0-3 |
| % La = 0-3 | % Si: 0-15; | % Cu: 0-20; | % Mn: 0-20; |
| % Mg: 0-20; | | | |

The rest consisting on iron (Fe) and trace elements

There are applications wherein iron based alloys are benefited from having a high iron (% Fe) content but not necessary iron being the majority component of the alloy. In an embodiment % Fe is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Fe is less than 99%, in another embodiment is less than 83%, in another embodiment is less than 69%, in another embodiment is less than 54%, in another embodiment is less than 48%, in another embodiment is less than 41%, in another embodiment is less than 38%, and even in another embodiment is less than 25%. In another embodiment % Fe is not the majority element in the iron based alloy.

In this context trace elements refers to any element of the list: H, He, Xe, Be, O, F, Ne, Na, P, S, Cl, Ar, K, Ca, Sc, Zn, Ga, Ge, As, Se, Br, Kr, Rb, Sr, Y, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Re, Os, Ir, Pt, Au, Hg, Tl, Pb, Bi, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the steel, such as reducing cost production of the steel, and/or its presence may be unintentional and related mostly to the presence of impurities in the alloying elements and scraps used for the production of the steel.

There are several applications wherein the presence of trace elements is detrimental for the overall properties of the iron based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the iron based alloy.

There are other applications wherein the presence of trace elements may reduce the cost of the alloy or attain any other additional beneficial effect without affecting the iron based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

Desirable amounts of the individual elements for different applications may continue in this case the pattern in terms of desirable quantities as described in the preceding paragraphs identical to the case of high mechanical strength iron based alloys or the case of tool steels alloys, in both cases with the exception of the % elements C,% B,% N and % Cr and/or % Ni in the case of corrosion resistant alloys.

It has been found that for some applications, the presence of excess carbon (% C) may be detrimental, for these applications is desirable a % C content in an embodiment of less than 1.8% by weight, preferably less than 0.48%, more preferably less than 0.18% and even 0.08%. In contrast there are applications where the presence of carbon at higher levels is desirable. For these applications amounts exceeding 0.02% by weight are desirable, preferably greater than 0.12% by weight, more preferably greater than 0.42% and even greater than 3.2%.

It has been found that for some applications, the excessive presence of boron (% B) may be detrimental, for these applications is desirable a % B content of less than 0.48% by weight, preferably less than 0.19%, more preferably less than 0.06% by weight and even less than 0.006%. In contrast there are applications wherein the presence of boron in higher amounts is desirable for these applications above 60 ppm amounts by weight are desirable, preferably above 200 ppm, preferably above 0.12%, and even greater than 0.52%.

It has been found that for some applications, the excessive presence of nitrogen (% N) may be detrimental, for these applications is desirable a % N content of less than 0.46%, preferably less than 0.18% by weight preferably less than 0.06% by weight and even less than 0.0006%. In contrast there are applications wherein the presence of nitrogen in higher amounts is desirable. For these applications above 60 ppm amounts by weight are desirable, preferably above 200 ppm, preferably above 0.2%, and even preferably above 0.52%. There are even applications wherein in an embodiment % N is detrimental or not optimal for one reason or another, in these applications it is preferred % N being absent from the alloy.

It has been found that for some applications, excessive presence of nickel (% Ni) may be detrimental, for these applications is desirable a % Ni content of less than 5.8%, preferably less than 2.8%, more preferably less than 1.8%, and even less than 0.008% In contrast there are applications wherein the presence of nickel at higher levels is desirable, for those applications amounts higher than 1.2% by weight, preferably higher than 3.2%, in other embodiment more preferably higher than 4.2% and even higher than 5.2%. There are even applications wherein in an embodiment % Ni is detrimental or not optimal for one reason or another, in these applications it is preferred % Ni being absent from the alloy.

It has been found that for some applications, excessive presence of chromium (% Cr) may be detrimental, for these applications in an embodiment is desirable a % Cr content of less than 2.9%, in other embodiment less than 1.8%, in other embodiment less than 0.8%, in other embodiment less than 0.8%. In contrast there are applications wherein the presence of chromium at higher levels is desirable, especially when a high corrosion resistance and/or resistance to oxidation at high temperatures is required for these applications; for these applications in an embodiment amounts exceeding 1.2% by weight are desirable, in other embodiment amounts exceeding 1.8% by weight in other embodiment amounts exceeding 2.1% by weight and even in another embodiment preferably above 2.8%. There are even applications wherein in an embodiment % Cr is detrimental or not optimal for one reason or another, in these applications it is preferred % Cr being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Sn that are detrimental in specific applications especially for certain Cr and/or C contents; For these applications in an embodiment with % Cr between 0.47% and 5.8% and/or C between 0.7% and 2.74%, % Sn is below 0.087% or even absent from the composition, even in another embodiment with % Cr between 0.47% and 5.8% and/or C between 0.7% and 2.74%, % Sn is above 0.92%. There are even applications wherein in an embodiment % Sn is detrimental or not optimal for one reason or another, in these applications it is preferred % Sn being absent from the alloy.

There are several applications wherein the presence of Si and B in the composition is detrimental for the overall properties of the steel, especially for certain Cu and/or B contents. For these applications in an embodiment with % Cu between 0.097 atomic % (at. %) and 3.33 at. %, the total content of % B and/or % Si is below 4.77 at. %, in another embodiment with % Cu between 0.097 at. % and 3.33 at. %, the total content of % B and/or % Si is below 1.33 at. %, in another embodiment with % Cu between 0.097 at. % and 3.33 at. %, % B is below 2.4 at. % and/or % Si is below 5.77 at. %, in another embodiment with % Cu between 0.097 at. % and 3.33 at. %, % B is above 16.2 at. % and/or % Si is above 27.2 at. %. In another embodiment with % Cu between 0.097 at. % and 3.33 at. %, the total content of % B and % Si is above 31 at. %, in another embodiment with % Cu between 0.097 at. % and 3.33 at. %, the total content of % B and % Si is above 31 at. %. In another embodiment with % Cu between 0.3 at. % and 1.7 at. %, % B is below 4.2 at. % and/or % Si is below 8.77 at. %, in another embodiment with % Cu between 0.3 at. % and 1.7 at. %, % B is above 9.2 at. % and/or % Si is above 17.2 at. %. In another embodiment with % Cu between 0.097 at. % and 3.33 at. %, % B is below 9.77 at. %, in another embodiment with % Cu between 0.097 at. % and 3.33 at. %, % B is above 22.2 at. % even in another embodiment with % Cu between 0.097 at. % and 3.33 at. %, % B is above 32.2 at. %. In another embodiment with % Cu between 0.97 at. % and 3.33 at. %, % B is below 9.77 at. %, in another embodiment with % Cu between 0.97 at. % and 3.33 at. %, % B is above 22.2 at. %. In another embodiment with % B between 0.97 at. % and 33.33 at. %, the total content of % B and/or % Si is below 1.33 at. %, in another embodiment with % B between 0.97 at. % and 33.33 at. %, the total content of % B and/or % Si is above 33.33 at. %.

It has been found that for some applications, certain contents of elements such as Si and B may be detrimental especially for certain Al and Ga contents. For these applications in an embodiment with % Al between 1.87 at. % and 16.6 at. %, % B is lower than 3.87%. In another embodiment with % Al between 1.87 at. % and 16.6 at. %, % B is higher than 23.87%. Even in another embodiment with % Al between 1.87 at. % and 16.6 at. % and/or % Ga between 0.43 at. % and 5.2 at. %, % B is below 1.33 at. % and/or % Si is below 0.43 at. %. In another embodiment with % Al between 1.87 at. % and 16.6 at. % and/or % Ga between 0.43 at. % and 5.2 at. %, % B is above 11.33 at. % and/or % Si is above 5.43 at. %.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are several elements such as Co that are detrimental in specific applications especially for certain Ni contents; For these applications in an embodiment with % Ni between 24.47% and 35.8%, % Co is lower than 12.6%. Even in another embodiment with % Ni between 24.47% and 35.8%, % Co is higher than 26.6%.

There are several elements such as rare earth elements (RE) that are detrimental in specific applications; For these applications in an embodiment RE are absent from the composition.

Any of the above Fe alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of an iron alloy for manufacturing metallic or at least partially metallic components.

The present invention is particularly suitable for the manufacture of components that can benefit from the properties of nickel and its alloys. Especially applications requiring high mechanical resistance at high temperatures y/o aggressive environments. In this sense, applying certain rules of alloy design and thermo-mechanical treatments, it is possible obtain very interesting features for applications in chemical industry, energy transformation, transport, tools, other machines or mechanisms, etc.

In an embodiment the invention refers to a nickel based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-2 | % Mn = 0-3 |
| % Al = 0-15 | % Mo = 0-20 | % W = 0-25 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % La = 0-5 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % Re = 0-50 |

The rest consisting on Nickel (Ni) and trace elements

wherein % Ceq=% C+0.86*% N+1.2*% B

There are applications wherein nickel based alloys are benefited from having a high nickel (% Ni) content but not necessary the nickel being the majority component of the alloy. In an embodiment % Ni is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Ni is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Ni is not the majority element in the nickel based alloy.

In this context trace elements refers to any element of the list: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the alloy, such as reducing cost production of the alloy, and/or its presence may be unintentional and related mostly to the presence of impurities in the alloying elements and scraps used for the production of the alloy.

There are several applications wherein the presence of trace elements is detrimental for the overall properties of the nickel based alloy in an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the nickel based alloy.

There are other applications wherein the presence of trace elements may reduce the cost of the alloy or attain any other additional beneficial effect without affecting the nickel based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 29% or more when incorporating these phases. Once incorporated and when evaluating the overall composition measured as stated in this application, the resulting nickel alloy generally has a 0.2% or more of the element (in this case % Ga), preferably 1.2% or more, more preferably 2.2% or more and even 6% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. It has been found that in some applications the % Ga can be replaced wholly or partially by % Bi with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C., more preferably below 180° C. or even below 46° C. For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications is desirable a % Cr content of less than 39% by weight, preferably less than 18%, more preferably less than 8.8% by weight and even less than 1.8%. By contrast there are applications wherein the presence of chromium at higher levels is desirable, for these applications amounts exceeding 2.2% by weight are desirable, greater than 5.5% by weight, more preferably over 22%, and even greater than 32%. There are even applications wherein in an embodiment % Cr is detrimental or not optimal for one reason or another, in these applications it is preferred % Cr being absent from the alloy.

It has been seen that for some applications the presence of excessive aluminum (% Al) can be detrimental, for these applications is desirable a % Al content of less than 7.8% by weight, preferably preferably less than 4.8%, more preferably less than 1.8% by weight and even less than 0.8%. In contrast there are applications wherein the presence of aluminum at higher levels is desirable, especially when a high hardening and/or environmental resistance are required, for these applications are desirable amounts, greater than 1.2% by weight, preferably greater than 3.2% by weight, more preferably above 8.2% and even above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi, % Cd, % Cs, % Sn, % Pb, % Zn, % Rb or % In with the amounts described in this paragraph, and to the definitions of s and T, the % Ga is replaced by the sum: % Ga+% Bi+% Cd+% Cs+% Sn+% Pb+% Zn+% Rb+% In, where depending on the application may be interesting the absence of any of them (ie although the sum is in line with the values given any of the items may be absent and have a nominal content of 0%, this being advantageous fora given application where the items in question are detrimental or not optimal for one reason or another).

It has been seen that for some applications, the excessive presence of cobalt (% Co) may be detrimental, for these applications is desirable a % Co content of less than 28% by weight, preferably less than 18%, more preferably less than 8.8% by weight, and even less than 1.8%. In contrast there are applications wherein the presence of cobalt in higher amounts is desirable. For these applications are desirable amounts exceeding 2.2% by weight, preferably higher than 12% by weight, more preferably greater than 22% and even greater than 32%. There are even applications wherein in an embodiment % Co is detrimental or not optimal for one reason or another, in these applications it is preferred % Co being absent from the alloy.

It has been seen that for some applications the presence of excessive carbon equivalent (% Ceq) may be detrimental, for these applications is desirable a % Ceq content of less than 1.4% by weight, preferably less than 0.8%, more preferably less than 0.46% by weight and even less than 0.08%. In contrast there are applications wherein the presence of carbon equivalent in higher amounts is desirable for these applications amounts exceeding 0.12% by weight are desirable, preferably greater than 0.52% by weight, more preferably greater than 0.82% and even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 0.38% by weight, preferably less than 0.18%, more preferably less than 0.09% by weight and even less than 0.009%. In contrast there are applications where the presence of carbon at higher levels is desirable. For these applications amounts exceeding 0.02% by weight are desirable, preferably greater than 0.12% by weight, more preferably greater than 0.22% and even greater than 0.32%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 0.9% by weight, preferably less than 0.4%, more preferably less than 0.16% by weight and even than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that there are applications for which the presence of nitrogen (% N) may be detrimental and it is preferable to its absence (may not be economically viable remove beyond the content as an impurity, less than 0.1% by weight, preferably less to 0.008%, more preferably less than 0.0008% and even less than 0.00008%). It has been seen that there are applications for which the presence of boron (% B) may be detrimental and it is preferable its absence (it may not be economically viable remove beyond the content as an impurity, than 0.1% by weight, preferably less to 0.008%, more preferably less than 0.0008% and even less than 0.00008%). There are even applications wherein in an embodiment % N is detrimental or not optimal for one reason or another, in these applications it is preferred % N being absent from the alloy.

It has been found that for some applications, the excessive presence of zirconium (% Zr) and/or hafnium (% Hf) may be detrimental, for these applications is desirable a content of % Zr+% Hf of less than 7.8% by weight, preferably less than 4.8%, more preferably less than 1.8% by weight and even below 0.8%. In contrast there are applications where the presence of some of these elements at higher levels is desirable, especially where a high hardening and/or environmental resistance is required, for these applications amounts of % Zr+% Hf greater than 0.1% by weight are desirable, preferably greater than 1.2% by weight, by weight, more preferably above 6%, or even above 12%. There are even applications wherein in an embodiment % Zr is detrimental or not optimal for one reason or another, in these applications it is preferred % Zr being absent from the alloy. There are even applications wherein in an embodiment % Hf is detrimental or not optimal for one reason or another, in these applications it is preferred % Hf being absent from the alloy.

It has been found that for some applications, the excessive presence of molybdenum (% Mo) and/or tungsten (% W) may be detrimental, for these applications a lower % Mo+½% W content is desirable of less than 14% by weight, preferably less than 9%, more preferably less than 4.8% by weight and even below 1.8%. In contrast there are applications where the presence of molybdenum and tungsten at higher levels is desirable, for these applications amounts of 1.2% Mo+% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been found that for some applications, the excessive presence of Vanadium (% V) may be detrimental, for these applications is desirable % V content less than 4.8% by weight, preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 1.2% by weight, more preferably greater than 2.2% and even above 4.2%. There are even applications wherein in an embodiment % V is detrimental or not optimal for one reason or another, in these applications it is preferred % V being absent from the alloy.

It has been that for some applications, excessive presence of copper (% Cu) may be detrimental, for these applications is desirable % Cu content of less than 14% by weight, more preferably less than 4.5% by weight, and even less than 0.9%. In contrast there are applications where the presence of copper at higher levels is desirable amounts greater than 6% by weight are desirable, preferably greater than 8% by weight, more preferably above 12% and even exceeding 16%. There are even applications wherein in an embodiment % Cu is detrimental or not optimal for one reason or another, in these applications it is preferred % Cu being absent from the alloy.

It has been that for some applications the presence of excessive iron (% Fe) may be detrimental, for these applications is desirable % Fe content of less than 58% by weight, preferably less than 24%, more preferably less than 12% by weight, and even less than 7.5%. In contrast there are applications where the presence of iron at higher levels is desirable, for these applications are desirable amounts greater than 6% by weight, preferably greater than 8% by weight, more preferably greater than 22% and even greater than 42%. There are even applications wherein in an embodiment % Fe is detrimental or not optimal for one reason or another, in these applications it is preferred % Fe being absent from the alloy.

It has been found that for some applications, the excessive presence of titanium (% Ti) may be detrimental, for these applications is desirable % Ti content of less than 9% by weight, preferably less than 4.5%, more preferably less than 2.9% by weight, and even less than 0.9%. In contrast there are applications where the presence of titanium in higher amounts is desirable. For these applications are desirable amounts greater than 1.2% by weight, preferably greater than 3.2% by weight, more preferably above 6% or even above 12%. There are even applications wherein in an embodiment % Ti is detrimental or not optimal for one reason or another, in these applications it is preferred % Ti being absent from the alloy.

It has been found that for some applications, the excessive presence of rhenium (% Re) may be detrimental, for these applications is desirable % Re content less than 41.8% by weight, preferably less than 24.8%, more preferably less than 11.78% by weight and even less than 1.45%. In contrast there are applications wherein the presence of rhenium in higher amounts is desirable for these applications are desirable amounts exceeding 0.6% by weight, preferably greater than 1.2% by weight, more preferably greater than 13.2%, even above 22.2%. There are even applications wherein in an embodiment % Re is detrimental or not optimal for one reason or another, in these applications it is preferred % Re being absent from the alloy.

It has been found that for some applications, the excessive presence of tantalum (% Ta) and/or niobium (% Nb) may be detrimental, for these applications is desirable % Ta+% Nb content less than 7.8% by weight, preferably less than 4.8%, more preferably less than 1.8% by weight, and even less than 0.8%. In contrast there are applications wherein higher amounts of % Ta and/or % Nb are desirable, especially for these applications is desired an amount of % Nb+% Ta greater than 0.1% by weight, preferably greater than 1.2% by weight, preferably greater than 6% and even greater than 12%. There are even applications wherein in an embodiment % Ta is detrimental or not optimal for one reason or another, in these applications it is preferred % Ta being absent from the alloy. There are even applications wherein in an embodiment % Nb is detrimental or not optimal for one reason or another, in these applications it is preferred % Nb being absent from the alloy.

It has been found that for some applications, the excessive presence of yttrium (% Y), cerium (% Ce) and/or lanthanide (% La) may be detrimental, for these applications is desirable % Y+% Ce+% La content less than 7.8% by weight, preferably less than 4.8%, more preferably less than 1.8% by weight, and even less than 0.8%. In contrast there are applications wherein higher amounts are desirable, especially when a high hardness is desired, for these applications is desired an amount of % Y+% Ce+% La greater than 0.1% by weight, preferably greater than 1.2% by weight, more preferably above 6% or even above 12%. There are even applications wherein in an embodiment % Y is detrimental or not optimal for one reason or another, in these applications it is preferred % Y being absent from the alloy. There are even applications wherein in an embodiment % Ce is detrimental or not optimal for one reason or another, in these applications it is preferred % Ce being absent from the alloy. There are even applications wherein in an embodiment % La is detrimental or not optimal for one reason or another, in these applications it is preferred % La being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are some applications wherein the presence of compounds phase in the nickel based alloy is detrimental. In an embodiment the % of compound phase in the alloy is below 79%, in another embodiment is below 49%, in another embodiment is below 19%, in another embodiment is below 9%, in another embodiment is below 0.9% and even in another embodiment compounds are absent from the composition. There are other applications wherein the presence of compounds in the nickel based alloy is beneficial. In another embodiment % of compound phase in the alloy is above 0.0001%, in another embodiment is above 0.3%, in another embodiment is above 3%, in another embodiment is above 13%, in another embodiment is above 43% and even in another embodiment the is above 73%.

For several applications it is especially interesting the use of nickel based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Nickel based alloy is used as a coating layer. In an embodiment the nickel based alloy is used as a coating layer with thickness above 1.1 micrometer, in another embodiment the nickel based alloy is used as a coating layer with thickness above 21 micrometer, in another embodiment the nickel based alloy is used as a coating layer with thickness above 10 micrometre, in another embodiment the nickel based alloy is used as a coating layer with thickness above 510 micrometre, in another embodiment the nickel based alloy is used as a coating layer with thickness above 1.1 mm and even in another embodiment the nickel based alloy is used as a coating layer with thickness above 11 mm. In another embodiment the nickel based alloy is used as a coating layer with thickness below 27 mm, in another embodiment the nickel based alloy is used as a coating layer with thickness below 17 mm, in another embodiment the nickel based alloy is used as a coating layer with thickness below 7.7 mm, in another embodiment the nickel based alloy is used as a coating layer with thickness below 537 micrometer, in another embodiment the nickel based alloy is used as a coating layer with thickness below 117 micrometre, in another embodiment the nickel based alloy is used as a coating layer with thickness below 27 micrometre and even in another embodiment the nickel based alloy is used as a coating layer with thickness below 7.7 micrometre.

For several applications it is especially interesting the use of nickel based alloy having a high mechanical resistance. For those applications in an embodiment the resultant mechanical resistance of the nickel based alloy is above 52 MPa, in another embodiment the resultant mechanical resistance of the alloy is above 72 MPa, in another embodiment the resultant mechanical resistance of the alloy is above 82 MPa, in another embodiment the resultant mechanical resistance of the alloy is above 102 MPa, in another embodiment the resultant mechanical resistance of the alloy is above 112 MPa and even in another embodiment the resultant mechanical resistance of the alloy is above 122 MPa. In another embodiment the resultant mechanical resistance of the alloy is below 147 MPa, in another embodiment the resultant mechanical resistance of the alloy is below 127 MPa, in another embodiment the resultant mechanical resistance of the alloy is below 117 MPa, in another embodiment the resultant mechanical resistance of the alloy is below 107 MPa, in another embodiment the resultant mechanical resistance of the alloy is below 87 MPa, in another embodiment the resultant mechanical resistance of the alloy is below 77 MPa and even in another embodiment the resultant mechanical resistance of the alloy is below 57 MPa.

There are several technologies that are useful to deposit the nickel based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the nickel based alloy being in powder form. In an embodiment the nickel based alloy is manufactured in form of powder. In another embodiment the powder is spherical. In an embodiment refers to a spherical powder with a particle size distribution which may be unimodal, bimodal, trimodal and even multimodal depending of the specific application requirements.

The nickel based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

There are several elements such as Cr, Fe and V that are detrimental in specific applications especially for certain Ga contents; For these applications in an embodiment with % Ga between 5.2% and 13.8%, the total content of Cr and/or V is below 17%, even in another embodiment with % Ga between 5.2% and 13.8%, the total content of Cr and/or V is above 25%. In another embodiment with % Ga between 18 at. % and 34 at. %, % Fe is below 14 at. %. Even in another embodiment with % Ga between 18 at. % and 34 at. %, % Fe is above 47 at. %.

There are several applications wherein the presence of Mo, Fe, Y, Ce, Mn and Re in the composition is detrimental for the overall properties of the nickel based alloy especially for certain Cr and/or Ga contents. In an embodiment with % Cr between 11% and 17% and/or % Ga between 4% and 9%, % Mo is below 4% or even absent from the composition and/or % Fe is below 2.3% or even absent from the composition. Even in another embodiment with % Cr between 11% and 17% and/or % Ga between 4% and 9%, % Mo is above 8.7% and/or % Fe is above 11.6%. In another embodiment with % Cr between 5.2% and 15.7% and/or % Ga between 3.6% and 7.2%, % Y is below 0.1% or even absent from the composition and/or % Ce is below 0.03% or even absent from the composition. In another embodiment with % Cr between 5.2% and 15.7% and/or % Ga between 3.6% and 7.2%, % Y is above 0.74% and/or % Ce is above 0.33%. In another embodiment with % Cr between 9.7% and 23.7% and/or % Ga between 0.6% and 8.2%, % Mn is below 0.36% or even absent from the composition. In another embodiment with % Cr between 9.7% and 23.7% and/or % Ga between 0.6% and 8.2%, % Mn is above 2.6%. In another embodiment with % Cr between 6.2% and 8.7% and/or % Ga between 6.2% and 8.7%, % Mo is below 0.6% or even absent from the composition and/or % Re is below 2.03% or even absent from the composition. In another embodiment with % Cr between 6.2% and 8.7% and/or % Ga between 6.2% and 8.7%, % Mo is above 2.74% and/or % Re is above 4.33%.

It has been found that for some applications, certain contents of elements such as Sc, Al, Ge, Y, W, Si, Pd and rare earth elements (RE) may be detrimental especially for certain Cr contents. For these applications in an embodiment with % Cr between 11.1% and 16.6%, the total content of % Sc and/or % RE is lower than 0.087% or even in another embodiment Sc and RE are absent from the composition. In another embodiment with % Cr between 11.1% and 16.6%, the total content of % Sc and/or % RE is lower than 0.87%. In another embodiment with % Cr between 17.1% and 26.1%, % Al is below 4.3% or even absent from the composition. In another embodiment with % Cr between 17.1% and 26.1%, % Al is above 11.3%. In another embodiment with presence of Cr, Pd is preferred to be absent from the composition. In another embodiment with % Cr between 9 at. % and 51 at. %, the total content of Al and/or Si is below 4 at. %. In another embodiment with % Cr between 9 at. % and 51 at. %, the total content of Al and/or Si is above 26 at. %. In another embodiment with % Cr between 9% and 23%, % Al is below 0.87% or even absent from the composition and/or % Si is below 0.37% or even absent from the composition. In another embodiment with % Cr between 9% and 23%, % Al is above 6.87% and/or % Si is above 3.37%. In another embodiment with % Cr between 6.8% and 22.3%, % Ge is below 0.37% or even absent from the composition. In another embodiment with % Cr between 14.1% and 32.1%, % Y is below 0.3% or even absent from the composition. In another embodiment with % Cr between 14.1% and 32.1%, % Y is above 1.37%. Even in another embodiment with % Cr between 0.087% and 8.1%, % W is below 3.3% or even absent from the composition. In another embodiment with % Cr between 0.087% and 8.1%, % W is above 11.3%.

There are several applications wherein the presence of Ca, In, Y, and rare earth elements (RE) in the composition is detrimental for the overall properties of the nickel based alloy. For these applications in an embodiment % Ca and/or % RE are absent from the composition. In another embodiment, % Y is below 0.0087 at. % or even absent from the composition. In another embodiment % Y is above 0.37 at. %. Even in another embodiment, % In is lower than 0.8% or even In is absent from the composition.

There are several elements such as In, Sn and Sb that are detrimental in specific applications especially for certain Co and Fe contents; For these applications in an embodiment with % Co and/or % Fe between 0.0087 at. % and 17.8 at. %, the total content of In and/or Sn and/or Sb is below 4.1 at. %. Even in another embodiment with % Co and/or % Fe between 0.0087 at. % and 17.8 at. %, the total content of In and/or Sn and/or Sb is above 19.2 at. %.

It has been found that for some applications, certain contents of elements such as Ta and Hf may be detrimental especially for certain Cr and Al contents. For these applications in an embodiment with % Cr between 1.1% and 16.6% and/or % Al between 2.1% and 7.6%, % Ta is below 0.87% or even absent from the composition and/or % Hf is below 0.13% or even absent from the composition. Even in another embodiment with Cr between 1.1% and 16.6% and/or % Al between 2.1% and 7.6%, % Hf is above 4.1%.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

Any of the above-described nickel alloy can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of any nickel alloy for manufacturing metallic or at least partially metallic components.

In an embodiment the invention refers to a molybdenum based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-2 | % Mn = 0-3 |
| % Al = 0-15 | % Ni = 0-50 | % Ti = 0-14 | |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % Re = 0-50 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |

The rest consisting on Molybdenum (Mo) and trace elements

wherein % Ceq=% C+0.86*% N+1.2*% B

There are applications wherein molybdenum based alloys are benefited from having a high molybdenum (% Mo) content but not necessary the molybdenum being the majority component of the alloy. In an embodiment % Mo is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Mo is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Mo is not the majority element in the molybdenum based alloy.

In this context trace elements refers to any element of the list: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the alloy, such as reducing cost production of the alloy, and/or its presence may be unintentional and related mostly to the presence of impurities in the alloying elements and scraps used for the production of the alloy.

There are several applications wherein the presence of trace elements is detrimental for the overall properties of the molybdenum based alloy in an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the molybdenum based alloy.

There are other applications wherein the presence of trace elements may reduce the cost of the alloy or attain any other additional beneficial effect without affecting the molybdenum based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 29% or more when incorporating these phases. Once incorporated and when evaluating the overall composition measured as stated in this application, the resulting molybdenum alloy generally has a 0.2% or more of the element (in this case % Ga), preferably 1.2% or more, more preferably 2.2% or more and even 6% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. It has been found that in some applications the % Ga can be replaced wholly or partially by % Bi with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point.

For some applications it is desirable that the above alloys have a melting point below 890° C., preferably below 640° C., more preferably below 180° C. or even below 46° C. For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications is desirable a % Cr content of less than 39% by weight, preferably less than 18%, more preferably less than 8.8% by weight and even less than 1.8%. By contrast there are applications wherein the presence of chromium at higher levels is desirable, for these applications amounts exceeding 2.2% by weight are desirable, greater than 5.5% by weight, more preferably over 22%, and even greater than 32%. There are even applications wherein in an embodiment % Cr is detrimental or not optimal for one reason or another, in these applications it is preferred % Cr being absent from the alloy.

It has been seen that for some applications the presence of excessive aluminum (% Al) can be detrimental, for these applications is desirable a % Al content of less than 7.8% by weight, preferably preferably less than 4.8%, more preferably less than 1.8% by weight and even less than 0.8%. In contrast there are applications wherein the presence of aluminum at higher levels is desirable, especially when a high hardening and/or environmental resistance are required, for these applications are desirable amounts, greater than 1.2% by weight, preferably greater than 3.2% by weight, more preferably above 8.2% and even above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi, % Cd, % Cs, % Sn, % Pb, % Zn, % Rb or % In with the amounts described in this paragraph, and to the definitions of s and T, the % Ga is replaced by the sum: % Ga+% Bi+% Cd+% Cs+% Sn+% Pb+% Zn+% Rb+% In, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of cobalt (% Co) may be detrimental, for these applications is desirable a % Co content of less than 28% by weight, preferably less than 18%, more preferably less than 8.8% by weight, and even less than 1.8%. In contrast there are applications wherein the presence of cobalt in higher amounts is desirable. For these applications are desirable amounts exceeding 2.2% by weight, preferably higher than 12% by weight, more preferably greater than 22% and even greater than 32%. There are even applications wherein in an embodiment % Co is detrimental or not optimal for one reason or another, in these applications it is preferred % Co being absent from the alloy.

It has been seen that for some applications the presence of excessive carbon equivalent (% Ceq) may be detrimental, for these applications is desirable a % Ceq content of less than 1.4% by weight, preferably less than 0.8%, more preferably less than 0.46% by weight and even less than 0.08%. In contrast there are applications wherein the presence of carbon equivalent in higher amounts is desirable for these applications amounts exceeding 0.12% by weight are desirable, preferably greater than 0.52% by weight, more preferably greater than 0.82% and even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 0.38% by weight, preferably less than 0.18%, more preferably less than 0.09% by weight and even less than 0.009%. In contrast there are applications where the presence of carbon at higher levels is desirable. For these applications amounts exceeding 0.02% by weight are desirable, preferably greater than 0.12% by weight, more preferably greater than 0.22% and even greater than 0.32%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 0.9% by weight, preferably less than 0.4%, more preferably less than 0.16% by weight and even than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that there are applications for which the presence of nitrogen (% N) may be detrimental and it is preferable to its absence (may not be economically viable remove beyond the content as an impurity, less than 0.1% by weight, preferably less to 0.008%, more preferably less than 0.0008% and even less than 0.00008%). It has been seen that there are applications for which the presence of boron (% B) may be detrimental and it is preferable its absence (it may not be economically viable remove beyond the content as an impurity, than 0.1% by weight, preferably less to 0.008%, more preferably less than 0.0008% and even less than 0.00008%). There are even applications wherein in an embodiment % N is detrimental or not optimal for one reason or another, in these applications it is preferred % N being absent from the alloy.

It has been found that for some applications, the excessive presence of zirconium (% Zr) and/or hafnium (% Hf) may be detrimental, for these applications is desirable a content of % Zr+% Hf of less than 7.8% by weight, preferably less than 4.8%, more preferably less than 1.8% by weight and even below 0.8%. In contrast there are applications where the presence of some of these elements at higher levels is desirable, especially where a high hardening and/or environmental resistance is required, for these applications amounts of % Zr+% Hf greater than 0.1% by weight are desirable, preferably greater than 1.2% by weight, by weight, more preferably above 6%, or even above 12%. There are even applications wherein in an embodiment % Zr is detrimental or not optimal for one reason or another, in these applications it is preferred % Zr being absent from the alloy. There are even applications wherein in an embodiment % Hf is detrimental or not optimal for one reason or another, in these applications it is preferred % Hf being absent from the alloy.

It has been found that for some applications, the excessive presence of molybdenum (% Mo) and/or tungsten (% W) may be detrimental, for these applications a lower % Mo+½% W content is desirable of less than 14% by weight, preferably less than 9%, more preferably less than 4.8% by weight and even below 1.8%. In contrast there are applications where the presence of molybdenum and tungsten at higher levels is desirable, for these applications amounts of 1.2% Mo+% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been found that for some applications, the excessive presence of Vanadium (% V) may be detrimental, for these applications is desirable % V content less than 4.8% by weight, preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 1.2% by weight, more preferably greater than 2.2% and even above 4.2%. There are even applications wherein in an embodiment % V is detrimental or not optimal for one reason or another, in these applications it is preferred % V being absent from the alloy.

It has been that for some applications, excessive presence of copper (% Cu) may be detrimental, for these applications is desirable % Cu content of less than 14% by weight, more preferably less than 4.5% by weight, and even less than 0.9%. In contrast there are applications where the presence of copper at higher levels is desirable amounts greater than 6% by weight are desirable, preferably greater than 8% by weight, more preferably above 12% and even exceeding 16%. There are even applications wherein in an embodiment % Cu is detrimental or not optimal for one reason or another, in these applications it is preferred % Cu being absent from the alloy.

It has been that for some applications the presence of excessive iron (% Fe) may be detrimental, for these applications is desirable % Fe content of less than 58% by weight, preferably less than 24%, more preferably less than 12% by weight, and even less than 7.5%. In contrast there are applications where the presence of iron at higher levels is desirable, for these applications are desirable amounts greater than 6% by weight, preferably greater than 8% by weight, more preferably greater than 22% and even greater than 42%. There are even applications wherein in an embodiment % Fe is detrimental or not optimal for one reason or another, in these applications it is preferred % Fe being absent from the alloy.

It has been found that for some applications, the excessive presence of titanium (% Ti) may be detrimental, for these applications is desirable % Ti content of less than 9% by weight, preferably less than 4.5%, more preferably less than 2.9% by weight, and even less than 0.9%. In contrast there are applications where the presence of titanium in higher amounts is desirable. For these applications are desirable amounts greater than 1.2% by weight, preferably greater than 3.2% by weight, more preferably above 6% or even above 12%. There are even applications wherein in an embodiment % Ti is detrimental or not optimal for one reason or another, in these applications it is preferred % Ti being absent from the alloy.

It has been found that for some applications, the excessive presence of rhenium (% Re) may be detrimental, for these applications is desirable % Re content less than 41.8% by weight, preferably less than 24.8%, more preferably less than 11.78% by weight and even less than 1.45%. In contrast there are applications wherein the presence of rhenium in higher amounts is desirable for these applications are desirable amounts exceeding 0.6% by weight, preferably greater than 1.2% by weight, more preferably greater than 13.2%, even above 22.2%. There are even applications wherein in an embodiment % Re is detrimental or not optimal for one reason or another, in these applications it is preferred % Re being absent from the alloy.

It has been found that for some applications, the excessive presence of tantalum (% Ta) and/or niobium (% Nb) may be detrimental, for these applications is desirable % Ta+% Nb content less than 7.8% by weight, preferably less than 4.8%, more preferably less than 1.8% by weight, and even less than 0.8%. In contrast there are applications wherein higher amounts of % Ta and/or % Nb are desirable, especially for these applications is desired an amount of % Nb+% Ta greater than 0.1% by weight, preferably greater than 1.2% by weight, preferably greater than 6% and even greater than 12%. There are even applications wherein in an embodiment % Ta is detrimental or not optimal for one reason or another, in these applications it is preferred % Ta being absent from the alloy. There are even applications wherein in an embodiment % Nb is detrimental or not optimal for one reason or another, in these applications it is preferred % Nb being absent from the alloy.

It has been found that for some applications, the excessive presence of yttrium (% Y), cerium (% Ce) and/or lanthanide (% La) may be detrimental, for these applications is desirable % Y+% Ce+% La content less than 7.8% by weight, preferably less than 4.8%, more preferably less than 1.8% by weight, and even less than 0.8%. In contrast there are applications wherein higher amounts are desirable, especially when a high hardness is desired, for these applications is desired an amount of % Y+% Ce+% La greater than 0.1% by weight, preferably greater than 1.2% by weight, more preferably above 6% or even above 12%. There are even applications wherein in an embodiment % Y is detrimental or not optimal for one reason or another, in these applications it is preferred % Y being absent from the alloy. There are even applications wherein in an embodiment % Ce is detrimental or not optimal for one reason or another, in these applications it is preferred % Ce being absent from the alloy. There are even applications wherein in an embodiment % La is detrimental or not optimal for one reason or another, in these applications it is preferred % La being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are some applications wherein the presence of compounds phase in the molybdenum based alloy is detrimental. In an embodiment the % of compound phase in the alloy is below 79%, in another embodiment is below 49%, in another embodiment is below 19%, in another embodiment is below 9%, in another embodiment is below 0.9% and even in another embodiment compounds are absent from the composition. There are other applications wherein the presence of compounds in the molybdenum based alloy is beneficial. In another embodiment % of compound phase in the alloy is above 0.0001%, in another embodiment is above 0.3%, in another embodiment is above 3%, in another embodiment is above 13%, in another embodiment is above 43% and even in another embodiment the is above 73%.

For several applications it is especially interesting the use of molybdenum based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Molybdenum based alloy is used as a coating layer. In In an embodiment the molybdenum based alloy is used as a coating layer with thickness above 1.1 micrometer, in another embodiment the molybdenum based alloy is used as a coating layer with thickness above 21 micrometer, in another embodiment the molybdenum based alloy is used as a coating layer with thickness above 10 micrometre, in another embodiment the molybdenum based alloy is used as a coating layer with thickness above 510 micrometre, in another embodiment the molybdenum based alloy is used as a coating layer with thickness above 1.1 mm and even in another embodiment the molybdenum based alloy is used as a coating layer with thickness above 11 mm. In another embodiment the molybdenum based alloy is used as a coating layer with thickness below 27 mm, in another embodiment the molybdenum based alloy is used as a coating layer with thickness below 17 mm, in another embodiment the molybdenum based alloy is used as a coating layer with thickness below 7.7 mm, in another embodiment the molybdenum based alloy is used as a coating layer with thickness below 537 micrometer, in another embodiment the molybdenum based alloy is used as a coating layer with thickness below 117 micrometre, in another embodiment the molybdenum based alloy is used as a coating layer with thickness below 27 micrometre and even in another embodiment the molybdenum based alloy is used as a coating layer with thickness below 7.7 micrometre.

For several applications it is especially interesting the use of molybdenum based alloy having a high mechanical resistance. For those applications in an embodiment the resultant mechanical resistance of the molybdenum based alloy is above 52 MPa, in another embodiment the resultant mechanical resistance of the alloy is above 72 MPa, in another embodiment the resultant mechanical resistance of the alloy is above 82 MPa, in another embodiment the resultant mechanical resistance of the alloy is above 102 MPa, in another embodiment the resultant mechanical resistance of the alloy is above 112 MPa and even in another embodiment the resultant mechanical resistance of the alloy is above 122 MPa. In another embodiment the resultant mechanical resistance of the alloy is below 147 MPa, in another embodiment the resultant mechanical resistance of the alloy is below 127 MPa, in another embodiment the resultant mechanical resistance of the alloy is below 117 MPa, in another embodiment the resultant mechanical resistance of the alloy is below 107 MPa, in another embodiment the resultant mechanical resistance of the alloy is below 87 MPa, in another embodiment the resultant mechanical resistance of the alloy is below 77 MPa and even in another embodiment the resultant mechanical resistance of the alloy is below 57 MPa.

There are several technologies that are useful to deposit the molybdenum based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the molybdenum based alloy being in powder form. In an embodiment the molybdenum based alloy is manufactured in form of powder. In another embodiment the powder is spherical. In an embodiment refers to a spherical powder with a particle size distribution which may be unimodal, bimodal, trimodal and even multimodal depending of the specific application requirements.

The present invention is particularly suitable for the manufacture of components that can benefit from the properties of molybdenum and its alloys. Especially applications requiring high mechanical resistance at high temperatures. In this sense, applying certain rules of alloy design and thermo-mechanical treatments, it is possible obtain very interesting features for applications in chemical industry, energy transformation, transport, tools, other machines or mechanisms, etc.

The molybdenum based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

Any of the above Mo based alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of molybdenum based alloy for manufacturing metallic or at least partially metallic components.

In an embodiment the invention refers to a tungsten based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-2 | % Mn = 0-3 |
| % Al = 0-15 | % Ni = 0-50 | % Ti = 0-14 | |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % Re = 0-50 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |
| % K = 0-600 ppm | | | |

The rest consisting on Tungsten (N) and trace elements

wherein % Ceq=% C+0.86*% N+1.2*% B

There are applications wherein tungsten based alloys are benefited from having a high tungsten (% W) content but not necessary the tungsten being the majority component of the alloy. In an embodiment % Mo is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % W is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % W is not the majority element in the tungsten based alloy.

In this context trace elements refers to any element of the list: H, He, Xe, Be, O, F, Ne, Na, Mg, Cl, Ar, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the alloy, such as reducing cost production of the alloy, and/or its presence may be unintentional and related mostly to the presence of impurities in the alloying elements and scraps used for the production of the alloy.

There are several applications wherein the presence of trace elements is detrimental for the overall properties of the tungsten based alloy in an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the tungsten based alloy

There are other applications wherein the presence of trace elements may reduce the cost of the alloy or attain any other additional beneficial effect without affecting the tungsten based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 29% or more when incorporating these phases. Once incorporated and when evaluating the overall composition measured as stated in this application, the resulting tungsten alloy generally has a 0.2% or more of the element (in this case % Ga), preferably 1.2% or more, more preferably 2.2% or more and even 6% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. It has been found that in some applications the % Ga can be replaced wholly or partially by % Bi with the amounts described in this paragraph for % Ga+% Bi. In some applications it is advantageous total replacement ie the absence of % Ga. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C., more preferably below 180° C. or even below 46° C. For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications is desirable a % Cr content of less than 39% by weight, preferably less than 18%, more preferably less than 8.8% by weight and even less than 1.8%. By contrast there are applications wherein the presence of chromium at higher levels is desirable, for these applications amounts exceeding 2.2% by weight are desirable, greater than 5.5% by weight, more preferably over 22%, and even greater than 32%. There are even applications wherein in an embodiment % Cr is detrimental or not optimal for one reason or another, in these applications it is preferred % Cr being absent from the alloy.

It has been seen that for some applications the presence of excessive aluminum (% Al) can be detrimental, for these applications is desirable a % Al content of less than 7.8% by weight, preferably preferably less than 4.8%, more preferably less than 1.8% by weight and even less than 0.8%. In contrast there are applications wherein the presence of aluminum at higher levels is desirable, especially when a high hardening and/or environmental resistance are required, for these applications are desirable amounts, greater than 1.2% by weight, preferably greater than 3.2% by weight, more preferably above 8.2% and even above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi, % Cd, % Cs, % Sn, % Pb, % Zn, % Rb or % In with the amounts described in this paragraph, and to the definitions of s and T, the % Ga is replaced by the sum: % Ga+% Bi+% Cd+% Cs+% Sn+% Pb+% Zn+% Rb+% In, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of cobalt (% Co) may be detrimental, for these applications is desirable a % Co content of less than 28% by weight, preferably less than 18%, more preferably less than 8.8% by weight, and even less than 1.8%. In contrast there are applications wherein the presence of cobalt in higher amounts is desirable. For these applications are desirable amounts exceeding 2.2% by weight, preferably higher than 12% by weight, more preferably greater than 22% and even greater than 32%. There are even applications wherein in an embodiment % Co is detrimental or not optimal for one reason or another, in these applications it is preferred % Co being absent from the alloy.

It has been seen that for some applications the presence of excessive carbon equivalent (% Ceq) may be detrimental, for these applications is desirable a % Ceq content of less than 1.4% by weight, preferably less than 0.8%, more preferably less than 0.46% by weight and even less than 0.08%. In contrast there are applications wherein the presence of carbon equivalent in higher amounts is desirable for these applications amounts exceeding 0.12% by weight are desirable, preferably greater than 0.52% by weight, more preferably greater than 0.82% and even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 0.38% by weight, preferably less than 0.18%, more preferably less than 0.09% by weight and even less than 0.009%. In contrast there are applications where the presence of carbon at higher levels is desirable. For these applications amounts exceeding 0.02% by weight are desirable, preferably greater than 0.12% by weight, more preferably greater than 0.22% and even greater than 0.32%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 0.9% by weight, preferably less than 0.4%, more preferably less than 0.16% by weight and even than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that there are applications for which the presence of nitrogen (% N) may be detrimental and it is preferable to its absence (may not be economically viable remove beyond the content as an impurity, less than 0.1% by weight, preferably less to 0.008%, more preferably less than 0.0008% and even less than 0.00008%). It has been seen that there are applications for which the presence of boron (% B) may be detrimental and it is preferable its absence (it may not be economically viable remove beyond the content as an impurity, than 0.1% by weight, preferably less to 0.008%, more preferably less than 0.0008% and even less than 0.00008%). There are even applications wherein in an embodiment % N is detrimental or not optimal for one reason or another, in these applications it is preferred % N being absent from the alloy.

It has been found that for some applications, the excessive presence of zirconium (% Zr) and/or hafnium (% Hf) may be detrimental, for these applications is desirable a content of % Zr+% Hf of less than 7.8% by weight, preferably less than 4.8%, more preferably less than 1.8% by weight and even below 0.8%. In contrast there are applications where the presence of some of these elements at higher levels is desirable, especially where a high hardening and/or environmental resistance is required, for these applications amounts of % Zr+% Hf greater than 0.1% by weight are desirable, preferably greater than 1.2% by weight, by weight, more preferably above 6%, or even above 12%. There are even applications wherein in an embodiment % Zr is detrimental or not optimal for one reason or another, in these applications it is preferred % Zr being absent from the alloy. There are even applications wherein in an embodiment % Hf is detrimental or not optimal for one reason or another, in these applications it is preferred % Hf being absent from the alloy.

It has been found that for some applications, the excessive presence of molybdenum (% Mo) and/or tungsten (% W) may be detrimental, for these applications a lower % Mo+½% W content is desirable of less than 14% by weight, preferably less than 9%, more preferably less than 4.8% by weight and even below 1.8%. In contrast there are applications where the presence of molybdenum and tungsten at higher levels is desirable, for these applications amounts of 1.2% Mo+% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been found that for some applications, the excessive presence of Vanadium (% V) may be detrimental, for these applications is desirable % V content less than 4.8% by weight, preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 1.2% by weight, more preferably greater than 2.2% and even above 4.2%. There are even applications wherein in an embodiment % V is detrimental or not optimal for one reason or another, in these applications it is preferred % V being absent from the alloy.

It has been that for some applications, excessive presence of copper (% Cu) may be detrimental, for these applications is desirable % Cu content of less than 14% by weight, more preferably less than 4.5% by weight, and even less than 0.9%. In contrast there are applications where the presence of copper at higher levels is desirable amounts greater than 6% by weight are desirable, preferably greater than 8% by weight, more preferably above 12% and even exceeding 16%. There are even applications wherein in an embodiment % Cu is detrimental or not optimal for one reason or another, in these applications it is preferred % Cu being absent from the alloy.

It has been that for some applications the presence of excessive iron (% Fe) may be detrimental, for these applications is desirable % Fe content of less than 58% by weight, preferably less than 24%, more preferably less than 12% by weight, and even less than 7.5%. In contrast there are applications where the presence of iron at higher levels is desirable, for these applications are desirable amounts greater than 6% by weight, preferably greater than 8% by weight, more preferably greater than 22% and even greater than 42%. There are even applications wherein in an embodiment % Fe is detrimental or not optimal for one reason or another, in these applications it is preferred % Fe being absent from the alloy.

It has been found that for some applications, the excessive presence of titanium (% Ti) may be detrimental, for these applications is desirable % Ti content of less than 9% by weight, preferably less than 4.5%, more preferably less than 2.9% by weight, and even less than 0.9%. In contrast there are applications where the presence of titanium in higher amounts is desirable. For these applications are desirable amounts greater than 1.2% by weight, preferably greater than 3.2% by weight, more preferably above 6% or even above 12%. There are even applications wherein in an embodiment % Ti is detrimental or not optimal for one reason or another, in these applications it is preferred % Ti being absent from the alloy.

It has been found that for some applications, the excessive presence of rhenium (% Re) may be detrimental, for these applications is desirable % Re content less than 41.8% by weight, preferably less than 24.8%, more preferably less than 11.78% by weight and even less than 1.45%. In contrast there are applications wherein the presence of rhenium in higher amounts is desirable for these applications are desirable amounts exceeding 0.6% by weight, preferably greater than 1.2% by weight, more preferably greater than 13.2%, even above 22.2%. There are even applications wherein in an embodiment % Re is detrimental or not optimal for one reason or another, in these applications it is preferred % Re being absent from the alloy.

It has been seen that for some applications, the excessive presence of potassium (% K) may be detrimental, for these applications is desirable a % K content of less than 528 ppm by weight, preferably less than 287 ppm, more preferably less than 108 ppm by weight, even less than 48.8 ppm and even less than 12.8 ppm. In contrast there are applications wherein the presence of potassium in higher amounts is desirable. For these applications are desirable amounts exceeding 2.2 ppm by weight, preferably higher than 8.8 ppm by weight, more preferably greater than 58 ppm, even greater than 108 ppm and even greater than 578 ppm. There are even applications wherein in an embodiment % K is detrimental or not optimal for one reason or another, in these applications it is preferred % K being absent from the alloy.

It has been found that for some applications, the excessive presence of tantalum (% Ta) and/or niobium (% Nb) may be detrimental, for these applications is desirable % Ta+% Nb content less than 7.8% by weight, preferably less than 4.8%, more preferably less than 1.8% by weight, and even less than 0.8%. In contrast there are applications wherein higher amounts of % Ta and/or % Nb are desirable, especially for these applications is desired an amount of % Nb+% Ta greater than 0.1% by weight, preferably greater than 1.2% by weight, preferably greater than 6% and even greater than 12%. There are even applications wherein in an embodiment % Ta is detrimental or not optimal for one reason or another, in these applications it is preferred % Ta being absent from the alloy. There are even applications wherein in an embodiment % Nb is detrimental or not optimal for one reason or another, in these applications it is preferred % Nb being absent from the alloy.

It has been found that for some applications, the excessive presence of yttrium (% Y), cerium (% Ce) and/or lanthanide (% La) may be detrimental, for these applications is desirable % Y+% Ce+% La content less than 7.8% by weight, preferably less than 4.8%, more preferably less than 1.8% by weight, and even less than 0.8%. In contrast there are applications wherein higher amounts are desirable, especially when a high hardness is desired, for these applications is desired an amount of % Y+% Ce+% La greater than 0.1% by weight, preferably greater than 1.2% by weight, more preferably above 6% or even above 12%. There are even applications wherein in an embodiment % Y is detrimental or not optimal for one reason or another, in these applications it is preferred % Y being absent from the alloy. There are even applications wherein in an embodiment % Ce is detrimental or not optimal for one reason or another, in these applications it is preferred % Ce being absent from the alloy. There are even applications wherein in an embodiment % La is detrimental or not optimal for one reason or another, in these applications it is preferred % La being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

For several applications it may be especially interesting the absence of carbides in the tungsten based alloy, there may be applications wherein it is particularly interesting the absence of tungsten carbides (WC) in the tungsten based alloy. In an embodiment tungsten % WC in the Tungsten based alloy is below 79%, in another embodiment is below 49%, in another embodiment is below 19%, in another embodiment is below 9% and even in another embodiment is below 0.9%. In another applications it may be especially interesting the presence of carbides in the alloy, there may be applications wherein it is particularly interesting the presence of tungsten carbides (% WC) in the tungsten based alloy. In an embodiment % WC in the Tungsten based alloy is above 0.0001%, in another embodiment is above 0.3%, in another embodiment is above 3%, in another embodiment is above 13%, in another embodiment is above 43% and even in another embodiment is above 73%.

There are some applications wherein the presence of compounds phase in the tungsten based alloy is detrimental. In an embodiment the % of compound phase in the composition is below 79%, in another embodiment is below 49%, in another embodiment is below 19%, in another embodiment is below 9%, in another embodiment is below 0.9% and even in another embodiment the compound phase is absent from the Tungsten based alloy. There are other applications wherein the presence of compounds in the tungsten based alloy is beneficial. In another embodiment the % of compound phase in the Tungsten based alloy is above 0.0001%, in another embodiment is above 0.3%, in another embodiment is above 3%, in another embodiment is above 13%, in another is above 43% and even in another embodiment is above 73%

For several applications it is especially interesting the use of tungsten based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Tungsten based alloy is used as a coating layer. In another embodiment the Tungsten based alloy is used as a coating layer with a thickness above 1.1 micrometres, in another embodiment the coating layer has a thickness above 21 micrometres, in another embodiment above 105 micrometres, in another embodiment above 510 micrometres, in another embodiment above 1.1 mm and even in another embodiment above 11 mm. For other applications a thinker layer is desired. In an embodiment the Tungsten based alloy is used as a coating layer with thickness below 17 mm, in another embodiment below 7.7 mm, in another embodiment below 537 micrometres, in another embodiment below 117 micrometres, in another embodiment below 27 micrometres and even in another embodiment below 7.7 micrometres.

There are several technologies that are useful to deposit the tungsten based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the tungsten based alloy being in powder form. In an embodiment the tungsten based alloy is manufactured in form of powder. In another embodiment the powder is spherical. In an embodiment refers to a spherical powder with a particle size distribution which may be unimodal, bimodal, trimodal and even multimodal depending of the specific application requirements.

The present invention is particularly suitable for the manufacture of components that can benefit from the properties of tungsten and its alloys. Especially applications requiring high strength at elevated temperature, high elastic modulus and/or high densities (and resulting properties such as the ability to minimize vibration, . . . ). In this sense, applying certain rules of alloy design and thermo-mechanical treatments, it is possible obtain very interesting features for applications in chemical industry, energy transformation, transport, tools, other machines or mechanisms, etc.

The tungsten based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

Any of the above tungsten based alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of tungsten based alloy for manufacturing metallic or at least partially metallic components.

The present invention is particularly suitable for the manufacture of components that can benefit from the properties of titanium and its alloys. Especially applications requiring high mechanical resistance at high temperatures y/o aggressive environments. In this sense, applying certain rules of alloy design and thermo-mechanical treatments, it is possible obtain very interesting features for applications in chemical industry, energy transformation, transport, tools, other machines or mechanisms, etc.

In an embodiment the invention refers to a titanium based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-5 | % Mn = 0-3 |
| % Al = 0-40 | % Mo = 0-20 | % W = 0-25 | % Ni = 0-40 |
| % Ta = 0-5 | % Zr = 0-8 | % Hf = 0-6, | % V = 0-15 |
| % Nb = 0-60 | % Cu = 0-20 | % Fe = 0-40 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % Pt = 0-5 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |
| % Pd = 0-5 | % Re = 0-5 | % Ru = 0-5 | |

The rest consisting on titanium (Ti) and trace elements

wherein % Ceq=% C+0.86*% N+1.2*% B

There are applications wherein titanium based alloys are benefited from having a high titanium (% Ti) content but not necessary the titanium being the majority component of the alloy. In an embodiment % Ti is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Ti is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Ti is not the majority element in the titanium based alloy.

In this context trace elements refers to any element of the list: H, He, Xe, Be, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Re, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the alloy such as reducing cost production of the alloy and/or its presence may be unintentional and related mostly to the presence of impurities in the alloying elements and scraps used for the production of the alloy

There are several applications wherein the presence of trace elements is detrimental for the overall properties of the titanium based alloy in an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the titanium based alloy

There are other applications wherein the presence of trace elements may reduce the cost of the alloy or attain any other additional beneficial effect without affecting the titanium based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 29% or more when incorporating these phases. Once incorporated and when evaluating the overall composition measured as stated in this application, the resulting titanium alloy generally has a 0.2% or more of the element (in this case % Ga), preferably 1.2% or more, more preferably 2.2% or more and even 6% or more even 12% or more. For certain applications it is especially interesting the use of particles with Ga only for tetrahedral interstices and not necessary for all interstices, for these applications is desirable a % Ga of more than 0.04% by weight, preferably more than 0.12%, more preferably more than 0.24% by weight and even more than 0.32%. It has been found that in some applications the % Ga can be replaced wholly or partially by Bi % with the amounts described in this paragraph for % Ga+% Bi. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C. the, more preferably below 180° C. or even below 46° C. For some applications it is more interesting alloy with these elements directly and not incorporate in separate particles. For some applications it is even interesting the use of particles mainly formed with these elements with a desirable content of % Ga+% Bi+% Cd+% Cs+% Sn+% Pb+Zn %+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without Sn % or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications is desirable a % Cr content of less than 39% by weight, preferably less than 18%, preferably less than 8.8% by weight and even less than 1.8%. By contrast there are applications wherein the presence of chromium at higher levels is desirable, for these applications amounts exceeding 2.2% by weight are desirable, preferably greater than 5.5% by weight, more preferably over 22%, and even greater than 32%. There are even applications wherein in an embodiment % Cr is detrimental or not optimal for one reason or another, in these applications it is preferred % Cr being absent from the alloy.

It has been seen that for some applications the presence of excessive aluminum (% Al) can be detrimental, for these applications is desirable % Al content lower than 28% by weight, preferably less than 18%, more preferably less than 8.8% by weight, and even less than 0.8%. In contrast there are applications wherein the presence of aluminum at higher levels is desirable, especially when a high hardening and/or environmental resistance are required, for these applications are desirable amounts greater than 1.2% by weight, preferably greater than 3.2% by weight, more preferably greater than 12% and even over 22%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% in, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of Cobalt (% Co) may be detrimental, for these applications is desirable a % Co content of less than 28% by weight, preferably less than 18%, more preferably less than 8.8% by weight, and even less than 1.8%. In contrast there are applications wherein the presence of cobalt in higher amounts is desirable. For these applications are desirable amounts exceeding 2.2% by weight, preferably higher than 5.9%, preferably higher than 12% by weight, more preferably greater than 22% and even greater than 32%. There are even applications wherein in an embodiment % Co is detrimental or not optimal for one reason or another, in these applications it is preferred % Co being absent from the alloy.

It has been seen that for some applications the presence of excessive carbon equivalent (% Ceq) may be detrimental, for these applications is desirable a % Ceq content by weight, less than 0.8%, preferably less than 0.46% by weight more preferably less than 0.18% by weight and even less than 0.08%. In contrast there are applications wherein the presence of carbon equivalent in higher amounts is desirable for these applications amounts exceeding 0.12% by weight are desirable, preferably greater than 0.22% more preferably greater than 0.52% by weight, even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 0.38% by weight, preferably less than 0.18%, more preferably less than 0.09% by weight and even less than 0.009%. In contrast there are applications where the presence of carbon at higher levels is desirable. For these applications amounts exceeding 0.02% by weight are desirable, preferably greater than 0.12% by weight, more preferably greater than 0.22% and even greater than 0.32%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 0.9% by weight, preferably less than 0.4%, more preferably less than 0.018% by weight and even less than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that there are applications for which the presence of nitrogen (% N) may be detrimental and it is preferable to its absence (may not be economically viable remove beyond the content as an impurity, less than 0.1% by weight, preferably less to 0.008%, more preferably less than 0.0008% and even less than 0.00008%). It has been seen that there are applications for which the presence of boron (% B) may be detrimental and it is preferable its absence (it may not be economically viable remove beyond the content as an impurity, less than 0.1% by weight, preferably less to 0.008%, more preferably less than 0.0008% and even less than 0.00008%). There are even applications wherein in an embodiment % N is detrimental or not optimal for one reason or another, in these applications it is preferred % N being absent from the alloy.

It has been found that for some applications, the excessive presence of zirconium (% Zr) and/or hafnium (% Hf) may be detrimental, for these applications is desirable a content of % Zr+% Hf of less than 7.8% by weight, preferably less than 4.8%, more preferably less than 1.8% by weight and even below 0.8%. In contrast there are applications where the presence of some of these elements at higher levels is desirable, especially where a high hardening and/or environmental resistance is required, for these applications amounts of % Zr+% Hf greater than 0.1% by weight are desirable, preferably greater than 1.2% by weight, by weight, more preferably above 6%, or even above 12%. For some applications if oxygen content is higher of 500 ppm, it has been seen that often is desired having % Zr+% Hf below 3.8% by weight, preferably less than 2.8%, more preferably below 1.4% and even below 0.08%. There are even applications wherein in an embodiment % Zr is detrimental or not optimal for one reason or another, in these applications it is preferred % Zr being absent from the alloy. There are even applications wherein in an embodiment % Hf is detrimental or not optimal for one reason or another, in these applications it is preferred % Hf being absent from the alloy.

It has been found that for some applications, the excessive presence of molybdenum (% Mo) and/or tungsten (% W) may be detrimental, for these applications a lower % Mo+½% W content is desirable of less than 14% by weight, preferably less than 9%, more preferably less than 4.8% by weight and even below 1.8%. In contrast there are applications where the presence of molybdenum and tungsten at higher levels is desirable, for these applications amounts of 1.2% Mo+% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been found that for some applications, the excessive presence of Vanadium (% V) may be detrimental, for these applications is desirable % V content less than 4.8% by weight, preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 1.2% by weight, more preferably greater than 4.2%, and even above 6.2%. There are even applications wherein in an embodiment % V is detrimental or not optimal for one reason or another, in these applications it is preferred % V being absent from the alloy.

It has been that for some applications, excessive presence of copper (% Cu) may be detrimental, for these applications is desirable % Cu content of less than 14% by weight, preferably less than 9%, more preferably less than 4.5% by weight, and even less than 0.9%. In contrast there are applications where the presence of copper at higher levels is desirable, amounts greater than 6% by weight are desirable, preferably greater than 8% by weight, more preferably above 12% and even exceeding 16%. There are even applications wherein in an embodiment % Cu is detrimental or not optimal for one reason or another, in these applications it is preferred % Cu being absent from the alloy.

It has been that for some applications the presence of excessive iron (% Fe) may be detrimental, for these applications is desirable % Fe content of less than 38% by weight, preferably less than 24%, more preferably less than 12% by weight, and even less than 7.5%. In contrast there are applications where the presence of iron at higher levels is desirable, for these applications are desirable amounts greater than 6% by weight, preferably greater than 8% by weight, more preferably greater than 22% and even greater than 32%. There are even applications wherein in an embodiment % Fe is detrimental or not optimal for one reason or another, in these applications it is preferred % Fe being absent from the alloy.

It has been that for some applications the presence of excessive nickel (% Ni) may be detrimental, for these applications is desirable % Ni content of less than 19% by weight, preferably less than 9%, more preferably less than 2.9% by weight, and even less than 0.9% In contrast there are applications where the presence of nickel at higher levels is desirable, for these applications are desirable amounts greater than 1.2% by weight, preferably greater than 3.2% by weight, more preferably greater than 6% by weight, and even greater than 22%. There are even applications wherein in an embodiment % Ni is detrimental or not optimal for one reason or another, in these applications it is preferred % Ni being absent from the alloy.

It has been found that for some applications, the excessive presence of tantalum (% Ta) may be detrimental, for these applications is desirable % Ta content of less than 3.8%, preferably less than 1.8% by weight, more preferably less than 0.8% by weight, and even than 0.08%. In contrast there are applications wherein higher amounts of % Ta are desirable, for these applications is desired an amount of % Ta greater than 0.01% by weight, preferably greater than 0.2% by weight, preferably greater than 1.2%, and even greater than 3.2%. There are even applications wherein in an embodiment % Ta is detrimental or not optimal for one reason or another, in these applications it is preferred % Ta being absent from the alloy.

It has been found that for some applications, the excessive presence of niobium (% Nb) may be detrimental, for these applications is desirable Nb content in an embodiment of less than 48%, preferably less than 28% by weight, more preferably less than 4.8%, more preferably less than 1.8% by weight, and even less than 0.8%. In contrast there are applications wherein higher amounts of % Nb are desirable. For these applications is desired an amount of % Nb greater than 0.1% by weight, preferably greater than 1.2% by weight, more preferably greater than 12% and even greater than 52%. There are even applications wherein in an embodiment % Nb is detrimental or not optimal for one reason or another, in these applications it is preferred % Nb being absent from the alloy.

It has been found that for some applications, the excessive presence of yttrium (% Y), cerium (% Ce) and/or lanthanide (% La) may be detrimental, for these applications is desirable % Y+% Ce+% La content less than 7.8% by weight, preferably less than 4.8%, more preferably less than 1.8% by weight, and even less than 0.8%. In contrast there are applications wherein higher amounts are desirable, especially when a high hardness is desired, for these applications is desired an amount of % Y+% Ce+% La greater than 0.1% by weight, preferably greater than 1.2% by weight, more preferably above 6% or even above 12%. There are even applications wherein in an embodiment % Y is detrimental or not optimal for one reason or another, in these applications it is preferred % Y being absent from the alloy. There are even applications wherein in an embodiment % Ce is detrimental or not optimal for one reason or another, in these applications it is preferred % Ce being absent from the alloy. There are even applications wherein in an embodiment % La is detrimental or not optimal for one reason or another, in these applications it is preferred % La being absent from the alloy.

It has been seen that for some applications the presence of excessive silicon (% Si) can be detrimental, for these applications is desirable % Si content less than 0.8% by weight, preferably less than 0.46%, more preferably less than 0.18% by weight and even less than 0.08%. By contrast there are applications where the presence of silicon in higher amounts is desirable for these applications amounts greater than 0.12% by weight are desirable, preferably greater than 0.52% by weight, more preferably greater than 1.2% and even above 2.2%. There are even applications wherein in an embodiment % Si is detrimental or not optimal for one reason or another, in these applications it is preferred % Si being absent from the alloy.

It has been found that for some applications the presence of excessive tin (% Sn) can be detrimental, for these applications is desirable % Sn content less than 4.8 wt % preferably less than 1.8%, more preferably less than 0.78% by weight and even less than 0.45%. By contrast there are applications where the presence of tin in higher amounts is desirable for these applications amounts greater than 0.6% by weight are desirable, preferably greater than 1.2% by weight, more preferably greater than 3.2% and even above 6.2%. There are even applications wherein in an embodiment % Sn is detrimental or not optimal for one reason or another, in these applications it is preferred % Sn being absent from the alloy.

It has been found that for some applications, excessive presence of palladium (% Pd) can be detrimental, for these applications is desirable % Pd content less than 0.9% by weight, preferably less than 0.4%, more preferably less than 0.018% by weight and even less than 0.006%. By contrast there are applications where the presence of palladium in higher amounts is desirable for these applications above 60 ppm amounts by weight are desirable, preferably above 200 ppm, more preferably greater than 0.52% and even above 1.2%. There are even applications wherein in an embodiment % Pd is detrimental or not optimal for one reason or another, in these applications it is preferred % Pd being absent from the alloy.

It has been found that for some applications, the excessive presence of rhenium (% Re) can be detrimental, for these applications is desirable % Re content less than 0.9 wt %, preferably less than 0.4%, more preferably less than 0.018% by weight and even less than 0.006%. By contrast there are applications where the presence of rhenium in higher amounts is desirable for these applications above 60 ppm amounts by weight are desirable, preferably above 200 ppm, more preferably greater than 0.52% and even above 1.2%. There are even applications wherein in an embodiment % Re is detrimental or not optimal for one reason or another, in these applications it is preferred % Re being absent from the alloy.

It has been found that for some applications, the excessive presence of ruthenium (% Ru) can be detrimental, for these applications is desirable % Ru content of less than 0.9 wt %, preferably less than 0.4%, more preferably less than 0.018% by weight and even less than 0.006%. By contrast there are applications where the presence of ruthenium in higher amounts is desirable for these applications above 60 ppm amounts by weight are desirable, preferably above 200 ppm, more preferably greater than 0.52% and even above 1.2%. There are even applications wherein in an embodiment % Ru is detrimental or not optimal for one reason or another, in these applications it is preferred % Ru being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Mo and B that are detrimental in specific applications especially for certain Al contents; For these applications in an embodiment with % Al between 1.7% and 6.7%, % Mo is below 6.8%, or even Mo is absent from the composition. In another embodiment with % Al between 41.7% and 6.7%, % Mo is above 13.2%. In another embodiment with % Al between 2.3% and 7.7%, % B is below 0.01%, or even B is absent from the composition. Even in another embodiment with % Al between 2.3% and 7.7%, % B is above 3.11%.

There are several elements such as P, C, N and B that are detrimental in specific applications; For these applications in an embodiment with, P, C, N and B are absent from the composition.

There are several elements such as Pd, Ag, Au, Cu, Hg and Pt that are detrimental in specific applications; For these applications in an embodiment Pd, Ag, Au, Cu, Hg and Pt are absent from the composition.

It has been found that for some applications, certain contents of elements such as rare earth elements (RE), including La and Y, may be detrimental especially for certain Ti contents. For these applications in an embodiment with % Ti between 32.5% and 62.5%, % RE, including La and Y, is lower than 0.087% or even RE including, La and Y, are absent from the composition. In another embodiment with % Ti between 32.5% and 62.5. % RE, including La and Y, is higher than 17. Even in another embodiment with any Ti content, % RE is lower than 1.3% or even RE are absent from the composition. In another embodiment with any Ti content, % RE is higher than 16.3%.

There are some applications wherein the presence of compounds phase in the titanium based alloy is detrimental. In an embodiment the % of compound phase in the alloy is below 79%, in another embodiment is below 49%, in another embodiment is below 19%, in another embodiment is below 9%, in another embodiment is below 0.9% and even in another embodiment compounds are absent from the composition. There are other applications wherein the presence of compounds in the titanium based alloy is beneficial. In another embodiment % of compound phase in the alloy is above 0.0001%, in another embodiment is above 0.3%, in another embodiment is above 3%, in another embodiment is above 13%, in another embodiment is above 43% and even in another embodiment the is above 73%.

For several applications it is especially interesting the use of titanium based alloys for coating materials, such as for example alloys and/or other ceramic, concrete, plastic, etc components to provide with a particular functionality the covered material such as for example, but not limited to cathodic and/or corrosion protection. For several applications it is desired having a coating layer with a thickness in the micrometre or mm range. In an embodiment the Titanium based alloy is used as a coating layer. In In an embodiment the titanium based alloy is used as a coating layer with thickness above 1.1 micrometer, in another embodiment the titanium based alloy is used as a coating layer with thickness above 21 micrometer, in another embodiment the titanium based alloy is used as a coating layer with thickness above 10 micrometre, in another embodiment the titanium based alloy is used as a coating layer with thickness above 510 micrometre, in another embodiment the titanium based alloy is used as a coating layer with thickness above 1.1 mm and even in another embodiment the titanium based alloy is used as a coating layer with thickness above 11 mm. In another embodiment the titanium based alloy is used as a coating layer with thickness below 27 mm, in another embodiment the titanium based alloy is used as a coating layer with thickness below 17 mm, in another embodiment the titanium based alloy is used as a coating layer with thickness below 7.7 mm, in another embodiment the titanium based alloy is used as a coating layer with thickness below 537 micrometer, in another embodiment the titanium based alloy is used as a coating layer with thickness below 117 micrometre, in another embodiment the titanium based alloy is used as a coating layer with thickness below 27 micrometre and even in another embodiment the titanium based alloy is used as a coating layer with thickness below 7.7 micrometre.

For several applications it is especially interesting the use of titanium based alloy having a high mechanical resistance. For those applications in an embodiment the resultant mechanical resistance of the titanium based alloy is above 52 MPa, in another embodiment the resultant mechanical resistance of the alloy is above 72 MPa, in another embodiment the resultant mechanical resistance of the alloy is above 82 MPa, in another embodiment the resultant mechanical resistance of the alloy is above 102 MPa, in another embodiment the resultant mechanical resistance of the alloy is above 112 MPa and even in another embodiment the resultant mechanical resistance of the alloy is above 122 MPa. In another embodiment the resultant mechanical resistance of the alloy is below 147 MPa, in another embodiment the resultant mechanical resistance of the alloy is below 127 MPa, in another embodiment the resultant mechanical resistance of the alloy is below 117 MPa, in another embodiment the resultant mechanical resistance of the alloy is below 107 MPa, in another embodiment the resultant mechanical resistance of the alloy is below 87 MPa, in another embodiment the resultant mechanical resistance of the alloy is below 77 MPa and even in another embodiment the resultant mechanical resistance of the alloy is below 57 MPa.

There are several technologies that are useful to deposit the titanium based alloy in a thin film; in an embodiment the thin film is deposited using sputtering, in another embodiment using thermal spraying, in another embodiment using galvanic technology, in another embodiment using cold spraying, in another embodiment using sol gel technology, in another embodiment using wet chemistry, in another embodiment using physical vapor deposition (PVD), in another embodiment using chemical vapor deposition (CVD), in another embodiment using additive manufacturing, in another embodiment using direct energy deposition, and even in another embodiment using LENS cladding.

There are several applications that may benefit from the titanium based alloy being in powder form. In an embodiment the titanium based alloy is manufactured in form of powder. In another embodiment the powder is spherical. In an embodiment refers to a spherical powder with a particle size distribution which may be unimodal, bimodal, trimodal and even multimodal depending of the specific application requirements.

The titanium based alloy is useful for the production of casted tools and ingots, including big cast or ingots, alloys in powder form, large cross-sections pieces, hot work tool materials, cold work materials, dies, molds for plastic injection, high speed materials, supercarburated alloys, high strength materials, high conductivity materials or low conductivity materials, among others.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

Any of the Ti based alloys can be combined with any other embodiment herein described in any combination, to the extent that the respective features are not incompatible.

The use of terms such as “below”, “above”, “or more”, “from,” “to,” “up to,” “at least,” “greater than,” “less than,” and the like, include the number recited and refer to ranges that can subsequently be broken down into sub-ranges.

In an embodiment the invention refers to the use of a titanium alloy for manufacturing metallic or at least partially metallic components.

The present invention is particularly suitable for the manufacture of components that can benefit from the properties of cobalt and its alloys. Especially applications requiring high mechanical resistance at high temperatures y/o aggressive environments. In this sense, applying certain rules of alloy design and thermo-mechanical treatments, it is possible obtain very interesting features for applications in chemical industry, energy transformation, transport, tools, other machines or mechanisms, etc.

In an embodiment the invention refers to a cobalt based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Ni = 0-50 | % Si = 0-2 | % Mn = 0-3 |
| % Al = 0-15 | % Mo = 0-20 | % W = 0-25 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % La = 0-5 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % Be = 0-10 |

The rest consisting on cobalt (Co) and trace elements

wherein % Ceq=% C+0.86*% N+1.2*% B

There are applications wherein cobalt based alloys are benefited from having a high cobalt (% Co) content but not necessary the cobalt being the majority component of the alloy. In an embodiment % Co is above 1.3%, in another embodiment is above 6%, in another embodiment is above 13%, in another embodiment is above 27%, in another embodiment is above 39%, another embodiment is above 53%, in another embodiment is above 69%, and even in another embodiment is above 87%. In an embodiment % Co is less than 99%, in another embodiment is less than 83%, in another embodiment is less than 69%, in another embodiment is less than 54%, in another embodiment is less than 48%, in another embodiment is less than 41, in another embodiment is less than 38%, and even in another embodiment is less than 25%. In another embodiment % Co is not the majority element in the cobalt based alloy.

In this context trace elements refers to any element of the list: H, He, Xe, O, F, Ne, Na, Mg, Cl, Ar, K, Sc, Br, Kr, Sr, Tc, Ru, Rh, Ag, I, Ba, Pr, Nd, Pm, Sm, Eu, Gd, Tb, Dy, Ho, Er, Tm, Yb, Lu, Pd, Os, Ir, Pt, Au, Hg, Tl, Po, At, Rn, Fr, Ra, Ac, Th, Pa, U, Np, Pu, Am, Cm, Bk, Cf, Es, Fm, Md, No, Lr, Rf, db, Sg, Bh, Hs, Mt alone and/or in combination. The inventor has seen that for several applications of the present invention it is important to limit the presence of trace elements to less than 1.8%, preferably less than 0.8%, more preferably less than 0.1% and even less than 0.03% in weight, alone and/or in combination.

Trace elements can be added intentionally to attain a particular functionality to the alloy, such as reducing cost production of the alloy, and/or its presence may be unintentional and related mostly to the presence of impurities in the alloying elements and scraps used for the production of the alloy.

There are several applications wherein the presence of trace elements is detrimental for the overall properties of the cobalt based alloy. In an embodiment all trace elements as a sum have a content below 2.0%, in other embodiment below 1.4%, in other embodiment below 0.8%, in other embodiment below 0.2%, in other embodiment below 0.1% or even below 0.06%. There are even some applications for a given application wherein trace elements are preferred being absent from the cobalt based alloy.

There are other applications wherein the presence of trace elements may reduce the cost of the alloy or attain any other additional beneficial effect without affecting the cobalt based alloy desired properties. In an embodiment each individual trace element has content below 2.0%, in other embodiment below 1.4%, in other embodiment below 0.8% in other embodiment below 0.2%, in other embodiment below 0.1% or even below 0.06%.

For certain applications, it is especially interesting the use of alloys with % Ga, % Bi, % Rb, % Cd, % Cs, % Sn, % Pb, % Zn and/or % In. It is particularly interesting is the use of low melting point phases with the presence of more than 2.2% % by weight Ga, preferably more than 12%, more preferably 21% or more and even 29% or more when incorporating these phases. Once incorporated and when evaluating the overall composition measured as stated in this application, the resulting cobalt alloy generally has a 0.2% or more of the element (in this case % Ga), preferably 1.2% or more, more preferably 2.2% or more and even 6% or more. For certain applications it is especially interesting the use of particles with Ga only for tetrahedral interstices and not necessary for all interstices, for these applications is desirable a % Ga of more than 0.02% by weight, preferably more than 0.06%, more preferably more than 0.12% by weight and even more than 0.16%. It has been found that in some applications the % Ga can be replaced wholly or partially by Bi % with the amounts described in this paragraph for % Ga+% Bi. In some applications it is advantageous total replacement ie the absence of Ga %. It has been found that it is even interesting for some applications the partial replacement of % Ga and/or % Bi by % Cd, % Cs, % Sn, % Pb, % Zn, % Rb or % In with the amounts described in this paragraph, in this case for % Ga+% Bi+% Cd+% Cs+% Sn+% Pb+% Zn+% Rb+% In, where depending on the application may be interesting the absence of any of them (ie although the sum is in line with the values given any element can be absent and have a nominal content of 0%, this being advantageous for a given application where the elements in question are detrimental or not optimal for one reason or another). These elements do not necessarily have to be incorporated in highly pure state, but often it is economically more interesting the use of alloys of these elements, given that the alloys in question have sufficiently low melting point. For some applications it is desirable that the above alloys have a melting point below 890° C., preferably below 640° C., more preferably below 180° C. or even below 46° C. For some applications it is more interesting alloy with these elements directly and not incorporate them in separate particles. For some applications it is even interesting the use of particles mainly formed with these elements with a desirable content of % Ga+% Bi+% Cd+% Cs+% Sn+% Pb+% Zn+% Rb+% In greater than 52%, preferably greater than 76%, more preferably above 86% and even higher than 98%. The final content of these elements in the component will depend on the volume fractions employed, but for some applications often move in the ranges described above in this paragraph. A typical case is the use of % Sn and % Ga alloys to have liquid phase sintering at low temperatures with high potential to break oxide films that may have other particles (usually the majority particles). % Sn content and % Ga is adjusted with the equilibrium diagram for controlling the volume content of liquid phase desired in the different post-processing temperatures, also the volume fraction of the particles of this alloy. For certain applications the % Sn and/or % Ga may be partially or completely replaced by other elements of the list (ie can be alloys without % Sn or % Ga). It is also possible get to do it with important content of elements not present in this list such as the case of % Mg and for certain applications with any of the preferred alloying elements for the target alloy.

It has been found that for some applications, excessive presence of chromium (% Cr) may be detrimental, for these applications is desirable a % Cr content of less than 39% by weight, preferably less than 18%, more preferably less than 8.8% by weight and even less than 1.8%. By contrast there are applications wherein the presence of chromium at higher levels is desirable, for these applications amounts exceeding 2.2% by weight are desirable, greater than 5.5% by weight, more preferably over 22%, and even greater than 32%. There are even applications wherein in an embodiment % Cr is detrimental or not optimal for one reason or another, in these applications it is preferred % Cr being absent from the alloy.

It has been seen that for some applications the presence of excessive aluminum (% Al) can be detrimental, for these applications is desirable a % Al content of less than 7.8% by weight, preferably preferably less than 4.8%, more preferably less than 1.8% by weight and even less than 0.8%. In contrast there are applications wherein the presence of aluminum at higher levels is desirable, especially when a high hardening and/or environmental resistance are required, for these applications are desirable amounts, greater than 1.2% by weight, preferably greater than 3.2% by weight, more preferably above 8.2% and even above 12%. For some applications the aluminum is mainly to unify particles in form of low melting point alloy, in these cases it is desirable to have at least 0.2% aluminum in the final alloy, preferably greater than 0.52%, more preferably greater than 1.02% and even higher than 3.2%. There are even applications wherein in an embodiment % Al is detrimental or not optimal for one reason or another, in these applications it is preferred % Al being absent from the alloy.

For some applications it is interesting to have a certain relationship between the aluminum content (% Al) and gallium content (% Ga). If we call S to the output parameter of % Al=S*% Ga, then for some applications it is desirable to have S greater than or equal to 0.72, preferably greater than or equal to 1.1, more preferably greater than or equal to 2.2 and even greater than or equal to 4.2. If we call T to the parameter resulting from % Ga=T*% Al for some applications it is desirable to have a T value greater than or equal to 0.25, preferably greater than or equal to 0.42, more preferably greater than or equal to 1.6 and even greater than or equal to 4.2. It has been found that it is even interesting for some applications the partial replacement of % Ga by % Bi,% Cd,% Cs,% Sn,% Pb,% Zn,% Rb or % In with the amounts described in this paragraph, and to the definitions of s and T, the % Ga is replaced by the sum:% Ga+% Bi+% Cd+% Cs+% Sn+% Pb+Zn %+% Rb+% In, where depending on the application may be interesting the absence of any of them (ie although the sum is in line with the values given any of the items may be absent and have a nominal content of 0%, this being advantageous for a given application where the items in question are detrimental or not optimal for one reason or another).

It has been seen that for some applications, the excessive presence of nickel (% Ni) may be detrimental, for these applications a % Ni content of less than 28% is desirable, preferably less than 18%, more preferably less than 8% or even less than 0.8%. By contrast, there are applications where the presence of nickel at higher levels are desirable, for these applications amounts greater than 1.2% by weight are desirable, preferably above 6%, more preferably above 12% and even over 22%. There are even applications wherein in an embodiment % Ni is detrimental or not optimal for one reason or another, in these applications it is preferred % Ni being absent from the alloy.

It has been seen that for some applications the presence of excessive carbon equivalent (% Ceq) may be detrimental, for these applications is desirable a % Ceq content of less than 1.4% by weight, preferably less than 0.8%, more preferably less than 0.46% by weight and even less than 0.08%. In contrast there are applications wherein the presence of carbon equivalent in higher amounts is desirable for these applications amounts exceeding 0.12% by weight are desirable, preferably greater than 0.52% by weight, more preferably greater than 0.82% and even greater than 1.2%. There are even applications wherein in an embodiment % Ceq is detrimental or not optimal for one reason or another, in these applications it is preferred % Ceq being absent from the alloy.

It has been found that for some applications, the presence of excess carbon (% C) may be detrimental, for these applications is desirable a % C content of less than 0.38% by weight, preferably less than 0.18%, more preferably less than 0.09% by weight and even less than 0.009%. In contrast there are applications where the presence of carbon at higher levels is desirable. For these applications amounts exceeding 0.02% by weight are desirable, preferably greater than 0.12% by weight, more preferably greater than 0.22% and even greater than 0.32%. There are even applications wherein in an embodiment % C is detrimental or not optimal for one reason or another, in these applications it is preferred % C being absent from the alloy.

It has been found that for some applications, the excessive presence of boron (% B) may be detrimental, for these applications is desirable a % B content of less than 0.9% by weight, preferably less than 0.4%, more preferably less than 0.16% by weight and even than 0.006%. In contrast there are applications wherein the presence of boron in higher amounts is desirable for these applications above 60 ppm amounts by weight are desirable, preferably above 200 ppm, more preferably greater than 0.52% and even above 1.2%. There are even applications wherein in an embodiment % B is detrimental or not optimal for one reason or another, in these applications it is preferred % B being absent from the alloy.

It has been seen that there are applications for which the presence of nitrogen (% N) may be detrimental and it is preferable to its absence (may not be economically viable remove beyond the content as an impurity, less than 0.098% by weight, preferably less to 0.06%, more preferably less than 0.0006% and even less than 0.00008%). It has been seen that there are applications for which the presence of boron (% B) may be detrimental and it is preferable its absence (it may not be economically viable remove beyond the content as an impurity, than 0.1% by weight, preferably less to 0.008%, more preferably less than 0.0008% and even less than 0.00008%). There are even applications wherein in an embodiment % N is detrimental or not optimal for one reason or another, in these applications it is preferred % N being absent from the alloy.

It has been found that for some applications, the excessive presence of zirconium (% Zr) and/or hafnium (% Hf) may be detrimental, for these applications is desirable a content of % Zr+% Hf of less than 7.8% by weight, preferably less than 4.8%, more preferably less than 1.8% by weight and even below 0.8%. In contrast there are applications where the presence of some of these elements at higher levels is desirable, especially where a high hardening and/or environmental resistance is required, for these applications amounts of % Zr+% Hf greater than 0.1% by weight are desirable, preferably greater than 1.2% by weight, by weight, more preferably above 6%, or even above 12%. There are even applications wherein in an embodiment % Zr is detrimental or not optimal for one reason or another, in these applications it is preferred % Zr being absent from the alloy. There are even applications wherein in an embodiment % Hf is detrimental or not optimal for one reason or another, in these applications it is preferred % Hf being absent from the alloy.

It has been found that for some applications, the excessive presence of molybdenum (% Mo) and/or tungsten (% W) may be detrimental, for these applications a lower % Mo+½% W content is desirable, of less than 14% by weight, preferably less than 9%, more preferably less than 4.8% by weight and even below 1.8%. In contrast there are applications where the presence of molybdenum and tungsten at higher levels is desirable, for these applications amounts of 1.2% Mo+% W exceeding 1.2% by weight are desirable, preferably greater than 3.2% by weight, more preferably greater than 5.2% and even above 12%. There are even applications wherein in an embodiment % Mo is detrimental or not optimal for one reason or another, in these applications it is preferred % Mo being absent from the alloy. There are even applications wherein in an embodiment % W is detrimental or not optimal for one reason or another, in these applications it is preferred % W being absent from the alloy.

It has been found that for some applications, the excessive presence of Vanadium (% V) may be detrimental, for these applications is desirable % V content less than 4.8% by weight, preferably less than 1.8%, more preferably less than 0.78% by weight and even less than 0.45%. In contrast there are applications wherein the presence of vanadium in higher amounts is desirable for these applications are desirable amounts exceeding 0.6% by weight, preferably greater than 1.2% by weight, more preferably greater than 2.2% and even above 4.2%. There are even applications wherein in an embodiment % V is detrimental or not optimal for one reason or another, in these applications it is preferred % V being absent from the alloy.

It has been that for some applications, excessive presence of copper (% Cu) may be detrimental, for these applications is desirable % Cu content of less than 14% by weight, more preferably less than 4.5% by weight, and even less than 0.9%. In contrast there are applications where the presence of copper at higher levels is desirable amounts greater than 6% by weight are desirable, preferably greater than 8% by weight, more preferably above 12% and even exceeding 16%. There are even applications wherein in an embodiment % Cu is detrimental or not optimal for one reason or another, in these applications it is preferred % Cu being absent from the alloy.

It has been that for some applications the presence of excessive iron (% Fe) may be detrimental, for these applications is desirable % Fe content of less than 58% by weight, preferably less than 24%, more preferably less than 12% by weight, and even less than 7.5%. In contrast there are applications where the presence of iron at higher levels is desirable, for these applications are desirable amounts greater than 6% by weight, preferably greater than 8% by weight, more preferably greater than 22% and even greater than 42%. There are even applications wherein in an embodiment % Fe is detrimental or not optimal for one reason or another, in these applications it is preferred % Fe being absent from the alloy.

It has been found that for some applications, the excessive presence of titanium (% Ti) may be detrimental, for these applications is desirable % Ti content of less than 9% by weight, preferably less than 4.5%, more preferably less than 2.9% by weight, and even less than 0.9%. In contrast there are applications where the presence of titanium in higher amounts is desirable. For these applications are desirable amounts greater than 1.2% by weight, preferably greater than 3.2% by weight, more preferably above 6% or even above 12%. There are even applications wherein in an embodiment % Ti is detrimental or not optimal for one reason or another, in these applications it is preferred % Ti being absent from the alloy.

It has been that for some applications, excessive presence of beryllium (% Be) may be detrimental, for these applications is desirable % Be content of less than 8.7% by weight, more preferably less than 4.5% by weight, and even less than 0.9%. In contrast there are applications where the presence of beryllium at higher levels is desirable, amounts greater than 0.8% by weight are desirable, preferably greater than 2.8% by weight, more preferably above 5.3% and even exceeding 9.6%. There are even applications wherein in an embodiment % Be is detrimental or not optimal for one reason or another, in these applications it is preferred % Be being absent from the alloy.

It has been found that for some applications, the excessive presence of tantalum (% Ta) and/or niobium (% Nb) may be detrimental, for these applications is desirable % Ta+% Nb content less than 7.8% by weight, preferably less than 4.8%, more preferably less than 1.8% by weight, and even less than 0.8%. In contrast there are applications wherein higher amounts of % Ta and/or % Nb are desirable, especially for these applications is desired an amount of % Nb+% Ta greater than 0.1% by weight, preferably greater than 1.2% by weight, preferably greater than 6% and even greater than 12%. There are even applications wherein in an embodiment % Ta is detrimental or not optimal for one reason or another, in these applications it is preferred % Ta being absent from the alloy. There are even applications wherein in an embodiment % Nb is detrimental or not optimal for one reason or another, in these applications it is preferred % Nb being absent from the alloy.

It has been found that for some applications, the excessive presence of yttrium (% Y), cerium (% Ce) and/or lanthanide (% La) may be detrimental, for these applications is desirable % Y+% Ce+% La content less than 7.8% by weight, preferably less than 4.8%, more preferably less than 1.8% by weight, and even less than 0.8%. In contrast there are applications wherein higher amounts are desirable, especially when a high hardness is desired, for these applications is desired an amount of % Y+% Ce+% La greater than 0.1% by weight, preferably greater than 1.2% by weight, more preferably above 6% or even above 12%. There are even applications wherein in an embodiment % Y is detrimental or not optimal for one reason or another, in these applications it is preferred % Y being absent from the alloy. There are even applications wherein in an embodiment % Ce is detrimental or not optimal for one reason or another, in these applications it is preferred % Ce being absent from the alloy. There are even applications wherein in an embodiment % La is detrimental or not optimal for one reason or another, in these applications it is preferred % La being absent from the alloy.

For some applications when aluminum is used as low melting point element or any other type of particle that oxidizes rapidly in contact with air, such as magnesium, etc. is used as low melting point element. If magnesium is used mainly as destroying the alumina film on aluminum particles or aluminum alloy (sometimes it is introduced as a separate powder of magnesium or magnesium alloy and also sometimes alloyed directly to the aluminum particles or aluminum alloy and also sometimes other particles such as low melting particles) the final content of % Mg can be quite small, in these applications often greater than 0.001% content, preferably greater than 0.02% is desired, more preferably greater than 0.12% and even above 3.6%.

For some applications it is interesting that the consolidation and/or densification of the particles with aluminum is carried out in atmosphere with high nitrogen content which often reaction occurs particularly if consolidation and/or densification (eg sintering with or without liquid) phase occurs at elevated temperatures, the nitrogen will react with the aluminum and/or other elements forming nitrides and thus appear as an element in the final composition. In these cases it is often useful to have in the final composition a nitrogen content of 0.002% or higher, preferably 0.02% or higher, more preferably 0.4% or higher and even 2.2% or higher.

There are several elements such as Pd that are detrimental in specific applications especially for high % Cr contents; for these applications in an embodiment with % Cr higher than 19% the % Pd in the cobalt based alloy is preferred below 51 ppm, and even in another embodiment Pd is preferred to be absent from the alloy.

There are several elements such as Pd, Pt, Au, Ir, Os, Rh and Ru that are detrimental in specific applications especially for high % Cr contents; for these applications in an embodiment with % Cr higher than 15.3% the sum of % Pd, % Pt, % Au, % Ir, % Os, % Rh and % Ru in the cobalt based alloy is preferred below 25%, and even in another embodiment with presence of Cr the sum of % Pd, % Pt, % Au, % Ir, % Os, % Rh and % Ru is preferred to be 0%.

It has been found that for some applications, certain contents of elements such as C, W, Co, N, Ga and Re may be detrimental for certain Cr contents. For these applications in an embodiment with % Cr higher than 11.8% and lower than 30.1% the % C in the cobalt based alloy is preferred to be higher than 0.12%. In another embodiment with % Cr higher than 11.8% and lower than 30.1% the % W in the cobalt based alloy is preferred to be lower than 7.8%, in another embodiment with % Cr higher than 11.8% and lower than 30.1% the % Co in the cobalt based alloy is preferred to be higher than 69% or lower than 42%. In another embodiment with % Cr above 10.2% the % N in the cobalt based alloy is preferred to be 0%. In another embodiment with % Cr higher than 11.8% and lower than 30.1%, Re is preferred to be absent from the alloy. Even in another embodiment with % Cr lower than 41% and higher than 9.9%, % Ga is preferred to be higher than 20.3% or lower than 0.9%

There are several elements such as rare earth elements that are detrimental in specific applications. For these applications, in an embodiment the sum of rare earth elements (%) is preferred to be below 14.6%, and even in another embodiment the sum of rare earth elements is preferred to be 0.

There are several applications wherein the presence of B, Si, Al, Mn, Ge, Fe and Ni in the composition is detrimental for the overall properties of the cobalt based alloy. In an embodiment the alloy does not contain Si and B at the same time, in another embodiment the alloy does not contain Fe and Ni at the same time, in another embodiment the alloy does not contain Al and Ni at the same time, in another embodiment the alloy does not contain Si and Ni at the same time, in another embodiment the alloy does not contain Mn and Ge at the same time. Even in another embodiment the alloy does not contain Mn, Si and B at the same time.

There are several properties of the alloy such as magnetic properties that are detrimental in specific applications. In an embodiment the cobalt based alloy is preferred not to be magnetic.

In an embodiment, there is at least a 1.2% of the volume (taking only the metallic and intermetallic constituents into account) where the content of the main alloying element (taking into account the mean composition of all mostly metallic or intermetallic particles) is smaller than a 70% in weight when the mixture of powders is made, or in general before the shaping stage of the process, and the amount of this volume (volume where the content of the main alloying element is smaller) is reduced at least an 11% of its original size after the whole processing and post-processing are concluded.

In an embodiment, there exists at least one low melting point element whose concentration in weight is at least a 2.2% greater than the mean content of this element (taking into account the mean composition of all mostly metallic or intermetallic particles) in at least a 1.2% of the volume (taking only the metallic and intermetallic constituents into account) when the mixture of powders is made, or in general before the shaping stage of the process, and the amount of this volume (volume where the concentration of at least one low melting point element is higher) is reduced at least an 11% of its original size after the whole processing and post-processing are concluded.

There are other applications wherein the presence of certain elements such as Re are detrimental for certain properties especially for embodiments containing Co, Si and Ti. For these applications in an embodiment containing Co, Si and Ti at the same time, Re is absent from the alloy.

There are several elements such as Ti, P, Zn and Ni that are detrimental in specific applications especially for some % Ga contents; for these applications in an embodiment with presence of % Ga, elements such as Ti and/or P and/or Zn are absent from the alloy. Even in another embodiment with presence of % Ga, elements such as Ti and/or P and/or Zn are absent from the alloy and/or elements such as Ni are present in the composition.

It has been found that for some applications, certain contents of elements such as Fe, Ni, Mn, and Al may be detrimental. For these applications, in an embodiment containing Fe and/or Ni, % Al is preferred below 2.9% and/or Mn is absent from the alloy. Even in another embodiment containing Fe and/or Ni, % Al is preferred above 13.1% and/or Mn is absent from the alloy.

Any of the above-described embodiments can be combined with any other embodiment herein described in any combination, to the extent that the respective features are not incompatible.

The present invention allows the realization of very aggressive cooling strategies, as mentioned given that the cooling channels can be brought very close to the surface given the improved resistance to stress corrosion cracking and to mechanical failure even when the channels have been machined with a rough surface. Besides the conventional drilling, brazing, shell construction, etc. manufacturing strategies, the present invention is very interesting for Additive Manufacturing (AM) and other more advanced manufacturing technologies, where even more aggressive cooling strategies can be applied, like cooling systems resembling the way the human body regulates temperature trough blood circulation trough primary channels that go into secondary channels with final capillary channels that execute the heat transference very close to the surface and a similar system to extract the cooling fluid after the intended heat exchange. Very many other strategies can be implemented with very effective, regular and tailored thermal regulation.

It has been seen that the present invention is especially advantageous for the manufacture of components with a thermoregulation system. This is because the manufacturing method allows the construction of complex geometries within the component, a feature that can be used for obtaining internal and even external thermoregulation systems, as discussed below, with high efficiency.

A particularly advantageous application of the present invention is the manufacture of molds, dies or other tools. As discussed in the preceding paragraph, the invention is especially advantageous when these matrices also have some thermo-regulator functionality (often heating, cooling or both).

An important advantage when it comes to thermoregulation systems, especially if it is performed with a fluid assistance, is that it is possible to obtain a homogenous distribution of the thermoregulatory fluid and very close to the surface to be thermoregulated. In the case of using channels, they can be very well distributed and very close to the surface. It has been seen that for some applications the mean distance of more effective fine channels for thermoregulation will be desirable lower than 18 mm, preferably lower than 8 mm, more preferably lower than 4.8 mm and even lower than 1.8 mm.

In an embodiment, the mean distance of fine channels for thermoregulation may be lower than 18 mm, in another embodiment lower than 8 mm, in another embodiment lower than 4.8 mm, in another embodiment lower than 1.8 mm and even in another embodiment lower than 0.8 mm.

For some applications a too small distance can be counterproductive, for those applications this distance will be desirable above 0.6 mm, preferably above 1.2 mm, more preferably above 6 mm and even above 16 mm. For some applications it is suitable that the mean distance between fine channels will be 18 mm or less, preferably 9 mm or less, more preferably 4.5 mm or less and ever lower than 1.8 mm. For some applications, especially when mechanical solicitation is high or there is corrosion risk, it will be desirable that the material used to the component manufacture has a high fracture toughness.

For some applications it is desirable that que material has a fracture toughness of 2 MPa√m or more, preferably higher than 32 MPa√m, more preferably higher than 42 MPa√m and even higher than 62 MPa√m. It has been seen that for some applications, especially where a material with a n excessive yield strength is not needed, is desirable to use a material with fracture toughness higher than 82 MPa√m, preferably higher than 102 MPa√m, more preferably higher than 156 MPa√m and even higher than 204 MPa√m. It has been seen that for some applications it is important that the mean diameter of fine channels is lower than 38 mm, preferably lower than 18 mm, more preferably lower than 8 mm and even lower than 2.8 mm.

In an embodiment the mean diameter of fine channels may be lower than 38 mm, in another embodiment lower than 18 mm, in another embodiment lower than 8 mm, in another embodiment lower than 2.8 mm and even in another embodiment lower than 0.8 mm.

It has been seen that for some applications it is important that the mean equivalent diameter of fine channels will be above 1.2 mm, preferably above 6 mm, more preferably above 12 mm and even above 22 mm. It has been seen that for some applications it will be desirable that the minimum average diameter equivalent of fine channel will be lower than 18 mm, preferably lower than 8 mm, more preferably and even lower than 2.8 mm. In an embodiment, the minimum average diameter equivalent of fine channel may be lower than 18 mm, in another embodiment lower than 8 mm, in another embodiment lower than 2.8 mm and even in another embodiment lower than 0.8 mm.

It has been seen that for some applications it is important that the equivalent average diameter of fine channels will be above 1.2 mm, preferably above 6 mm, more preferably above 12 mm and above 22 mm. It has been seen that for some applications it will be desirable that the minimum equivalent diameter will be lower than 18 mm, preferably lower than 12 mm, preferably lower than 9 mm, more preferably lower than 4 mm and eve lower than 1.8 mm.

In an embodiment, the minimum equivalent diameter may be lower than 18 mm, in another embodiment lower than 12 mm, in another embodiment lower than 9 mm, in another embodiment lower than 4 mm, in another embodiment lower than 1.8 mm and even in another embodiment lower than 0.8 mm.

It has been seen that for some applications it is important the average equivalent diameter of main channels to be above 12 mm, preferably above 22 mm, more preferably above 56 mm and even above 108 mm.

In thermoregulation systems with components submitted to important mechanical efforts, there is always the dilemma between the proximity and the channels section where the thermoregulation fluid circulates. If channels have a little section, pressure drop increase and the head exchange capacity is reduced.

In an embodiment, the total pressure drop in the system may be lower than 7.9 bar, in another embodiment lower than 3.8 bar, in another embodiment lower than 2.4 bar, in another embodiment lower than 1.8 bar, in another embodiment lower than 0.8 bar and even in another embodiment lower than 0.3 bar.

In another embodiment, the pressure drop in the capillaries may be lower than 5.9 bar, in another embodiment lower than 2.8 bar, in another embodiment lower than 1.4 bar, in another embodiment lower than 0.8 bar, in another embodiment lower than 0.5 bar and even in another embodiment lower than 0.1 bar.

If the distance to the surface to be thermoregulated is high then the thermoregulation is ineffective. On the other hand if channels have a big section and are close to the surface to be thermoregulated, the mechanical failure possibilities increase in great manner. To solve this dilemma, in the present invention a combined system which replicates the blood transport in human body (which also has a thermoregulatory mission) is proposed. There are main arteries in the human body which transport oxygenated blood to secondary arteries, to reach fine capillaries. The less oxygenated blood is transported through capillaries to secondary veins and then to main veins. Similarly, as can be seen in FIG. 5, in the proposed system the thermoregulatory fluid (hot or cold depending on the thermoregulatory function) is transported from main channels to secondary channels (there may be different secondary channels orders, this means, tertiary, quaternary, etc.) until arrive to fine and not very large channel very close to the surface to be thermoregulated. This system is advantageous for some applications, for other applications is more suitable the use of more traditional systems. Being the small cross section very short, the pressure drop effect turns it into manageable. By means of simulation of finite elements, the more advantageous configurations of secondary and main channels for a given application can be studied, both in terms of thermoregulatory efficacy as in fluid mechanics referred to sections, length, position, flow, pressure, type of fluid, etc. A special feature of the proposed system, compared to traditional systems, lies in that input and output of the thermoregulatory fluid within the same component is made by different channels, which mainly are connected between them, by channels having an individual cross section considerably smaller, which are mainly responsible to perform the desired thermoregulation. It has been seen that for some applications the cross section of the input channel (sometimes there may be more than one channel, in this case cross section will be summed), it will be desirable to be at least 3 times higher than the section of the smaller channel of all the channels contributing in the desired area of the component where the thermoregulation is desired, preferably above 6 times, more preferably above 11 times, and even above 110 times.

As can be seen in the schematic representation in FIG. 5A, the thermoregulation fluid enters into the component by a main channel (or several channels, in the schematic representation only can be seen one channel, but in the same way there may be several inputs or main entrance channels), the fluid is divided into several secondary channels until arrive to the fine channels of desired heat exchange. It has been seen that for some applications it will be desirable that the main input channels have several divisions (branches), it will be desirable 3 or more, preferably 6 or more, more preferably 22 or more and even 110 or more. As previously defined, the secondary channels may have several division orders (tertiary channels, quaternary channels, . . . ) it has been seen that for some applications it will be desirable to have a high division order of the input channels, for these applications it will be desirable a division order of 3 or more, preferably 4 or more, more preferably 6 or more and even 12 or more. There are applications wherein an excessive division order in the input channels can be negative, for these applications it will be desirable a division order of 18 or less, preferably 8 or less, more preferably 4 or less, and even 3 or less. It has been seen that for some applications it will be desirable that the secondary input channels have several divisions; it will be desirable 3 or more, more preferably 6 or more, more preferably 22 or more, even 110 or more. Related to the heat exchange channels as previously discussed in preceding paragraphs, it will be often desirable that these channels will be close to the thermoregulation surface, close between them to have an homogenous regulation and in applications with a high mechanic solicitation it will be desirable a small channel section, which increases fluid pressure drops and it will be desirable not being too long. FIG. 5B shows a schematic representation, a bird's eye view, of a possible sub-superficial distribution of the fine channels in the desired exchange zone or active surface. For some applications it has been seen that it will be specially desirable that individually the fine channels under the active surface don't have an excessive average length (effective length, the length of the section under the active surface wherein efficient thermoregulation is desired, not accounting the section that carried the fluid from the secondary channels, eventually also from main channels, to the section wherein the heat exchange with the active surface is efficient, the average value due to the very fine channel may have a different length and hence the arithmetic average value is used as in the rest of the document, unless otherwise it is indicated), in these applications it will be desirable an average value of less than 1.8 m, preferably less than 450 mm, more preferably less than 180 mm and even less than 98 mm. For some applications it will be desirable to work with a very small cross section channels or minimize pressure drops due to any other reason, in this case it will be desirable an average effective lengths of less than 240 mm, preferably less than 74 mm, more preferably less than 48 mm and even of less than 18 mm. For several applications, the end of the fine channel acts as discontinuity and for this or other reasons it will be desirable a minimum average effective length of 12 mm or more, preferably above 32 mm, more preferably above 52 mm and even above 110 mm. For several applications it will be desirable a high sub-superficial fine channels under the active surfaces where thermoregulation is desired. In this sense if sub-superficial fine channels are cut at the point where has the higher cross section and the zone to be thermoregulated is evaluated, which is the channel surface density where the channels are present, this means which percentage of the total area performs the channel area (which can be referred as fine channels surface density), it has been seen that for some applications it will be desirable fine channel higher than 12%, preferably higher than 27%, more preferably higher than 42%, and even higher than 52%. There are applications wherein a very homogenous or intensive heat exchange is required, wherein fine channels surface densities are desired 62% or more, preferably higher than 72%, more preferably higher than 77% and even higher than 86%. For some applications, and excessive fine channel surface density may bring mechanical failure of the component or other problems, in such cases it will be desirable a fine channel surface density of 57% or lower, preferably 47% or lower, more preferably 23% or lower and even 14% or lower. It has been seen that for some applications which is important is to control the ratio H=Total length (sum) of the fine channels effective part/average length of the fine channels effective part. It has been seen that for some applications it will be desirable a H ratio higher than 12, preferably higher than 110, more preferably higher than 1100 and even higher than 11000. For some applications an excessive H ratio may be negative, for such applications it will be desirable an H ratio lower than 900, preferably lower than 230, more preferably lower than 90 and even lower than 45. There are also applications wherein it is desirable a certain number of fine channels per square metre. For some applications it will be desirable 110 or more fine channels per square metre, preferably more than 1100 or more, more preferably 11000 or more and even 52000 or more. It has been seen that for some applications it will be desirable that the main channels output have several divisions, it will be desirable 3 or more, preferably 6 or more, more preferably 22 or more and even 110 or more. As defined, secondary channels may have several division orders (tertiary channels, quaternary channels.) it has been seen that for some applications it will be desirable a high division order in channels output, for such applications it will be desirable a division order of 2 or more, preferably 4 or more, more preferably 6 or more and even 12 or more. There are applications wherein an excessive division order in channels output can be negative, for such applications it will be desirable a division order of 18 or less, preferably 8 or less, more preferably 4 or less and even 3 or less. It has been seen that for some applications it will be desirable that output secondary channels have several divisions, it will be desirable 3 or more, preferably 6 or more, more preferably 22 or more and even 110 or more.

For some applications it will be more desirable give up excessive divisions, so in this applications there will not be secondary channels, it is moving from primary channels to thermoregulation fine channels.

It has been seen that for certain applications wherein a fluid for thermoregulation is used it will be suitable that the fluid will be a water-base fluid, it will be desirable a 42% in volume or more water, preferably 52% or more, more preferably 86% or more and even 96% or more. It has been seen that for several application it will be interesting that the organic-based fluid will be mainly a mineral oil, in such cases it will be desirable the mineral oil in quantity of at least 32% in volume, preferably 52% or more, more preferably 78% or more, and even 92% or more. It has been seen that for some applications it will be interesting that the organic-based fluid will be mainly an aromatic organic component, in such cases it will be desirable the aromatic organic component at least 32% in volume, preferably more than 52% or more, more preferably 78% or more and even 92% or more. It has been seen that for some applications it will be interesting that the organic-based fluid will be mainly vegetal oil, in such cases it will be interesting the amount of vegetal oil to be at least 32% in volume, preferably 52% or more, more preferably 78% or more, and even 92% or more. It has been seen that for some applications it will be interesting that the organic-based fluid will be mainly a non-aromatic organic component, in such cases it will be interesting that the quantity of non-aromatic organic component will be at least 32% in volume, preferably 52% or more, more preferably 78% or more, and even 92% or more. It has been seen that for some applications it will be interesting that the thermoregulatory fluid will be a gas. It has been seen that for some applications it will be interesting that the thermoregulatory fluid will be a mist. In some of these applications it has been seen that is suitable that the gas and/or mist enter into the component with certain pressure, usually it is desired an absolute inlet pressure of 2.2 bar or more, preferably 11 bar or more, more preferably 110 bar or more, and even 1100 bar or more. It has been seen that in some applications wherein the thermoregulatory fluid is a liquid, it is suitable that the liquid enter into the component with certain pressure, usually it is desired an absolute inlet pressure of 2.2 bar or more, preferably 5.5 bar or more, more preferably 11 bar or more, and even 22 bar or more.

For some applications, for example when the component is a piece or tool that has to cool the piece that is conforming, it is interesting to have a high cooling rate of the processed component. This can be done with the present invention using conformal cooling, with the channels very close to the surface, also with the system described in the preceding paragraphs. For some applications, the present invention, allows use the latent heat of vaporization from a fluid for cooling fast. A possible execution consists on a replicate of the sweating system of the human body. By analogy in this document it is denominated sweeting component (sometimes, especially when reference is made to applications wherein the component is a die, mould or tool in general, it can be referred as sweeting die). It consists on a die having small holes which transport small fluid quantities to the active evaporation surface. For some applications it is desired a controlled drip (drop) scenario. For some applications it is even desired a jet or more massive water supply. For some applications it is desired a scenario of incomplete drop formation in the active evaporation surface, this means a drop that does not break off from the evaporation surface unless it transforms to steam. In another embodiment, the drops may reach the surface of the component by external methods. To determine the scenario that takes place, fluid pressure, surface tension and the configuration of fluid transporting internal channels and the outlet holes in the active evaporation surface, among others must be controlled. Often it is suitable to implement a system with controlled pressure drop for a better pressure balance in the different holes.

In an embodiment, the total pressure drop may be lower than 7.9 bar, in another embodiment lower than 3.8 bar, in another embodiment lower than 2.4 bar, in another embodiment lower than 1.8 bar, in another embodiment lower than 0.8 bar and even in another embodiment lower than 0.3 bar.

In an embodiment, the pressure drop in the capillaries may be lower than 5.9 bar, in another embodiment lower than 2.8 bar, in another embodiment lower than 1.4 bar, in another embodiment lower than 0.8 bar, in another embodiment lower than 0.5 bar and even in another embodiment lower than 0.1 bar.

Although often the fluid to be evaporated in the evaporation surface is water, an aqueous solution or an aqueous suspension, several other fluids can be used, so the term water can be replaced by other fluids which may evaporate with latent heat of vaporization associated.

It has been seen that for some applications it is interesting that the diameter of the tubes for transporting fluid to the active surface are small. In those cases it is desirable less than 1.4 mm, preferably less than 0.9 mm, more preferably 0.45 mm and even less than 0.18 mm. In an embodiment, the diameter of the tubes for transporting fluid to the active surface may be less than 1.4 mm, in another embodiment less than 0.9 mm, in another embodiment less than 0.45 mm, in another embodiment less than 0.18 mm and even in another embodiment less than 0.09 mm For some applications it is interesting that the diameter of the tubes for transporting fluid to the active evaporation surface is not too small, in those cases it is desirable greater than 0.08 mm, preferably greater than 0.6, more preferably greater than 1.2 mm and even greater than 2.2 mm. For some applications it has been seen that the pressure applied to the fluid in the tubes for transporting fluid to the active surface should not be too small, for those cases it is desirable a differential pressure (difference with the gas pressure on the evaporation surface) of 0.8 bar or less, preferably 0.4 bar or less, more preferably 0.08 bar or less, and even 0.008 bar or less. For some applications it has been seen that it is interesting regulate the number of fluid average drops emerging from the holes in the tubes wherein fluid is transported to the active evaporation surface. For some applications it has been seen that it is interesting that the average drop number emerging from the holes in the tubes for conducting fluid to the active evaporation surface must not be too high, for those cases it is desirable a number of drops per minute lower than 80, preferably lower than 18, more preferably lower than 4 and even lower than 0.8. As previously disclosed, there are applications wherein it is undesirable drops breaking off itself from the end of the holes. For some applications it has been seen that the number of average drop emerging from the holes in the tubes for conducting fluid to the active evaporation surface must not be too low, for those cases it is desirable a number of drops per minute greater than 80, preferably greater than 18, more preferably greater than 4 and even greater than 0.8. It has been seen that for some applications is very important the control of the tubes number to transport the fluid to the active evaporation surface per unity of active evaporation surface. In this sense for some applications it is suitable to have more than 0.5 tubes per cm2, preferably more than 1.2 tubes per cm2, more preferably more than 6 tubes per cm2 and even more than 27 tubes per cm2. For some applications the important is the percentage of the active evaporation surface which is holes. In this sense for some applications it is desirable that at least a percentage greater than 1.2% of the contact area surface is hole, preferably greater than 28% and even greater than 62%. For some applications it has been seen that it is desirable that the average distance between the holes centres in the active evaporation surface will be less than 12× the hole diameter, preferably less than 8×, more preferably less than 4×, and even less than 1.4×. For some applications it is important the surface tension of the fluid being evaporated to be significant, in those cases it is desirable to be greater than 22 mM/m, preferably greater than 52 mM/m, more preferably greater than 70 mM/m, and even greater than 82 mM/m. For some applications it is important the surface tension of the fluid being evaporated not to be excessive, in those cases it is desirable to be lower than 75 mm/m, preferably lower than 69 mM/m, more preferably lower than 38 mM/m, and even lower than 18 mM/m.

The rugosity (Ra) of the inside of channels is very important for describing flow. In an embodiment, Ra may be lower than 49.6 microns, in another embodiment lower than 18.7 microns, in another embodiment lower than 9.7 microns, in another embodiment lower than 4.6 microns and even in another embodiment lower than 1.3 microns.

For some applications it is quite important the way of providing the fluid to be evaporated to the tubes for transporting the fluid to the active evaporation surface. Often this input is made through a network of channels inside the component. These channels may have different geometries and have accumulation zones and also it is interesting as previously disclosed to have controlled pressure drop zones to equilibrate different zones. In an embodiment, the total pressure drop may be lower than 7.9 bar, in another embodiment lower than 3.8 bar, in another embodiment lower than 2.4 bar, in another embodiment lower than 1.8 bar, in another embodiment lower than 0.8 bar and even in another embodiment lower than 0.3 bar. In an embodiment, the pressure drop in the capillaries may be lower than 5.9 bar, in another embodiment lower than 2.8 bar, in another embodiment lower than 1.4 bar, in another embodiment lower than 0.8 bar, in another embodiment lower than 0.5 bar and even in another embodiment lower than 0.1 bar. The mission of this channel framework in addition to providing the desired flow to each of the tube, for some applications it is interesting that the pressure in the outlet tube or at least a part of them is fairly homogeneous. The techniques developed for drip (drop) irrigation systems, among others, can be replicated (sometimes with some adaptation due to downsize, but replicating the concept) for this purpose. The inventor has seen that for some applications it is desirable that the pressure difference of the fluid which evaporates to reach the outlet tubes for transporting fluid to the active evaporation surface, for a representative group, to be lower than 8 bar, preferably lower than 4 bar, more preferably lower than 1.8 bar and even lower than 0.8 bar. For holes that do not require large pressures, as it is often the case of holes with not too thin diameter, it has been seen that for some applications it is desirable a difference lower than 400 mbar, preferably lower than 90 mbar, more preferably lower than 8 mbar and even lower than 0.8 mbar. A representative group of tubes are for the same surface evaporation, in areas wherein the same evaporation intensity of 35% or more of the tubes in the aforementioned area is required, preferably 55% or more, more preferably 85% or more and even 95% or more. For some applications, especially also for some applications when different evaporation intensities are required in different areas, it is desirable that the difference of pressure of the fluid which evaporates when arrive to the tube outlets for the transport of the fluid to the active evaporation surface, for the hole with higher pressure and the hole with less pressure, to be greater than 0.012 bar, preferably greater than 0.12 bar, more preferably greater than 1.2 bar and even greater than 6 bar.

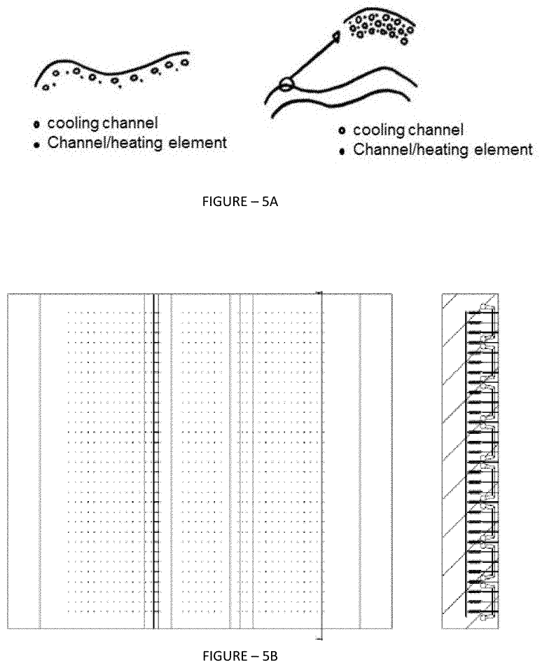

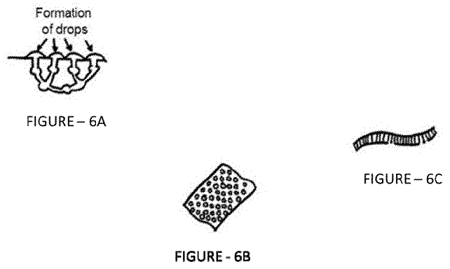

One possible implementation of the sweating component is shown in FIG. 6. These images are an illustrative example of a possible implementation to promote understanding, in no case it is a representation of how to implement the invention, since there are many implementations and it would be disproportionate try to illustrate all of them in detail. The selected implementation for the figure is not the more effective but it can be selected due it is believed that can better contribute to understanding the concept and to a rapid spread, to develop the implementation of the concept optimized for each particular application. In FIG. 6A it is intended to represent a hypothetical (or possible) cross section wherein a system of sub-superficial channels distribute the fluid to be evaporated to finally brought the fluid to the active evaporation surface, in which holes it is shown the formation of a drop. In this representation it must be understand that out of the plane, and therefore not visible in the representation, there are several tubes to transport the fluid to the active evaporation surface that feed on the same sub-superficial division. In FIG. 6B a possible distribution of the tube outlets to transport the fluid to the active evaporation surface is shown in a birds eye representation. In FIG. 6C is shown a schematic representation of a possible implementation of a mould part manufactured by additive manufacturing which is responsible of achieving the tubes to transport the fluid to the active evaporation surface and its corresponding holes.

Although often the cooling channels, and the holes outputs as well as the tubes to transport the fluid to the active evaporation surface, are circular, they can be of any other geometry in its cross section as well as of variable geometry, depending on the application. This applies to the entire document unless otherwise is specified.

An interesting application for the sweating die, like the thermoregulation systems explained in this entire document and even combinations of both is hot stamping. The combination of sweating dies with any of the thermoregulation systems explained throughout this document may be interesting for many applications besides the hot stamping. All that is mentioned for hot stamping, or part of this, may be extended to other applications, especially those where there is a component to be cooled that at least can accept direct contact with water or steam.

For applications where the contact with water is not acceptable, the tubes that go to the active surface can be infiltrated with a metal or a high thermal conductivity alloy, such as Ag, Cu, Al . . . . Then the tubes or channels to the surface will transport the heat better contributing to the total heat removal capacity of this active surface component. In fact in this way the thermoregulation capacity is improved both in the sense of cooling and heating, and can be used for some heat & cool applications. For some applications it is not suitable the metal or high thermal conductivity alloy outcropping to the active surface, at least in some areas, in those cases tubes may lack holes and finish below the active surface, before infiltration, so the metal or the high thermal conductivity alloy does not reach the surface.

In an embodiment the design of the cooling channel, the determination of the sizes, types of cooling channels, length of the channels, distance to the working surface as well as the flow rate of coolant among others may be done using any available simulation software.

In the context of the present invention the distance between the working surface of the tool, die, piece or mould and the channel refers to the minimum distance between any point of the channel surrounding and the working surface of the tool, die, piece or mould.

In an embodiment of the invention the shape of the channels do (may) not have a constant section. In an embodiment of the invention, the channels have a minimum shape and a maximum shape.

In the context of the present invention the average distance, is referred to the average value (where you sum all the numbers and then divide by the number of numbers) of the distance between the different channel surrounding sections and the working surface of the tool, die, piece or mould. In this context the minimum average distance refers to the minimum average distance between the channel surrounding and the working surface of the tool, die, piece or mould.

In an embodiment the channels are close to the working surface of the tool, die, piece or mould at a distance between the channel surrounding and the working surface of less than 75 mm.

In another embodiment the distance between the channel surrounding and the working surface of the tool, die, piece or mould is less than 51 mm, in another embodiment the distance is less than 46 mm, in another embodiment the distance is less than 39 mm, in another embodiment the distance is less than 27 mm, in another embodiment the distance is less than 19 mm, in another embodiment the distance is less than 12 mm, in another embodiment the distance is less than 10 mm, in another embodiment the distance is less than 8 mm, in another embodiment is less than 7.8 mm, in another embodiment the distance is less than 7.4 mm, in another embodiment the distance is less than 6.9 mm, in another embodiment the distance is less than 6.4 mm, in another embodiment the distance is less than 5.8 mm, in another embodiment the distance is less than 5.4 mm, in another embodiment the distance is less than 4.9 mm, in another embodiment the distance is less than 4.4 mm, in another embodiment the distance is less than 3.9 mm, and even in another embodiment the distance is less than 3.4 mm.

In an embodiment of the invention the shape of the cooling channels of the tool, die, piece or mould are selected from circular, square, rectangular, oval or half circle.

In an embodiment the cooling channels of the tool, die, piece or mould include primary channels and/or secondary channels and/or capillary channels; in another embodiment the cooling channels of the tool, die, piece or mould include primary channels; in another embodiment the cooling channels of the tool, die, piece or mould include primary channels and secondary channels, in another embodiment the cooling channels of the tool, die, piece or mould include primary channels and secondary channels and capillary channels, in another embodiment the cooling channels of the tool, die, piece or mould include primary channels and capillary channels; in another embodiment the cooling channels of the tool, die, piece or mould include secondary channels and capillary channels; in another embodiment the cooling channels of the tool, die, piece or mould include secondary channels; in another embodiment the cooling channels of the tool, die, piece or mould include capillary channels.

In an embodiment, for constant sections of the primary channels, the shape of the primary channels of the tool, die, piece or mould have a shape area of less than 2041.8 mm2; in another embodiment, the shape of the primary channels of the tool, die, piece or mould have a shape area of less than 1661.1 mm2; in another embodiment, the shape of the primary channels of the tool, die, piece or mould have a shape area of less than 1194 mm2; in another embodiment, the shape of the primary channels of the tool, die, piece or mould have a shape area of less than 572.3 mm2; in another embodiment, the shape of the primary channels of the tool, die, piece or mould have a shape area of less than 283.4 mm2; in another embodiment, the shape of the primary channels of the tool, die, piece or mould have a shape area of less than 213.0 mm2; in another embodiment, the shape of the primary channels of the tool, die piece or mould have a shape area of less than 149 mm2; in another embodiment, the shape of the primary channels of the tool, die, piece or mould have a shape area of less than 108 mm2; in another embodiment, the shape of the primary channels of the tool, die, piece or mould have a shape area of less than 42 mm2; in another embodiment, the shape of the primary channels of the tool, die, piece or mould have a shape area of less than 37 mm2; in another embodiment, the shape of the primary channels of the tool, die, piece or mould have a shape area of less than 31 mm2; in another embodiment, the shape of the secondary channels of the tool, die, piece or mould have a shape area of less than 28 mm2; in another embodiment, the shape of the primary channels of the tool, die, piece or mould have a shape area of less than 21 mm2; in another embodiment, the shape of the primary channels of the tool, die, piece or mould have a shape area of less than 14 mm2; in another embodiment, the shape of the primary channels of the tool, die, piece or mould is between 56 mm2 and 21 mm2; in another embodiment, the shape of the primary channels of the tool, die, piece or mould is between 56 mm2 and 14 mm2.

In an embodiment, when the section is not constant, the value of the above shape of the primary channels of the tool, die, piece or mould is referred to the minimum shape of the primary channel.

In an embodiment, for constant sections of the secondary channels, the shape of the secondary channels of the tool, die, piece or mould have a shape area of less than 122.3 mm2; in another embodiment, the shape of the secondary channels of the tool, die, piece or mould have a shape area of less than 82.1 mm2; in another embodiment, the shape of the secondary channels of the tool, die, piece or mould have a shape area of less than 68.4 mm2; in another embodiment, the shape of the secondary channels of the tool, die, piece or mould have a shape area of less than 43.1 mm2; in another embodiment, the shape of the secondary channels of the tool, die, piece or mould have a shape area of less than 26.4 mm2; in another embodiment, the shape of the secondary channels of the tool, die, piece or mould have a shape area of less than 23.2 mm2; in another embodiment, the shape of the secondary channels of the tool, die, piece or mould have a shape area of less than 18.3 mm2; in another embodiment, the shape of the secondary channels of the tool, die, piece or mould have a shape area of less than 14.1 mm2; in another embodiment, the shape of the secondary channels of the tool, die, piece or mould have a shape area of less than 11.2 mm2; in another embodiment, the shape of the secondary channels of the tool, die, piece or mould have a shape area of less than 9.3 mm2; in another embodiment, the shape of the secondary channels of the tool, die, piece or mould have a shape area of less than 7.2 mm2; in another embodiment, the shape of the secondary channels of the tool, die, piece or mould have a shape area of less than 6.4 mm2; in another embodiment o, the shape of the secondary channels of the tool, die, piece or mould have a shape area of less than 5.8 mm2; in another embodiment, the shape of the secondary channels of the tool, die, piece or mould have a shape area of less than 5.2 mm2; in another embodiment, the shape of the secondary channels of the tool, die, piece or mould have a shape area of less than 4.8 mm2; in another embodiment, the shape of the secondary channels of the tool, die, piece or mould have a shape area of less than 4.2 mm2; in another embodiment of the invention, the shape of the secondary channels of the tool, die, piece or mould have a shape area of less than 3.8 mm2; in another embodiment, the shape of the secondary channels of the tool, die, piece or mould is between 7.8 mm2 and 3.8 mm2; in another embodiment, the shape of the secondary channels of the tool, die, piece or mould is between 5.2 mm2 and 3.8 mm2.

In an embodiment, when the section is not constant, the value of the above shape of the secondary channels of the tool, die, piece or mould is referred to the minimum shape of the secondary channel.

In an embodiment, for constant sections of the capillary channels the shape of the capillary channels of the tool, die, piece or mould have a shape area of less than 1.6 mm2; in another embodiment, the shape of the capillary channels of the tool, die, piece or mould have a shape area of less than 1.2 mm2; in another embodiment, the shape of the capillary channels of the tool, die, piece or mould have a shape area of less than 0.8 mm2; in another embodiment, the shape of the capillary channels of the tool, die, piece or mould have a shape area of less than 0.45 mm2; in another embodiment, the shape of the capillary channels of the tool, die, piece or mould have a shape area of less than 0.18 mm2; in another embodiment the shape of the secondary channels of the tool, die, piece or mould is between 1.6 mm2 and 0.18 mm2; in another embodiment, the shape of the capillary channels of the tool, die, piece or mould is between 1.6 mm2 and 0.45 mm2; in another embodiment, the shape of the capillary channels of the tool, die, piece or mould is between 1.2 mm2 and 0.45 mm2.

In an embodiment, when the section is not constant, the value of the above shape of the capillary channels of the tool, die, piece or mould is referred to the minimum shape of the capillary channel.

In the context of the present invention, the equivalent diameter is referred to the equivalent spherical diameter of any other shape, including square, rectangular, oval and half circle shapes among other more complex shapes.

In an embodiment, for other shapes of the secondary channels different from circular shapes and including square, rectangular, oval and half circle shapes among other shapes, the shape of the secondary channels of the tool, die, piece or mould have a shape area of less than 1.4 times the equivalent diameter; in another embodiment of the invention, the shape of the secondary channels of the tool, die, piece or mould have a shape area of less than 0.9 times the equivalent diameter; in another embodiment, the shape of the secondary channels of the tool, die, piece or mould have a shape area of less than 0.7 times the equivalent diameter; in another embodiment, the shape of the secondary channels of the tool, die, piece or mould have a shape area of less than 0.5 times the equivalent diameter; in another embodiment, the shape of the secondary channels of the tool, die, piece or mould have a shape area of less than 0.18 times the equivalent diameter.

In an embodiment the shape of the secondary channels and capillary channels do not have a constant section. In an embodiment of the invention, the secondary channels have a minimum shape and a maximum shape. In an embodiment, the capillary channels have a minimum shape and a maximum shape.

In an embodiment the sum of the minimum shapes of all the capillary channels connected to a secondary channel must be equal to the shape of the secondary channel to which are connected. In another embodiment of the invention the sum of the minimum shapes of all the capillary channels connected to a secondary channel are at least 1.2 times the shape of the secondary channel to which are connected.

In an embodiment the sum of the maximum shapes of all the capillary channels connected to a secondary channel are more than the shape of the secondary channel to which are connected. In another embodiment the sum of the maximum shapes of all the capillary channels connected to a secondary channel are at least 1.2 times the shape of the secondary channel to which are connected.

Any of the above-described embodiments can be combined with any other embodiment herein described in any combination, to the extent that the respective features are not incompatible.

The present invention is also interesting to implement “sweating components”. Those are tools (for example dies) or any other type of component that capitalizes on the heat of evaporation of water to execute a thermal regulation.

In an embodiment, interconnected porosity sweating die (or any other random or determined sweating gland or alike) also made trough Investment Casting may be also comprised in the present invention.

In an embodiment, SnGa specially for Ti base alloys and Al base alloys. Infiltration with a SnGa or AlGa alloy and then liquid phase sintering . . . .

The author has seen, that most of the AM processes and even the not AM manufacturing processes can be advantageously combined for some applications. Especially processes that allow for a low cost construction, which can be combined with higher added value manufacturing processes for highly demanded zones. One such case is the usage of a more or less conventional process like a casting (sand, investment, nano— . . . ), HIP, fast substractive manufacturing process with low cost material, or a lower cost AM method, like one based on the stereo-lithography of particle charged resins or filling with particles of organic material moulds manufactured trough AM or fast near net shape conventional method. To bring the value added material, also conventional methods can be applied like welding based methods (TIG, MIG, plasma, . . . ) or others like cladding, thermal spray, cold spray or similar. Also AM methods can be used being very often the ones with localized material supply often the preferred ones, like the so called Direct Energy Deposition, etc. In some cases the more value added manufacturing process is employed to bring higher added value material or attain a particular microstructure in order to have a specific functionality in some particular areas of the manufactured component (often a tool). This can also sometimes be achieved with localized heat treatments, through induction, laser, etc, superficial treatments (nitriding, carburizing, boridizing, sulfidizing, mixtures thereof, etc.) or thin coatings as described. For some applications the added value manufacturing step might also be incorporated to increase the manufacturing accuracy in certain critical areas so that tighter tolerances can be achieved. When this is the case it is interesting sometimes to have a 3D view or scanning system to be able to evaluate with a closed loop the amounts to be corrected. For some applications it is also interesting to have a system which is simultaneously additive and subtractive so that it can add material and also machine it away with sufficient precision.

A method for producing a die or mold from sintered powder material and having at least one internal channel formed therein for conducting a heat transfer medium into, though, and out of the mold, comprising placing a first layer of sintering powder selected from the group consisting of iron, iron-carbon, copper, copper alloy, tungsten carbide and titanium carbide in a frame, forming a mother mold conforming in size and configuration to a desired mold cavity, forming a pattern of long and slender shape having a desired surface configuration corresponding to that of said internal channel for conducting a heat transfer medium and which complements the surface of the desired mold cavity, said pattern being made of metal infiltrated into the pores of said sintering powder and having a lower melting point than that of said sintering powder, at least partially embedding said mother mold in said layer of sintering powder, adding a second layer of said sintering powder to completely embed the mother mold and separated from the first layer by a demolding agent, completely embedding said pattern in complementary spaced relation in one of said layers of sintering powder so that both ends of said pattern contact with the inside of a wall of said frame, heating said sintering powder, mother mold and pattern to a sintering temperature to sinter said powder and to infiltrate said infiltrated metal of said pattern into said powder, and cooling so as to obtain a hardened, sintered mold separable into two parts along the boundary of said first and second layers and having an internal channel whose configuration complements that of said pattern and the mold cavity.

Also the inventor has seen an alternative way to capitalize the heat of vaporization of a fluid like in the case of the sweating dies, in which a fluid is brought to the Surface trough small wisely placed orifices (the fluid is often water or a water based fluid but could also be another fluid depending on the application). The aim consists on the formation of distributed droplets on the Surface of a die or tool. One way to achieve such effect consists on keeping the die or tool below the dew point and pulverize it with an atomized fluid (for example a water solution) on the working surface before the cooling action of the manufactured component takes place. In some applications the heat input from the component is quite intense and keeping the die or tool below the dew point is not an easy task (it can be achieved with some aggressive cooling strategies like the usage of very close to the surface cooling channels like the capillary system described in this document, where an undercooled fluid is circulated, like Freon or even liquid nitrogen. In some applications it can also be achieved with a severe external cooling action, like spraying of pulverized water to capitalize also in this stage the heat of vaporization of water). The application of a fairly homogeneous layer of fluid droplets on at least part of the working surface can be made in several ways, one of them being the usage of fluid atomizing nozzles. Especially for dies or tools with complex geometries with vertical walls and generally faces with different orientations, sometimes care has to be taken on selecting the size of the fluid droplets to assure their remanence in the desired location. In an embodiment, the way or measuring the size of fluid droplets is by considering them spheres and measuring their diameter. In an embodiment, the size of the fluid droplets is 500 microns or less, in another embodiment 300 microns or less, in another embodiment 150 microns or less, in another embodiment 70 microns or less and even in another embodiment 10 microns or less.

Sometimes it is preferably to have drops with a large size. In an embodiment, the size of the fluid droplets may be 2000 microns or less, in another embodiment 1500 microns or less, in another embodiment 11200 microns or less, in another embodiment 900 microns or less and even in another embodiment 750 microns or less.

In the case of hot stamping proceeding in this way as was the case with the sweating dies, extremely short component cooling times are achievable, which allow even to use different manufacturing techniques than the traditional single step press, being possible to move into multiple step transferized press or even progressive die press systems.

For some applications it is important that the cooling takes place in a set up that constrains the possible undesirable distortions associated to the thermal expansion coefficient of the component being manufactured, and thus the component is kept in some kind of die, tool or shape retainer while being cooled. Some applications have low dimensional accuracy constraints and thus it is not necessary to have shape retention during the cooling step and thus this can be done through direct pulverization on the component (with adequate nozzles or other fluid atomizing system) to promote the cooling of the manufactured component capitalizing the heat of vaporization of the atomized liquid. In another embodiment, fluid droplets can be provided by external methods.

Degradation and failure of structures, tools, die, moulds, pieces or machine part tools represent a huge cost. Material properties play a determinant role in durability of many components, such as tools, dies, moulds or pieces. In an embodiment the technical effects of the above disclosed embodiments include a reduction in cost and long durability of the components due to the properties of the steel used to manufacture the tool, die, piece or mould such as fracture toughness, environmental resistance, corrosion resistance, stress corrosion cracking resistance, mechanical strength, and/or wear resistance. In several embodiments, the invention also provides a reduction in the time spent on cooling which would drastically increase the production rate as well as reduce costs.

Hot stamping is understood as a manufacturing process for parts or components, wherein the material of the part to be formed is heated in some way (in the industrial slang sometimes referred to semi-hot stamping depending on temperature) and shaped, usually with a parent or tool and sometimes with the help of a fluid, and simultaneously and/or after the part is later cooled.

In the case of hot-stamping steel sheet, direct cooling with water is reported in JP2014079790, but the system does not have good control over the amount of water supplied. In fact, it has been reported its use with 22MnB5 plates, where a deterioration of elongation at break (fracture strain) has also been reported with this type of sheets when cooling is directly carried out with abundant water. It has been surprisingly observed that for the present invention the elongation values do not decrease that much if the intensity of cooling is properly controlled. Steel sheets alloyed with boron that are capable of exhibiting superior mechanical strength (typically >1750 MPa and even substantially above 2000 MPa) benefit even more from the present invention because of their peculiar termperability.

The present invention even allows to change the system for obtaining hot stamped parts sheet metal, and this change in strategy is an invention itself since it is not reported in the state of the prior art. In this sense, it is possible in the present invention to make hot stamping with a system of progressive die or transfer press (in fact with any system that allows the use of more than one station die where the piece produced moves from one station to the next).

In an embodiment, the method of the present invention allows changing the strategy for obtaining hot stamped sheet metal parts.

In an embodiment the present invention allows manufacturing a die capable of carrying out an enhanced heating or cooling.

For some applications, it is preferable to heat outside the sequence of dies and start the sequence with one or more forming stations.

In an embodiment, the sequence of dies is heated outside the system.

For other applications, it is interesting to initially have heated stations of the format (generally rapid heating is preferred to be integrated into the system as transfert or progressive induction, intense radiation, the conductive heating, microwave heating . . . ).

In an embodiment, initial heating systems are included in the manufacturing system.

For some pre- or post-heating applications, it is desirable to have a conditioning station format (stamping, marking, positioning, forming small, . . . ).

In an embodiment, a conditioning station format is included in the manufacturing system.

For some applications, it is desirable that the shaping sequences, or at least some of them take place at the highest possible temperature of the sheet, so it may be convenient to take appropriate measures to prevent excessive cooling of the sheet to the greatest extent possible in these stages or even increase the temperature if possible (heating array, radiation shields, . . . ) (for some applications it is desirable that any shaping step includes punching operations).

In an embodiment, the shaping or shaping sequences take place at the highest temperature of the sheet.

In another embodiment, the method of the present invention considers appropriate measures for preventing excessive cooling.

In another embodiment, these measures even consider increasing the temperature of the sheet.

After the shaping steps for some applications it is desirable to arrange the stages of controlled cooling where they often use one or more arrays that are at least partially dies that perspire (sweat/perspire).

In an embodiment, dies that partially perspire are used in the cooling stage.

For some applications, it is desirable to have later stages of temperature maintenance to perform an interrupted quenching or to perform temperings at least partially in the component (the heating can be done in any way but each application has a more advantageous form of heating, some of the most typical are: induction, convection, radiation, contact with little conductive or heated die, conduction or other heating based on the Joule effect, microwave, etc. Also for some applications it is desirable to have final stages dies.

In an embodiment, a stage of temperature maintenance for tempering or partial tempering the component is included after the forming stage.

In an embodiment, a stage of temperature maintenance for quenching or partial quenching the component is included after the forming stage.

In an embodiment, a hardening or partial hardening of the component is included after the shaping stage at temperatures above 60° C., in other embodiments at temperatures above 120° C., in another embodiment at temperatures above 220° C., and even in another embodiment at temperatures above 460° C.

In another embodiment, heating can be carried out by induction to temperatures above 460° C., in another embodiment to temperatures above 508° C., in another embodiment to temperatures above 555° C., in another embodiment to temperatures above 660° C., in another embodiment to temperatures above 710° C.

In another embodiment, heating can be carried out by convection to temperatures above 460° C., in another embodiment to temperatures above 508° C., in another embodiment to temperatures above 555° C., in another embodiment to temperatures above 660° C., in another embodiment to temperatures above 710° C.

In another embodiment, heating can be carried out by radiation to temperatures above 460° C., in another embodiment to temperatures above 508° C., in another embodiment to temperatures above 555° C., in another embodiment to temperatures above 660° C., in another embodiment to temperatures above 710° C.

In another embodiment, heating can be carried out by little conductive or heated die to temperatures above 460° C., in another embodiment to temperatures above 508° C., in another embodiment to temperatures above 555° C., in another embodiment to temperatures above 660° C., in another embodiment to temperatures above 710° C.

In another embodiment, heating can be carried out by any process based in the Joule effect to temperatures above 460° C., in another embodiment to temperatures above 508° C., in another embodiment to temperatures above 555° C., in another embodiment to temperatures above 660° C., in another embodiment to temperatures above 710° C.

In another embodiment, heating can be carried out by microwave to temperatures above 460° C., in another embodiment to temperatures above 508° C., in another embodiment to temperatures above 555° C., in another embodiment to temperatures above 660° C., in another embodiment to temperatures above 710° C.

There are several other applications (including even hot stamping sheet metal with conventional dies) that can benefit from being able to have a die that allows for interrupted quenching and/or at least tempers local and/or partial in manufactured components.

In an embodiment, the die manufacture with the present method allows interrupted quenching and/or at least local tempers and/or partial tempers in manufactured components.

The present invention, with the various implementations explained in the preceding and following paragraphs, allows thermoregulation very accurate, which can be helpful in some applications to obtain components with different properties in different areas (“Tailored components”). This can be obtained intensity gradients often with cooling in different areas, or by partial heating. The shaping dies can be arrays that sweat only in the geometry part to be shaped, while other areas may have little conductive material inserts, heated areas, intensification inserts of radiation, etc.

In an embodiment, the dies manufactured with the present invention allows a very accurate thermoregulation.

In another embodiment, the dies manufactured with the present invention allows obtaining components with different properties in different areas (“Tailored components”).

In another embodiment, the dies obtained with the present method allows obtaining intensity gradients often with cooling in different areas, or by partial heating.

In another embodiment the shaping dies manufactured with the present invention allows obtaining arrays that perspire only in a certain geometry of the part to be shaped.

Most strategies described herein are combinable between them, unless otherwise indicated.

Another possible implementation of the present invention is to have neighboring areas with different temperature adjustments (or thermo-regulations), i.e. to have near areas in the component that are cooled with very different intensity or are heated with different intensity or some areas that are heated while others are cooled.

In an embodiment, the method of the present invention allows thermo-regulations of near areas.

Thermoregulation both in the sense of cooling and heating can be carried out by exchanging heat with a fluid flowing through predetermined channels (which may be made in different ways as described herein or in any other way).

In an embodiment, the method of the present invention allows performing thermo-regulation by means of channels.

In another embodiment, the channels in the thermo-regulation system may allow a fluid to flow.

In another embodiment, the fluid in the channels may flow in such a way the Reynolds of the flux is above 2800, in another embodiment above 4200, in another embodiment above 12000, and even in another embodiment above 22000.

In an embodiment, a high speed of the fluid in the channel may be beneficial to thermo-regulation. In that case, the average speed of the fluid in the channels may be higher than 0.7 m/s, in another embodiment higher than 1.6 m/s, in another embodiment higher than 2.2 m/s, in another embodiment higher than 3.5 m/s and even in another embodiment higher than 5.6 m/s.

In an embodiment, a high speed of the fluid in the channel may be detrimental to thermo-regulation. In that case, the average speed of the fluid in the channels may be lower than 14 m/s, in another embodiment lower than 9 m/s, in another embodiment lower than 4.9 m/s, and even in another embodiment lower than 3.9 m/s.

Heating be can also carried out by conduction (or any other system based on the Joule effect) or by induction with inserted or embedded coils (or any system based on eddy currents), or by radiation, among others.

In an embodiment, the method of the present invention allows performing thermo-regulation by means of a heat & cool technology as defined elsewhere in this document.

The fact of having heating and cooling areas very close to each other (which is sometimes technically known as heat & cool in this document) can be capitalized for many applications. An illustrative example of an application that may capitalize the heat & cool technique is where the area and/or surface of a component has to be cooled and heated at different time intervals, so in this case is convenient to have cooling channels next to those for heating in order to activate cooling and heating alternately.

In an embodiment, the method of the present invention allows having heating and cooling areas very close to each other.

In another embodiment, the method of the present invention allows having heating and cooling areas very close to each other at different time intervals.

In an embodiment, the method of the present invention allows activating cooling and heating alternatively.

In another embodiment, the method of the present invention allows activating cooling and heating alternatively by placing heating and cooling channels close to each other.

If cooling or heating is carried out using a fluid, it is interesting that the heat capacity of the fluid is not excessive so when its circulation stops, the thermo-regulation of the system in the opposite sense does not become difficult. Another illustrative example may be for components subjected to thermal stresses (particularly thermal fatigue or thermal shock). These stresses are generated by the temperature gradient between two adjacent areas due to the limited thermal conductivity of the material, the nonzero thermal expansion coefficient, and the nonzero elastic modulus that induce stresses in the component. The thermal gradients in the surrounding areas from the application of the component may be reduced through the active counteract of the gradient by heating the cold zone and/or cooling the hot.

In an embodiment, the method of the present invention allows counteracting thermal stresses caused by thermal gradients.

In another embodiment, thermal gradients are counteracted by heating a cold zone.

In another embodiment, thermal gradients are counteracted by cooling a hot zone.

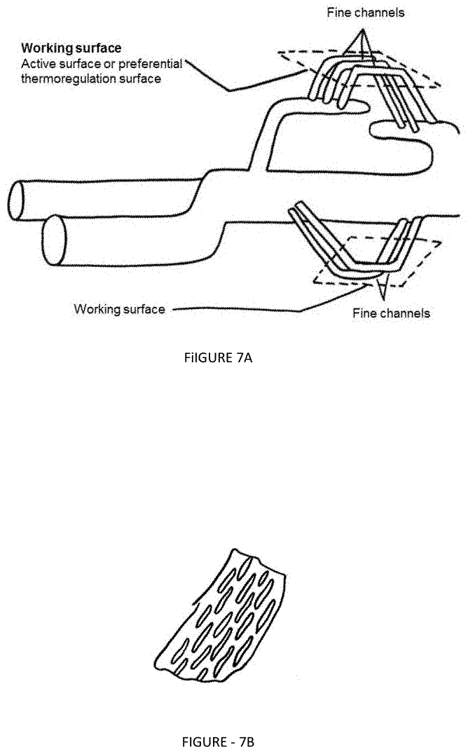

The present implementation of the heat & cool technology may be implemented in several ways. In order to ease the understanding FIG. 7 present a schematic representation, however these schematics are in any case a representation of all possible implementations or necessarily the most common way to implement the implementation of this invention. A schematic representation can be seen in FIG. 7A, where an active surface is intended to heat and cool in short consecutive periods, the representation corresponds to a cross section so that the active surface is reduced to a line. For this purpose, two circuits close to the surface of interest and close to each other are arranged, alternatively a branch of each circuit can be observed (for better understanding these are painted differently).

In an embodiment, the method of the present invention allows manufacturing a cooling circuit that includes a capillary system.

In another embodiment, the method of the present invention allows manufacturing a cooling circuit that includes a capillary system that uses a cooling fluid.

In another embodiment, the thermal inertia of the capillary cooling circuit can be minimized by optimizing its design.

The cooling circuit may have several implementations, including a capillary system as described in an earlier implementation of the invention, but in this case a cooling fluid with moderate specific heat and not too high density is often chosen in order to have a low thermal inertia, alternatively this effect can be minimized through design.

In an embodiment, the method of the present invention allows manufacturing a heating circuit that includes a capillary system using channels.

In another embodiment, the method of the present invention allows manufacturing a capillary heating system that uses channels with a circulating hot fluid.

In another embodiment, the method of the present invention allows manufacturing a capillary heating circuit that uses resistive heating.

In another embodiment, the method of the present invention allows manufacturing a capillary heating circuit that uses conductive heating.

In another embodiment, the method of the present invention allows manufacturing a capillary heating circuit that uses Eddy currents.

In another embodiment, the method of the present invention allows manufacturing a capillary heating circuit that uses radiation.

In the heating circuit the implementation possibilities are even greater, from channels with a fluid as described in the case of cooling circuits but in this case with a hot fluid to different types of resistive, conductive heating, Eddy currents based heating and even radiation (although the schematic representation in this case is usually different), etc.

In an embodiment, the method of the present invention compensates thermal stresses by regulating the flows of heat or thermal gradients through the depth of the component.

In another embodiment, the method of the present invention controls cooling of another component at the active surface by regulating the flows of heat or thermal gradients through the depth of the component.

In the case in which thermal stresses are tried to be compensated and/or for cases where a controlled cooling of another component of the active surface is attempted to be implemented, it is interesting to be able to regulate the flows of heat and/or thermal gradients through the depth of the component and not just at a surface level, FIG. 7B shows a schematic representation for better understanding of a possible implementation. In this representation, the elements for cooling and heating at different distances from the surface of interest can be seen.

In an embodiment, the method of the present invention considers acting against the thermal stress caused by hot liquid aluminum on the aluminum surface during injection molding by heating the inside quickly.

Illustratively, this surface of interest could be the surface of an injection mold where the aluminum surface is heated by the bump of liquid aluminum in the injection phase. The surface is rapidly heated by effect of contact with liquid aluminum and radiation. Due to the limited conductivity of the matrix material, the matrix material below the surface is not heated as fast as the surface itself and due to the thermal expansion coefficient and elastic modulus, compressive stresses are generated on the surface. These stresses can be reduced by acting against this thermal gradient from the surface of the material to its inside by heating it quickly.

In an embodiment, the method of the present invention considers acting against the thermal stress caused during the external cooling of the die by cooling the inside of the material using the configuration of the present invention.

Also in the process of external cooling of the matrix by spraying water, the surface cools while the interior is warm and for the same reasons stated above stresses are generated, in this case of traction type, on the material surface, which may be decreased by acting on the gradient through cooling the inside of the material. This happens in virtually all components subjected to thermal shock and/or thermal fatigue or generally to any sudden change in temperature in an active surface (which may be outside or inside) or area of the component.

In an embodiment, the method of the present invention considers cooling a minimum rectangle section containing a channel or device of cooling.

In another embodiment, the method of the present invention considers heating a minimum rectangle section containing a channel or device of heating.

In this section, when referring to the possibility of cooling and heating in a small area or surrounding areas, the magnitude of proximity depends on the particular application. It has been found that for some applications it is desirable to measure this proximity with the minimum rectangle section containing a channel or device for cooling and a channel or device for heating.

In an embodiment, the minimum rectangle has an area of 18000 mm2 or less, in another embodiment 950 mm2 or less, in another embodiment less than 90 mm2, and even in another embodiment 18 mm2 or less.

It has been found that for some applications it is desirable that this minimum rectangle has an area of 18000 mm2 or less, preferably 950 mm2 or less, more preferably less than 90 mm2, and even 18 mm2 or less.

In an embodiment, the minimum distance between a heating or cooling element with respect the active surface is 98 mm or less, in another embodiment 18 mm or less, in another embodiment 8 mm or less, in another embodiment 4 mm or less, and even in another embodiment 1 mm or less.

For some applications, it is interesting that the minimum distance between a heating or cooling element with respect the active surface is 98 mm or less, preferably 18 mm or less, more preferably 8 mm or less and even 4 mm or less.

In an embodiment, the distance between elements with the same function (cooling or heating) have a minimum distance (between all cross sections) of 48 mm or less, in another embodiment less than 18 mm, in another embodiment less than 8 mm, in another embodiment less than 2 mm and even in another embodiment 1 mm or less.

For some applications, it is interesting that the distance between elements with the same function (cooling or heating) have a minimum distance (between all cross sections) of 48 mm or less, preferably less than 18 mm, more preferably less than 8 mm and even less than 2 mm.

In an embodiment, the distance between elements with opposite objectives (heating vs. cooling) have a minimum distance (between all cross sections) of 48 mm or less, in another embodiment less than 18 mm, in another embodiment less than 8 mm, in another embodiment 2 mm or less, in another embodiment 1.8 mm or less and even in another embodiment 0.8 mm or less.

For some applications, it is interesting that the distance between elements with opposite objectives (heating vs. cooling) have a minimum distance (between all cross sections) of 48 mm or less, preferably less than 18 mm, more preferably less than 8 mm and even 2 mm or less.

In an embodiment, the method of the present invention considers having a quenching system with a small ability for storing heat.

In another embodiment, the method of the present invention considers having a quenching system with a great ability for storing heat.

In another embodiment, the method of the present invention considers having a heating circuit with a small ability for storing heat.

In another embodiment, the method of the present invention considers having a heating circuit with a great ability for storing heat.

For some applications, it is interesting that the ability of the fluid to store heat in the quenching system (usually for cooling circuits but sometimes also for the heating circuits when this is done with a fluid), is small (there are applications that require fair otherwise).

In an embodiment, the method of the present invention considers having a R parameter of less than 9.8 MJ/(m3*K), preferably less than 4.9 MJ/(m3*K), more preferably less than 3.8 MJ/(m3*K) and even less than 1.9 MJ/(m3*K), where R=Ce*Ro; Ce=Specific heat at constant volume and Ro=density both at room temperature (throughout the document if the measurements of the properties indicated otherwise are made at room temperature following the definition of the International System).

If we define the parameter R=Ce*Ro where: Ce=Specific heat at constant volume and Ro=density both at room temperature (throughout the document if the measurements of the properties indicated otherwise are made at room temperature following the definition of the International System). For some applications it is interesting that R is less than 9.8 MJ/(m3*K), preferably less than 4.9 MJ/(m3*K), more preferably less than 3.8 MJ/(m3*K) and even less than 1.9 MJ/(m3*K).

In an embodiment, the method of the present invention comprises recovering the quenching capacity of the circuit by stopping and activating the cycles of cooling and heating.

In another embodiment, when the cycles of cooling and heating are carried out with a fluid, the method of the present invention comprises stopping the circulation of the fluid.

In another embodiment when the circulation fluid is stopped the other fluid may not have much energy to be quenched before being re-flowed for recovering the quenching capacity of the circuit.

In some applications, when the cycles of cooling and heating are carried out with a fluid, it is convenient to stop the circulation of the fluid having the opposite sought effect in a given cycle and it is desirable that the fluid that is not flowing does not need much energy to be quenched and to start the opposite cycle when the fluid is re-flowed again and the quenching capacity of the circuit is recovered.

In an embodiment, the method of the present invention comprises a rapid cooling of an area of a component in the heat & cool system.

In another embodiment, the method of the present invention comprises a rapid cooling of an active surface of a component in the heat & cool system.

In another embodiment, the method of the present invention comprises a rapid cooling of an area of a component in the heat & cool system and maintaining that temperature.

In another embodiment, the method of the present invention comprises a rapid cooling of an active surface of a component in the heat & cool system and maintaining that temperature.

In another embodiment, the method of the present invention comprises a slow cooling of an area of a component in the heat & cool system.

In another embodiment, the method of the present invention comprises a slow cooling of an active surface of a component in the heat & cool system.

In another embodiment, the method of the present invention comprises a slow cooling of an area of a component in the heat & cool system and maintaining that temperature.

In another embodiment, the method of the present invention comprises a slow cooling of an active surface of a component in the heat & cool system and maintaining that temperature.

For some applications, it has been found that it is interesting that the heat & cool system allows rapid cooling of an area or active surface of a component to a certain temperature and then maintained this temperature or allow a slow cooling.

In an embodiment, the method comprises having a temperature of rapid cooling of 52° C. or higher, in another embodiment 110° C. or higher, in another embodiment 270° C. or higher and even in another embodiment 510° C. or higher.

For some applications, it is interesting that the temperature of rapid cooling is 52° C. or higher, preferably 110° C. or higher, more preferably 270° C. or higher and even 510° C. or higher.

In an embodiment, the method of the present invention comprises capitalizing the flexibility in the design for heat & cool implementations.

In another embodiment, the method of the present invention comprises capitalizing the flexibility in the design for heat & cool implementations using circuits with circulating fluids.

In an embodiment, the method of the present invention comprises capitalizing the flexibility in the design for heat & cool implementations using circuits with cryogenic fluids.

In an embodiment, the method of the present invention comprises capitalizing the flexibility in the design for heat & cool implementations using circuits with cold fluids.

In an embodiment, the method of the present invention comprises capitalizing the flexibility in the design for heat & cool implementations using circuits with warm fluids.

In an embodiment, the method of the present invention comprises capitalizing the flexibility in the design for heat & cool implementations using circuits with hot fluids.

In an embodiment, the method of the present invention comprises capitalizing the flexibility in the design for heat & cool implementations using circuits with very hot fluids.

In another embodiment, the method of the present invention comprises capitalizing the flexibility in the design for heat & cool implementations using other possible thermoregulation strategies.

One of the advantages of some of the implementations of the present invention is the great flexibility in the design, which can be capitalized to heat & cool implementation in the manner described for circuits with circulating fluids (cryogenic, cold, warm, hot and/or very hot), but also for other possible thermoregulation strategies.

In an embodiment, the method of the present invention comprises thermoregulation strategies that can be tailored made.

In an embodiment, the method of the present invention comprises thermoregulation strategies that can be tailored made with coils and complex geometries.

In an embodiment, the method of the present invention comprises thermoregulation strategies that can be tailored made with coils and complex geometries distributed in a certain area of interest.

In an embodiment, the method of the present invention comprises thermoregulation strategies that can be tailored made with resistive heating elements and complex geometries.

In an embodiment, the method of the present invention comprises thermoregulation strategies that can be tailored made with resistive heating elements and complex geometries distributed in a certain area of interest.

In this sense the strategies can be tailored made, with coils or resistive heating elements with complex geometries and also well distributed in a certain area of interest.

In an embodiment, the method of the present invention comprises having a not excessive minimum distance between circuits with the same purpose in an orthogonal direction to the active surface of the component.

In another embodiment, the minimum distance between circuits with the same purpose in an orthogonal direction to the active surface of the component is 48 mm or less, in another embodiment less than 18 mm, in another embodiment less than 8 mm and even in another embodiment less than 1.8 mm.

It has been found that for some applications it is desirable that the minimum distance between circuits with the same purpose in an orthogonal direction to the active surface of the component of interest is not excessive. For these applications, it is often desirable a distance of 48 mm or less, preferably less than 18 mm, more preferably less than 8 mm and even less than 1.8 mm.

In an embodiment, the method of the present invention comprises the ability of the internal circuitry to compensate an external gradient of 26° C. or more, in another embodiment 52° C. or more, in another embodiment 110° C. or more, and even in another embodiment 210° C. or more.

For some applications, it is interesting the ability of the internal circuitry to compensate an external gradient of 26° C. or more, preferably 52° C. or more, more preferably 110° C. or more, and even 210° C. or more.

In an embodiment, the method of the present invention comprises having differences of temperatures in the near area (near area previously defined as the minimum rectangle) up to 52° C. or more, in another embodiment up to 110° C. or more, in another embodiment up to 260° C. or more and in another embodiment, even up to 510° C. or more.

For some applications, it is interesting that in a near area (near area previously defined as the minimum rectangle) the differences of temperatures may be up to 52° C. or more, preferably up to 110° C. or more, more preferably up to 260° C. or more and even up to 510° C. or more.

In an embodiment, the method of the present invention comprises optimized strategies for implementing heating elements.

In an embodiment, the method of the present invention comprises embedding heating elements.

The heating elements may be implemented in various ways as already indicated. Thanks to the great design flexibility, optimized strategies may be implemented very locally. Also in reference on how to build or locate these heating elements in the component there are plenty of ways or systems, and an exhaustive list is not going to be made. For an exemplary purpose, in this paragraph a couple of possible implementations are presented. One possible implementation is the embedded, that means that voids in the component are left on purpose in order to place the heating elements.

In an embodiment, the method of the present invention comprises the “in-situ” construction of heating elements.

In an embodiment, the method of the present invention comprises shaping an internal structure for containing the heating elements.

In another embodiment, the method of the present invention comprises shaping an internal structure with the shape of a channel for containing the heating elements.

In another embodiment, the method of the present invention comprises shaping an internal structure with the shape of a coil for containing the heating elements.

In an embodiment, the method of the present invention comprises shaping an internal structure coated with an electrically insulating material for containing the heating elements.

In another embodiment, the method of the present invention comprises shaping an internal structure with the shape of a channel coated with an electrically insulating material for containing the heating elements.

In another embodiment, the method of the present invention comprises leaving an internal structure with the shape of a coil coated with an electrically insulating for containing the heating element.

In an embodiment, the method of the present invention comprises shaping an internal structure for the heating elements and filling it with a conductive metal.

In an embodiment, the method of the present invention comprises shaping an internal structure for the heating elements and filling it with a conductive metal introduced in liquid form.

In an embodiment, the method of the present invention comprises shaping an internal structure for the heating elements and filling with it a conductive metal introduced as particulates.

In an embodiment, the method of the present invention comprises shaping an internal structure for the heating elements and filling it with a conductive metal introduced as embedded particulates.

In an embodiment, the method of the present invention comprises shaping an internal structure for the heating elements and filling it with a conductive metal introduced as particulates in suspension.

In an embodiment, the method of the present invention comprises shaping an internal structure for the heating elements and filling it with a high conductivity metal alloy.

In an embodiment, the method of the present invention comprises shaping an internal structure for the heating elements and filling it with a low melting metal alloy.

Another possible implementation is the “in-situ” construction, for example leaving an internal structure with the shape of a channel, coil, etc., which may be or not coated internally with an electrically insulating material among other alternative methods by circulation of the desired material (resins suspension with ceramic particles, . . . ) and often using some type of curing and finally filling with a conductive metal that can be introduced as liquid, particulates (embedded or not in a suspension, etc.), or otherwise (any metal alloy but it often high conductivity alloys based Cu, Al, Ag, etc., or alloys of low melting base Ga, Bi, Sn, . . . are used). As above mentioned, the list of possible implementations in this regard it is extremely extensive, so it is not necessary to enumerate in detail.

In an embodiment, the method of the present invention comprises the use of the heat & cool technology for manufacturing tools.

The heat & cool technology is especially interesting for the manufacture of tools (molds, dies, . . . ).

In an embodiment, the method of the present invention comprises minimizing the amount of material employed in the manufacturing of tools.

When using some of the technologies of the present invention for the construction of tools (molds, dies, punches, cutting tools, etc.), and for most components in which the material used is of high-cost, it becomes economically interesting to try to minimize the amount of material employed, although the mold made by AM is more complex and even when the mold have more material than the filling itself.

In this regard, for some applications, it is interesting to obtain light constructions in order to save material. Sometimes the material itself is not too expensive but it is the morphology in which the particles must be used and the strict morphological requirements such as sphericity, narrow particle size distribution which may be mono-modal, bimodal or polymodal.

In an embodiment, the method of the present invention comprises minimizing the amount of material employed in the manufacturing of tools by using finite element programs.

In another embodiment, the method of the present invention comprises minimizing the amount of material employed in the manufacturing of tools by using algorithms for topology optimization.

For lightweight construction, finite element programs and algorithms for topology optimization are often used. Bionics optimization may be also of aid for reducing the amount of material used. In order to achieve that complex systems withstand the loads for some components, also in the case of some tools, it is common to use ribbings, casts, braces, etc. to reduce the weight and thus the amount of material used.

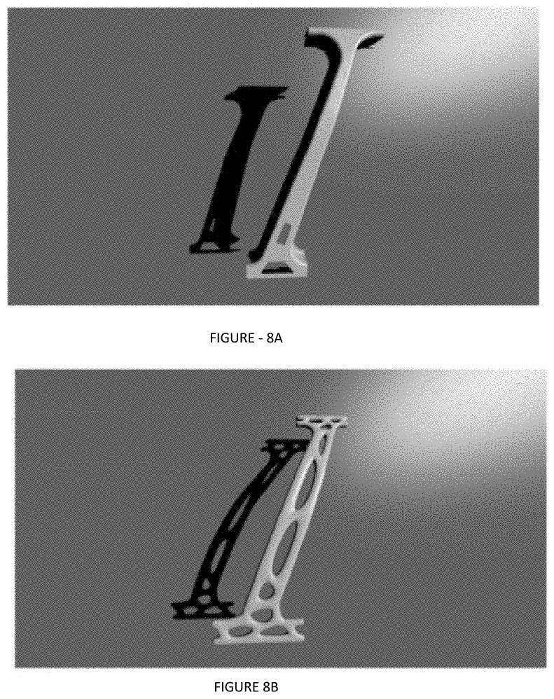

In order to ease clarification in this aspect, FIG. 8A show a design of a B-pillar manufactured by conventional methods and FIG. 8B shows the same design of B-pillar following the topological optimization included in the method of the present invention. As it can be seen, a significant weight reduction on the component may be achieved by the method of the present invention.

In an embodiment, the method of the present invention comprises the construction of tubular sections with different types of section and not very thick walls for transporting fluids through areas that from the point of view of mechanical, thermal and/or tribological loads may be hollow.

In another embodiment, the average thickness of walls in tubular sections for fluid transport in unfilled material areas is 98 mm thick or less, in another embodiment less than 18 mm, in another embodiment less than 4 mm and even in another embodiment less than 1.8 mm.

A particularly interesting case occurs in the transport of a fluid, which is often useful in the present invention to construct tubular sections with different types of section and not very thick walls to transport fluids through areas that from the point of view of mechanical, thermal and/or tribological loads may be empty. It has been found that for some applications it is desirable that the average thickness of the walls of the tubular sections of fluid transport in unfilled material areas is 98 mm thick or less, preferably less than 18 mm, more preferably less than 4 mm and even less than 1.8 mm.

In an embodiment, the method of the present invention comprises reducing the weight of a component for economic viability.

In another embodiment, the method of the present invention comprises reducing the weight of a component in cases in which the costs of conventional manufacturing methods for removing the weight are higher than those for obtaining a lightweight component.

In another embodiment, the method of the present invention comprises a component that is 1/1.5 or less the weight of the component obtained with the most economical manufacture process, in another embodiment less than ½, in another embodiment less than ⅓ and even in another embodiment less than 1/4.5.

For some applications where it is vital for the economic viability of the component made to reduce weight and also in the case of tools and other components in which the cost of the conventional manufacturing used for removing weight is not justified by the possible advantages of obtaining a lighter component. For some applications of this type it is desirable that when using the present invention, the component is 1/1.5 or less the weight of the component obtained with the most economical manufacture process, preferably less than ½, more preferably less than ⅓ and even less than 1/4.5.

In an embodiment, the method of the present invention comprises a die component with large hollows and tubular conductions for fluids in hollow zones.

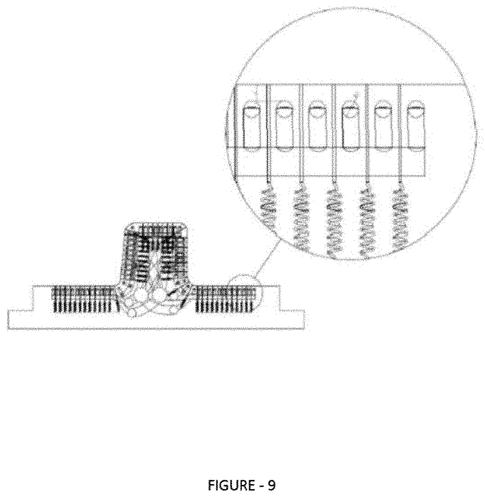

In an embodiment, the method of the present invention comprises a mold with large hollows and tubular conductions of fluids in hollow zones. In order to present an illustrative example of a possible schematic representation, FIG. 9 presents a die component or mould with large hollows and tubular conductions of fluids in hollow zones.

Sometimes the final geometry resembles that of what would be used if the component was obtained by casting, but with thinner walls, more intricate or more severe casting details. The castings may be also conducted by a high level of detail in very small components such as cutting punches, small slides, ejectors, cores, etc.

In an embodiment, the method of the present invention comprises shaping a component with severe casting details.

In another embodiment, the method of the present invention comprises shaping a component with a volume filled with only 74% or less, in another embodiment 48% or less, in another embodiment 28% or less and in another embodiment even 18% or less compared with the minimum hexahedron that contains the component.

For some applications it is important that casting is very severe, being desirable that compared with the minimum hexahedron that contains the component only 74% or less of the volume is filled, preferably 48% or less, more preferably 28% or less and even 18% or less.

In an embodiment, the method of the present invention comprises excluding the active surface of a component.

In another embodiment, the method of the present invention comprises including only the material contained in the minimum hexahedron that contains the component.

In another embodiment, the method of the present invention comprises excluding the maximum volume generated by the active surface and a plane that cuts it.

For some applications, it is desirable to exclude the active surface, taking into account only the material contained in the minimum hexahedron that contains the component and excluding the maximum volume generated by the active surface and a plane that cuts it.

In an embodiment, the method of the present invention comprises having intermediate steps in the manufacture of components.

In another embodiment, the method of the present invention comprises introducing a polymerizable resin with particles in suspension into the mold made by additive manufacturing.

In another embodiment, the method comprises removing the polymerizable resin by pyrolysis.

In another embodiment, the method comprises removing the polymerizable resin by dissolution.

In another embodiment, the method comprises removing the polymerizable resin by etching.

In another embodiment, the method of the present invention comprises evacuating the mold as a first step in order to reduce internal porosity.

In another embodiment, the method of the present invention comprises evacuating the mold as a first step and simultaneously filling it with a resin loaded with particles in suspension.

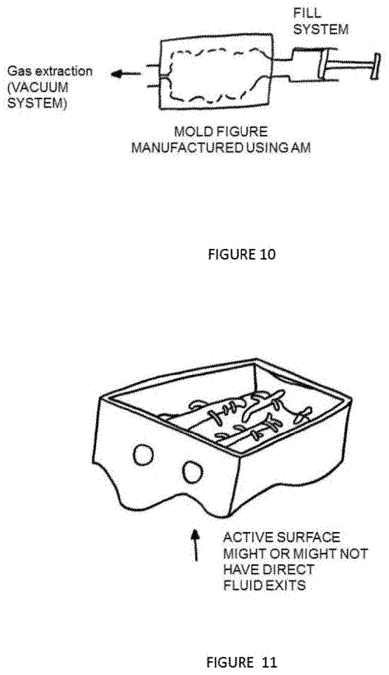

For some components it is interesting to have one or more intermediate steps. An example of an intermediate step is the introduction into the mold made by AM of a polymerizable resin containing in suspension the particles of interest, instead of directly introducing the particles as in previous cases. The resin can be removed at a later stage by pyrolysis, dissolution, etching . . . . It has been seen that in such cases it is difficult to get a component without too many internal porosities and a way to achieve this is through evacuating the mold as a first step and/or simultaneously filling it with the resin loaded with particles in suspension. A schematic representation, for illustrative purposes, can be seen in FIG. 10.

In an embodiment, the method of the present invention comprises having particles with a low melting point in order to ease the removal of gases from pyrolysis of the organic component.

In an embodiment, the method of the present invention comprises having particles with a low melting point in order to ease the removal of gases from pyrolysis of the resin.

Although in this case it is easier to achieve more complex geometries by destroying the AM mold and subsequently eliminate the resin by pyrolysis before sintering the particles using a bed of particles or sand to preserve the geometry of interest among degradation points of the resin or other organic component and sintering, it is often desirable to have particles of low melting point to ease strategies that allow removing gases from pyrolysis of the resin or other organic component (and allow destruction of the AM mold at the same time).

In an embodiment, the method of the present invention may include a post-processing.

In another embodiment, the post-processing may be a surface conditioning method.

In another embodiment, the post-processing may be electro-chemical polishing.

In another embodiment, the post-processing may be tribo-mechanical polishing.

In another embodiment, the post-processing may be machining.

In another embodiment, the post-processing may be blasting.

In another embodiment, the post-processing may be a mass thermal treatment.

In another embodiment, the post-processing may be a surface thermal treatment.

For all components manufactured according to the present invention it may be of interest for some applications to use a post-processing. The post-processing applied can be very diverse, from surface conditionings (polished electro-chemical, tribo-mechanical or any other combination, machined, blasted, . . . ), to mass or surface thermal treatments, coatings, etc.

In an embodiment, the method of the present invention comprises coating as post-processing.

In another embodiment, this coating may be soft.

In another embodiment, this coating may be an electro-chemical soft coating.

In another embodiment, this coating may be a liquid bath soft coating.

In another embodiment this coating may be hard.

In another embodiment, this coating may be a thermal projection.

In another embodiment, this coating may be a kinetic projection.

In another embodiment, this coating may be a hook friction.

In another embodiment, this coating may be a diffusion.

In another embodiment, this coating may be a PVD.

In another embodiment, this coating may be a diffusion.

In another embodiment, this coating may be a CVD.

In another embodiment, this coating may be vapor deposited.

In another embodiment, this coating may be plasma deposited.

In another embodiment, this post-processing may be any technology that allows to change the surface functionality of the component in any way that may be of interest to a particular application.

In another embodiment this coating may be of a single nature.

In another embodiment, this coating may be of a composite nature.

Any type of coating may be of interest for a particular application, because the coating layer itself can have a great impact on the component's functionality. All the technology of thin film developed so far and that to be developed is applicable. Without any intention of drawing up an exhaustive list but to provide some illustrative examples it is worth to mention the mainly soft coatings of the electrochemical type, liquid bath, etc.; coatings that can be both soft and hard: thermal projections, kinetic projections (cold spray, . . . ), hooks friction, diffusion or other technologies; coatings that are mostly hard such as

PVD, CVD, and other vapor or plasma. Any other technology that allow to change the surface functionality of the component in any way that may be of interest to a particular application. The coating may be of any singular or composite nature.

In an embodiment, the method of the present invention comprises a densification mechanism. In another embodiment, the method of the present invention comprises using hard particles.

In another embodiment, the volume of hard particles is 2% or more, in another embodiment 5.5% or more, in another embodiment 11% or more or even in another embodiment 22% or more.

In another embodiment, the method of the present invention comprises using reinforcement fibers.

In another embodiment, the volume of reinforcement fibers is 2% or more, in another embodiment 5.5% or more, in another embodiment 11% or more or even in another embodiment 22% or more.

Due to the densification mechanism often employed in the present invention, it is interesting for various applications to use hard particles or reinforcement fibers to confer a specific tribological behavior and/or to increase the mechanical properties. In this sense some applications benefit from the use of 2% by volume or more reinforcement particle, in another embodiment 5.5% or more, in another embodiment 11% or more or even in another embodiment 22% or more.

In an embodiment, hard particles may be introduced separately.

In another embodiment, hard particles may be introduced embedded in another phase.

In another embodiment, hard particles may be synthesized during the process.

In another embodiment, the method of the present invention comprises introducing particles with a hardness of 11 GPa or more, in another embodiment 21 GPa or more, in another embodiment 26 GPa or more, and even in another embodiment 36 GPa or more.

In another embodiment, the method of the present invention comprises including particles as that have a positive effect on mechanical properties as reinforcement.

In another embodiment, the method of the present invention comprises adding fibers.

In another embodiment, the method of the present invention comprises adding glass fibers.

In another embodiment, the method of the present invention comprises adding carbon fibers.

In another embodiment, the method of the present invention comprises adding wiskers.

In another embodiment, the method of the present invention comprises adding nanotubes.

These reinforcing particles may not be necessarily introduced separately; they can be embedded in another phase or can be synthesized during the process. Typical reinforcing particles are particles high hardness such as diamond, cubic boron nitride (cBN), oxides (aluminum, zirconium, iron, etc.), nitrides (titanium, vanadium, chromium, molybdenum, etc.), carbides (titanium, vanadium, tungsten, iron, etc.), borides (titanium, vanadium, etc.) mixtures thereof and generally any particle with a hardness of 11 GPa or more, preferably 21 GPa or more, more preferably 26 GPa or more, and even 36 GPa or more. On the other hand, mainly in applications that benefit from increased mechanical properties, they can be used as reinforcing particles, any particle which is known which can have a positive effect on the mechanical properties as fibers (glass, carbon, etc.), wiskers, nanotubes, etc.

All the above embodiments can be combined with each other without limitation, to the extent that they are not incompatible.

### EXAMPLES

### Example 1

A feedstock system that enables the method of the present invention is developed, for the manufacturing of Titanium based alloy components for aerospace, decorative, automobile, chemical, medical or any other kind of application. The system consists on powder-like filled polymeric material. The filling of the polymeric material consists in turn on a compacted mixture of powder of Ti alloyed with Si and V with a narrow particle size distribution centered at D50=10 microns, and a powder of a 20% Ga80% Al (weight) alloy with a narrow particle size distribution centered at D50=4 microns. The GaAl alloy represents around a 6% in weight of the total metallic powder. The polymeric material containing HDPE. SLS is used as AM technique, but other techniques could also have been employed (especially DLP-SLA). A post processing consisting on a debinding step with heating at 5K/min to 400° C. holding for 30 minutes and then heating at 3K/min to 550° C., followed by a sintering at 1250° C.

### Example 2

photosensitive acrylic resin comprising 87% 1,6-hexane diol diacrylate-and 13% ethoxylated tetraacrylate pentaerythrinol is prepared, to which is added 0.55% photo-initiator (2,2-dimethoxy-1, 2-phenylacetophenone).

Powder aluminum alloy is prepared with an average particle size of 10 microns and the following composition (% by weight):

Cr: 0.25%; Cu: 1.7%; Fe: 0.1%; Mg: 2.6%; Mn: 0.2%; Si: 0.15%; Zn: 5.6%

With the photosensitive resin described above a suspension is prepared by adding a 60% by volume of the indicated powder, the mixing is done mechanically by adding the powder at stages. 2% by weight of dispersant is added. (aluminum particle), the dispersant used is a cationic dispersant, 5% styrene is used to lower the viscosity of the mixture.

A system with esparsor arm is used to add 50 microns in suspension in each step and curing is performed using a mask in the shape of two specimens of flat traction (one next to the other) and a mercury-xenon light with a peak around 360 nm.

40 Layers are made and shaped pieces of specimens are removed and dried. Subsequently the specimens are placed in a box with very fine silica fume, also covering parts. The system is then introduced into a vacuum oven, where it is realized vacuum for several hours to 0.1 mbar. At this point, without stopping the vacuum system, the temperature is raised slowly to 250° C. where remains for 4h. Then it continues slowly raising the temperature to 350° C., where remains for 10h. Finally the temperature is raised to 550° C. where remains for 10h. the temperature is lowered slowly and proceed to the extraction of parts and cleaning. One of the specimens was submitted to hot isostatic pressing (HIP) at 550° C. and 100 MPa pressure.

T6 treatment is made to to the test pieces and then proceeds to polishing and test pieces, yielding over 80% of the value of elastic limit in both cases.

### Example 3

A photosensitive acrylic resin consisting in 50% phthalic diglycol diacrylate (PDDA), 10% acrylic acid, 25% methyl methylacrylate, 5% styrene and 10% butyl acrylate is prepared. To the mixture is added a 1% cationic photo-initiator (1,3,3,1′,3′,3′-hexamethyl-11-chloro-10,12-propylenetricarbocyanine triphenylbutylborate).

Iron base alloy powder is prepared with an average size of 50 microns with the following composition (% by weight): % C 0.4; % Ni: 7.5; % Cr: 8%; % Mo: 1%; % V: 1%; % Co: 2%

Al alloy 70% 30% Ga powder is prepared with an average size of 20 micrometer.

In a mixer Shaker-mixer type a homogeneous powder mixture with 7% by volume of small powder and 93% vol of the powder with large particle size is prepared. A suspension is prepared with the photosensitive resin above disclosed by adding 68% by volume of the homogeneous mixture of powders, the mixture is done mechanically by adding the powder at stages. 2% by weight of dispersant (of the powder particles) is added, the dispersant used is a cationic dispersant. 5% styrene is used to lower the viscosity of the mixture. a system with esparsor arm is used to add 50 microns in suspension in each step and curing is performed using a mask in the shape of two specimens of flat traction (one next to the other) and a laser diode source with a peak centered around 800 nm. 40 layers are made and shaped pieces of specimens are removed and dried. Subsequently the specimens are placed in a vacuum oven, where it is made vacuum for several hours to 0.01 mbar. At this point, without stopping the vacuum system, the temperature is raised slowly to 250° C. where it remains 4h. Then it continues slowly raising the temperature to 350° C. where remains for 10h. Finally the temperature is raised slowly to 550° C. where remains for 10h. the temperature is lowered slowly and proceeds to the extraction of the parts and cleaning. Subsequently the specimens are submitted to a hot isostatic pressing (HIP) at 1150° C. and 200 MPa pressure. Then is submitted to a treatment consisting on austenitize to 1040° C. quenching and tempering twice at 540° C. The specimens were tested in both cases obtaining a resistance to traction greater than 2000 MPa.

### Example 4

a model is developed to verify the functionality of a progressive system of die for hot stamping. two die sets which are mounted side by side in a press. The two sets of matrices have an omega shape. The first die set has an internal thermoregulation system capillary type with different levels until fine channels below the surface manufactured with 4 mm diameter and 20 mm length, the average distance between fine channels is 9 mm between centers. For this circuit of the first die set o is circulated it at 280° C. The second die set is composed of a top insert and a bottom insert (like the first die set) which in this case is a sweating die type, which are made with a network of tubes with holes in the active surface each insert of 0.8 mm diameter, on average there are about 12 holes per cm2 in the active surfaces. It is processed with this system and manual sheet Usibor transferización thick of 1500P 1.85 mm. The holding time at each station is 2 to 4 seconds. components are obtained with the omega shape of the dies and mechanical strength over 1600 MPa.

Inserts of dies are built from molds made by stereolithography using a resin that leaves no residue when burning in a DLP type printer. The resin molds have all negative channel, etc. The molds are exposed to ultraviolet light out of the printer. The molds are filled with a mixture of different powder for each pair of inserts of the die.

For the pair of inserts (top and bottom) of the first die, the following mixture is used:

90% by weight of powder with d50=18 microns and the following nominal composition by weight:

% C=0.45; % Mn=5%; % Si=2%; % Zr=3.8%; % Ti=2. Base Fe.

8.6% by weight of powder with d50=7.5 microns and the following nominal composition by weight:

% C=0.45; % Mn=5%; % Si=2%; % Zr=3.8%; % Ti=2. Base Fe. 1.4% by weight of powder with d50=4 microns and the following nominal composition by weight:

% Sn=40%; Ga %=60%.

For the pair of inserts (top and bottom) of the second die, the following mixture is used: 90.6% by weight of powder with d50=90 microns and the following nominal composition by weight: % C: 0.4; % Ni: 7.5; % Cr: 8%; % Mo: 1%; % V: 0.8%; % Co: 2%; % Al: 0.3% Based Fe. 8.7% by weight of powder with d50=40 microns and the following nominal composition by weight: % C: 0.4; % Ni: 7.5; % Cr: 8%; % Mo: 1%; % V: 0.8%; % Co: 2%; % Al: 0.3% base Fe.

0.7% by weight of powder with d50=20 microns and the following nominal composition by weight:

% Al=60%; Ga %=40%

For both sets of dies, the powder mixtures are introduced dry and molds are vibrated until filled with an apparent density greater than 68%. The dies are placed in a vacuum oven, with a vacuum 2*10-3 mbar or less and filled with high purity nitrogen, for two times a first stop at 90° C. for 3 hours is made. a very slow rise to 580° C. where and a stop for is made 4h. Here vacuum is made in the furnace chamber. And one last slow rise to 1150° C. is made where a stop 6h is done latter to the segments of the second die set is have a HIP from 6 am to 1150° C. with 200 MPa pressure is made

### Example 5

For the PMSRT of a shape constructed using stereolitography of a particle loaded resin, where the resin loses shape retention between 180 and 250° C., and whose degradation is time dependent, it was determined that the highest temperature at which the resin could still deliver sufficient shape retention was 200° C. provided the holding time was just a few minutes. A fast heating to 200° C. and short dwell was considered as the plausible treatment. Particles were a mix of a high melting point powder which was a high mechanical strength copper beryllium alloy with a bimodal distribution with modes at 150 microns and 20 microns and a gallium powder with d50 20 microns, the relation of high melting point powder to low melting point powder was 90/10. Equilibrium showed full melting of the Ga powder at 200° C. and a desirable 20-30% Cu dissolution into the liquid phase to raise the melting temperature above 400° C. To study the required dwell approximate calculation of diffusivity was employed. The simplification was made to only consider diffusion of copper into liquid gallium. From Xuping Su et al. in JPEDAV (2010) 31: pg. 333-340 (D01: 10.1007/s11669-010-9726-4) Equation 12 was computed taking the data from table 2, except for the atomic volume of gallium which was computed to be 1,203*10-5 m3/mol (according to A.F. Crawley, Int. Met. Rev., 1974, 19, p 32-48). Eq. 12 renders roughly 1.6*10-11 m2/s. Which renders a few minutes required for the dissolution of enough copper, in very good agreement with table 3 in Yatsenko et al. in Journal of Physics 98(2008)062032—DOI: 10.1088/1742-6596/98/6/062032. In this case, half an hour is taken for this first dwell time. So, the test was set for a 10-minute dwell which proved more than sufficient.

### Example 6

A simple mold was constructed trough AM with a low ash upon burning resin, whose degradation temperature was around 200° C. The fill system was composed of a high melting powder which was a steel with more than 95% Fe and a d50 of 70 microns and a low melting point powder 90% Sn 10% Ga (melting point around 200° C.). and a d50 of 10 microns. The volume fraction ratio of the high melting point to the low melting point powder was 77/23. It was decided that a first dwell in the PMSRT should take place at 150° C. The study of the equilibria renders a melting temperature for the low melting point powder over 500° C. if 1% Fe is incorporated in the low melting point powder. To make the first order approximation to conduct the first test, only the diffusion of iron in pure tin was taken into account (D0=4.8*10-4 cm2/s; Q=51.1 KJ/mol according to the Smitells metal handbook). Applying fick's second law with all necessary assumptions (infinite soured of Fe at the surface amongst others) it was deduced that D*t had to be in the order of 8.1*10-12 m2. The calculation of D for the given temperature roughly renders 2.4*10-14 m2/s. Therefore, the first approximation for the minimum dwell time should be 340 seconds. A time of 2h was chosen for the first test, for practical reasons, given the ramp up speed chosen to avoid thermal stresses. The first try-out did show that the diffusion of Fe into the low melting point powder was more than the minimum required since a mean of more than a 4% Fe was found in the core of the low melting point powder.

### Example 7

A powder mixture that enables the method of the present invention is developed for the manufacturing of bronze based alloy components. The system consists on a compacted mixture of Bronze powder (90 wt. % Cu and 10 wt. % Sn) with a narrow particle size distribution centered at D50=20 microns, and a powder of a 20% Ga80% Sn (by weight) alloy with a narrow particle size distribution centered at D50=8 microns. The mixture of powders is shaped to its tap density and subjected to heat treatment. The heat treatment consisted in heating from room temperature to 150° C. at 20° C./h at maintaining 5 hours before heating until 250° C. at 20° C./h and maintaining during 5 h.

### Example 8

TABLE 1
Low melting point alloys

| Low MP Alloy | Al (%) | Ga (%) | Mg (%) | Sn (%) |
|---|---|---|---|---|
| 1 | 75.00 | 25.00 | | |
| 2 | 69.00 | 30.00 | 1.00 | |
| 3 | 60.00 | 40.00 | | |
| 4 | 45.00 | 54.00 | 1.00 | |
| 5 | 70.00 | 30.00 | | |
| 6 | 67.00 | 30.00 | 3.00 | |
| 7 | | 10.00 | | 90.00 |
| 8 | | 20.00 | | 80.00 |
| 9 | | 30.00 | | 70.00 |
| 10 | | 55.00 | | 45.00 |
| 11 | 49.00 | 50.00 | 1.00 | |
| 12 | 44.00 | 53.00 | 3.00 | |
| 13 | 40.00 | 59.00 | 1.00 | |
| 14 | 45.00 | 55.00 | | |
| 15 | 29.00 | 70.00 | 1.00 | |
| 16 | 29.00 | 68.00 | 3.00 | |
| 17 | | 35.00 | | 65.00 |
| 18 | | 40.00 | | 60.00 |

TABLE 2
High melting point alloys.

| High MP Alloy | D50 (μm) | Particle shape |
|---|---|---|
| Steel | 100 | Rounded |
| Copper | 40 | Dendritic |
| Bronze | 20 | Spherical |
| Aluminum | 20 | Angular |
| Titanium | 50 | Irregular |

TABLE 3
Wettability assessment (poor-regular-good-excellent) as function
of temperature (100° C.-200° C.-300° C.).

| | | | | |
|---|---|---|---|---|
| A (steel) | B (copper) | C (brass) | D (aluminum) | E (titanium) |

100° C.

| | | | | | |
|---|---|---|---|---|---|
| 1 | Poor | Poor | Poor | Poor | Poor |
| 2 | Poor | Poor | Poor | Poor | Poor |
| 3 | Poor | Poor | Poor | Poor | Poor |
| 4 | Regular | Regular | Regular | Regular | Regular |
| 5 | Poor | Poor | Poor | Poor | Poor |
| 6 | Poor | Poor | Poor | Poor | Poor |
| 7 | Poor | Good | Poor | Poor | Poor |
| 8 | Poor | Good | Poor | Poor | Poor |
| 9 | Good | Excellent | Good | Good | Good |
| 10 | Excellent | Excellent | Excellent | Excellent | Good |
| 11 | Poor | Poor | Poor | Poor | Poor |
| 12 | Poor | Poor | Poor | Poor | Poor |
| 13 | Poor | Poor | Regular | Regular | Poor |
| 14 | Poor | Good | Regular | Poor | Regular |
| 15 | Good | Regular | Good | Good | Good |
| 16 | Good | Regular | Good | Good | Good |
| 17 | Good | Excellent | Excellent | Good | Poor |
| 18 | Good | Excellent | Excellent | Good | Poor |

200° C.

| | | | | | |
|---|---|---|---|---|---|
| 1 | Poor | Poor | Poor | Poor | Poor |
| 2 | Poor | Poor | Poor | Poor | Poor |
| 3 | Poor | Poor | Poor | Poor | Poor |
| 4 | Good | Good | Good | Good | Good |
| 5 | Poor | Poor | Poor | Poor | Poor |
| 6 | Poor | Poor | Poor | Poor | Poor |
| 7 | Regular | Excellent | Regular | Regular | Regular |
| 8 | Regular | Excellent | Regular | Regular | Regular |
| 9 | Excellent | Excellent | Excellent | Excellent | Good |
| 10 | Excellent | Excellent | Excellent | Excellent | Good |
| 11 | Poor | Poor | Poor | Poor | Poor |
| 12 | Poor | Poor | Poor | Poor | Poor |
| 13 | Poor | Poor | Regular | Regular | Poor |
| 14 | Poor | Good | Regular | Poor | Regular |
| 15 | Good | Regular | Good | Good | Good |
| 16 | Good | Regular | Good | Good | Good |
| 17 | Excellent | Excellent | Excellent | Good | Regular |
| 18 | Excellent | Excellent | Excellent | Good | Regular |

300° C.

| | | | | | |
|---|---|---|---|---|---|
| 1 | Poor | Poor | Poor | Poor | Poor |
| 2 | Poor | Poor | Poor | Poor | Poor |
| 3 | Poor | Poor | Poor | Poor | Poor |
| 4 | Good | Good | Good | Good | Good |
| 5 | Poor | Poor | Poor | Poor | Poor |
| 6 | Poor | Poor | Poor | Poor | Poor |
| 7 | Good | Excellent | Good | Good | Good |
| 8 | Good | Excellent | Good | Good | Good |
| 9 | Excellent | Excellent | Excellent | Excellent | Regular |
| 10 | Excellent | Excellent | Excellent | Excellent | Regular |
| 11 | Poor | Poor | Poor | Poor | Poor |
| 12 | Poor | Poor | Poor | Poor | Poor |
| 13 | Poor | Poor | Regular | Regular | Poor |
| 14 | Poor | Good | Regular | Poor | Regular |
| 15 | Good | Regular | Good | Good | Good |
| 16 | Good | Regular | Good | Good | Good |
| 17 | Excellent | Excellent | Excellent | Excellent | Regular |
| 18 | Excellent | Excellent | Excellent | Excellent | Regular |

TABLE 4
Diffusion analysis (poor-regular-good-excellent) of elements
by SEM for selected alloys (4, 9 and 10) in the substrates.
Thermal treatment from room temperature to 250° C. at 20°
C./h and isothermal for 5 h in Ar atmosphere (1 ppm O₂).

| Substrate | 4 | 9 | 10 |
|---|---|---|---|
| A (steel) | Ga, (Regular) | Ga, Sn (Good) | Ga, Sn (Good) |
| | Al (Good) | | |
| B (Copper) | — | Ga, Sn (Regular) | Ga, Sn (Regular) |
| C (Brass) | — | Ga, Sn | Ga, Sn |
| | | (Excellent) | (Excellent) |
| D (Aluminum) | Ga, (Regular) | Ga, Sn (Good) | Ga, Sn (Good) |
| E (Titanium) | Ga, Al(Good) | Ga, Sn (Good) | Ga, Sn (Good) |

### Example 9

Analysis of different thermal treatments (TT) for alloy number 9 as low melting point alloy and different high melting point alloys (steel, copper, bronze, aluminum, and titanium) (see Table 2 Example 1). (d50 low melting point alloy=10 μm). Scale of analysis (poor—regular—good—excellent)

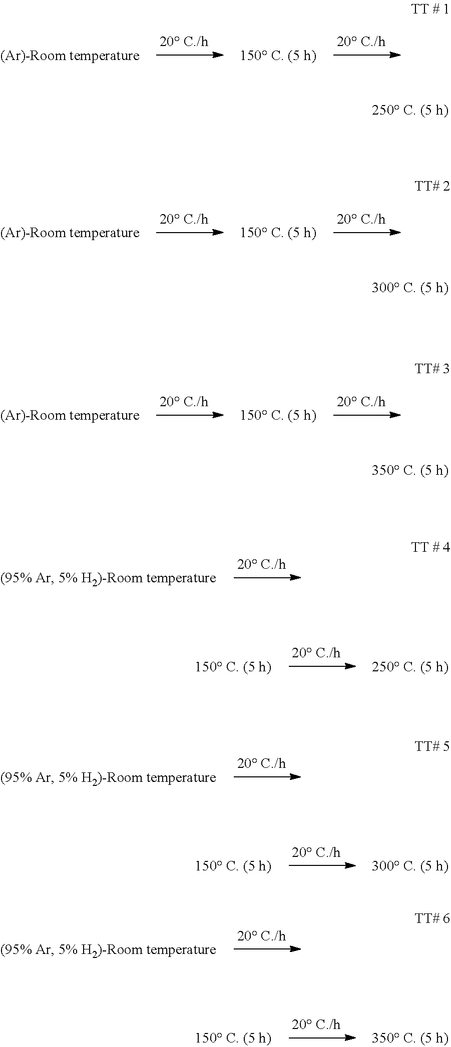

All atmospheres contained an average amount of 1 ppm of 02.

| | A | B | C | D | E |
|---|---|---|---|---|---|
| | (steel) | (copper) | (bronze) | (aluminum) | (titanium) |
| TT - 1 | poor | Good | Excellent | Regular | Regular |
| TT - 2 | poor | Excellent | Excellent | Regular | Regular |
| TT - 3 | Good | Excellent | Excellent | Good | Good |
| TT - 4 | Regular | Good | Excellent | Regular | Regular |
| TT - 5 | Regular | Excellent | Excellent | Good | Good |
| TT - 6 | Good | Excellent | Excellent | Good | Good |

Analysis Criteria:

Poor—mixture remained in powdery form

Regular—mixture remained partially in powder form

Good—mixture was partially densified

Excellent—mixture was densified

### Example 10—List of Fluxes that Improve Wettability

| Flux | Observations |
|---|---|
| Alumchrome ™ | Especially for LM point alloys 9 and 10 |
| Tacflux 012 ™ | Especially good for brass |
| EDEX ™ | Especially good for cleansing oxides and |
| | preparing the surface |

### Example 11 Include Several Compositions of the Alloys of the Invention

| | | | | | | | | | | | | | | | | | | | | | | | Taust/ | Ttemp/ | | |
|---|---|---|---|---|---|---|---|---|---|---|---|---|---|---|---|---|---|---|---|---|---|---|---|---|---|---|
| C | % Fe | % Ti | % Al | % Co | % Ni | % Cu | % Mo | % W | % Mg | % Mn | % Si | % Cr | % V | % Zn | % Sn | % Ga | % Bi | % In | % Pb | % Cd | % Cs | Others | sol | prec | HV | Com |
| 0.02 | | 0.45 | | | | | bal | | | | | | | | | 4 | | | | | | % Zr-0.07% | | | 240 | |
| 0.03 | | 0.4 | | | | | bal | | | | | | | | 8 | 2 | | | | | | % Zr-0.06% | | | 170 | |
| 0.1 | | | 2 | | | | bal | | | | | | | | | 3 | | 2 | | 1 | | % Hf-1.1% | | | 300 | |
| | | | | | | | bal | | | | | | | | | 2 | | 1 | | | 1 | % Ta-8% | | | 160 | |
| | | | 4 | | | 20 | bal | | | | | | | 2 | | 2 | | | 2 | | | | | | 180 | |
| | | | | | | | bal | | | | | | | | | | 0.5 | 2 | | | | % Re-5% | | | 160 | |
| | | | 3 | | | | bal | | | | | | | | | 2 | | | | | | % La2O3/% Y2O3/% ZrO2 | | | 230 | |
| | | | | | | | bal | | | | | | | | | 1 | | 2 | | | | % Re-35%/% Pd-0.3% | | | 120 | |
| | | | | | | | bal | 40 | | | | | | | | 5 | | | | | | | | | 200 | |
| | | | | | | | bal | | | | | | | | | 18 | | | | | | | | | 110 | |
| 0.1 | 0.2 | 0.5 | 2 | 0.2 | 0.5 | 1 | bal | 2 | 0.5 | 1 | 0.5 | 1 | 1 | 1 | 4 | 2 | 1 | 0.5 | 0.5 | 0.5 | 0.5 | % Rb-0.2% | | | 120 | |
| | | | | | | | 30 | bal | | | | | | | | 3 | | | | | | | | | 350 | |
| | | | | | | | | bal | | | | | | | | | | | | | | % La2O3/% Y2O3/% ZrO2 | | | 480 | |
| | | | | | | | | bal | | | | | | | | | | | | | | % Re 25% | | | 380 | |
| | | | | | | 30 | | bal | | | | | | 3 | | | | | 2 | | | | | | 350 | |
| | | | | | | | | bal | | | | | | | | | | | | | | % K 0.003% | | | 440 | |
| | | | | | | | | bal | | | | | | | | | | | | | | | | | 370 | |
| | 2 | | | 2 | 4 | | | bal | | | | | | | 2 | 2 | | | | 2 | | | | | 420 | |
| | 1 | | | | 3 | | 1 | bal | | | | | | | | 3 | | | | | | | | | 300 | |
| | 2 | | | | 4 | | | bal | | | | | | | | 2 | 1 | 2 | | | 1 | | | | 280 | |
| | | | 2 | | 5 | 4 | | bal | | | | | | | | 2 | | | | | | | | | 270 | |
| | 2 | | | | 4 | | 4 | bal | | | | | | | 2 | 2 | | | | | | | | | 320 | |
| | | | | | | | | bal | | | | | | | | 22 | | | | | | | | | 250 | |
| 0.5 | 2 | 0.8 | 1 | 1 | 2 | 1 | 3 | bal | 0.5 | 1 | 0.5 | 1 | 1 | 0.5 | 2 | 1 | 1 | 1 | 0.5 | 1 | 0.5 | % Rb-0.2% | 1200 | | 210 | |
| 0.15 | 0.1 | | 3 | bal | 0.2 | | 5.5 | | | 0.2 | 0.6 | 28 | | | | 4 | | | | | | | | 600 | 320 | |
| | | | | bal | 30 | | 9 | | | | | 18 | | | | | 6 | | | 2 | 1 | | | 600 | 600 | |
| | | | | bal | 29 | | 8 | | | | | 17 | | | 5 | 8 | | | | | | | | 850 | 560 | |
| 2.3 | 1 | 0.5 | 4 | bal | 1 | | | 11 | | | | 28 | | | | 2 | | | | | | % B-0.5% | 1220 | 1120 | 500 | |
| 0.2 | 1 | | 5 | bal | 2 | | 4 | | | 1 | | 25 | | | | 2 | | | | | | | 1250 | 720 | 280 | |
| 1 | | | | bal | | | | 4 | | | | 25 | | | 4 | 1 | 1 | | 2 | | | % Nb-5% | 1180 | | 270 | |
| 0.1 | 1.5 | | | bal | 15 | | | 10 | | | | 20 | | | | 4 | | 1 | | | | | | | 290 | |
| 0.4 | 1 | | 18 | bal | 20 | | 6 | 1.5 | | | | 20 | | | | 6 | | | | | | % N-0.05% | | | 260 | |
| 0.6 | 1 | 1 | 2 | bal | 10 | 2 | 2 | 2 | 0.3 | 1 | 0.5 | 15 | 1 | 1 | 2 | 1 | 1 | 1 | 1 | 0.5 | 0.5 | % Rb-0.6% | | | 250 | |
| | | | | | 9 | bal | | | | | | | | | 6 | 1.5 | | | | | | | | | 300 | |
| | | | | | 2 | bal | | | | | | | | | 1 | 2 | | | | | | % Be-0.4% | | | 200 | |
| | | | | 0.1 | 0.15 | bal | | | | | | | | | | 3 | | | | | | % Be-2% | | | 350 | |
| | | | | | | bal | | | | | | | | | | 0.5 | | | | | | | | | 70 | |
| | | | | | | bal | | | | | | | | 5 | | 0.5 | | | | | | | | | 110 | |
| | | | | | | bal | | | | | | | | 25 | | 3 | | | | | | | | | 180 | |
| | | | | | | bal | | | | | | | | | | 2.5 | | | | | | % P-0.5% | | | 250 | |
| | 1 | | | | | bal | | | | 0.5 | | | | 35 | | 1 | | | | | | | | | 100 | |
| | | | 8 | | | bal | | | | | | | | | | 2 | | | | | | | | | 200 | |
| | | | | | 12 | bal | | | | | | | | | 2 | | | | 9 | | | | | | 70 | |
| 0.1 | 2 | 0.5 | | | | bal | 0.5 | 0.1 | | | | | | 5 | 5 | | 0.5 | 0.5 | 5 | | | | | | 75 | |
| | | | | 2 | 5 | bal | | | | | | 0.1 | 0.2 | | | | | | | 0.5 | 0.2 | % Zr-4% | | | 100 | |
| 0.6 | 1 | 1 | 2 | 1 | 3 | bal | 2 | 2 | 0.3 | 1 | 0.5 | 1 | 1 | 1 | 2 | 1 | 1 | 1 | 1 | 0.5 | 0.5 | % Rb-0.6% | | | 120 | |
| | | | 4 | | | | | | bal | | | | | | | 2 | | 0.5 | | | | % Ce-2%/% La-1% | | | 60 | |
| | | | 6 | | | | | | bal | 0.5 | 0.1 | | | 0.2 | | 1 | | | | | 0.5 | % Sr-2.5% | | | 75 | |
| | | | | | | | | | bal | | | | | | | 0.5 | | | | 0.5 | | % Y-4%/% Nd-2.25% | | | 120 | |
| | | | 8 | 0.5 | 0.1 | 0.05 | | | bal | 0.2 | 0.05 | | | 0.5 | | 1 | 0.2 | | | | | % Re-2%/% Ca-2% | | | 80 | |
| 0.6 | 0.2 | 1 | 2 | 2 | 0.1 | 0.1 | 0.2 | 0.2 | bal | 1 | 0.1 | 0.2 | 0.2 | 1 | 0.5 | 1 | 0.5 | | 0.2 | 0.5 | 0.5 | % Rb-0.6% | | | 85 | |
| | bal | 1 | 10 | 15 | 20 | 4 | | | | | | | | | | 3 | | | | | | | | | 120 | |
| | | | 2 | | bal | | | | | 2 | 1 | | | | | | | | | | | | | | 180 | |
| | | | 2 | | bal | | | | | | | 20 | | | | 0.5 | | | | | | | | | 200 | |
| | 1 | | | | bal | 20 | | | | 1 | | | | | 5 | 1.5 | | | | | | | | | 100 | |
| 0.01 | 3 | 0.5 | | 2 | bal | | 17 | 3 | | 0.5 | | | 0.3 | | | 0.5 | 0.2 | 0.1 | | | | | 1120 | 260 | 220 | |
| 0.1 | 27 | 0.3 | 1 | 1 | bal | 0.5 | 3 | | | 0.3 | 0.3 | 20 | | | | 1.5 | | | | | | % Nb-5%/% P& % B-0.006% | 980 | 640 | 400 | |
| | | 0.5 | 3 | | bal | 30 | | | | | | | | | | 1 | | | 0.1 | 0.1 | 0.2 | | | | 110 | |
| 0.1 | 24 | | | | bal | | | | | | | 15 | | | | | | | | | | | | | 150 | |
| | | 40 | 2 | | bal | | | | | | | | | | | 0.5 | | | | | | | | | 600 | |
| | 16 | | | | bal | | 5 | | | | | | | | 5 | 4 | | 0.2 | | | | | | | 150 | |
| 0.6 | 1 | 1 | 2 | 2 | bal | 2 | 2 | 2 | 0.5 | 1 | 0.5 | 5 | 0.5 | 0.5 | 2 | 1 | 0.5 | 0.5 | 0.5 | 0.5 | 0.5 | % Rb-0.6% | | | 220 | |
| | 0.4 | 0.05 | bal | | | 0.1 | | | 0.1 | 0.1 | 0.3 | 0.05 | 0.1 | 0.1 | | 1 | | | 0.5 | | | % Zr-0.1% | | | 100 | |
| | 0.3 | 0.1 | bal | | | 4 | | | 0.05 | 0.3 | 0.5 | | 0.1 | | | | 0.5 | 0.5 | | | | | | | 120 | |
| 0.01 | 1 | | bal | | | | | | | 1 | | | | | 0.5 | 0.5 | | | | | | | | | 50 | |
| | 1 | 0.2 | bal | | | 0.5 | | | | | 5 | | | | | | | | | | | | | | 40 | |
| | 0.5 | | bal | 0.2 | 0.1 | 0.2 | | | 3.5 | | 0.3 | 0.2 | | 0.2 | | 1 | | | | 0.2 | 0.1 | | | | 100 | |
| | 0.5 | 0.2 | bal | | | 1 | | | | | | | | | | | | | | | | | | | 100 | |
| | | | bal | | | 1 | 0.2 | 0.2 | 1.5 | | 0.2 | | | 5 | | 4 | | | | | | | | | 120 | |
| | | | bal | | | 1 | | | | | | | | | 1 | 12 | | | | | | | | | 60 | |
| | | 1 | bal | | 0.2 | | | | 2 | 1 | 0.5 | | | | | 1 | | | | | | % B-0.05% | | | 70 | |
| | | | bal | | | | | | 4.5 | | | | | | | 0.2 | | | | | | % Zr-0.8%/% Sc-0.6% | 600 | 300 | 85 | |
| | | | bal | | | | | | 4 | | | | | | | 1.8 | | | | 0.2 | 0.1 | % Zr-0.4%/% Sc-0.4% | 600 | 300 | 90 | |
| | | | bal | | | 1.2 | | | 2.2 | | | 0.25 | | 5 | | 0.6 | 0.4 | 0.2 | | | | | 490 | 120 | 110 | |
| | 1 | 0.2 | bal | 0.5 | 0.5 | 2 | | 0.5 | 1 | 1 | 0.5 | 1 | 1 | 1 | 2 | 1 | | 0.2 | 0.5 | 0.5 | 0.5 | % Rb-0.6% | | | 60 | |
| | | bal | | | | | | | | | | | | | | 12 | | | | | | % Rb-1% | | | 140 | |
| | | bal | | | | | | | | | | | | | | 4 | 1 | 1 | | | | | | | 145 | |
| | | bal | 6 | | | | | | | | | | 4 | | | 8 | | | | | | | | | 300 | |
| | | bal | 5.4 | | | | | | | | | | 4 | | | 1.5 | | | | | | | 950 | 525 | 370 | |
| | | bal | 5.7 | | | | | | | | | | 4 | | | 0.7 | | | | | | | 950 | 525 | 360 | |
| | 0.4 | bal | 4.4 | | | | 5 | | | | | 3 | 5 | | | 1.5 | | | | | | % B-0.4% | 950 | 525 | 400 | |
| | | bal | 5.4 | | | | | | | | | | 4 | | | 3.5 | | | | | 0.5 | | 950 | 525 | 480 | |
| 0.05 | 0.2 | bal | 3 | | 0.2 | 0.1 | | 0.2 | | | | | | 0.2 | | 2.5 | | | | | | % O-0.15% | 950 | 525 | 400 | |
| | | bal | | 0.2 | | | | | | 0.1 | | | | | | 11 | | | | | | | 950 | 525 | 340 | |
| | | bal | 3 | | | | | | | | | | | | 2.5 | 3 | | | | | | | 950 | 525 | 360 | |
| | | bal | | | | | | | | | | | | | | 1.5 | | | | | | % Pd-0.3% | | | 145 | |
| | | bal | 1.5 | | | | | | | | | | 2.5 | | | 2 | | 0.5 | | 0.5 | | % Pd-0.1% | 950 | 525 | 360 | |
| | | bal | | | 1 | | 0.3 | | | | | | | | | 2 | | | | | | % Ru-0.1% | | | 270 | |
| | | bal | 2 | 0.3 | | | 4 | | | | | 6 | 8 | | | 1 | 0.5 | | | | | % Zr-4% | | | 300 | |
| | 1.5 | bal | 2 | | | | | | | | 0.3 | | 2.5 | | 1 | 2 | | | 0.5 | | | | 950 | 525 | 330 | |
| | | bal | | | | | | 0.5 | 0.2 | | | | | | | 6 | | | | | | % Nb-35% | | | 350 | |
| 0.1 | 1 | bal | 1 | 1 | 2 | 1 | 2 | 1 | 0.5 | 1 | 0.5 | 2 | 2 | 1 | 2 | 3 | 0.5 | 0.5 | 0.5 | 0.5 | 0.5 | % Rb-0.3%/% N-0.1% | 950 | 525 | 550 | |
| | 0.25 | bal | 5 | | | | 2 | | | | 0.2 | 2 | | | 2 | 1.5 | | | | | | % Zr-2% | | | 350 | |
| | 2 | bal | 1 | | | | | | | | | | 10 | | | 2 | | | | | | | | | 380 | |
| | | bal | 2 | | | | 4 | 4 | | | | | | 0.5 | 2 | 4 | | | | | | % Zr-5%/% N-0.05% | | | 350 | |
| 0.05 | | bal | 3 | | | | 2 | | | | 0.1 | | | | 3 | 3 | | 0.5 | | | | % Zr-3%/% O-0.12 | | | 320 | |
| 0.1 | | bal | 1 | | | | 1 | | | | | | 1 | | | 9 | | | | | | | | | 300 | |
| 0.4 | bal | | 0.9 | 2 | 7.5 | | 1 | | | | | 8 | 1 | | | 0.3 | | | | | | | 1080 | 540 | 530 | |
| 0.4 | bal | | 1.8 | 2 | 7.5 | | 1 | | | | | 8 | 1 | | | 1 | | | | | | | 1080 | 540 | 600 | |
| 0.1 | bal | | 2 | | 12 | 0.5 | 2 | 1 | | 2 | 1 | 17 | | | | 1 | | | | | 0.5 | | 1080 | 540 | 230 | |
| 0.4 | bal | | 0.4 | | | | 4 | | | | | | | | | 0.15 | | | | | | | 1080 | 600 | 540 | * |
| 0.4 | bal | | 0.7 | | 0.4 | | 4 | | | | | | 0.4 | | | 0.3 | | | | | | | 1080 | 600 | 600 | ** |
| 0.5 | bal | | | | 2 | | 4 | 4 | | | | 6 | 4 | | | 4 | 0.5 | 0.5 | | | | % B-3% | 1100 | 450 | 700 | |
| 1 | bal | | | | | | 1 | | | | | 12 | 1 | | | 3 | | | | | 0.1 | % B-0.005% | 1050 | 520 | 650 | |
| 0.2 | bal | | | | 0.5 | | 2 | | | | | 4 | 1 | | | | | | | | | % N-0.1% | | | 250 | |
| 2.1 | bal | | | 5 | | | 2 | 12 | | 0.5 | 0.5 | 4 | 4 | | 2 | 4 | | | | | | % Zr-1%/% Nb-1 | 1250 | 550 | 830 | |
| 2.5 | bal | | 2 | | 0.5 | | 4 | 12 | | 0.4 | 0.2 | 8 | 5 | | | 3 | | | | | | | 1200 | 580 | 800 | |
| 1 | bal | | 1.5 | | | | 2 | 1 | | 0.3 | 1 | 8 | 3 | | | 1 | | | | | | | 1070 | 520 | 720 | |
| 0.7 | bal | | | | | 0.5 | | | 0.5 | 0.5 | 0.5 | 17 | 0.4 | | 2 | 1 | 0.5 | | | 0.2 | | | 1040 | 500 | 510 | |
| 0.4 | bal | | 2 | | | | | | | 1 | 0.5 | 14 | | | | 2 | | | 0.1 | | | % S-0.1% | 1020 | 250 | 440 | |
| 0.4 | bal | | 0.5 | | | | 1 | | | 0.5 | 1 | 5 | 1 | | | 0.3 | | | | | | | 1020 | 600 | 410 | |
| 0.35 | bal | | | | | | 3.5 | | | 0.4 | 0.3 | 5 | 0.5 | | 0.5 | 0.5 | | | | | | | 1040 | 600 | 450 | |
| 0.6 | bal | | | | 1 | | 0.5 | | | 0.5 | 0.5 | 2 | 0.2 | | 1 | 0.5 | | | | | | % S | 980 | 450 | 340 | |
| 0.4 | bal | | | | | | 0.3 | | | 1 | 0.2 | 1 | | | 1 | 0.5 | | | | | | | | | 300 | |
| 0.2 | bal | | 0.5 | | 0.3 | | 0.1 | | | 1.6 | 0.5 | | | | | 0.2 | | | | | | | | | 220 | |
| 0.2 | bal | | | | | | | | | 1.4 | 0.3 | | | | | | | | | | | % B-0.005% | 900 | | 450 | |
| 0.2 | bal | | 10 | | | | | | | 1 | | 11 | | | | 10 | | | | | | | | | 400 | |
| 0.25 | bal | 0.2 | | | | 0.5 | | | | 1 | 0.4 | | 0.1 | | 2 | 2 | | | | | | % P-0.5% | | | 400 | |
| 0.02 | bal | | | 4.5 | 30 | | | | | 0.05 | 0.25 | | | | | 0.5 | | | | | | | | | 140 | |
| 0.1 | bal | | 1 | 1 | 2 | 1 | 2 | 1 | 0.5 | 1 | 0.5 | 2 | 2 | 1 | 2 | 3 | 0.5 | 0.5 | 0.5 | 0.5 | 0.5 | % Rb-0.3%% N-0.1% | 950 | | 560 | |

*- Thermal conductivity at room temperature and 40HRc = 60 W/mK
**- Thermal conductivity at room temperature and 40HRc = 45 W/mK
The claims describe further embodiments of the invention.

1. A method of manufacturing metallic or at least partially metallic components, comprising following steps:
a) providing a powder mixture comprising at least a low melting point alloy in powder form and at least a high melting point alloy in powder form and optionally an organic compound, wherein the powder mixture has a melting point below 790° C.;
b) shaping the powder mixture with a shaping technique resulting in a green component;
c) subjecting the green component to at least one heat treatment at a temperature between 0.35 times of a melting temperature of the low melting point alloy and 0.39 times of a melting temperature of the high melting point alloy, until the component reaches a compressive strength of at least 1.2 MPa, wherein, the melting temperature of the low melting point alloy is the melting temperature of the alloy having the lowest melting point among the alloys present in an amount of at least 1% in volume of the powder mixture, and the melting temperature of high melting point alloy is the melting temperature of the alloy having the highest volume % among the high melting point alloys present in an amount of at least 3.8% in volume of the powder mixture, wherein the high melting point alloy is an alloy having a melting temperature at least 110° C. higher than the melting temperature of the low melting point alloy and wherein there is diffusion between the high melting point alloy and the low melting point alloy.

2. The method according to claim 1, wherein the low melting point alloy is selected from AlGa, MgGa, NiGa, and/or MnGa alloy, and wherein the low melting point alloy contains at least 0.1% by weight gallium.

3. The method according to claim 1, wherein the low melting point alloy is an AlGa alloy containing at least 0.1% gallium.

4. The method according to claim 1, wherein the low melting point alloy is an AlGa alloy containing at least 12% by weight gallium.

5. The method according to claim 1, wherein the high melting point alloy is selected from a Fe-based alloy, a Ni-based alloy, a Co-based alloy, a Cu-based alloy, an Al-based alloy, a W-based alloy, a Mo-based alloy, or a Ti-based alloy.

6. The method according to claim 1, wherein the powder mixture comprises a high melting point alloy with a melting temperature 640° C. higher than the melting temperature of the metallic powder with a low melting point.

7. The method according to claim 1, wherein the powders in the mixture have different particle sizes.

8. The method according to claim 1, wherein the tap density of the powder mixture is 45% or more.

9. The method according to claim 1, wherein the shaping technique is selected from an additive manufacturing (AM) technique or a polymer shaping technique, wherein the polymer shaping technique is selected from the group consisting of injection molding, blow-molding, thermoforming, casting, compression, pressingRIM, extrusion, rotomolding, dip molding, and foam shaping.

10. The method according to claim 1, wherein the heat treatment in step c) is made under vacuum, low pressure, high pressure, inert atmosphere, reductive atmosphere and/or oxidative atmosphere.

11. The method according to claim 1, wherein the component is infiltrated with a metal.

12. The method according to claim 1 further comprising: d) subjecting the component obtained in step c) to sintering at a temperature at least 0.7 times the melting temperature of the high melting point alloy.

13. The method according to claim 12, wherein at least 1% in volume of liquid phase is formed during sintering.

14. The method according to claim 1 further comprising: e) subjecting the component to Hot Isostatic Pressing (HIP).

15. The method according to claim 1, wherein the powder mixture comprises an aluminium-based alloy with the following composition, all percentages in weight percent:

| % Si: 0-50 (optionally 0-20); | | % Cu: 0-20; | % Mn: 0-20; |
|---|---|---|---|
| % Zn: 0-15; | % Li: 0-10; | % Sc: 0-10; | % Fe: 0-30; |
| % Pb: 0-20; | % Zr: 0-10; | % Cr: 0-20; | % V: 0-10; |
| % Ti: 0-30; | % Bi: 0-20; | % Ga: 0-60; | % N: 0-8; |
| % B: 0-5; | % Mg: 0-50 (optionally 0-20); | | % Ni: 0-50; |
| % W: 0-10; | % Ta: 0-5; | % Hf: 0-5; | % Nb: 0-10; |
| % Co: 0-30; | % Ce: 0-20; | % Ge: 0-20; | % Ca: 0-10; |
| % In: 0-20; | % Cd: 0-10; | % Sn: 0-40; | % Cs: 0-20; |
| % Se: 0-10; | % Te: 0-10; | % As: 0-10; | % Sb: 0-20; |
| % Rb: 0-20; | % La: 0-10; | % Be: 0-15; | % Mo: 0-10; |
| % C: 0-5 | % O: 0-15, | | |

the rest consisting of aluminium and trace elements.

16. The method according to claim 1, wherein the powder mixture comprises a nickel-based alloy with the following composition, all percentages in weight percent:

| | | | |
|---|---|---|---|
| % Ceq = 0-1.5 | % C = 0-0.5 | % N = 0-0.45 | % B = 0-1.8 |
| % Cr = 0-50 | % Co = 3-40 | % Si = 0-2 | % Mn = 0-3 |
| % Al = 0-15 | % Mo = 0-20 | % W = 0-25 | % Ti = 0-14 |
| % Ta = 0-5 | % Zr = 0-8 | % Hf = 0-6, | % V = 0-8 |
| % Nb = 0-15 | % Cu = 0-20 | % Fe = 0-70 | % S = 0-3 |
| % Se = 0-5 | % Te = 0-5 | % Bi = 0-10 | % As = 0-5 |
| % Sb = 0-5 | % Ca = 0-5 | % P = 0-6 | % Ga = 0-30 |
| % Bi = 0-10 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5, |

the rest consisting of nickel and trace elements.

17. The method according to claim 1, wherein the powder mixture comprises a titanium-based alloy having the following composition, all percentages being in weight percent:

| | | | |
|---|---|---|---|
| % Ceq = 0-1.5 | % C = 0-0.5 | % N = 0-0.45 | % B = 0-1.8 |
| % Cr = 0-50 | % Co = 0-40 | % Si = 0-5 | % Mn = 0-3 |
| % Al = 0-40 | % Mo = 0-20 | % W = 0-25 | % Ni = 0-40 |
| % Ta = 0-5 | % Zr = 0-8 | % Hf = 0-6, | % V = 0-15 |
| % Nb = 0-60 | % Cu = 0-20 | % Fe = 0-40 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-30 |
| % Pt = 0-5 | % Rb = 0-10 | % Cd = 0-10 | % Cs = 0-10 |
| % Sn = 0-10 | % Pb = 0-10 | % Zn = 0-10 | % In = 0-10 |
| % Ge = 0-5 | % Y = 0-5 | % Ce = 0-5 | % La = 0-5 |
| % Pd = 0-5 | % Re = 0-5 | % Ru = 0-5, | |

the rest consisting of titanium and trace elements, and
wherein % Ceq=% C+0.86*% N+1.2*% B.

18. The method according to claim 1, wherein the powder mixture comprises an iron-based alloy having the following composition, all percentages being in weight percent:

| | | | |
|---|---|---|---|
| % Ceq = 0.15-3.5 | % C = 0.15-3.5 | % N = 0-2 | % B = 0-2.7 |
| % Cr = 0-20 | % Ni = 0-15 | % Si = 0-6 | % Mn = 0-3 |
| % Al = 0-15 | % Mo = 0-10 | % W = 0-15 | % Ti = 0-8 |
| % Ta = 0-5 | % Zr = 0-6 | % Hf = 0-6, | % V = 0-12 |
| % Nb = 0-10 | % Cu = 0-10 | % Co = 0-20 | % S = 0-3 |
| % Se = 0-5 | % Te = 0-5 | % Bi = 0-10 | % As = 0-5 |
| % Sb = 0-5 | % Ca = 0-5, | % P = 0-6 | % Ga = 0-20 |
| % Sn = 0-10 | % Rb = 0-10 | % Cd = 0-10 | % Cs = 0-10 |
| % La = 0-5 | % Pb = 0-10 | % Zn = 0-10 | % In = 0-10 |
| % Ge = 0-5 | % Y = 0-5 | % Ce = 0-5 | |

the rest consisting of iron and trace elements,
wherein
% Ceq=% C+0.86*% N+1.2*% B,
wherein
% Cr+% V+% Mo+% W+% Nb+% Ta+% Zr+% Ti>3.

19. The method according to claim 1, wherein the powder mixture has a volume comprising less than 70% by weight of the main alloying element thereof, wherein the volume is at least 1.2% by volume of metallic and intermetallic constituents of the powder mixture before shaping, and wherein the volume is reduced by at least 11% after the whole processing and post-processing are concluded.

20. The method according to claim 1, wherein the manufactured component comprises more than 0.1% in volume of other constituents different from metals in their composition.
